(19) United States
(12) Patent Application Publication
(10) Pub. No.: US 2026/0026186 A1
(43) Pub. Date: Jan. 22, 2026

(54) LIGHT-EMITTING ELEMENT, FUSED POLYCYCLIC COMPOUND FOR THE SAME, AND ELECTRONIC APPARATUS INCLUDING THE SAME

(71) Applicant: Samsung Display Co., Ltd., Yongin-si (KR)

(72) Inventors: Seonhyoung HUR, Yongin-si (KR); Hirokazu MIYASHITA, Yongin-si (KR); TAEIL KIM, Yongin-si (KR); Hyungjong KIM, Yongin-si (KR); JUNHA PARK, Yongin-si (KR); MUN-KI SIM, Yongin-si (KR); MINJUNG JUNG, Yongin-si (KR)

(73) Assignee: Samsung Display Co., Ltd., Yongin-si (KR)

(21) Appl. No.: 19/273,269

(22) Filed: Jul. 18, 2025

(30) Foreign Application Priority Data
Jul. 19, 2024 (KR) 10-2024-0095812

(51) Int. Cl. H10K 50/12; C09K 11/06; H10K 59/38; H10K 59/80; H10K 85/30; H10K 85/40; H10K 85/60

(52) U.S. Cl. CPC H10K 50/12; C09K 11/06; H10K 59/38; H10K 59/879; H10K 85/342; H10K 85/346; H10K 85/40; H10K 85/622; H10K 85/623; H10K 85/626; H10K 85/633; H10K 85/636; H10K 85/654; H10K 85/6572; H10K 85/6574; H10K 85/6576; H10K 85/658; C09K 2211/1014

(57) ABSTRACT

Embodiments provide a fused polycyclic compound, a light-emitting element that includes the fused polycyclic compound, an electronic apparatus that includes the light-emitting element. The light-emitting element includes a first electrode, a second electrode disposed on the first electrode, and an emission layer disposed between the first electrode and the second electrode, wherein the emission layer includes the fused polycyclic compound. The fused polycyclic compound is represented by Formula 1, which is explained in the specification:

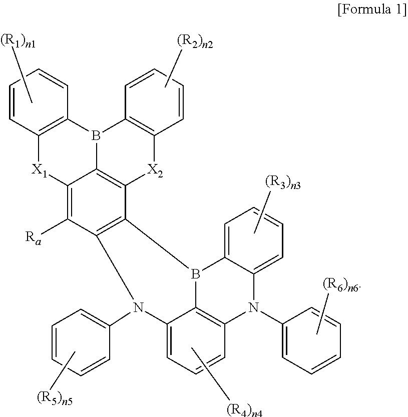

### CROSS-REFERENCE TO RELATED APPLICATION(S)

This application claims priority to and benefits of Korean Patent Application No. 10-2024-0095812 under 35 U.S.C. § 119, filed on Jul. 19, 2024, in the Korean Intellectual Property Office, the entire contents of which are incorporated herein by reference.

### BACKGROUND

### 1. Technical Field

The disclosure relates to a light-emitting element, a fused polycyclic compound used for the light-emitting element, and an electronic apparatus including the light-emitting element.

### 2. Description of the Related Art

An electronic apparatus may include a display device that displays an image. Ongoing development continues for an organic electroluminescence display device as an image display device. In contrast to liquid crystal display devices, organic electroluminescence display devices are so-called self-emissive display devices in which holes and electrons respectively injected from a first electrode and a second electrode recombine in an emission layer, so that in the emission layer, an emission material, which contains an organic compound, emits light to achieve display.

In the application of an organic electroluminescence element to a display device, there is a persistent demand for improvements in low-driving voltage, high luminous efficiency, and long lifespan. Thus, continuous development is required for materials for an organic electroluminescence element that are capable of stably achieving such characteristics.

In order to implement an organic electroluminescence element having high efficiency, technologies pertaining to phosphorescent emission, which utilizes triplet state energy, or pertaining to fluorescent emission, which uses triplet-triplet annihilation (TTA) in which a singlet exciton is generated by the collision of triplet excitons, are under development. Research and development are presently directed to materials for thermally activated delayed fluorescence (TADF) that utilize delayed fluorescence phenomena.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light-emitting element having improved luminous efficiency and element lifespan.

The disclosure also provides a fused polycyclic compound capable of improving luminous efficiency and element lifespan of a light-emitting element.

The disclosure also provides an electronic apparatus including a light-emitting element having improved luminous efficiency and lifespan, thereby having excellent display quality.

According to an embodiment, a light-emitting element may include a first electrode, a second electrode disposed on the first electrode, and an emission layer disposed between the first electrode and the second electrode, wherein the emission layer may include a first compound represented by Formula 1:

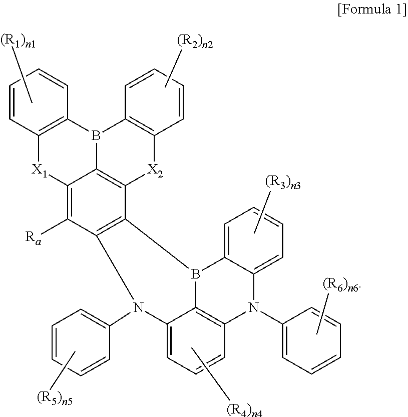

In Formula 1, X₁ may be O, S, Se, or a moiety represented by Formula 2; and X₂ may be O, S, Se, or N(R₈).

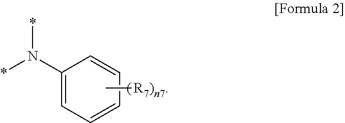

In Formula 1 and Formula 2, Rₐ and R₁ to R₇ may each independently be a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring; R₈ may be a substituted or unsubstituted aryl group having 6 to 30 ring-forming carbons or a substituted or unsubstituted heteroaryl group having 2 to 30 ring-forming carbons; at least one of R₁ to R₇ may each independently include a substituted or unsubstituted anthracene group, a substituted or unsubstituted pyrene group, a substituted or unsubstituted acenaphthyl group, or a substituted or unsubstituted acridine group; n1 to n3 may each independently be an integer from 0 to 4; n4 may be an integer from 0 to 3; and n5 to n7 may each independently be an integer from 0 to 5. In Formula 2, -* represents a bond to Formula 1.

In an embodiment, in Formula 1, at least one of R₁ to R₇ may each independently be a group represented by Formula 3-1 or Formula 3-2:

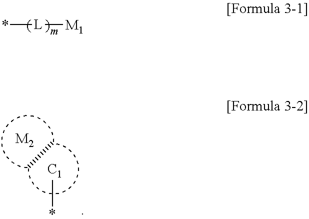

In Formula 3-1 and Formula 3-2, M₁ may be a substituted or unsubstituted anthracene group, a substituted or unsubstituted pyrene group, a substituted or unsubstituted acenaphthyl group, or a substituted or unsubstituted acridine group; L may be a direct linkage, a substituted or unsubstituted arylene group having 6 to 30 ring-forming carbons, or a substituted or unsubstituted heteroarylene group having 2 to 30 ring-forming carbons; m may be an integer from 1 to 3; M₂ may be a substituted or unsubstituted anthracene ring, a substituted or unsubstituted pyrene ring, a substituted or unsubstituted acenaphthyl ring, or a substituted or unsubstituted acridine ring; C₁ may be a substituted or unsubstituted aromatic hydrocarbon ring having 6 to 30 ring-forming carbons or a substituted or unsubstituted aromatic heterocycle having 2 to 30 ring-forming carbons; and -* represents a bond to Formula 1.

In an embodiment, in Formula 3-1, L may be a direct linkage, a substituted or unsubstituted phenylene group, or a substituted or unsubstituted divalent carbazole group.

In an embodiment, in Formula 1, at least one of R₁ to R₇ may each independently be a group represented by one of Formula 4-1 to Formula 4-5:

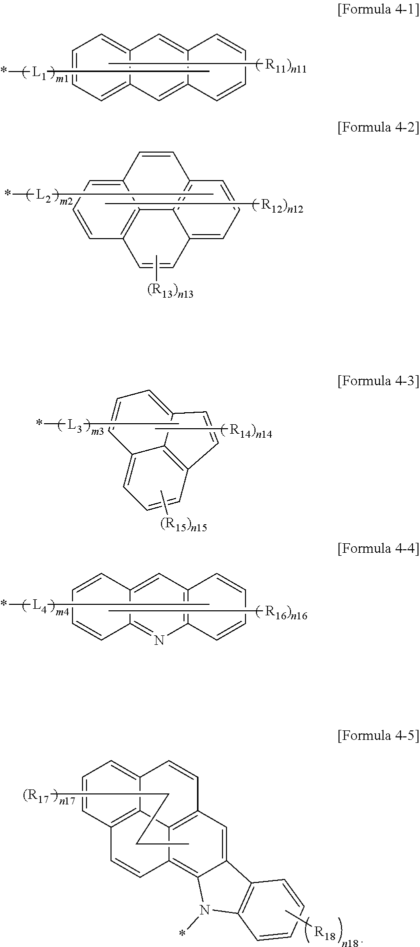

In Formula 4-1 to Formula 4-5, L₁ to L₄ may each independently be a direct linkage, a substituted or unsubstituted arylene group having 6 to 30 ring-forming carbons, or a substituted or unsubstituted heteroarylene group having 2 to 30 ring-forming carbons; R₁₁ to R₁₈ may each independently be a hydrogen atom, a deuterium atom, a halogen atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons; m1 to m4 may each independently be an integer from 1 to 3; n11 may be an integer from 0 to 9; n12 may be an integer from 0 to 7; n13 may be an integer from 0 to 2; n14 and n18 may each independently be an integer from 0 to 4; n15 may be an integer from 0 to 3; n16 and n17 may each independently be an integer from 0 to 8; and -* represents a bond to Formula 1.

In an embodiment, the first compound represented by Formula 1 may be represented by Formula 5-1 or Formula 5-2:

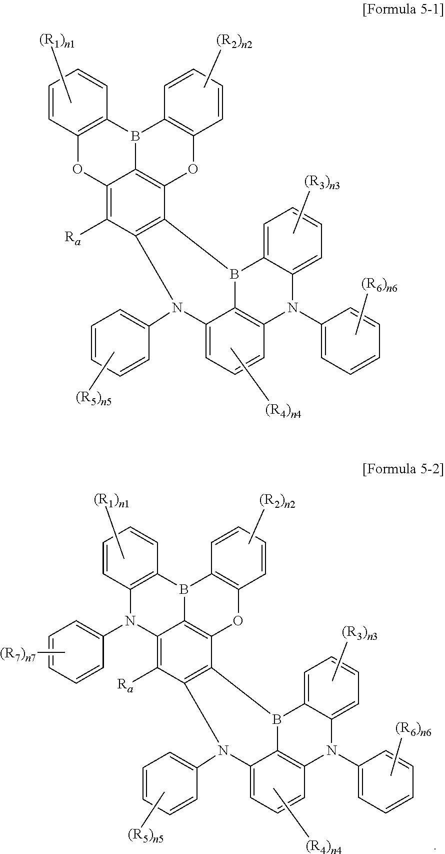

In Formula 5-1 and Formula 5-2, Rₐ, R₁ to R₇, and n1 to n7 are the same as defined in Formula 1.

In an embodiment, the first compound represented by Formula 1 may be represented by Formula 6-1 or Formula 6-2:

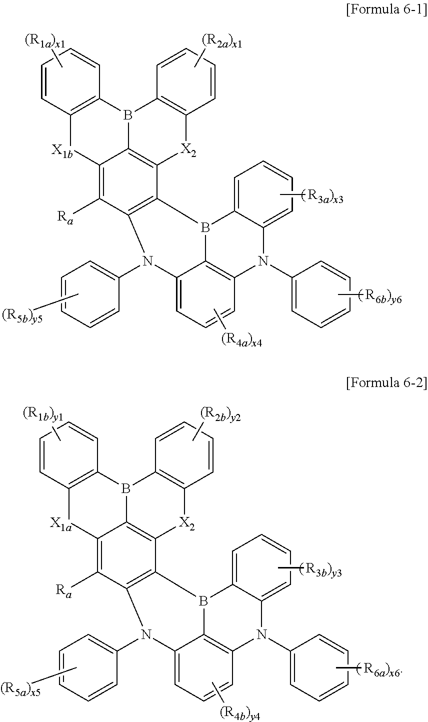

In Formula 6-1 and Formula 6-2, X₁ₐ may be O, S, Se, or a moiety represented by Formula 2-a; and X_{1b} may be O, S, Se, or a moiety represented by Formula 2-b:

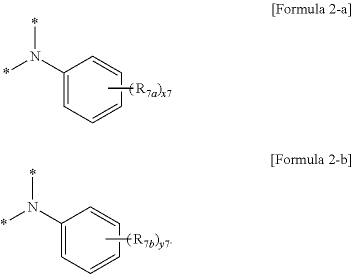

In Formula 6-1, Formula 6-2, Formula 2-a, and Formula 2-b, R₁ₐ to R₇ₐ and R_{1b} to R_{7b} may each independently be a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring; x1 to x3 and y1 to y3 may each independently be an integer from 0 to 4; x4 and y4 may each independently be an integer from 0 to 3; x5 to x7 and y5 to y7 may each independently be an integer from 0 to 5; and -* represents a bond to Formula 1. In Formula 6-1, at least one of R₁ₐ to R₄ₐ may each independently include a substituted or unsubstituted anthracene group, a substituted or unsubstituted pyrene group, a substituted or unsubstituted acenaphthyl group, or a substituted or unsubstituted acridine group. In Formula 6-2, at least one of R₅ₐ to R₇ₐ may each independently include a substituted or unsubstituted anthracene group, a substituted or unsubstituted pyrene group, a substituted or unsubstituted acenaphthyl group, or a substituted or unsubstituted acridine group.

In Formula 6-1 and Formula 6-2, Rₐ and X₂ are the same as defined in Formula 1.

In an embodiment, the first compound represented by Formula 1 may be represented by Formula 7-1 or Formula 7-2:

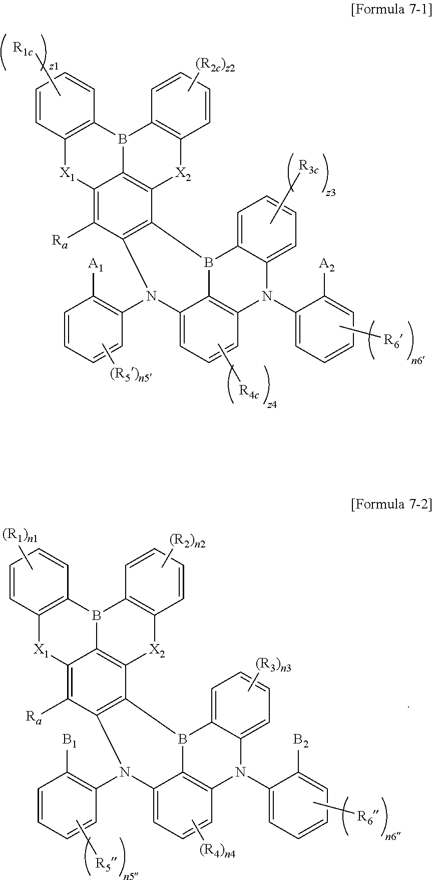

In Formula 7-1 and Formula 7-2, R_{1c} to R_{4c}, R₅′, R₆′, R₅″, and R₆″ may each independently be a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring; z1 to z3, n5′, n6′, n5″, and n6″ may each independently be an integer from 0 to 4; z4 may be an integer from 0 to 3; at least one of R_{1c} to R_{4c} may each independently be a group represented by Formula 3-1 or Formula 3-2; A₁ and A₂ may each independently be a substituted or unsubstituted aryl group having 6 to 30 ring-forming carbons or a substituted or unsubstituted heteroaryl group having 2 to 30 ring-forming carbons; at least one of B₁ and B₂ may each independently be a group represented by Formula 3-1 or Formula 3-2; and the remainder of B₁ and B₂ may be a substituted or unsubstituted aryl group having 6 to 30 ring-forming carbons or a substituted or unsubstituted heteroaryl group having 2 to 30 ring-forming carbons.

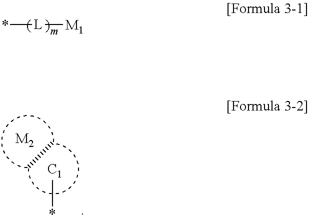

In Formula 3-1 and Formula 3-2, M₁ may be a substituted or unsubstituted anthracene group, a substituted or unsubstituted pyrene group, a substituted or unsubstituted acenaphthyl group, or a substituted or unsubstituted acridine group; L may be a direct linkage, a substituted or unsubstituted arylene group having 6 to 30 ring-forming carbons, or a substituted or unsubstituted heteroarylene group having 2 to 30 ring-forming carbons; m may be an integer from 0 to 3; M₂ may be a substituted or unsubstituted anthracene ring, a substituted or unsubstituted pyrene ring, a substituted or unsubstituted acenaphthyl ring, or a substituted or unsubstituted acridine ring; C₁ may be a substituted or unsubstituted aromatic hydrocarbon ring having 6 to 30 ring-forming carbons or a substituted or unsubstituted aromatic heterocycle having 2 to 30 ring-forming carbons; and -* represents a bond to Formula 1.

In Formula 7-1 and Formula 7-2, X₁, X₂, Rₐ, R₁ to R₄, and n1 to n4 are the same as defined in Formula 1.

In an embodiment, the first compound represented by Formula 1 may be represented by one of Formula 8-1 to Formula 8-3:

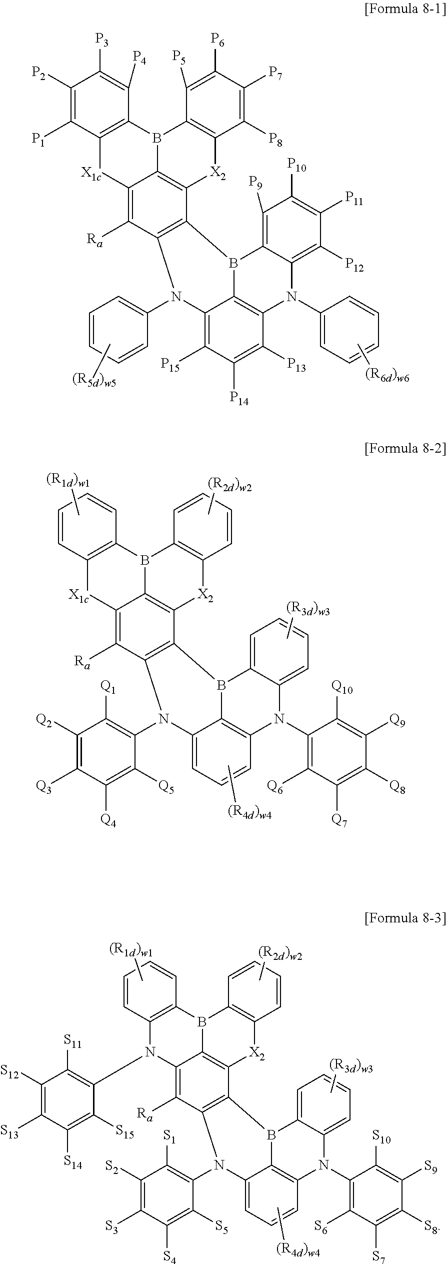

In Formula 8-1 to Formula 8-3, X_{1c} may be O, S, or Se; R_{1d} to R_{6d} may each independently be a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring; w1 to w3 may each independently be an integer from 0 to 4; w4 may be an integer from 0 to 3; and w5 and w6 may each independently be an integer from 0 to 5. In Formula 8-1, at least one of P₁ to P₁₅ may each independently be a group represented by one of Formula 4-1 to Formula 4-5; and the remainder of P₁ to P₁₅ may each independently be a hydrogen atom, a deuterium atom, a substituted or unsubstituted t-butyl group, a substituted or unsubstituted phenyl group, a substituted or unsubstituted biphenyl group, or a substituted or unsubstituted carbazole group. In Formula 8-2, at least one of Q₁ to Q₁₀ may each independently be a group represented by one of Formula 4-1 to Formula 4-5; and the remainder of Q₁ to Q₁₀ may each independently be a hydrogen atom, a deuterium atom, a substituted or unsubstituted t-butyl group, a substituted or unsubstituted phenyl group, a substituted or unsubstituted biphenyl group, or a substituted or unsubstituted carbazole group. In Formula 8-3, at least one of S₁ to S₁₅ may each independently be a group represented by one of Formula 4-1 to Formula 4-5; the remainder of S₁ to S₁₅ may each independently be a hydrogen atom, a deuterium atom, a substituted or unsubstituted t-butyl group, a substituted or unsubstituted phenyl group, a substituted or unsubstituted biphenyl group, or a substituted or unsubstituted carbazole group.

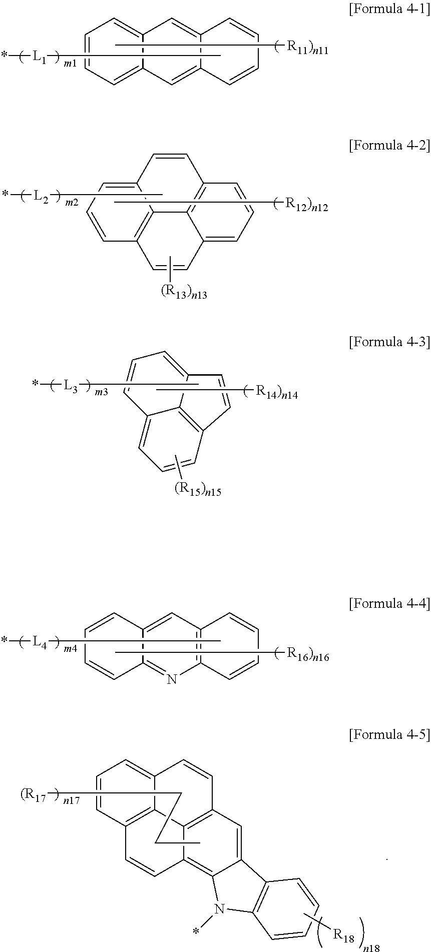

In Formula 4-1 to Formula 4-5, L₁ to L₄ may each independently be a direct linkage, a substituted or unsubstituted arylene group having 6 to 30 ring-forming carbons, or a substituted or unsubstituted heteroarylene group having 2 to 30 ring-forming carbons; R₁₁ to R₁₈ may each independently be a hydrogen atom, a deuterium atom, a halogen atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons; m1 to m4 may each independently be an integer from 1 to 3; n11 may be an integer from 0 to 9; n12 may be an integer from 0 to 7; n13 may be an integer from 0 to 2; n14 and n18 may each independently be an integer from 0 to 4; n15 may be an integer from 0 to 3; n16 and n17 may each independently be an integer from 0 to 8; and -* represents a bond to Formula 1.

In Formula 8-1 to Formula 8-3, Rₐ and X₂ are the same as defined in Formula 1.

In an embodiment, the first compound represented by Formula 1 may include at least one compound selected from Compound Group 1, which is explained below.

In an embodiment, the emission layer may further include at least one of a second compound represented by Formula HT-1, a third compound represented by Formula ET-1, and a fourth compound represented by Formula D-1:

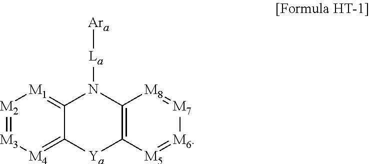

In Formula HT-1, M₁ to M₈ may each independently be N or C(R₅₁); Lₐ may be a direct linkage, a substituted or unsubstituted arylene group having 6 to 30 ring-forming carbons, or a substituted or unsubstituted heteroarylene group having 2 to 30 ring-forming carbons; Yₐ may be a direct linkage, C(R₅₂)(R₅₃), or Si(R₅₄)(R₅₅); Arₐ may be a substituted or unsubstituted aryl group having 6 to 30 ring-forming carbons or a substituted or unsubstituted heteroaryl group having 2 to 30 ring-forming carbons; and R₅₁ to R₅₅ may each independently be a hydrogen atom, a deuterium atom, a halogen atom, a cyano group, a silyl group, a substituted or unsubstituted thio group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring.

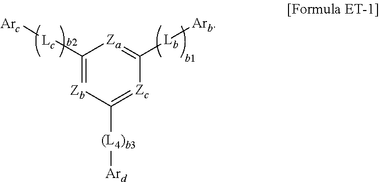

In Formula ET-1, at least one of Zₐ to Z_{c} may be N; the remainder of Zₐ to Z_{c} may each independently be C(R₅₆) R₅₆ may be a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons; b1 to b3 may each independently be an integer from 0 to 10; Ar_{b} to Ar_{d} may each independently be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons; and L_{b} to L_{d} may each independently be a direct linkage, a substituted or unsubstituted arylene group having 6 to 30 ring-forming carbons, or a substituted or unsubstituted heteroarylene group having 2 to 30 ring-forming carbons.

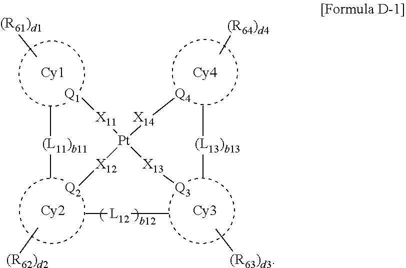

In Formula D-1, Q₁ to Q₄ may each independently be C or N; Cy1 to Cy4 may each independently be a substituted or unsubstituted hydrocarbon ring having 5 to 30 ring-forming carbons or a substituted or unsubstituted heterocycle having 2 to 30 ring-forming carbons; X₁₁ to X₁₄ may be each independently a direct linkage or *—O—*; L₁₁ to L₁₃ may each independently be a direct linkage,

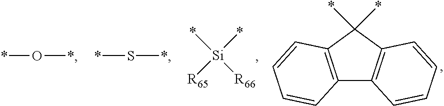

a substituted or unsubstituted alkylene group having 1 to 20 carbons, a substituted or unsubstituted arylene group having 6 to 30 ring-forming carbons, or a substituted or unsubstituted heteroarylene group having 2 to 30 ring-forming carbons; b11 to b13 may each independently be 0 or 1; R₆₁ to R₆₆ may each independently be a hydrogen atom, a deuterium atom, a halogen atom, a cyano group, a nitro group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons; and d1 to d4 may each independently be an integer from 0 to 4.

According to an embodiment, an electronic apparatus may include a circuit layer disposed on a base layer, and a display element layer disposed on the circuit layer, the display element layer including a light-emitting element. The light-emitting element may include a first electrode, a second electrode disposed on the first electrode, and an emission layer disposed between the first electrode and the second electrode, and the emission layer may include a first compound represented by Formula 1, which is explained herein.

In an embodiment, the light-emitting element may further include a capping layer disposed on the second electrode, and the capping layer may have a refractive index equal to or greater than about 1.6 with respect to light in a wavelength range of about 550 nm to about 660 nm.

In an embodiment, the electronic apparatus may further include an optical control layer disposed on the display element layer; the light-emitting element may emit a first color light; and the optical control layer may include a first optical control part that includes a first quantum dot that converts the first color light to a second color light having a longer wavelength region than the first color light, a second optical control part that includes a second quantum dot that converts the first color light to a third color light having a longer wavelength region than the first color light and the second color light, and a third optical control part that transmits the first color light.

In an embodiment, the electronic apparatus may further include a color filter layer disposed on the optical control layer; and the color filter layer may include a first filter that transmits the second color light, a second filter that transmits the third color light, and a third filter that transmits the first color light.

According to an embodiment, a fused polycyclic compound may be represented by Formula 1, which is explained herein.

In an embodiment, in Formula 1, at least one of R₁ to R₇ may each independently be a group represented by Formula 3-1 or Formula 3-2, which are explained herein.

In an embodiment, in Formula 1, at least one of R₁ to R₇ may each independently be a group represented by one of Formula 4-1 to Formula 4-5, which are explained herein.

In an embodiment, the fused polycyclic compound represented by Formula 1 may be represented by Formula 5-1 or Formula 5-2, which are explained herein.

In an embodiment, the fused polycyclic compound represented by Formula 1 may be represented by Formula 6-1 or Formula 6-2, which are explained herein.

In an embodiment, the fused polycyclic compound represented by Formula 1 may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light-emitting element according to an embodiment;

FIG. 4 is a schematic cross-sectional view of a light-emitting element according to an embodiment;

FIG. 5 is a schematic cross-sectional view of a light-emitting element according to an embodiment;

FIG. 6 is a schematic cross-sectional view of a light-emitting element according to an embodiment;

FIG. 7 and FIG. 8 are each a schematic cross-sectional view of a display device according to an embodiment;

FIG. 9 is a schematic cross-sectional view of a display device according to an embodiment;

FIG. 10 is a schematic cross-sectional view of a display device according to an embodiment;

FIG. 11 is a schematic diagram of an interior of a vehicle in which a display device according to an embodiment is disposed;

FIG. 12 is a schematic perspective view of an electronic apparatus according to an embodiment;

FIG. 13 is an exploded schematic perspective view of an electronic apparatus according to an embodiment;

FIG. 14 is a block diagram of an electronic apparatus according to an embodiment;

FIG. 15 is a schematic diagram of an electronic apparatus according to an embodiment; and

FIG. 16 is a schematic diagram of an electronic apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is unsubstituted or substituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. A hydrocarbon ring and a heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbons in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbons in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 50, 6 to 40, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

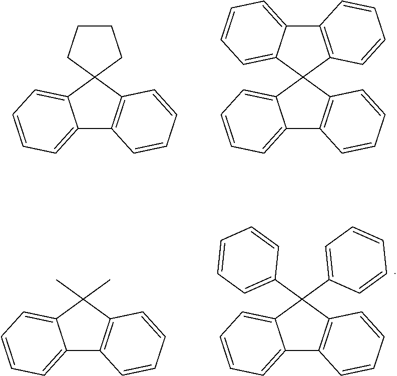

In the specification, a heterocyclic group may be any functional group or substituent derived from a ring that includes at least one of B, O, N, P, S, Si, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 60, 2 to 50, 2 to 40, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, a germanium group may be an alkylgermanium group or an arylgermanium group. Examples of a germanium group may include a trimethylgermanium group, triethylgermanium group, a t-butyldimethylgermanium group, a vinyldimethylgermanium group, a propyldimethylgermanium group, a triphenylgermanium group, a tribiphenylgermanium group, a diphenylgermanium group, a phenyl germanium group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

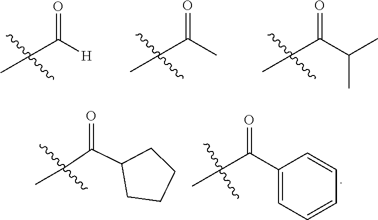

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, and a naphthylthio group, but embodiments are not limited thereto.

In the specification, an oxy group may be an oxygen atom that is bonded to an alkyl group or to an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols [symbol] and -* each represent a bond to a neighboring atom in a corresponding formula or moiety.

Hereinafter, embodiments will be described with reference to the accompanying drawings.

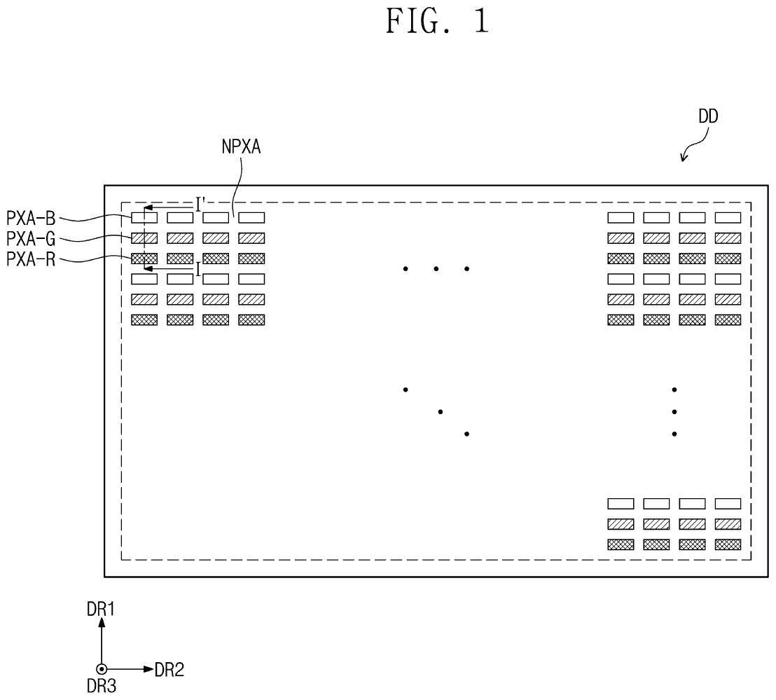

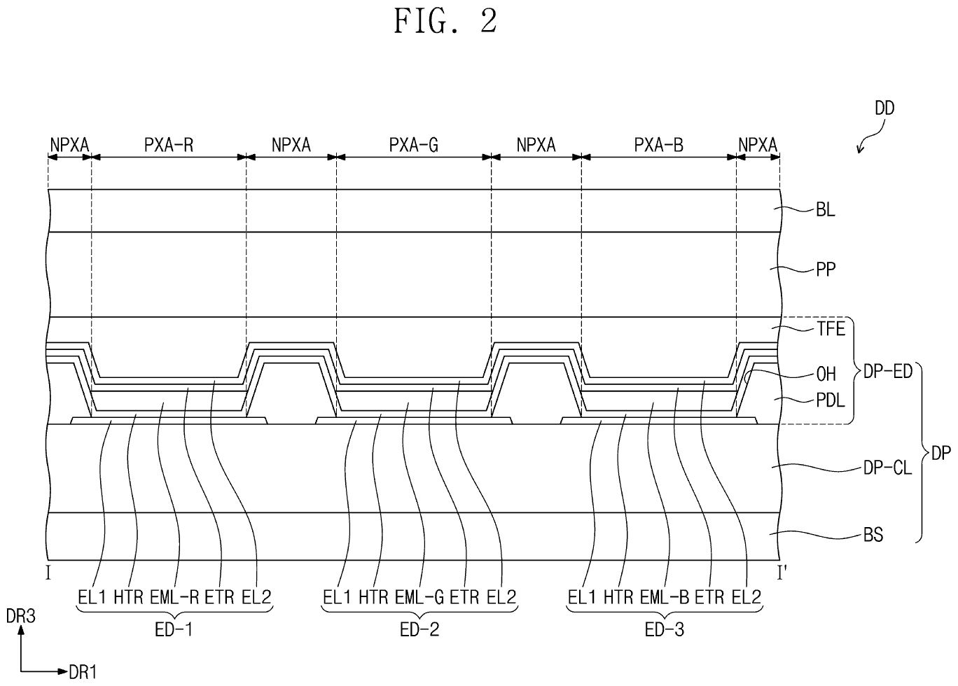

FIG. 1 is a schematic plan view of a display device DD according to an embodiment. FIG. 2 is a schematic cross-sectional view of the display device DD according to the embodiment. FIG. 2 is a schematic cross-sectional view of a portion taken along virtual line I-I′ in FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

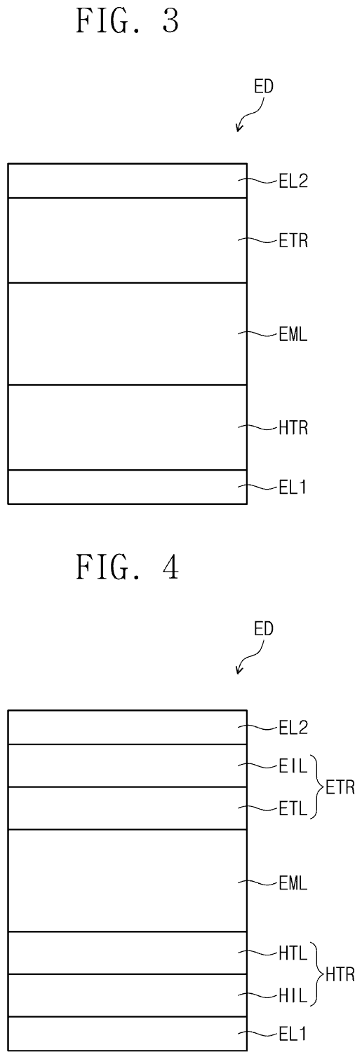

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer throughout the light emitting elements ED-1, ED-2, and ED-3. However, embodiments are not limited thereto. Although not shown in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 in an embodiment may be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light-emitting element ED according to embodiments. The light emitting element ED according to an embodiment may include a first electrode EL1, a second electrode EL2 facing the first electrode EL1, and at least one functional layer disposed between the first electrode EL1 and the second electrode EL2. The light emitting element ED according to an embodiment may include a fused polycyclic compound according to an embodiment, which will be explained below, in the at least one functional layer.

The light emitting element ED may include a hole transport region HTR, an emission layer EML, an electron transport region ETR, and the like, as the at least one functional layer. Referring to FIG. 3, the light emitting element ED according to an embodiment may include a first electrode EL1, a hole transport region HTR, an emission layer EML, an electron transport region ETR, and a second electrode EL2, which are stacked in that order.

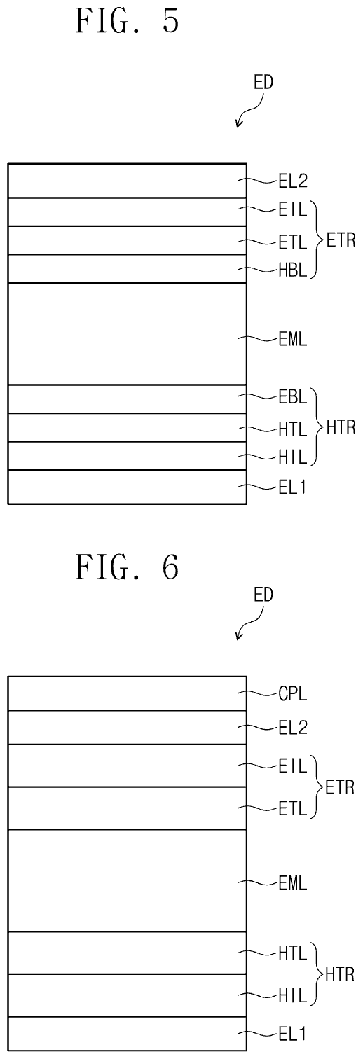

In comparison to FIG. 3, FIG. 4 is a schematic cross-sectional view of a light emitting element ED, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED that further includes a capping layer CPL disposed on the second electrode EL2.

The light emitting element ED may include a fused polycyclic compound according to an embodiment, which will be explained below, in the at least one functional layer. In the light emitting element ED, at least one of the hole transport region HTR, the emission layer EML, and the electron transport region ETR may include the fused polycyclic compound according to an embodiment. For example, in the light emitting element ED, the emission layer EML may include the fused polycyclic compound.

The first electrode EL1 has conductivity. The first electrode EL1 may be include a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayered structure that includes a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

For example, the hole transport region HTR may have a single-layered structure of a hole injection layer HIL or a hole transport layer HTL, or may have a single-layered structure that includes a hole injection material and a hole transport material. In embodiment, the hole transport region HTR may have a hole injection layer HIL/hole transport layer HTL structure, a hole injection layer HIL/hole transport layer HTL/buffer layer (not shown) structure, a hole injection layer HIL/buffer layer (not shown) structure, a hole transport layer HTL/buffer layer (not shown) structure, or a hole injection layer HIL/hole transport layer HTL/electron blocking layer EBL structure, in which the layers of each structure are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the hole transport region HTR may include a compound represented by Formula H-1:

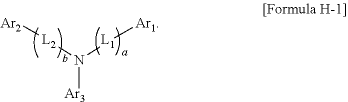

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ or multiple L₂ may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least of among Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

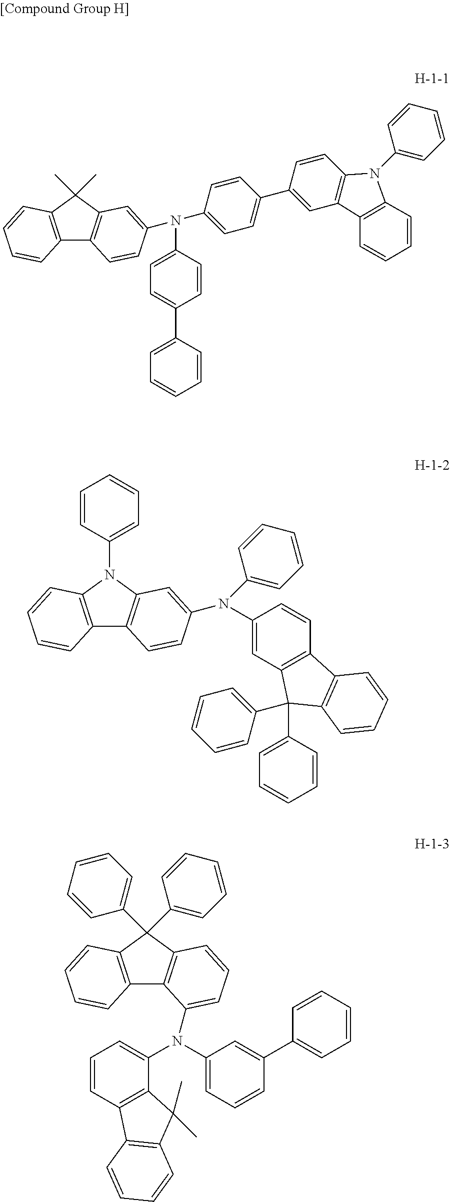 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

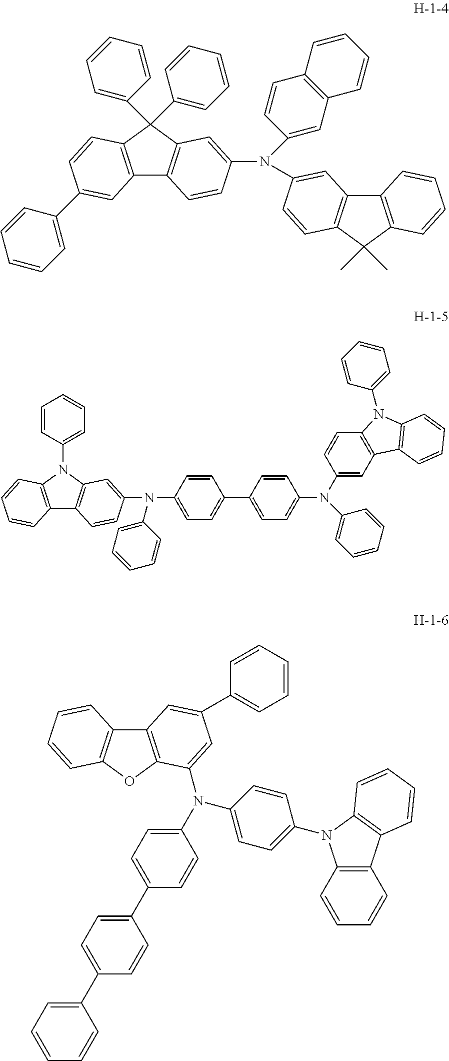 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

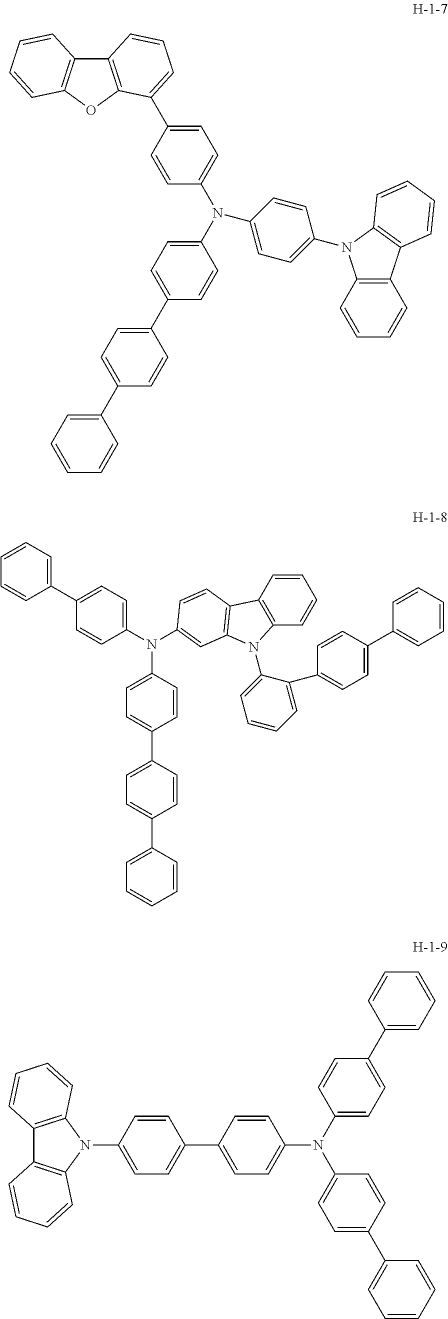 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

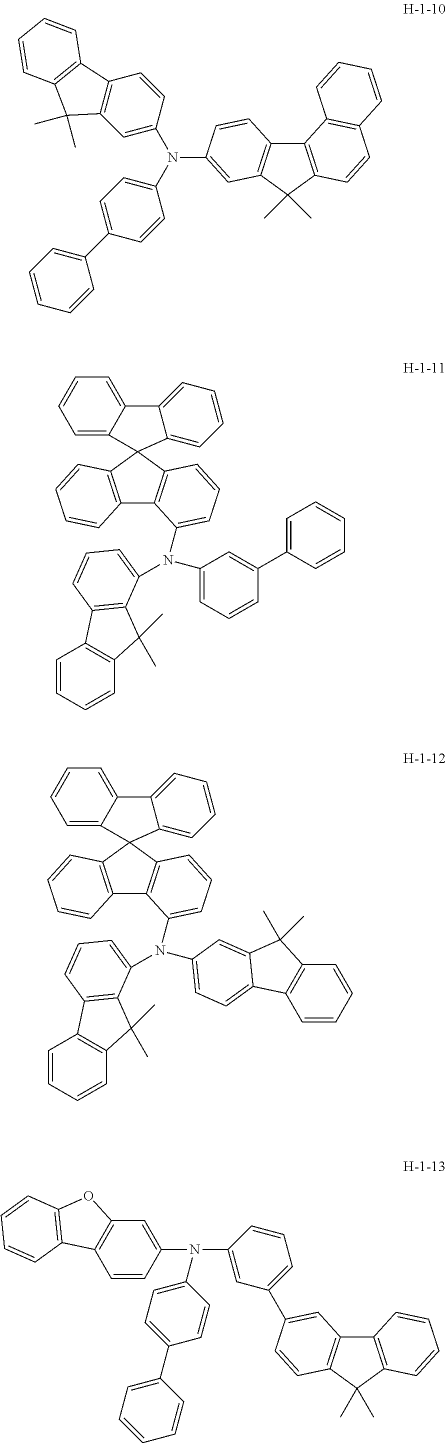 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

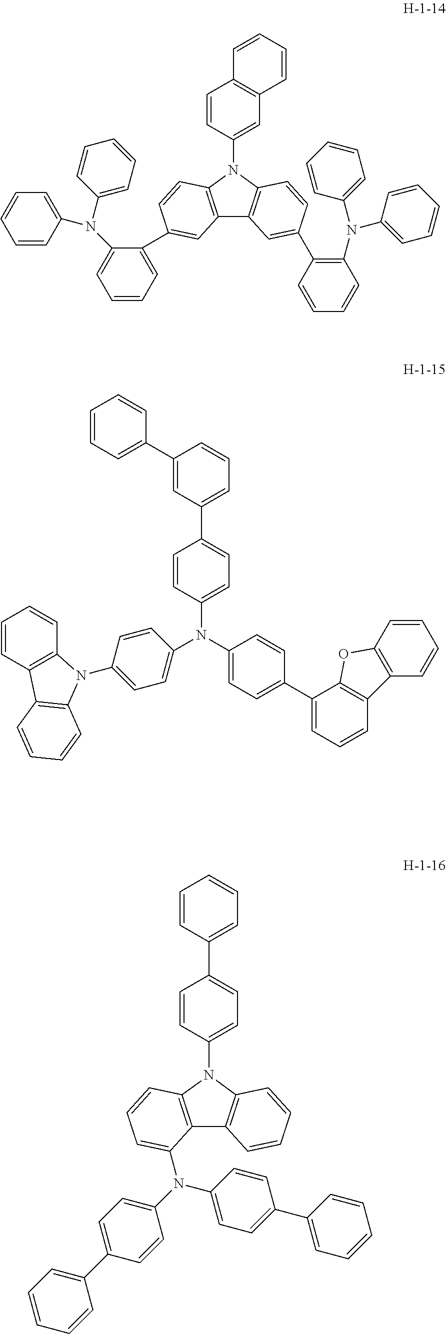 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

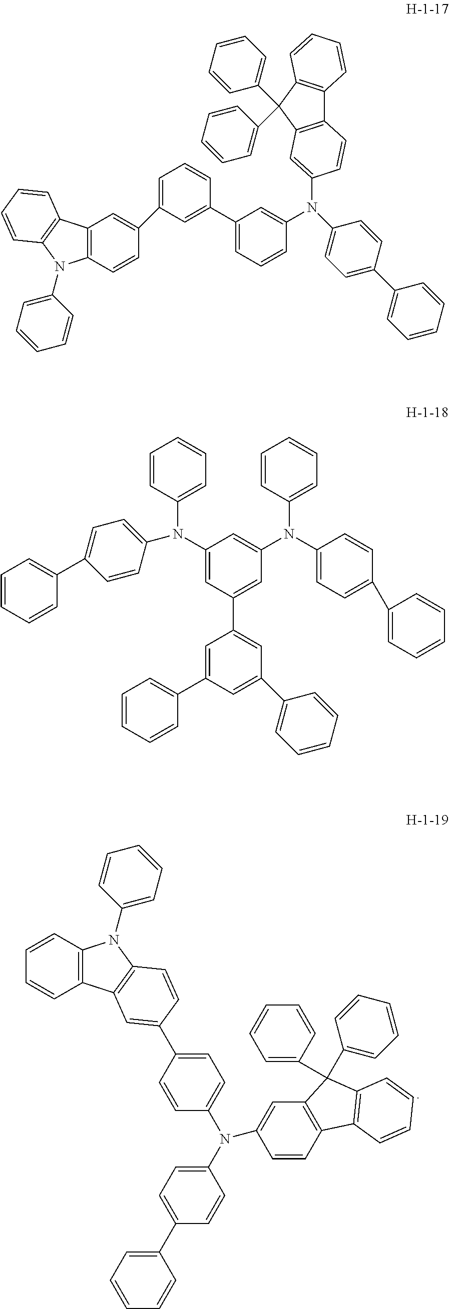 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrene sulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 30 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge-generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. Any material that may be included in the hole transport region HTR may be included in the buffer layer (not shown). The electron blocking layer EBL may prevent the injection of electrons from an electron transport region ETR to the hole transport region HTR.

An emission layer EML may be provided on the hole transport region HTR. The emission layer EML may have a thickness in a range of about 100 Å to about 1000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

The light-emitting element ED according to an embodiment may include a fused polycyclic compound represented by Formula 1 in at least one functional layer disposed between a first electrode EL1 and a second electrode EL2. In the light-emitting element ED, the emission layer EML may include a fused polycyclic compound according to an embodiment. In an embodiment, the emission layer EML may include the fused polycyclic compound as a dopant. The fused polycyclic compound may be a dopant material of the emission layer EML. In the specification, the fused polycyclic compound according to an embodiment may be referred to as a first compound.

The fused polycyclic compound according to an embodiment may have a structure that includes a fused ring core, in which five rings are fused together and which includes a first boron atom and first and second nitrogen atoms. The fused polycyclic compound according to an embodiment further includes two aromatic hydrocarbon rings that are connected to the fused ring core. A second boron atom, a first heteroatom, and a second heteroatom may be included as linking moieties between the fused ring core and the two aromatic hydrocarbon rings. The two aromatic hydrocarbon rings may be connected to the fused ring core via the second boron atom, the first heteroatom, and the second heteroatom to form additional fused rings.

In an embodiment, in the fused ring core of the fused polycyclic compound, three substituted or unsubstituted benzene rings may be connected to each other via the first boron atom, the first nitrogen atom, and the second nitrogen atom to thereby form a fused structure of five rings. For example, in the fused ring core, the three benzene rings may each be connected to the first boron atom as a central atom, and among the three benzene rings, a first benzene ring and a second benzene ring may be connected via the first nitrogen atom, and the remaining benzene ring, which is a third benzene ring, may be connected to the first benzene ring via the second nitrogen atom. The first boron atom and the first and second nitrogen atoms may each be connected to the first benzene ring.

In an embodiment, the two aromatic hydrocarbon rings may be connected to the fused ring core via a second boron atom, a first heteroatom, and a second heteroatom to form additional fused rings. For example, the fused polycyclic compound according to an embodiment may have a structure in which the two aromatic hydrocarbon rings are fourth and fifth benzene rings that are connected to the fused ring core, and the second boron atom, the first heteroatom, and the second heteroatom may serve as linking moieties between the fused ring core and the fourth and fifth benzene rings. The fourth and fifth benzene rings may be connected to the fused ring core via the second boron atom, the first heteroatom, and the second heteroatom to form four additional fused rings.

The fourth benzene ring and the fifth benzene ring may be connected to the second benzene ring of the fused ring core. For example, the second boron atom, the first heteroatom, and the second heteroatom may each be connected to the second benzene ring, and the fourth benzene ring and the second benzene ring may be connected via the second boron atom and the first heteroatom. The fifth benzene ring and the second benzene ring may be connected via the second boron atom and the second heteroatom. The second boron atom may be connected to a carbon atom of the second benzene ring at a para position to the first nitrogen atom. The first heteroatom may be connected to a carbon atom of the second benzene ring at a para position with to the first boron atom. The second heteroatom may be connected to a carbon atom of the second benzene ring at an ortho position to the first boron atom. In the specification, the second benzene ring that is connected to the fourth and fifth benzene rings may be referred to as a “fused benzene ring”.

In an embodiment, the first heteroatom may be a nitrogen atom (N), an oxygen atom (O), a sulfur (S) atom, or a selenium (Se) atom. The second heteroatom may be a nitrogen atom (N), an oxygen atom (O), a sulfur (S) atom, or a selenium (Se) atom.

In the fused polycyclic compound according to an embodiment, a benzene ring may be connected to each of the first nitrogen atom and the second nitrogen atom of the fused ring core. For example, a sixth benzene ring may be connected to the first nitrogen atom, and a seventh benzene ring may be connected to the second nitrogen atom. If the first heteroatom is a nitrogen atom, an eighth benzene ring may be connected to the first heteroatom. If the first heteroatom is a nitrogen atom, the first heteroatom may be referred to as a third nitrogen atom.

The fused polycyclic compound according to an embodiment may include a first substituent connected to the fused ring core. Among the benzene rings of the fused polycyclic compound according to an embodiment, the first substituent may be connected to at least one benzene ring other than the “fused benzene ring”. In the fused polycyclic compound according to an embodiment, the first substituent may be connected to at least one of the first benzene ring and the third benzene ring to the eighth benzene ring. For example, when the first heteroatom is a third nitrogen atom, the first substituent may be connected to at least one of the first benzene ring and the third benzene ring to the eighth benzene ring. As another example, when the first heteroatom is an oxygen atom, a sulfur atom, or a selenium atom, the first substituent may be connected to at least one of the first benzene ring and the third benzene ring to the seventh benzene ring.

In an embodiment, the first substituent may include a first sub substituent. The first sub substituent may be a substituted or unsubstituted anthracene group, a substituted or unsubstituted pyrene group, a substituted or unsubstituted acenaphthyl group, or a substituted or unsubstituted acridine group. For example, the first substituent may include a substituted or unsubstituted anthracene group, a substituted or unsubstituted pyrene group, a substituted or unsubstituted acenaphthyl group, or a substituted or unsubstituted acridine group.

In the specification, the term “Substituent a includes Substituent b” may be interpreted such that Substituent a is Substituent b, or Substituent a includes Substituent b as a substituent. For example, the first substituent may be a substituted or unsubstituted anthracene group, a substituted or unsubstituted pyrene group, a substituted or unsubstituted acenaphthyl group, or a substituted or unsubstituted acridine group; or the first substituent may be substituted with a substituted or unsubstituted anthracene group, substituted with a substituted or unsubstituted pyrene group, substituted with a substituted or unsubstituted acenaphthyl group, or substituted with a substituted or unsubstituted acridine group. For example, the first substituent may be a substituted or unsubstituted anthracene group, a substituted or unsubstituted pyrene group, a substituted or unsubstituted acenaphthyl group, or a substituted or unsubstituted acridine group. As another example, the first substituent may be an aryl group having 6 to 30 ring-forming carbons or a heteroaryl group having 2 to 30 ring-forming carbons, which may each be substituted with a substituted or unsubstituted anthracene group, a substituted or unsubstituted pyrene group, a substituted or unsubstituted acenaphthyl group, or a substituted or unsubstituted acridine group.

In the specification, the term “Substituent a includes Substituent b” may refer to a case where Substituent b is connected to Substituent a through a covalent bond, or may refer to a case where Substituent b is fused to share two or more carbon atoms of Substituent a.

The fused polycyclic compound according to an embodiment may be represented by Formula 1:

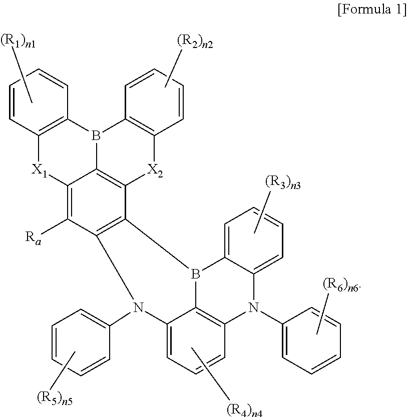

The fused polycyclic compound represented by Formula 1 may include a fused ring core that is formed by the fusion of five rings around a first boron atom and first and second nitrogen atoms, and may have a structure in which two aromatic hydrocarbon rings are connected to the fused ring core. A second boron atom, a first heteroatom, and a second heteroatom may serve as linking moieties between the fused ring core and the two aromatic hydrocarbon rings. The two aromatic hydrocarbon rings may be connected to the fused ring core via the second boron atom, the first heteroatom, and the second heteroatom to thereby form additional fused rings. In the specification with respect to Formula 1, a benzene ring that is substituted with a substituent represented by R₄ may correspond to the above-described first benzene ring, a benzene ring that is substituted with a substituent represented by Rₐ may correspond to the above-described second benzene ring, a benzene ring substituted with a substituent represented by R₃ may correspond to the above-described third benzene ring, a benzene ring substituted with a substituent represented by R₁ may correspond to the above-described fourth benzene ring, a benzene ring substituted with a substituent represented by R₂ may correspond to the above-described fifth benzene ring, a benzene ring substituted with a substituent represented by R₅ may correspond to the above-described sixth benzene ring, and a benzene ring substituted with a substituent represented by R₆ may correspond to the above-described seventh benzene ring. In Formula 2, which will be described below, a benzene ring substituted with a substituent represented by R₇ may correspond to the above-described eighth benzene ring.

In Formula 1, X₁ may be O, S, Se, or a moiety represented by Formula 2. For example, X₁ may be O, or X₁ may be a moiety represented by Formula 2.

In Formula 1, X₂ may be O, S, Se, or N(R₈). For example, X₂ may be O.

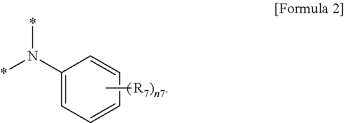

In Formula 1 and Formula 2, Rₐ and R₁ to R₇ may each independently be a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. For example, Rₐ may be a hydrogen atom, R₁ to R₇ may each independently be a hydrogen atom, a deuterium atom, a substituted or unsubstituted t-butyl group, a substituted or unsubstituted phenyl group, a substituted or unsubstituted biphenyl group, a substituted or unsubstituted indole group, a substituted or unsubstituted carbazole group, a substituted or unsubstituted anthracene group, a substituted or unsubstituted pyrene group, a substituted or unsubstituted acenaphthyl group, or a substituted or unsubstituted acridine group.

In Formula 1, R₈ may be a substituted or unsubstituted aryl group having 6 to 30 ring-forming carbons or a substituted or unsubstituted heteroaryl group having 2 to 30 ring-forming carbons. For example, R₈ may be a substituted or unsubstituted phenyl group.

In Formula 1, at least one of R₁ to R₇ may each independently include a substituted or unsubstituted anthracene group, a substituted or unsubstituted pyrene group, a substituted or unsubstituted acenaphthyl group, or a substituted or unsubstituted acridine group. For example, in Formula 1, when X₁ is a moiety represented by Formula 2, at least one of R₁ to R₇ may each independently include a substituted or unsubstituted anthracene group, a substituted or unsubstituted pyrene group, a substituted or unsubstituted acenaphthyl group, or a substituted or unsubstituted acridine group. As another example, in Formula 1, when X₁ is O, S, or Se, at least one of R₁ to R₆ may each independently include a substituted or unsubstituted anthracene group, a substituted or unsubstituted pyrene group, a substituted or unsubstituted acenaphthyl group, or a substituted or unsubstituted acridine group.

In Formula 1, at least one of R₁ to R₇ may each independently be a substituted or unsubstituted anthracene group, a substituted or unsubstituted pyrene group, a substituted or unsubstituted acenaphthyl group, or a substituted or unsubstituted acridine group; or at least one of R₁ to R₇ may each independently be substituted with a substituted or unsubstituted anthracene group, a substituted or unsubstituted pyrene group, a substituted or unsubstituted acenaphthyl group, or a substituted or unsubstituted acridine group. For example, at least one of R₁ to R₇ may each independently be an aryl group having 6 to 30 ring-forming carbons or a heteroaryl group having 2 to 30 ring-forming carbons, each substituted with a substituted or unsubstituted anthracene group, a substituted or unsubstituted pyrene group, a substituted or unsubstituted acenaphthyl group, or a substituted or unsubstituted acridine group.

In Formula 1, n1 to n3 may each independently be an integer from 0 to 4. If n1 to n3 are each 0, the fused polycyclic compound may not be substituted with R₁ to R₃, respectively. A case where n1 to n3 are each 4 and four of each of R₁ to R₃ are all hydrogen atoms may be the same as a case where n1 to n3 are each 0. If n1 to n3 are each 2 or greater, multiple groups of each of R₁ to R₃ may all be the same, or at least one thereof may be different from the remainder.

In Formula 1, n4 may be an integer from 0 to 3. If n4 is 0, the fused polycyclic compound may not be substituted with R₄. A case where n4 is 3 and three R₄ are all hydrogen atoms may be the same as a case where n4 is 0. If n4 is 2 or greater, multiple R₄ may all be the same, or at least one thereof may be different from the remainder.

In Formula 1, n5 and n6 may each independently be an integer from 0 to 5. If n5 and n6 are each 0, the fused polycyclic compound may not be substituted with R₅ and R₆, respectively. A case where n5 and n6 are each 5 and five R₅ and five R₆ are all hydrogen atoms may be the same as a case where n5 and n6 are each 0. If n5 and n6 are each 2 or greater, multiple R₅ and multiple R₆ may all be the same, or at least one thereof may be different from the remainder.

In Formula 2, n7 may be an integer from 0 to 5. If n7 is 0, the fused polycyclic compound may not be substituted with R₇. A case where n7 is 5 and five R₇ are all hydrogen atoms may be the same as a case where n7 is 0. If n7 is 2 or more, multiple R₇ may all be the same, or at least one thereof may be different from the remainder.

In Formula 2, -* represents a bond to Formula 1.

In an embodiment, in Formula 1, at least one of R₁ to R₇ may each independently be a group represented by Formula 3-1 or Formula 3-2. The group represented by Formula 3-1 or Formula 3-2 may correspond to the above-described first substituent.

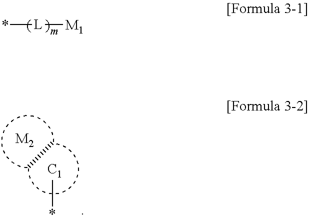

In Formula 3-1, M₁ may be a substituted or unsubstituted anthracene group, a substituted or unsubstituted pyrene group, a substituted or unsubstituted acenaphthyl group, or a substituted or unsubstituted acridine group.

In Formula 3-1, L may be a direct linkage, a substituted or unsubstituted arylene group having 6 to 30 ring-forming carbons, or a substituted or unsubstituted heteroarylene group having 2 to 30 ring-forming carbons. In an embodiment, in Formula 3-1, L may be a direct linkage, a substituted or unsubstituted phenylene group, or a substituted or unsubstituted divalent carbazole group.

In Formula 3-1, m may be an integer from 1 to 3. For example, m may be 1. If m is 2 or greater, L may be a substituted or unsubstituted arylene group having 6 to 30 ring-forming carbons or a substituted or unsubstituted heteroarylene group having 2 to 30 ring-forming carbons.

In Formula 3-2, M₂ may be a substituted or unsubstituted anthracene ring, a substituted or unsubstituted pyrene ring, a substituted or unsubstituted acenaphthyl ring, or a substituted or unsubstituted acridine ring.

In Formula 3-2, C₁ may be a substituted or unsubstituted aromatic hydrocarbon ring having 6 to 30 ring-forming carbons or a substituted or unsubstituted aromatic heterocycle having 2 to 30 ring-forming carbons. For example, C₁ may be a substituted or unsubstituted indole group.

In Formula 3-1 and Formula 3-2, -* represents a bond to Formula 1.

In an embodiment, in Formula 1, at least one of R₁ to R₇ may each independently be a group represented by one of Formula 4-1 to Formula 4-5. The groups represented by Formula 4-1 to Formula 4-5 may each correspond to the above-described first substituent.

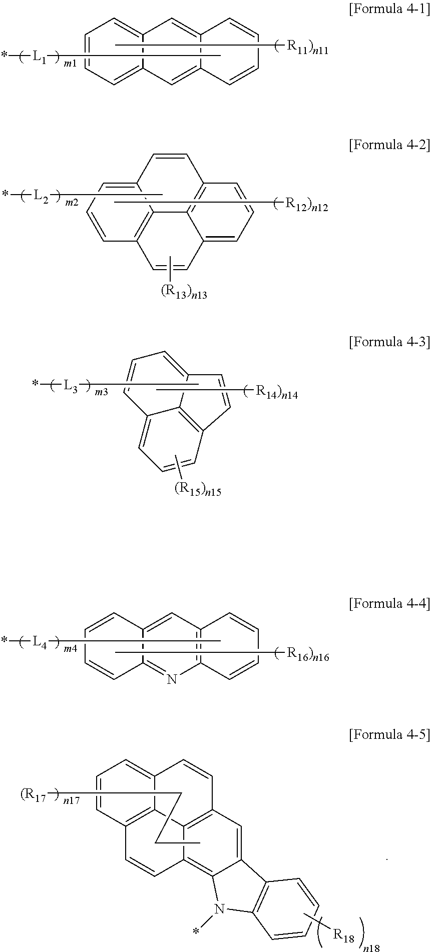

Formula 4-1 to Formula 4-4 each represent a case where in Formula 3-1, M₁ is further defined. Formula 4-5 represents a case where in Formula 3-2, C₁ and M₂ are each further defined.

In Formula 4-1 to Formula 4-4, L₁ to L₄ may each independently be a direct linkage, a substituted or unsubstituted arylene group having 6 to 30 ring-forming carbons, or a substituted or unsubstituted heteroarylene group having 2 to 30 ring-forming carbons. For example, L₁ to L₄ may each independently be a direct linkage, a substituted or unsubstituted phenylene group, or a substituted or unsubstituted divalent carbazole group.

In Formula 4-1 to Formula 4-5, R₁₁ to R₁₈ may each independently be a hydrogen atom, a deuterium atom, a halogen atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. For example, R₁₁ to R₁₈ may each independently be a hydrogen atom or a substituted or unsubstituted phenyl group.

In Formula 4-1 to Formula 4-4, m1 to m4 may each independently be an integer from 1 to 3.

In Formula 4-1, n11 may be an integer from 0 to 9. If n11 is 0, the fused polycyclic compound may not be substituted with R₁₁. A case where n11 is 9 and nine R₁₁ are all hydrogen atoms may be the same as a case where n11 is 0. If n11 is 2 or greater, multiple R₁₁ may all be the same, or at least one thereof may be different from the remainder.

In Formula 4-2, n12 may be an integer from 0 to 7. If n12 is 0, the fused polycyclic compound may not be substituted with R₁₂. A case where n12 is 7 and seven R₁₂ are all hydrogen atoms may be the same as a case where n12 is 0. If n12 is 2 or greater, multiple R₁₂ may all be the same, or at least one thereof may be different from the remainder.

In Formula 4-2, n13 may be an integer from 0 to 2. If n13 is 0, the fused polycyclic compound may not be substituted with R₁₃. A case where n13 is 2 and two R₁₃ are all hydrogen atoms may be the same as a case where n13 is 0. If n13 is 2, two R₁₃ may all be the same, or at least one thereof may be different from the remainder.

In Formula 4-3, n14 may be an integer from 0 to 4. If n14 is 0, the fused polycyclic compound may not be substituted with R₁₄. A case where n14 is 4 and four R₁₄ are all hydrogen atoms may be the same as a case where n14 is 0. If n14 is 2 or greater, multiple R₁₄ may all be the same, or at least one thereof may be different from the remainder.

In Formula 4-3, n15 may be an integer from 0 to 3. If n15 is 0, the fused polycyclic compound may not be substituted with R₁₅. A case where n15 is 3 and three R₁₅ are all hydrogen atoms may be the same as a case where n15 is 0. If n15 is 2 or greater, multiple R₁₅ may all be the same, or at least one thereof may be different from the remainder.

In Formula 4-4, n16 may be an integer from 0 to 8. If n16 is 0, the fused polycyclic compound may not be substituted with R₁₆. A case where n16 is 8 and eight R₁₆ are all hydrogen atoms may be the same as a case where n16 is 0. If n16 is 2 or greater, multiple R₁₆ may all be the same, or at least one thereof may be different from the remainder.

In Formula 4-5, n17 may be an integer from 0 to 8. If n17 is 0, the fused polycyclic compound may not be substituted with R₁₇. A case where n17 is 8 and eight R₁₇ are all hydrogen atoms may be the same as a case where n17 is 0. If n17 is 2 or greater, multiple R₁₇ may all be the same, or at least one thereof may be different from the remainder.

In Formula 4-5, n18 may be an integer from 0 to 4. If n18 is 0, the fused polycyclic compound may not be substituted with R₁₈. A case where n18 is 4 and four R₁₈ are all hydrogen atoms may be the same as a case where n18 is 0. If n18 is 2 or greater, multiple R₁₈ may all be the same, or at least one thereof may be different from the remainder.

In Formula 4-1 to Formula 4-5, -* represents a bond to Formula 1.

In an embodiment, the fused polycyclic compound represented by Formula 1 may be represented by Formula 1-a or Formula 1-b:

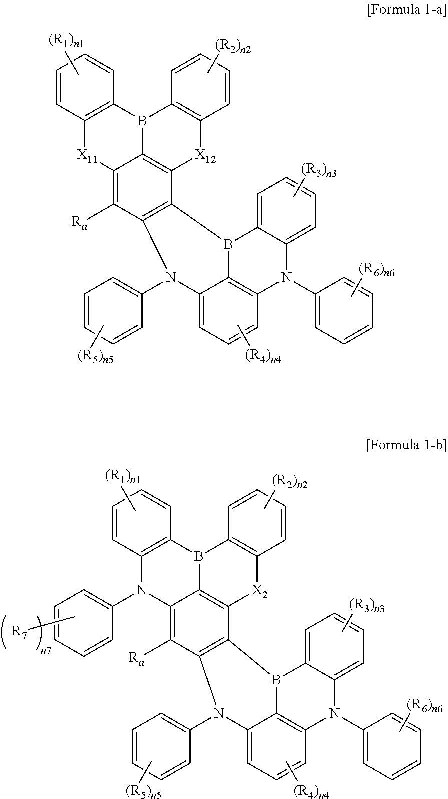

Formula 1-a and Formula 1-b each represent a case where in Formula 1, X₁ is further defined. Formula 1-a represents a case where in Formula 1, X₁ is O, S, or Se. Formula 1-b represent a case where in Formula 1, X₁ is a moiety represented by Formula 2.

In Formula 1-a, X₁₁ may be O, S, or Se.

In Formula 1-a, at least one of R₁ to R₆ may each independently include a substituted or unsubstituted anthracene group, a substituted or unsubstituted pyrene group, a substituted or unsubstituted acenaphthyl group, or a substituted or unsubstituted acridine group.

In an embodiment, in Formula 1-a, at least one of R₁ to R₆ may each independently be a group represented by Formula 3-1 or Formula 3-2.

In an embodiment, in Formula 1-a, at least one of R₁ to R₆ may each independently be a group represented by one of Formula 4-1 to Formula 4-5.

In Formula 1-b, at least one of R₁ to R₇ may each independently include a substituted or unsubstituted anthracene group, a substituted or unsubstituted pyrene group, a substituted or unsubstituted acenaphthyl group, or a substituted or unsubstituted acridine group.

In an embodiment, in Formula 1-b, at least one of R₁ to R₇ may each independently be a group represented by Formula 3-1 or Formula 3-2.

In an embodiment, in Formula 1-b, at least one of R₁ to R₇ may each independently be a group represented by one of Formula 4-1 to Formula 4-5.

In an embodiment, the fused polycyclic compound represented by Formula 1 may be represented Formula 5-1 or Formula 5-2:

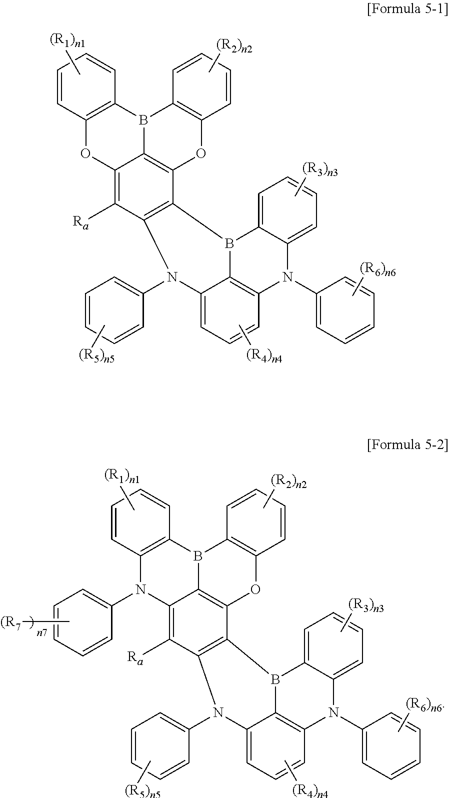

Formula 5-1 and Formula 5-2 each represent a case where in Formula 1, X₁ and X₂ are further defined.

In Formula 5-1, at least one of R₁ to R₆ may each independently include a substituted or unsubstituted anthracene group, a substituted or unsubstituted pyrene group, a substituted or unsubstituted acenaphthyl group, or a substituted or unsubstituted acridine group.

In an embodiment, in Formula 5-1, at least one of R₁ to R₆ may each independently be a group represented by Formula 3-1 or Formula 3-2.

In an embodiment, in Formula 5-1, at least one of R₁ to R₆ may each independently be a group represented by one of Formula 4-1 to Formula 4-5.

In Formula 5-2, at least one of R₁ to R₇ may each independently include a substituted or unsubstituted anthracene group, a substituted or unsubstituted pyrene group, a substituted or unsubstituted acenaphthyl group, or a substituted or unsubstituted acridine group.

In an embodiment, in Formula 5-2, at least one of R₁ to R₇ may each independently be a group represented by Formula 3-1 or Formula 3-2.

In an embodiment, in Formula 5-2, at least one of R₁ to R₇ may each independently be a group represented by one of Formula 4-1 to Formula 4-5.

In Formula 5-1 and Formula 5-2, Rₐ, R₁ to R₇, and n1 to n7 are the same as defined in Formula 1.

In an embodiment, the fused polycyclic compound represented by Formula 1 may be represented by Formula 6-1 or Formula 6-2:

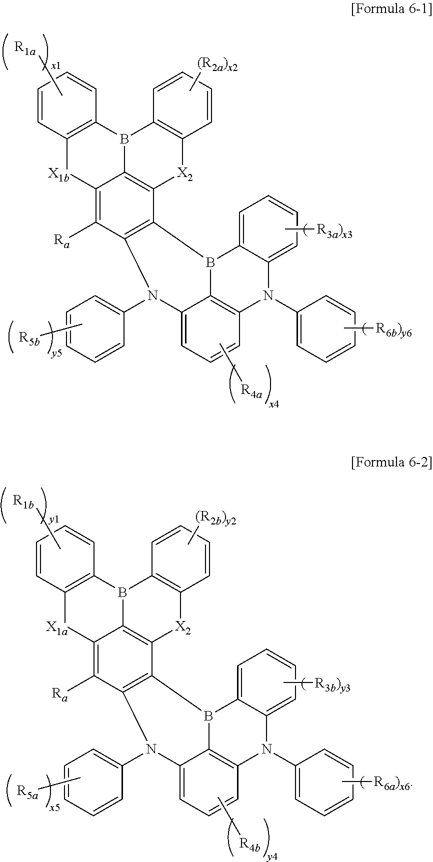

In Formula 6-1, X_{1b} may be O, S, Se, or a moiety represented by Formula 2-b. For example, X_{1b} may be O, or X_{1b} may be a moiety represented by Formula 2-b.

In Formula 6-2, X₁ₐ may be O, S, Se, or a moiety represented by Formula 2-a. For example, X₁ₐ may be O, or X₁ₐ may be a moiety represented by Formula 2-a.

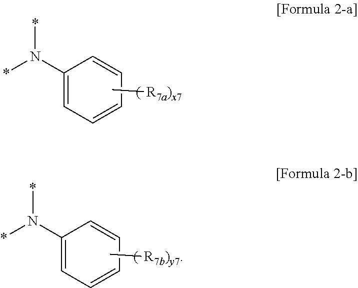

In Formula 6-1, Formula 6-2, Formula 2-a, and Formula 2-b, R₁ₐ to R₇ₐ and R_{1b} to R_{7b} may each independently be a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. For example, R₁ₐ to R₇ₐ and R_{1b} to R_{7b} may each independently be a hydrogen atom, a deuterium atom, a substituted or unsubstituted t-butyl group, a substituted or unsubstituted phenyl group, a substituted or unsubstituted biphenyl group, a substituted or unsubstituted indole group, a substituted or unsubstituted carbazole group, a substituted or unsubstituted anthracene group, a substituted or unsubstituted pyrene group, a substituted or unsubstituted acenaphthyl group, or a substituted or unsubstituted acridine group.

In Formula 6-1, x1 to x3 may each independently be an integer from 0 to 4. If x1 to x3 are each 0, the fused polycyclic compound may not be substituted with R₁ₐ to R₃ₐ, respectively. A where x1 to x3 are each 4 and four of each of R₁ₐ to R₃ₐ are all hydrogen atoms may be the same as a case where x1 to x3 are each 0. If x1 to x3 are each 2 or greater, multiple groups of each of R₁ₐ to R₃ₐ may all be the same, or at least one thereof may be different from the remainder.

In Formula 6-1, x4 may be an integer from 0 to 3. If x4 is 0, the fused polycyclic compound may not be substituted with R₄ₐ. A case where x4 is 3 and three R₄ₐ are all hydrogen atoms may be the same as a case where x4 is 0. If x4 is 2 or greater, multiple R₄ₐ may all be the same, or at least one thereof may be different from the remainder.

In Formula 6-2, x5 and x6 may each independently be an integer from 0 to 5. If x5 and x6 are each 0, the fused polycyclic compound may not be substituted with R₅ₐ and R₆ₐ, respectively. A case where x5 and x6 are each 5 and five R₅ₐ and five R₆ₐ are all hydrogen atoms may be the same as a case where x5 and x6 are each 0. If x5 and x6 are each 2 or greater, multiple R₅ₐ and multiple R₆ₐ may all be the same, or at least one thereof may be different from the remainder.

In Formula 6-2, y1 to y3 may each independently be an integer from 0 to 4. If y1 to y3 are each 0, the fused polycyclic compound may not be substituted with R_{1b} to R_{3b}, respectively. A case where y1 to y3 are each 4 and four of each of R_{1b} to R_{3b} are all hydrogen atoms may be the same as a case where y1 to y3 are each 0. If y1 to y3 are each 2 or greater, multiple groups of each of R_{1b} to R_{3b} may all be the same, or at least one thereof may be different from the remainder.

In Formula 6-2, y4 may be an integer from 0 to 3. If y4 is 0, the fused polycyclic compound may not be substituted with R_{4b}. A case where y4 is 3 and three R_{4b} are all hydrogen atoms may be the same as a case where y4 is 0. If y4 is 2 or greater, multiple R_{4b} may all be the same, or at least one thereof may be different from the remainder.

In Formula 6-1, y5 and y6 may each independently be an integer from 0 to 5. If y5 and y6 are each 0, the fused polycyclic compound may not be substituted with R_{5b} and R_{6b}, respectively. A case where y5 and y6 are each 5 and five R_{5b} and five R_{6b} are all hydrogen atoms may be the same as a case where y5 and y6 are each 0. If y5 and y6 are each 2 or greater, multiple R_{5b} and multiple R_{6b} may all be the same, or at least one thereof may be different from the remainder.

In Formula 2-a, x7 may be an integer from 0 to 5. If x7 is 0, the fused polycyclic compound may not be substituted with R₇ₐ. A case where x7 is 5 and five R₇ₐ are all hydrogen atoms may be the same as a case where x7 is 0. If x7 is 2 or greater, multiple R₇ₐ may all be the same, or at least one thereof may be different from the remainder.

In Formula 2-b, y7 may be an integer from 0 to 5. If y7 is 0, the fused polycyclic compound may not be substituted with R_{7b}. A case where y7 is 5 and five R_{7b} are all hydrogen atoms may be the same as a case where y7 is 0. If y7 is 2 or greater, multiple R_{7b} may all be the same, or at least one thereof may be different from the remainder.

In Formula 2-a and Formula 2-b, -* represents a bond to Formula 1.

In Formula 6-1, at least one of R₁ₐ to R₄ₐ may each independently include a substituted or unsubstituted anthracene group, a substituted or unsubstituted pyrene group, a substituted or unsubstituted acenaphthyl group, or a substituted or unsubstituted acridine group. For example, in Formula 6-1, at least one of R₁ₐ to R₄ₐ may each independently be a substituted or unsubstituted anthracene group, a substituted or unsubstituted pyrene group, a substituted or unsubstituted acenaphthyl group, or a substituted or unsubstituted acridine group; or at least one of R₁ₐ to R₄ₐ may each independently be substituted with a substituted or unsubstituted anthracene group, a substituted or unsubstituted pyrene group, a substituted or unsubstituted acenaphthyl group, or a substituted or unsubstituted acridine group. For example, at least one of R₁ₐ to R₄ₐ may each independently be an aryl group having 6 to 30 ring-forming carbons or a heteroaryl group having 2 to 30 ring-forming carbons, each substituted with a substituted or unsubstituted anthracene group, a substituted or unsubstituted pyrene group, a substituted or unsubstituted acenaphthyl group, or a substituted or unsubstituted acridine group.

In an embodiment, in Formula 6-1, at least one of R₁ₐ to R₄ₐ may each independently be a group represented by Formula 3-1 or Formula 3-2.

In an embodiment, in Formula 6-1, at least one of R₁ₐ to R₄ₐ may each independently be a group represented by one of Formula 4-1 to Formula 4-5.

In Formula 6-2, at least one of R₅ₐ to R₇ₐ may each independently include a substituted or unsubstituted anthracene group, a substituted or unsubstituted pyrene group, a substituted or unsubstituted acenaphthyl group, or a substituted or unsubstituted acridine group. For example, in Formula 6-2, at least one of R₅ₐ to R₇ₐ may each independently be a substituted or unsubstituted anthracene group, a substituted or unsubstituted pyrene group, a substituted or unsubstituted acenaphthyl group, or a substituted or unsubstituted acridine group; or at least one of R₅ₐ to R₇ₐ may each independently be substituted with a substituted or unsubstituted anthracene group, a substituted or unsubstituted pyrene group, a substituted or unsubstituted acenaphthyl group, or a substituted or unsubstituted acridine group. For example, at least one of R₅ₐ to R₇ₐ may each independently be an aryl group having 6 to 30 ring-forming carbons or a heteroaryl group having 2 to 30 ring-forming carbons, each substituted with a substituted or unsubstituted anthracene group, a substituted or unsubstituted pyrene group, a substituted or unsubstituted acenaphthyl group, or a substituted or unsubstituted acridine group.

In Formula 6-1 and Formula 6-2, of Rₐ and X₂ are the same as defined in Formula 1.

In an embodiment, the fused polycyclic compound represented by Formula 1 may be represented by Formula 7-1 or Formula 7-2:

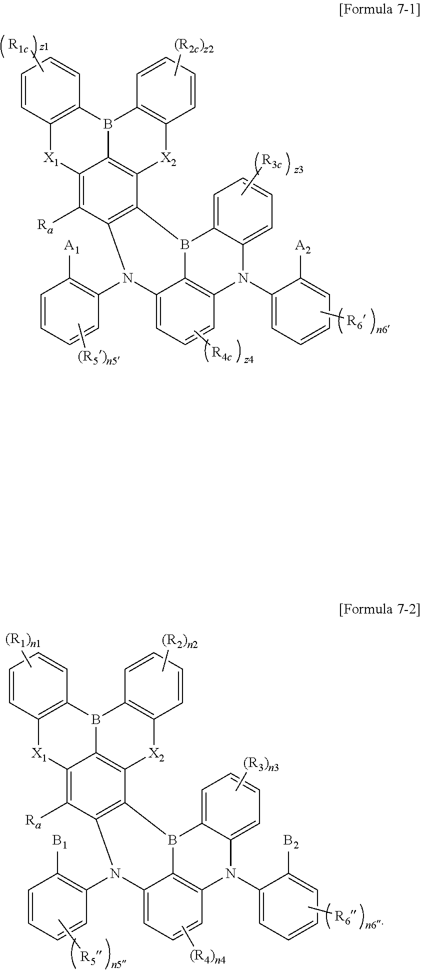

In Formula 7-1 and Formula 7-2, R_{1c} to R_{4c}, R₅′, R₆′, R₅″, and R₆″ may each independently be a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. For example, R_{1c} to R_{4c}, R₅′, R₆′, R₅″, and R₆″ may each independently be a hydrogen atom, a deuterium atom, a substituted or unsubstituted t-butyl group, a substituted or unsubstituted phenyl group, a substituted or unsubstituted biphenyl group, a substituted or unsubstituted indole group, a substituted or unsubstituted carbazole group, a substituted or unsubstituted anthracene group, a substituted or unsubstituted pyrene group, a substituted or unsubstituted acenaphthyl group, or a substituted or unsubstituted acridine group.

In Formula 7-1, z1 to z3 may each independently be an integer from 0 to 4. If z1 to z3 are each 0, the fused polycyclic compound may not be substituted with R_{1c} to R_{3c}, respectively. A case where z1 to z3 are each 4 and four of each of R_{1c} to R_{3c} are all hydrogen atoms may be the same as a case where z1 to z3 are each 0. If z1 to z3 are each 2 or greater, multiple groups of each of R_{1c} to R_{3c} may all be the same, or at least one thereof may be different from the remainder.

In Formula 7-1, z4 may be an integer from 0 to 3. If z4 is 0, the fused polycyclic compound may not be substituted with R_{4c}. A case where z4 is 3 and three R_{4c} are all hydrogen atoms may be the same as a case where z4 is 0. If z4 is 2 or greater, multiple R_{4c} may all be the same, or at least one thereof may be different from the remainder.

In Formula 7-1, n5′ and n6′ may each independently be an integer from 0 to 4. If n5′ and n6′ are each 0, the fused polycyclic compound may not be substituted with R₅′ and R₆′, respectively. A case where n5′ and n6′ are each 4 and four R₅′ and four R₆′ are all hydrogen atoms may be the same as a case where n5′ and n6′ are each 0. If n5′ and n6′ are each 2 or greater, multiple R₅′ and multiple R₆′ may all be the same, or at least one thereof may be different from the remainder.

In Formula 7-2, n5″ and n6″ may each independently be an integer from 0 to 4. If n5″ and n6″ are each 0, the fused polycyclic compound may not be substituted with R₅″ and R₆″, respectively. A case where n5″ and n6″ are each 4 and four R₅″ and four R₆″ are all hydrogen atoms may be the same as a case where n5′ and n6′ are each 0. If n5″ and n6″ are each 2 or greater, multiple R₅″ and multiple R₆″ may all be the same, or at least one thereof may be different from the remainder.

In Formula 7-1, at least one of R_{1c} to R_{4c} may each independently be a group represented by Formula 3-1 or Formula 3-2.

In an embodiment, in Formula 7-1, at least one of R_{1c} to R_{4c} may each independently be a group represented by one of Formula 4-1 to Formula 4-5.

In Formula 7-1, A₁ and A₂ may each independently be a substituted or unsubstituted aryl group having 6 to 30 ring-forming carbons or a substituted or unsubstituted heteroaryl group having 2 to 30 ring-forming carbons. For example, A₁ and A₂ may each independently be a substituted or unsubstituted phenyl group.

In Formula 7-2, at least one of B₁ and B₂ may each independently be a group represented by Formula 3-1 or Formula 3-2; and the remainder of B₁ and B₂ may be a substituted or unsubstituted aryl group having 6 to 30 ring-forming carbons or a substituted or unsubstituted heteroaryl group having 2 to 30 ring-forming carbons. For example, one of B₁ and B₂ may be a group represented by Formula 3-1 or Formula 3-2, and the other of B₁ and B₂ may be a substituted or unsubstituted phenyl group. As another example, B₁ and B₂ may each independently be a group represented by Formula 3-1 or Formula 3-2.

In an embodiment, at least one of B₁ and B₂ may each independently be a group represented by one of Formula 4-1 to Formula 4-5; and the remainder of B₁ and B₂ may be a substituted or unsubstituted aryl group having 6 to 30 ring-forming carbons or a substituted or unsubstituted heteroaryl group having 2 to 30 ring-forming carbons. For example, one of B₁ and B₂ may be a group represented by one of Formula 4-1 to Formula 4-5; and the other of B₁ and B₂ may be a substituted or unsubstituted phenyl group. As another example, B₁ and B₂ may each independently be a group represented by one of Formula 4-1 to Formula 4-5.

In Formula 7-1 and Formula 7-2, X₁, X₂, Rₐ, R₁ to R₄, and n1 to n4 are the same as defined in Formula 1.

In an embodiment, the fused polycyclic compound represented by Formula 1 may be represented by one of Formula 8-1 to Formula 8-3:

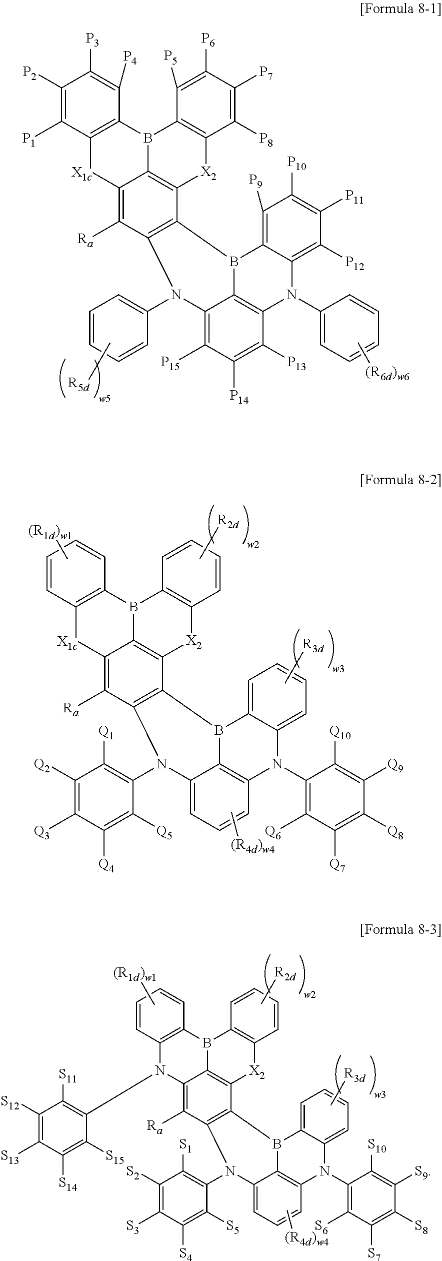

In Formula 8-1 and Formula 8-2, X_{1c} may be O, S, or Se. For example, X_{1c} may be O.

In Formula 8-1 to Formula 8-3, R_{1d} to R_{6d} may each independently be a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. For example, R_{1d} to R_{6d} may each independently be a hydrogen atom, a substituted or unsubstituted t-butyl group, or a substituted or unsubstituted phenyl group.

In Formula 8-2 and Formula 8-3, w1 to w3 may each independently be an integer from 0 to 4. If w1 to w3 are each 0, the fused polycyclic compound may not be substituted with R_{1d} to R_{3d}, respectively. A case where w1 to w3 are each 4 and four of each of R_{1d} to R_{3d} are all hydrogen atoms may be the same as a case where w1 to w3 are each 0. If w1 to w3 are each 2 or greater, multiple groups of each of R_{1d} to R_{3d} may all be the same, or at least one thereof may be different from the remainder.

In Formula 8-2 and Formula 8-3, w4 may be an integer from 0 to 3. If w4 is 0, the fused polycyclic compound may not be substituted with R_{4d}. A case where w4 is 3 and three R_{4d} are all hydrogen atoms may be the same as a case where w4 is 0. If w4 is 2 or greater, multiple R_{4d} may all be the same, or at least one thereof may be different from the remainder.

In Formula 8-1, w5 and w6 may each independently be an integer from 0 to 5. If w5 and w6 are each 0, the fused polycyclic compound may not be substituted with R_{5d} and R_{6d}, respectively. A case where w5 and w6 are each 5 and five R_{5d} and five R_{6d} are all hydrogen atoms may be the same as a case where w5 and w6 are each 0. If w5 and w6 are each 2 or greater, multiple R_{5d} and multiple R_{6d} may all be the same, or at least one thereof may be different from the remainder.

In Formula 8-1, at least one of P₁ to P₁₅ may each independently be a group represented by one of Formula 4-1 to Formula 4-5; and the remainder of P₁ to P₁₅ may each independently be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

In an embodiment, at least one of P₁ to P₁₅ may each independently be a group represented by one of Formula 4-1 to Formula 4-5; and the remainder of P₁ to P₁₅ may each independently be a hydrogen atom, a deuterium atom, a substituted or unsubstituted t-butyl group, a substituted or unsubstituted phenyl group, a substituted or unsubstituted biphenyl group, or a substituted or unsubstituted carbazole group.

In Formula 8-2, at least one of Q₁ to Q₁₀ may each independently be a group represented by one of Formula 4-1 to Formula 4-5; and the remainder of Q₁ to Q₁₀ may each independently be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

In an embodiment, at least one of Q₁ to Q₁₀ may each independently be a group represented by one of Formula 4-1 to Formula 4-5; and the remainder of Q₁ to Q₁₀ may each independently be a hydrogen atom, a deuterium atom, a substituted or unsubstituted t-butyl group, a substituted or unsubstituted phenyl group, a substituted or unsubstituted biphenyl group, or a substituted or unsubstituted carbazole group.

In Formula 8-3, at least one of S₁ to S₁₅ may each independently be a group represented by one of Formula 4-1 to Formula 4-5; and the remainder of S₁ to S₁₅ may each independently be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

In an embodiment, at least one of S₁ to S₁₅ may each independently be a group represented by one of Formula 4-1 to Formula 4-5; and the remainder of S₁ to S₁₅ may each independently be a hydrogen atom, a deuterium atom, a substituted or unsubstituted t-butyl group, a substituted or unsubstituted phenyl group, a substituted or unsubstituted biphenyl group, or a substituted or unsubstituted carbazole group.

In Formula 8-1 to Formula 8-3, Rₐ and X₂ are the same as defined in Formula 1.

The fused polycyclic compound according to an embodiment may include at least one of a second sub substituent and a third sub substituent. The second sub substituent may be connected to the sixth benzene ring, which is connected to the first nitrogen atom. The second sub substituent may be connected to the sixth benzene ring at an ortho position with respect to the first nitrogen atom. The third sub substituent may be connected to the seventh benzene ring, which is connected to the second nitrogen atom. The third sub substituent may be connected to the seventh benzene ring at an ortho position with respect to the second nitrogen atom. In an embodiment, the second sub substituent and the third sub substituent may be each independently a substituted or unsubstituted aryl group having 6 to 30 ring-forming carbons or a substituted or unsubstituted heteroaryl group having 2 to 30 ring-forming carbons.

In the fused polycyclic compound according to an embodiment, a trigonal planar structure of the first boron atom may be effectively maintained due to steric hindrance caused by the second and third sub substituents. The first boron atom has an electron deficiency due to an unoccupied p-orbital and thus may convert to a tetrahedral configuration by interacting with other nucleophiles, which may lead to deterioration of the element. According to embodiments, in the fused polycyclic compound, since the second sub substituent and the third sub substituent are bonded to the fused ring core, an unoccupied p-orbital of the first boron atom may be effectively protected, and thus deterioration of the light-emitting element caused by structural deformation of the first boron atom may be prevented. In the fused polycyclic compound according to an embodiment, since intermolecular interactions are inhibited due to steric hindrance caused by the second and third sub substituents, the formation of aggregates, excimers, and exciplexes may be controlled, thereby improving luminous efficiency. Therefore, when the fused polycyclic compound according to an embodiment is included in the emission layer EML of the light-emitting element ED, luminous efficiency and element lifespan may be further improved.

In an embodiment, the fused polycyclic compound represented by Formula 1 may be represented by Formula 9. In Formula 9, E₁ may correspond to the above-described second sub substituent, and E₂ may correspond to the above-described third sub substituent.

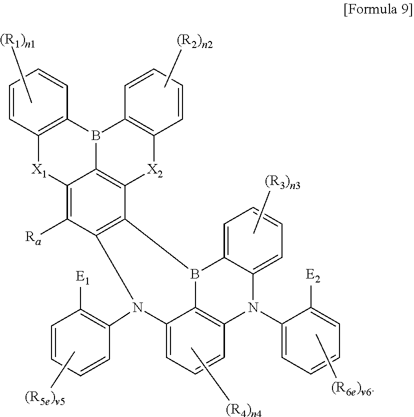

In Formula 9, E₁ and E₂ may each independently be a substituted or unsubstituted aryl group having 6 to 30 ring-forming carbons or a substituted or unsubstituted heteroaryl group having 2 to 30 ring-forming carbons.

In Formula 9, R₅ₑ and R₆ₑ may each independently be a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. For example, R₅ₑ and R₆ₑ may each independently be a hydrogen atom, a deuterium atom, a substituted or unsubstituted t-butyl group, a substituted or unsubstituted phenyl group, a substituted or unsubstituted biphenyl group, a substituted or unsubstituted indole group, a substituted or unsubstituted carbazole group, a substituted or unsubstituted anthracene group, a substituted or unsubstituted pyrene group, a substituted or unsubstituted acenaphthyl group, or a substituted or unsubstituted acridine group.

In Formula 9, v5 and v6 may each independently be an integer from 0 to 4. If v5 and v6 are each 0, the fused polycyclic compound may not be substituted with R₅ₑ and R₆ₑ, respectively. A case where v5 and v6 are each 4 and four R₅ₑ and four R₆ₑ are all hydrogen atoms may be the same as a case where v5 and v6 are each 0. If v5 and v6 are each 2 or greater, multiple R₅ₑ and multiple R₆ₑ may all be the same, or at least one thereof may be different from the remainder.

In Formula 9, at least one of R₁ to R₄, R₅ₑ, R₆ₑ, and R₇ may each independently include a substituted or unsubstituted anthracene group, a substituted or unsubstituted pyrene group, a substituted or unsubstituted acenaphthyl group, or a substituted or unsubstituted acridine group. For example, in Formula 9, if X₁ is a moiety represented by Formula 2, at least one of R₁ to R₄, R₅ₑ, R₆ₑ, and R₇ may each independently include a substituted or unsubstituted anthracene group, a substituted or unsubstituted pyrene group, a substituted or unsubstituted acenaphthyl group, or a substituted or unsubstituted acridine group. As another example, in Formula 9, if X₁ is O, S, or Se, at least one of R₁ to R₄, R₅ₑ, and R₆ₑ may each independently include a substituted or unsubstituted anthracene group, a substituted or unsubstituted pyrene group, a substituted or unsubstituted acenaphthyl group, or a substituted or unsubstituted acridine group.

In an embodiment, in Formula 9, at least one of R₁ to R₄, R₅ₑ, R₆ₑ, and R₇ may each independently be a substituted or unsubstituted anthracene group, a substituted or unsubstituted pyrene group, a substituted or unsubstituted acenaphthyl group, or a substituted or unsubstituted acridine group; or at least one of R₁ to R₄, R₅ₑ, R₆ₑ, and R₇ may each independently be substituted with a substituted or unsubstituted anthracene group, a substituted or unsubstituted pyrene group, a substituted or unsubstituted acenaphthyl group, or a substituted or unsubstituted acridine group. For example, R₁ to R₄, R₅ₑ, R₆ₑ, and R₇ may each independently be an aryl group having 6 to 30 ring-forming carbons or a heteroaryl group having 2 to 30 ring-forming carbons, each substituted with a substituted or unsubstituted anthracene group, a substituted or unsubstituted pyrene group, a substituted or unsubstituted acenaphthyl group, or a substituted or unsubstituted acridine group.

In Formula 9, Rₐ, R₁ to R₄, n1 to n4, X₁, and X₂ are the same as defined in Formula 1.

In an embodiment, the fused polycyclic compound according to an embodiment may include at least one deuterium atom as a substituent. For example, in the fused polycyclic compound according to an embodiment, at least one hydrogen atom may be substituted with a deuterium atom.

In an embodiment, the fused polycyclic compound represented by Formula 1 may be any compound selected from Compound Group 1. In an embodiment, in the light-emitting element ED, at least one functional layer may include at least one compound selected from Compound Group 1. In an embodiment, in the light-emitting element ED, the first compound may include at least one compound selected from Compound Group 1:

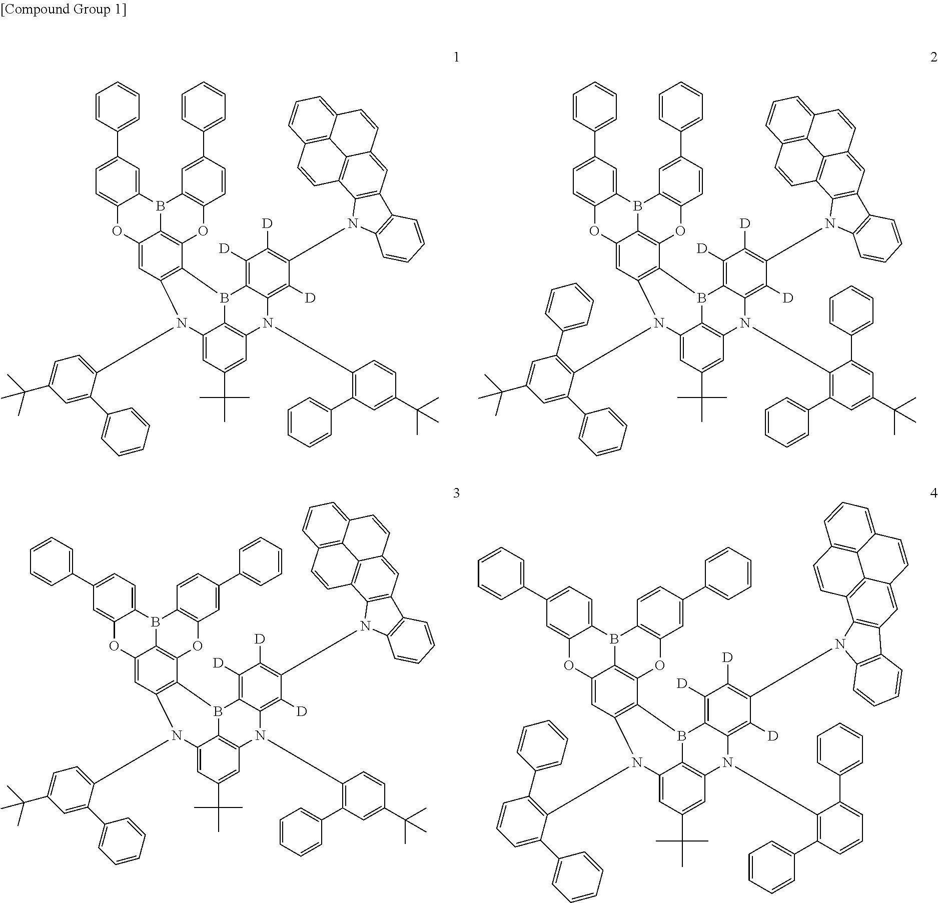

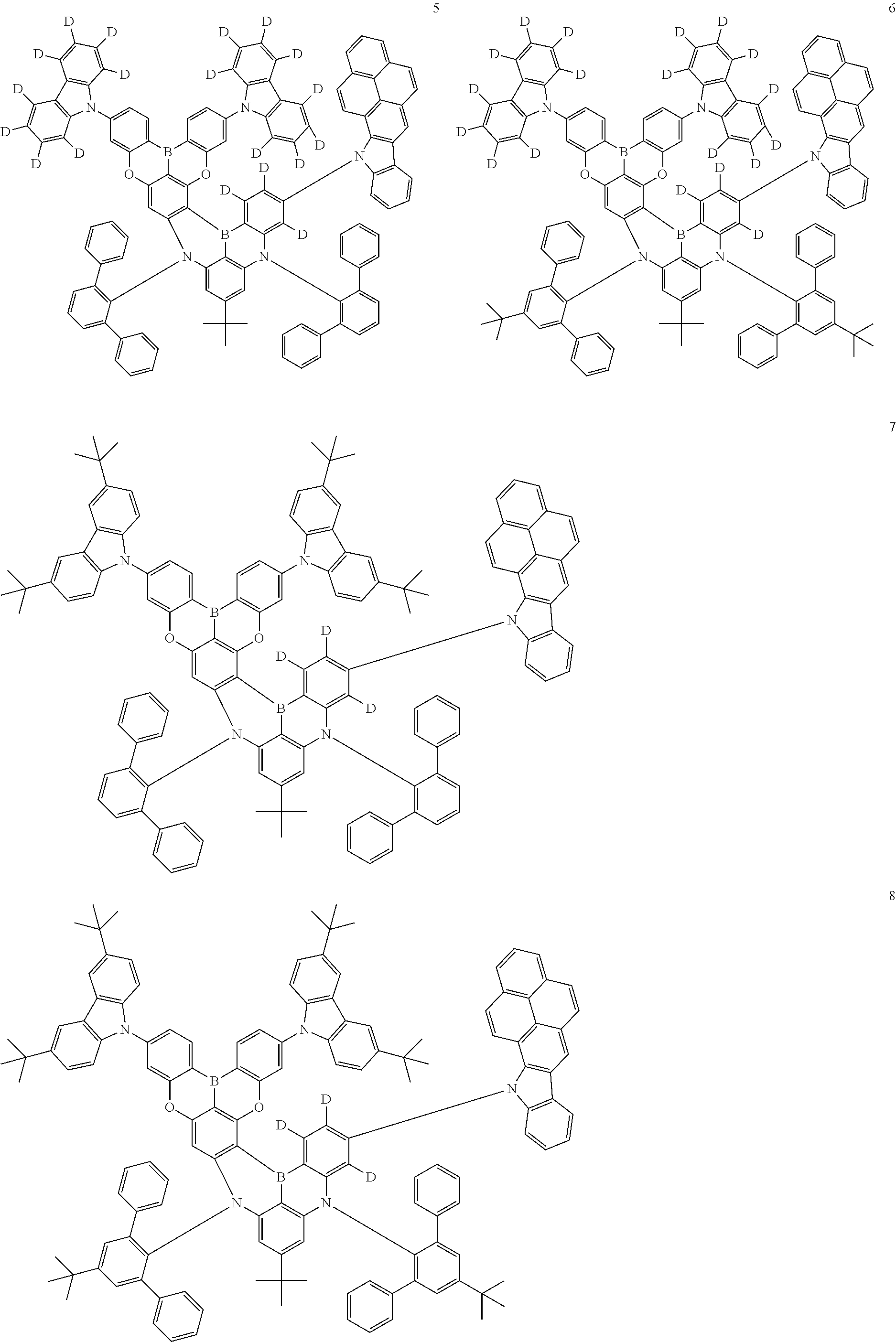

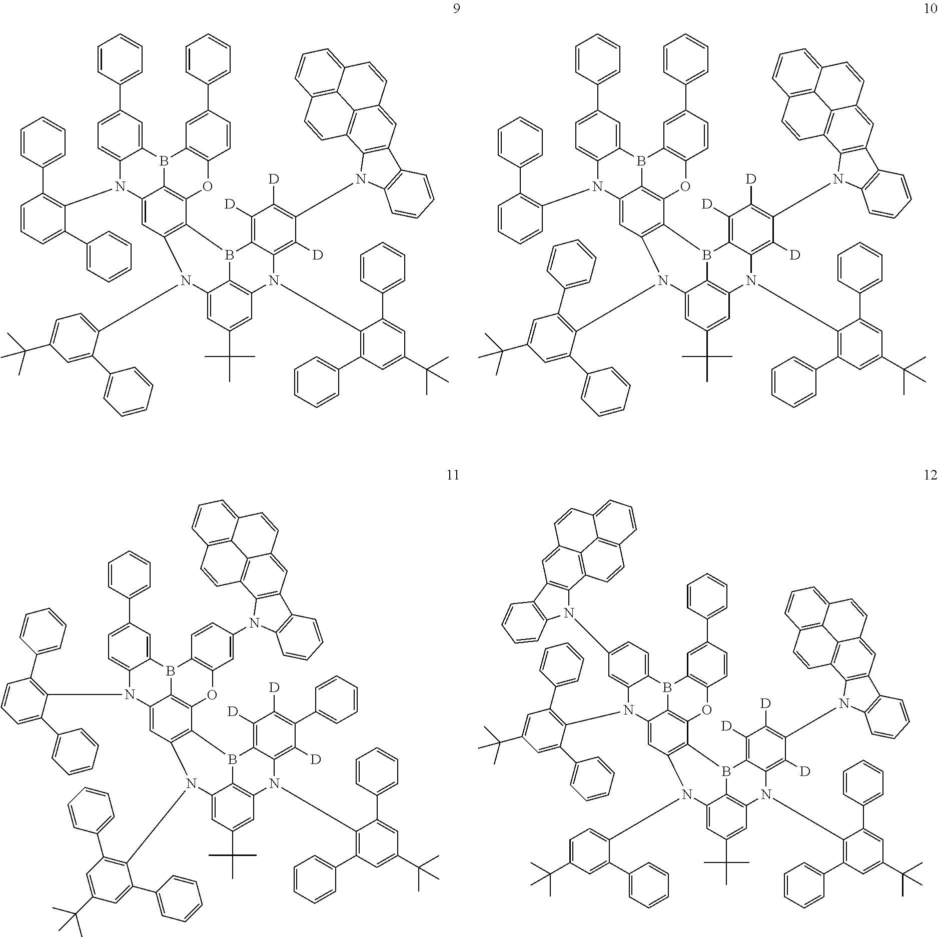

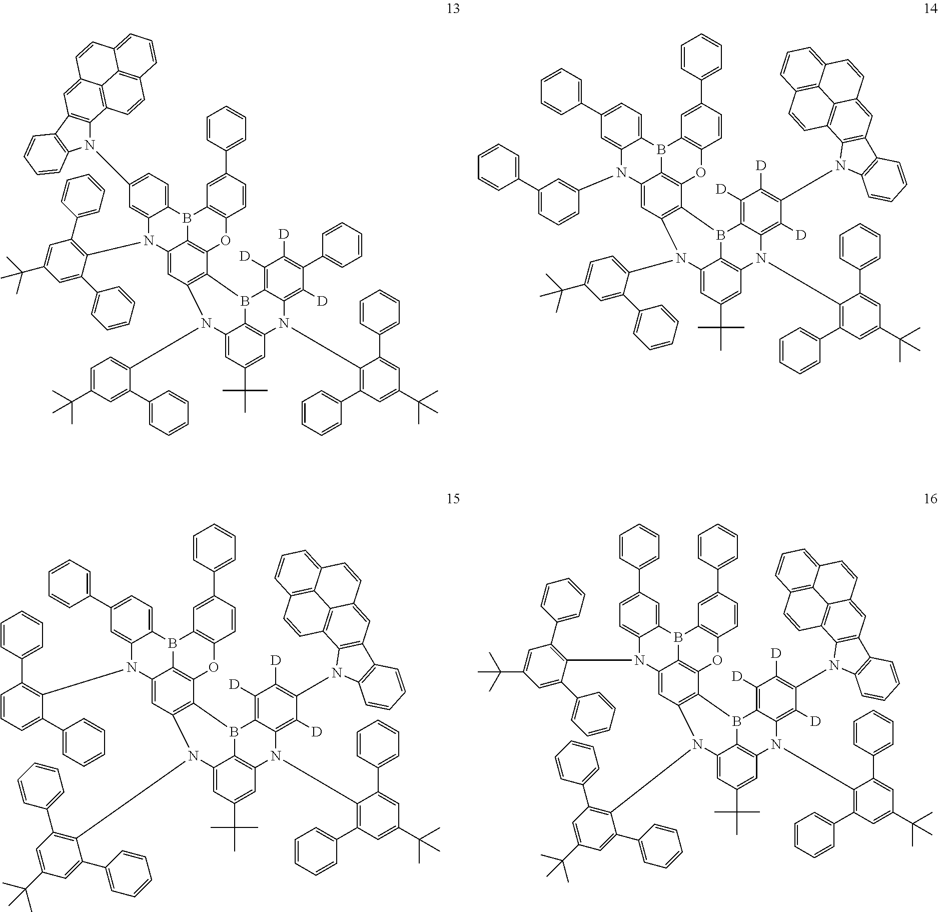

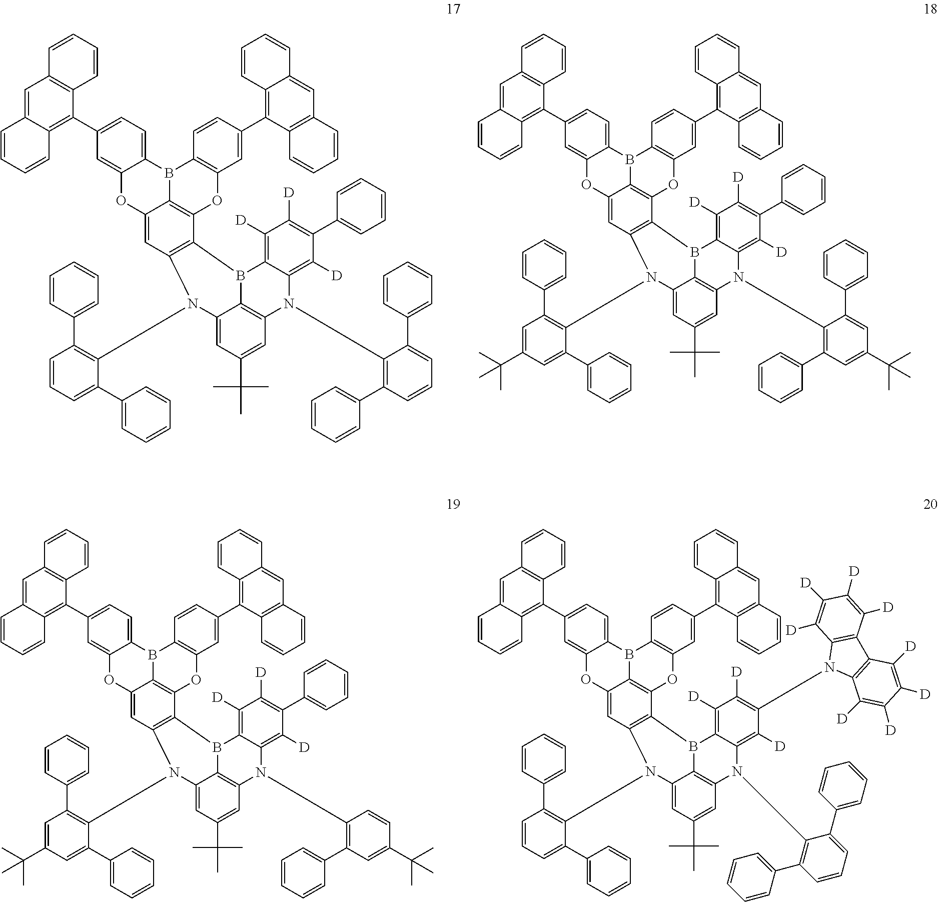

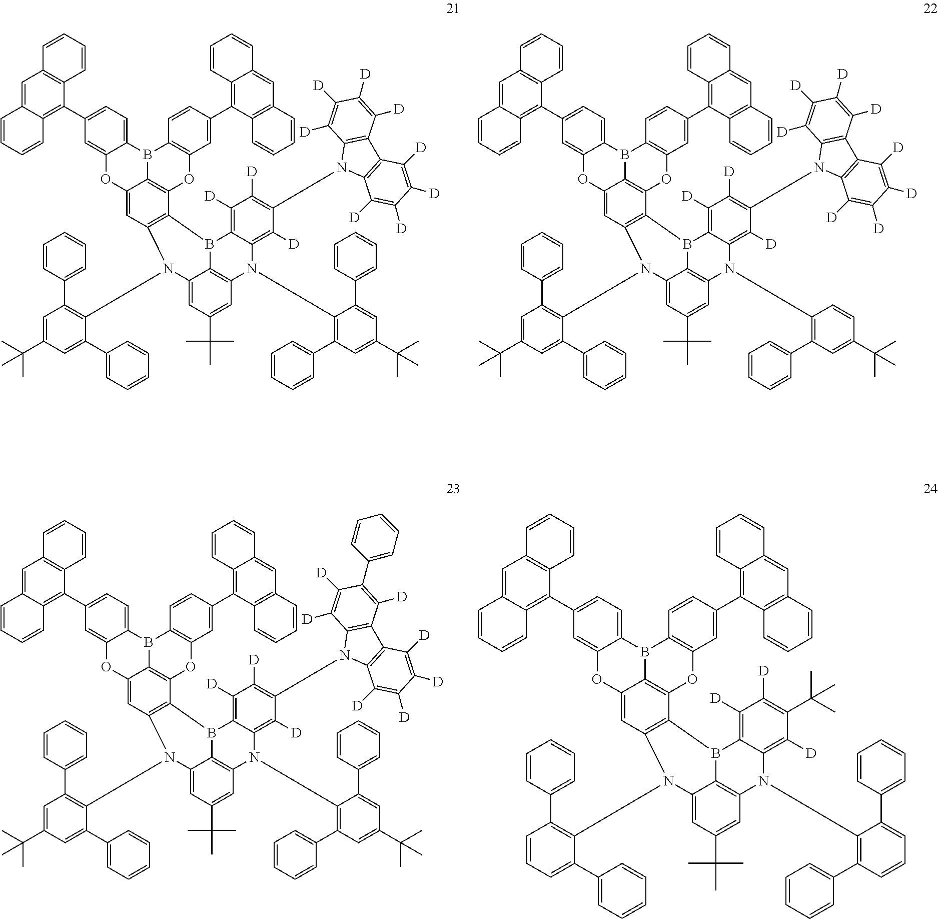

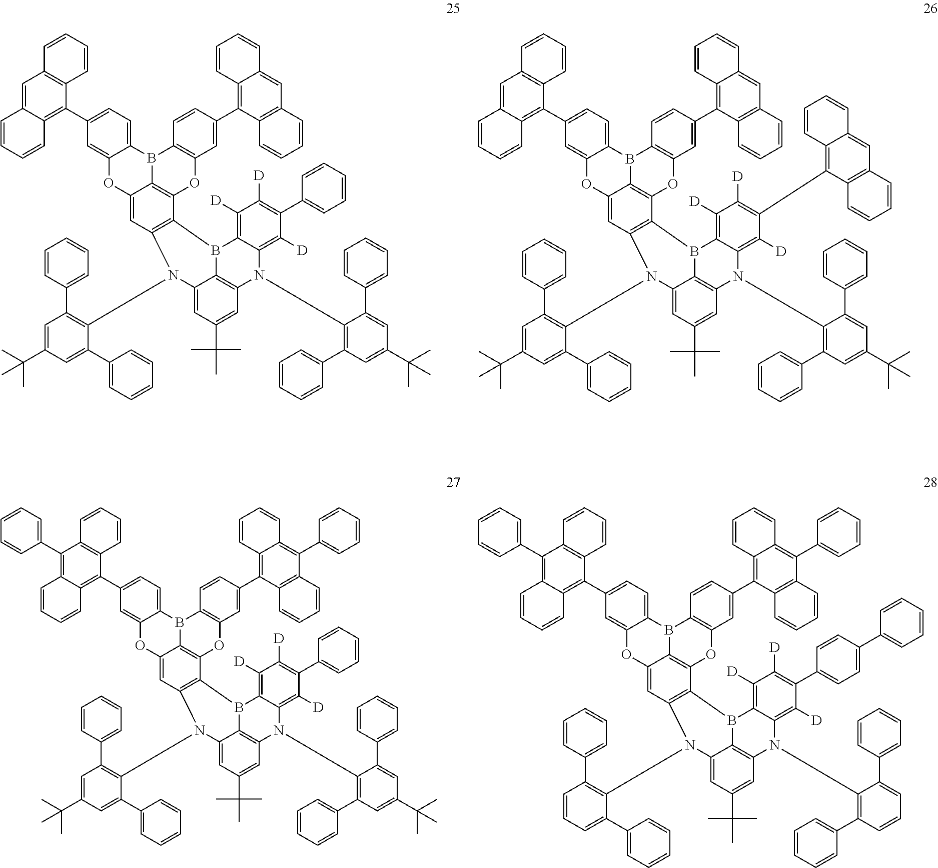

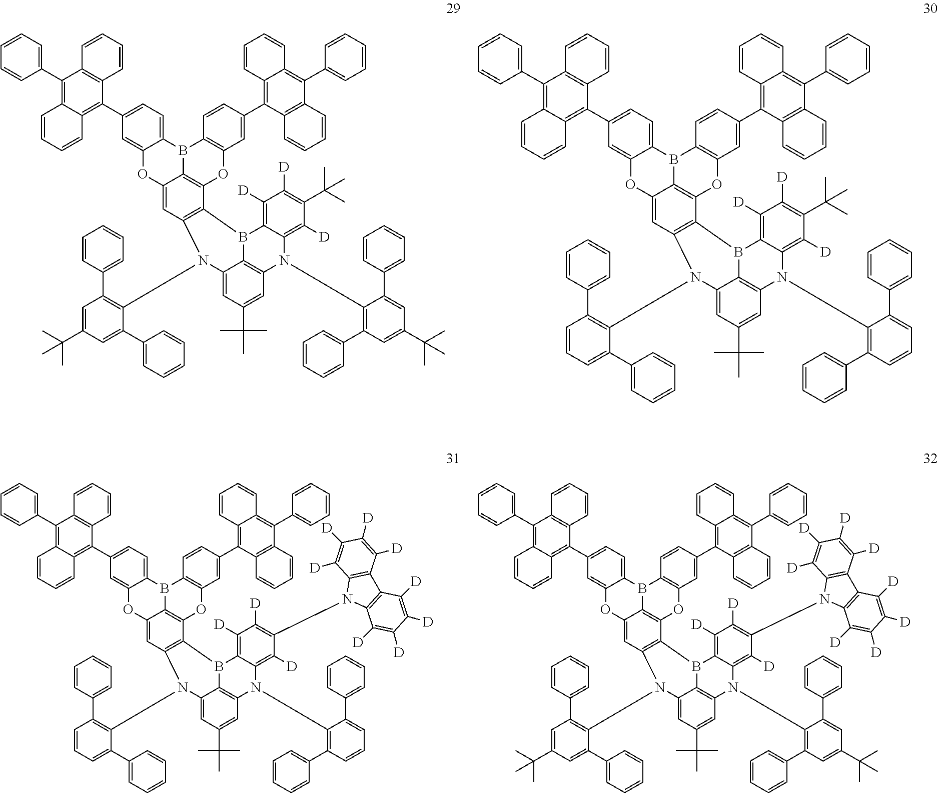

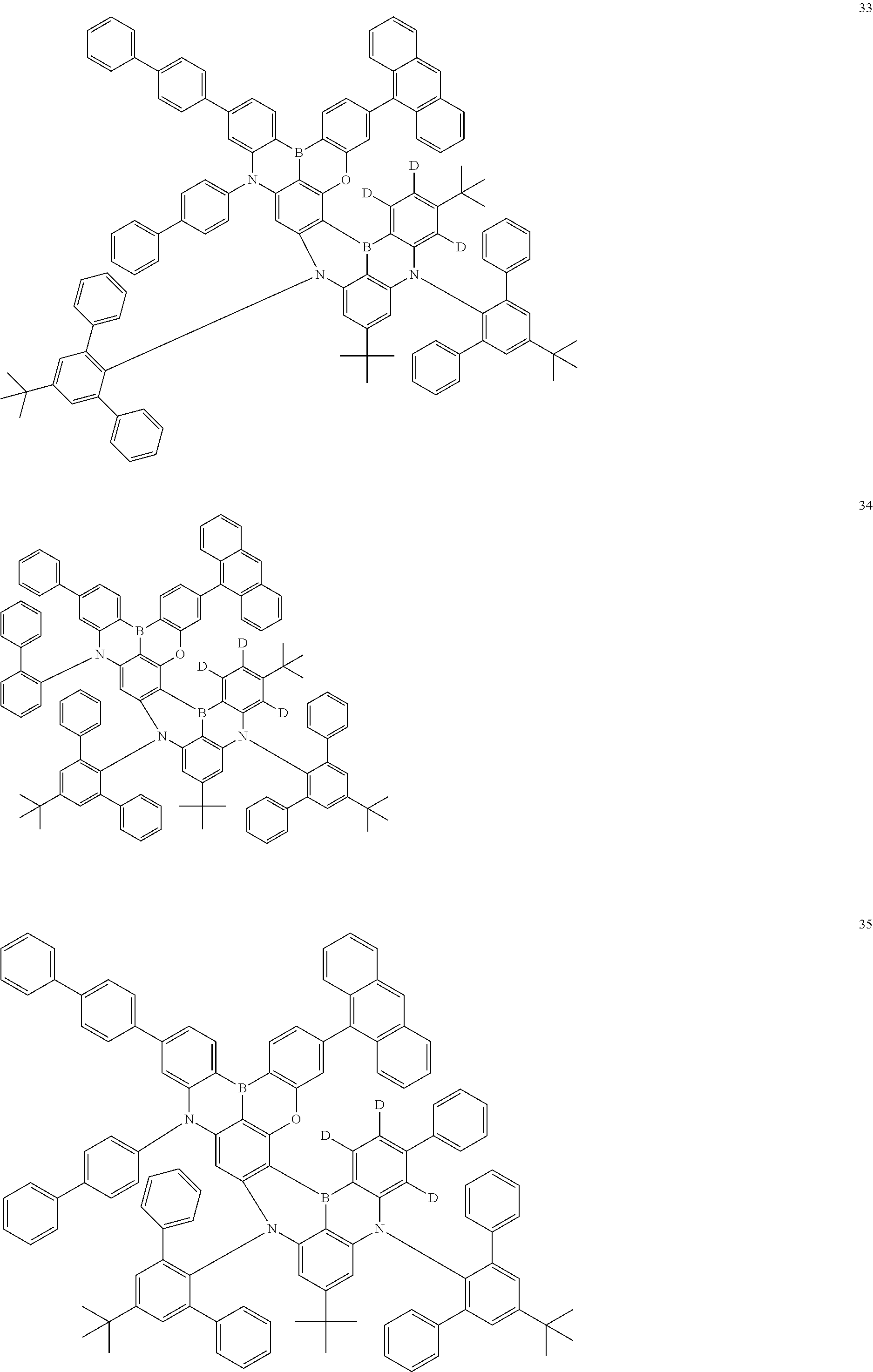

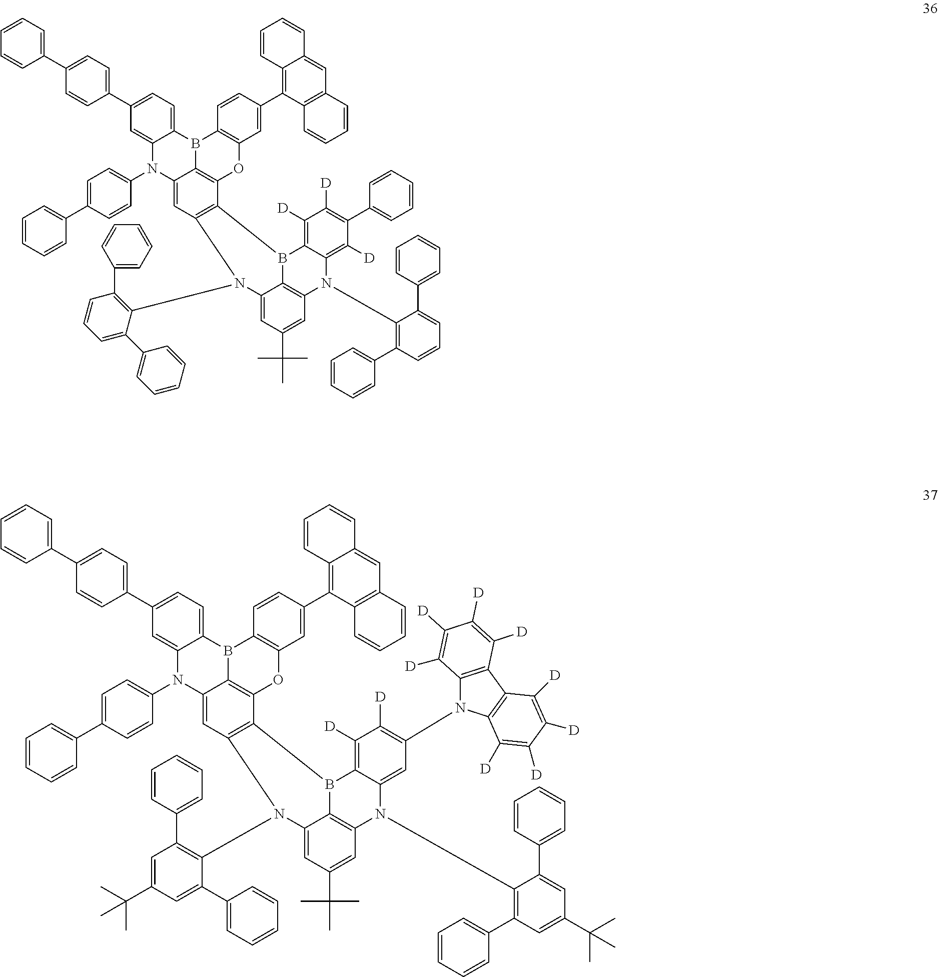

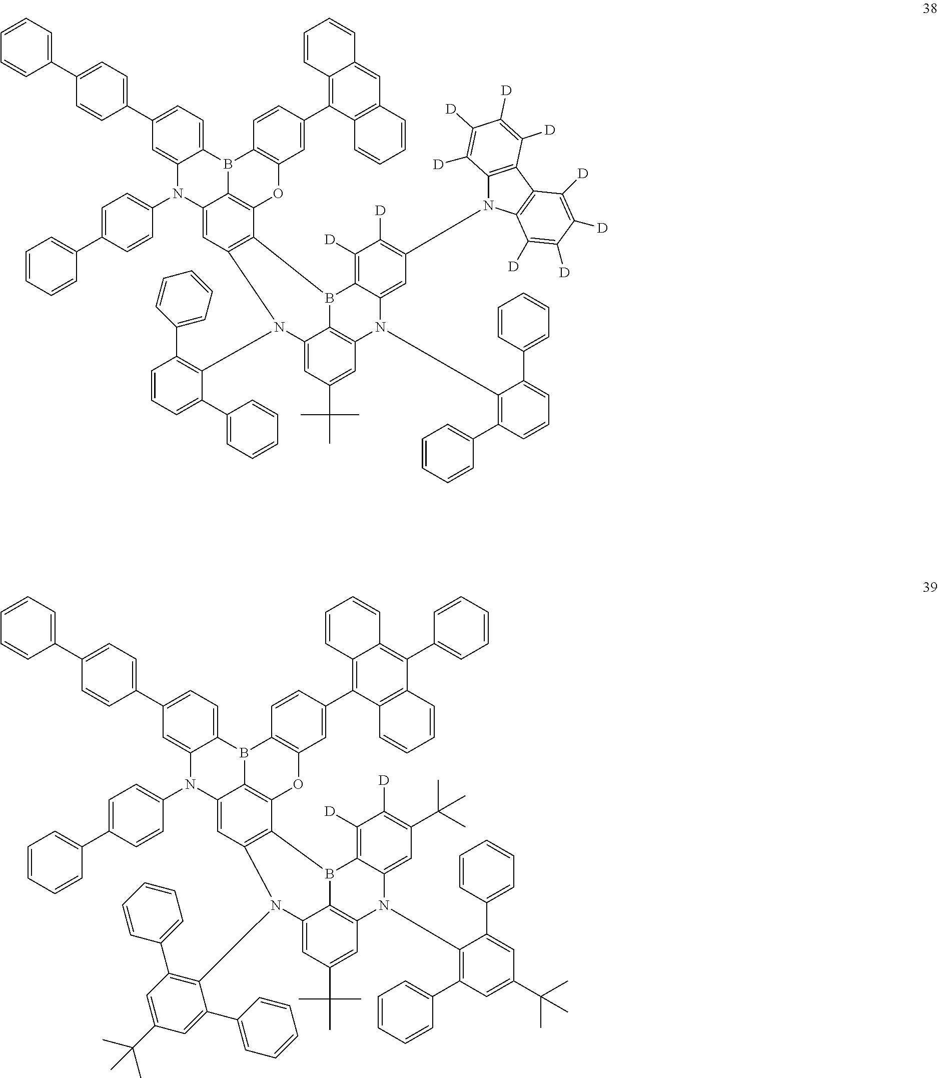

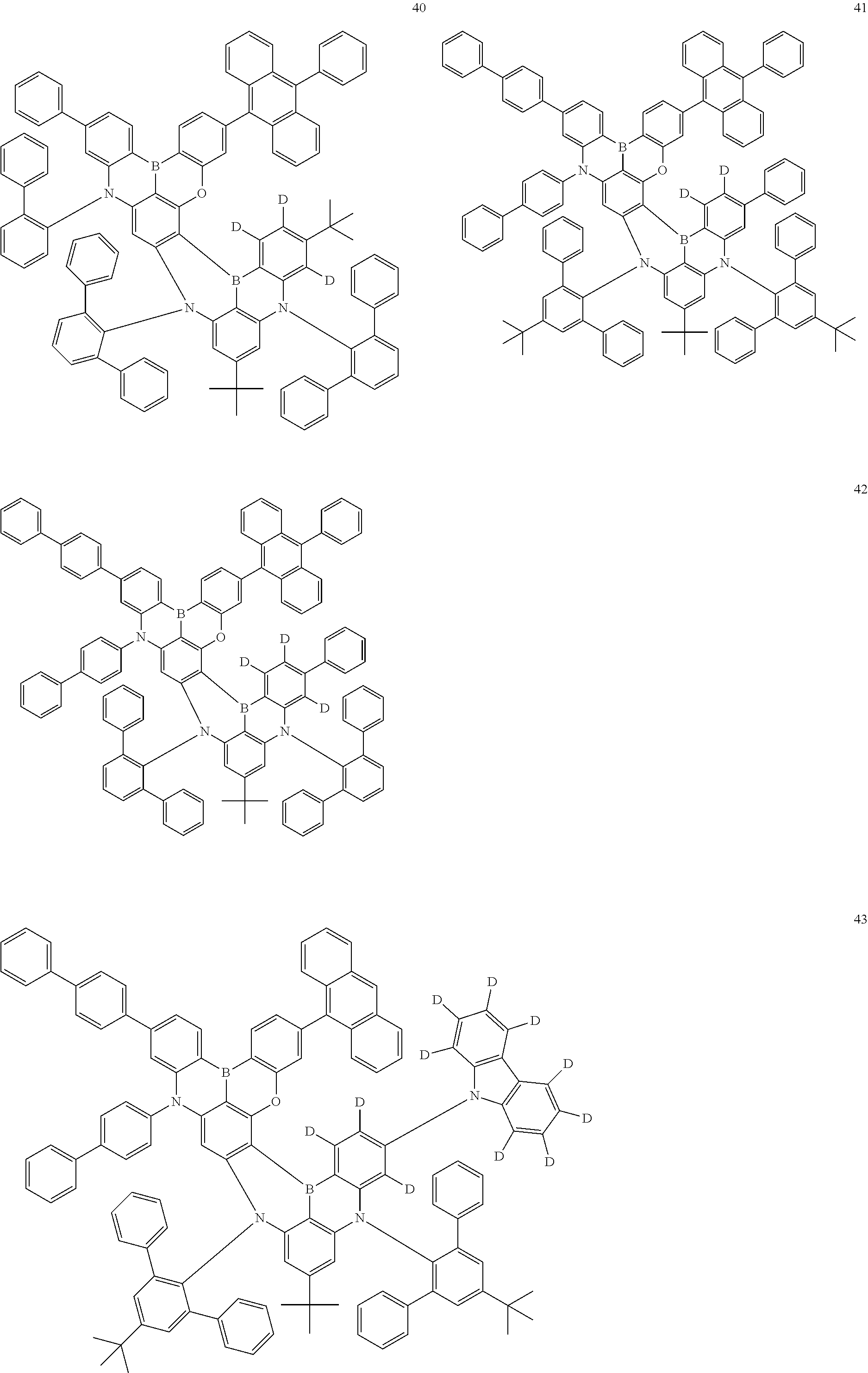

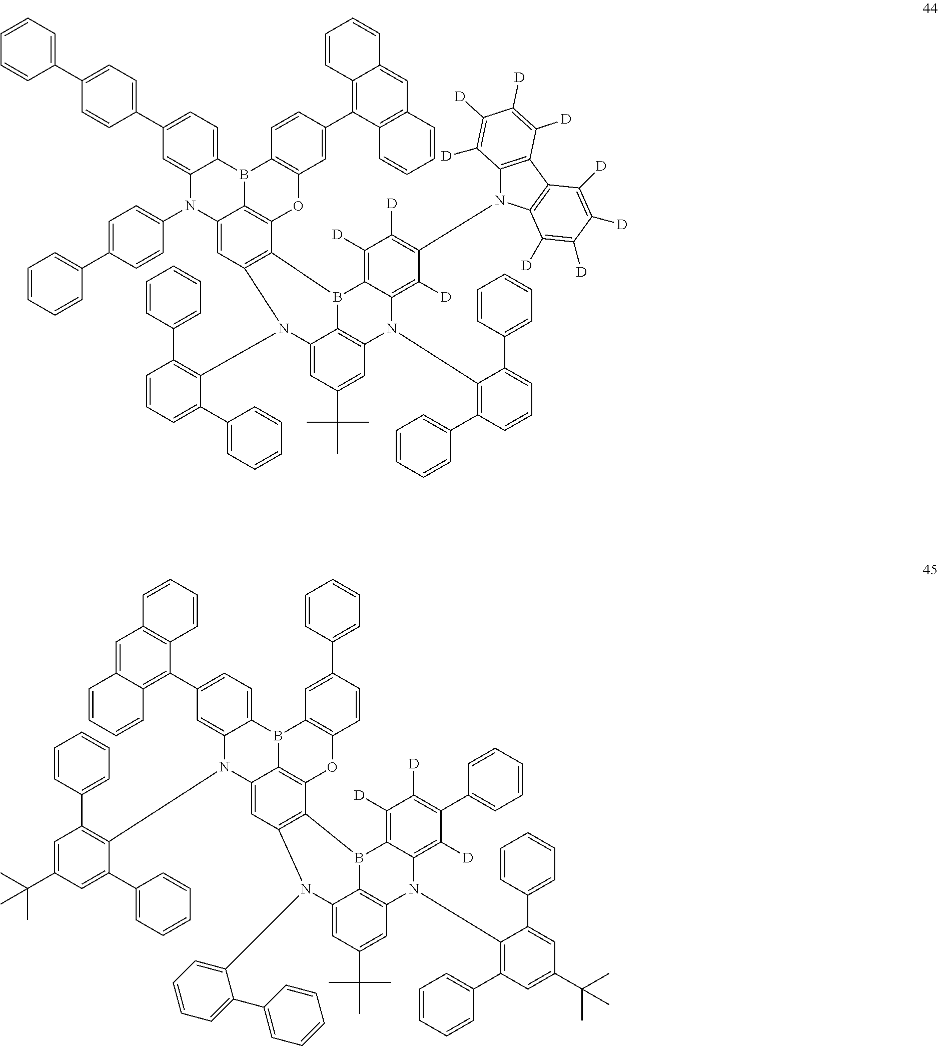

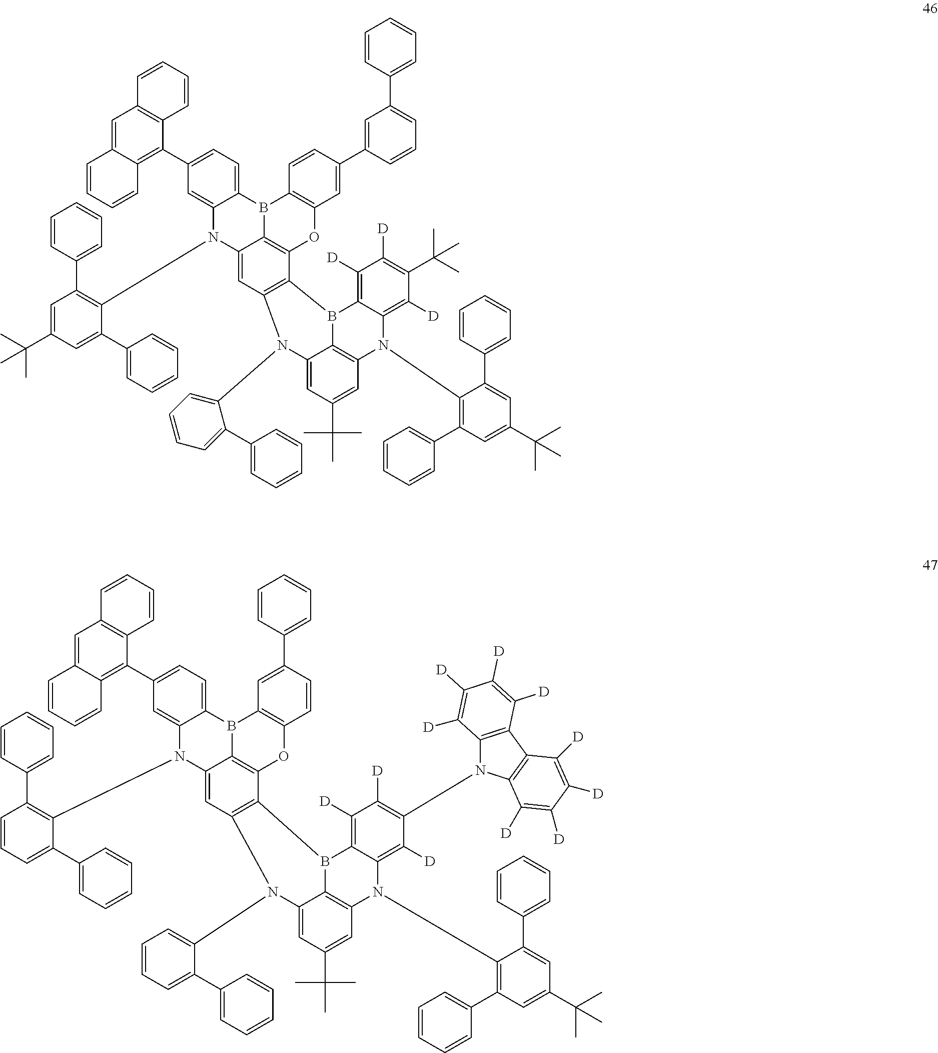

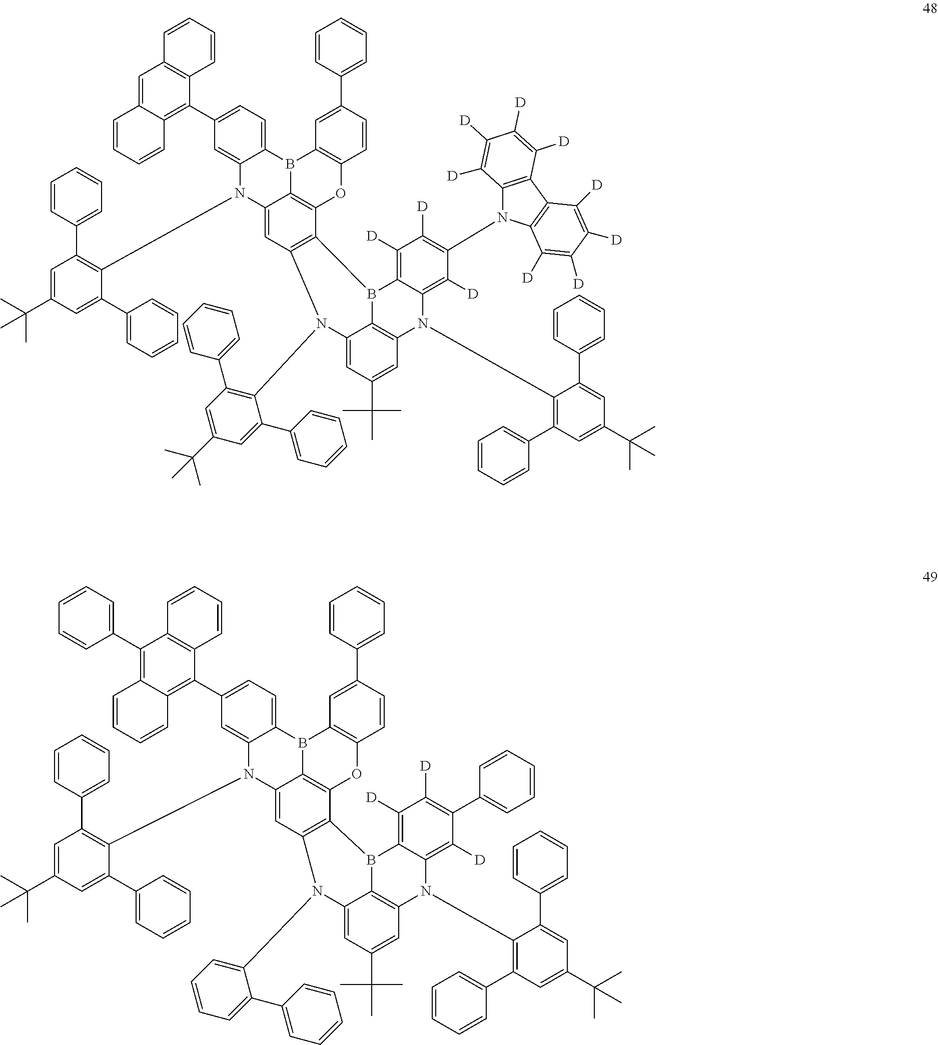

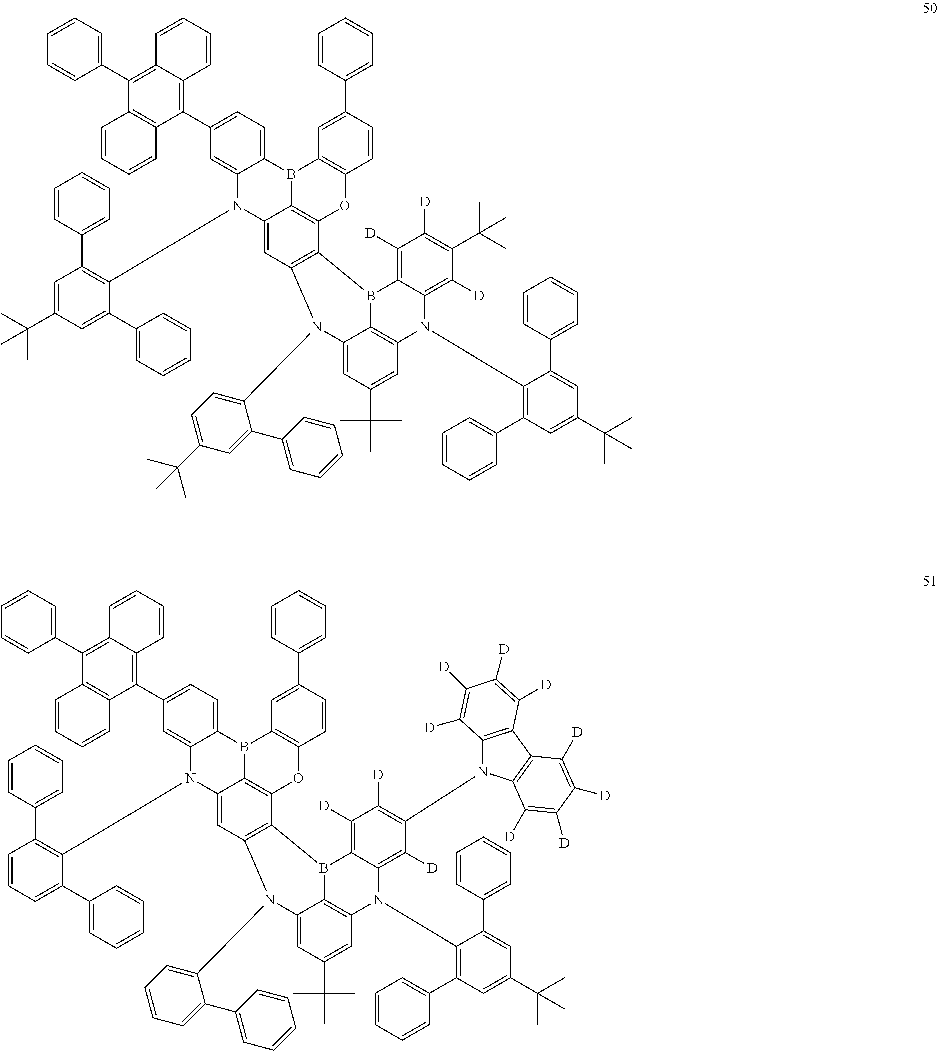

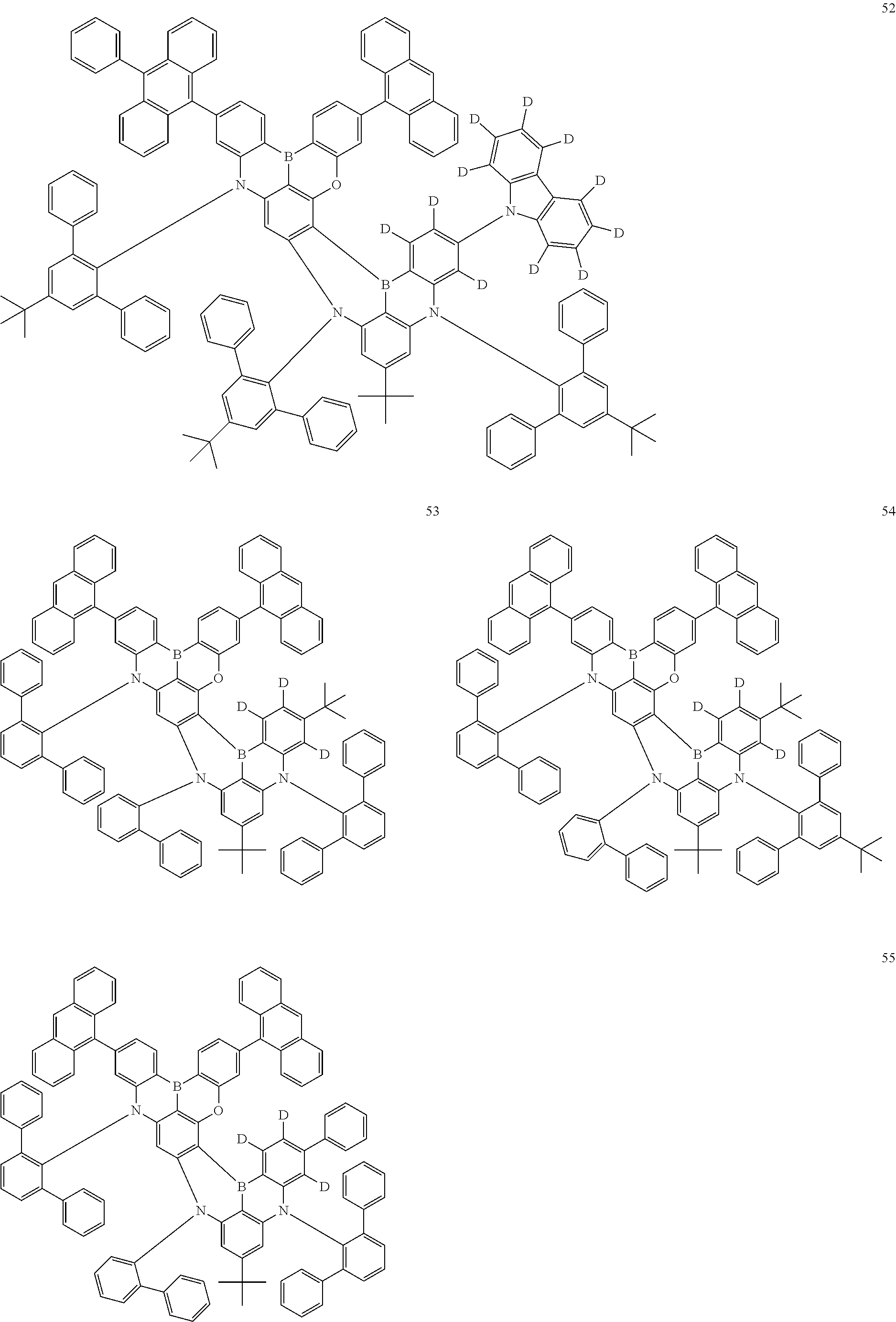

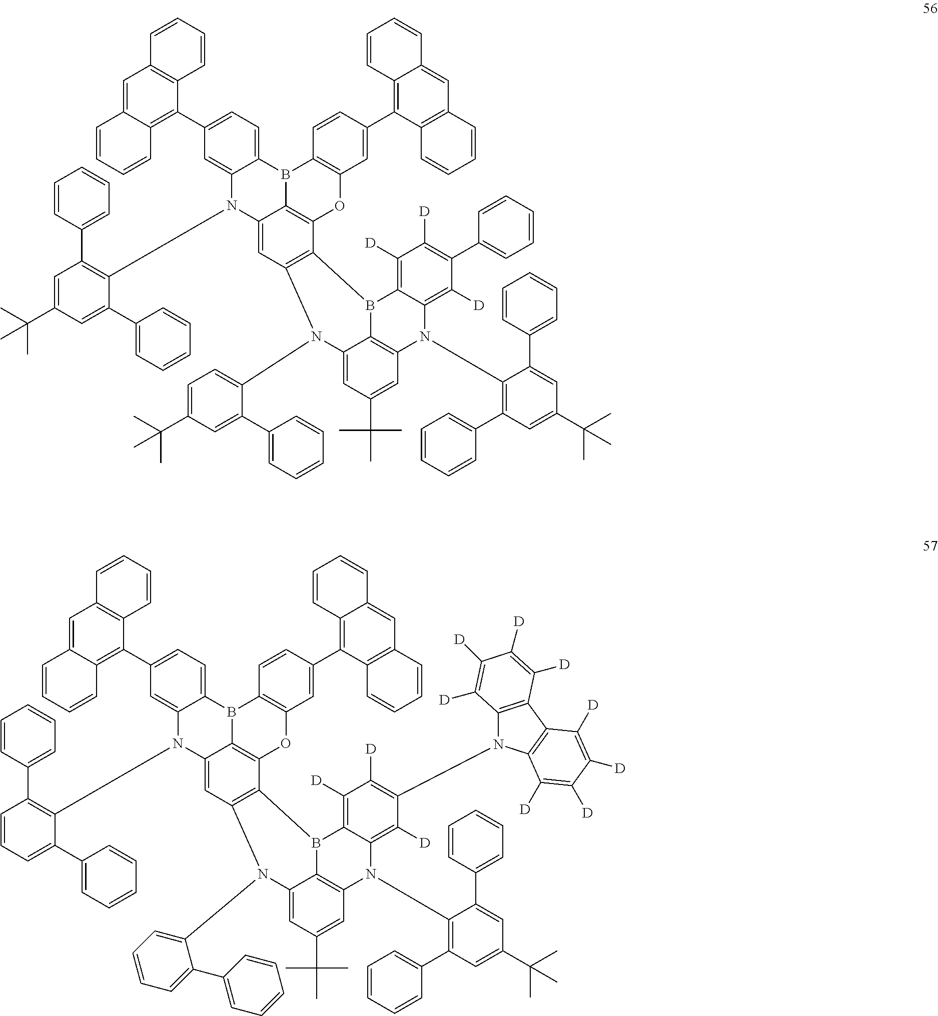

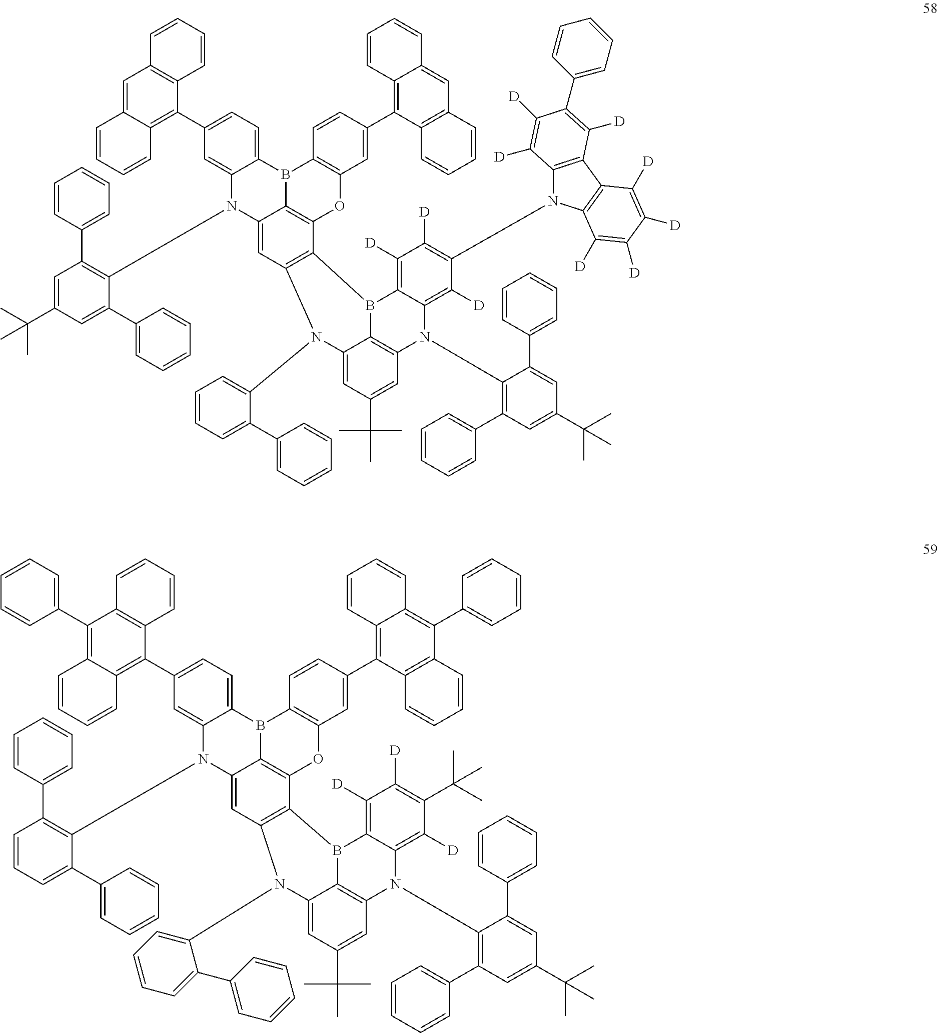

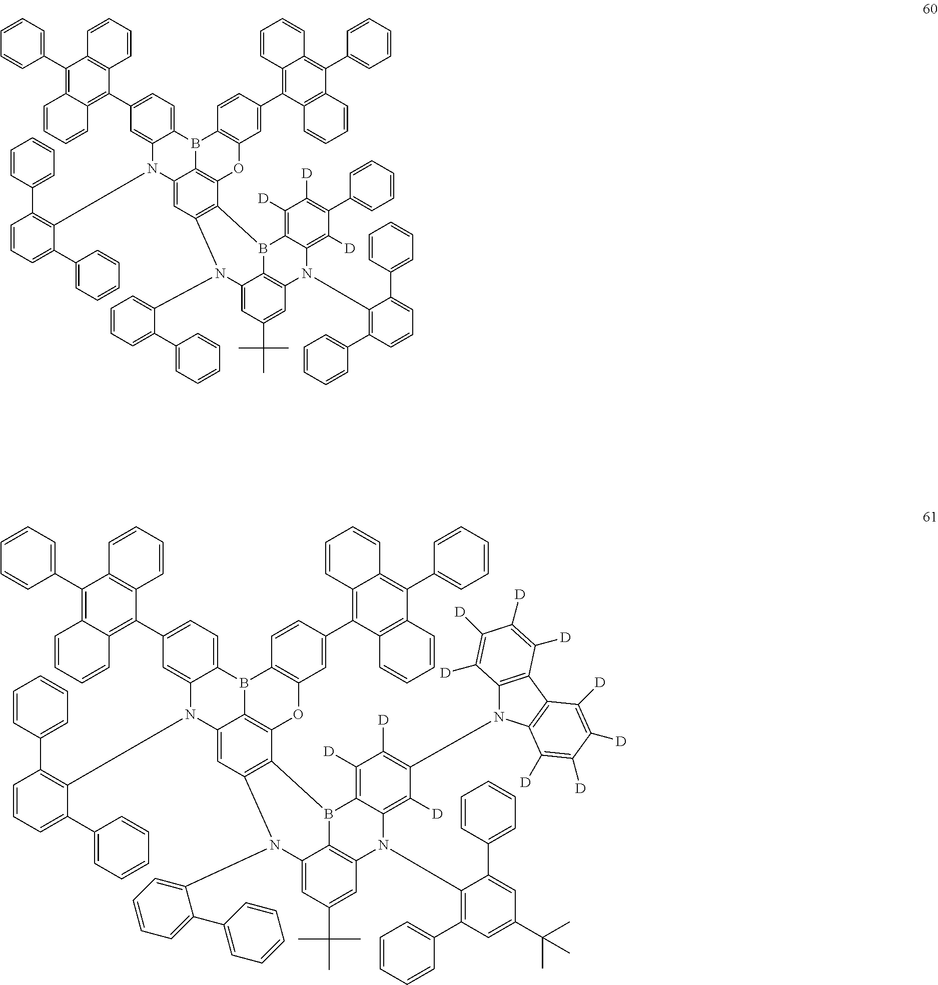

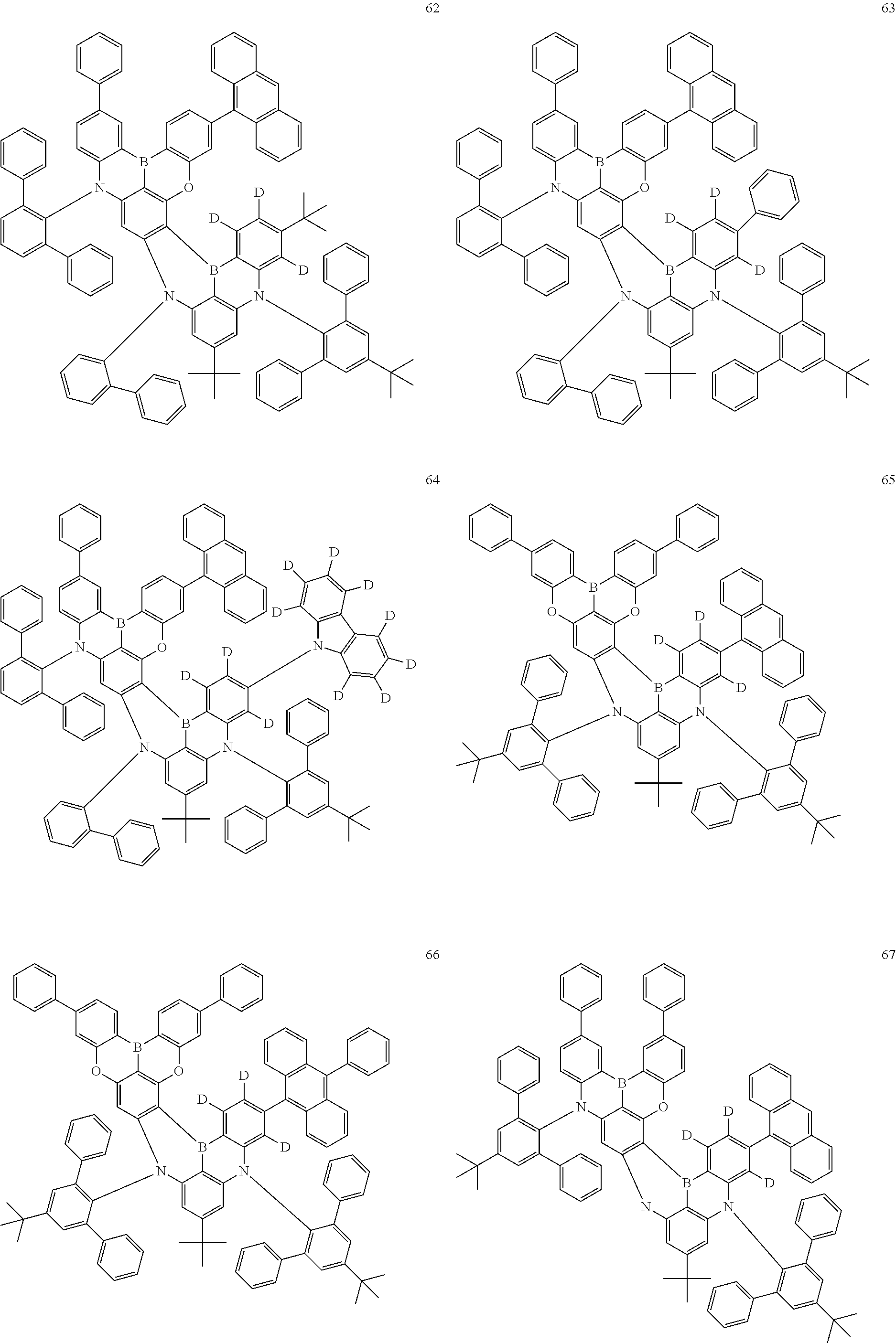

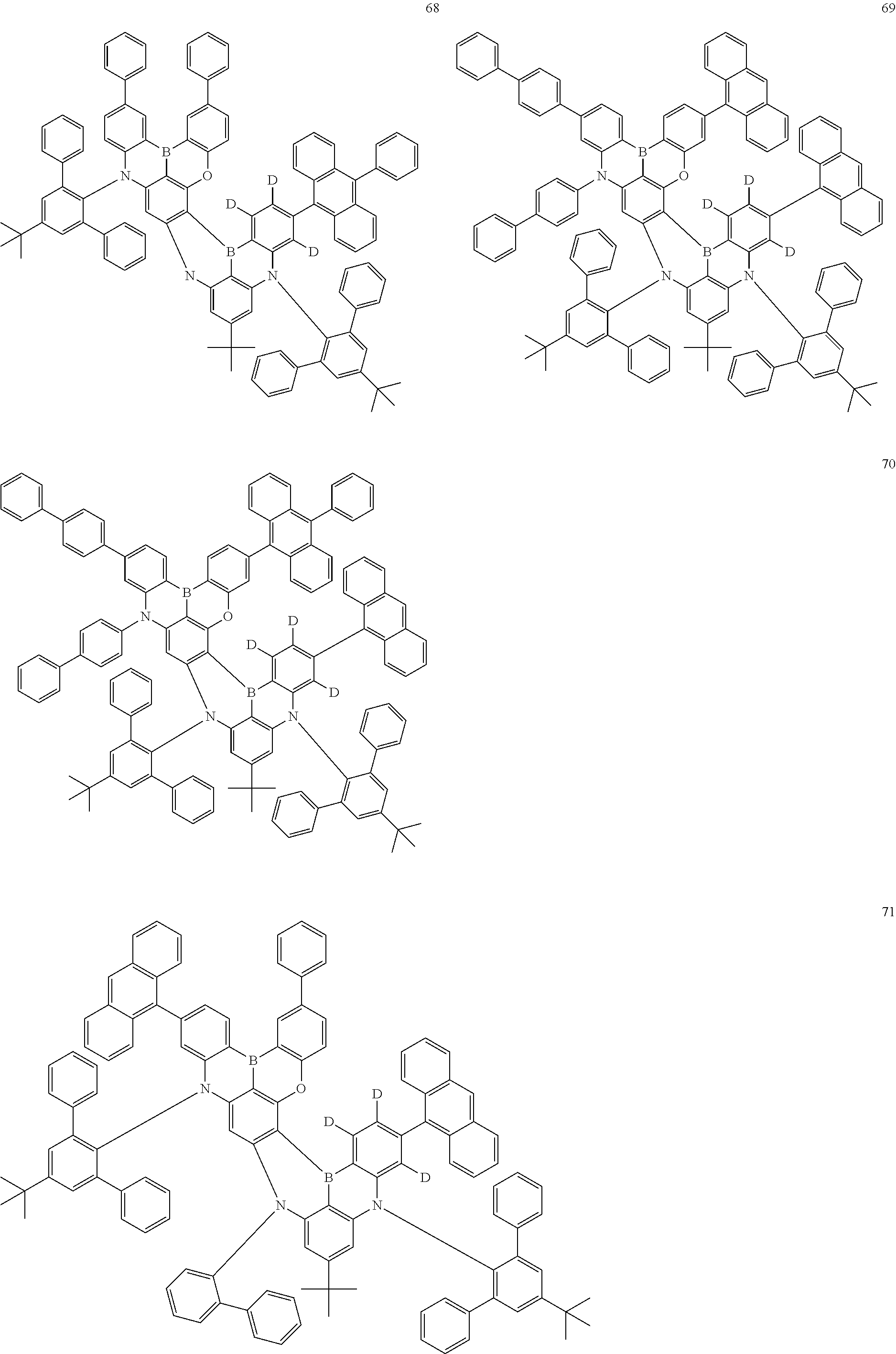

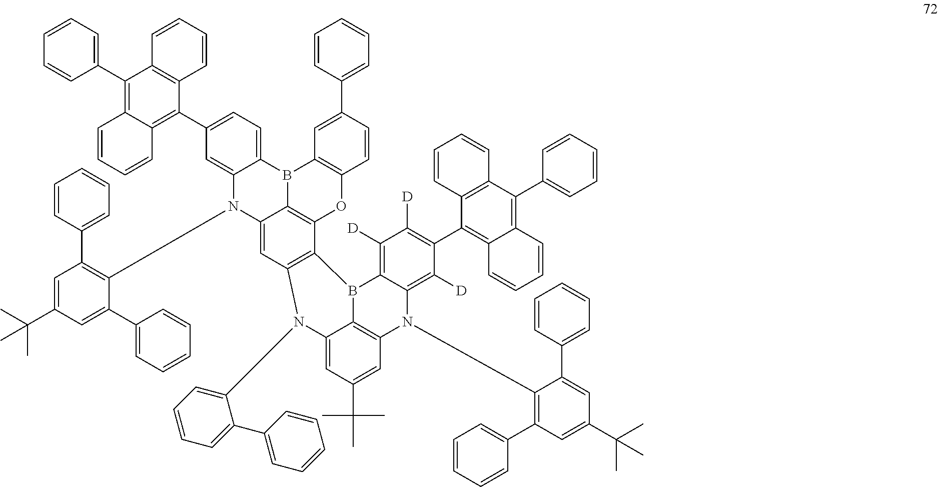 [SMILES: [2H]c1c([2H])c(-c2c3ccccc3c(-c3ccccc3)c3ccccc23)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1ccc(-c2ccccc2)cc1B4c1ccc(-c2c4ccccc4c(-c4ccccc4)c4ccccc24)cc1N3c1c(-c2ccccc2)cc(C(C)(C)C)cc1-c1ccccc1]

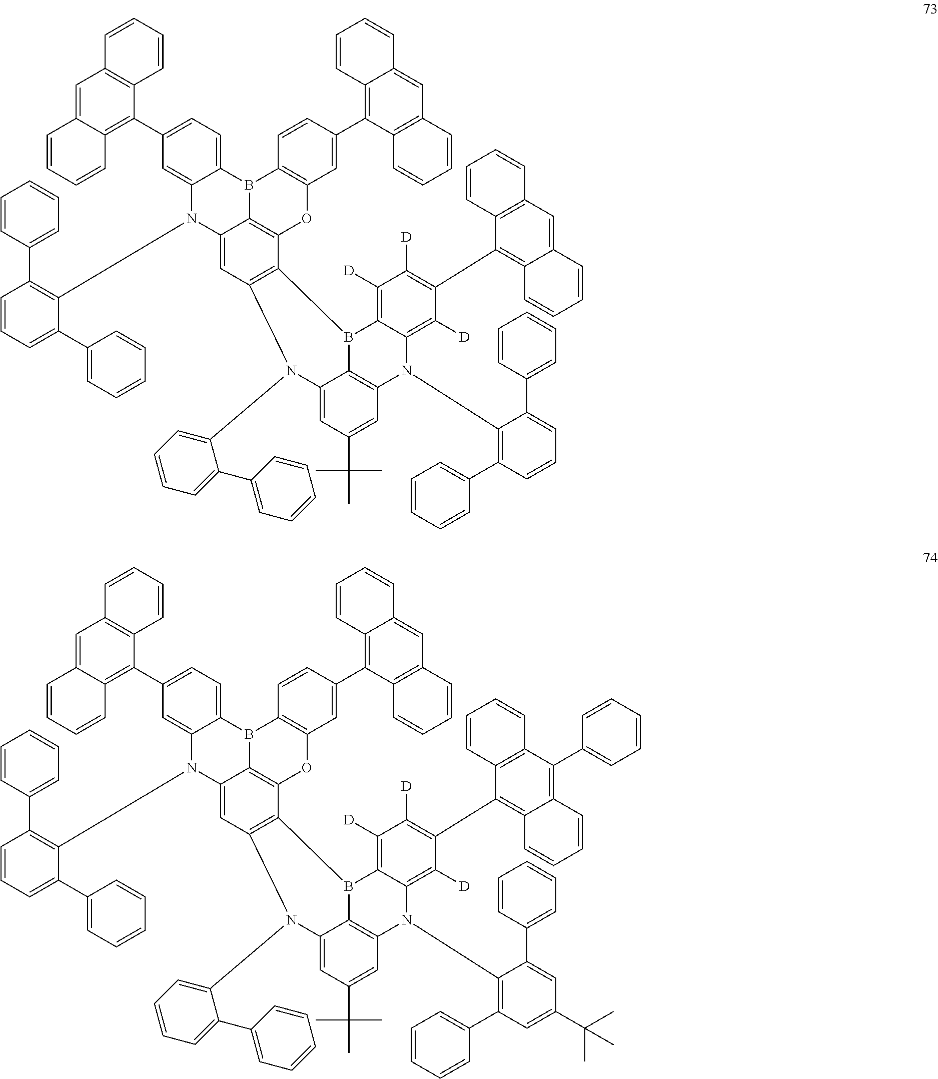 [SMILES: [2H]c1c([2H])c(-c2c3ccccc3cc3ccccc23)c([2H])c2c1B1c3c(cc(C(C)(C)C)cc3N2c2c(-c3ccccc3)cccc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1 ; [2H]c1c([2H])c(-c2c3ccccc3c(-c3ccccc3)c3ccccc23)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1]

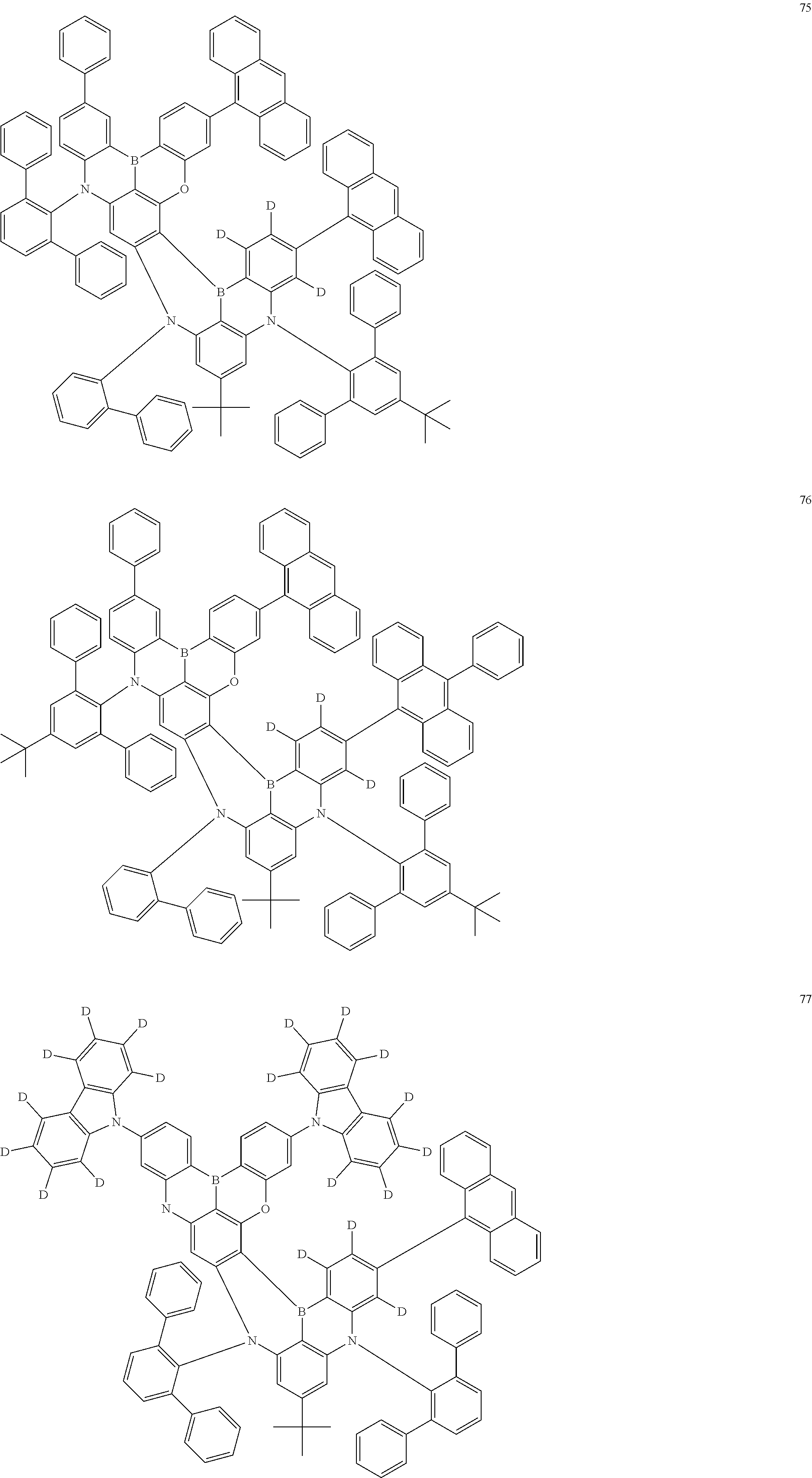

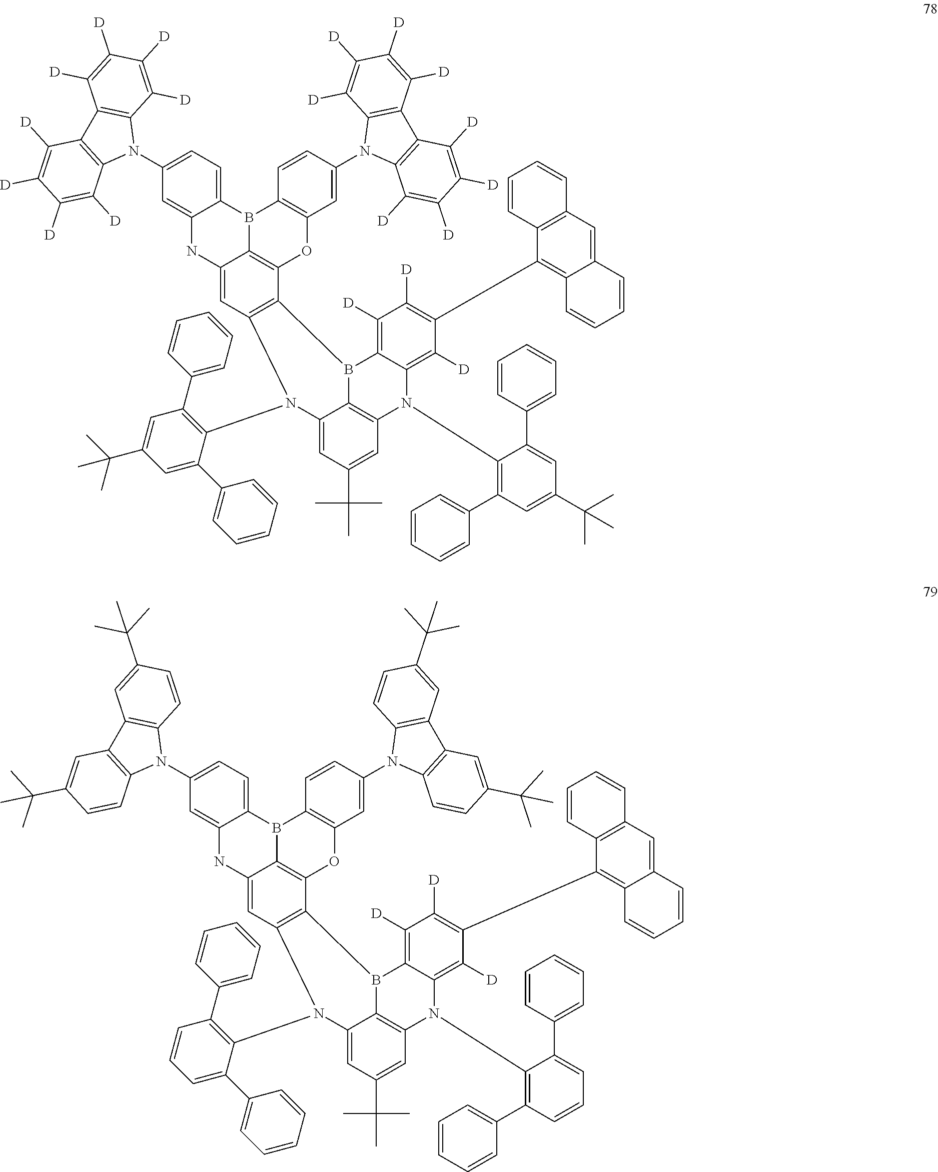

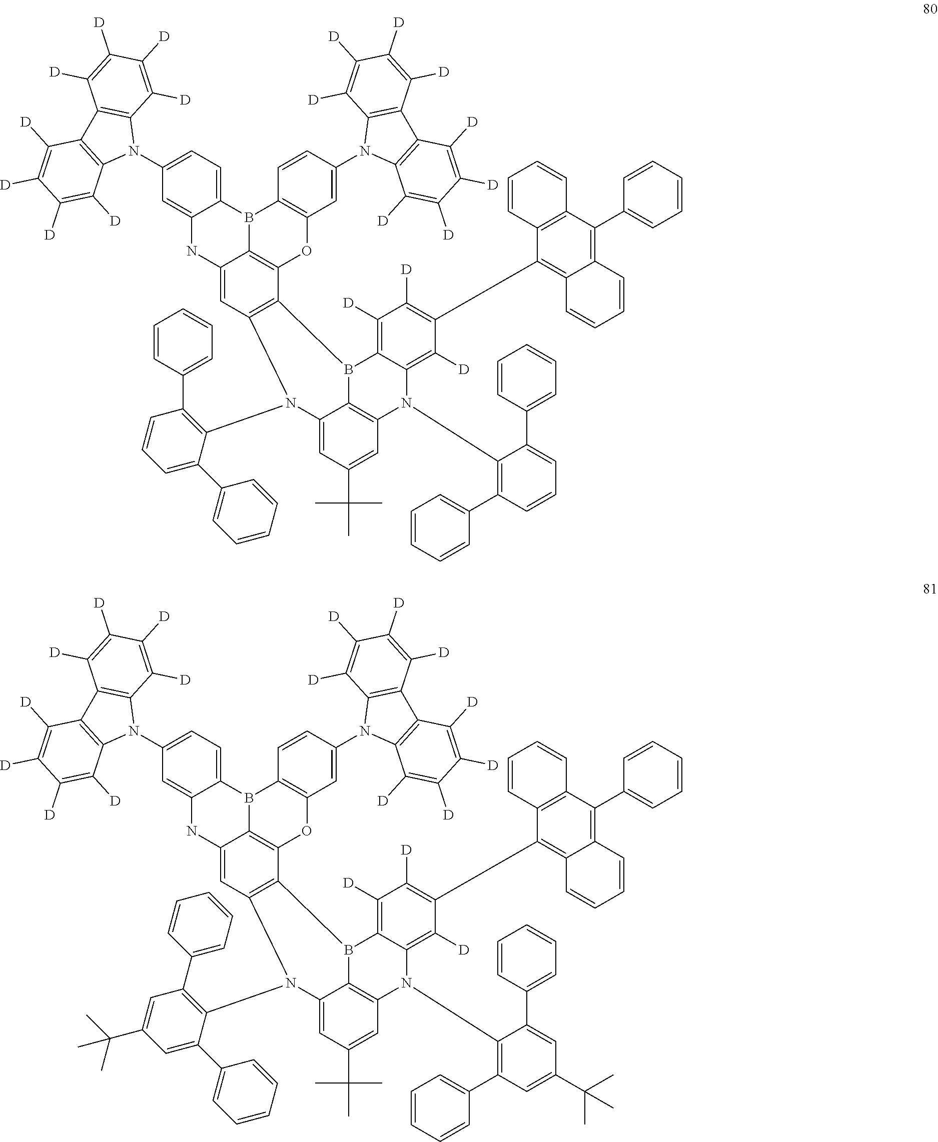

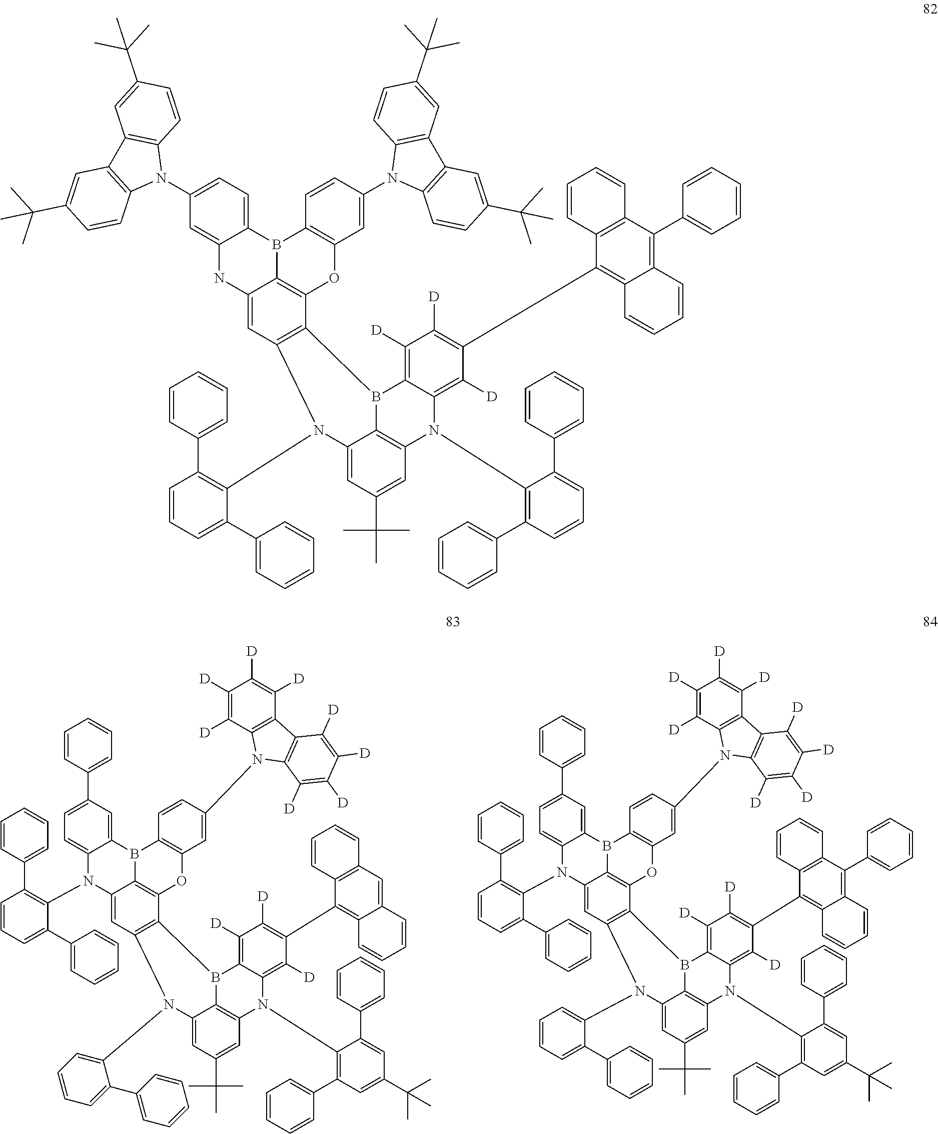

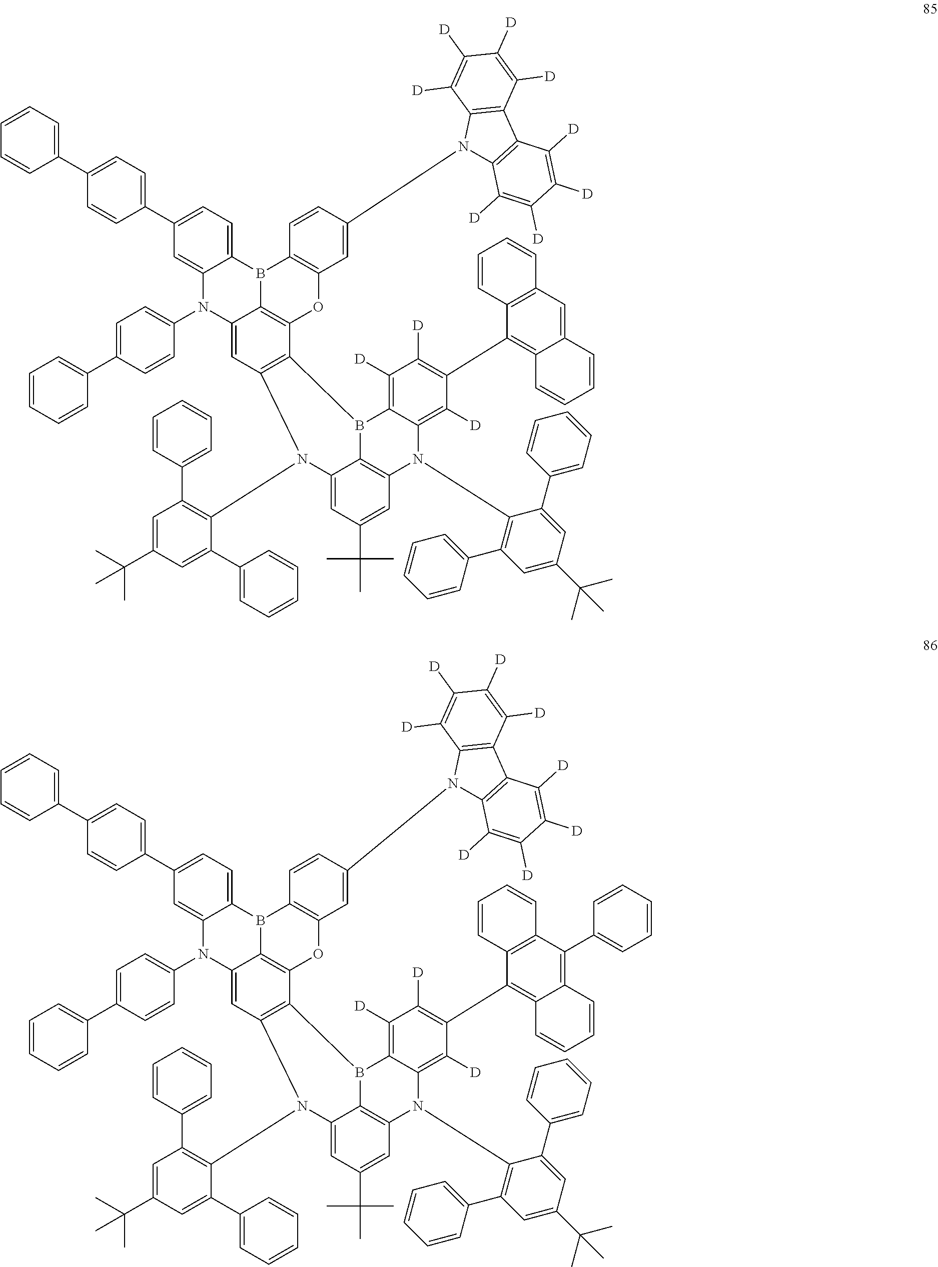

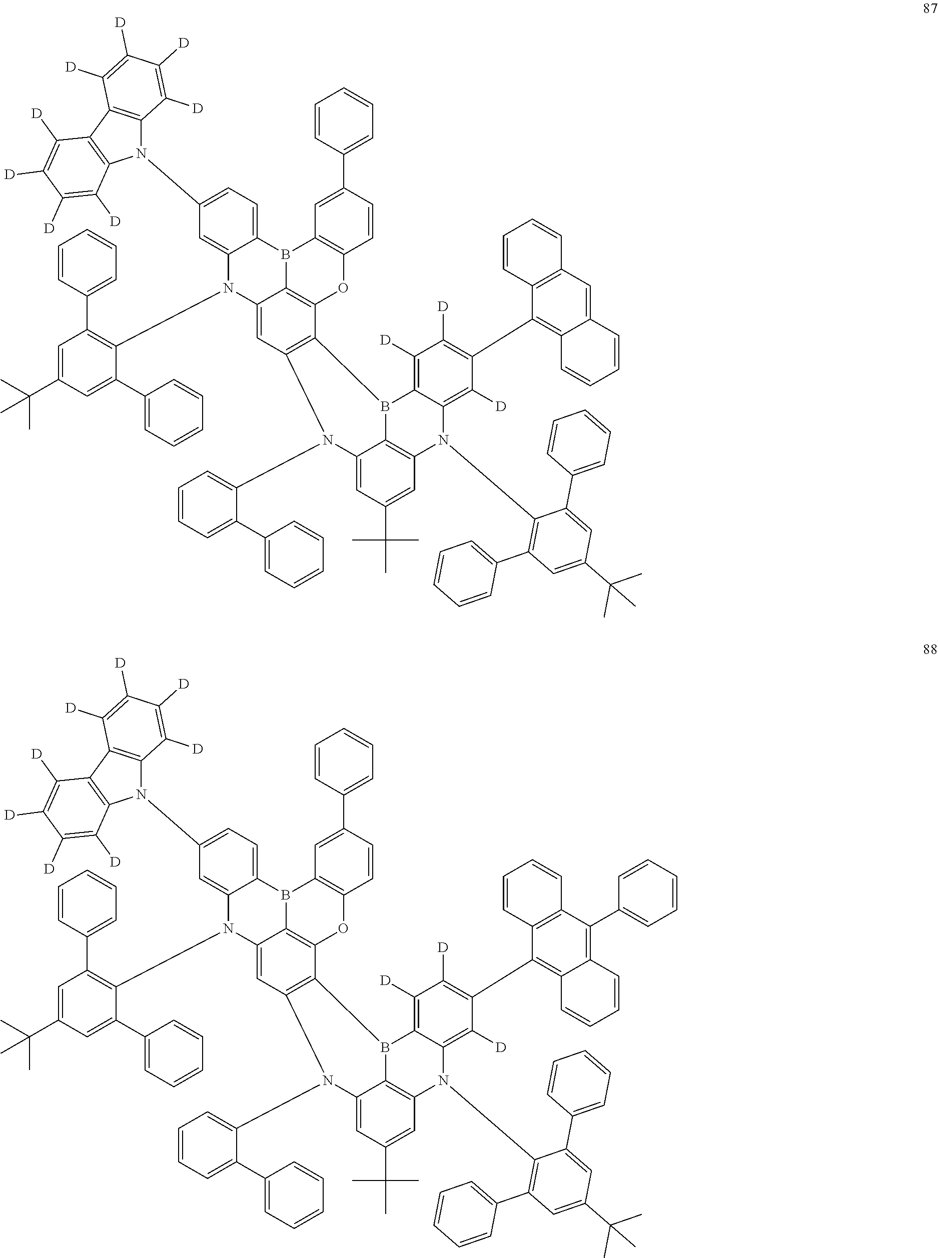

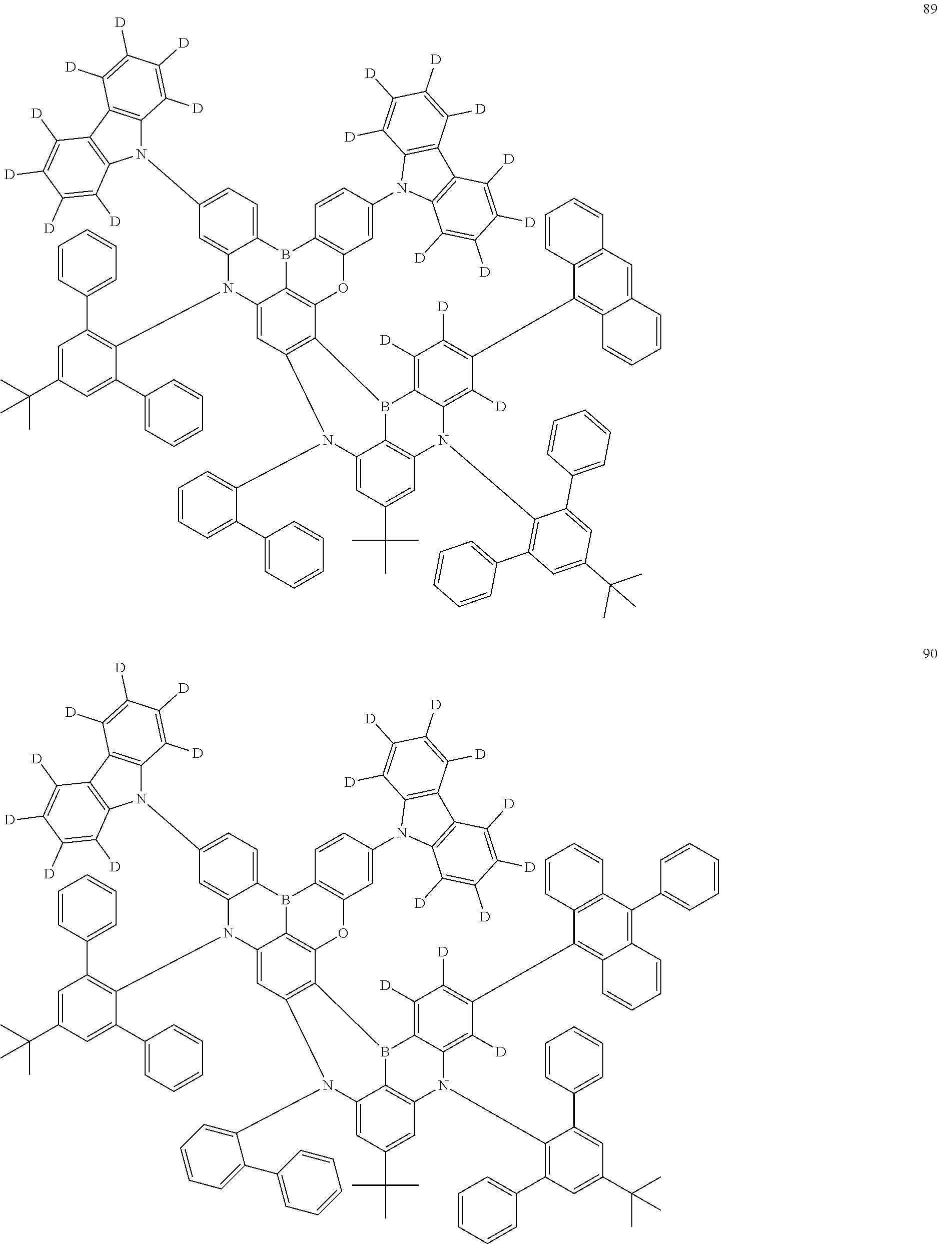

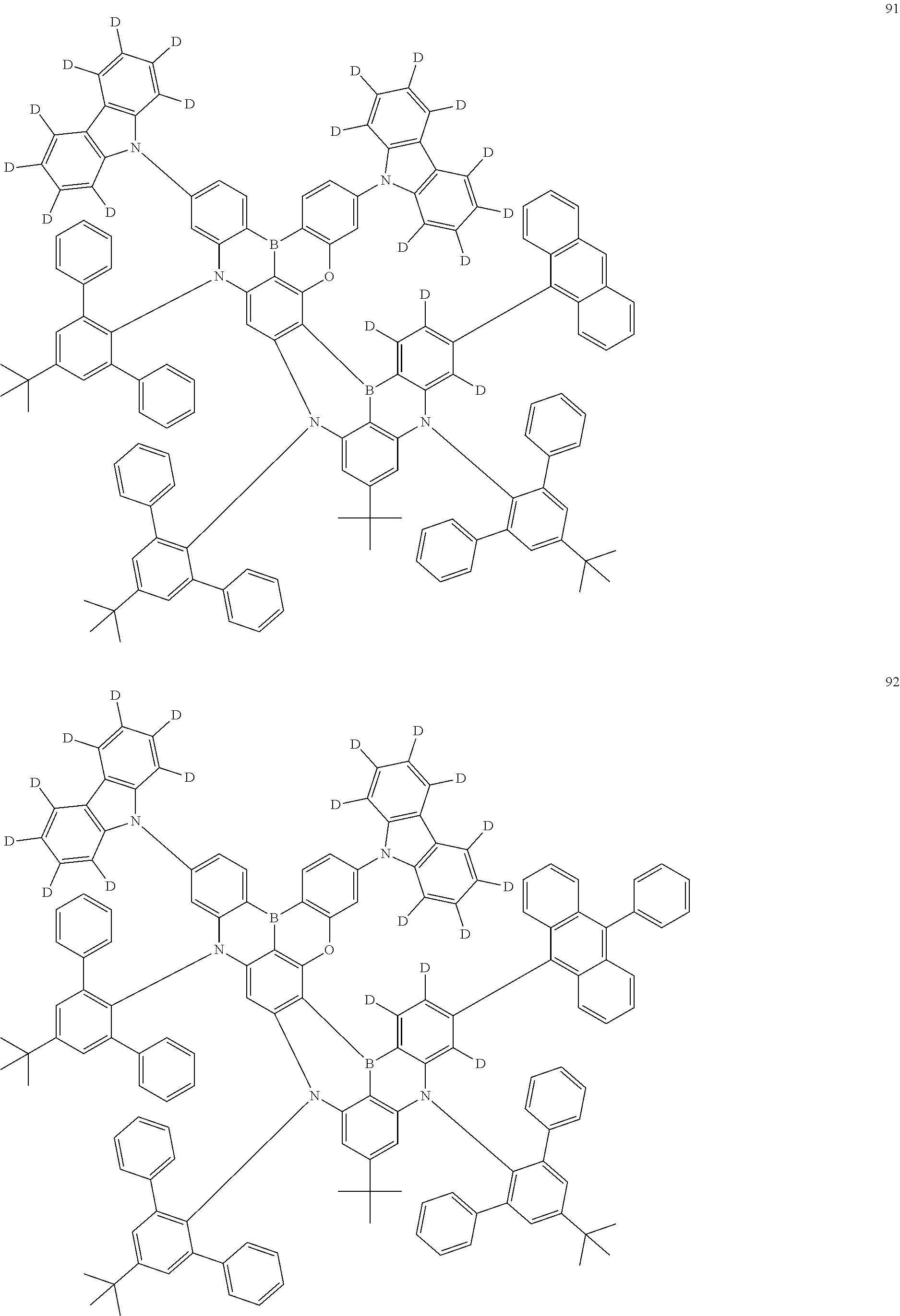

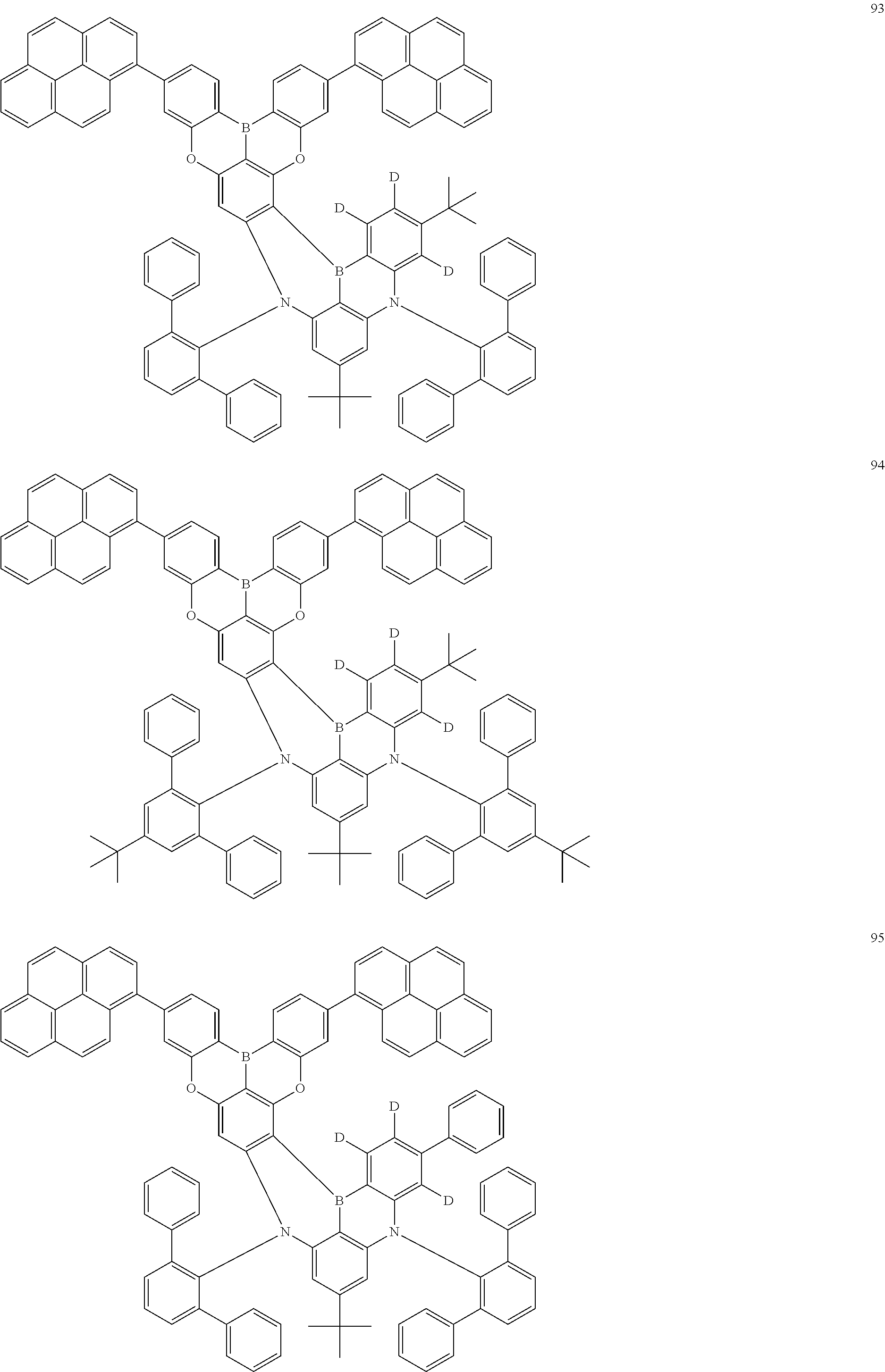

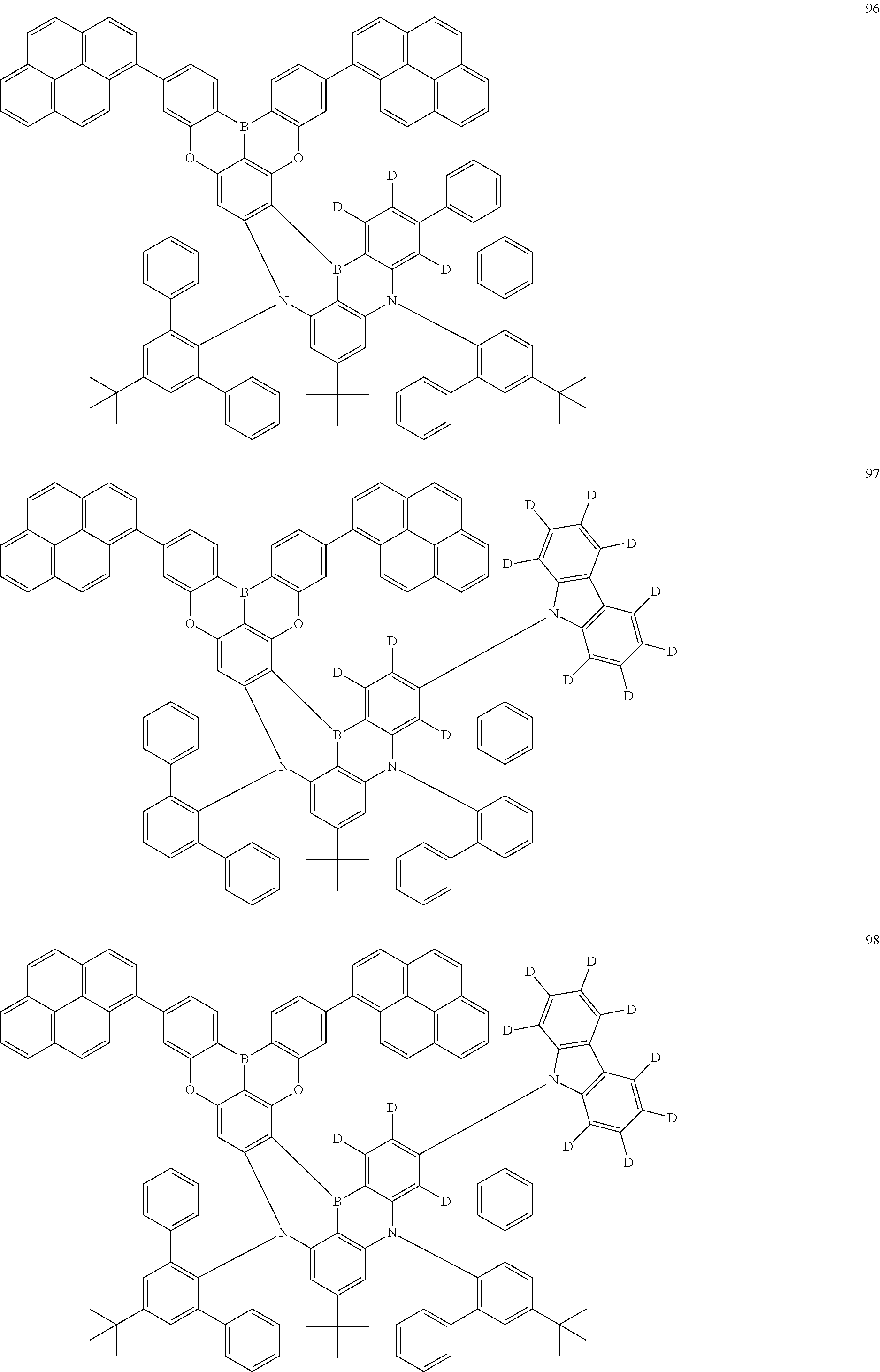

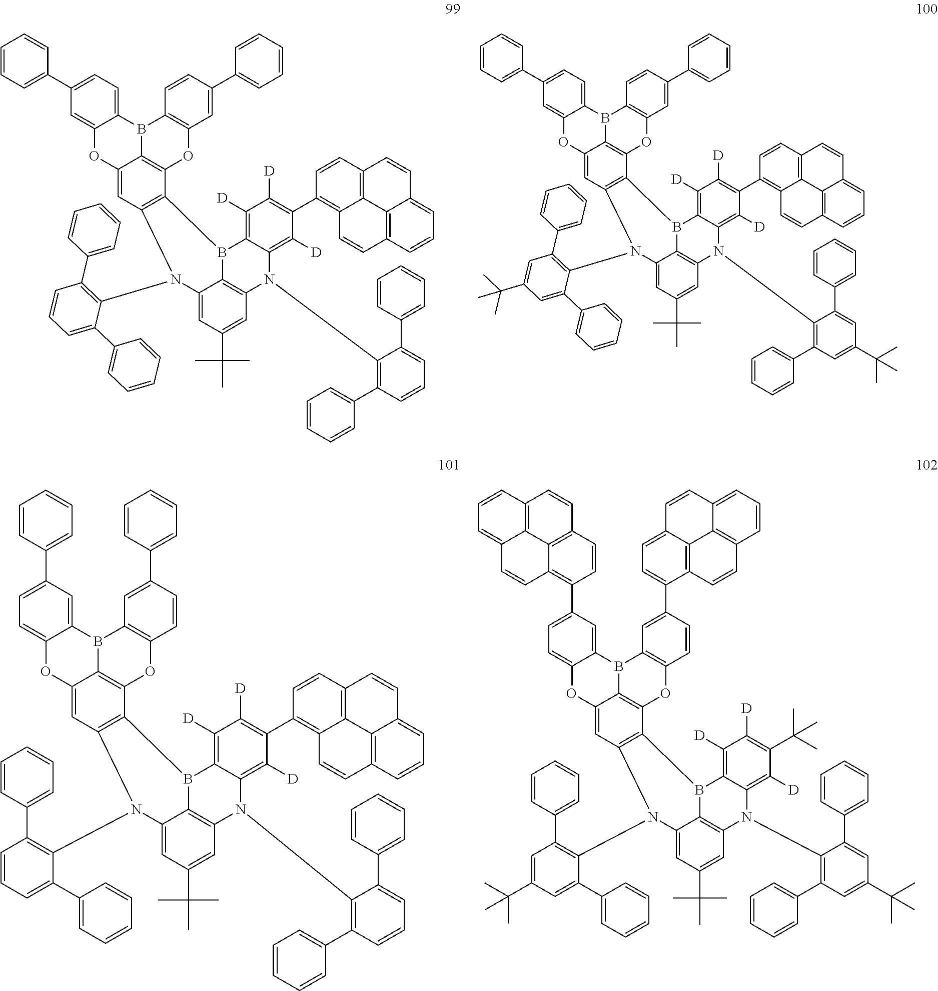

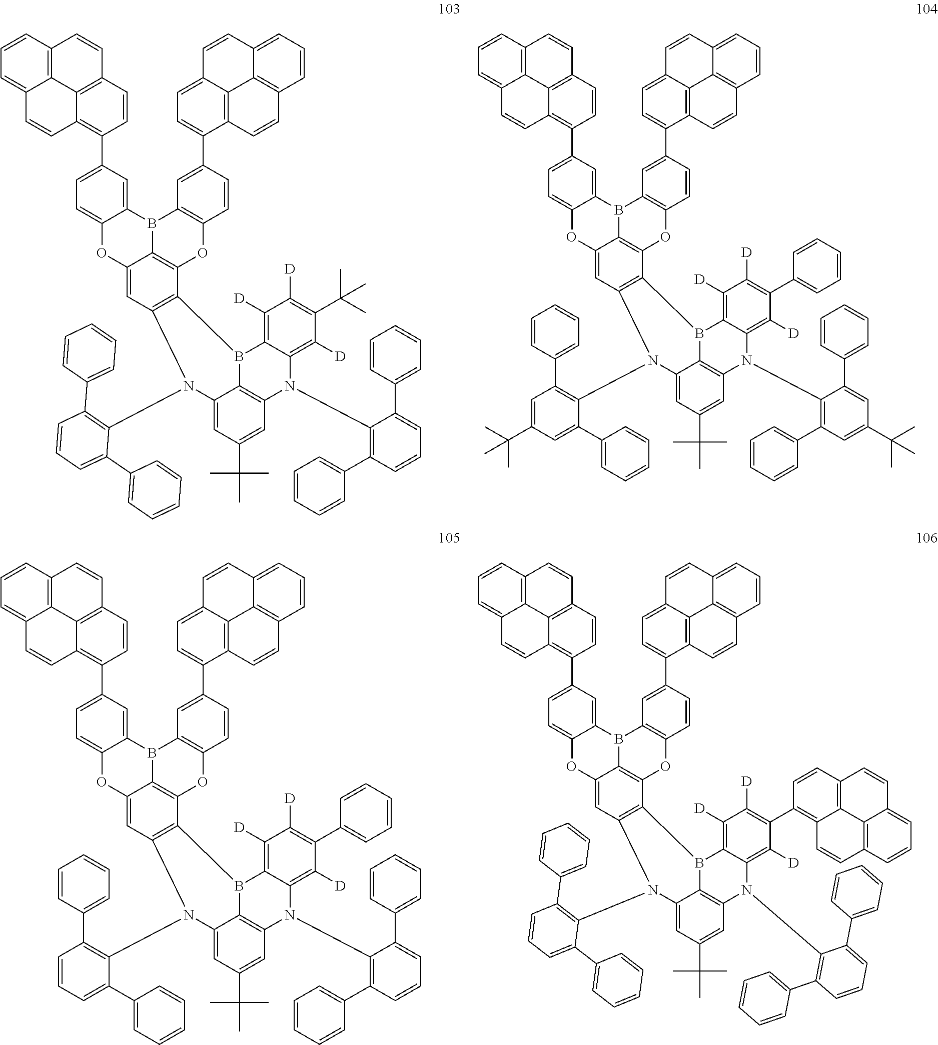

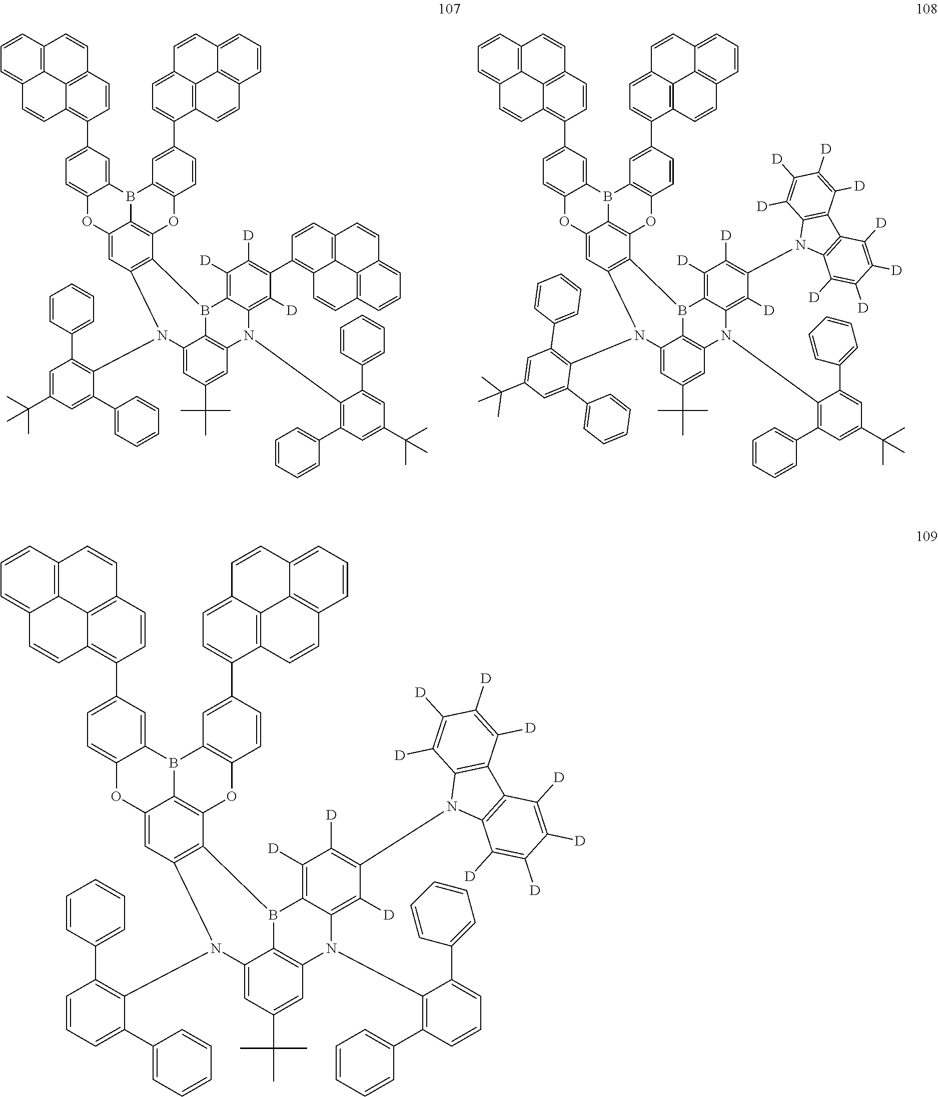

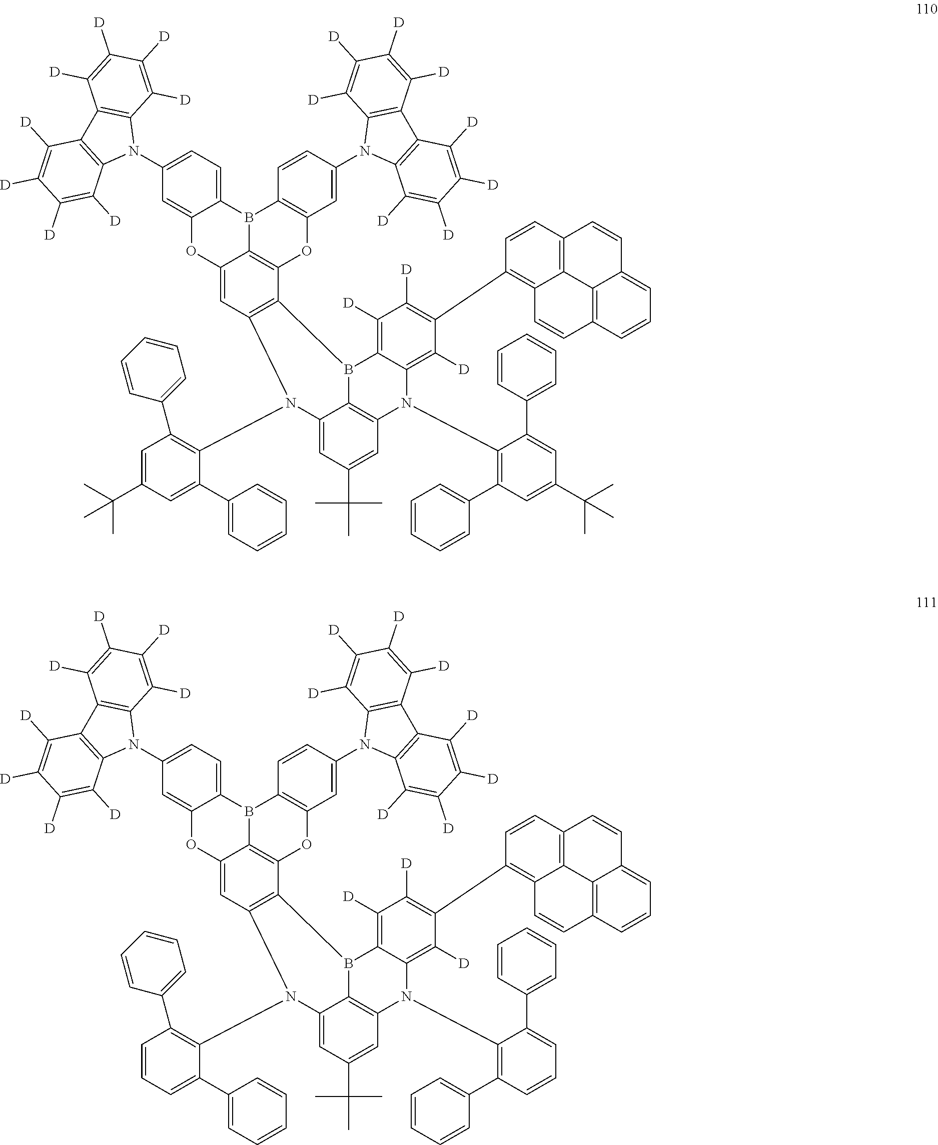

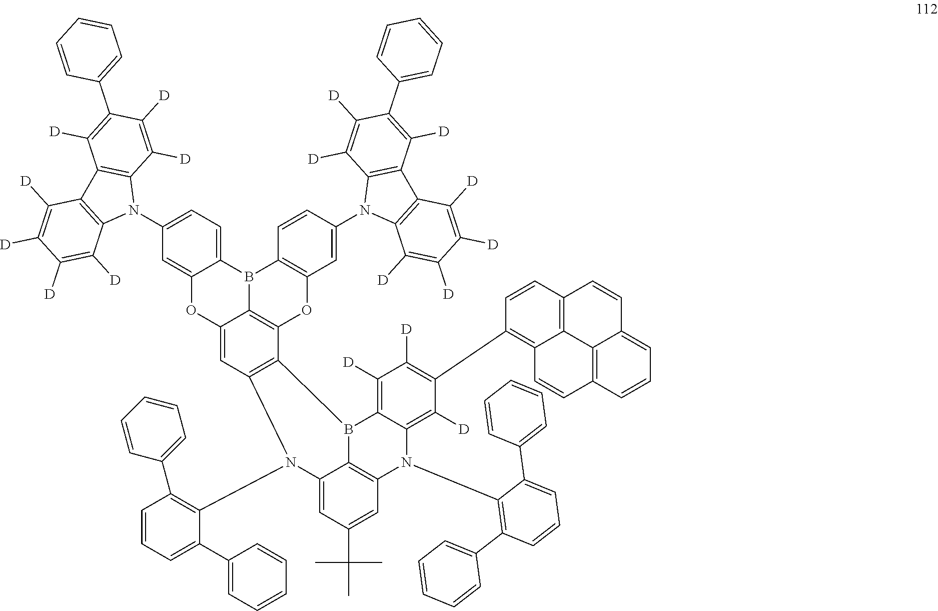 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-n2c5c([2H])c([2H])c([2H])c([2H])c5c5c([2H])c(-c6ccccc6)c([2H])c([2H])c52)ccc1B4c1ccc(-n2c4c([2H])c([2H])c([2H])c([2H])c4c4c([2H])c(-c5ccccc5)c([2H])c([2H])c42)cc1O3]

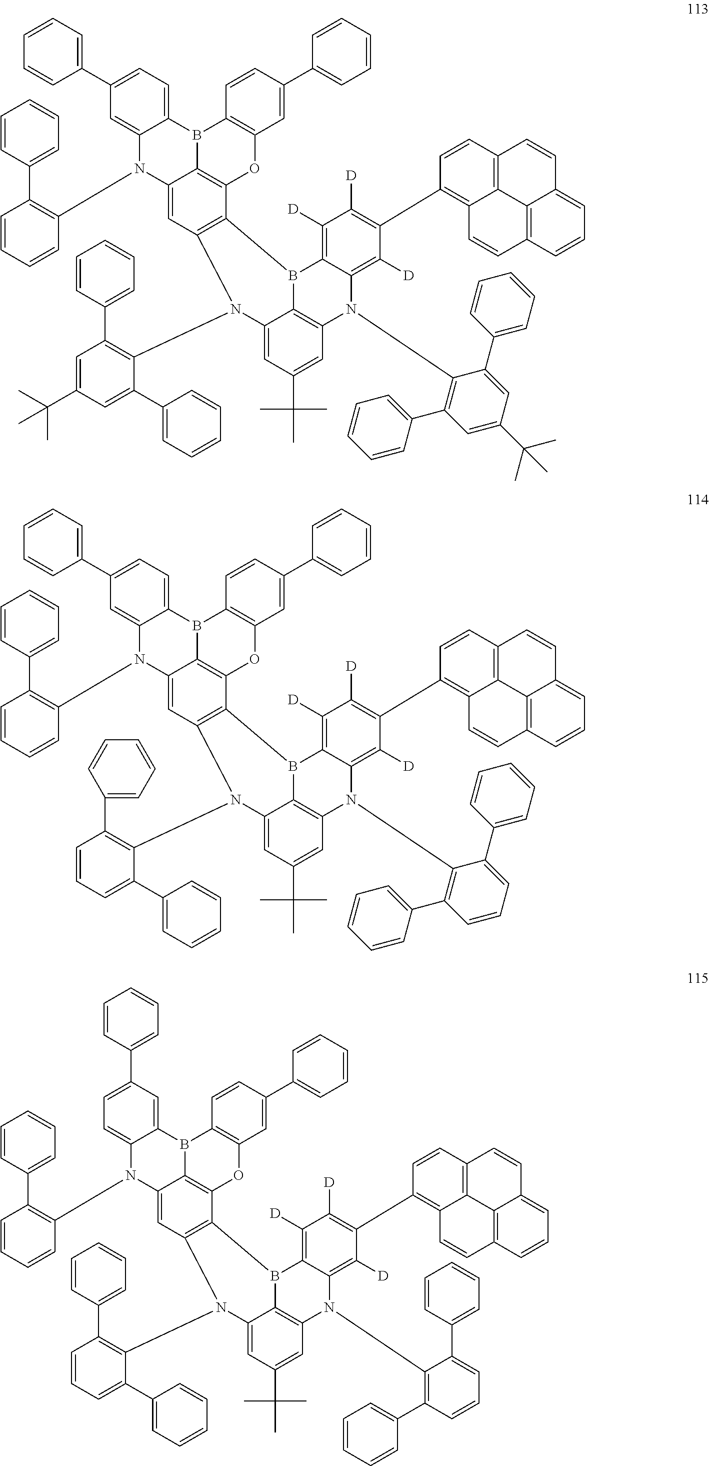

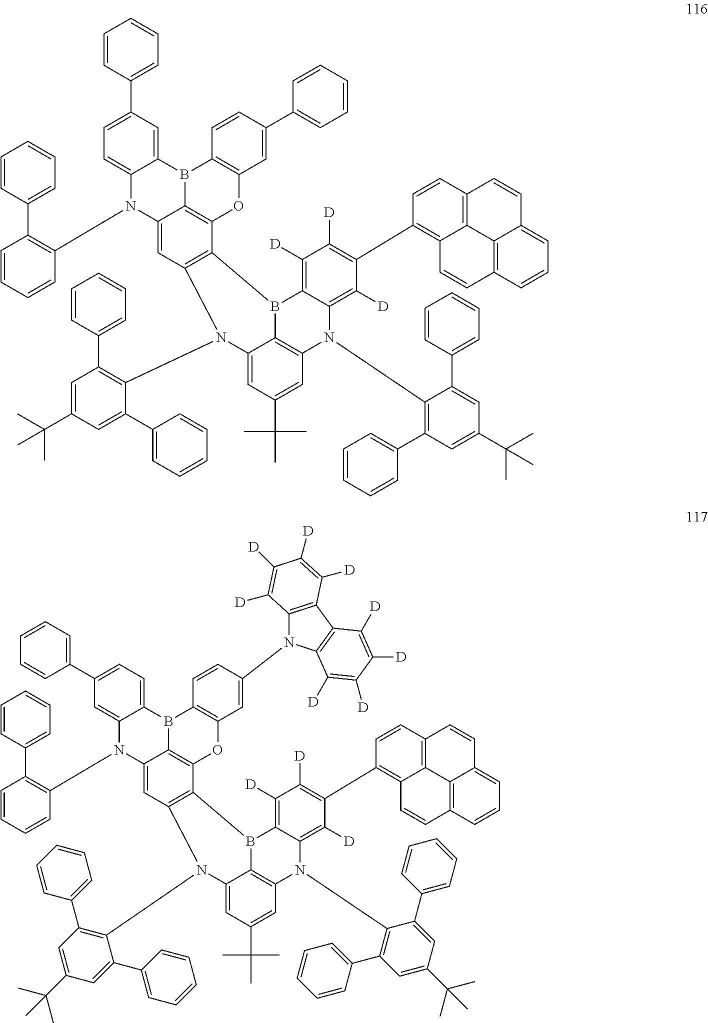

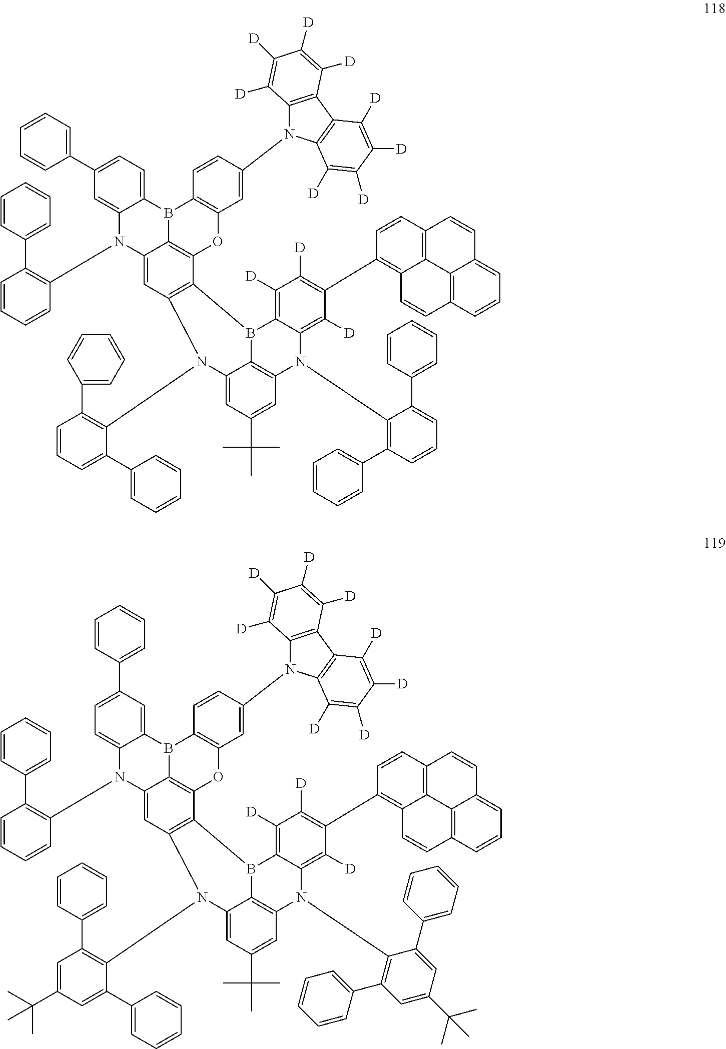

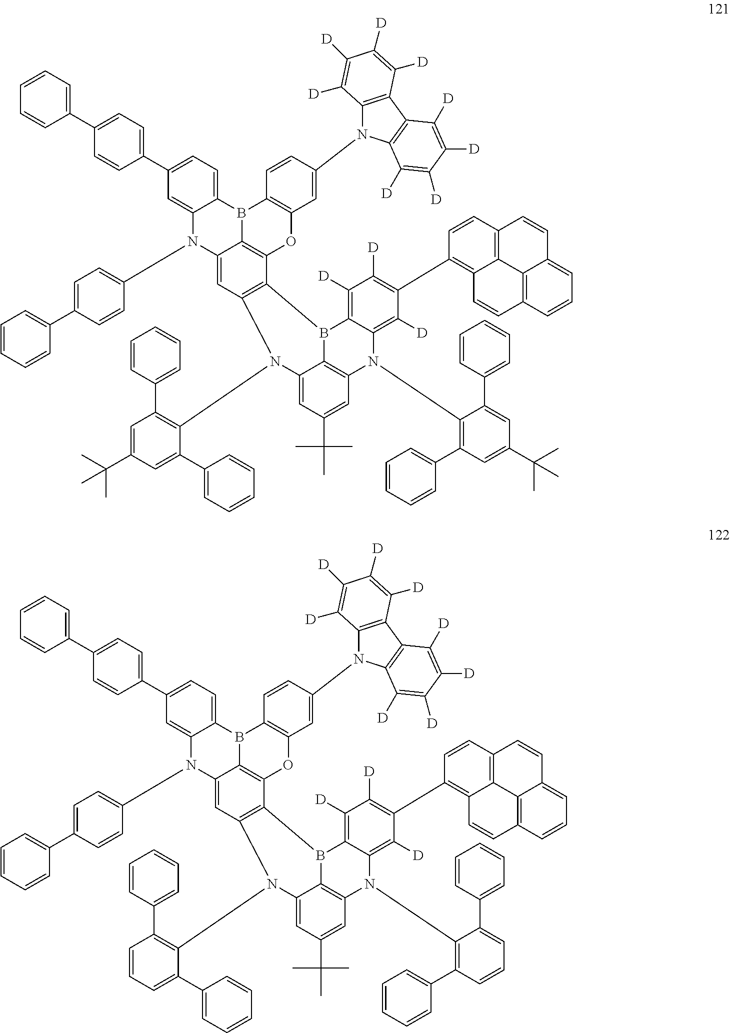

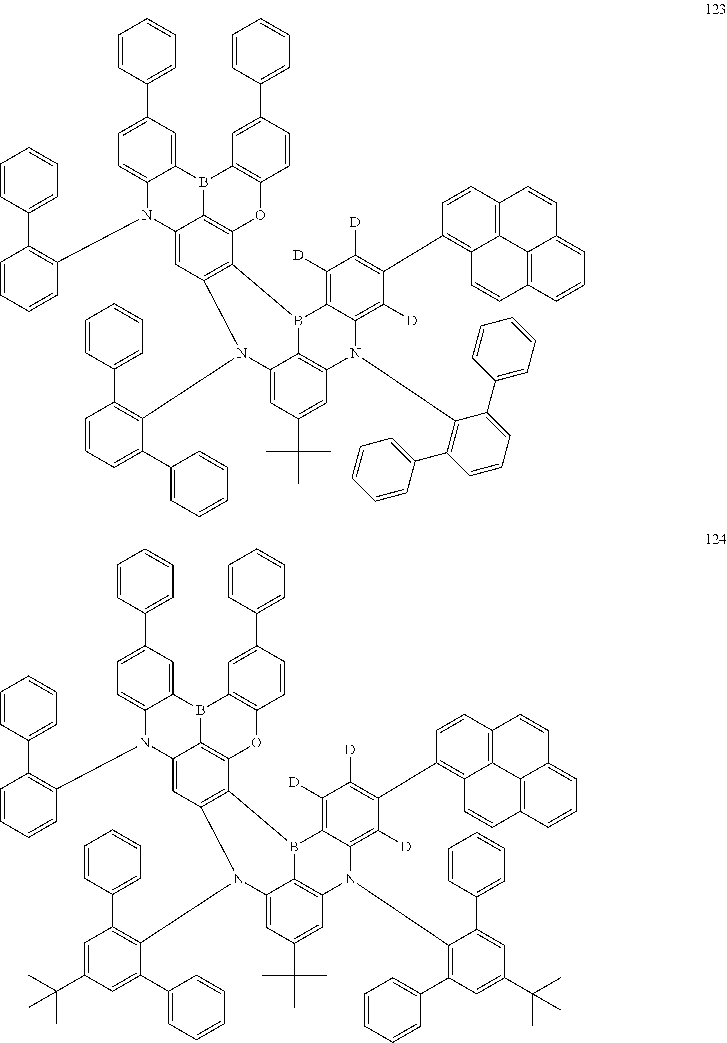 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1ccc(-c2ccccc2)cc1B4c1cc(-c2ccccc2)ccc1N3c1ccccc1-c1ccccc1 ; [2H]c1c([2H])c(-c2ccc3ccc4cccc5ccc2c3c45)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1ccc(-c2ccccc2)cc1B4c1cc(-c2ccccc2)ccc1N3c1ccccc1-c1ccccc1]

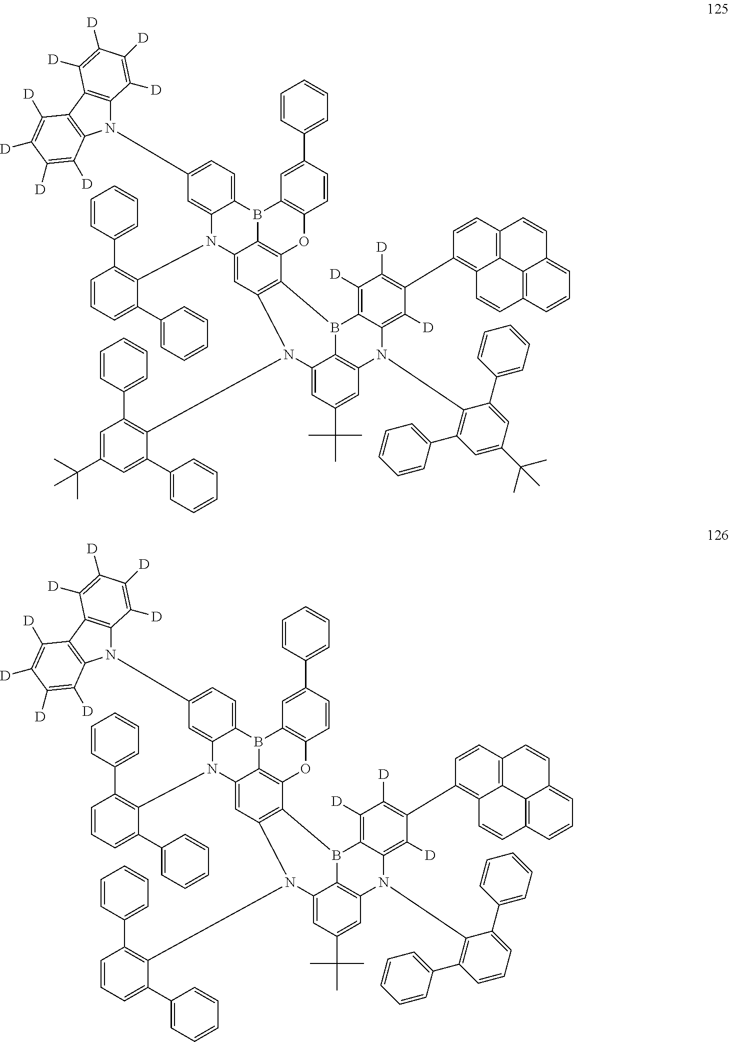

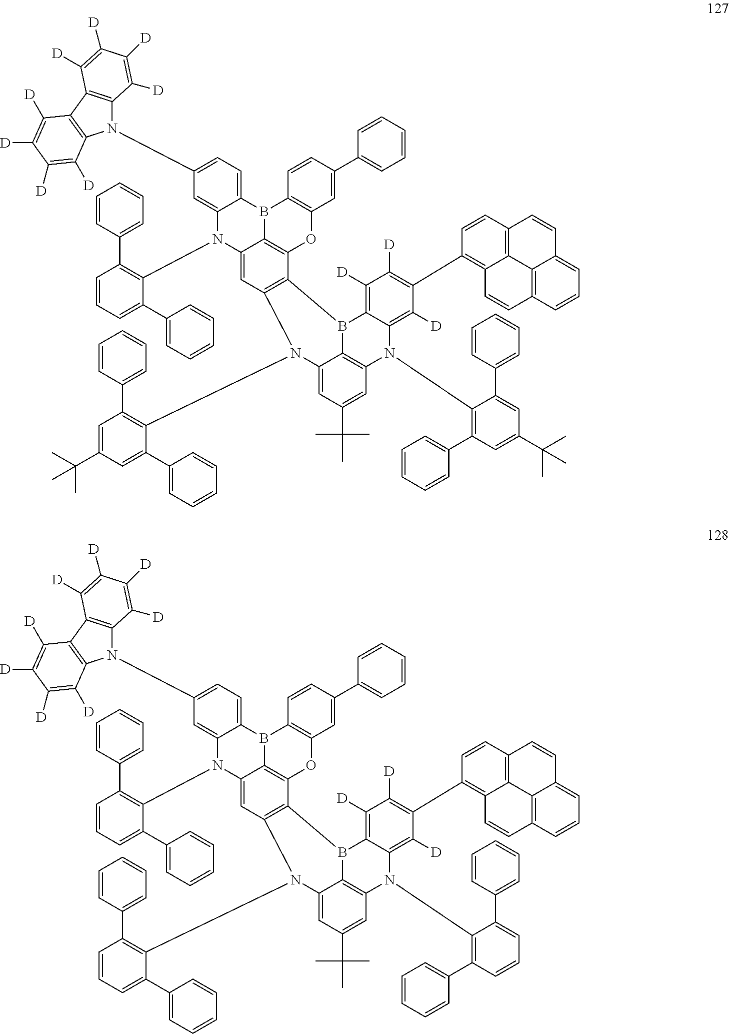

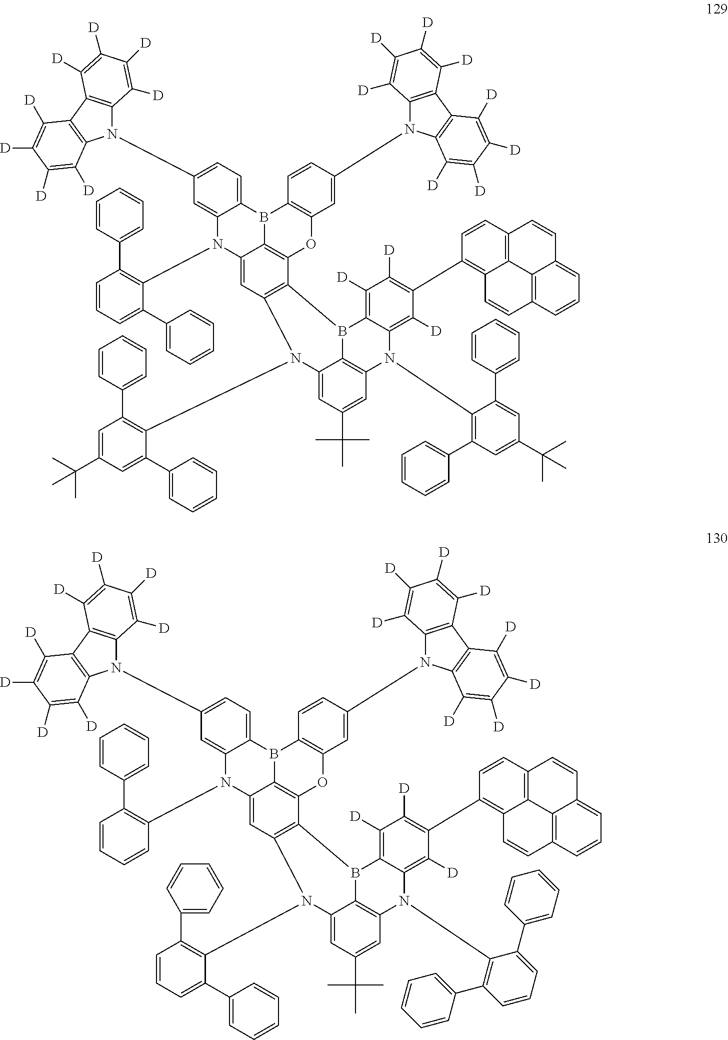

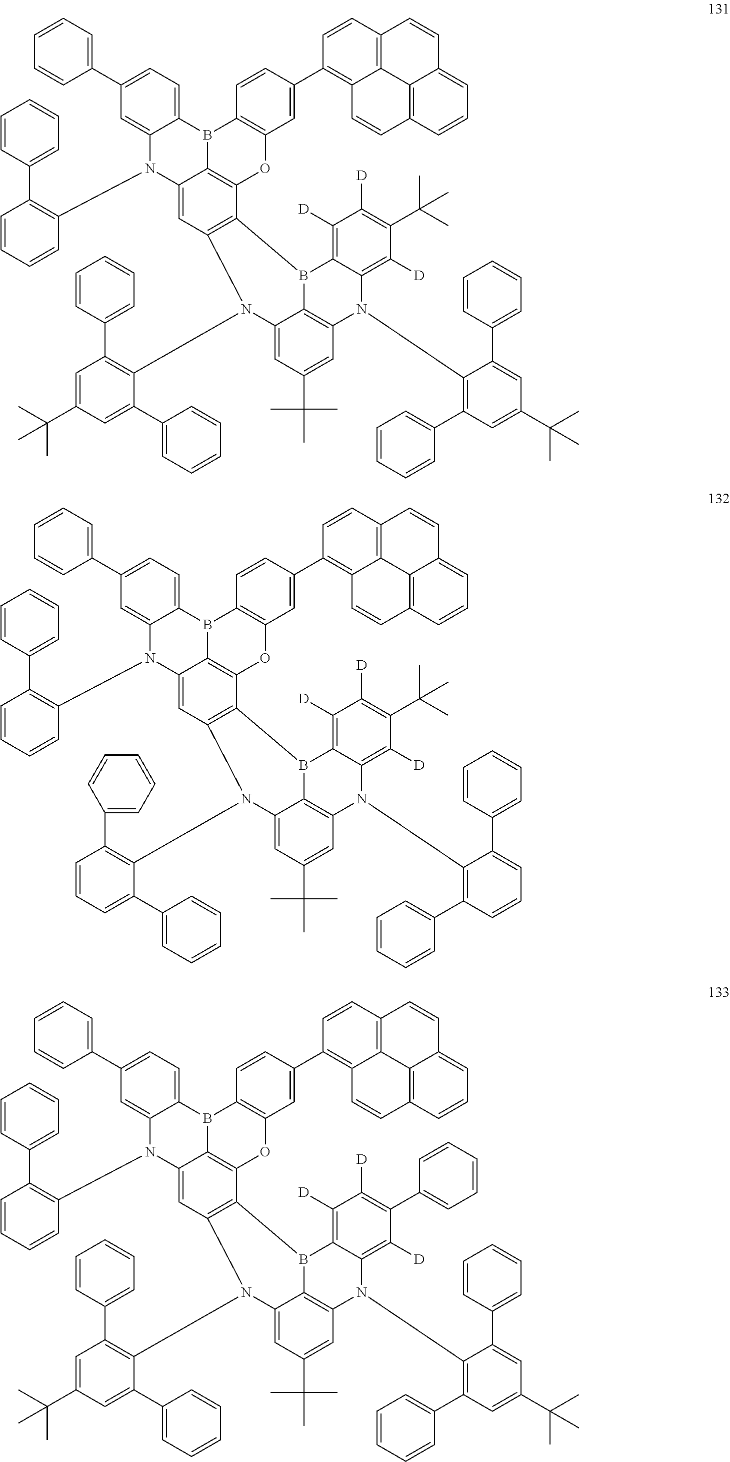

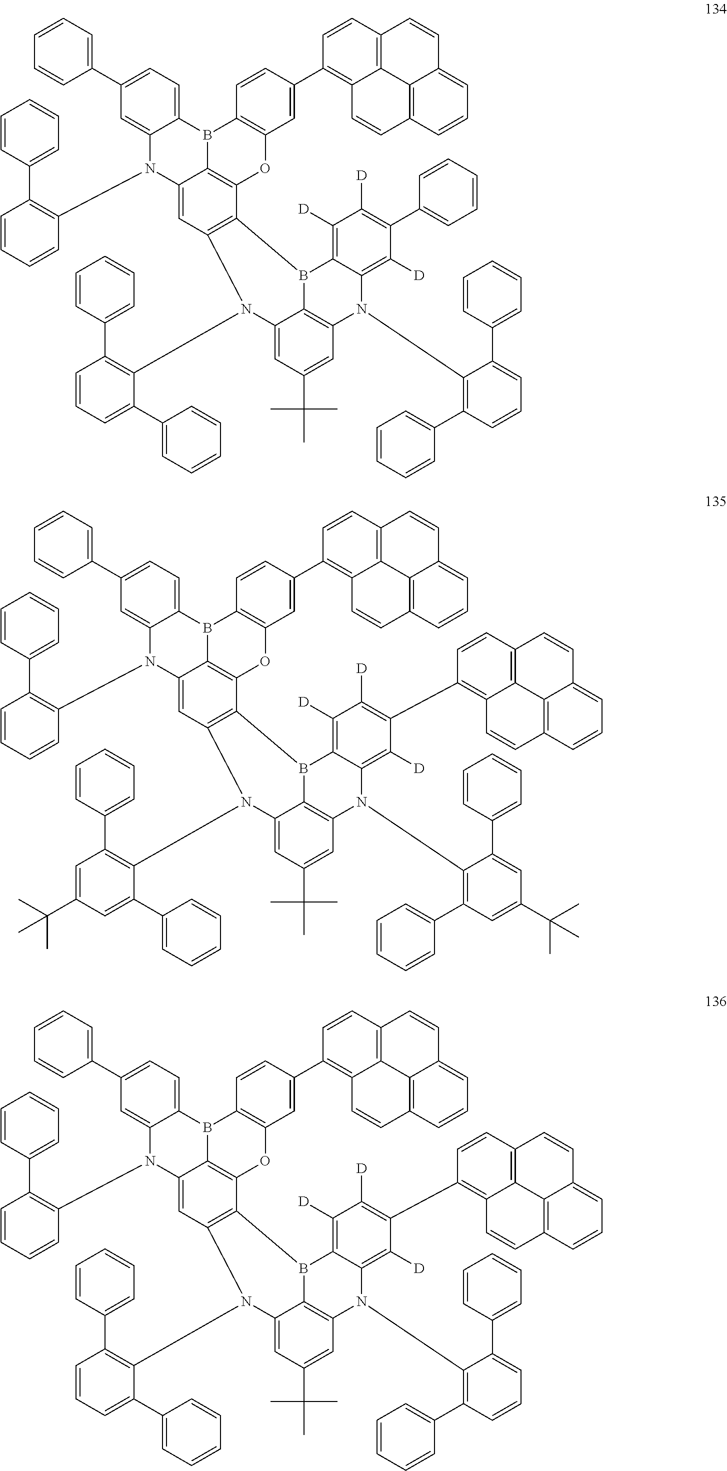

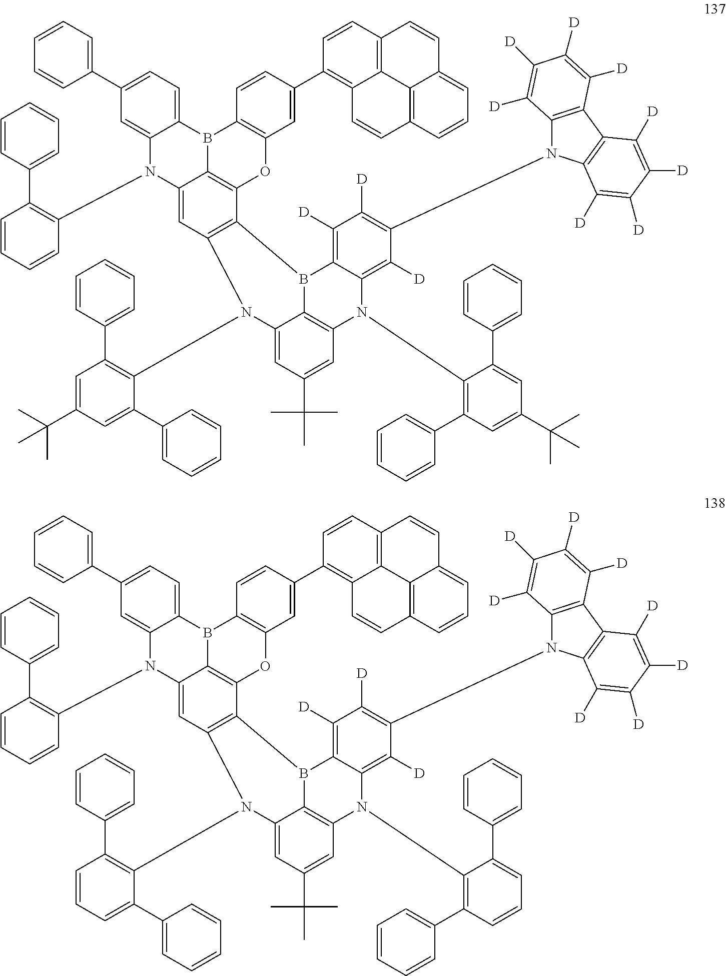

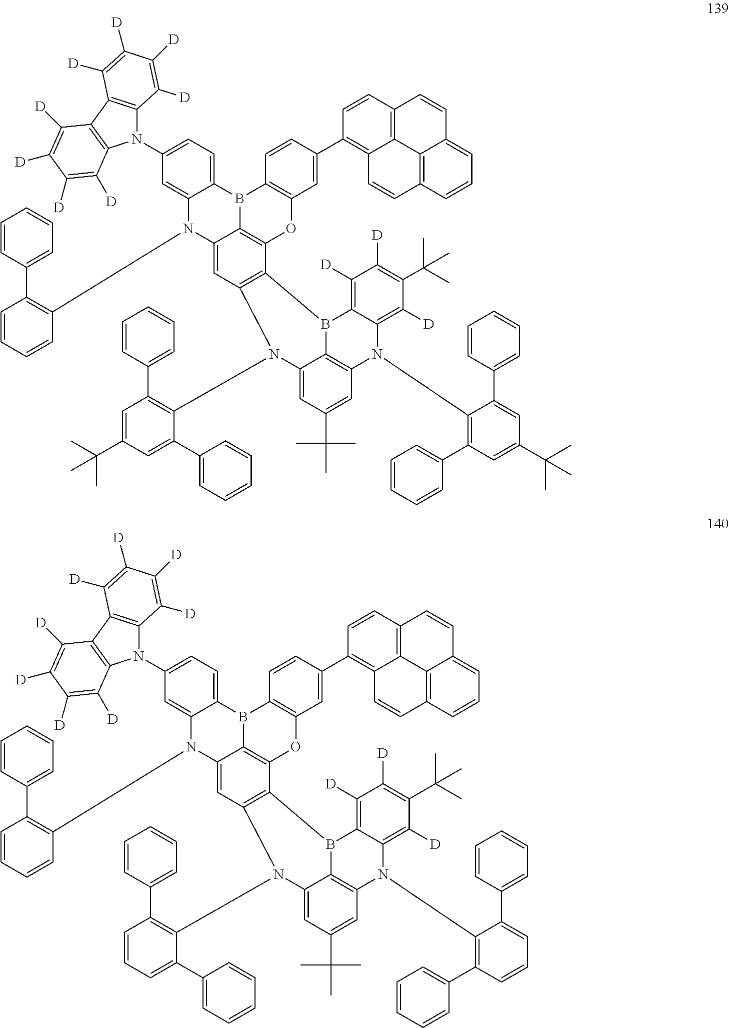

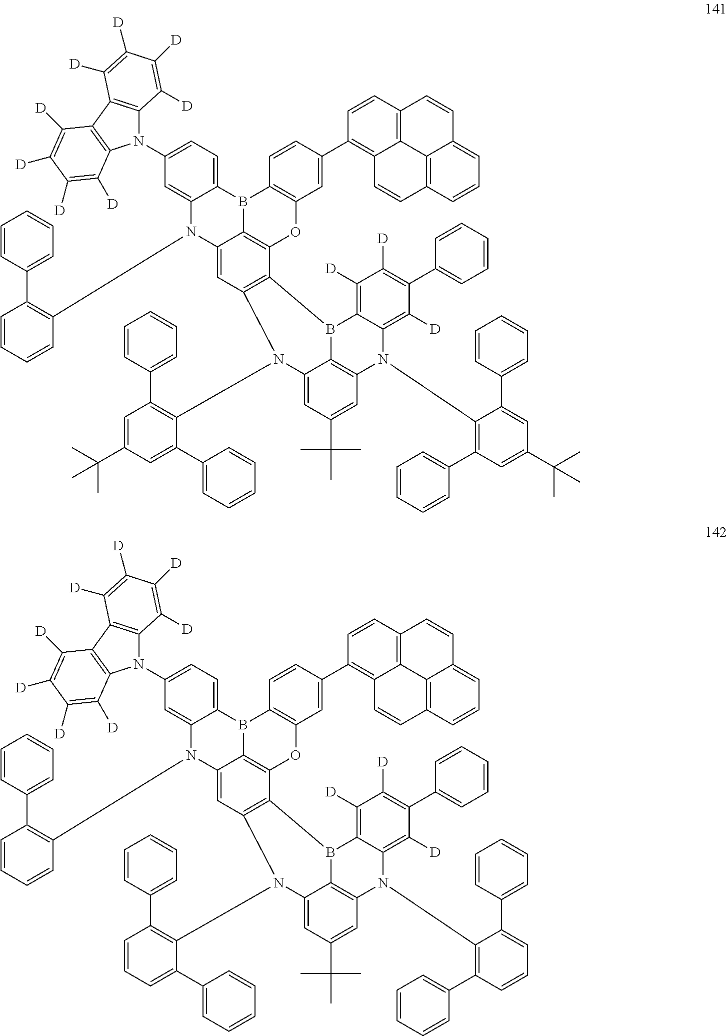

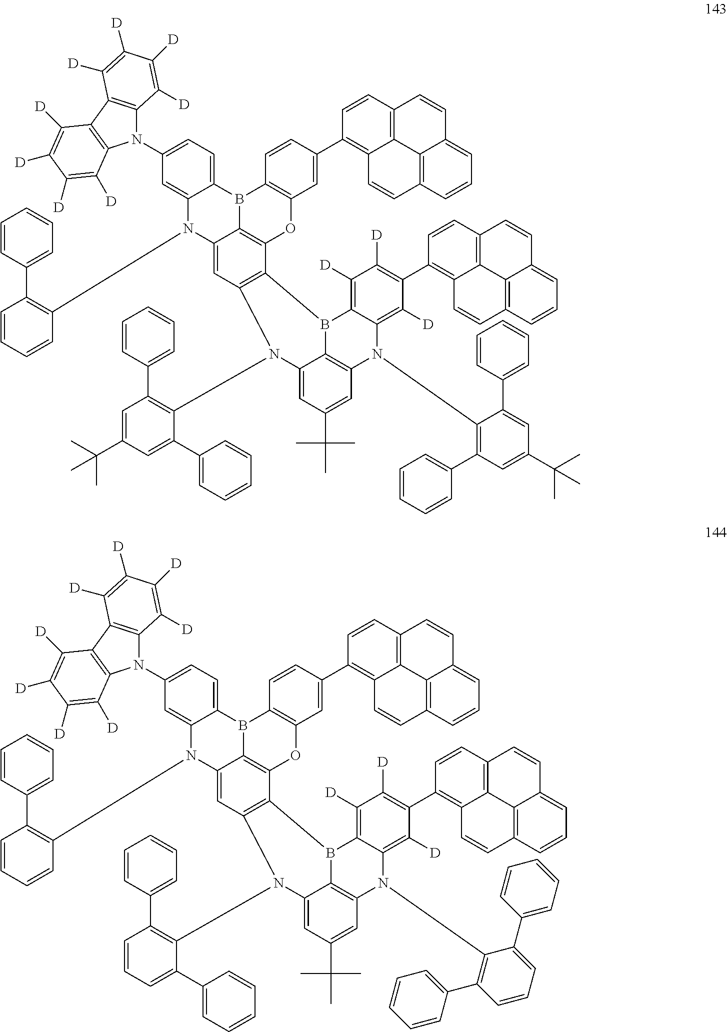

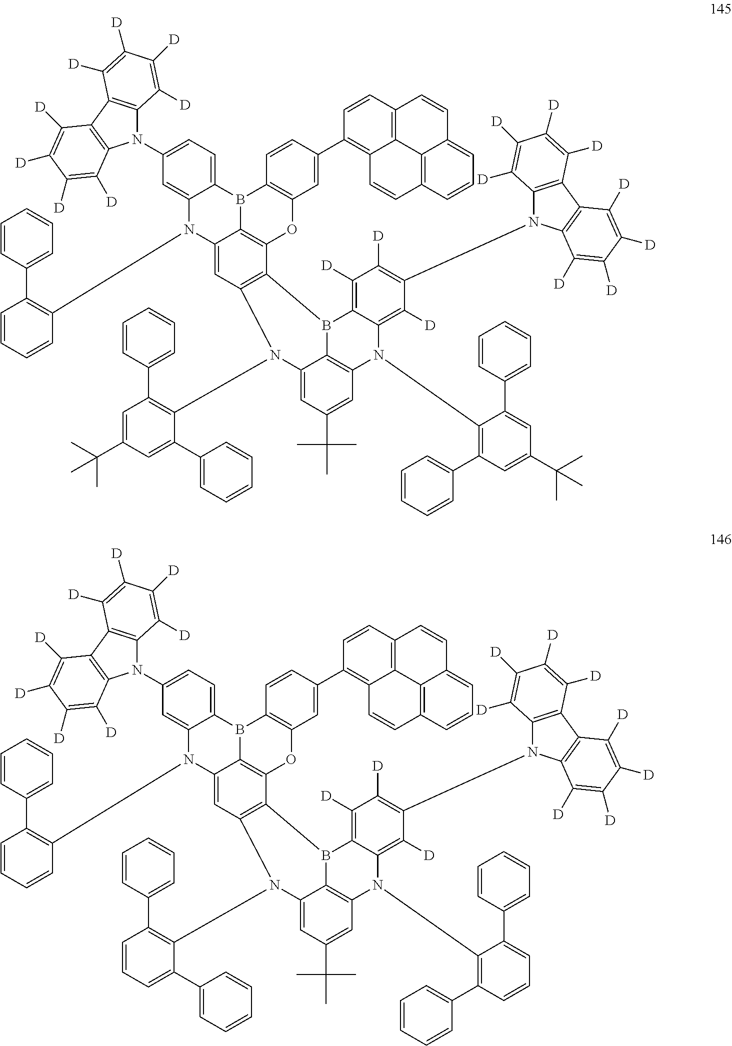

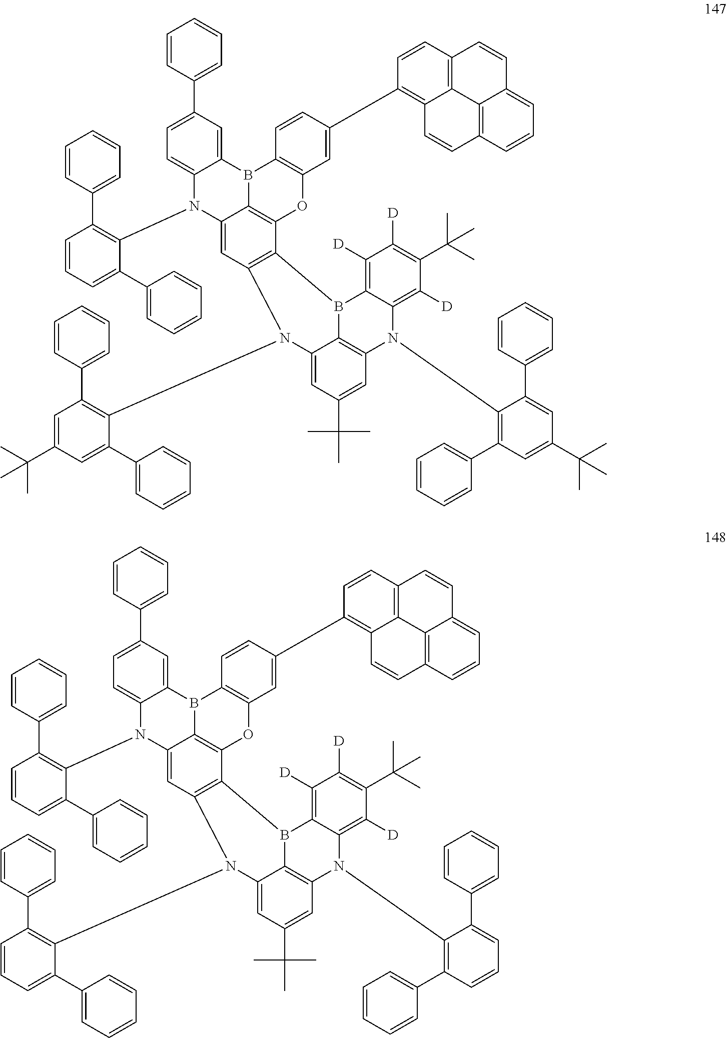 [SMILES: [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1cc(-c2ccccc2)ccc1N3c1c(-c2ccccc2)cccc1-c1ccccc1 ; [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1cc(-c2ccccc2)ccc1N3c1c(-c2ccccc2)cccc1-c1ccccc1]

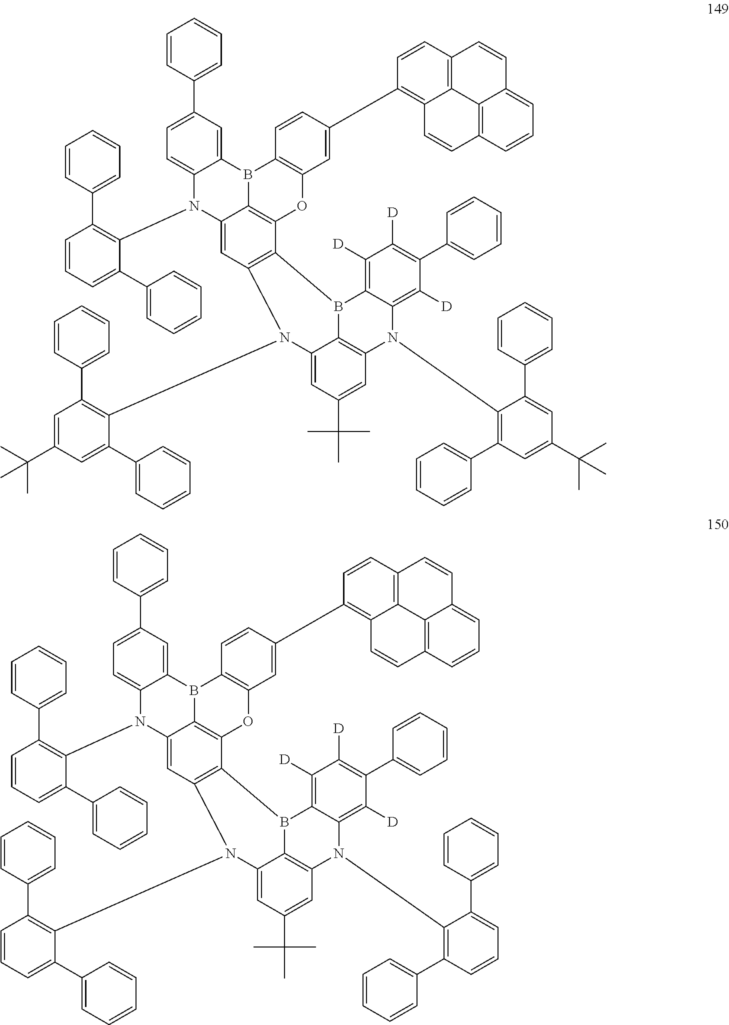

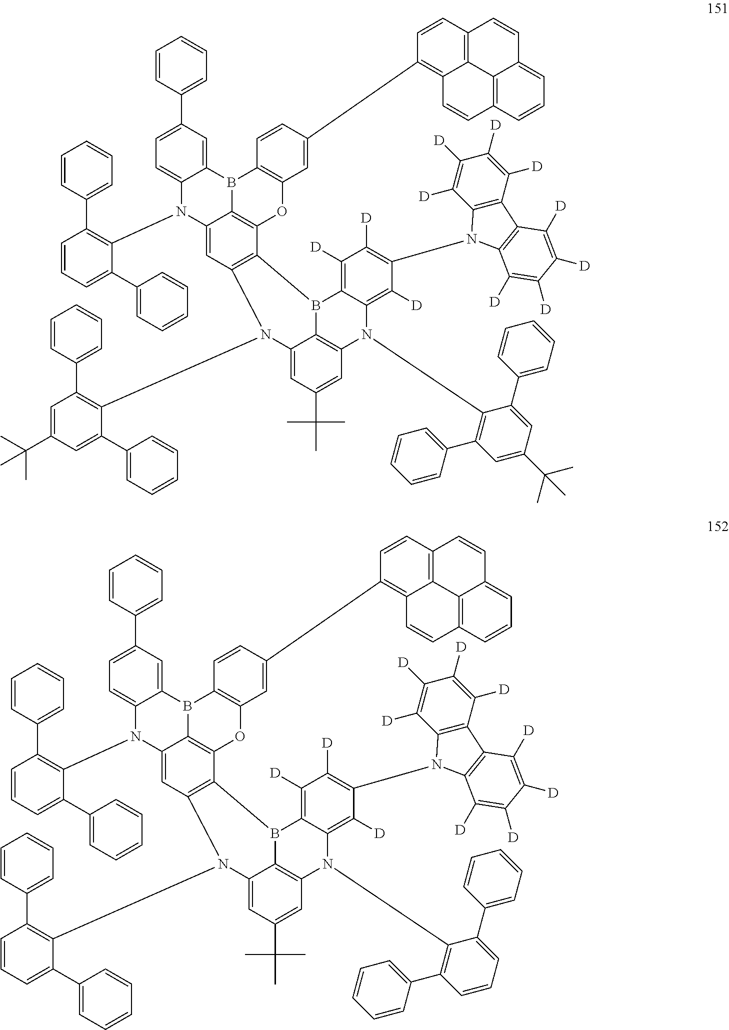

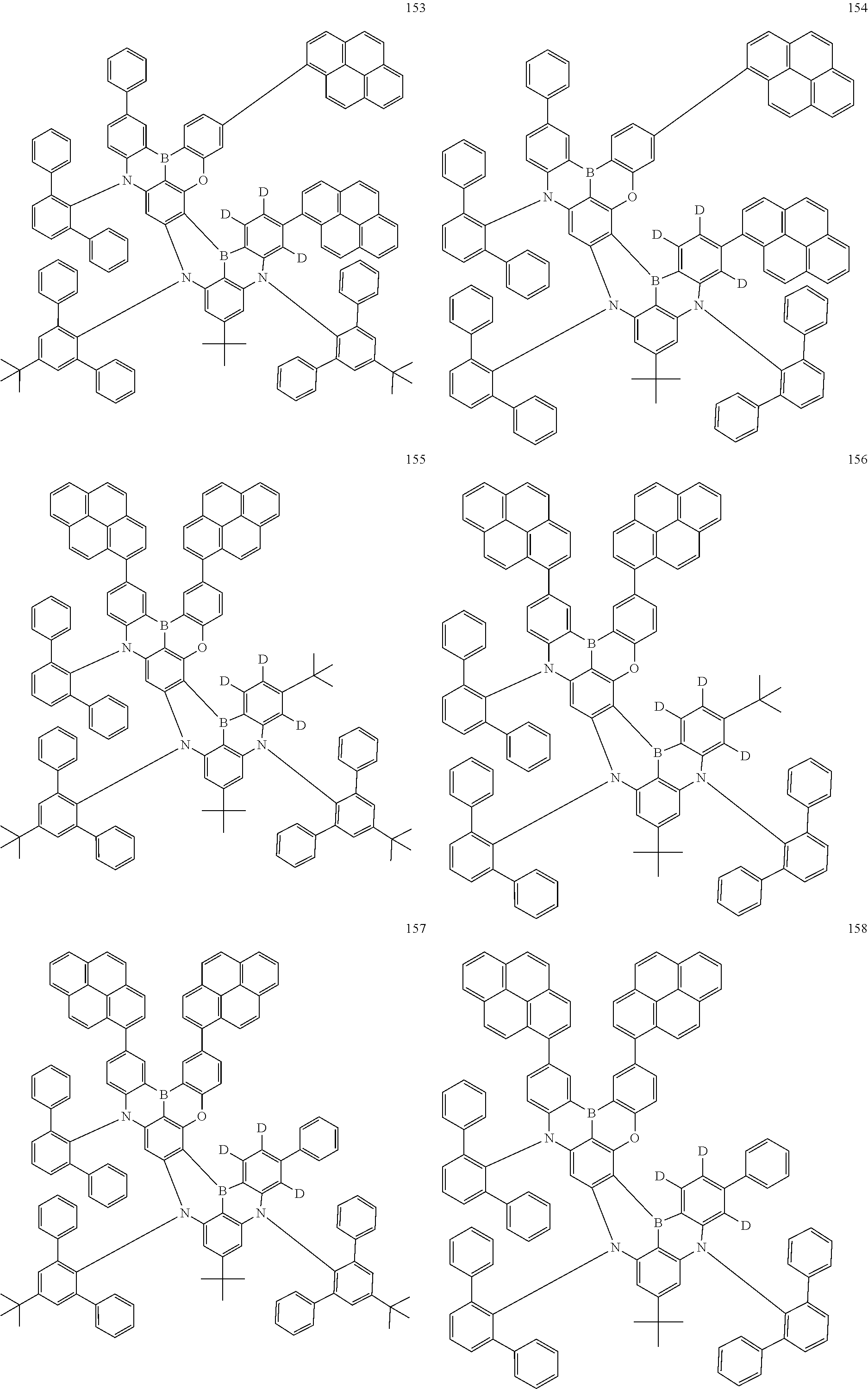

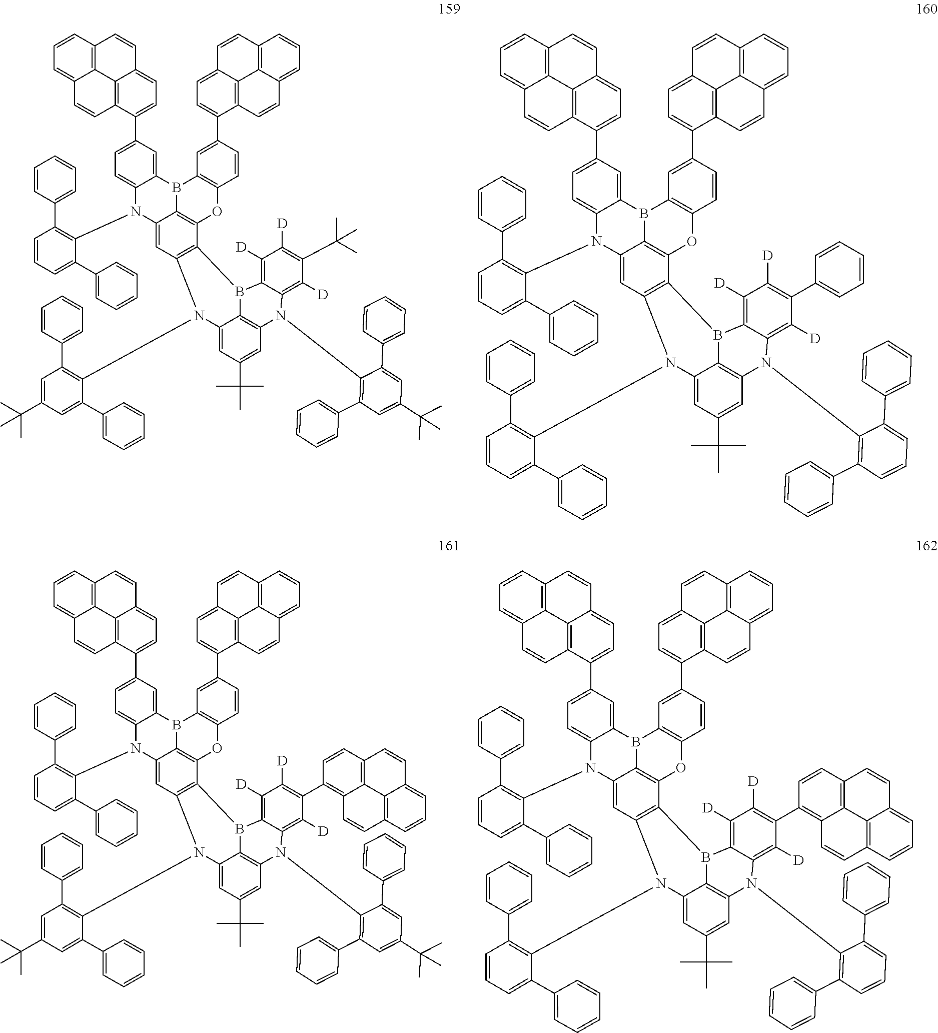

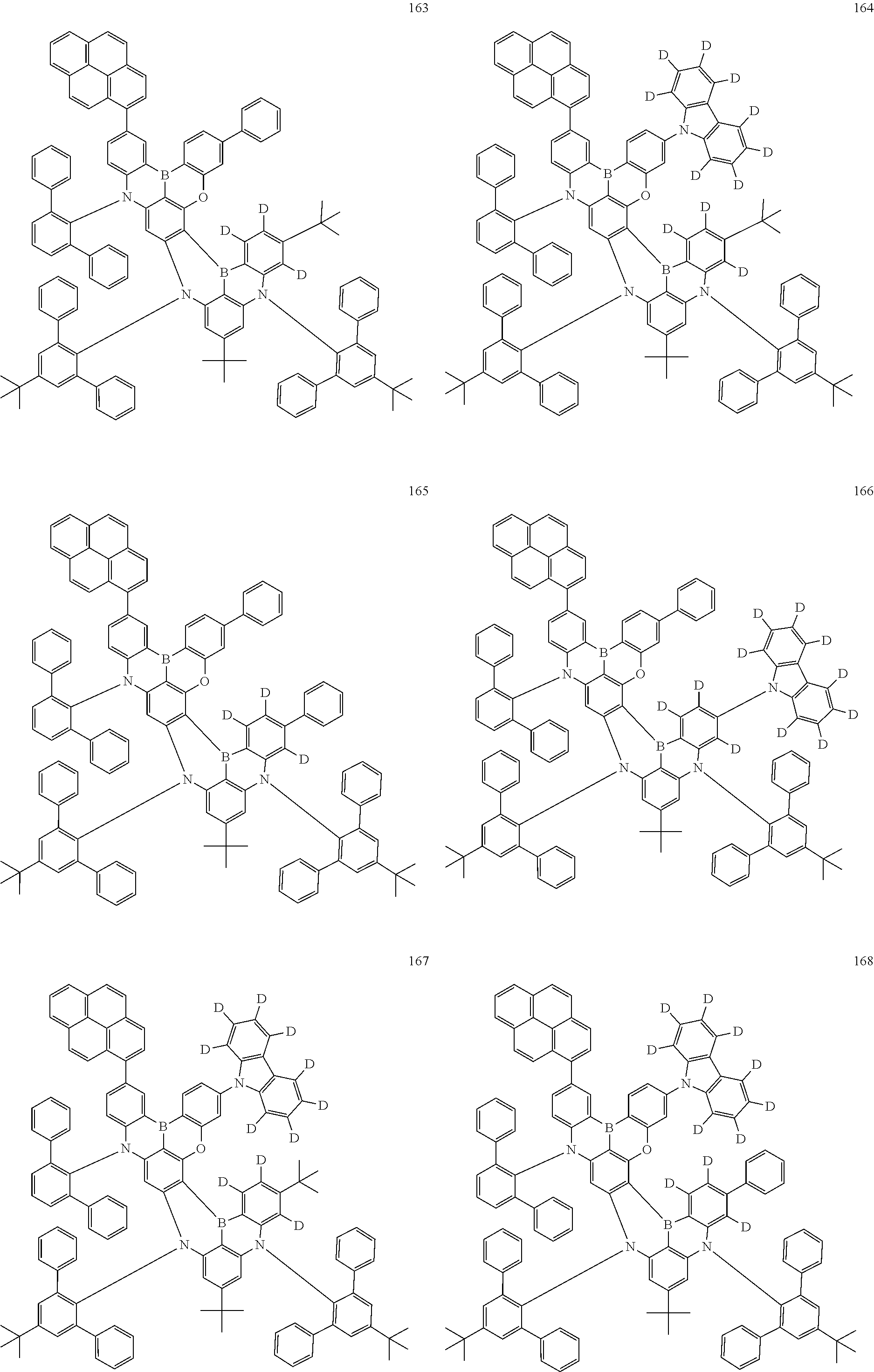

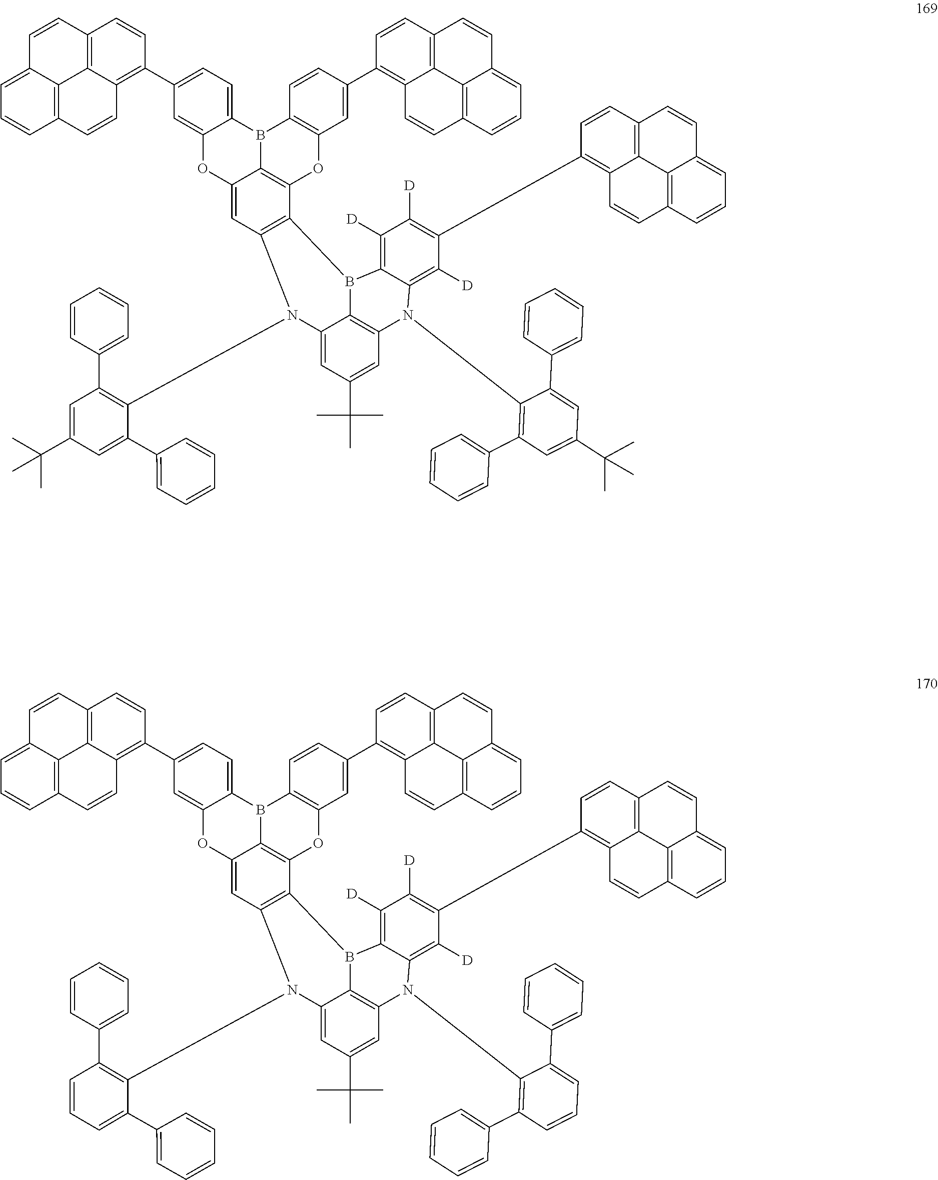 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1O3 ; [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1O3]

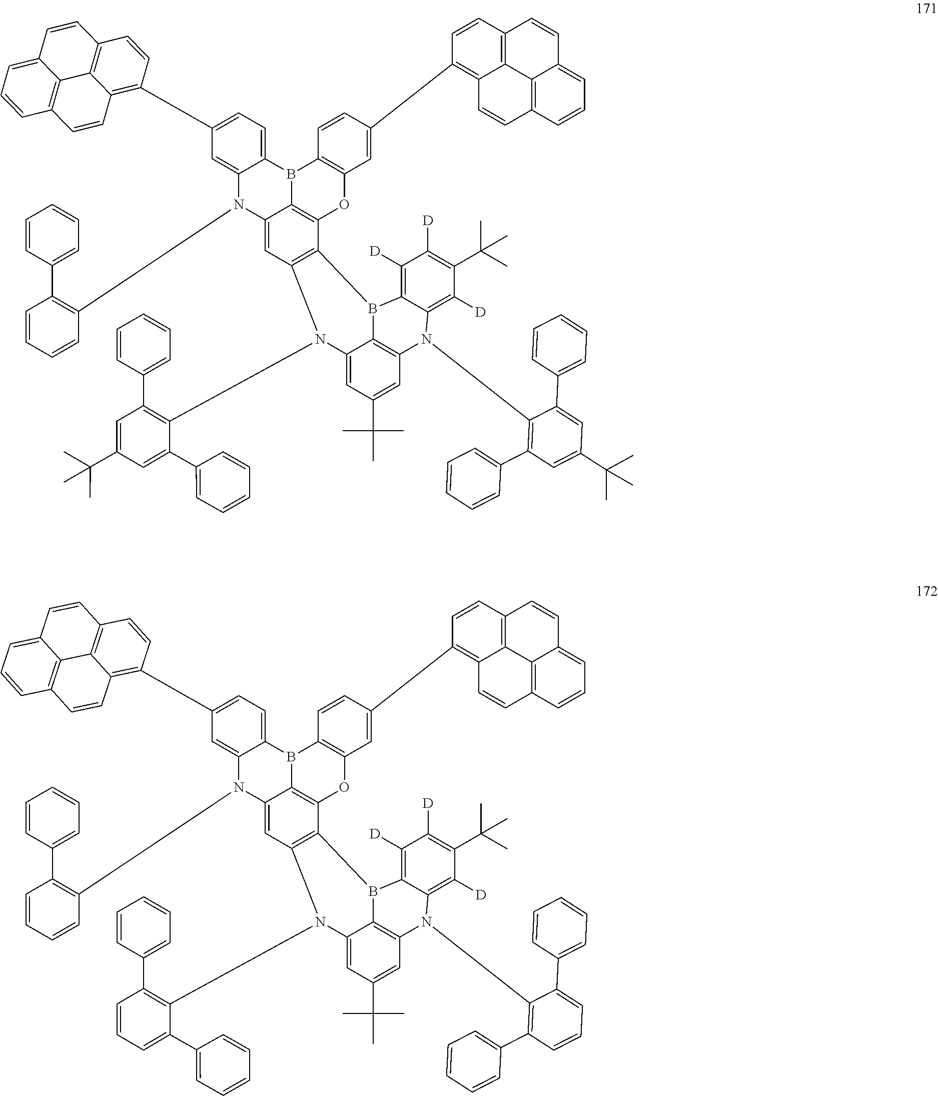 [SMILES: [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1 ; [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1]

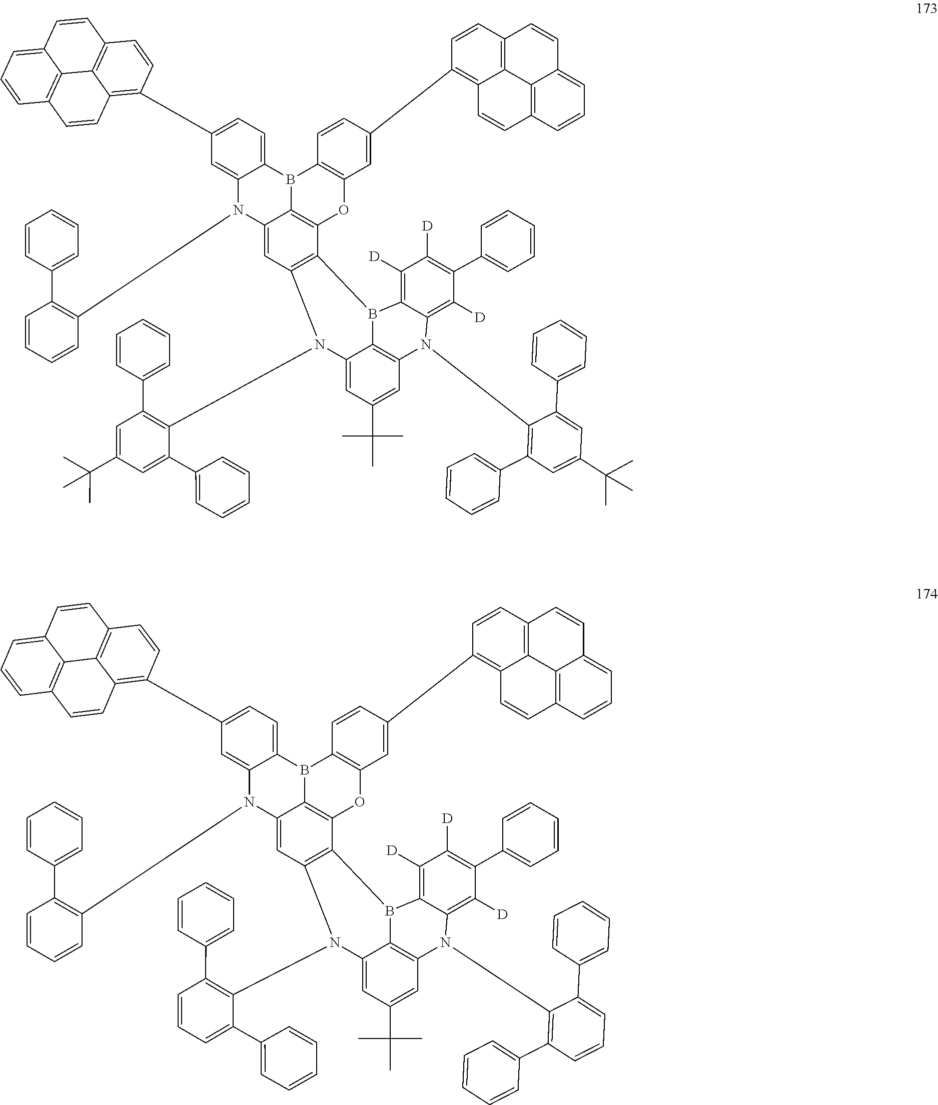 [SMILES: [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1 ; [2H]c1c([2H])c(-c2ccccc2)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1]

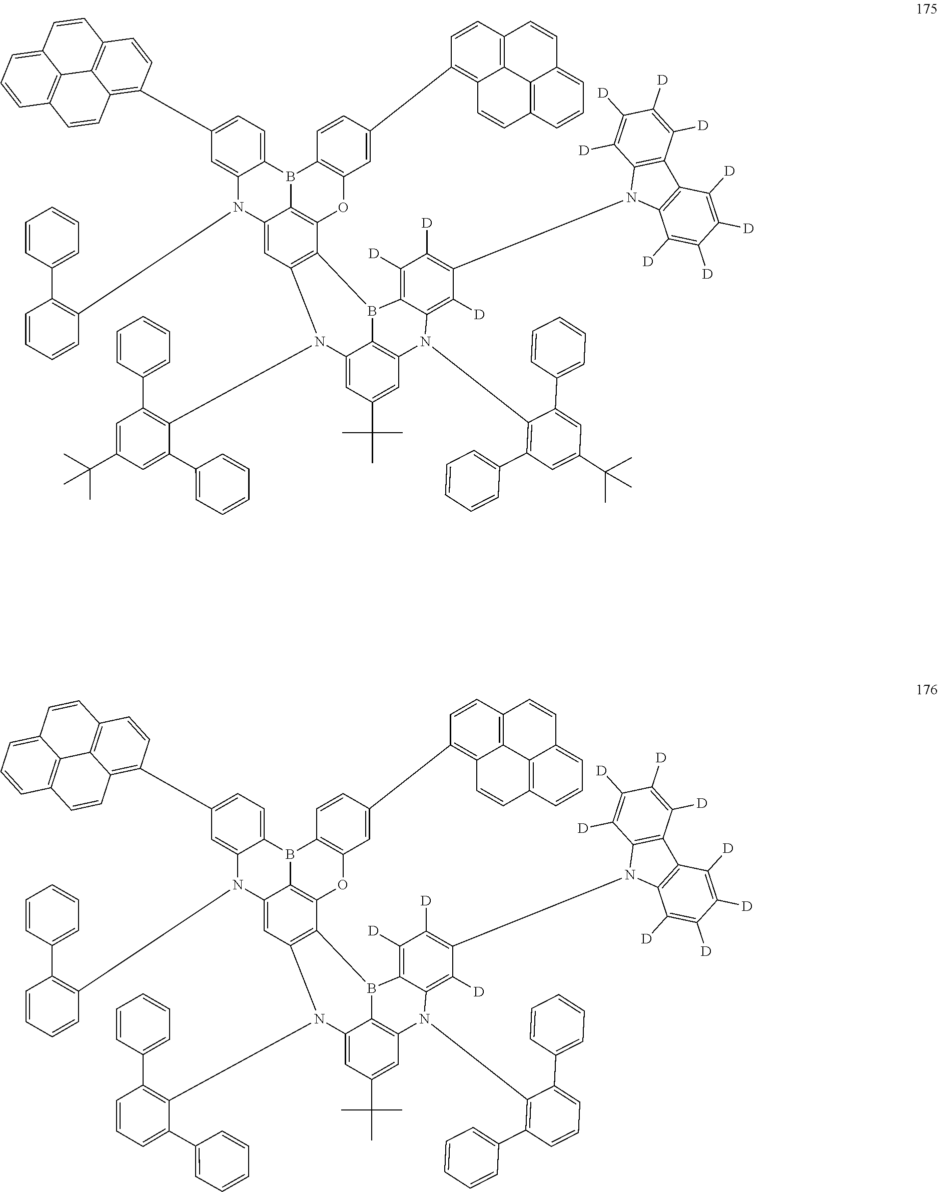

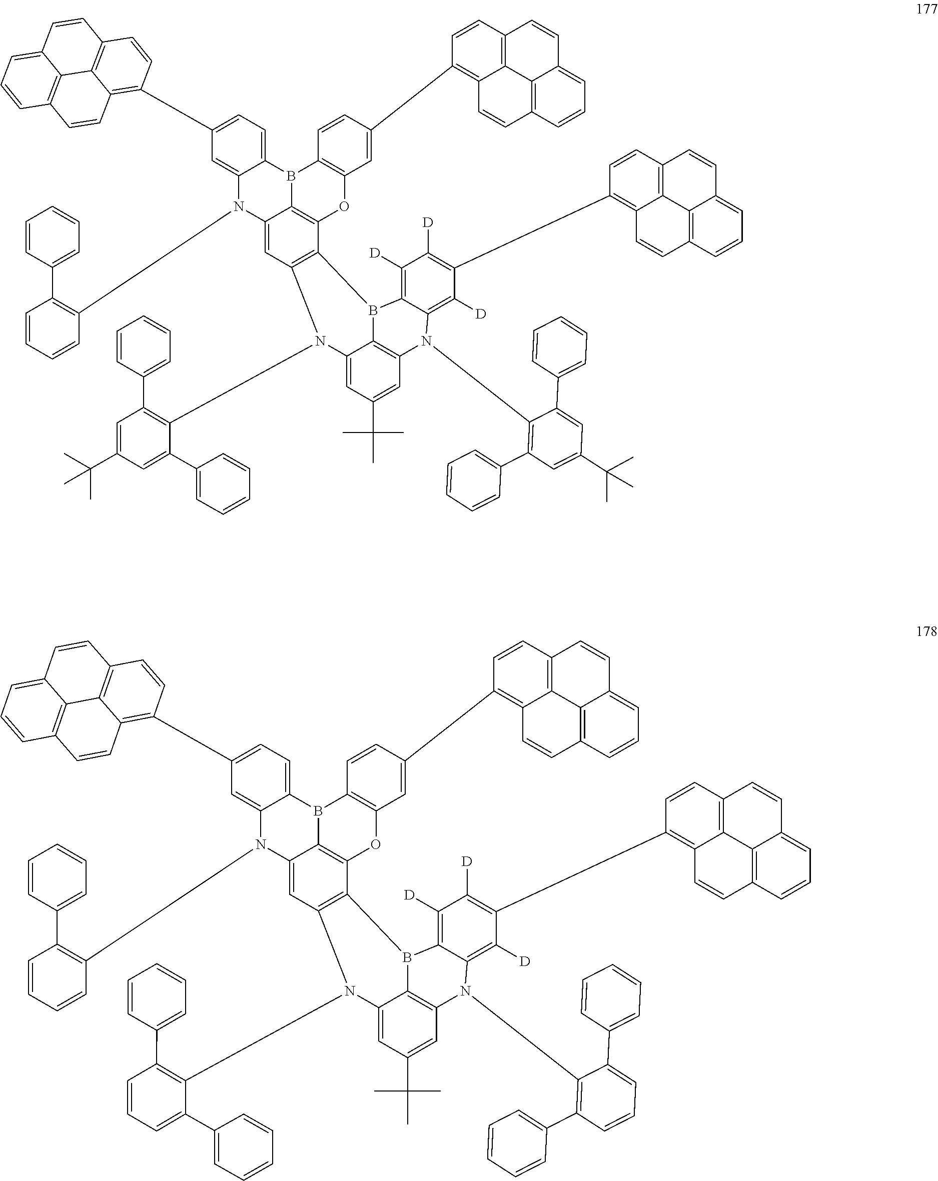

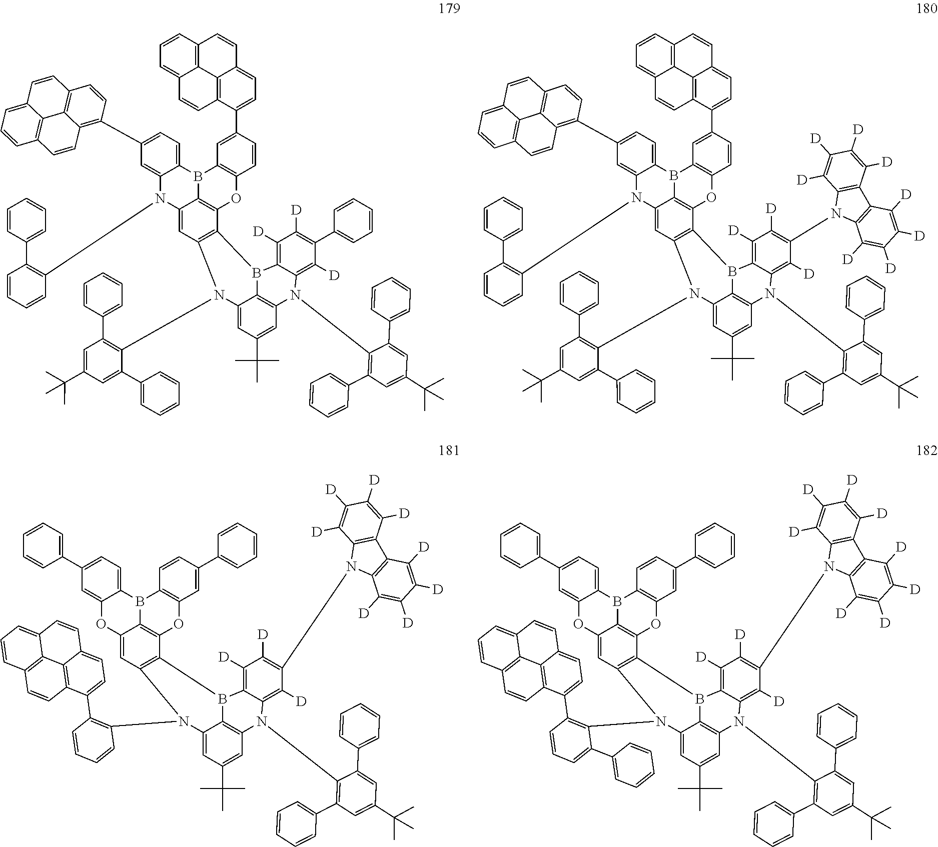

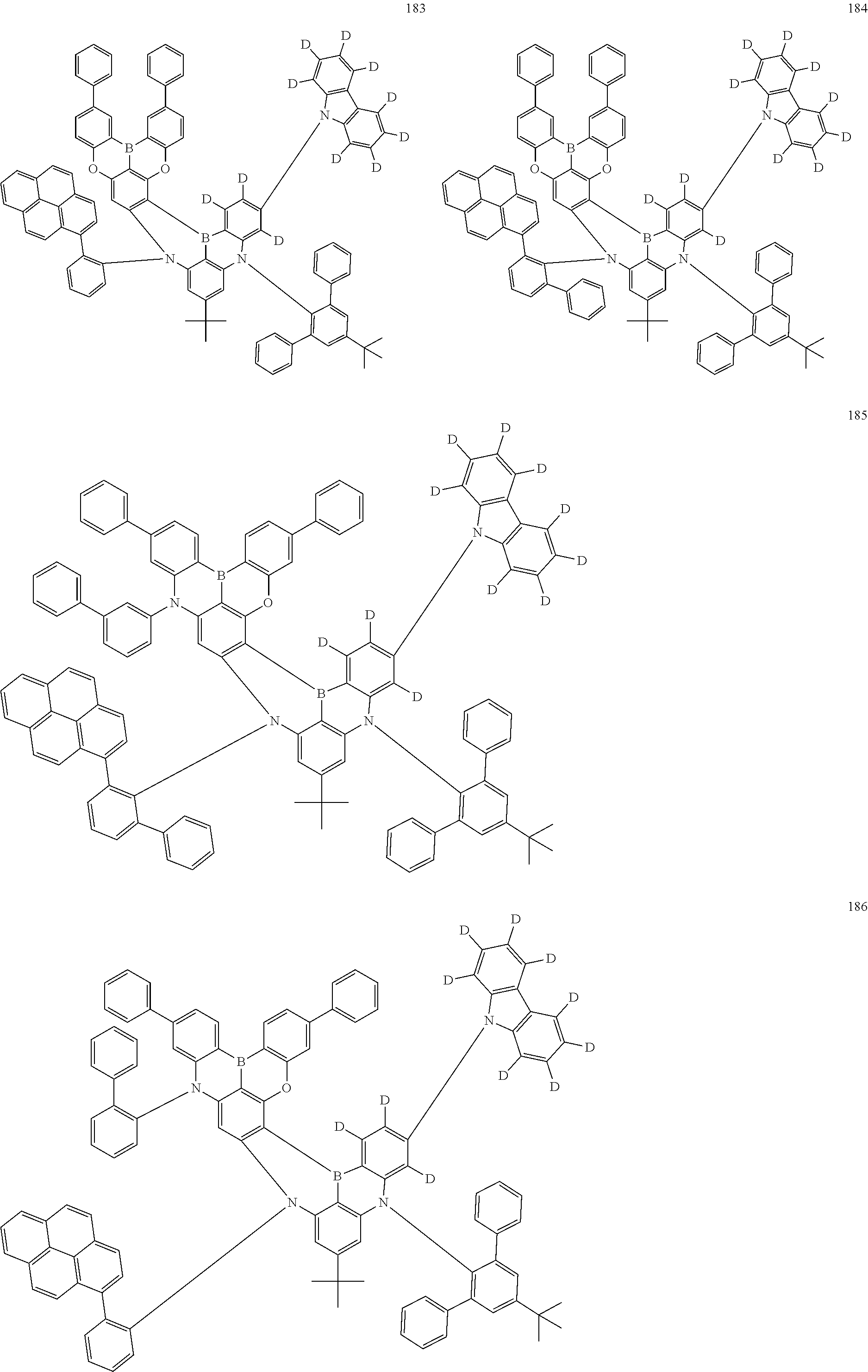

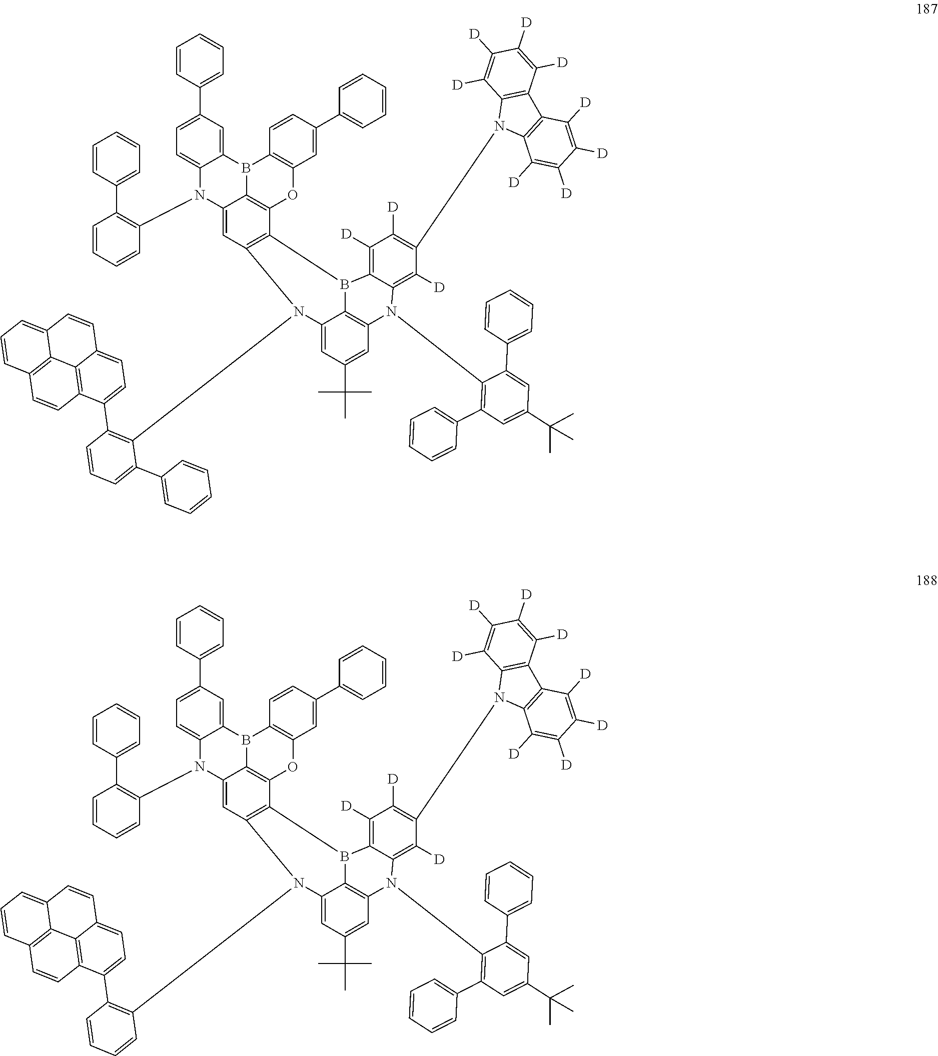

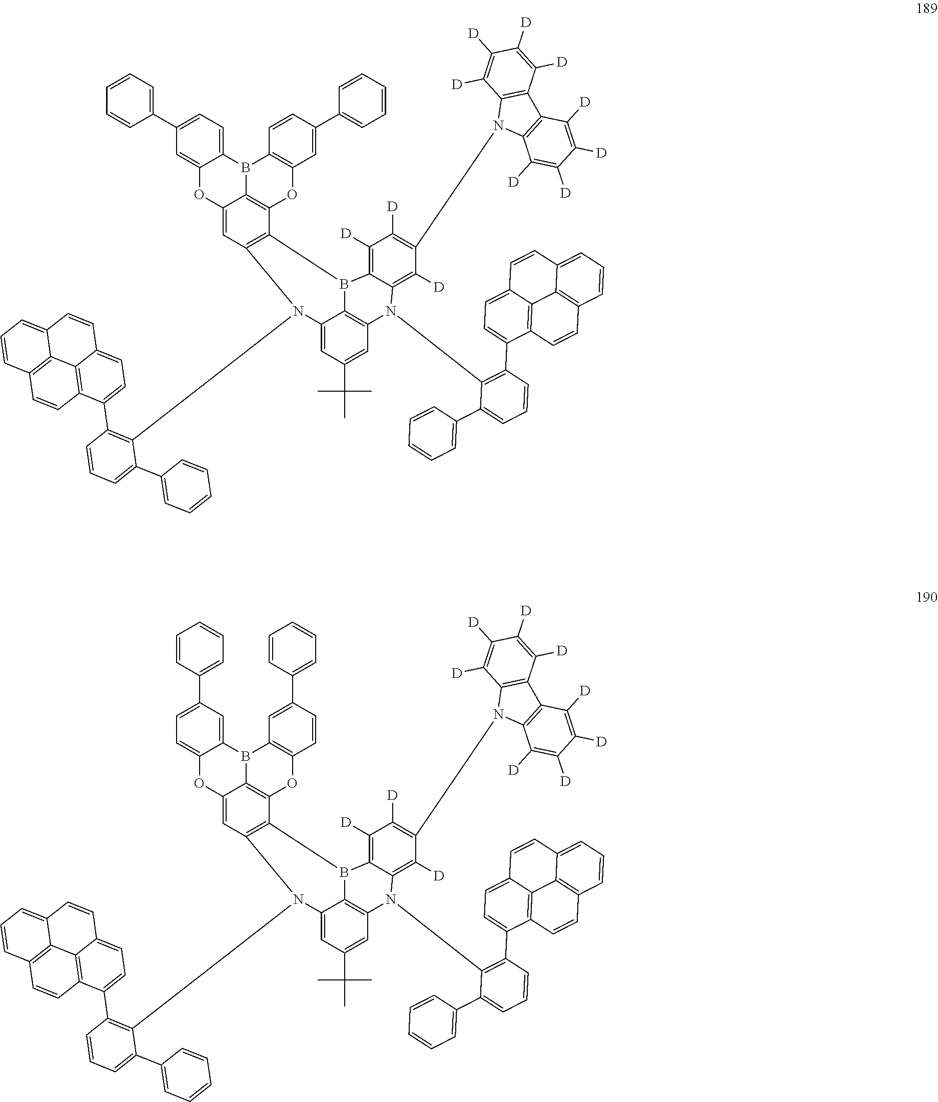

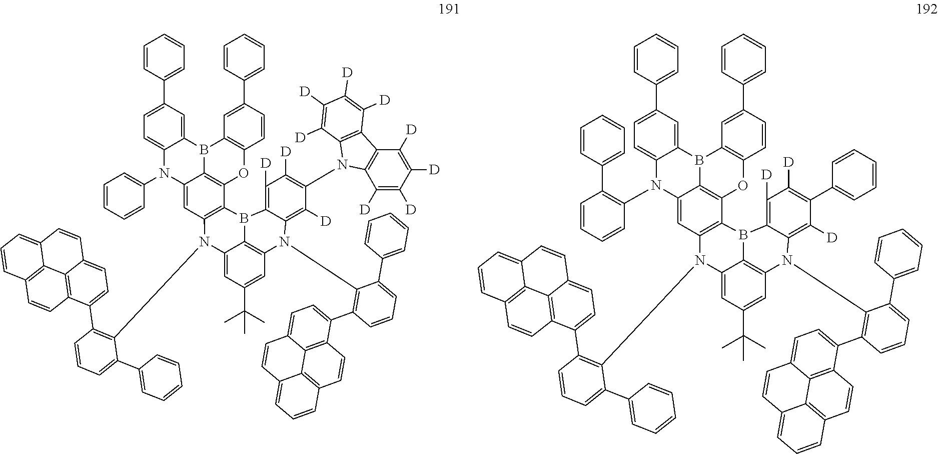

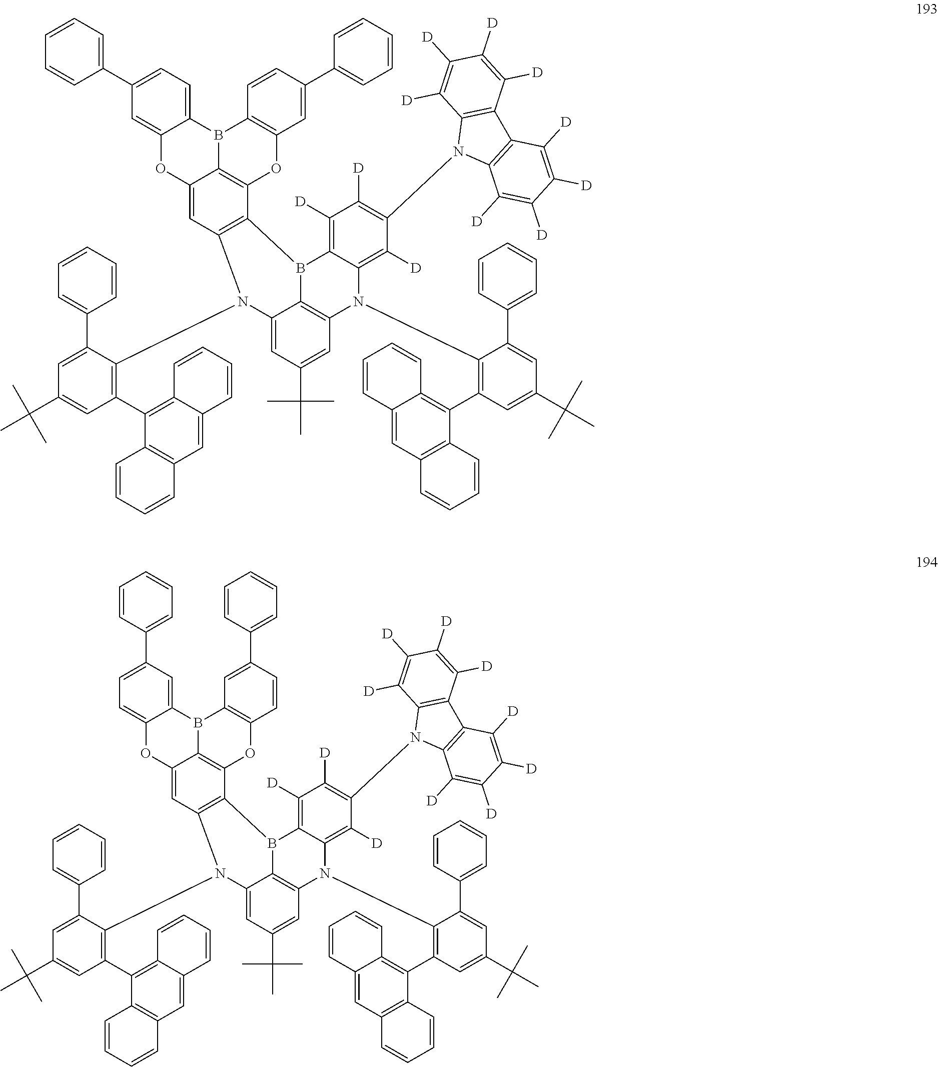

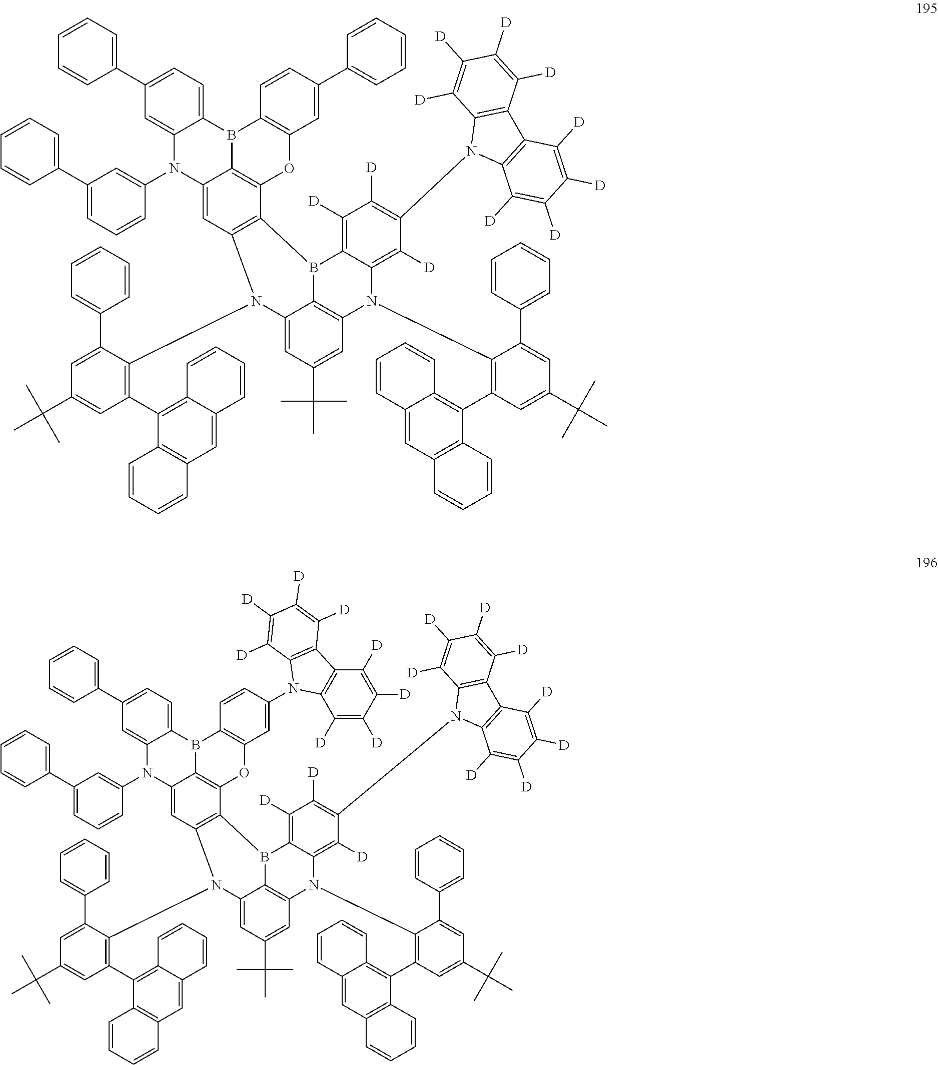

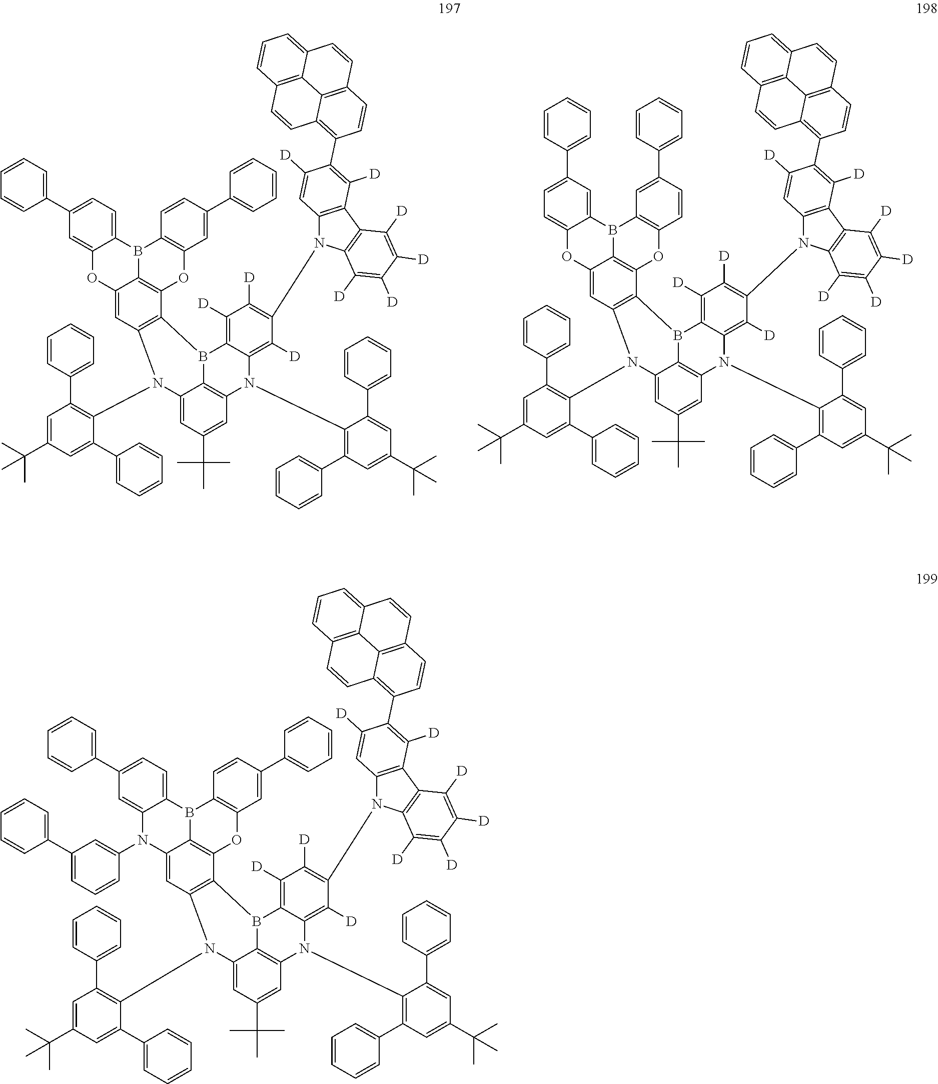

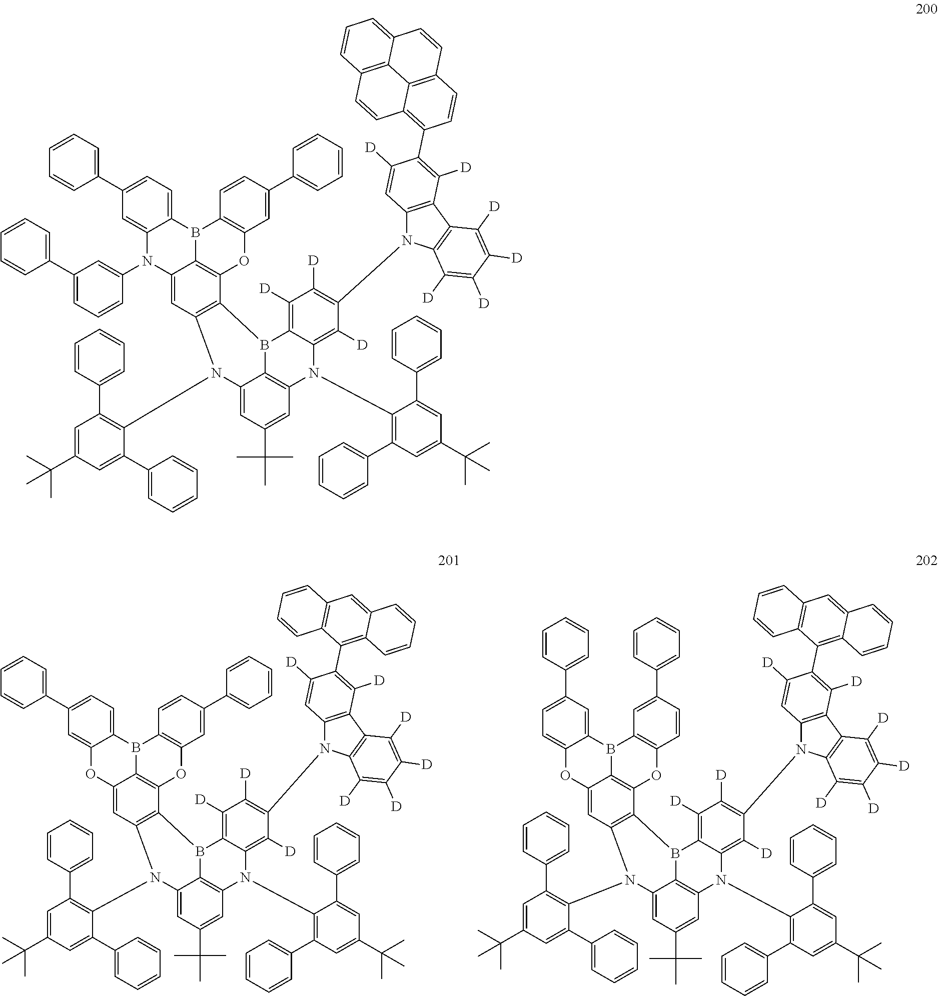

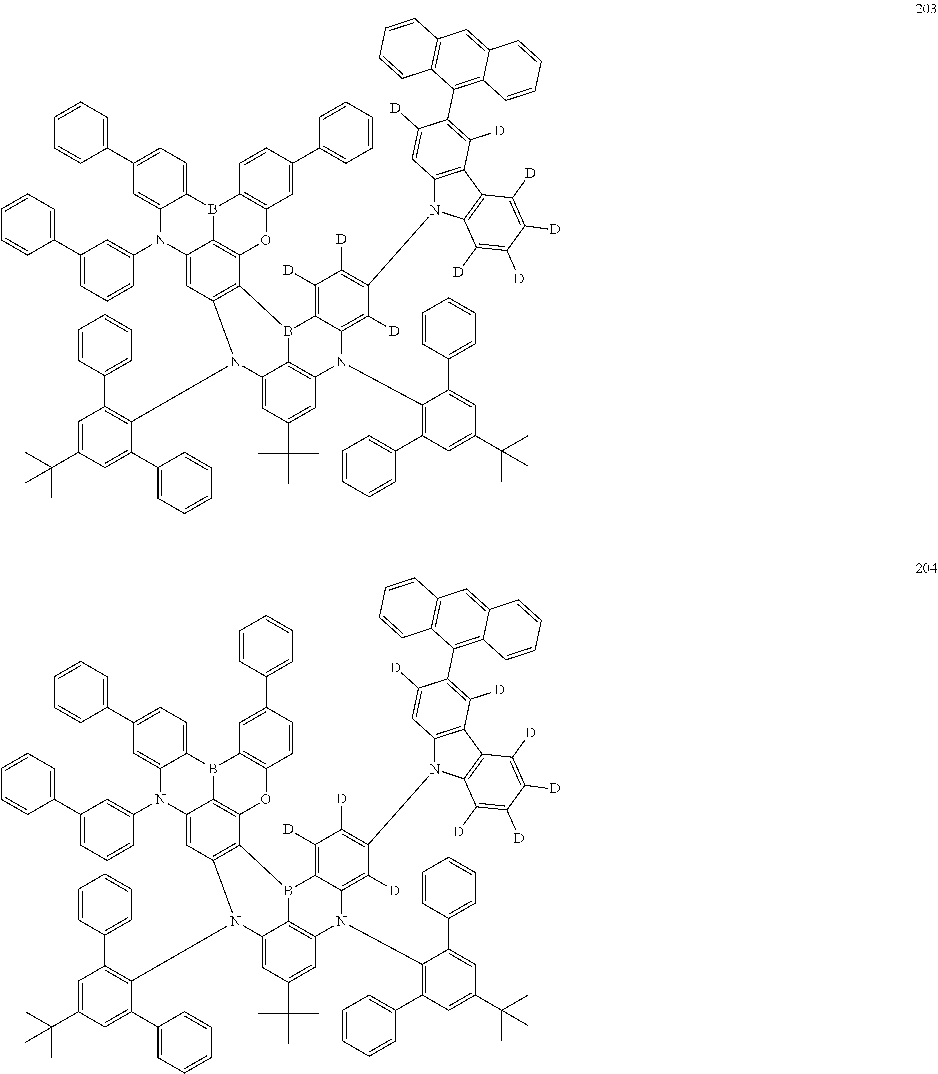

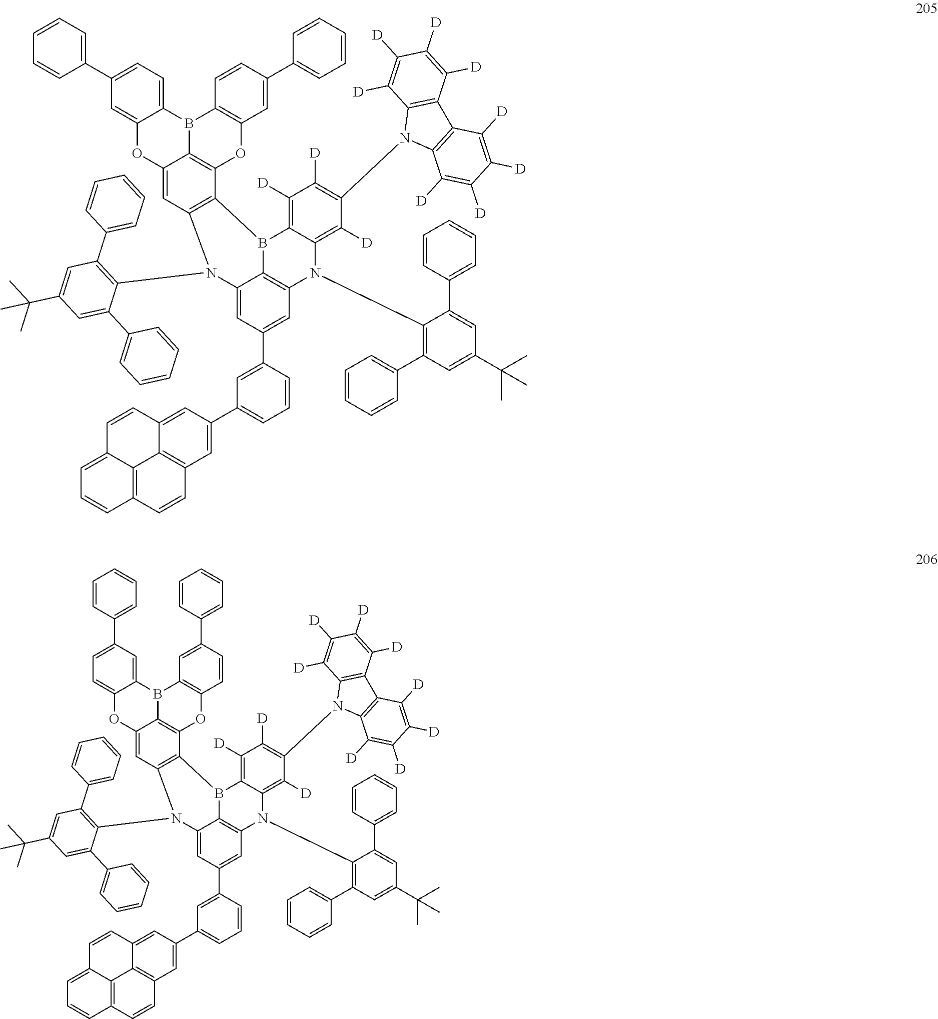

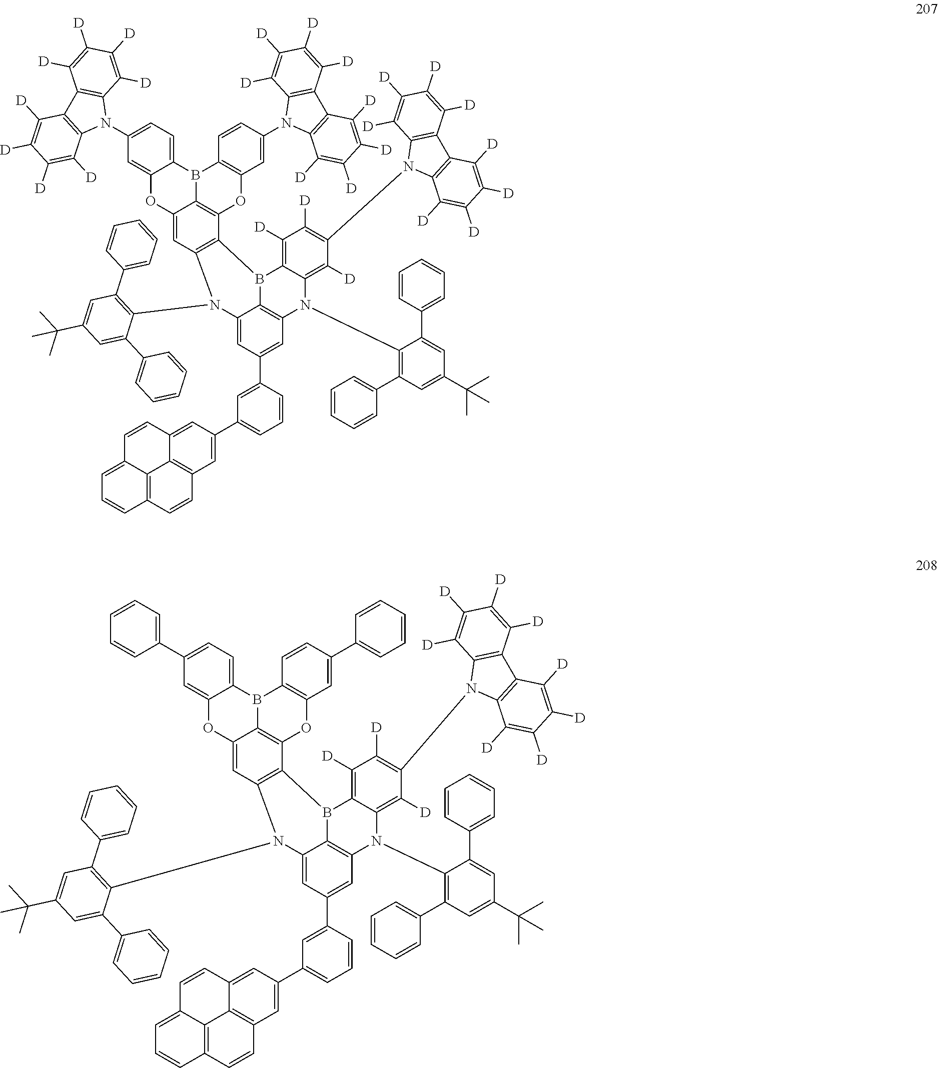

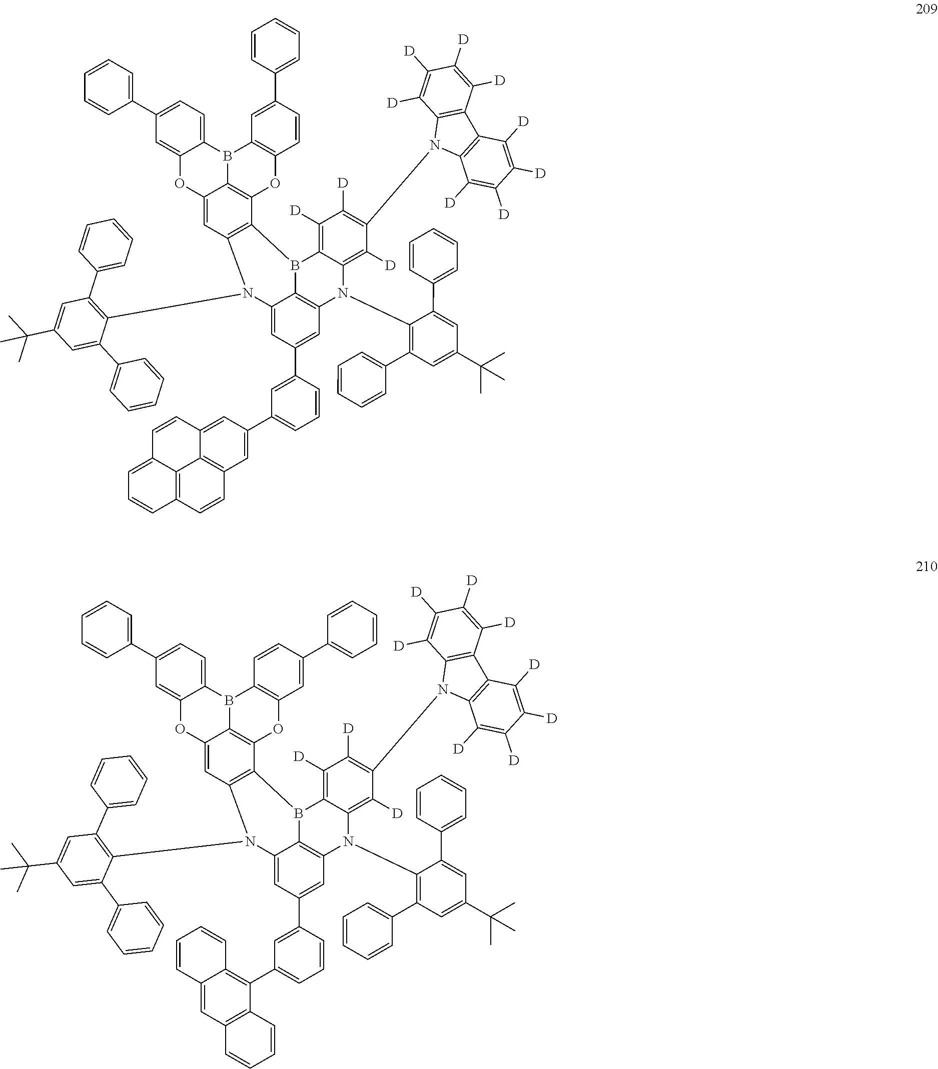

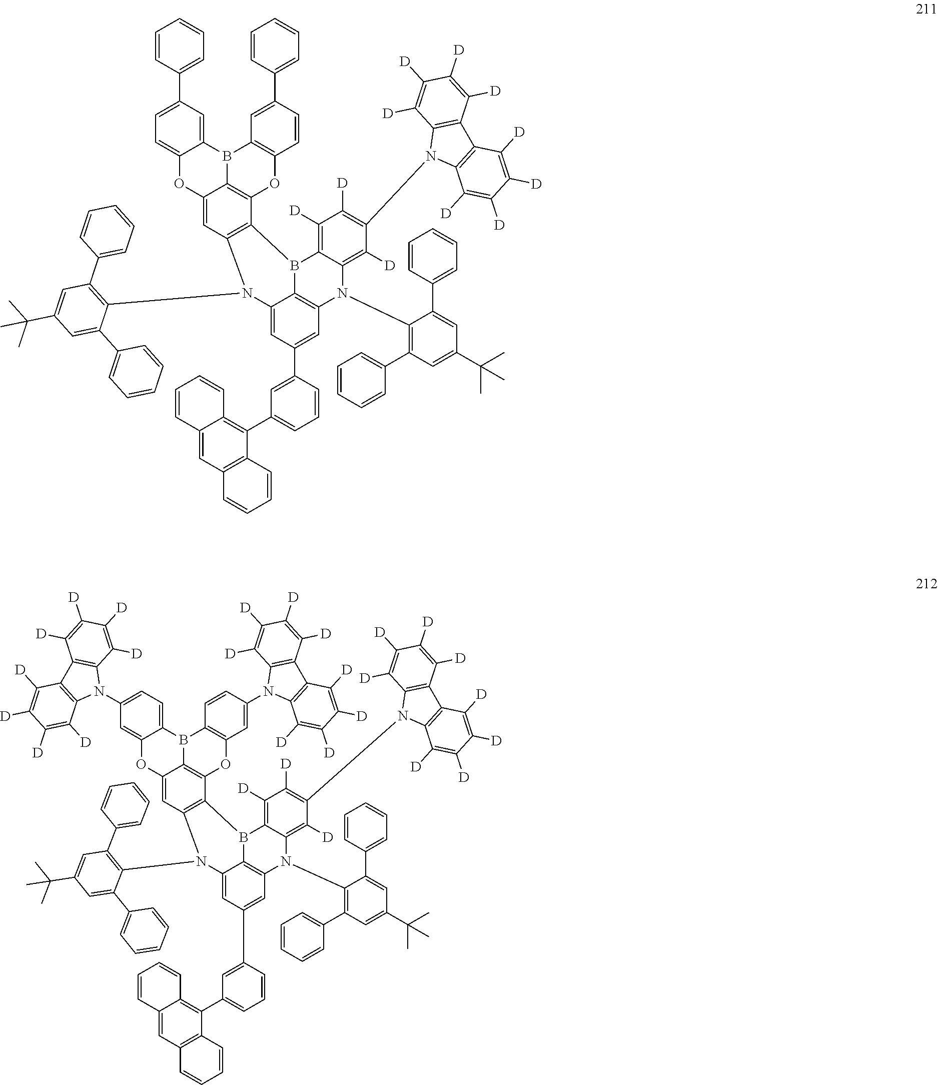

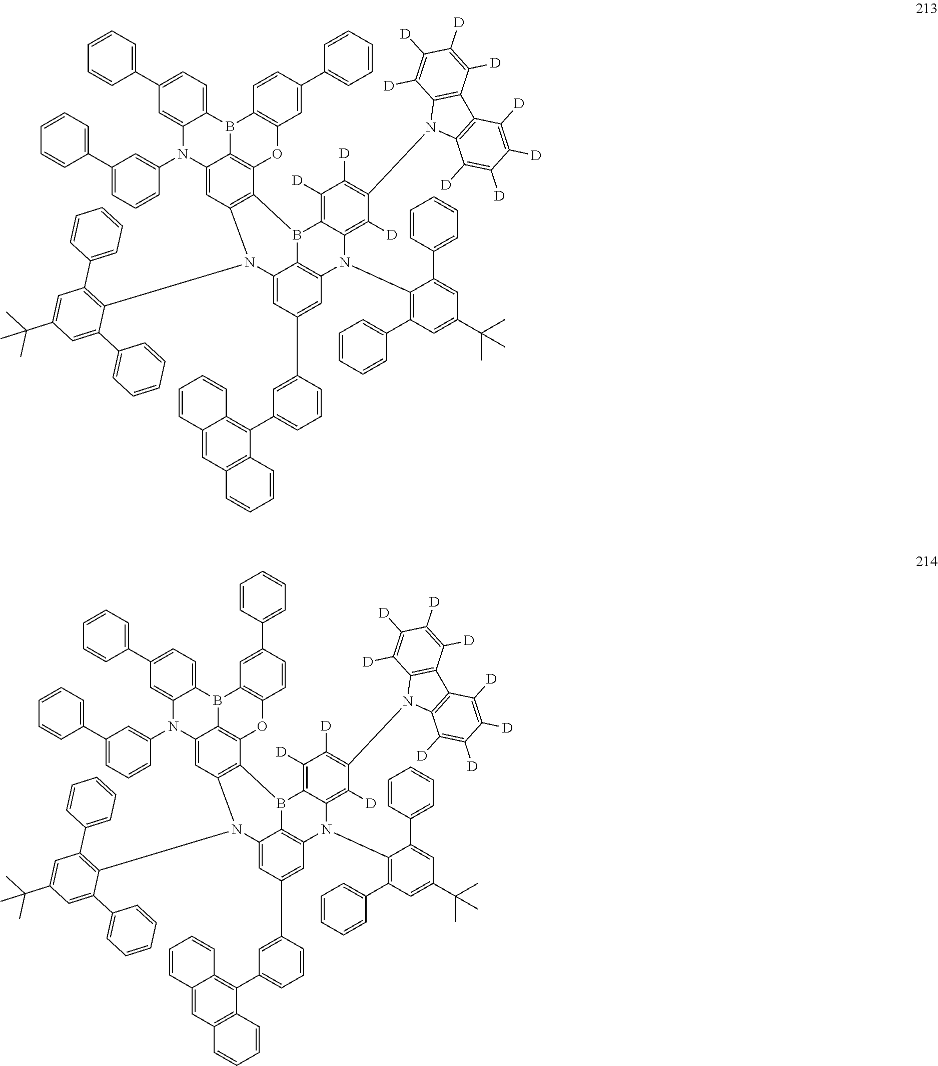

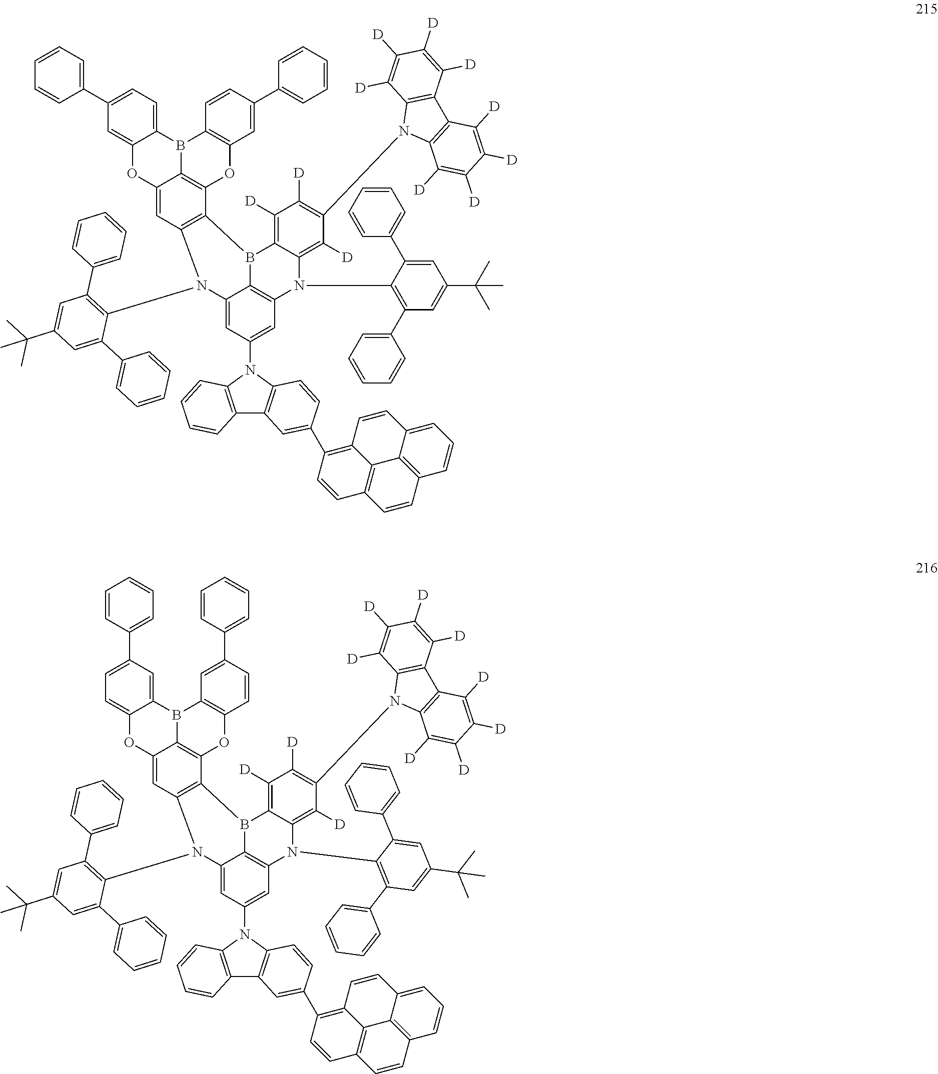

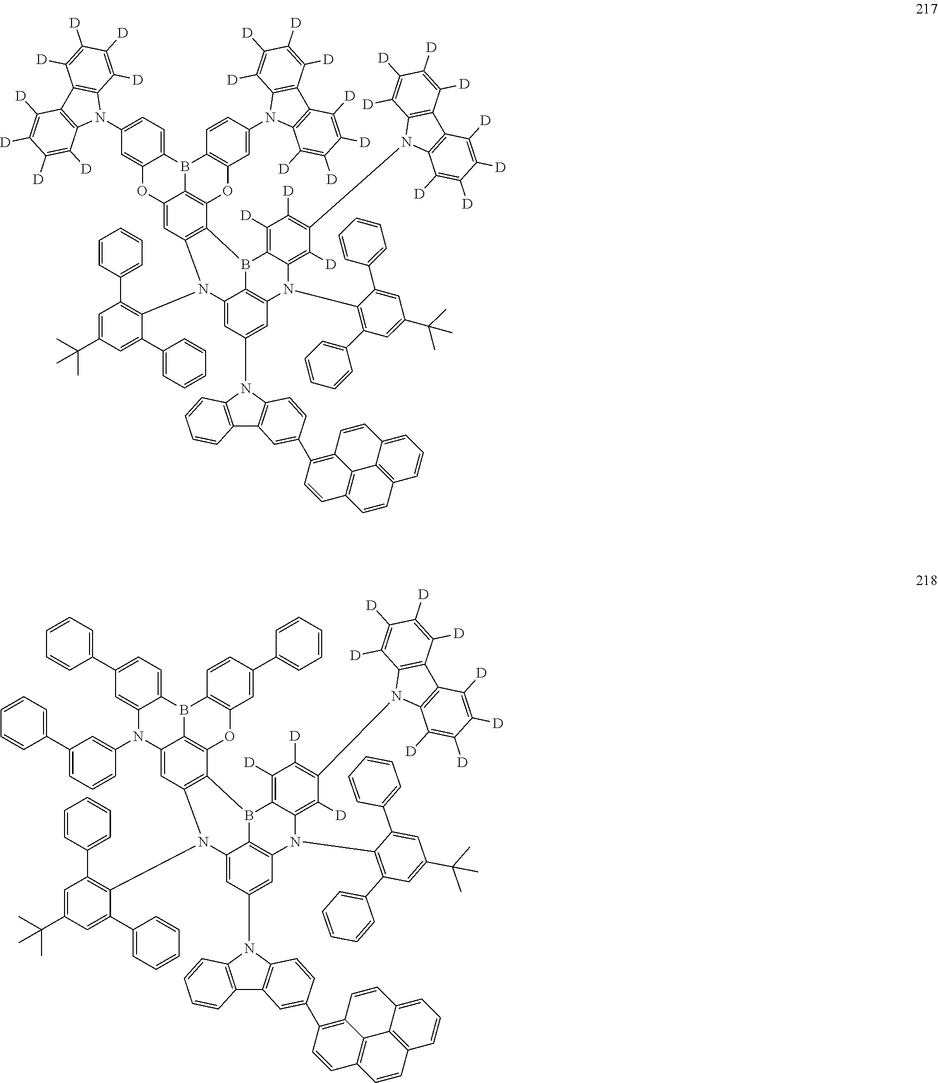

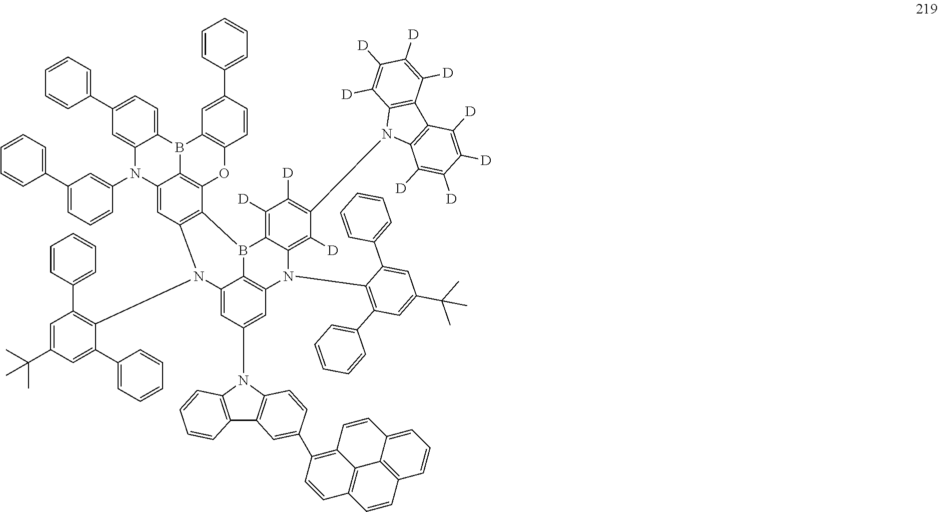 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(-n4c5ccccc5c5cc(-c6ccc7ccc8cccc9ccc6c7c89)ccc54)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1ccc(-c2ccccc2)cc1B4c1ccc(-c2ccccc2)cc1N3c1cccc(-c2ccccc2)c1]

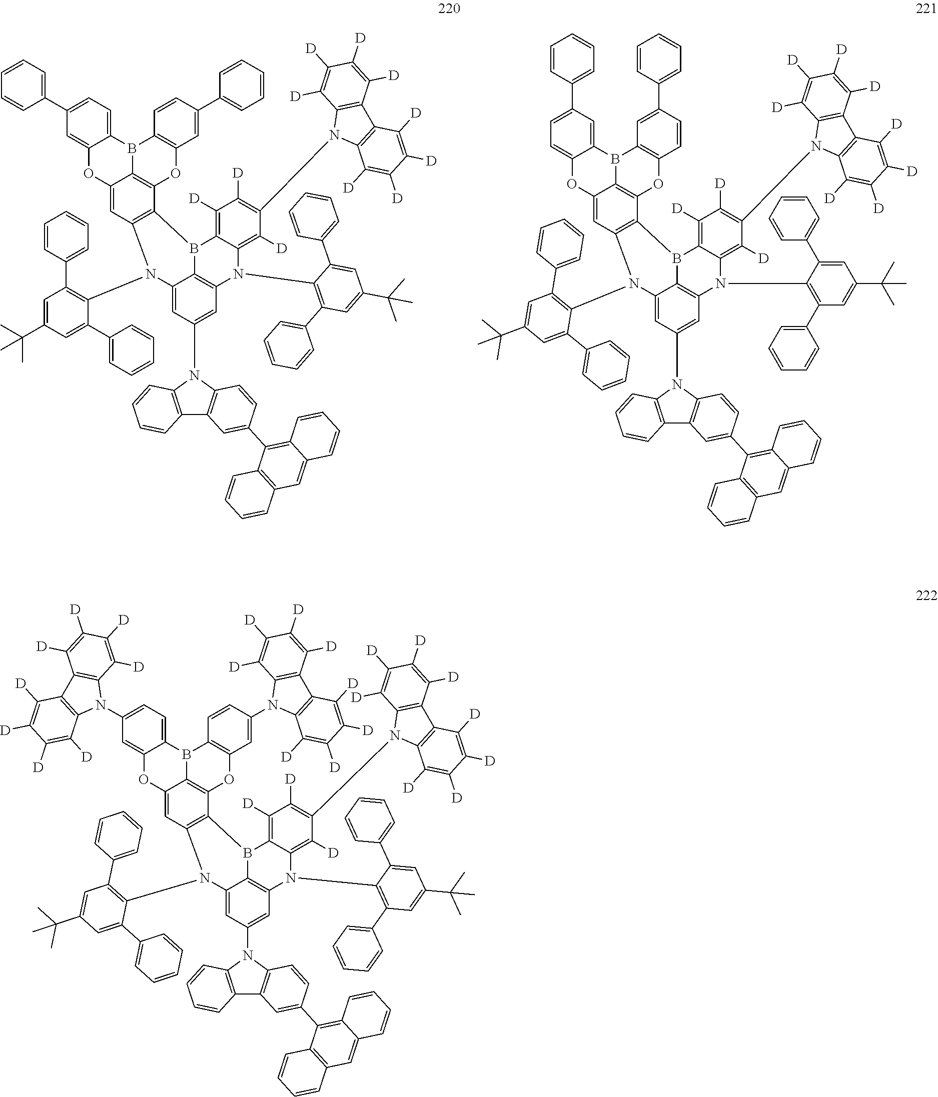

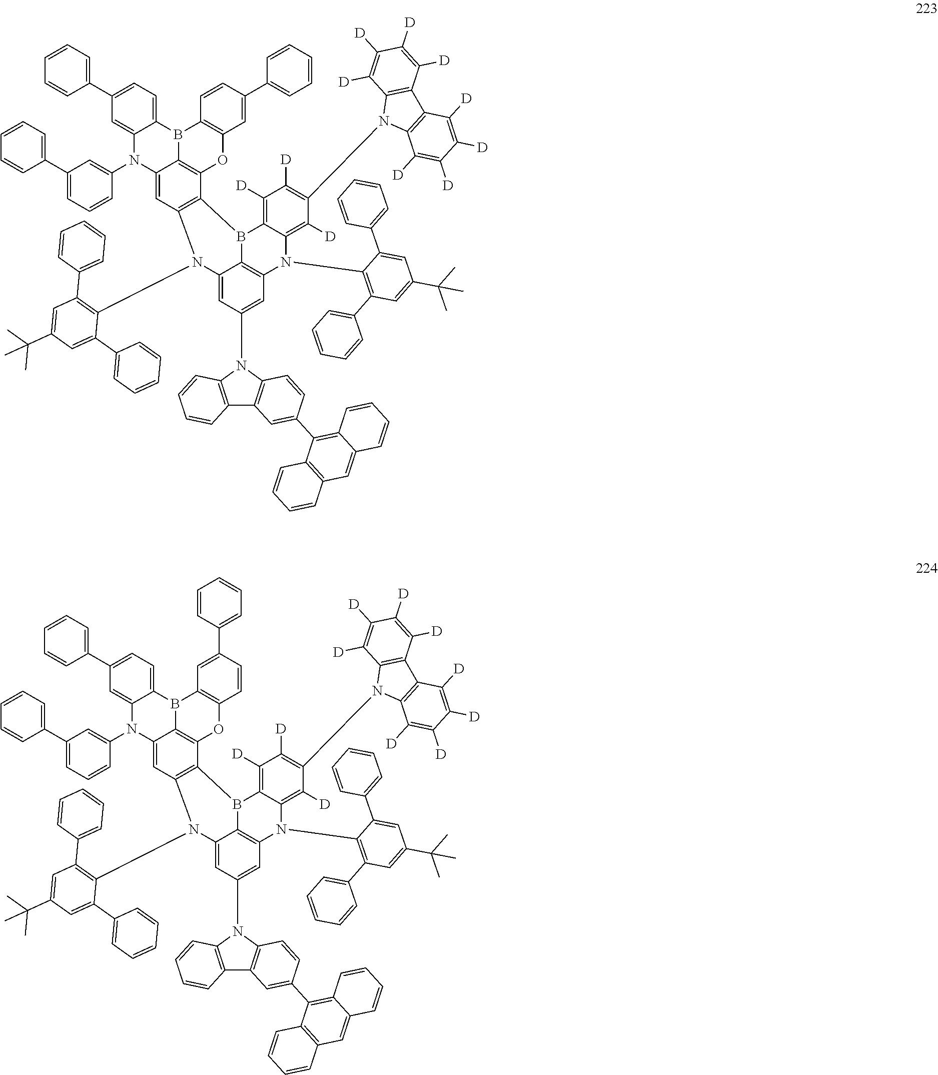

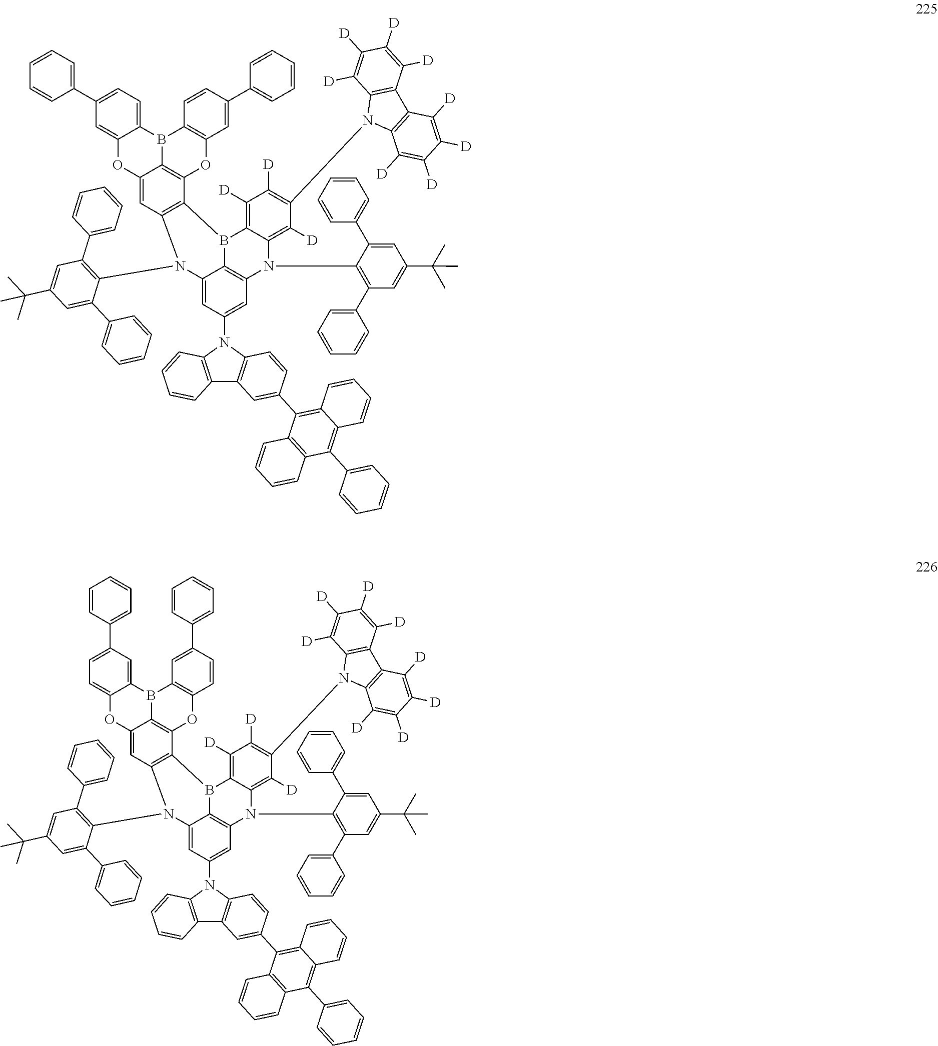

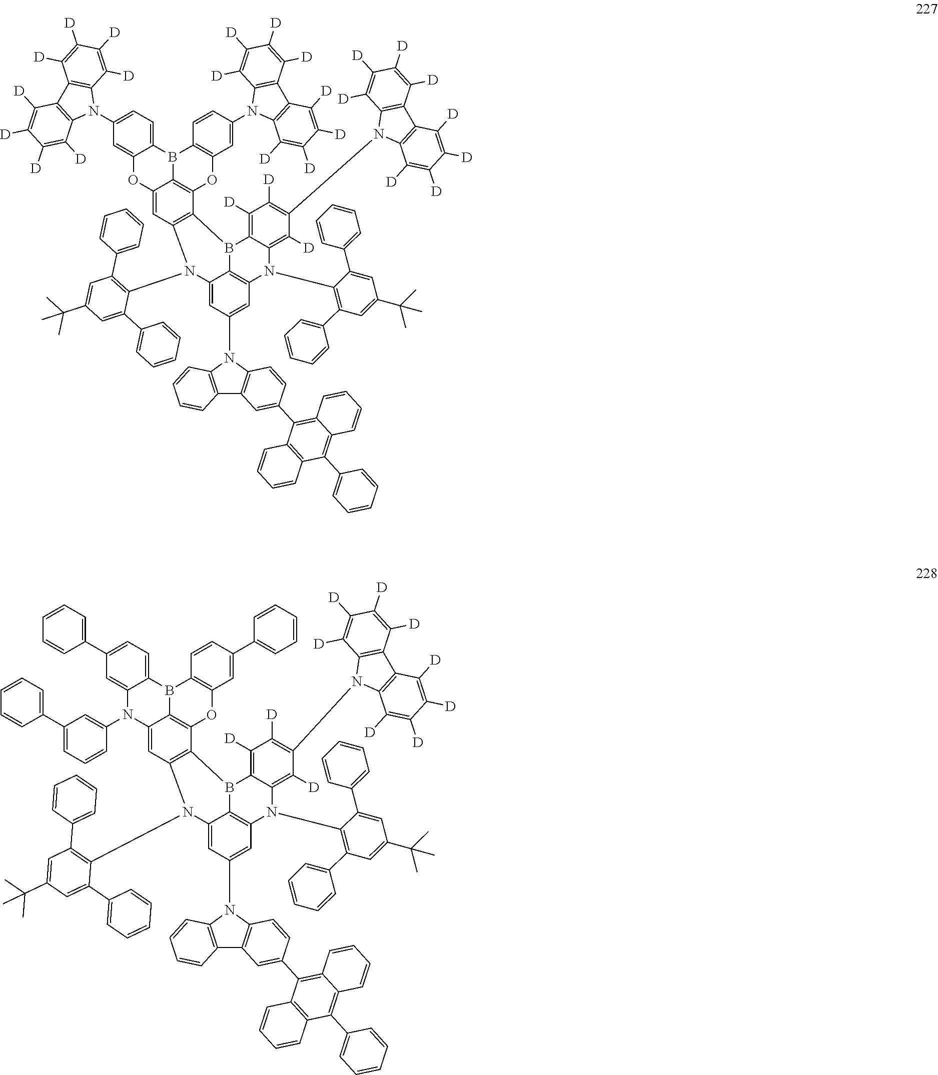

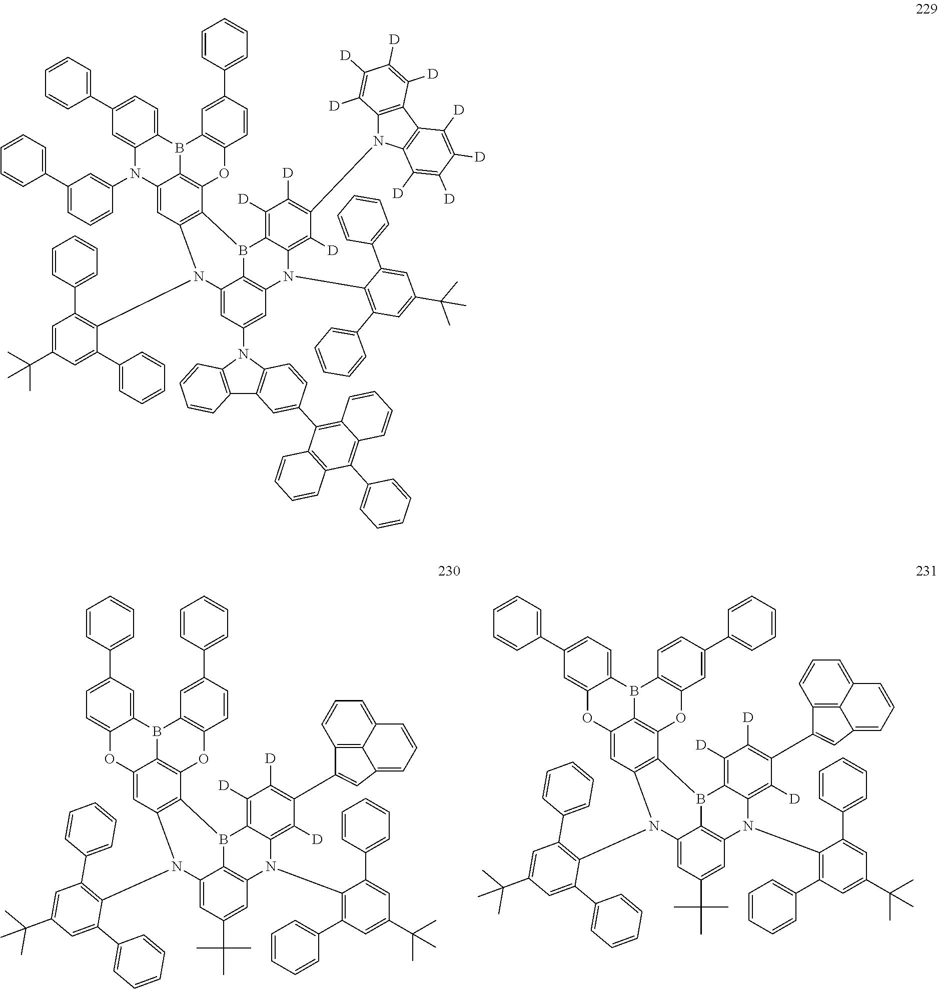

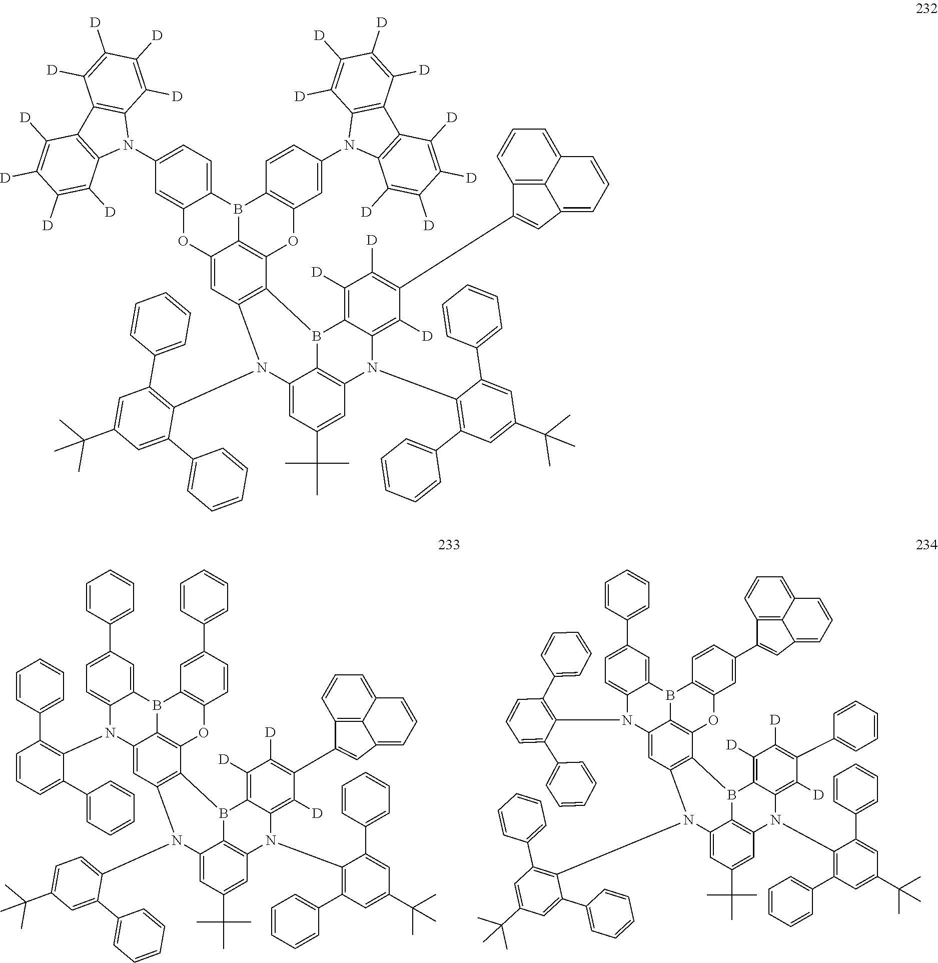

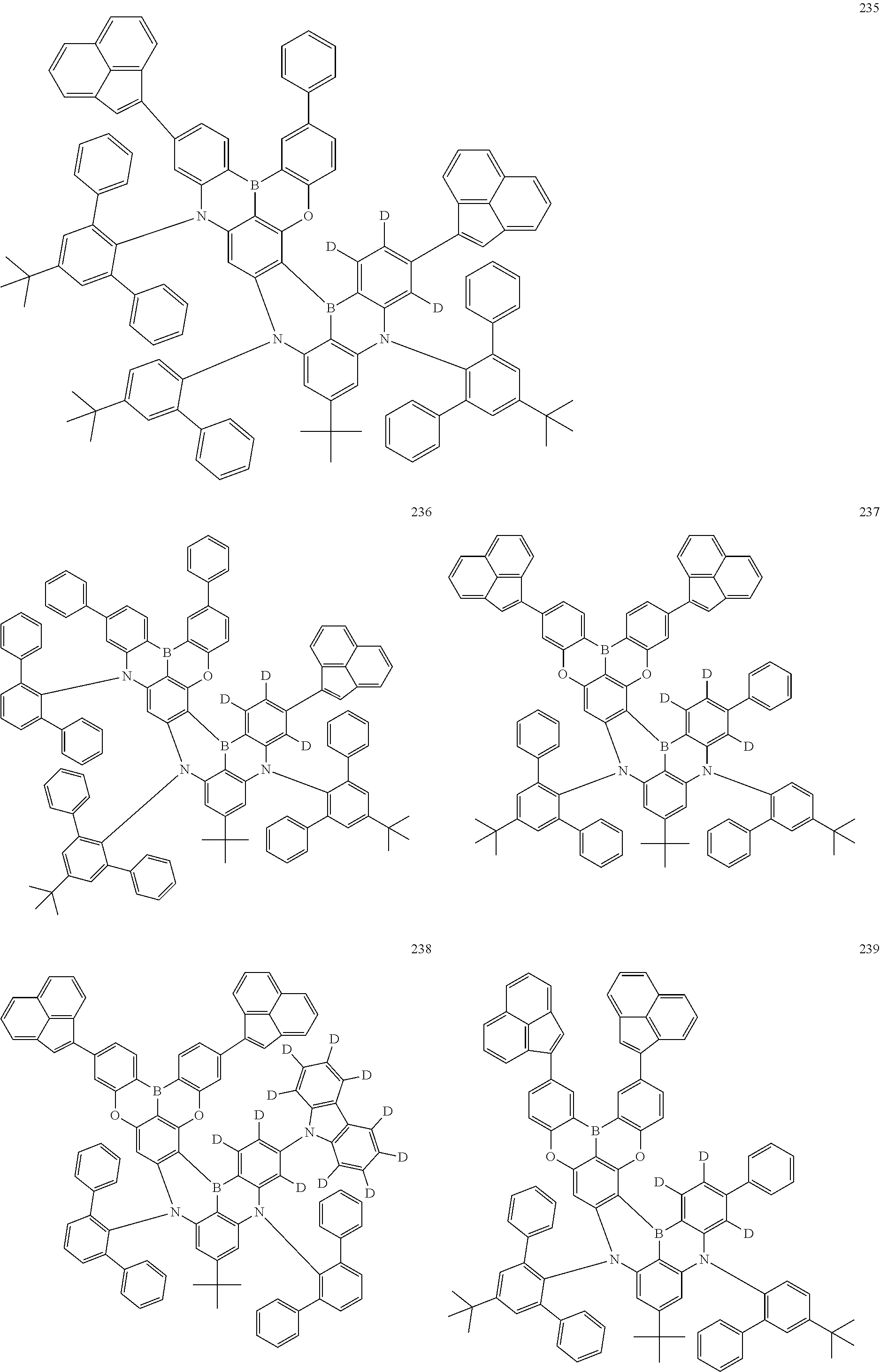

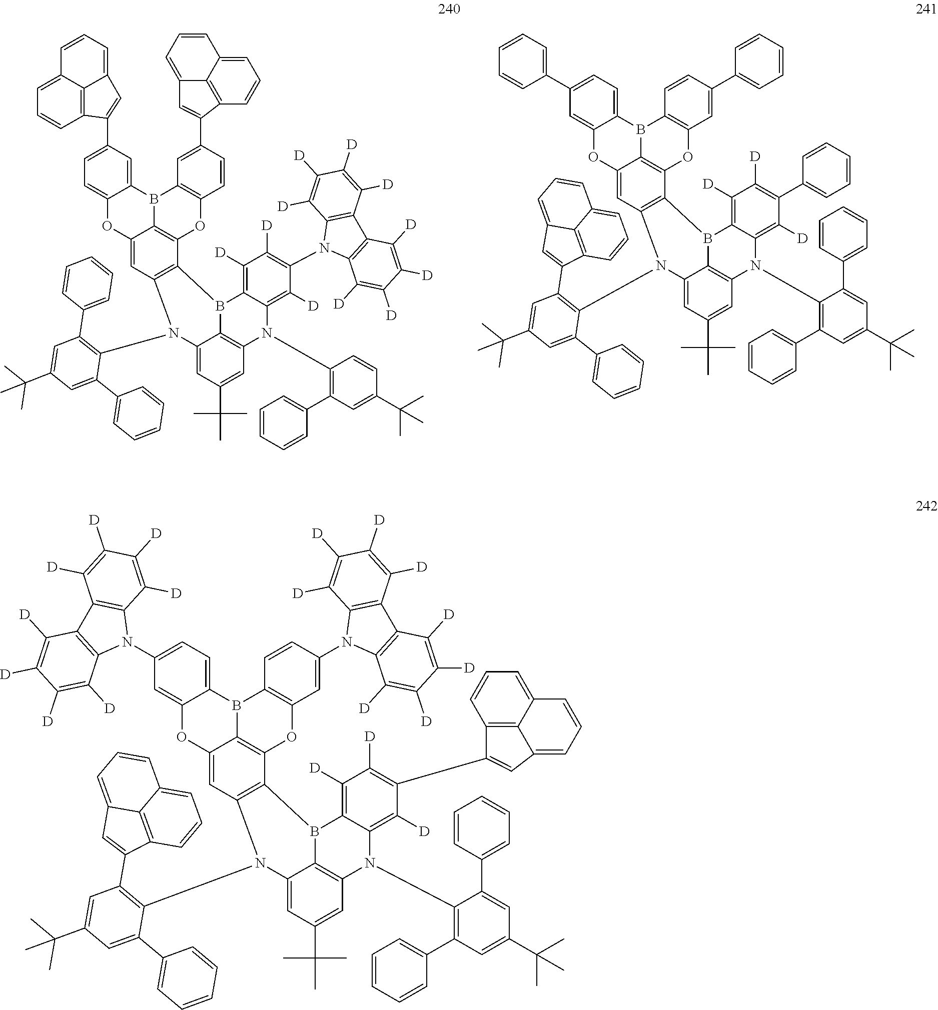

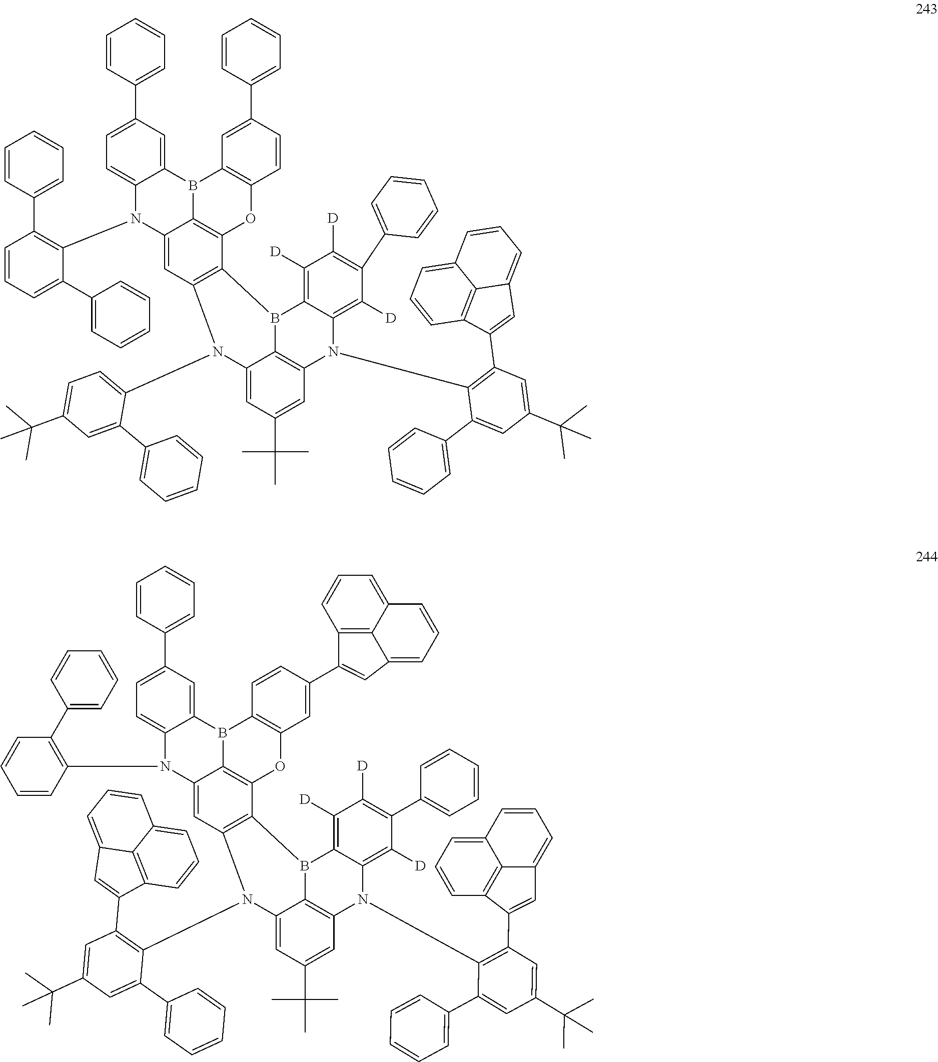 [SMILES: [2H]c1c([2H])c(-c2ccccc2)c([2H])c2c1B1c3c(cc(C(C)(C)C)cc3N2c2c(C3=Cc4cccc5cccc3c45)cc(C(C)(C)C)cc2-c2ccccc2)N(c2ccc(C(C)(C)C)cc2-c2ccccc2)c2cc3c4c(c21)Oc1ccc(-c2ccccc2)cc1B4c1cc(-c2ccccc2)ccc1N3c1c(-c2ccccc2)cccc1-c1ccccc1 ; [2H]c1c([2H])c(-c2ccccc2)c([2H])c2c1B1c3c(cc(C(C)(C)C)cc3N2c2c(C3=Cc4cccc5cccc3c45)cc(C(C)(C)C)cc2-c2ccccc2)N(c2c(C3=Cc4cccc5cccc3c45)cc(C(C)(C)C)cc2-c2ccccc2)c2cc3c4c(c21)Oc1cc(C2=Cc5cccc6cccc2c56)ccc1B4c1cc(-c2ccccc2)ccc1N3c1ccccc1-c1ccccc1]

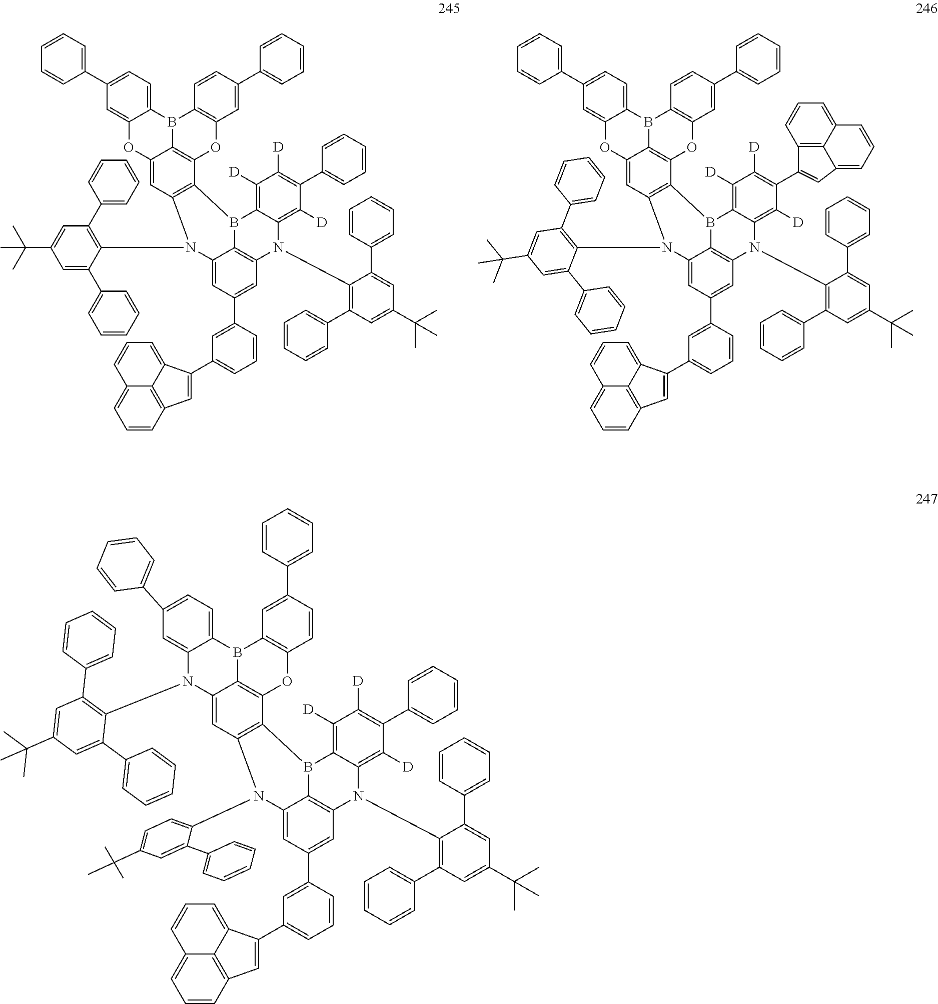

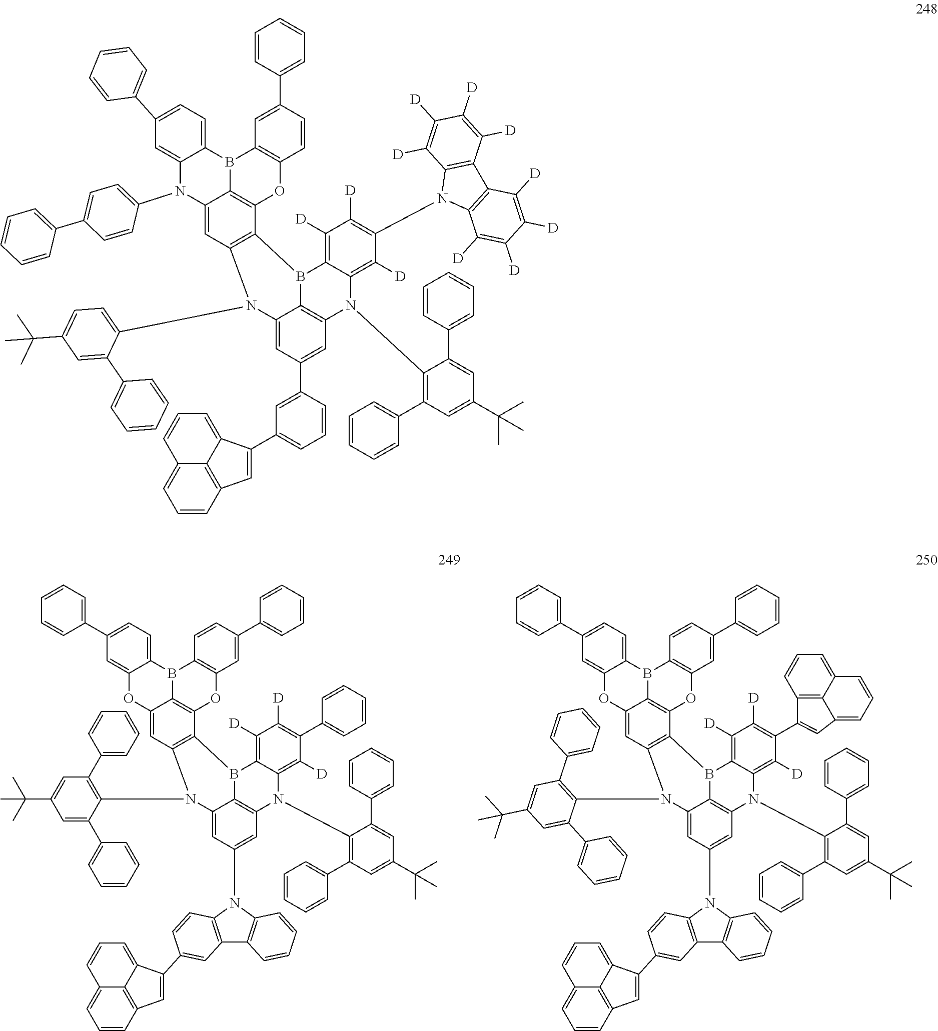

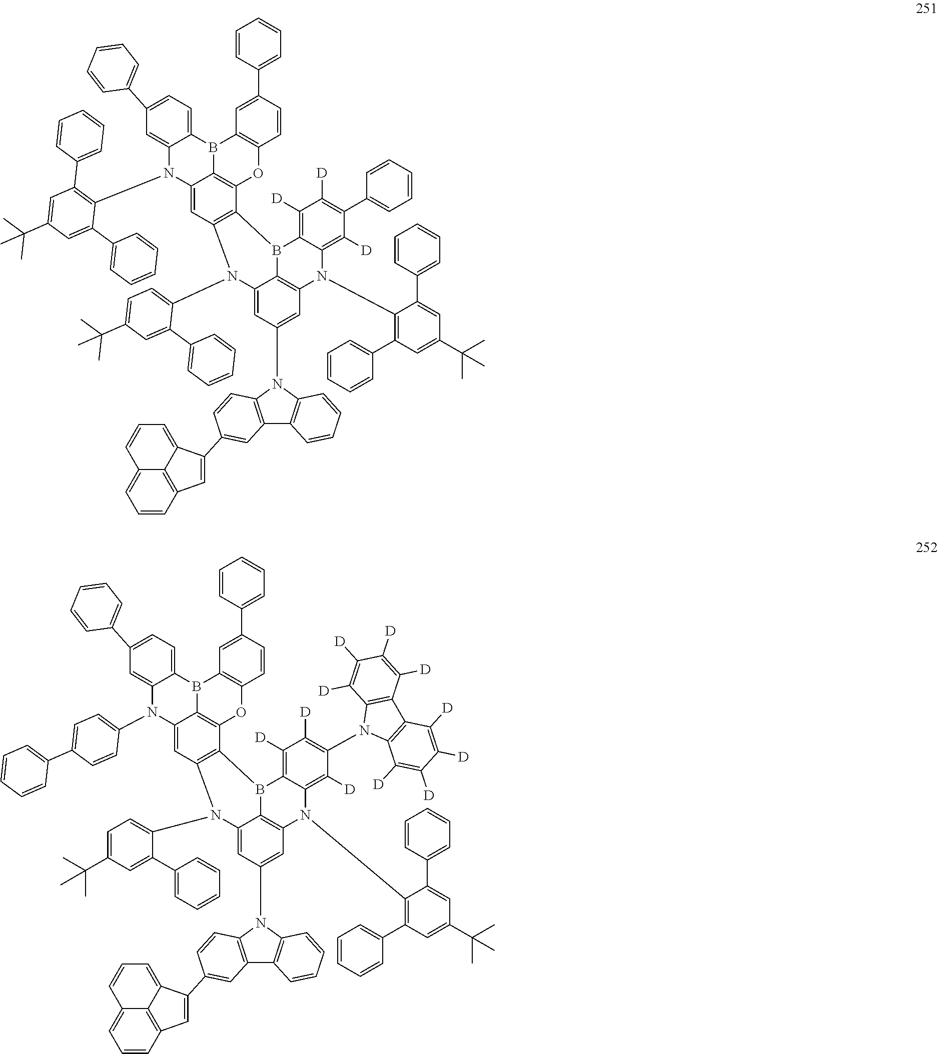

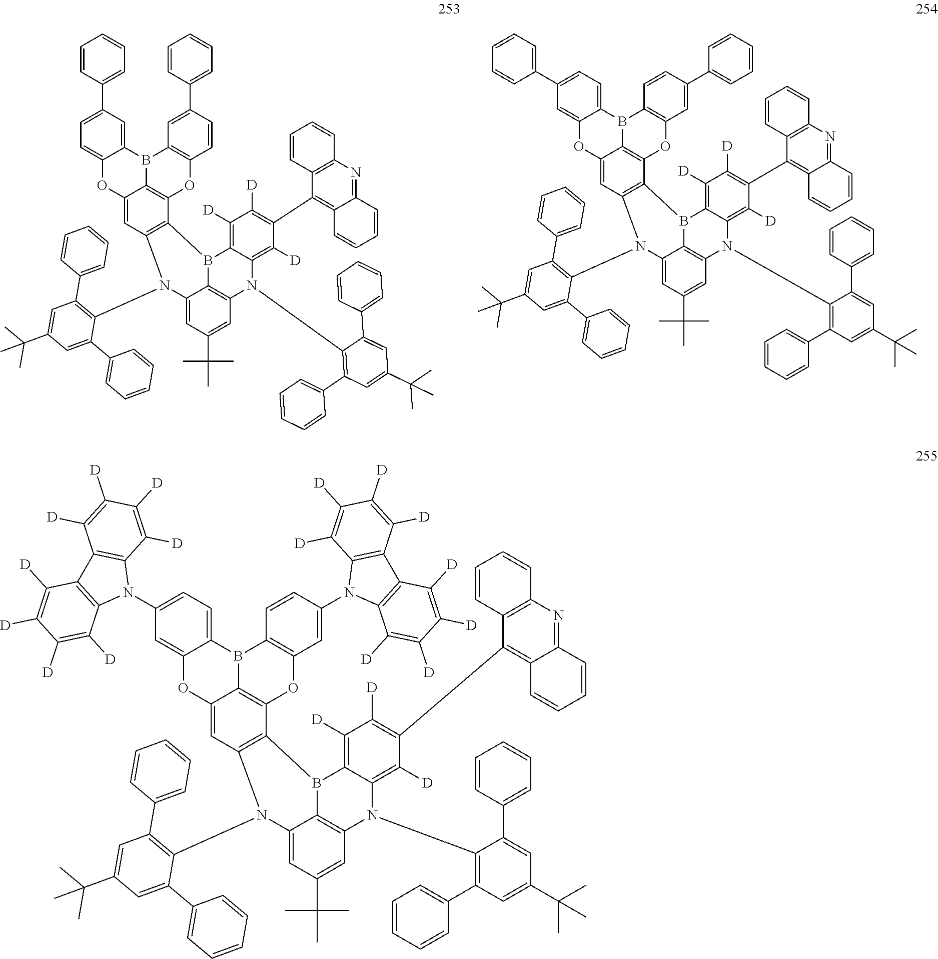

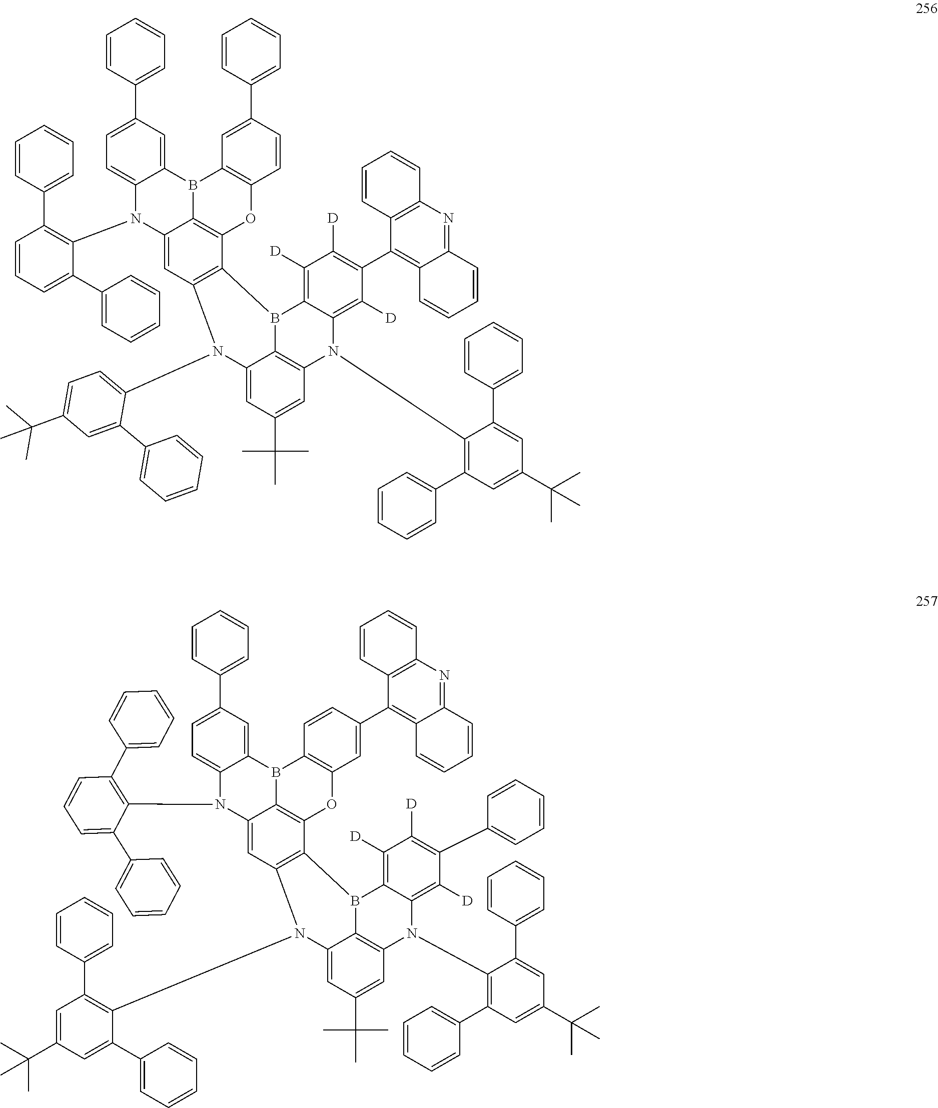

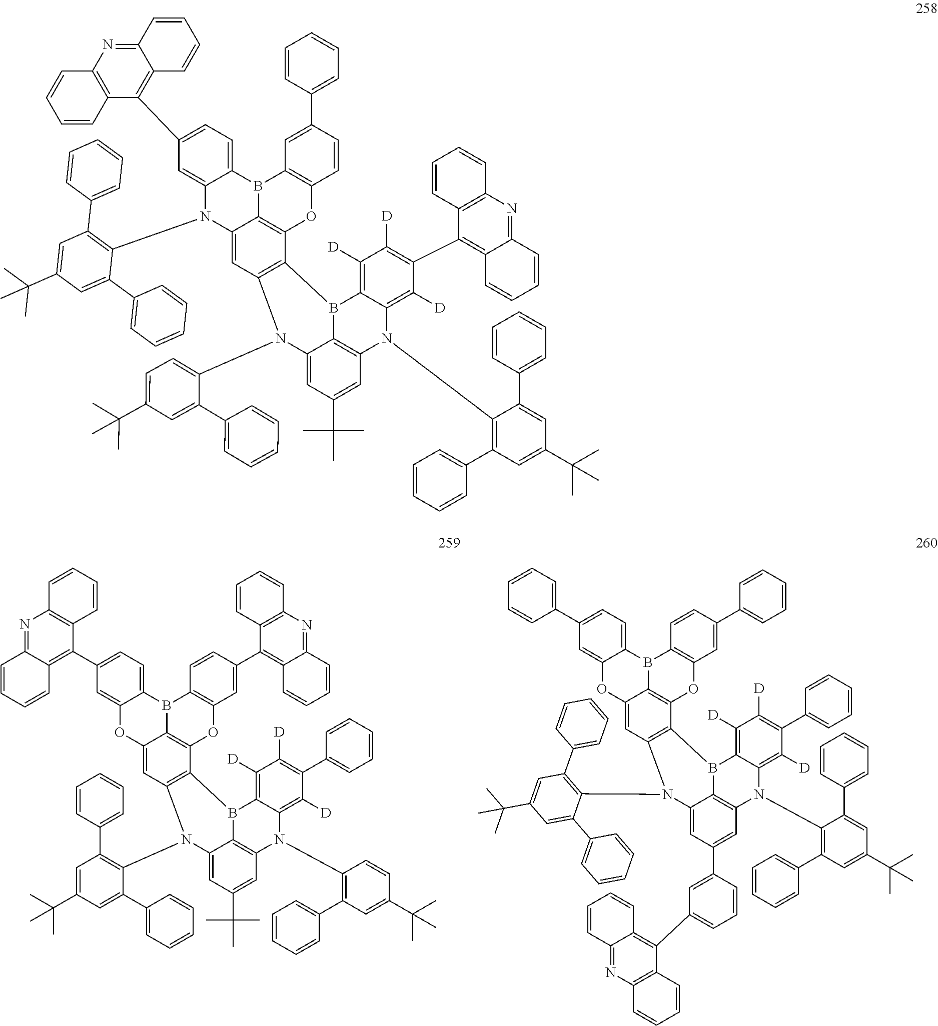

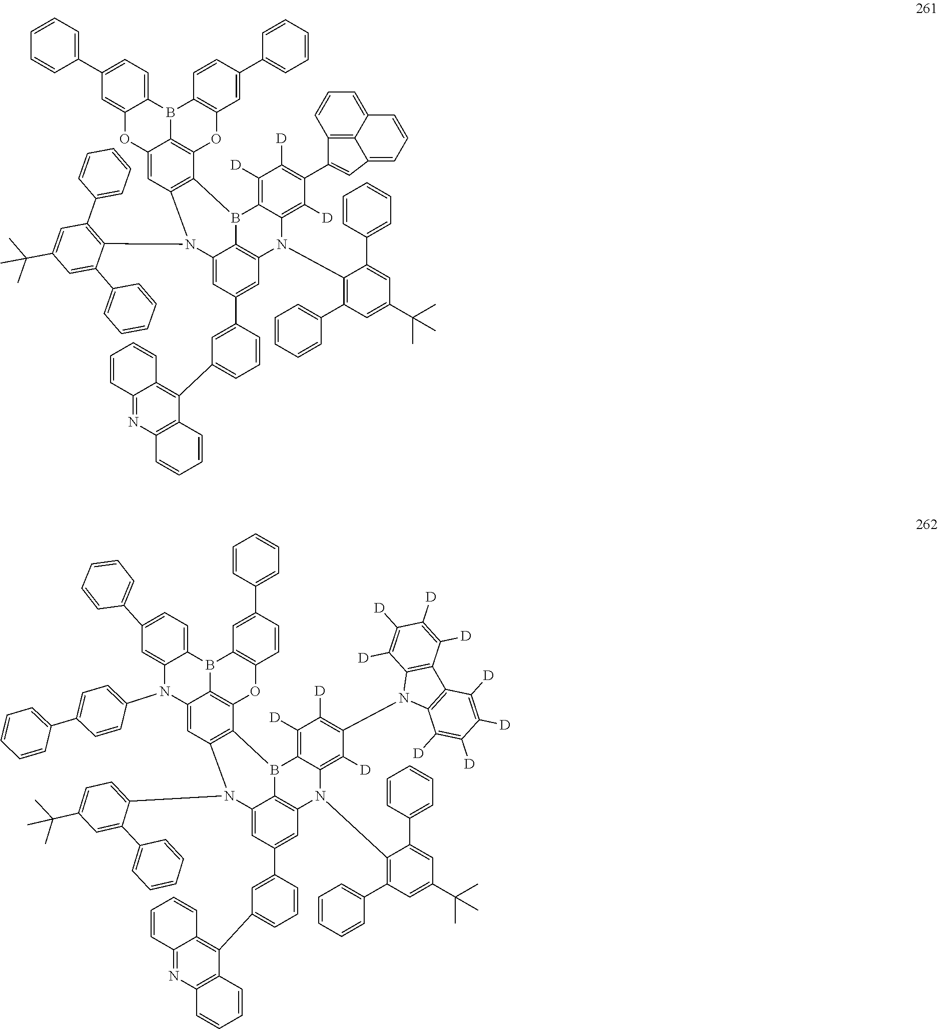

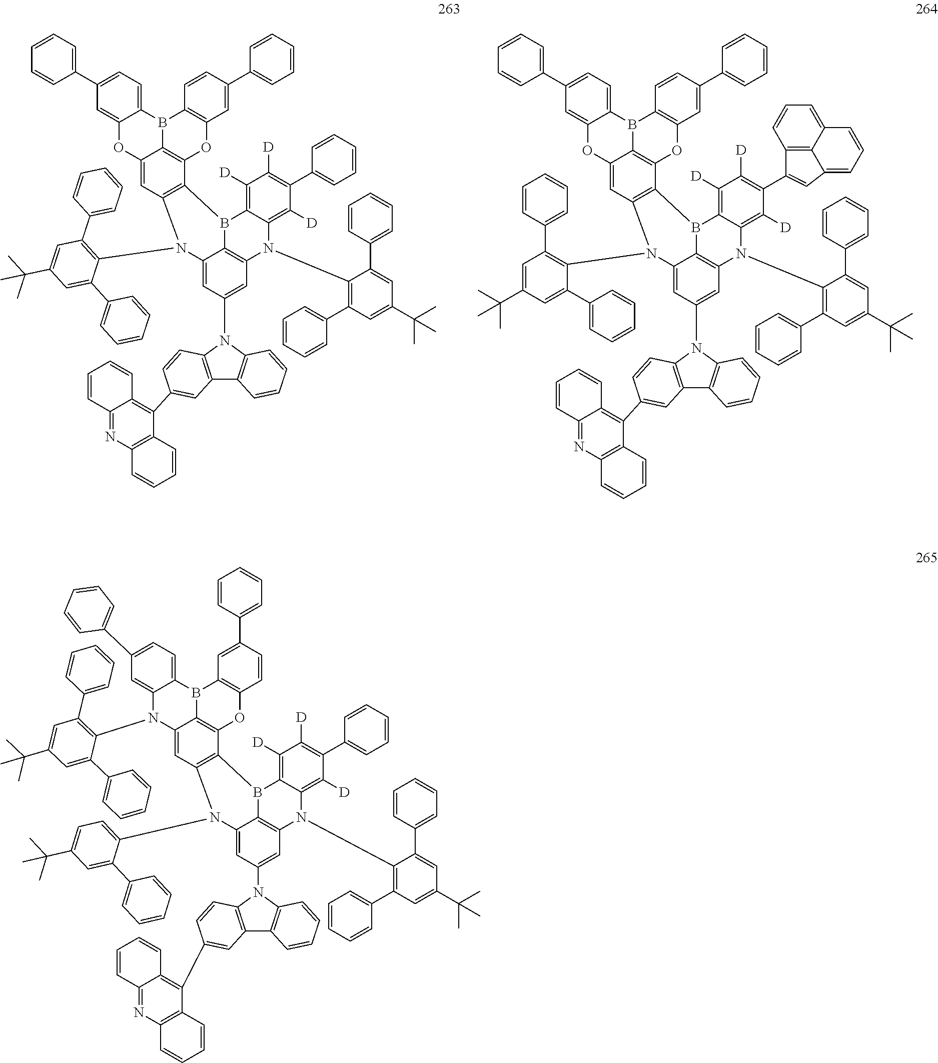

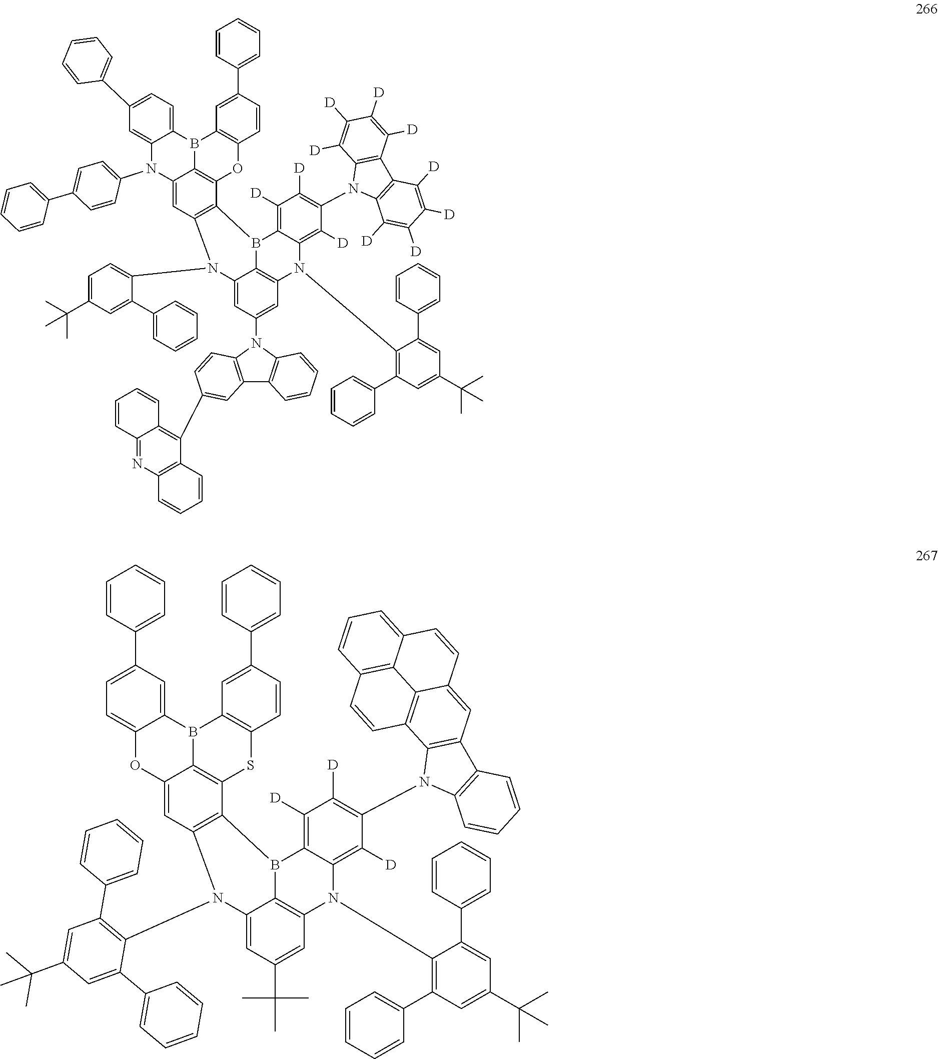

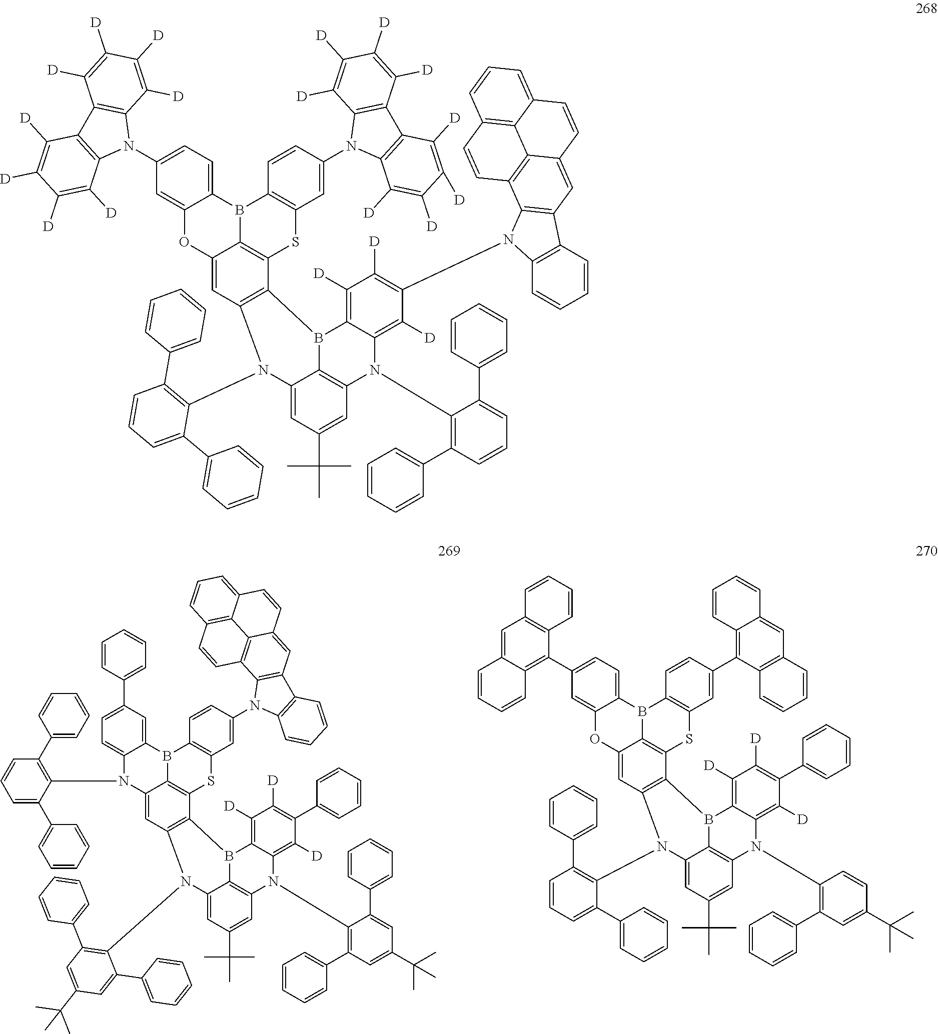

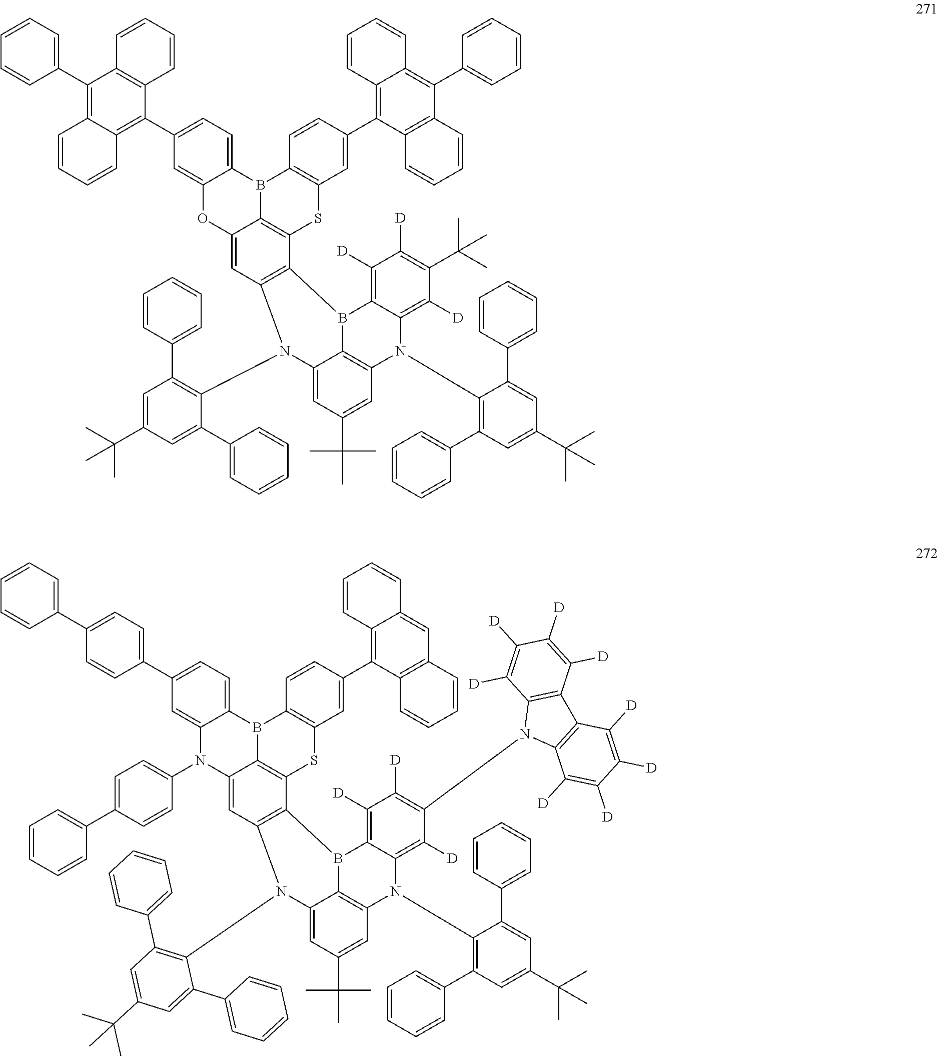

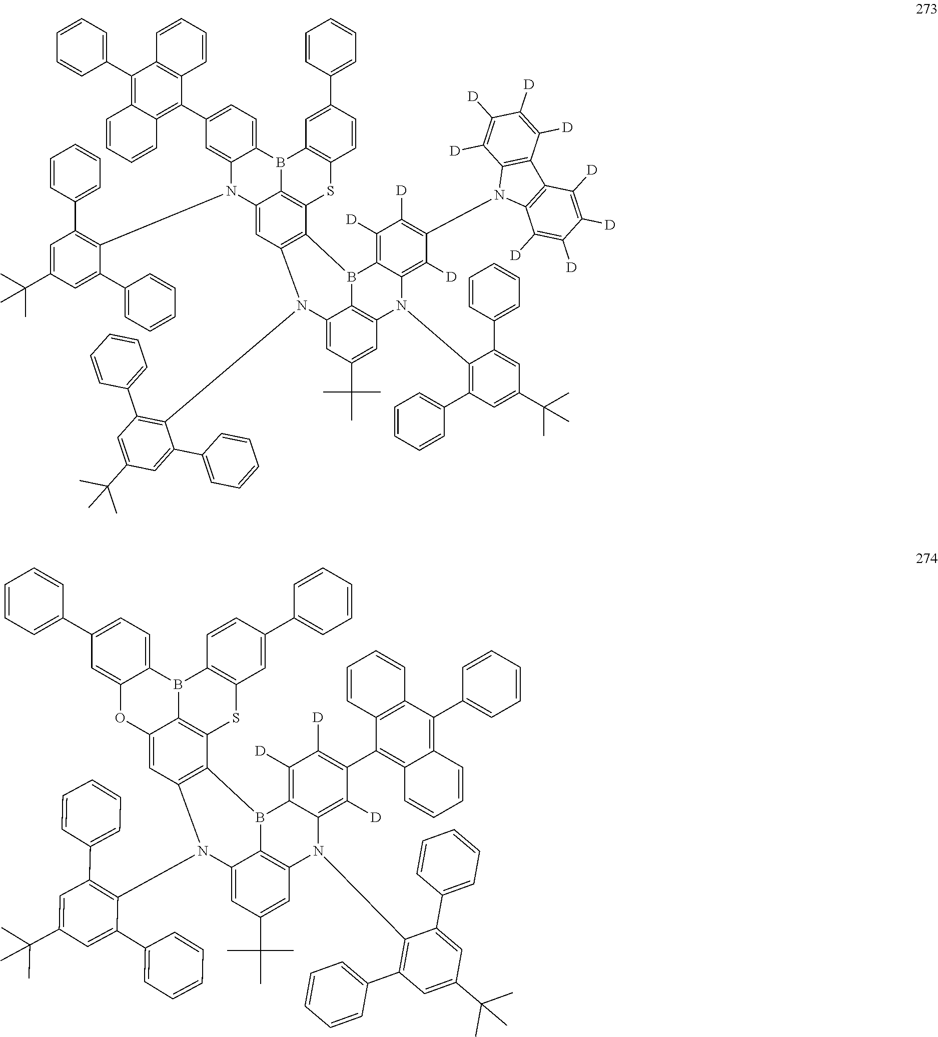

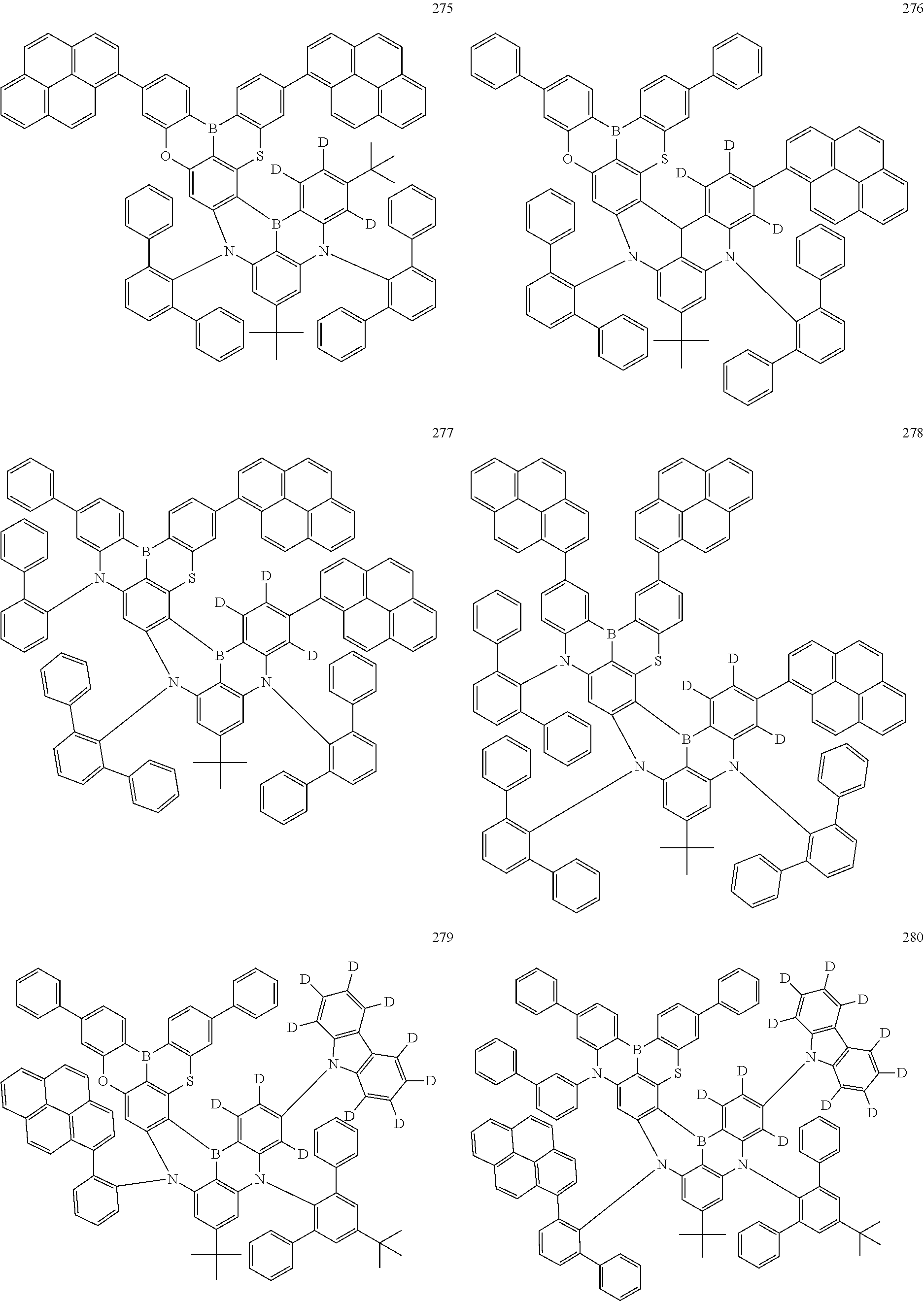

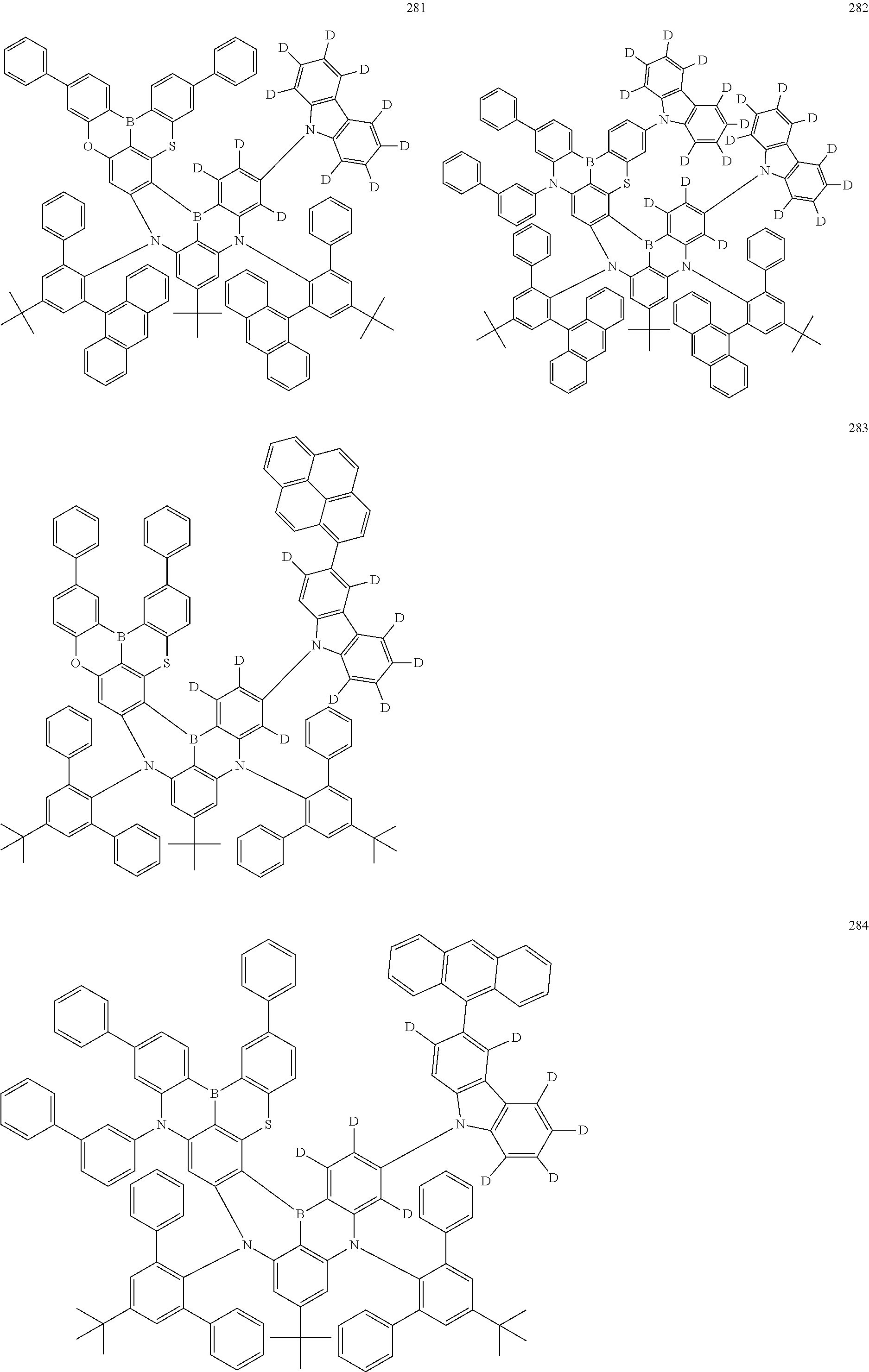

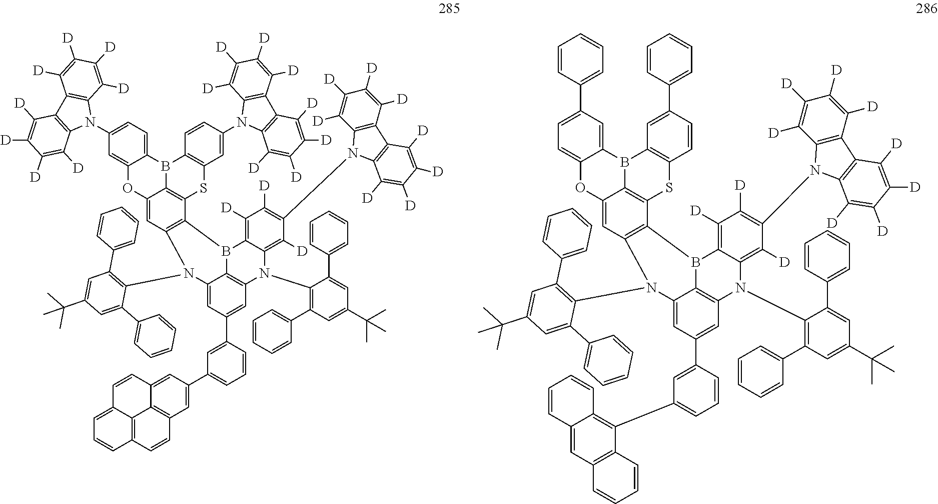

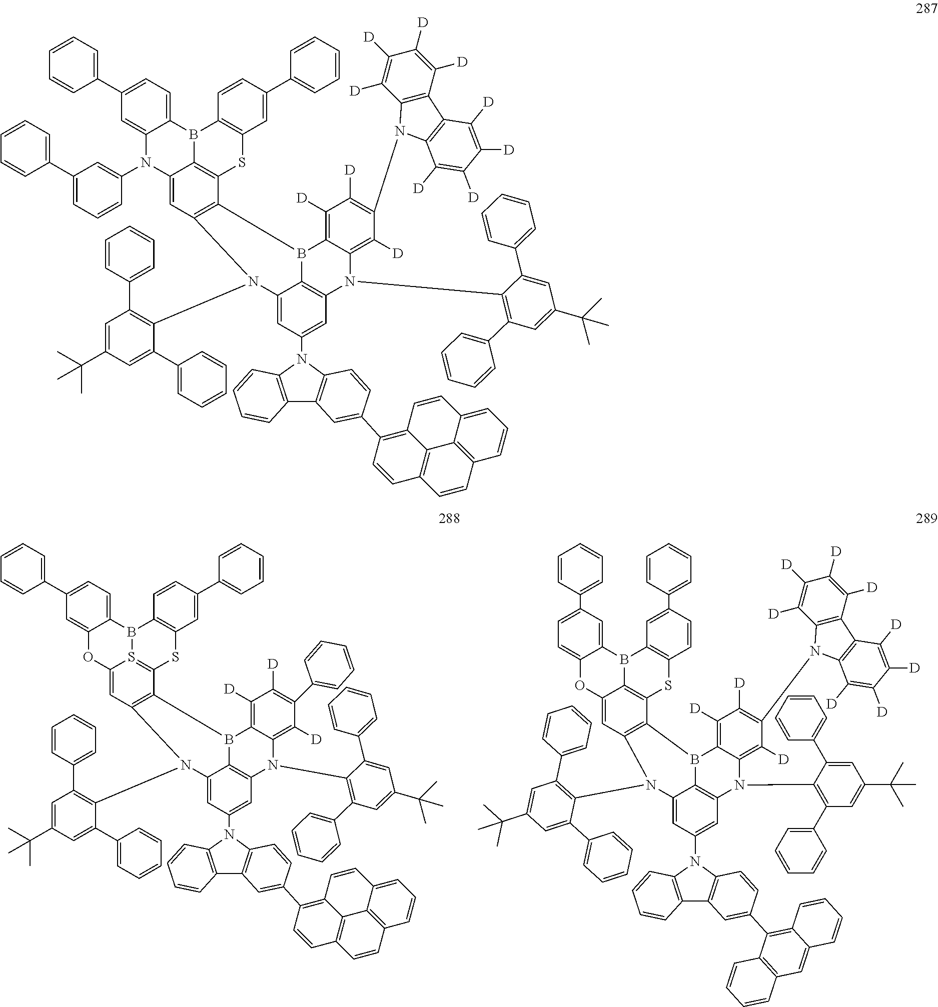

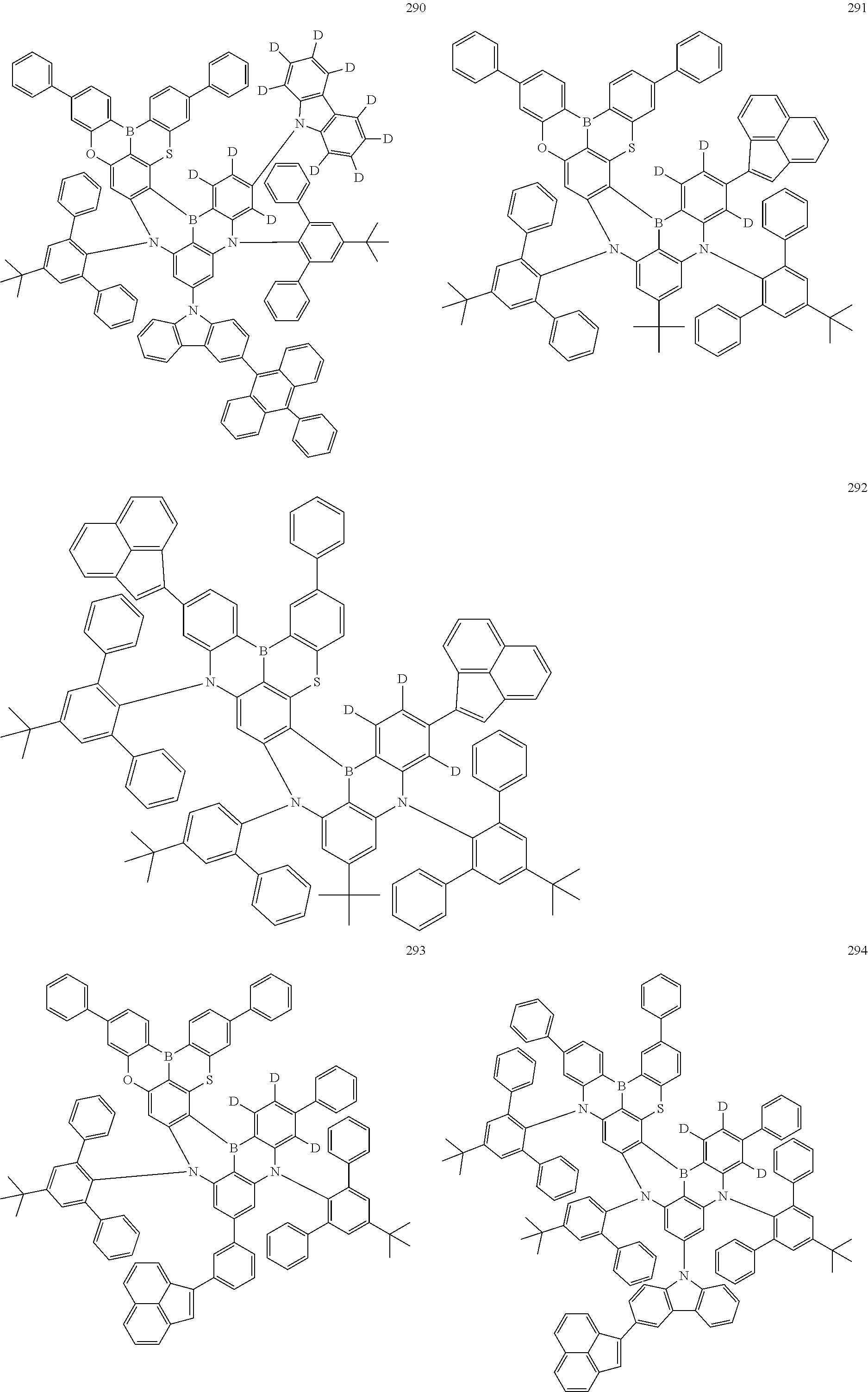

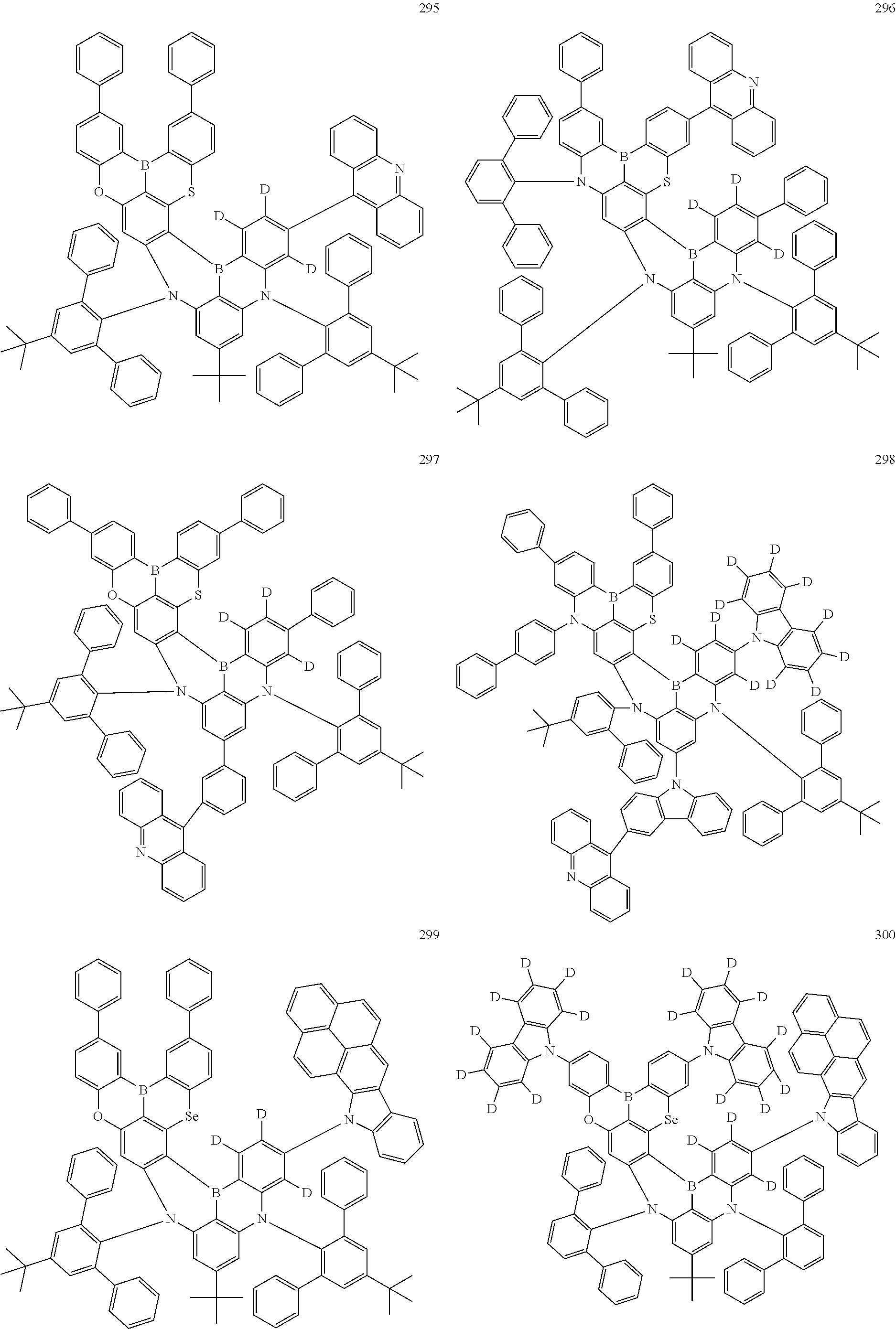

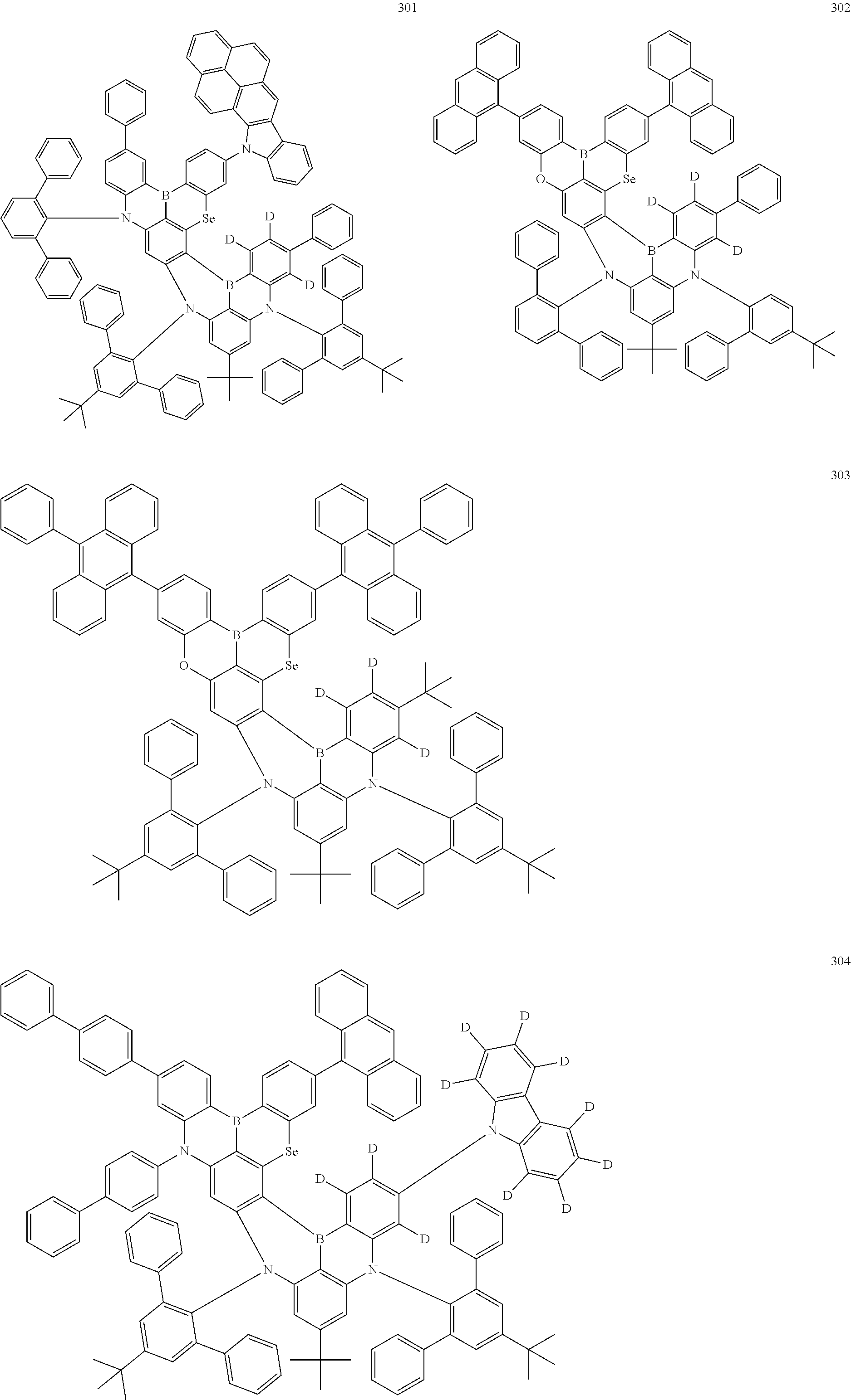

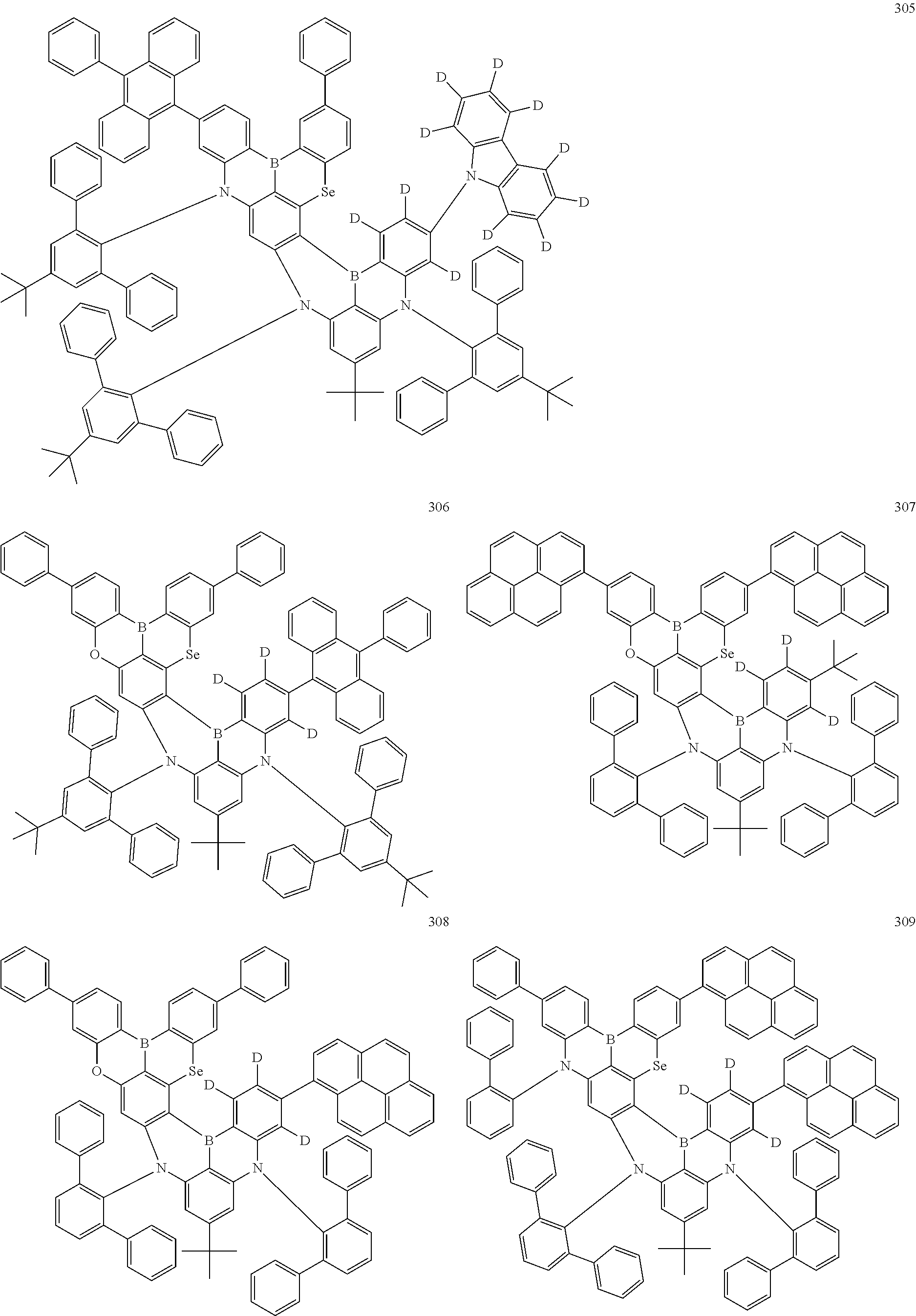

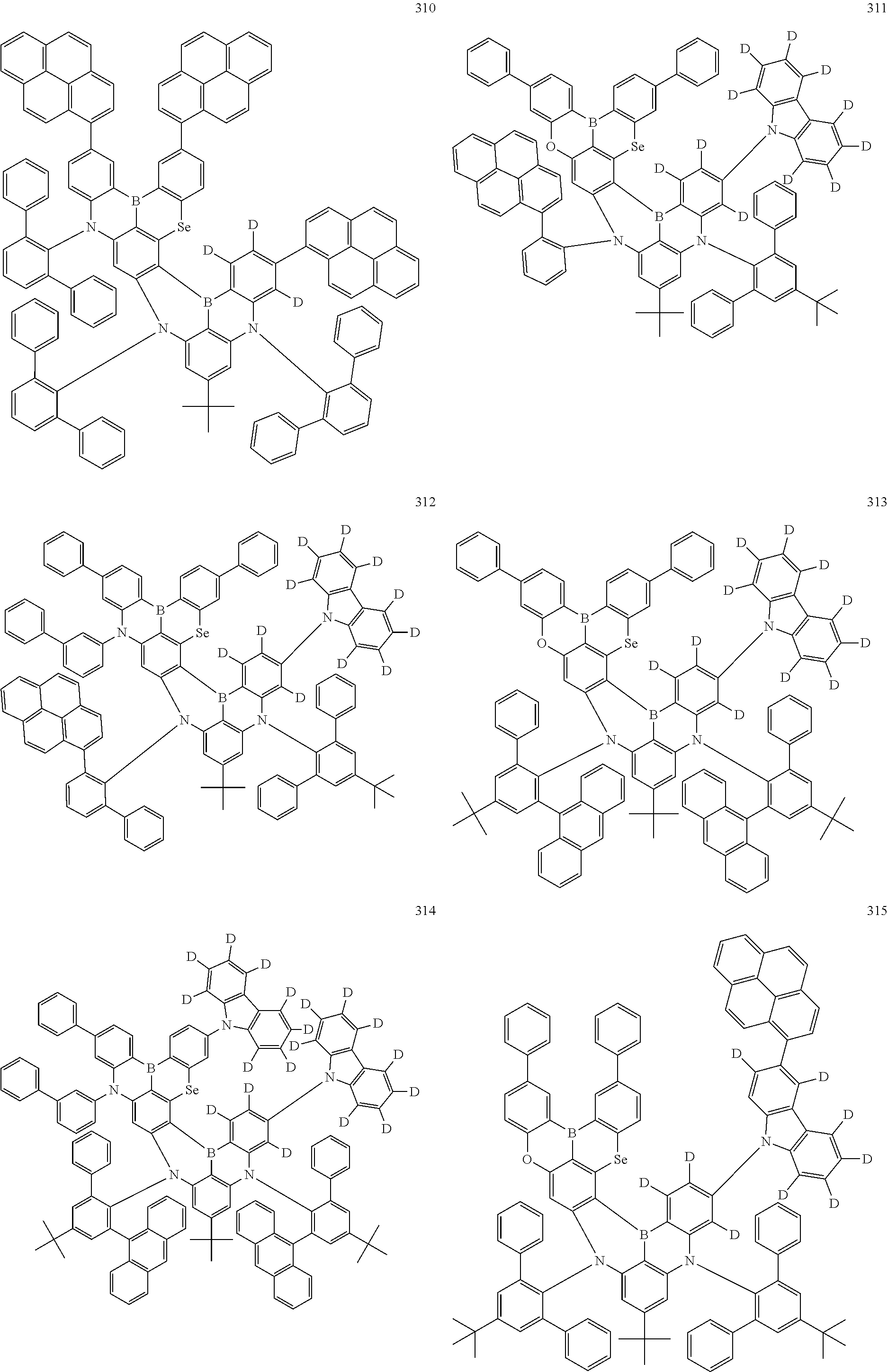

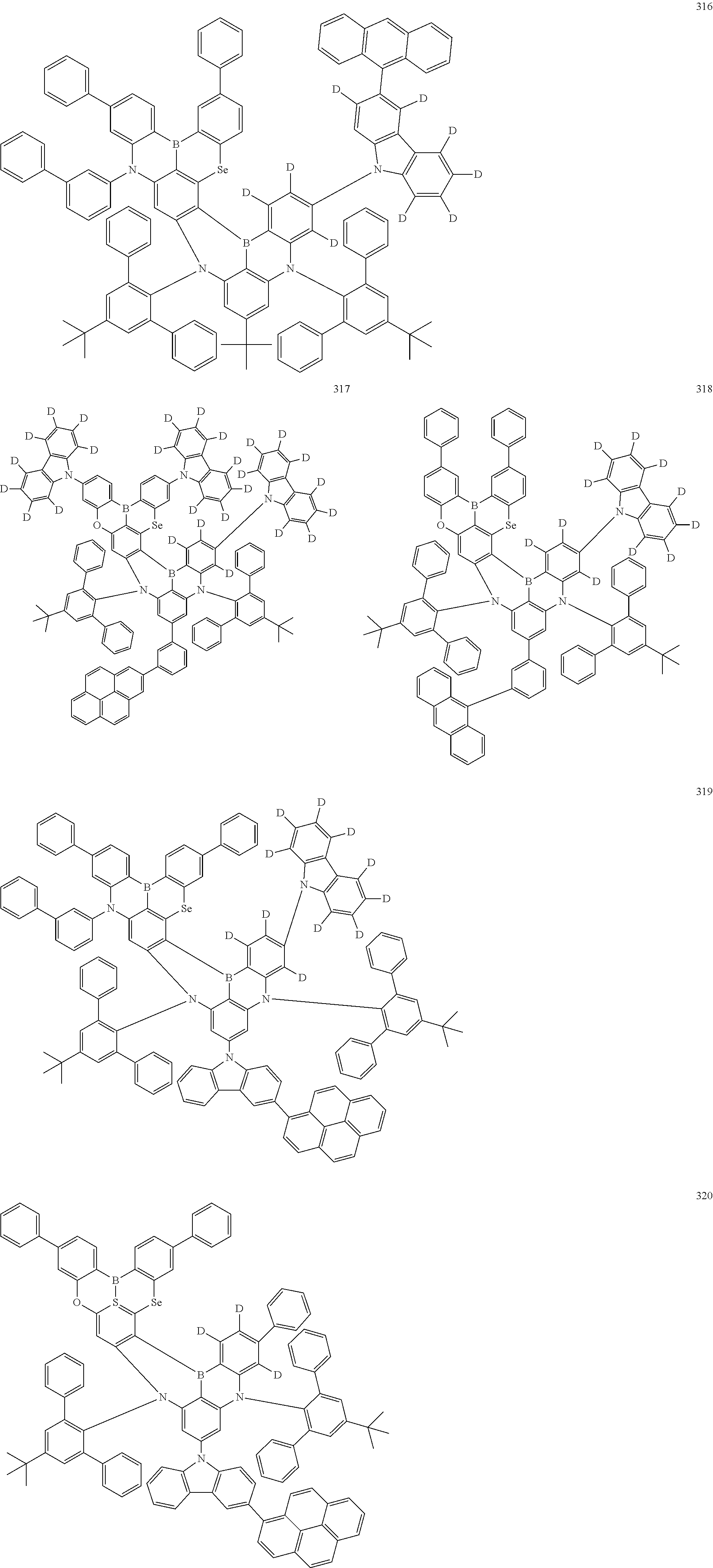

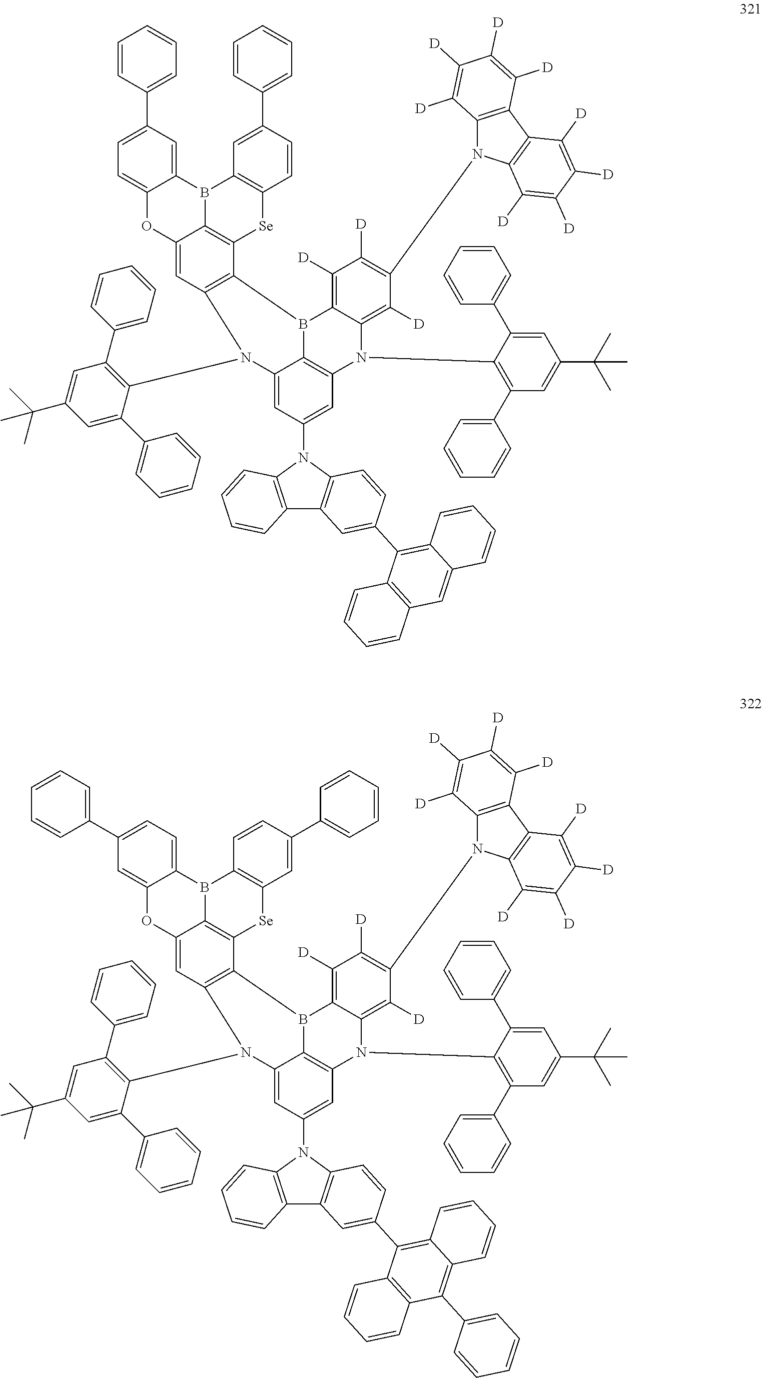

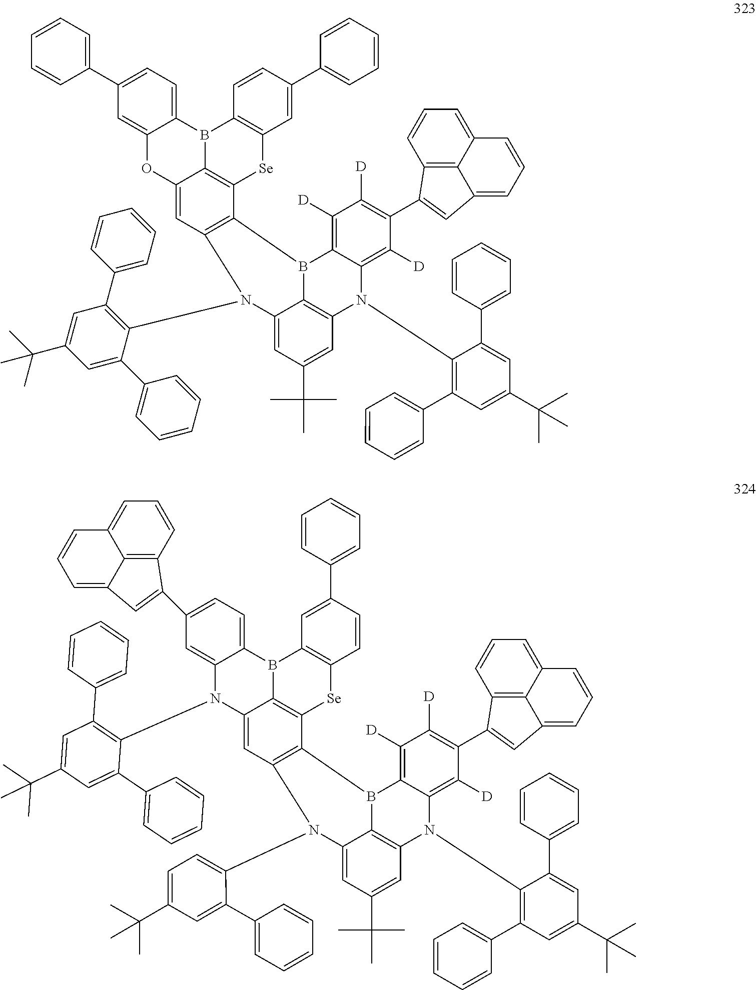

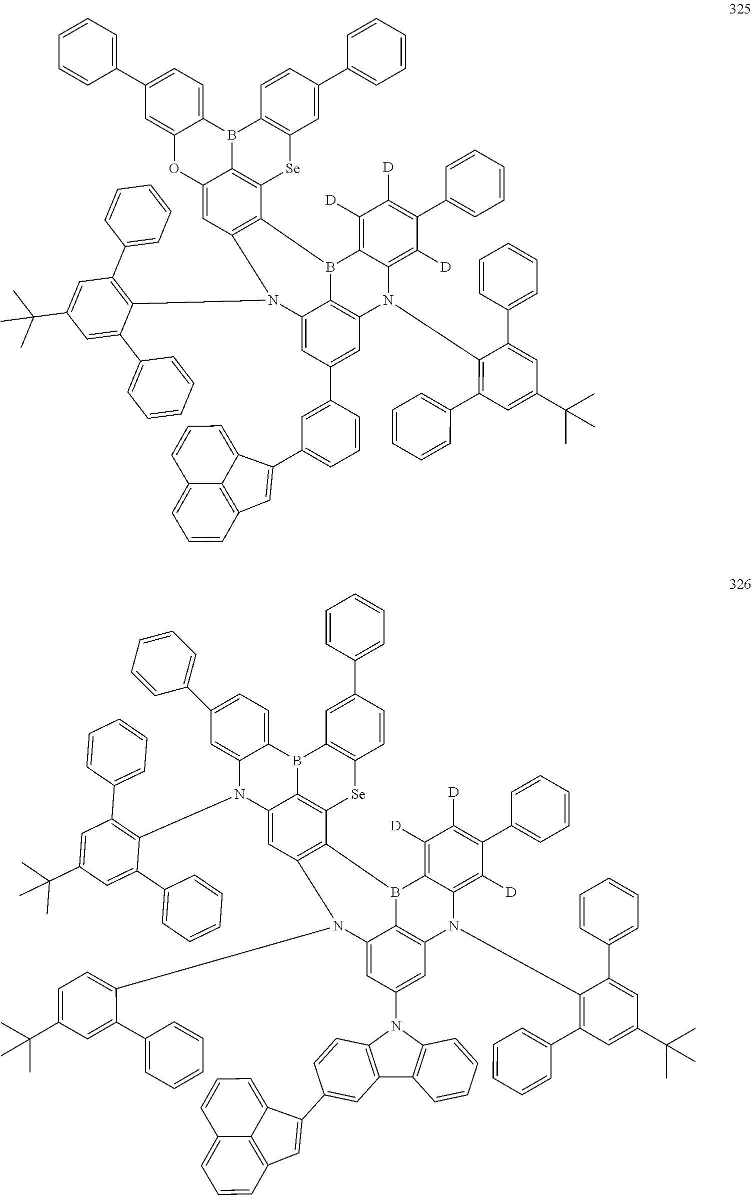

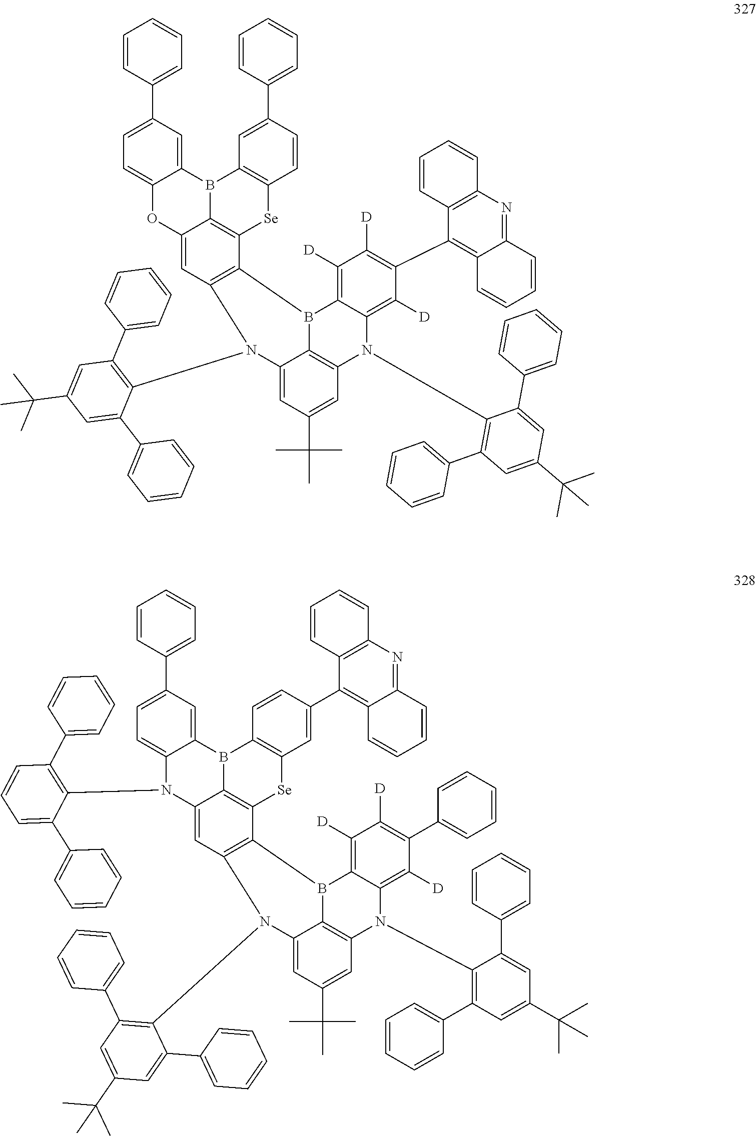 [SMILES: [2H]c1c([2H])c(-c2c3ccccc3nc3ccccc23)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)[Se]c1ccc(-c2ccccc2)cc1B4c1cc(-c2ccccc2)ccc1O3 ; [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)[Se]c1cc(-c2c5ccccc5nc5ccccc25)ccc1B4c1cc(-c2ccccc2)ccc1N3c1c(-c2ccccc2)cccc1-c1ccccc1]

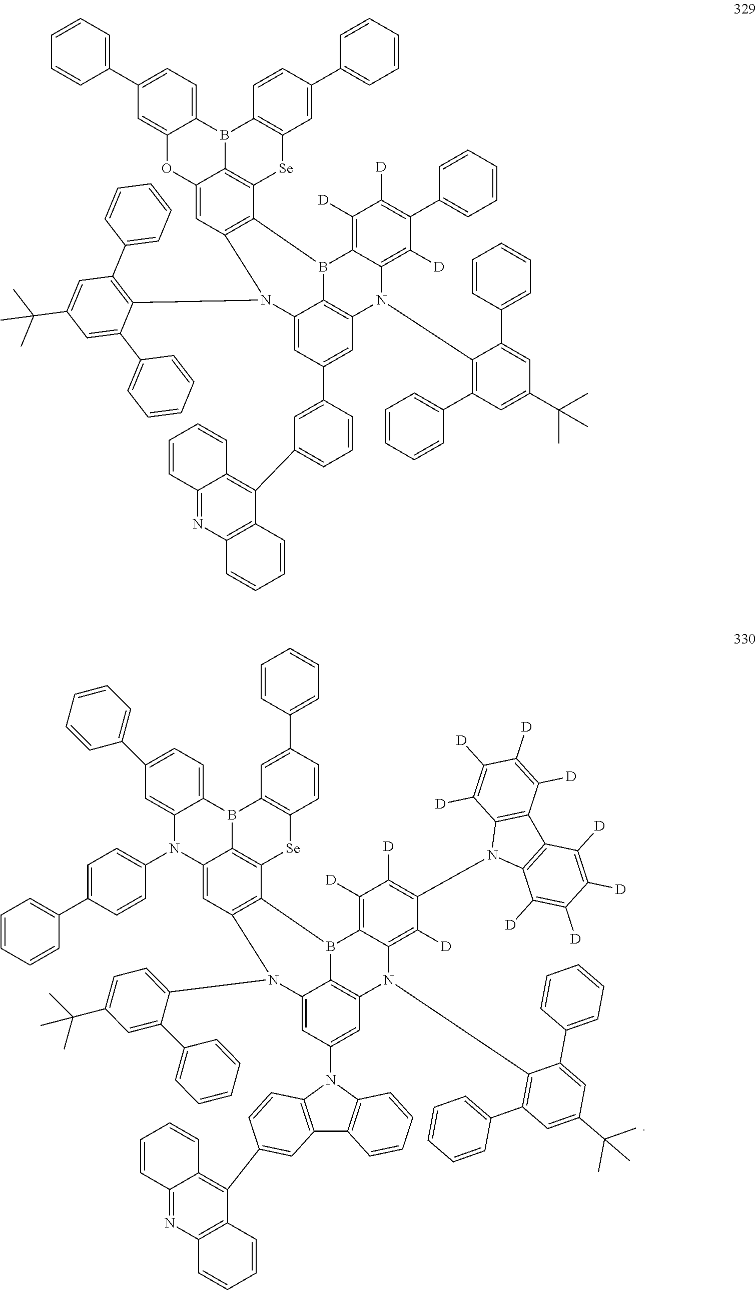

In Compound Group 1, D represents a deuterium atom.

The fused polycyclic compound according to an embodiment has a structure in which two aromatic hydrocarbon rings are connected to the fused ring core via a boron atom and two heteroatoms, thereby expanding a fused polycyclic structure, and which includes at least one first substituent, thereby contributing to improvements in high efficiency and long lifespan.

The first substituent includes a first sub substituent having a lowest excited triplet energy level (T1^{S}) equal to or less than about 2.0 eV. For example, the first substituent includes a first sub substituent having a lowest excited triplet energy level (T1^{S}) in a range of about 1.5 eV to about 2.0 eV. In an embodiment, the first sub substituent may be a substituted or unsubstituted anthracene group, a substituted or unsubstituted pyrene group, a substituted or unsubstituted acenaphthyl group, or a substituted or unsubstituted acridine group. The fused polycyclic compound according to an embodiment includes a first substituent that includes a first sub substituent having a lowest excited triplet energy level (T1^{S}) equal to or less than about 2.0 eV, and thus may exhibit characteristics of high efficiency and long lifespan.

The lowest excited triplet energy level of the first sub substituent may satisfy Expression 1:

$$T {1}^{S} \leq 2. eV \qquad [ Expression 1 ]$$

In Expression 1, T1^{S} may be a lowest excited triplet energy level of the first sub substituent.

In a compound that exhibits thermally activated delayed fluorescence characteristics, intersystem crossing (ISC) occurs, where excitons transition from a lowest singlet energy level to a triplet energy level. After this process, reverse intersystem crossing (RISC) may occur, where the excitons transition from a triplet excited energy level to a lowest singlet excited energy level. This process is followed by delayed fluorescence emission as the excitons transition from a singlet energy level to a ground state. In the specification, a mechanism of thermally activated delayed fluorescence may include not only a lowest triplet energy level (T1 level) but may also include higher-order triplet energy levels (denoted by Tn level, where n is an integer of 2 or greater) during processes of intersystem crossing (ISC) and reverse intersystem crossing (RISC).

The fused polycyclic compound according to an embodiment may exhibit characteristics of a relatively low lowest excited triplet energy level (T1 level) by including the first sub substituent, and device lifespan may be improved by preventing accumulation of triplet excitons within a molecule. The triplet state primarily undergoes non-radiative relaxation, and as energy of a triplet state becomes higher, a light-emitting dopant tends to be more prone to deterioration. The accumulation of the triplet excitons at a triplet energy level may accelerate deterioration of the compound due to processes such as triplet-triplet annihilation (TTA), and triplet-polaron quenching (TPQ). According to embodiments, by including the first sub substituent having a relatively low lowest excited triplet energy level (T1^{S}) equal to or less than about 2.0 eV, accumulation of triplet excitons within a molecule may be prevented, thereby improving luminous efficiency and device lifespan. By the inclusion of the first sub substituent having a relatively low lowest excited triplet energy level (T1^{S}), a lowest excited triplet energy level (T1 level) of the fused polycyclic compound according to an embodiment may be lower than a lowest excited triplet energy level of a fused polycyclic compound that does not include the first sub substituent. When triplet excitons transition to triplet energy levels (T1 level, or Tn level, where n is an integer of 2 or greater) of a light-emitting dopant via Dexter energy transfer, the triplet excitons may transition, through reverse intersystem crossing (RISC), to a lowest singlet energy level (S1 level) or may stabilize to a low lowest excited triplet energy level (T1 level). For example, after stabilization to a lower lowest excited triplet energy level (T1 level), the triplet excitons may undergo non-radiative decay, and thus the light-emitting element may have improved lifespan.

An emission spectrum of the fused polycyclic compound according to an embodiment may have a full width at half maximum (FWHM) in a range of about 10 nm to about 50 nm. For example, the emission spectrum of the fused polycyclic compound may have an FWHM in a range of about 20 nm to about 40 nm. Since the emission spectrum of the fused polycyclic compound according to an embodiment falls within the above-described range, when the fused polycyclic compound according to an embodiment is included in an element, luminous efficiency may be improved. When the fused polycyclic compound according to an embodiment is used as a blue emission material for the light-emitting element, the light-emitting element may have improved element lifespan.

In an embodiment, the fused polycyclic compound according to an embodiment may be a thermally activated delayed fluorescence material. The fused polycyclic compound according to an embodiment may be a thermally activated delayed fluorescence dopant that has a difference (ΔE_{ST}) equal to or less than about 0.6 eV between a lowest triplet excited energy level (T1 level) and a lowest singlet excited energy level (S1 level). For example, the fused polycyclic compound according to an embodiment may be a thermally activated delayed fluorescence dopant that has a difference (ΔE_{ST}) equal to or less than about 0.2 eV between a lowest triplet excited energy level (T1 level) and a lowest singlet excited energy level (S1 level). However, embodiments are not limited thereto.

In an embodiment, the fused polycyclic compound represented by Formula 1 may include a second sub substituent and a third sub substituent. A singlet energy level and a triplet energy level of the fused polycyclic compound may be appropriately modified by adjusting the number, the bonding location, and the like of the second sub substituent and the third sub substituent. Through this adjustment, the fused polycyclic compound according to an embodiment may exhibit improved characteristics of thermally activated delayed fluorescence.

The fused polycyclic compound according to an embodiment may be an emission material having a peak emission wavelength in a range of about 430 nm to about 490 nm. For example, the fused polycyclic compound according to an embodiment may be a blue thermally activated delayed fluorescence (TADF) dopant. However, embodiments are not limited thereto, and when the fused polycyclic compound according to an embodiment is used as an emission material, the fused polycyclic compound may be used as a dopant material that emits light in various wavelength regions, such as a red emission dopant and a green emission dopant.

In the light-emitting element ED, the emission layer EML may emit delayed fluorescence. For example, the emission layer EML may emit thermally activated delayed fluorescence (TADF)

In embodiment, the emission layer EML of the light-emitting element ED may emit blue light. For example, the light-emitting element ED according to an embodiment may emit blue light in a wavelength region equal to or less than about 490 nm. However, embodiments are not limited thereto, and the emission layer EML may emit green light or red light.

The emission layer EML may include the fused polycyclic compound according to an embodiment. The fused polycyclic compound according to an embodiment may be included in the emission layer EML as a dopant material. The fused polycyclic compound according to an embodiment may be a thermally activated delayed fluorescence material. The fused polycyclic compound according to an embodiment may be used as a thermally activated delayed fluorescence dopant. For example, in the light-emitting element ED, the emission layer EML may contain at least one compound selected from Compound Group 1 as a thermally activated delayed fluorescence dopant. However, a use of the fused polycyclic compound according to an embodiment is not limited thereto.

In an embodiment, the emission layer EML may include multiple compounds. In embodiments, emission layer EML may include the fused polycyclic compound represented by Formula 1 as a first compound, and may further include at least one of a second compound represented by Formula HT-1, a third compound represented by Formula ET-1, and a fourth compound represented by Formula D-1.

In an embodiment, the emission layer EML may include the first compound represented by Formula 1, and may further include at least one of a second compound represented by Formula HT-1 and a third compound represented by Formula ET-1.

In an embodiment, the emission layer EML may further include a second compound represented by Formula HT-1. In an embodiment, the second compound may be used as a hole transport host material in the emission layer EML.

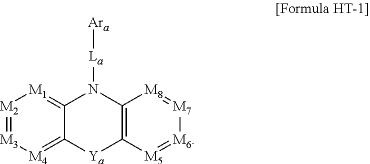

In Formula HT-1, M₁ to M₈ may each independently be N or C(R₅₁). For example, M₁ to M₈ may each independently be C(R₅₁). As another example, one of M₁ to M₈ may be N, and the remainder of M₁ to M₈ may each independently be C(R₅₁).

In Formula HT-1, Lₐ may be a direct linkage, a substituted or unsubstituted arylene group of 6 to 30 ring-forming carbon atoms, or a substituted or unsubstituted heteroarylene group of 2 to 30 ring-forming carbon atoms. For example, Lₐ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅₄)(R₅₅). For example, the two benzene rings that are connected to the nitrogen atom in Formula HT-1 may be connected to each other via a direct linkage,

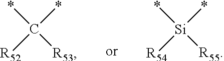

In Formula HT-1, if Yₐ is a direct linkage, the second compound represented by Formula HT-1 may include a carbazole moiety.

In Formula HT-1, Arₐ may be a substituted or unsubstituted aryl group of 6 to 30 ring-forming carbon atoms or a substituted or unsubstituted heteroaryl group of 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or bonded to an adjacent group to form a ring. For example, R₅₁ to R₅₅ may each independently be a hydrogen atom or a deuterium atom. As another example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2:

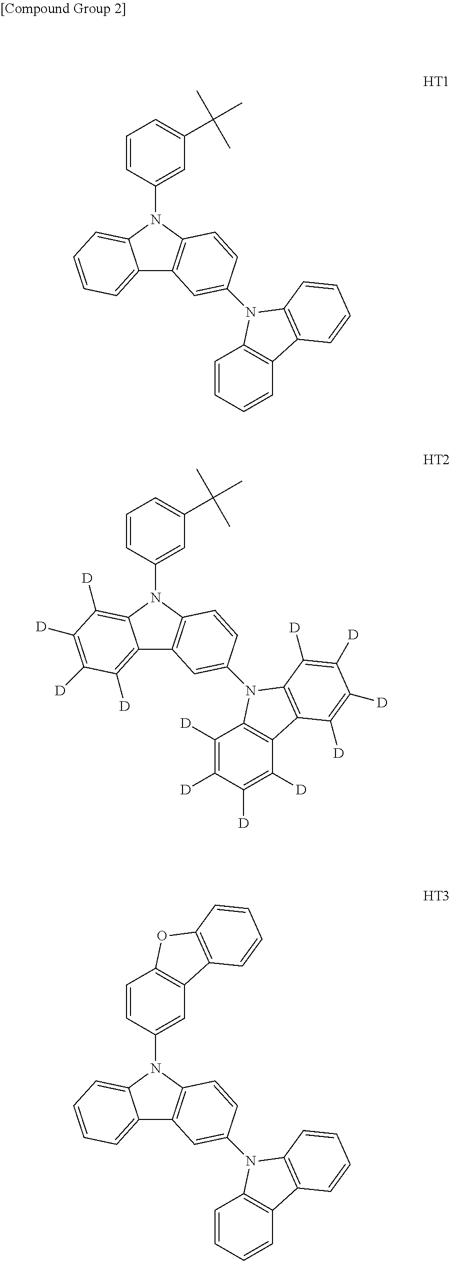 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

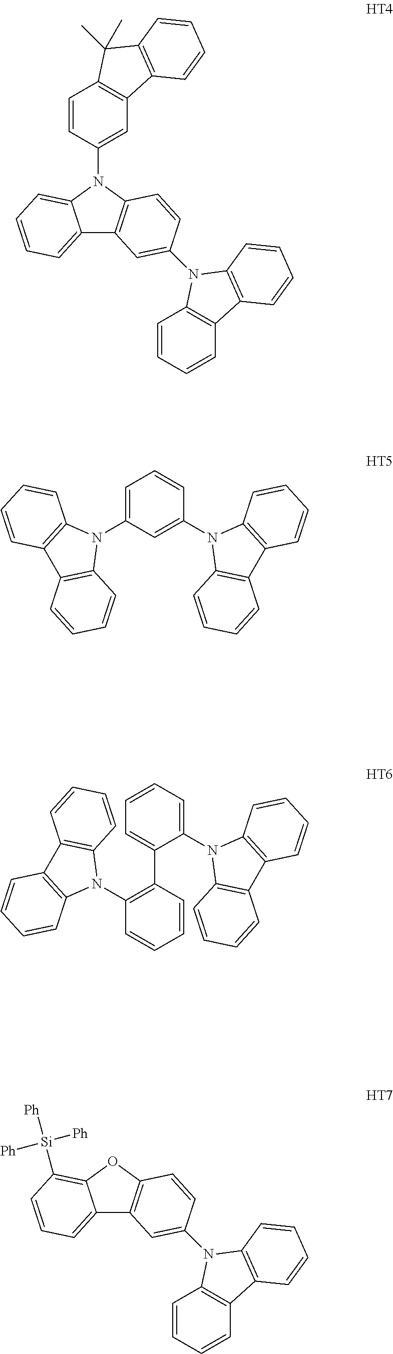 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

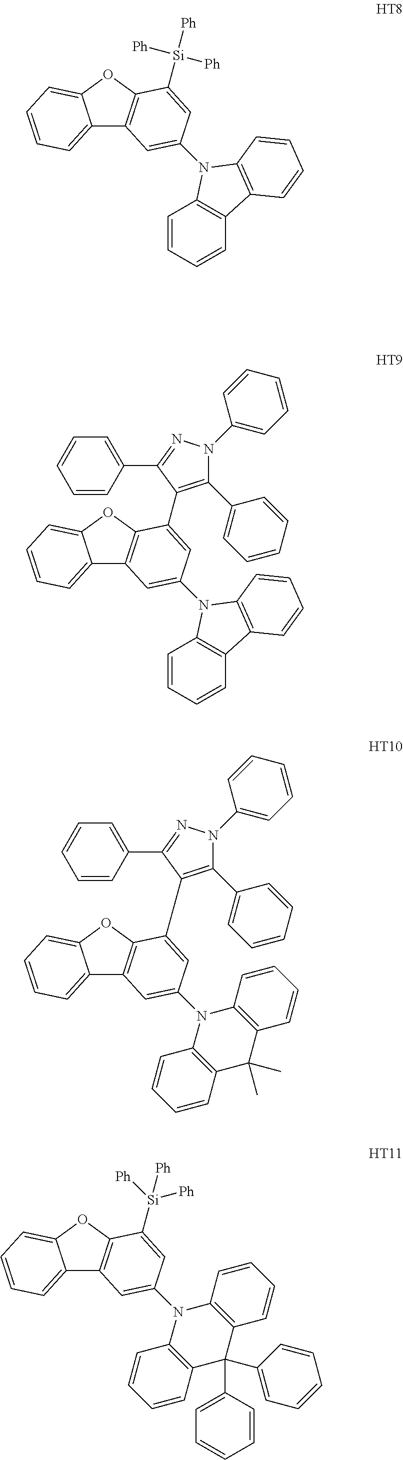 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

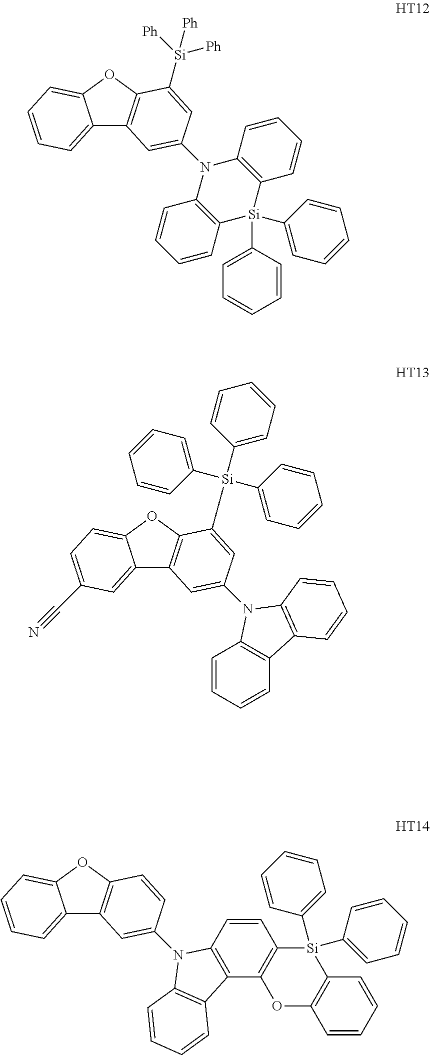 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

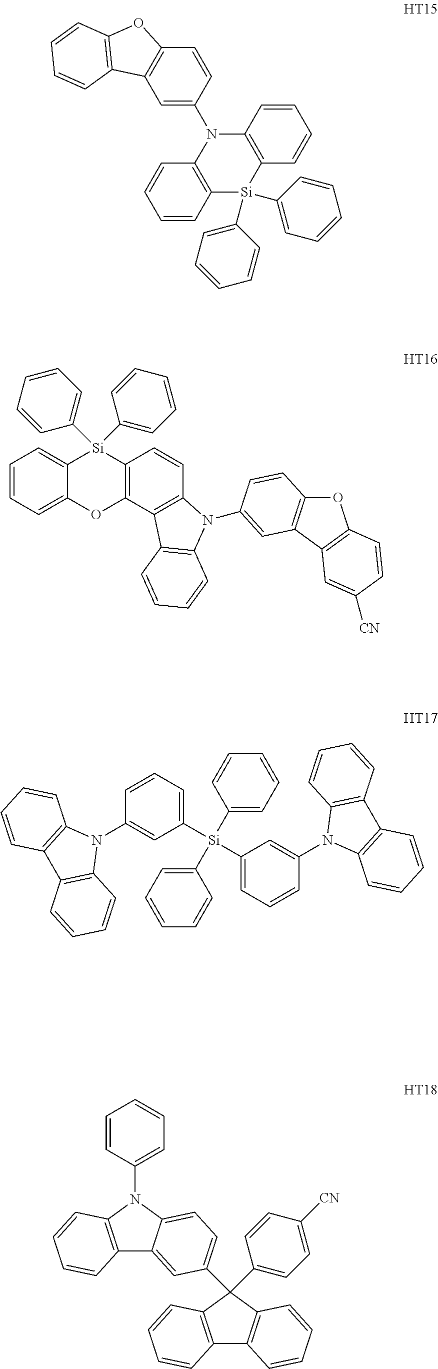 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

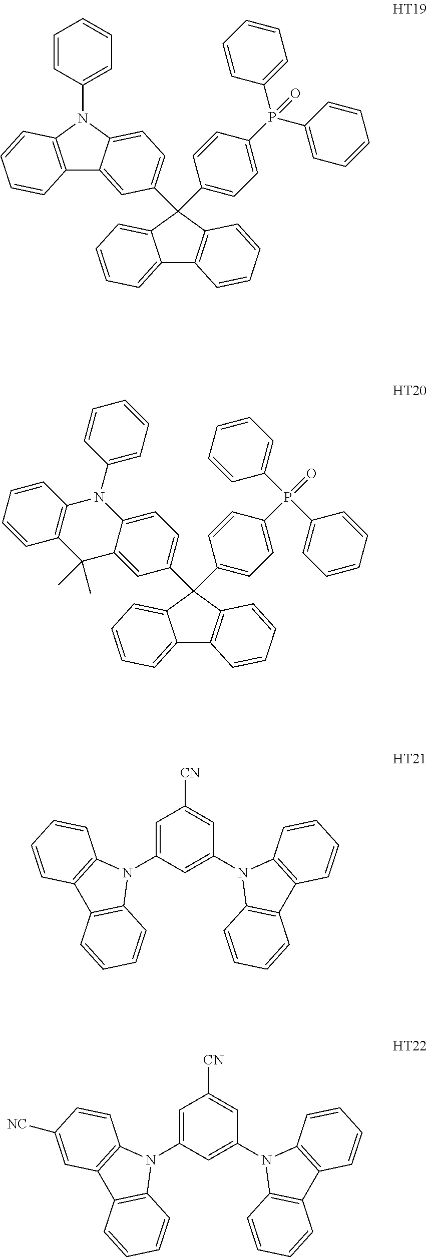 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

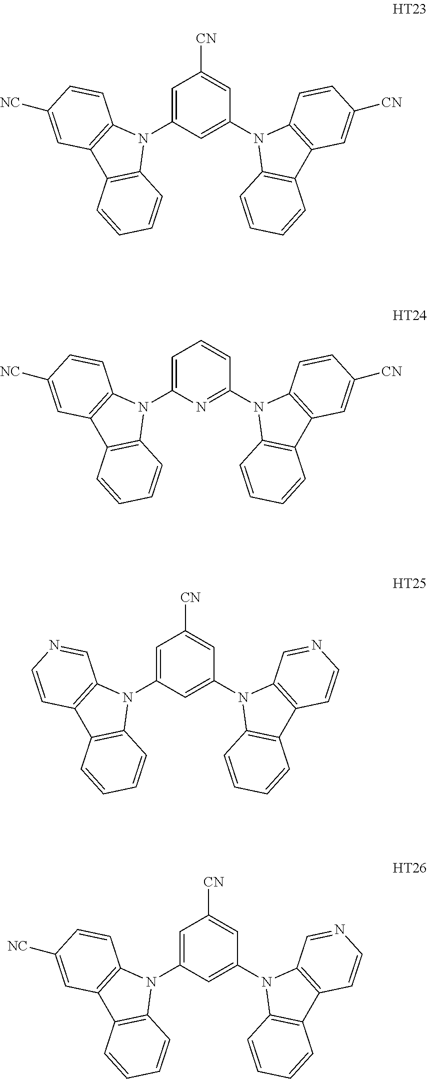 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

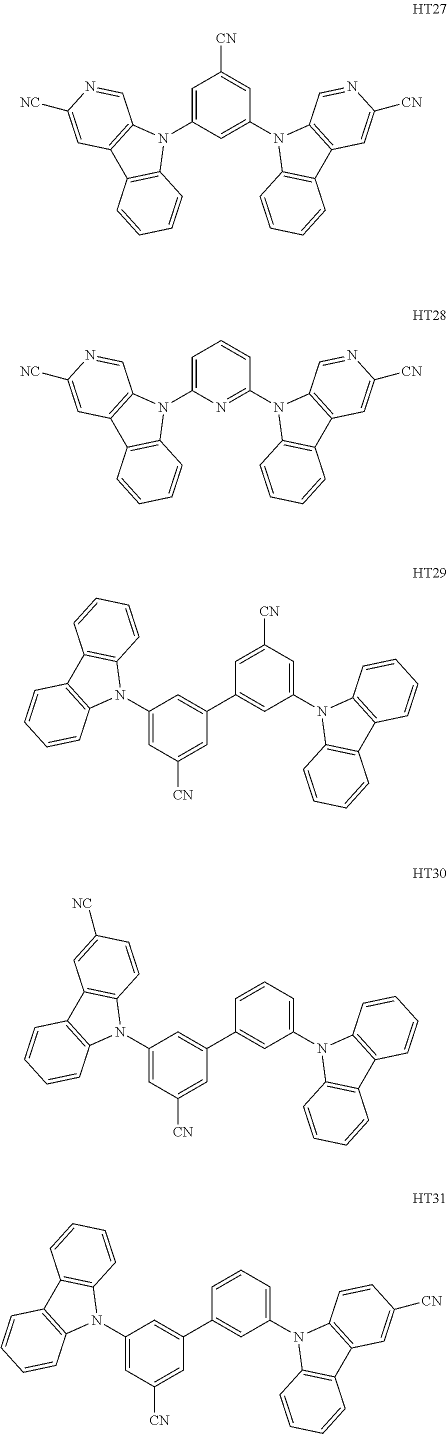 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

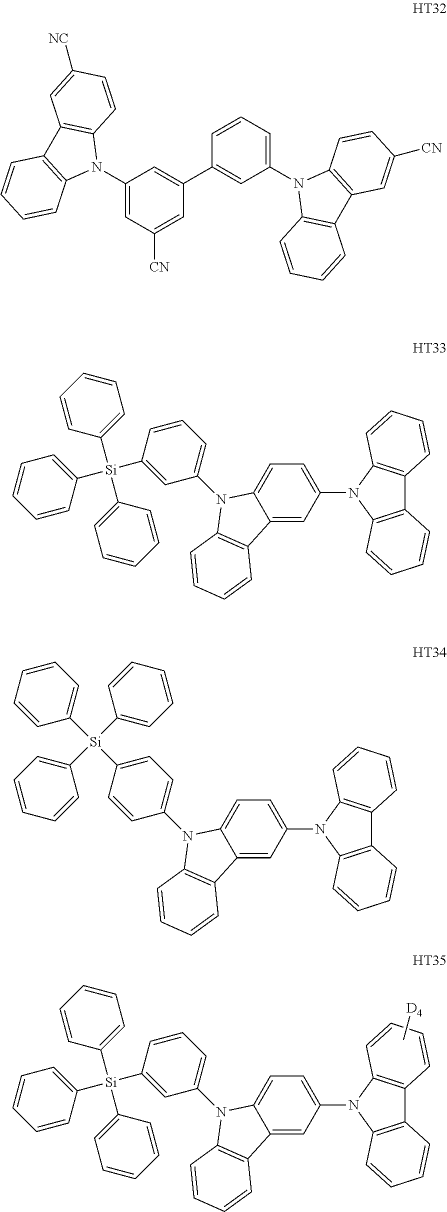

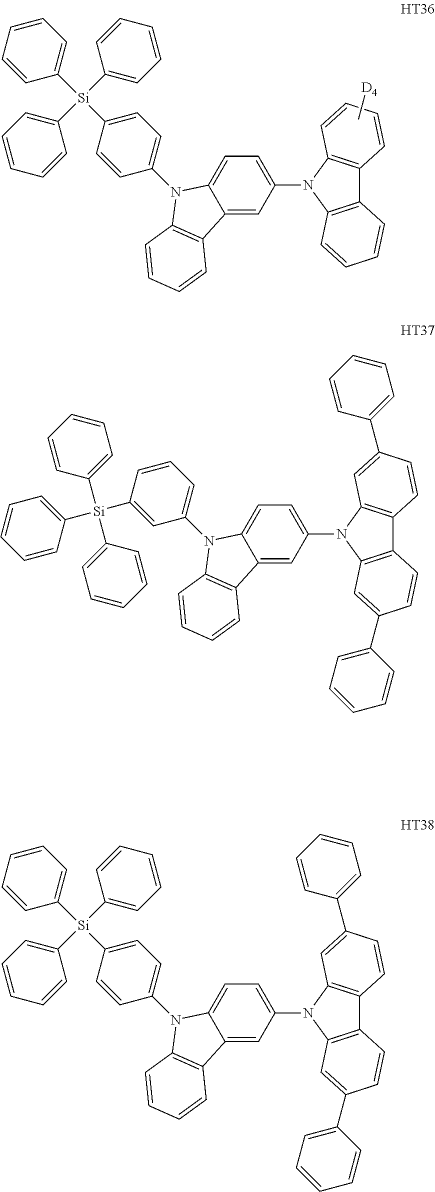

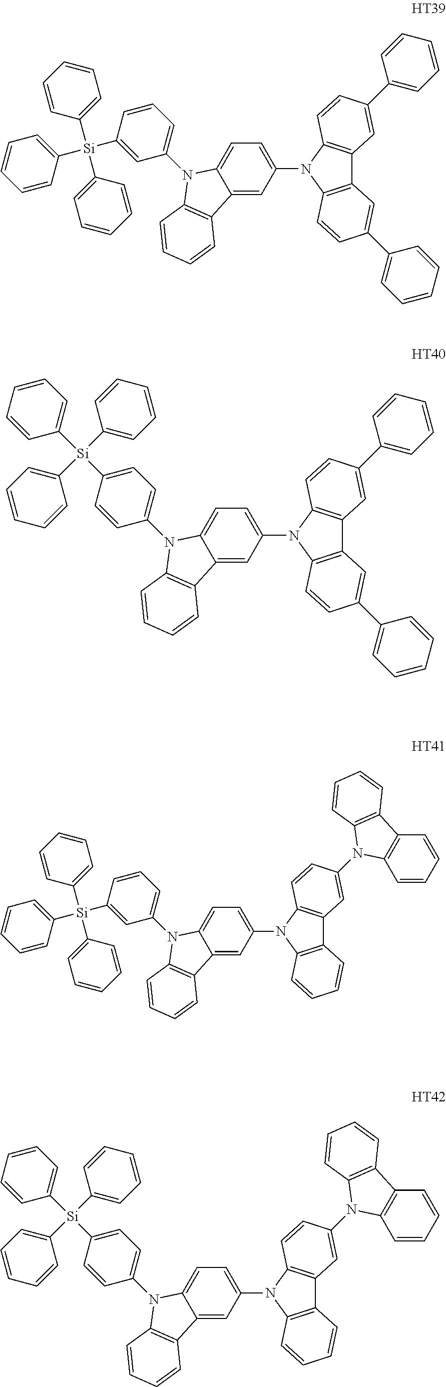 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

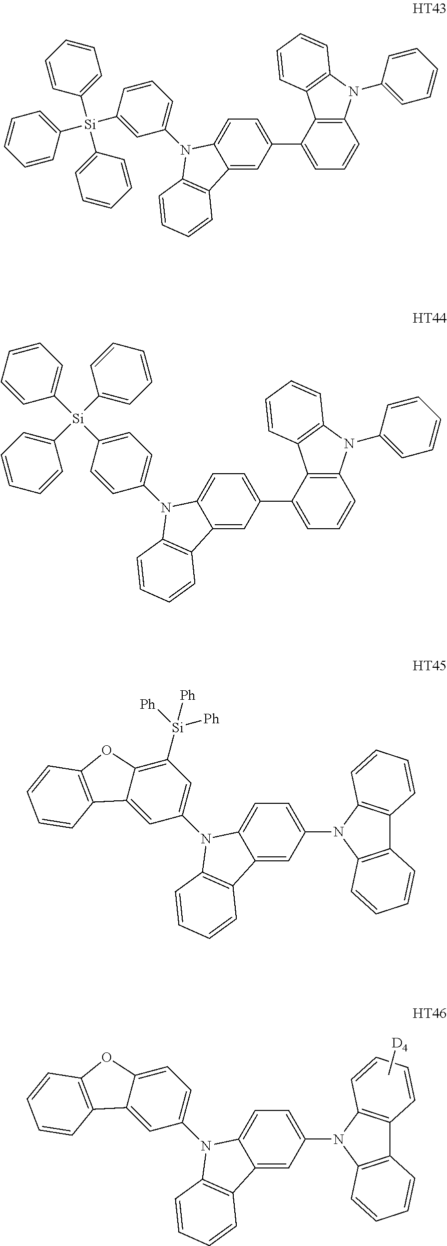

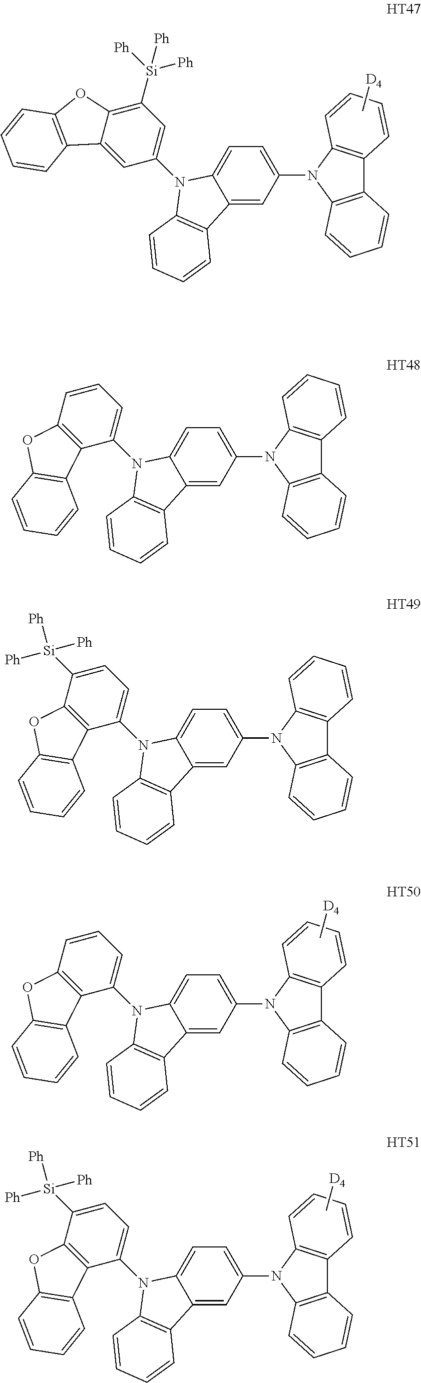

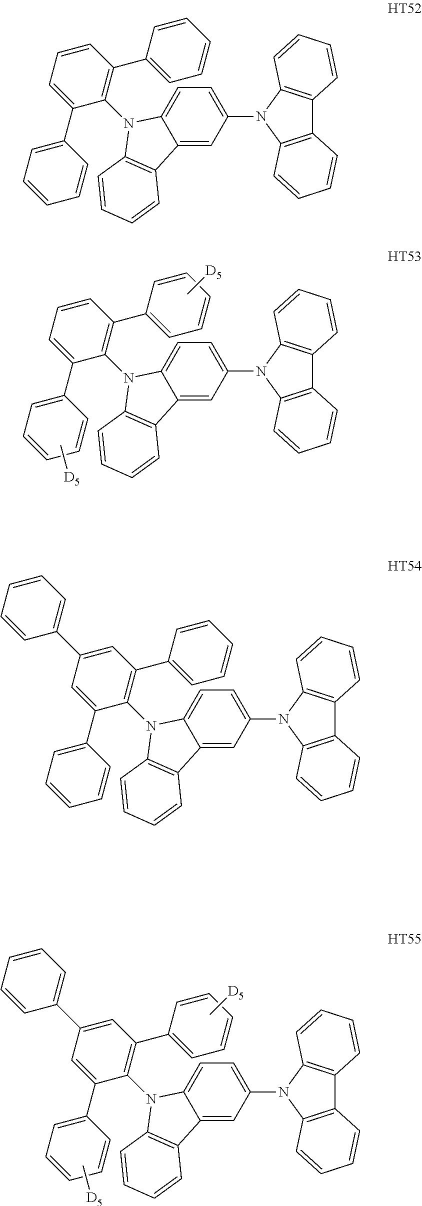

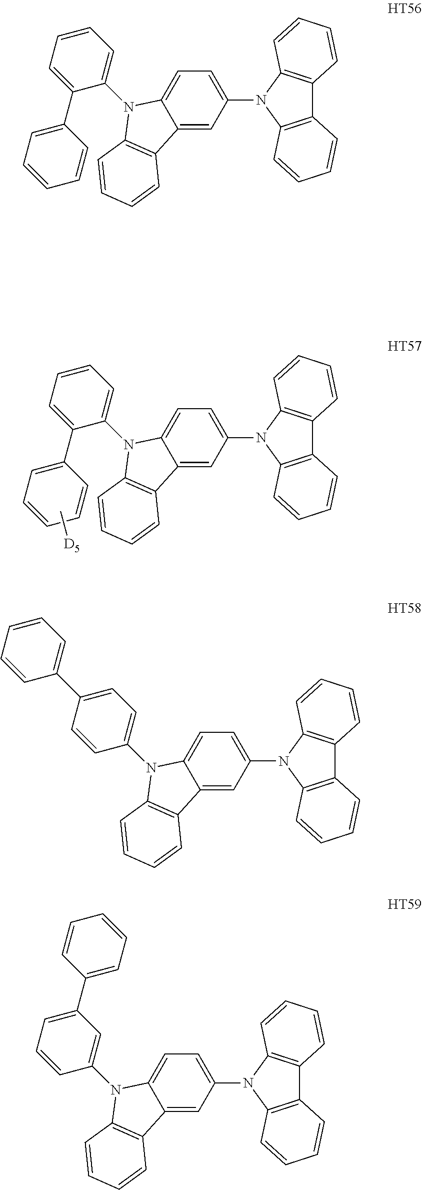

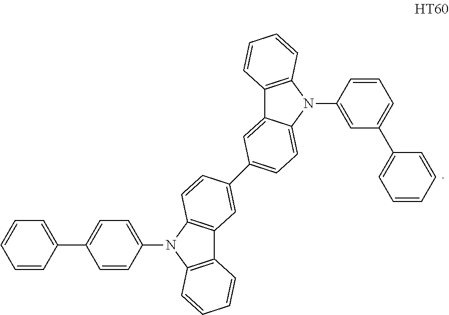 [SMILES: c1ccc(-c2ccc(-n3c4ccccc4c4cc(-c5ccc6c(c5)c5ccccc5n6-c5cccc(-c6ccccc6)c5)ccc43)cc2)cc1]

In Compound Group 2, D represents a deuterium atom, and Ph represents an unsubstituted phenyl group.

In an embodiment, the emission layer EML may further include a third compound represented by Formula ET-1. In an embodiment, the third compound may be used as an electron transport host material in the emission layer EML.

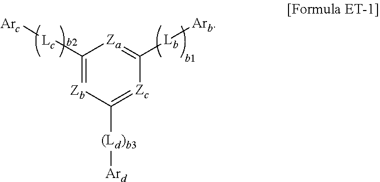

In Formula ET-1, at least one of Zₐ to Z_{c} may be N; and the remainder of Zₐ to Z_{c} may each independently be C(R₅₆). For example, one of Zₐ to Z_{c} may be N, and the remainder of Zₐ to Z_{c} may each independently be C(R₅₆). Thus, the third compound represented by Formula ET-1 may include a pyridine moiety. As another example, two of Zₐ to Z_{c} may be N, and the remainder of Zₐ to Z_{c} may be C(R₅₆). Thus, the third compound represented by Formula ET-1 may include a pyrimidine moiety. As yet another example, Zₐ to Z_{c} may each be N. Thus, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer from 0 to 10.

In Formula ET-1, Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar_{b} to Ar_{d} may each independently be a substituted or unsubstituted phenyl group or a substituted or unsubstituted carbazole group.

In Formula ET-1, L_{b} to L_{d} may each independently be a direct linkage, a substituted or unsubstituted arylene group of 6 to 30 ring-forming carbon atoms, or a substituted or unsubstituted heteroarylene group of 2 to 30 ring-forming carbon atoms. If b1 to b3 are each 2 or more, multiple groups of each of L_{b} to L_{d} may each independently be a substituted or unsubstituted arylene group of 6 to 30 ring-forming carbon atoms or a substituted or unsubstituted heteroarylene group of 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3:

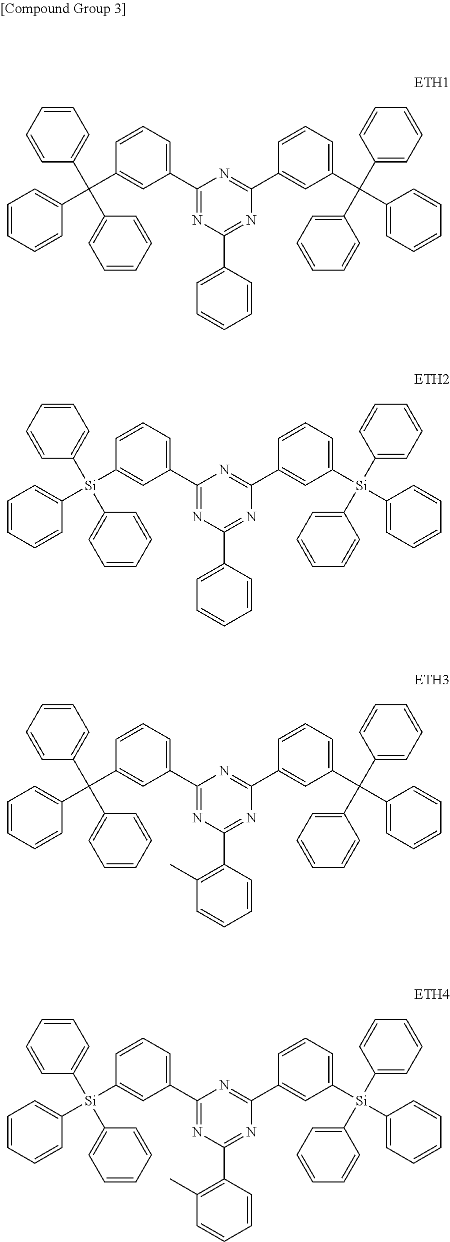 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

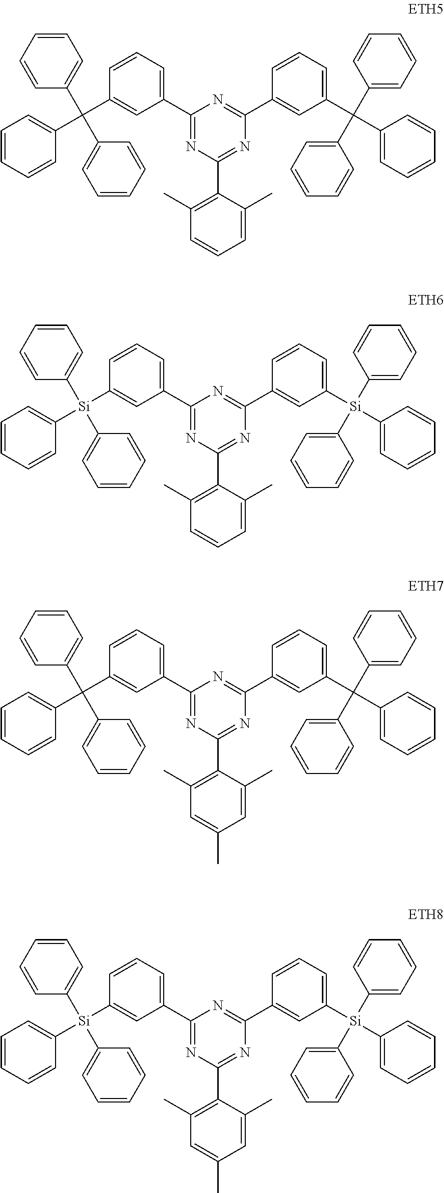 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

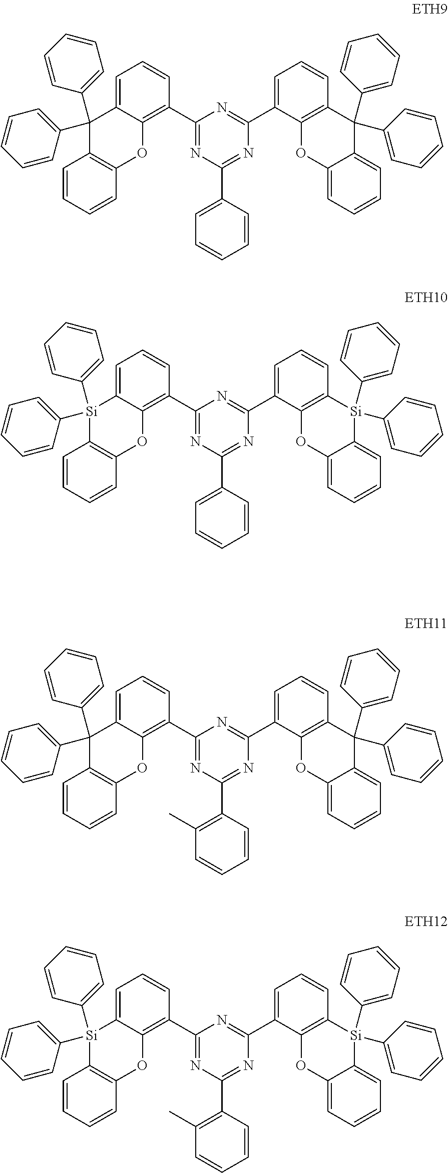 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

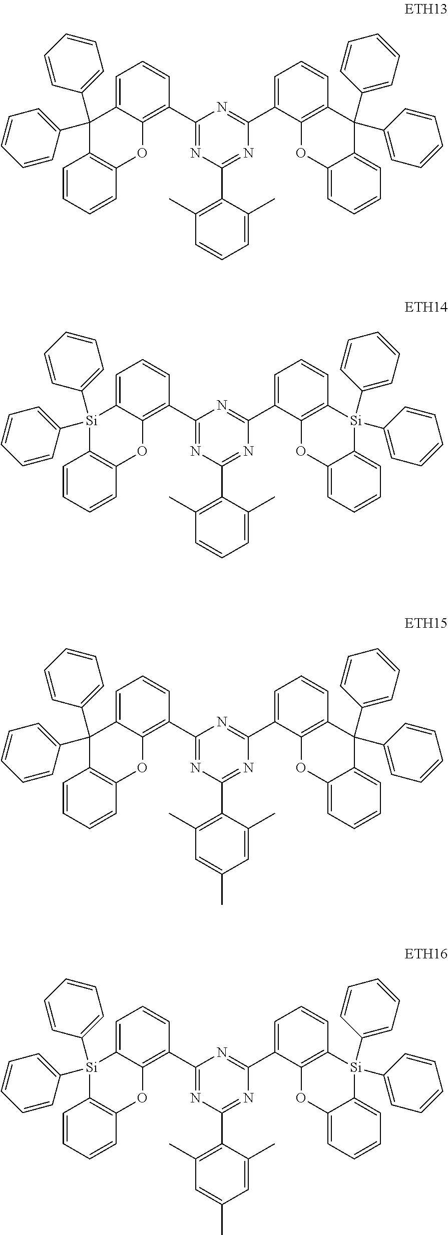 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

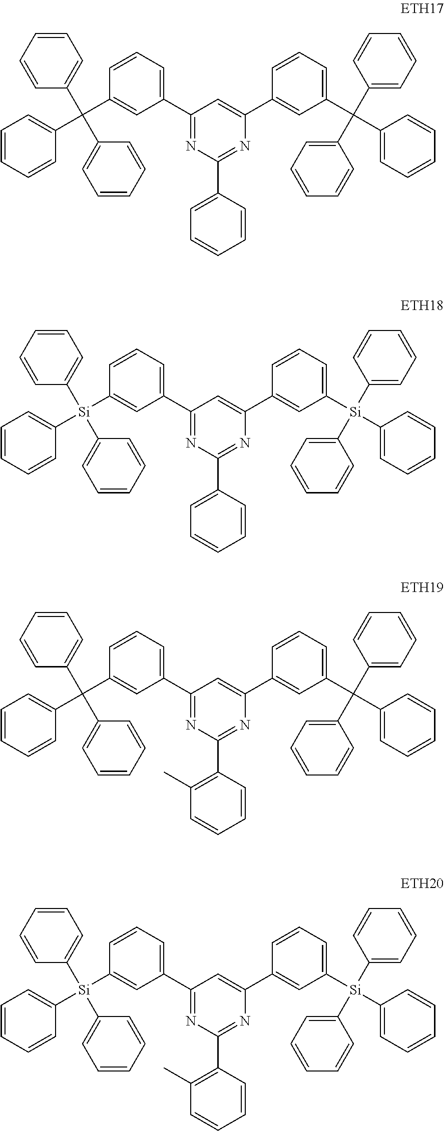 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

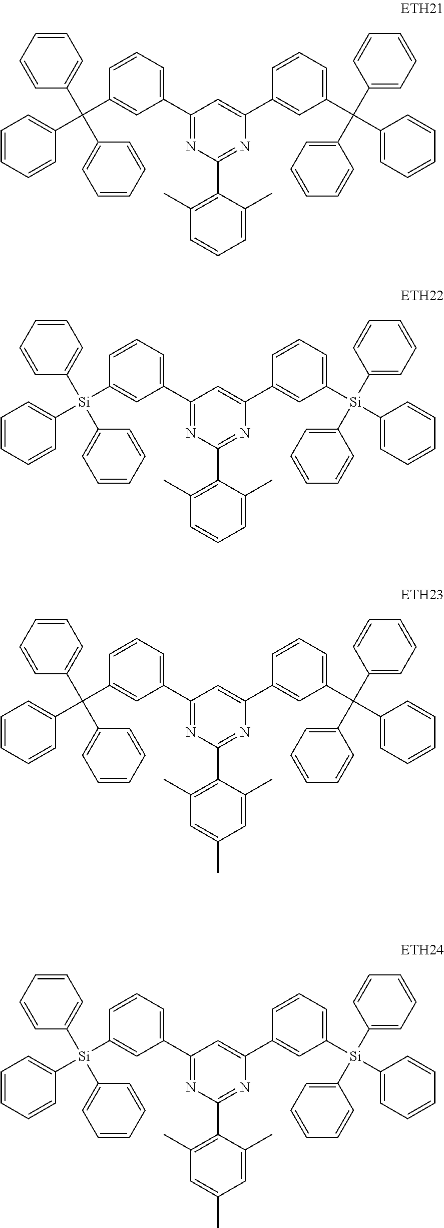 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

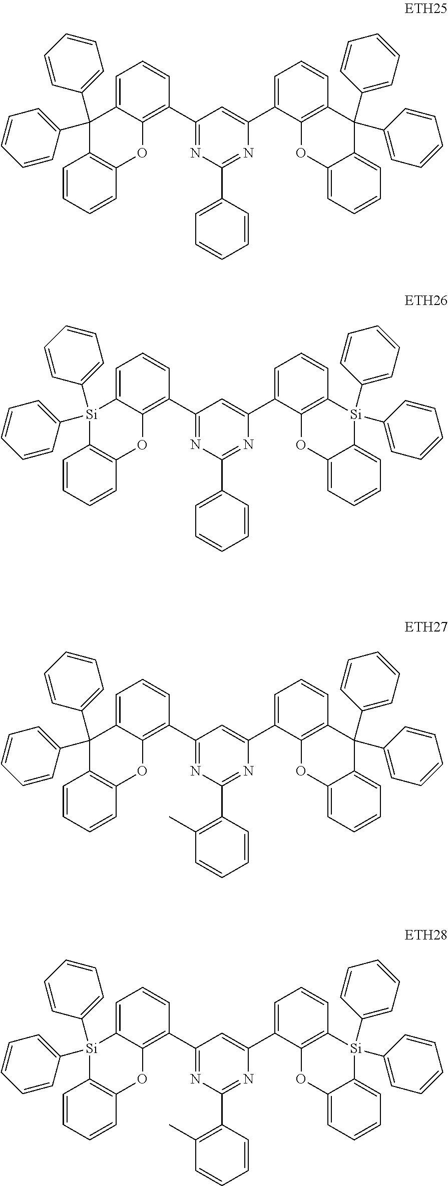 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

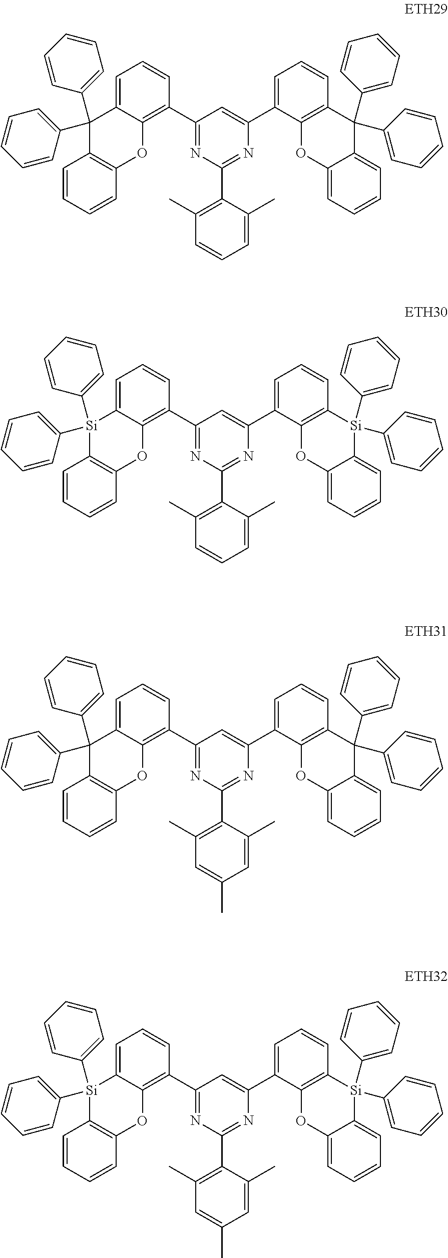 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

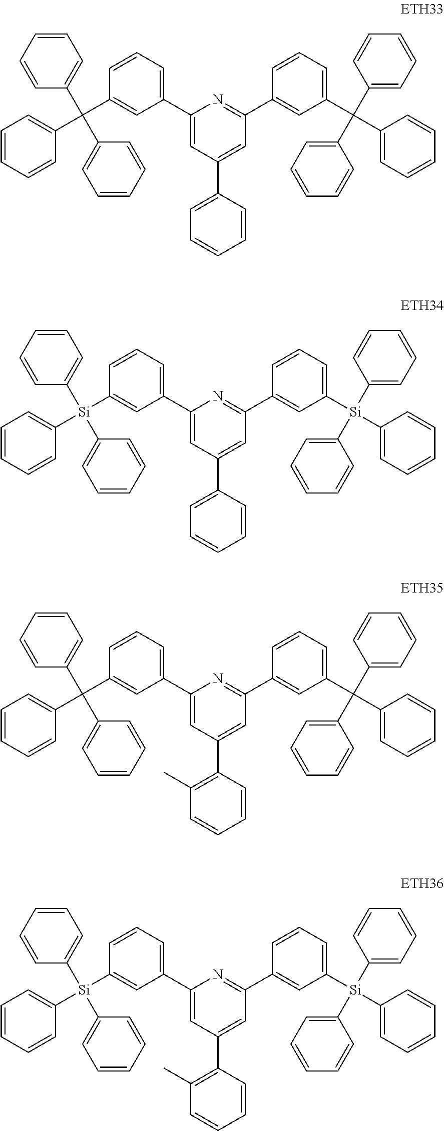 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

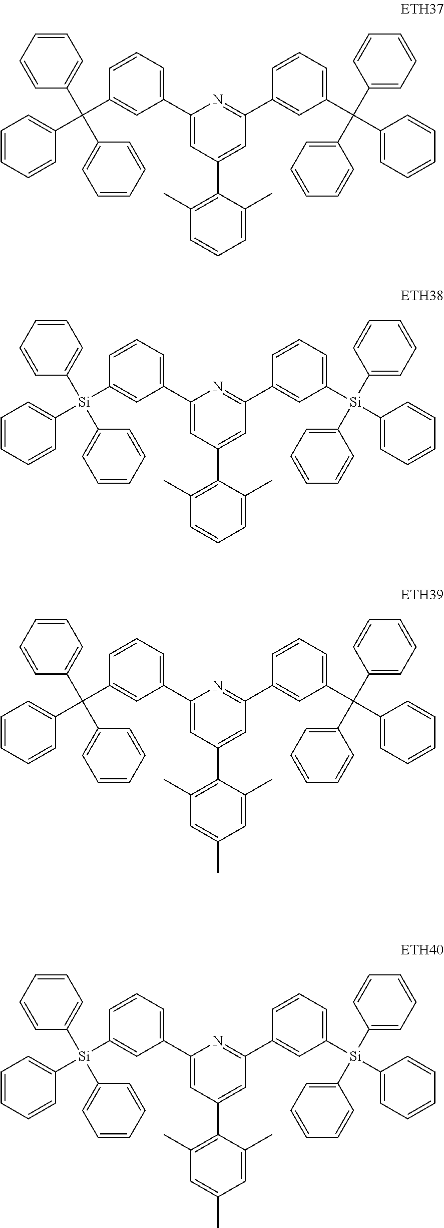 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

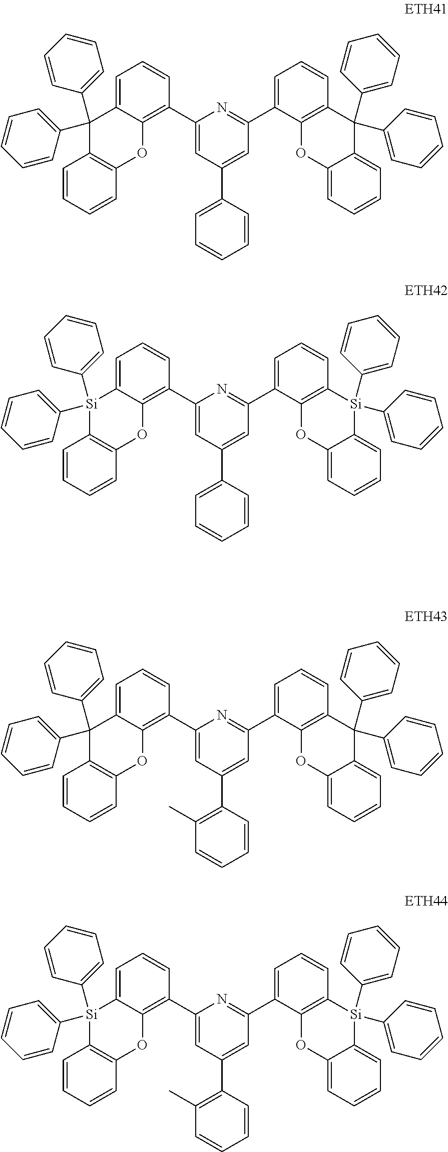 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

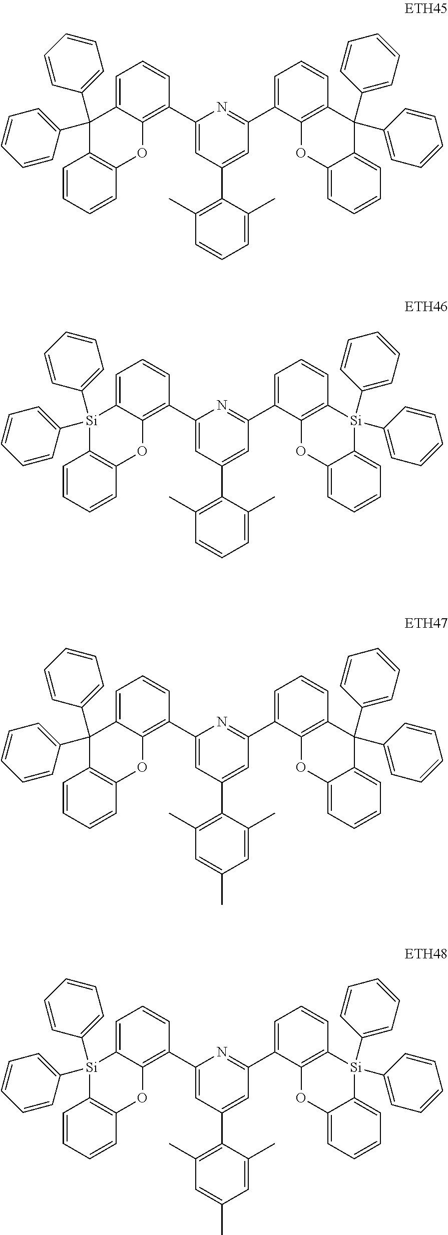 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

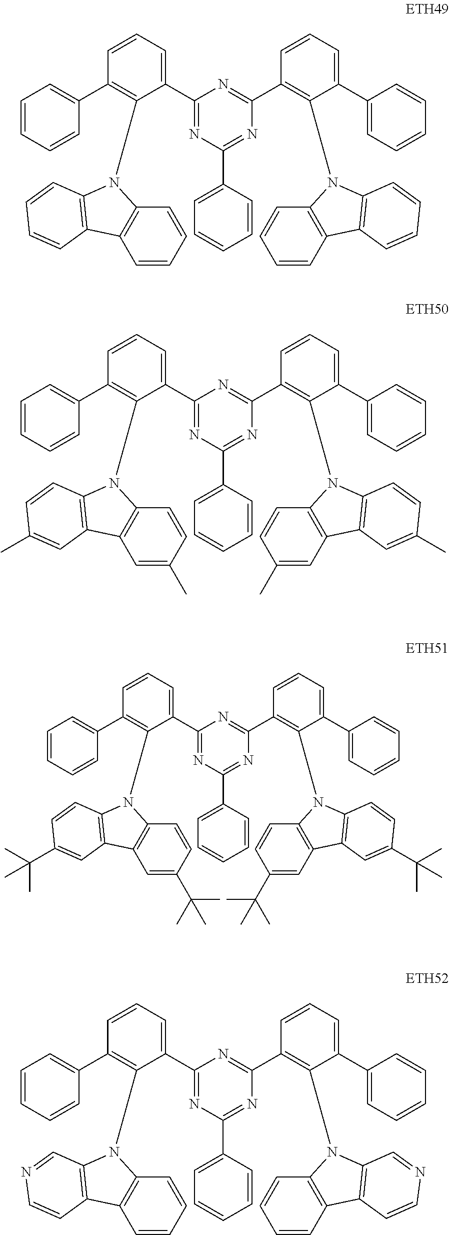

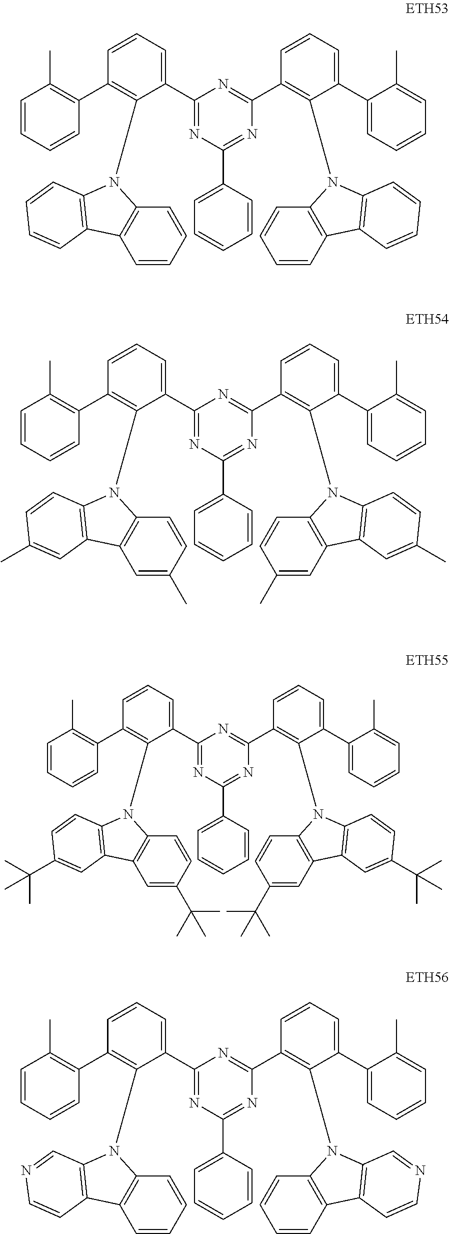

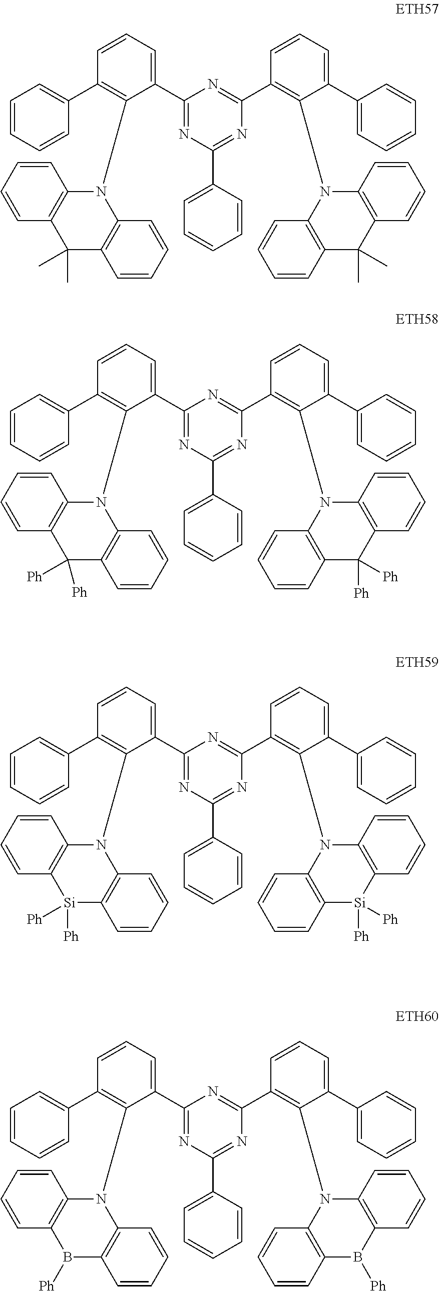

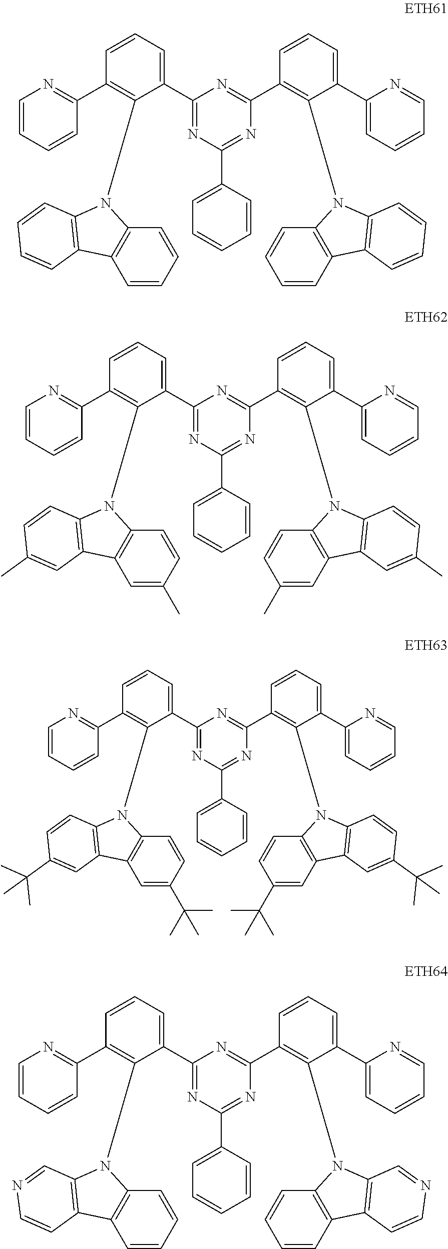

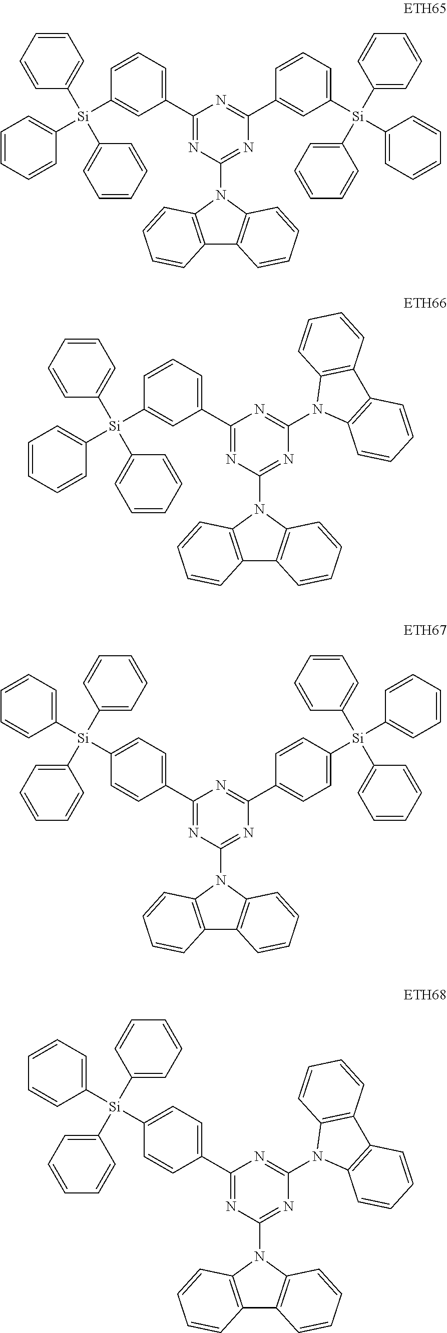 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

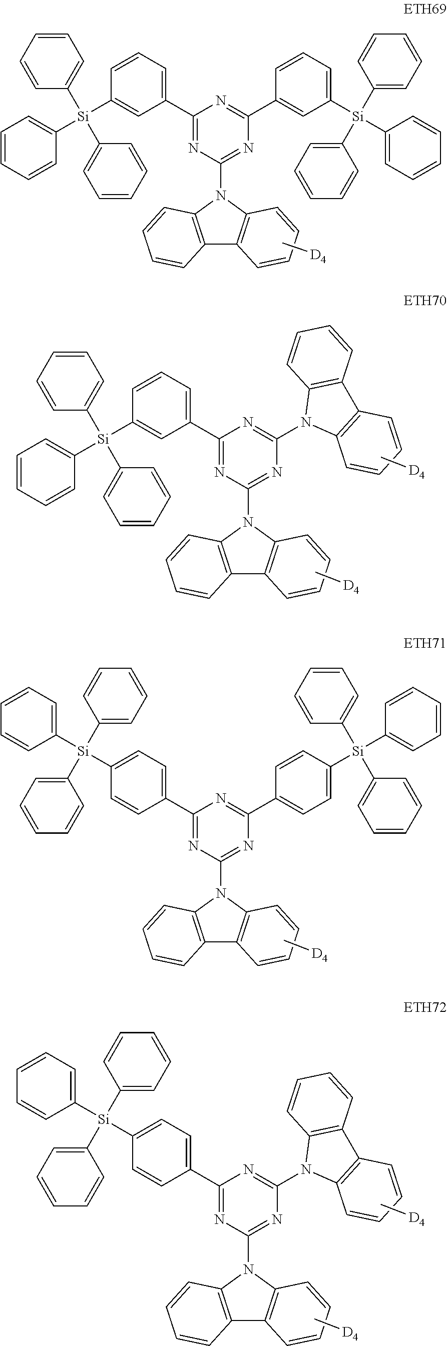

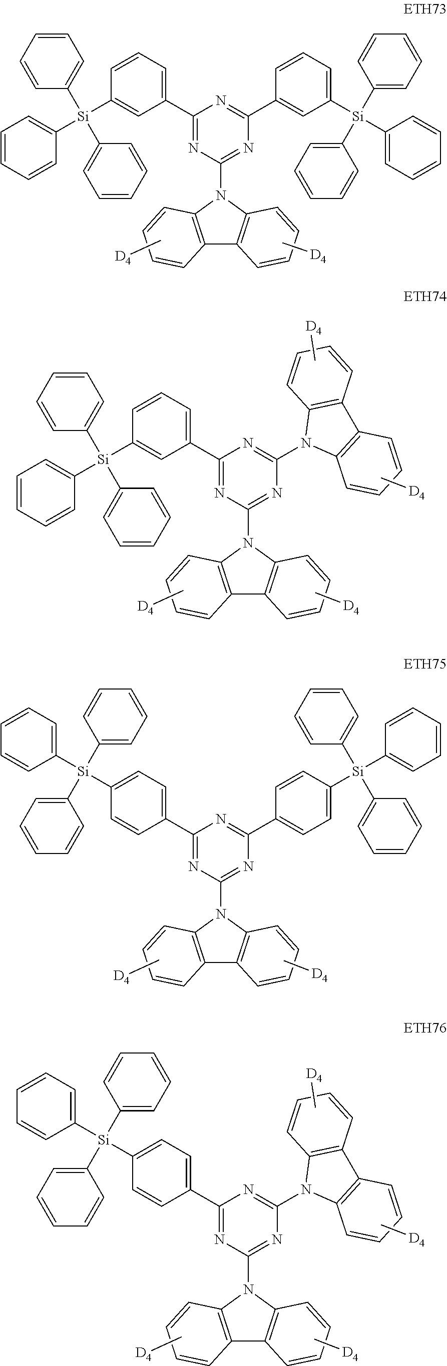

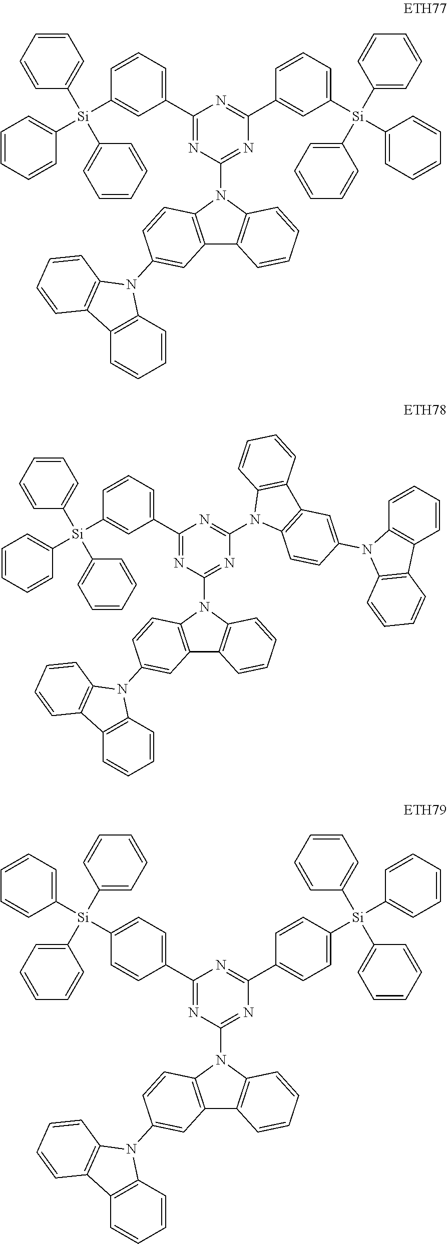 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

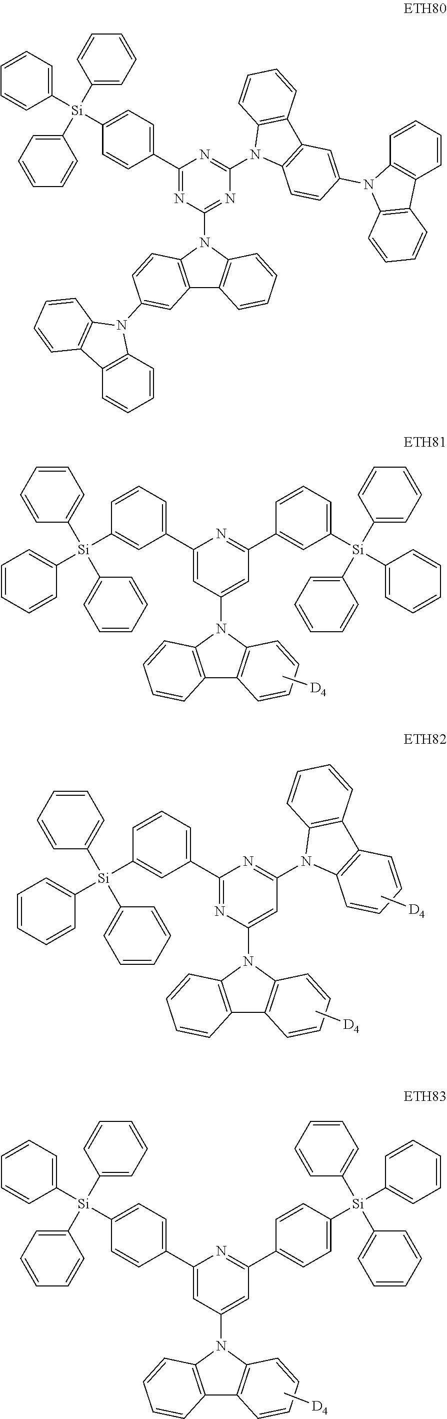

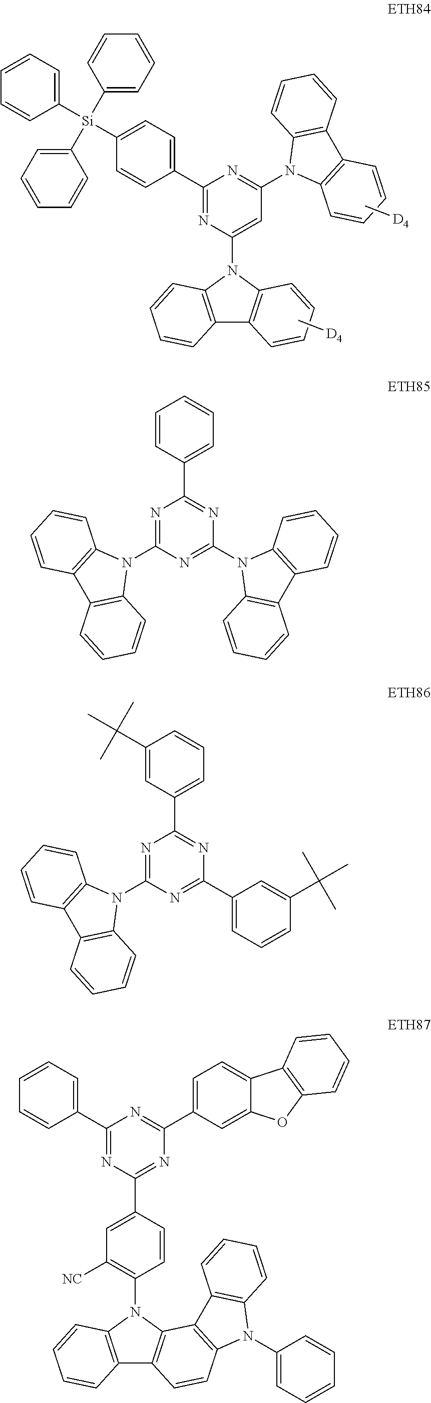

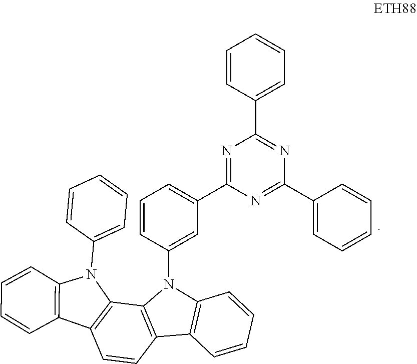 [SMILES: c1ccc(-c2nc(-c3ccccc3)nc(-c3cccc(-n4c5ccccc5c5ccc6c7ccccc7n(-c7ccccc7)c6c54)c3)n2)cc1]

In Compound Group 3, D represented a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by the hole transport host and the electron transport host may be in a range of about 2.4 eV to about 3.0 eV. The triplet energy level of the exciplex may be a value that is less than an energy gap of each host material. The exciplex may have a triplet energy level equal to or less than about 3.0 eV, which is an energy gap between the hole transport host and the electron transport host.

In an embodiment, the emission layer EML may further include a fourth compound, in addition to the first compound, the second compound, and the third compound. The fourth compound may be used as a phosphorescence sensitizer in the emission layer EML. Energy may be transferred from the fourth compound to the first compound, thereby implementing light emission.

In an embodiment, the emission layer EML may further include, as a fourth compound, an organometallic complex that includes platinum (Pt) as a central metal atom and ligands bonded to the central metal atom. In an embodiment, the emission layer EML may include a fourth compound represented by Formula D-1:

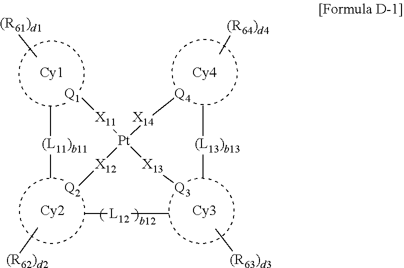

In Formula D-1, Q₁ to Q₄ may each independently be C or N.

In Formula D-1, Cy1 to Cy4 may each independently be a substituted or unsubstituted hydrocarbon ring of 5 to 30 ring-forming carbon atoms or a substituted or unsubstituted heterocycle of 2 to 30 ring-forming carbon atoms.

In Formula D-1, X₁₁ to X₁₄ may be each independently a direct linkage or *—O—*. For example, any one of X₁₁ to X₁₄ may be *—O—*, and the remainder of X₁₁ to X₁₄ may each be a direct linkage.

In Formula D-1, L₁₁ to L₁₃ may each independently be a direct linkage,

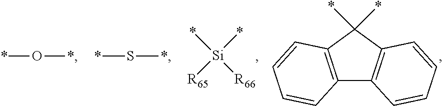

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, -* represents a bond to one of C1 to C4.

In Formula D-1, b11 to b13 may each independently be 0 or 1. If b11 is 0, C1 and C2 may not be directly connected to each other. If b12 is 0, C2 and C3 may not be directly connected to each other. If b3 is 0, C3 and C4 may not be directly connected to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R₆₁ to R₆₄, respectively. A case where d1 to d4 are each 4 and four groups of each of R₆₁ to R₆₄ are all hydrogen atoms may be the same as a case where d1 to d4 are each 0. If d1 to d4 are each 2 or more, multiple groups of each of R₆₁ to R₆₄ may all be the same, or at least one thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-5:

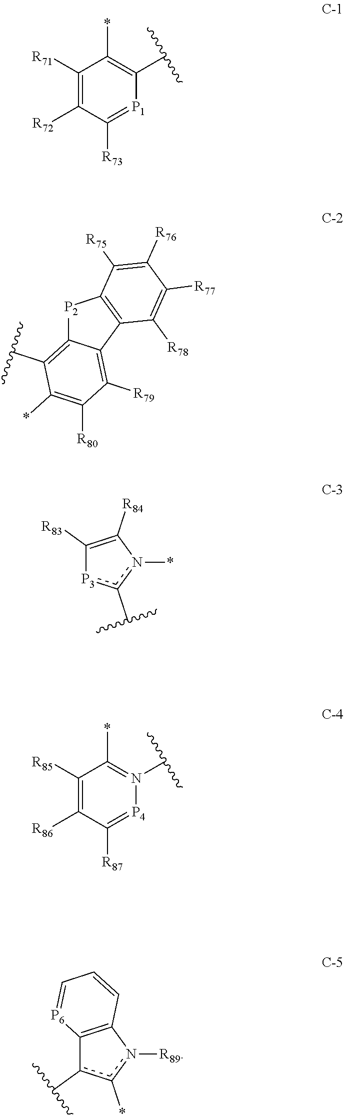

In Formula C-1 to Formula C-5, P₁ may be C—* or C(R₇₄), P₂ may be N—* or N(R₈₁), P₃ may be N—* or N(R₈₂), P₄ may be C—* or C(R₈₈), and P₆ may be C—* or C(R₉₀). In Formula C-1 to Formula C-5, R₇₁ to R₉₀ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring.

In Formula C-1 to Formula C-5, [symbol] represents a bond to Pt, which is a central metal atom, and -* represents a bond to an adjacent ring group (C1 to C4) or to a linking moiety (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby implementing light emission.

In another embodiment, the emission layer EML may include the first compound, the second compound, the third compound, and the fourth compound. In the emission layer EML, the second compound and the third compound may form an exciplex, and energy may be transferred from the exciplex to the fourth compound and to the first compound, thereby implementing light emission. In an embodiment, the fourth compound may be a sensitizer. In the light emitting element ED, the fourth compound included in the emission layer EML may serve as a sensitizer that transfers energy from a host (for example, an exciplex host) to the first compound, which is a light-emitting dopant. For example, the fourth compound, which serves as an auxiliary dopant, may accelerate energy transfer to the first compound, which is a light emitting dopant, thereby increasing an emission ratio of the first compound. Accordingly, emission efficiency of the emission layer EML may be improved. If energy transfer to the first compound increases, excitons formed in the emission layer EML may not accumulate and may rapidly emit light, so that deterioration of a device may be reduced. Accordingly, the lifetime of the light emitting element ED may increase.

The light emitting element ED may include the first compound, the second compound, the third compound, and the fourth compound, and the emission layer EML may include a combination of two host materials and two dopant materials. In the light emitting element ED, the emission layer EML may include the second compound and the third compound, which are two different hosts, the first compound that emits delayed fluorescence, and the fourth compound that includes an organometallic complex, so that the light-emitting element ED may exhibit excellent emission efficiency properties.

In an embodiment, the fourth compound represented by Formula D-1 may be selected from Compound Group 4. In an embodiment, in the light-emitting element ED, the fourth compound may include at least one compound selected from Compound Group 4:

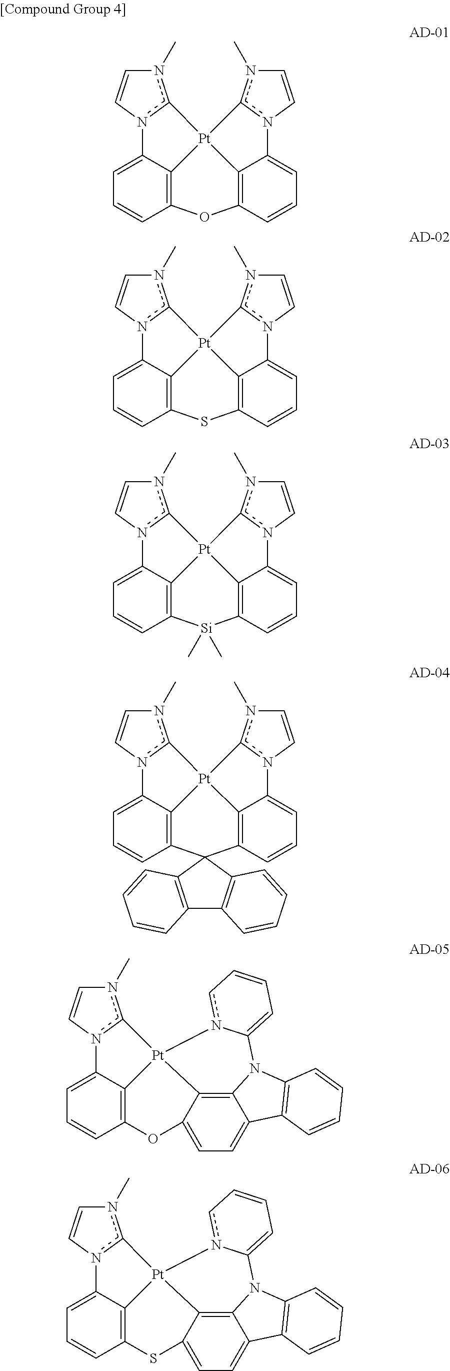

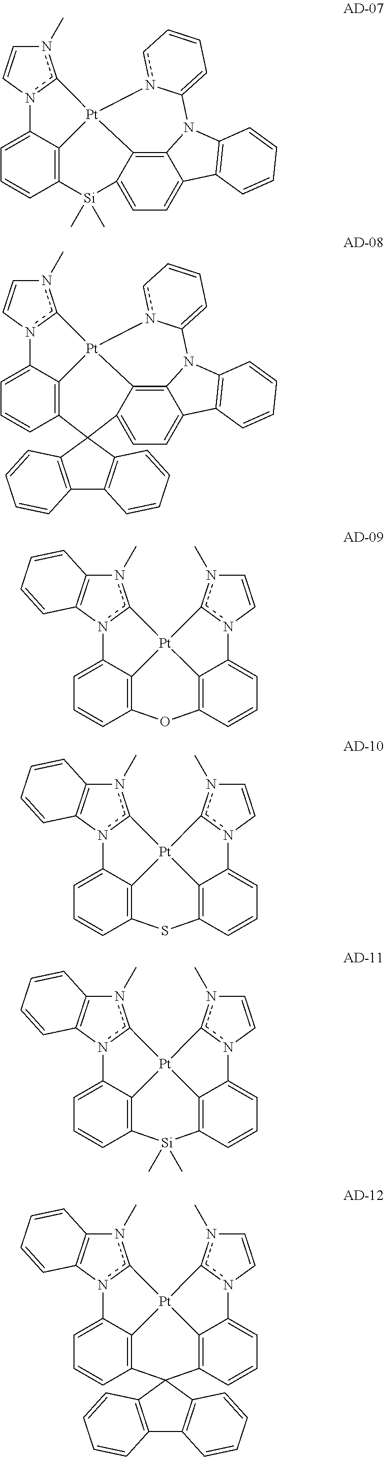

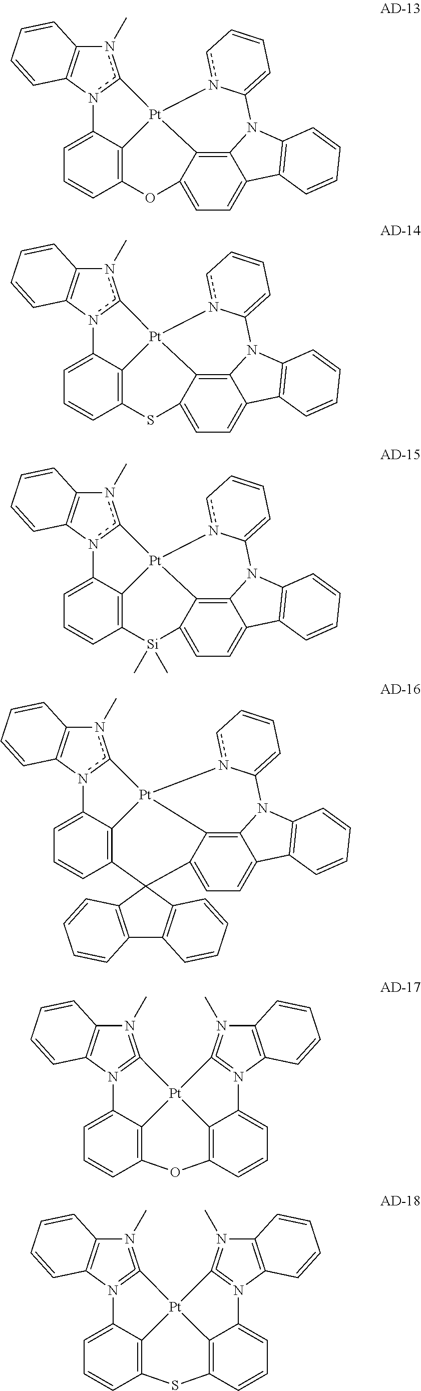

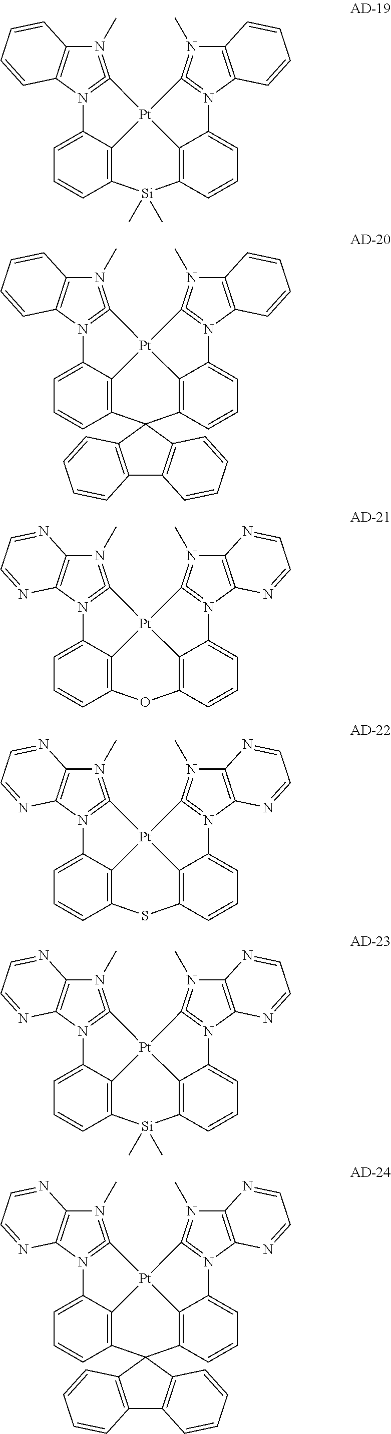

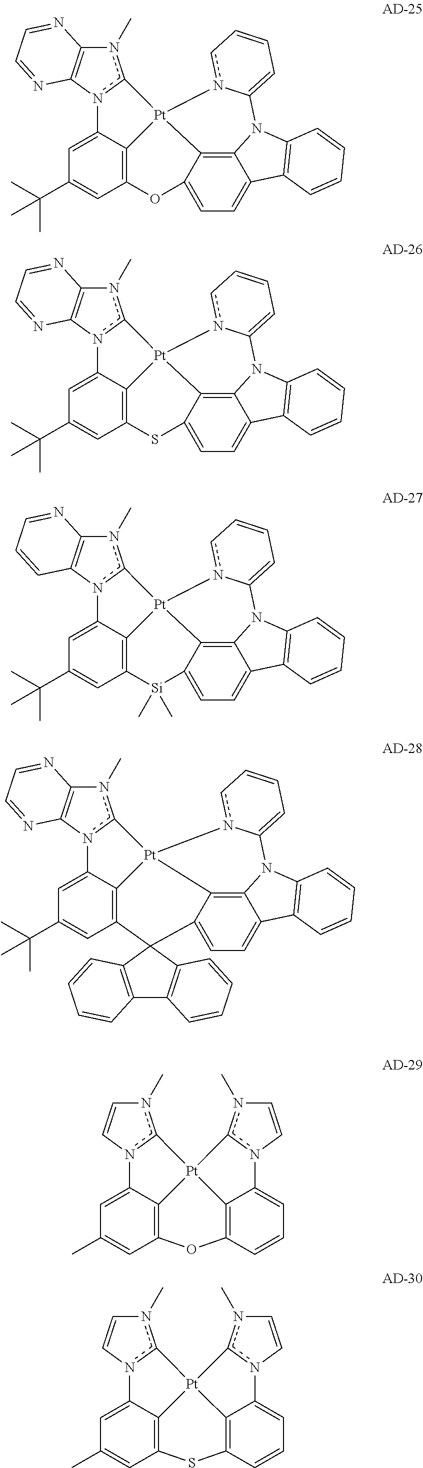

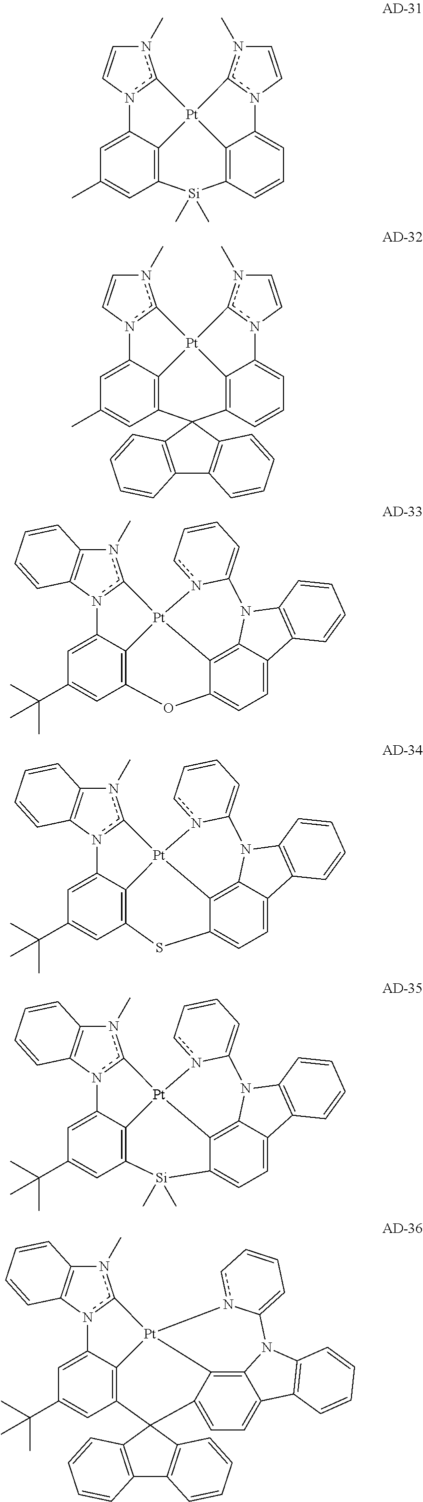

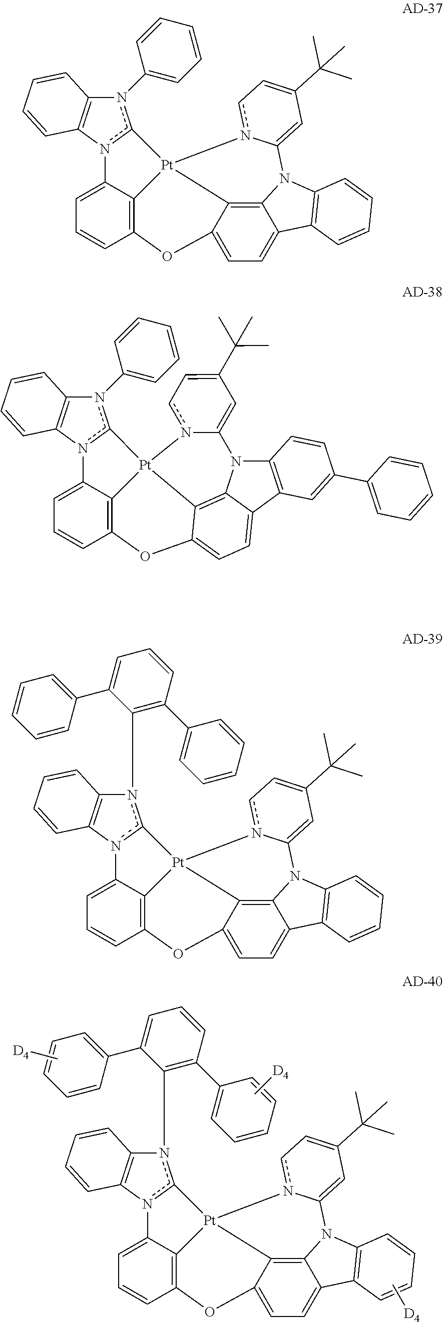

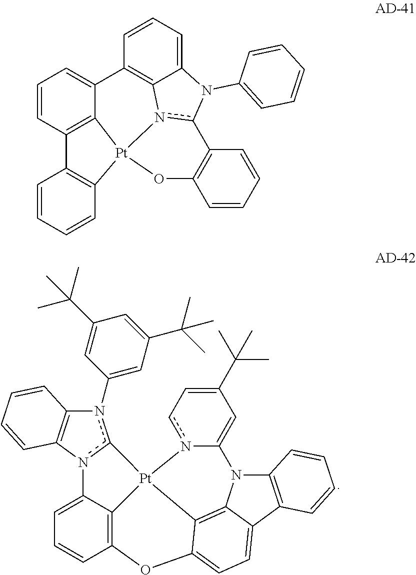

In Compound Group 4, D represents a deuterium atom.

In an embodiment, the light emitting element ED may include multiple emission layers. The multiple emission layers may be provided as a stack, so that the light emitting element ED may emit white light. The light emitting element ED including multiple emission layers may be a light emitting element having a tandem structure. If the light emitting element ED includes multiple emission layers, at least one emission layer EML may each independently include a first compound represented by Formula 1. If the light emitting element ED includes multiple emission layers, at least one emission layer EML may include the first compound, the second compound, the third compound, and the fourth compound.

In the light emitting element ED, if the emission layer EML includes the first compound, the second compound, the third compound, and the fourth compound, an amount of the first compound may be in a range of about 0.1 wt % to about 5 wt %, based on a total weight of the first compound, the second compound, the third compound, and the fourth compound. However, embodiments are not limited thereto. If an amount of the first compound satisfies the range described above, energy transfer from the second compound and the third compound to the first compound may increase, so that emission efficiency and device lifetime may increase.

In the emission layer EML, a combined amount of the second compound and the third compound may be the remainder of the total weight of the first compound, the second compound, the third compound, and the fourth compound, excluding the amount of the first compound and the fourth compound. For example, in the emission layer EML, a combined amount of the second compound and the third compound may be in a range of about 65 wt % to about 95 wt %, based on a total weight of the first compound, the second compound, the third compound, and the fourth compound.

Within the combined amount of the second compound and the third compound, a weight ratio of the second compound to the third compound may be in a range of about 3:7 to about 7:3.

If the amounts of the second compound and the third compound satisfies the ranges and ratios described above, charge balance properties of the emission layer EML may be improved, and emission efficiency and device lifetime may be improved. If the amounts of the second compound and the third compound deviate from the ranges and ratios described above, charge balance in the emission layer EML may not be achieved, emission efficiency may be reduced, and the device may readily deteriorate.

If the emission layer EML includes the fourth compound, an amount of the fourth compound may be in a range of about 4 wt % to about 30 wt %, based on a total weight of the first compound, the second compound, the third compound, and the fourth compound in the emission layer EML. However, embodiments are not limited thereto. If an amount of the fourth compound satisfies the range described above, energy transfer from a host (for example, an exciplex host) to the first compound, which is a light emitting dopant, may increase, so that an emission ratio may be improved. Accordingly, emission efficiency of the emission layer EML may be improved. If the amounts of the first compound, the second compound, the third compound, and the fourth compound included in the emission layer EML satisfy the ranges and ratios described above, excellent emission efficiency and long device lifetime may be achieved.

In the light emitting element ED, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as shown in FIG. 3 to FIG. 6, the emission layer EML may further include hosts and dopants of the related art, in addition to the host and dopant as described above. In an embodiment, the emission layer EML may include a compound represented by Formula E-1. The compound represented by Formula E-1 may be used as a fluorescence host material:

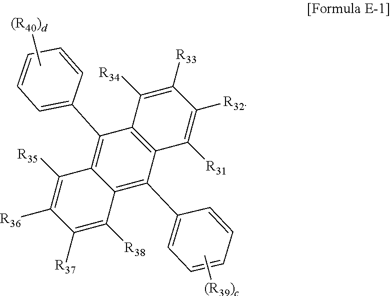

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E21:

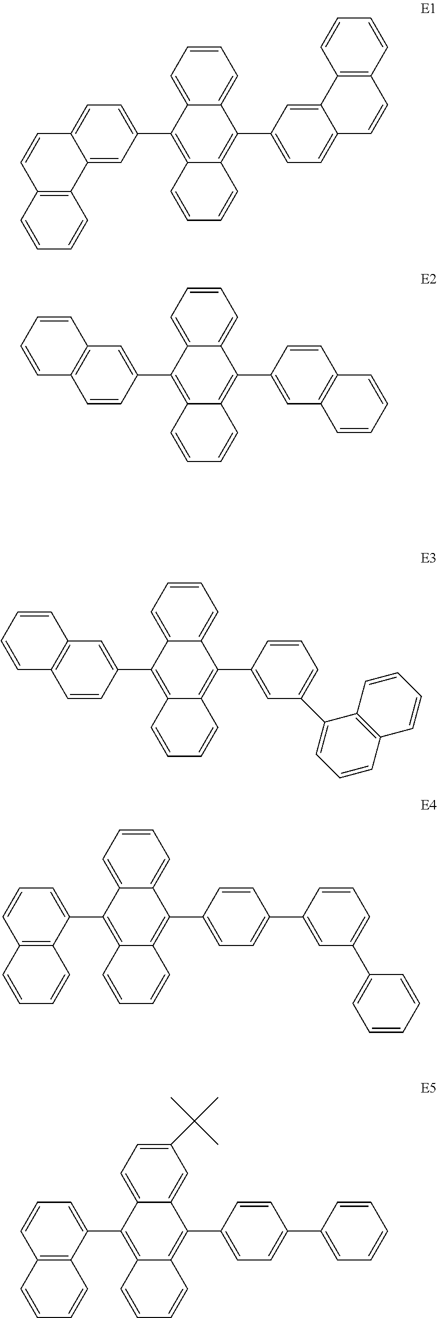

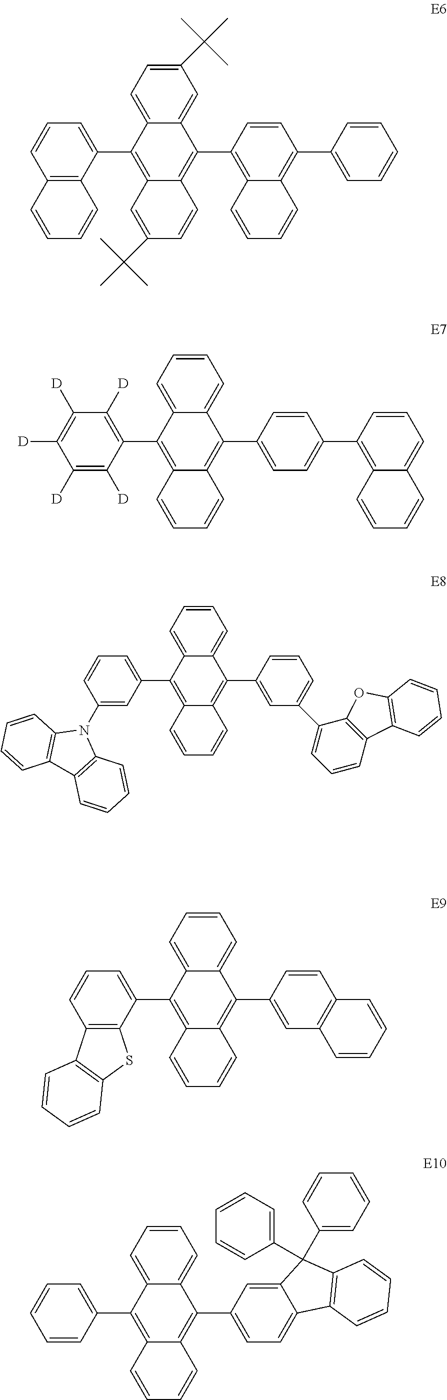

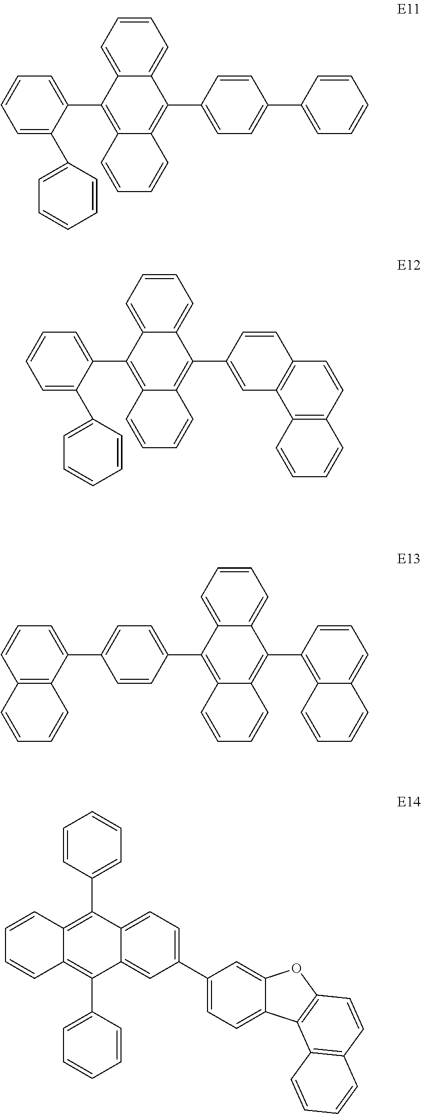

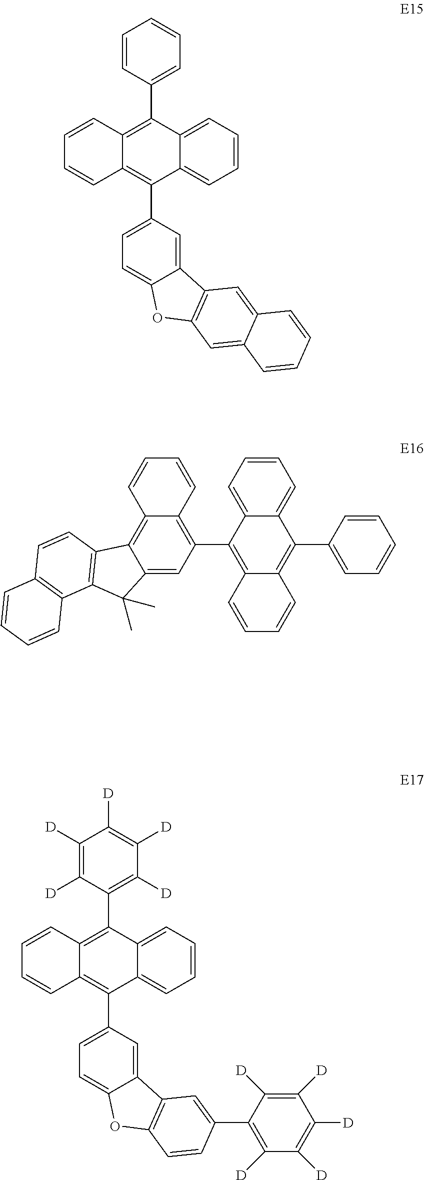

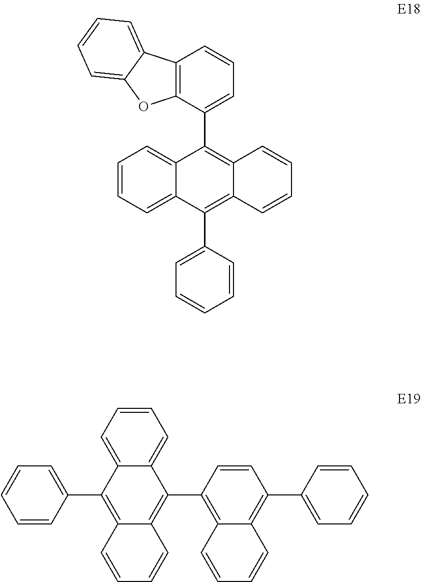

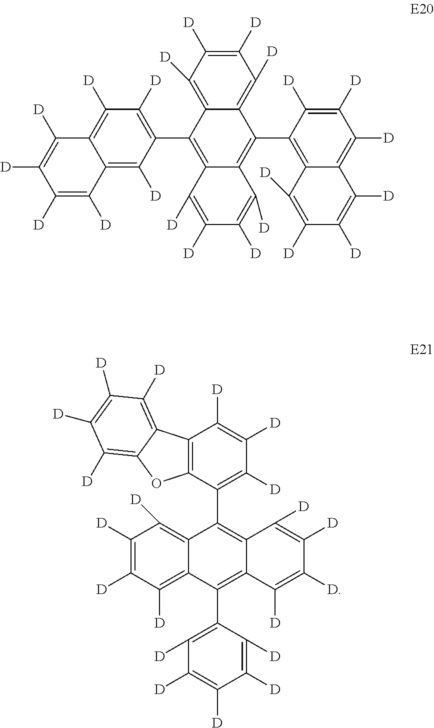

In an embodiment, the emission layer EML may include a compound represented by Formula E-2a or Formula E-2b. The compound represented by Formula E-2a or Formula E-2b may be used as a host material for a phosphorescent element.

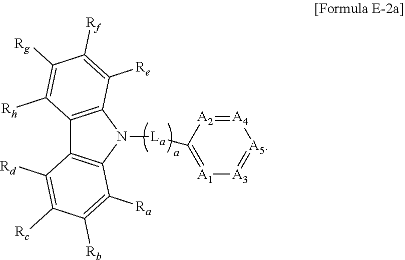

In Formula E-2a, a may be an integer from 0 to 10; Lₐ may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple Lₐ may each independently be a substituted or unsubstituted arylene group of 6 to 30 ring-forming carbon atoms or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring. For example, Rₐ to Rᵢ may be bonded to an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

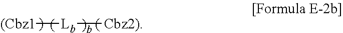

In Formula E-2b, Cbz1 and Cbz2 may each independently be an unsubstituted carbazole group or a carbazole group substituted with an aryl group of 6 to 30 ring-forming carbon atoms. In Formula E-2b, L_{b} may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10. If b is 2 or more, multiple L_{b} may each independently be a substituted or unsubstituted arylene group of 6 to 30 ring-forming carbon atoms or a substituted or unsubstituted heteroarylene group of 2 to 30 ring-forming carbon atoms.

In an embodiment, the compound represented by Formula E-2a or Formula E-2b may be any compound selected from Compound Group E-2. However, the compounds shown in Compound Group E-2 are only examples, and the compound represented by Formula E-2a or Formula E-2b is not limited to Compound Group E-2:

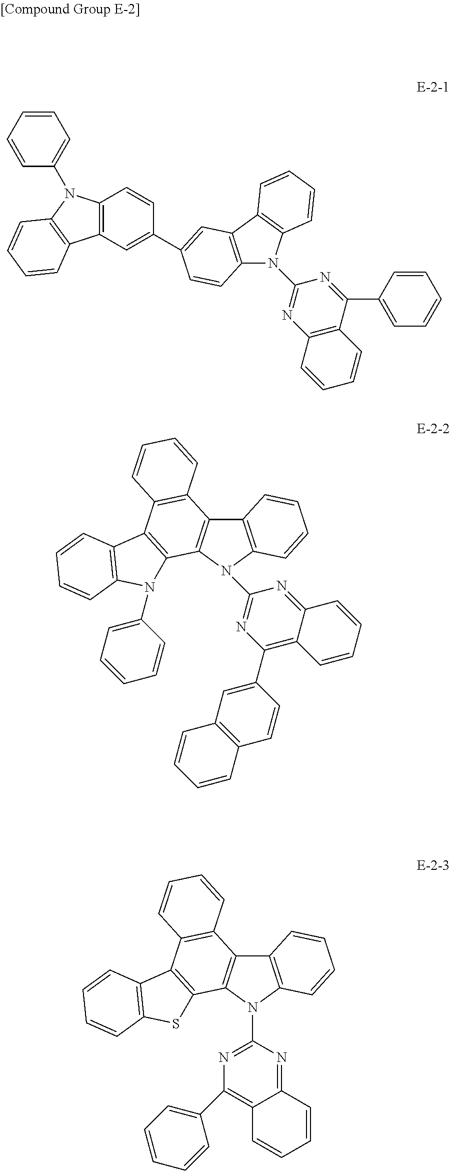 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

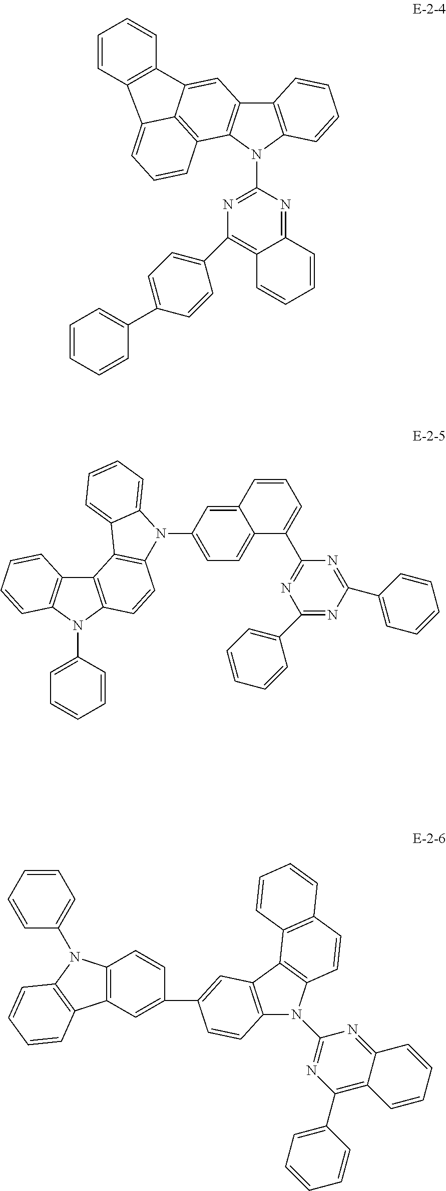 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

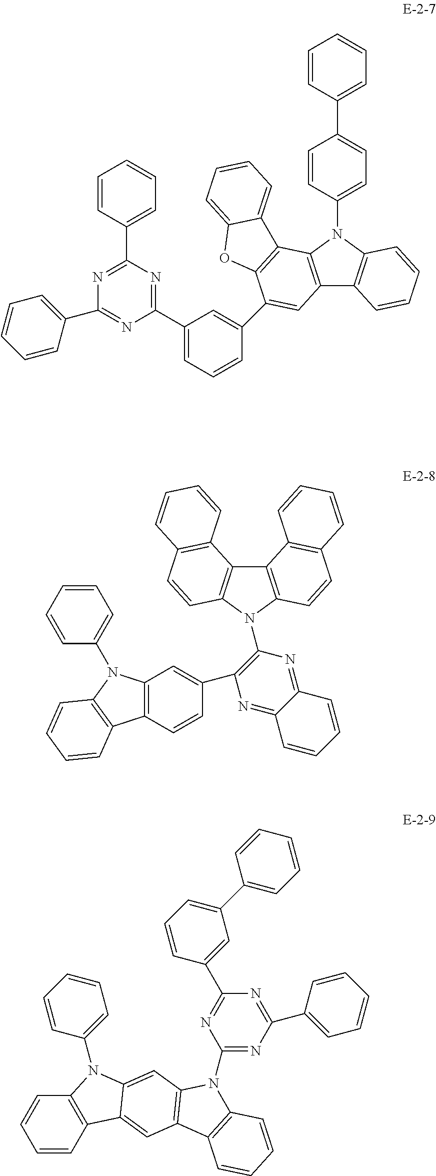 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

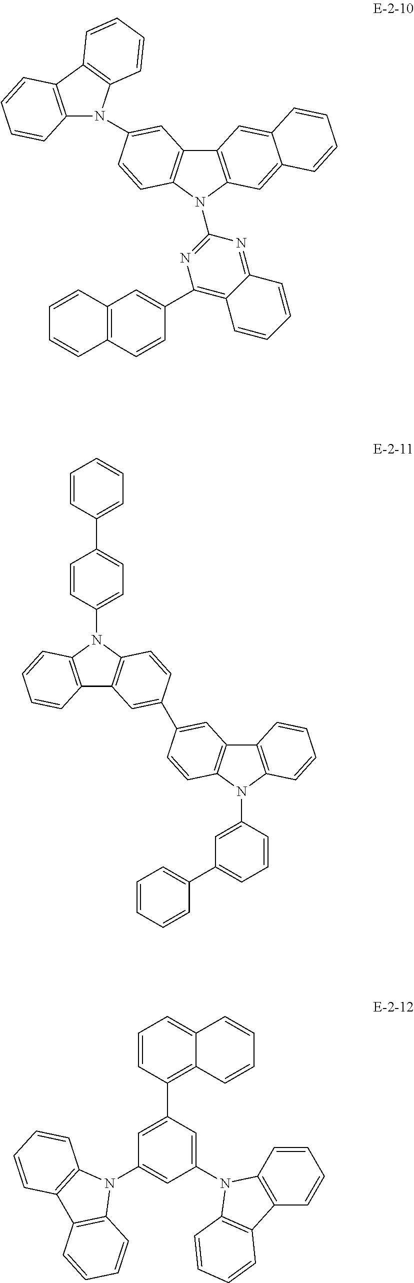 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

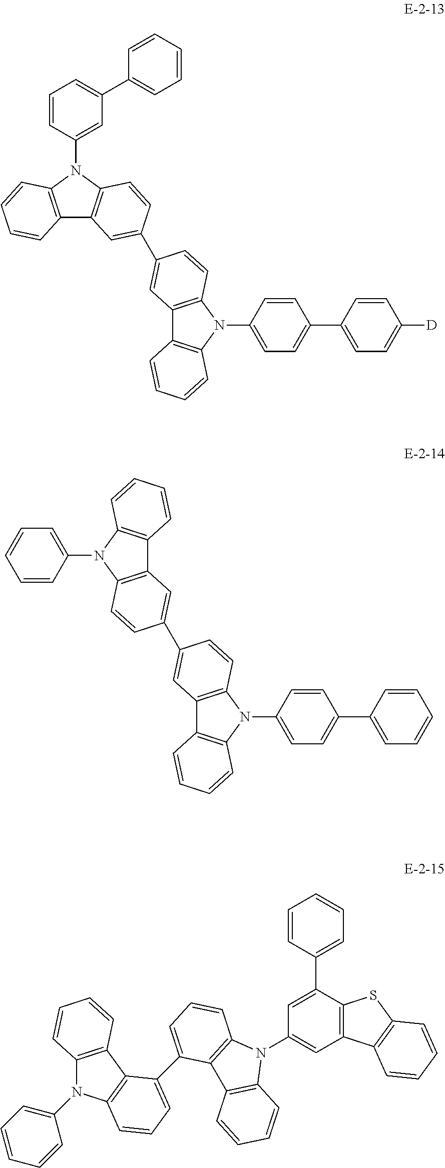 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

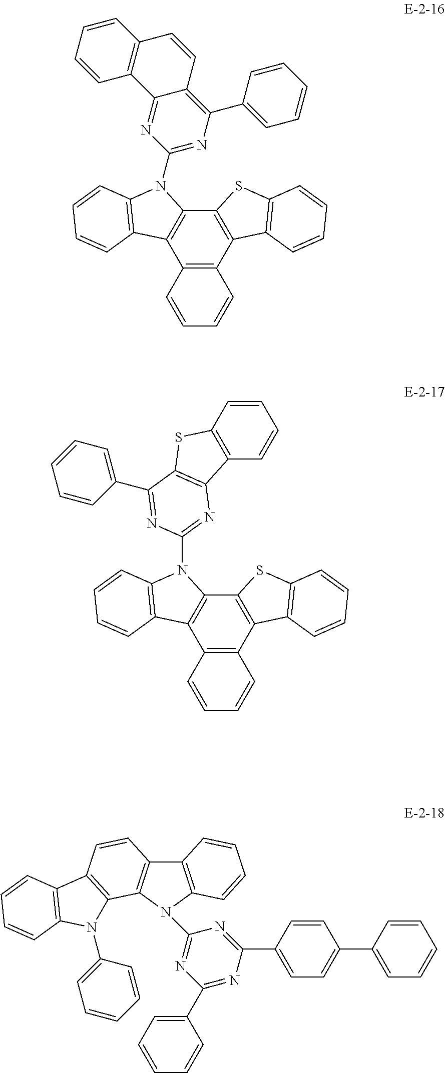 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

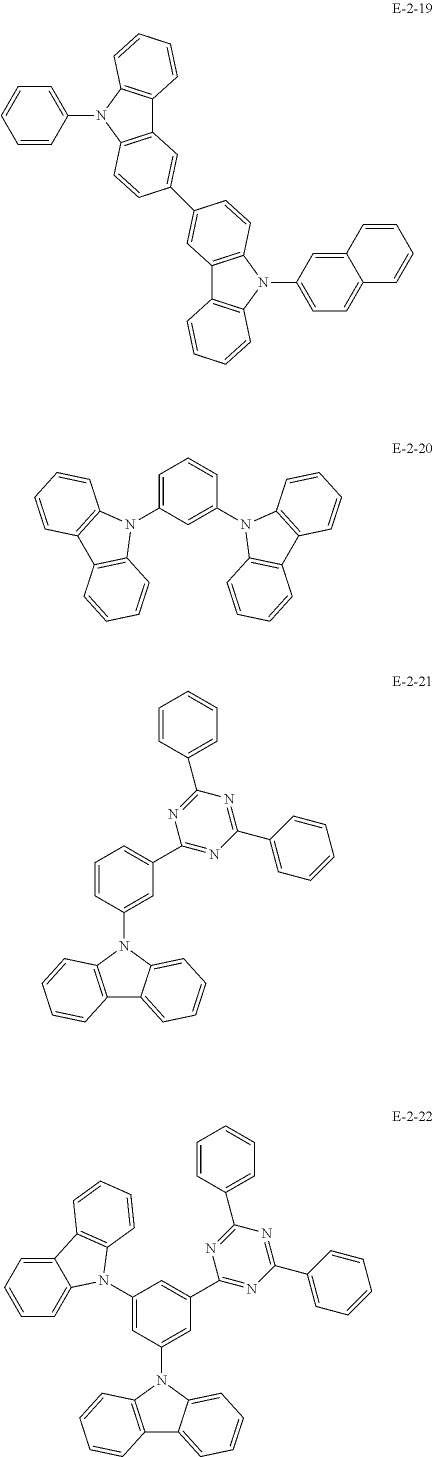 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

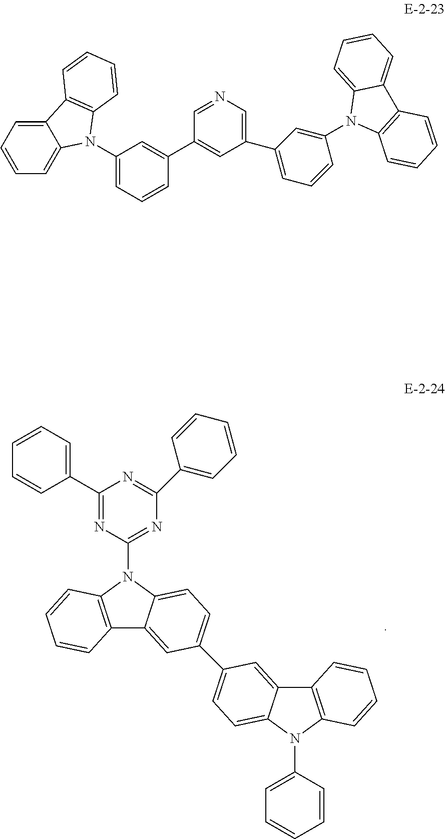 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In embodiments, the emission layer EML may further include a material of the related art as a host material. For example, the emission layer EML may include, as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

In an embodiment, the emission layer EML may include a compound represented by Formula M-a. The compound represented by Formula M-a may be used as a phosphorescence dopant material.

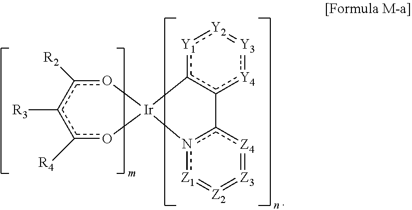

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring. In Formula M-a, m may be 0 or 1, and n may be 2 or 3. In Formula M-a, if m is 0, n may be 3, and if m is 1, n may be 2.

In an embodiment, the compound represented by Formula M-a may be any compound selected from Compounds M-a1 to M-a25. However, Compounds M-a1 to M-a25 are only examples, and the compound represented by Formula M-a is not limited to Compounds M-a1 to M-a25:

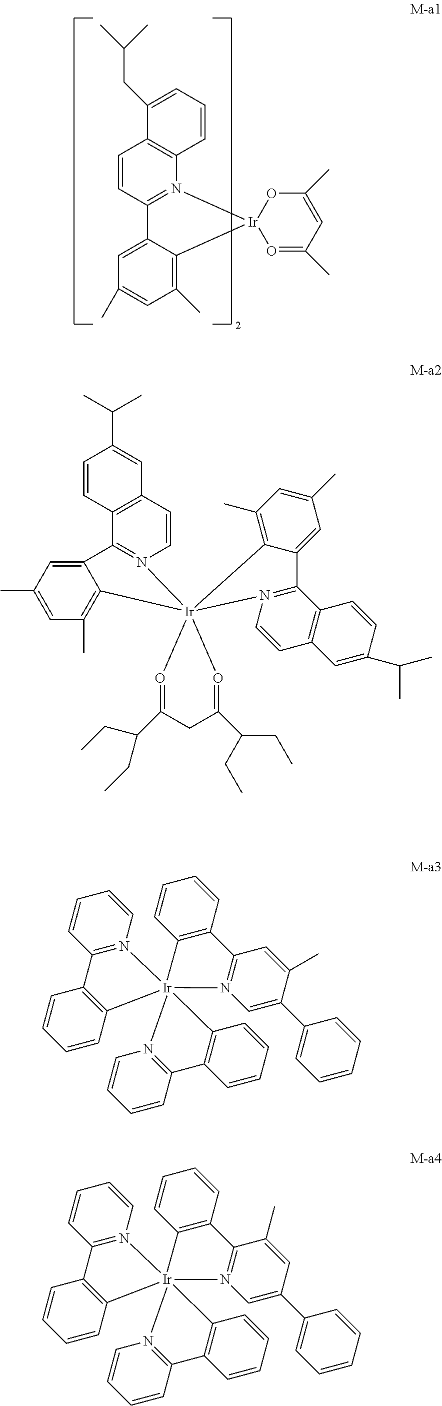

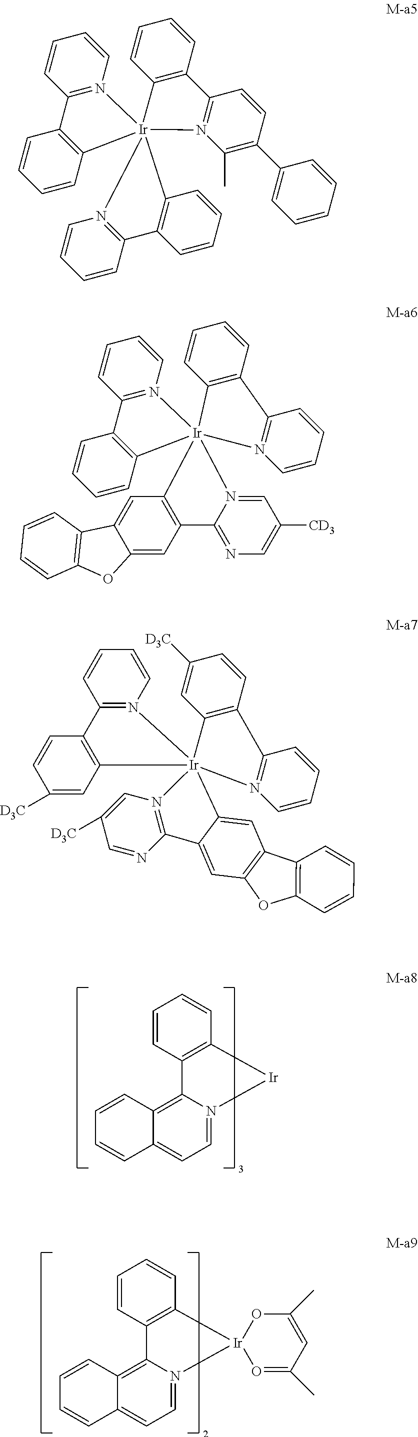

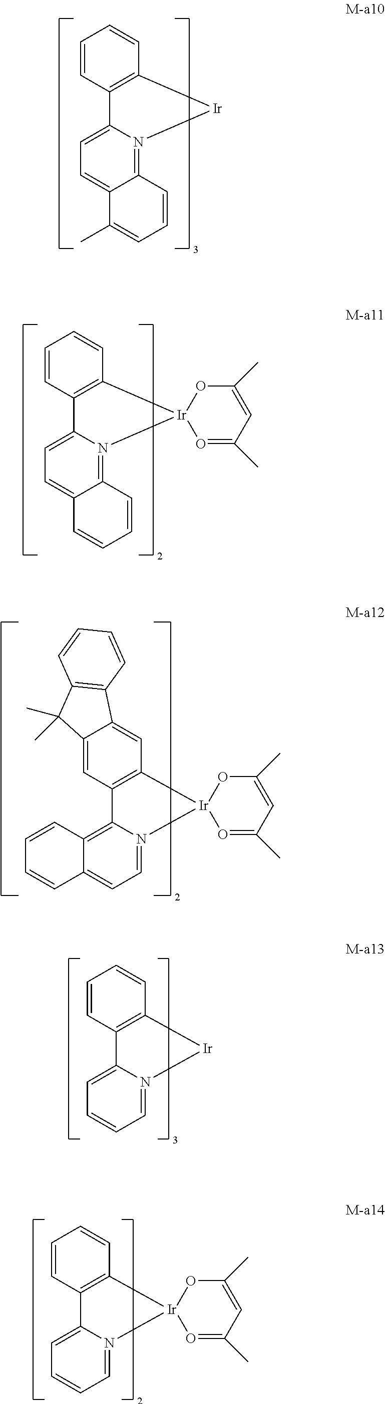

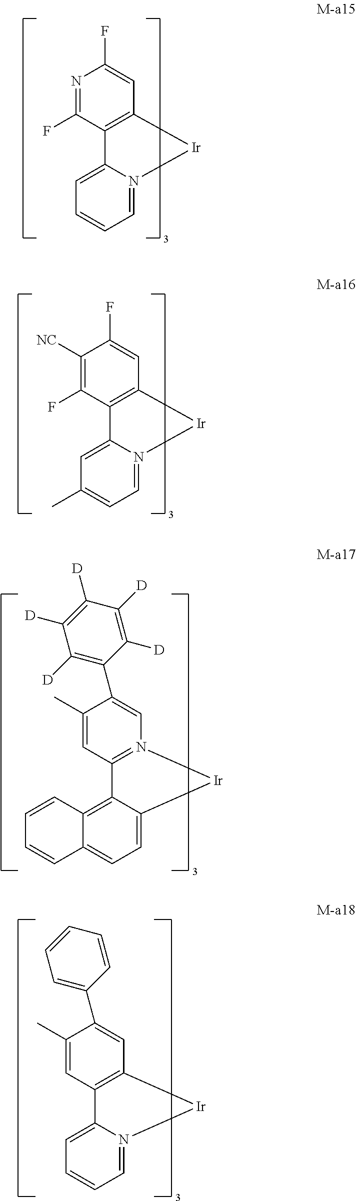

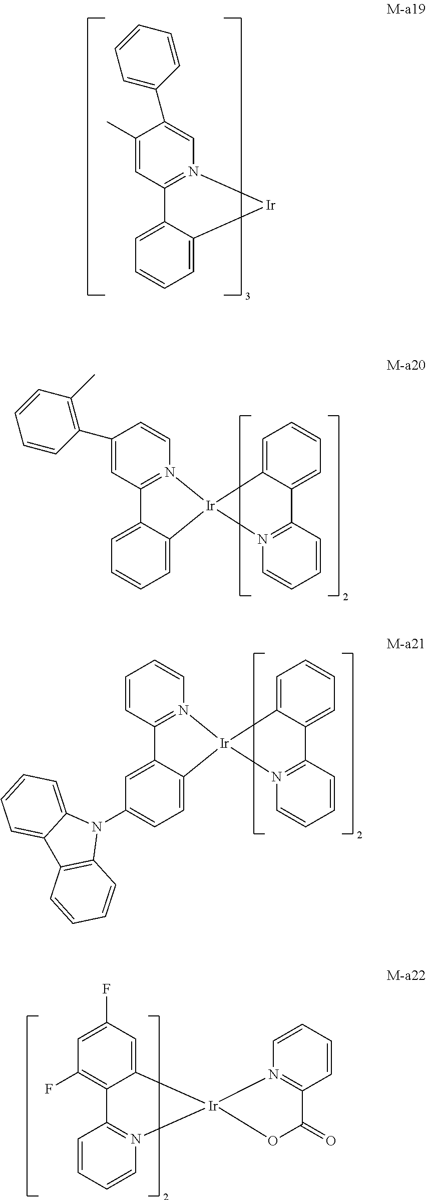

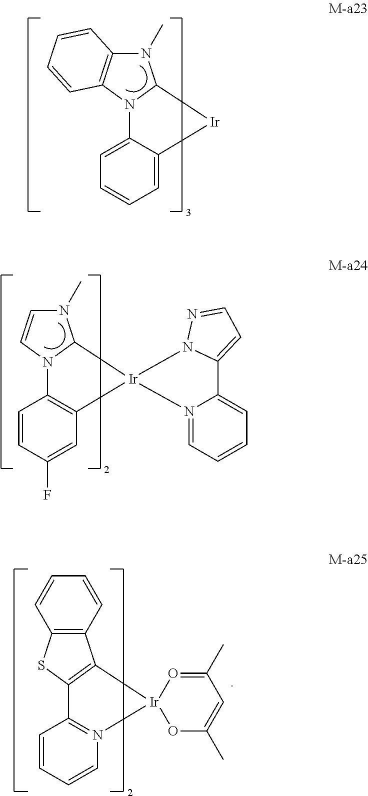

In an embodiment, the emission layer EML may further include a compound represented by one of Formula F-a to Formula F-c. The compounds represented by one of Formula F-a to Formula F-c may be used as fluorescence dopant materials.

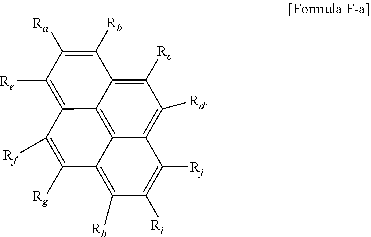

In Formula F-a, two of Rₐ to Rⱼ may each independently be substituted with a group represented by *—NAr₁Ar₂. The remainder of Rₐ to Rⱼ that are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In the group represented by *—NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ and Ar₂ may each independently be a heteroaryl group including O or S as a ring-forming atom.

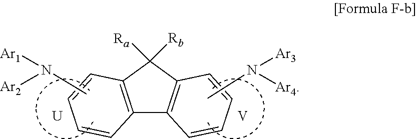

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring. In Formula F-b, Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. If the number of U or V is 1, a fused ring may be present at a portion respectively designated by U or V, and if the number of U or V is 0, a fused ring may not be present at the portion respectively designated by U or V. If the number of U is 0 and the number of V is 1, or if the number of U is 1 and the number of V is 0, a fused ring having the fluorene core of Formula F-b may be a cyclic compound having four rings. If the number of U and V is each 0, a fused ring having the fluorene core of Formula F-b may be a cyclic compound having three rings. If the number of U and V is each 1, a fused ring having the fluorene core of Formula F-b may be a cyclic compound having five rings.

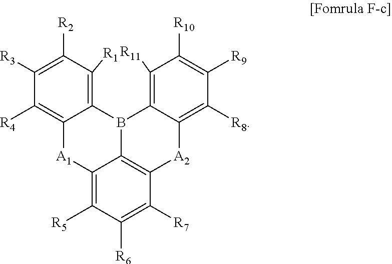

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring.

In Formula F-c, A₁ and A₂ may each independently be bonded to a substituent of an adjacent ring to form a fused ring. For example, if A₁ and A₂ are each independently N(Rₘ), A₁ may be bonded to R₄ or R₅ to form a ring, and/or A₂ may be bonded to R₇ or R₈ to form a ring.

In an embodiment, the emission layer EML may include, as a dopant material of the related art, a styryl derivative (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (for example, 2,5,8,11-tetra-t-butylperylene (TBP)), pyrene or a derivative thereof (for example, 1,1-dipyrene, 1,4-dipyrenylbenzene, and 1,4-bis(N,N-diphenylamino)pyrene), etc.

The emission layer EML may include a phosphorescence dopant material of the related art. For example, a metal complex that includes iridium (Ir), platinum (Pt), osmium (Os), gold (Au), titanium (Ti), zirconium (Zr), hafnium (Hf), europium (Eu), terbium (Tb) or thulium (Tm) may be used as a phosphorescence dopant material. For example. iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescence dopant. However, embodiments are not limited thereto.

In embodiments, the emission layer EML may include a quantum dot.

In the specification, a quantum dot may be a crystal of a semiconductor compound. A quantum dot may emit light in various emission wavelengths, according to a size of the crystal. A quantum dot may emit light in various emission wavelengths by adjusting an elemental ratio of a quantum dot compound.

A diameter of the quantum dot may be, for example, in a range of about 1 nm to about 10 nm.

The quantum dot may be synthesized by a chemical bath deposition process, a metal organic chemical vapor deposition process, a molecular beam epitaxy process, or a similar process thereto.

Chemical bath deposition is a method that includes mixing an organic solvent and a precursor material and growing a quantum dot particle crystal. While growing the crystal, the organic solvent may additionally serve as a dispersant that is coordinated onto a surface of the quantum dot crystal and may control the growth of the crystal. Accordingly, chemical bath deposition may be more advantageous when compared to a vapor deposition method such as metal organic chemical vapor deposition (MOCVD) and molecular beam epitaxy (MBE), and may control the growth of a quantum dot particle through a low-cost process.

The quantum dot may include a Group II-VI compound, a Group III-VI compound, a Group I-III-VI compound, a Group III-V compound, a Group III-II-V compound, a Group IV-VI compound, a Group IV element, a Group IV compound, or any combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof. In an embodiment, a Group II-VI compound may further include a Group I metal and/or a Group IV element. Examples of a Group I-II-VI compound may include CuSnS and CuZnS, and examples of a Group II-IV-VI compound may include ZnSnS and the like. Examples of a Group I-II-IV-VI compound may include a quaternary compound such as Cu₂ZnSnS₂, Cu₂ZnSnS₄, Cu₂ZnSnSe₄, Ag₂ZnSnS₂, and a mixture thereof.

Examples of a Group III-VI compound may include: a binary compound such as In₂S₃ and In₂Se₃; a ternary compound such as InGaS₃ and InGaSe₃; and any combination thereof.

Examples of a Group I-III-VI compound may include: a ternary compound such as AgInS, AgInS₂, CuInS, CuInS₂, AgGaS₂, CuGaS₂, CuGaO₂, AgGaO₂, AgAlO₂, and mixtures thereof; a quaternary compound such as AgInGaS₂ and CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and mixtures thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof; and any combination thereof. In an embodiment, a Group III-V compound may further include a Group II metal. Examples of a Group III-II-V compound may include InZnP, etc.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof.

Examples of a Group II-IV-V compound may include a ternary compound such as ZnSnP, ZnSnP₂, ZnSnAs₂, ZnGeP₂, ZnGeAs₂, CdSnP₂, and CdGeP₂, and a mixture thereof.

Examples of a Group IV element may include Si, Ge, and a mixture thereof. Examples of a Group IV compound may include a binary compound such as SiC, SiGe, and a mixture thereof.

Each element included in a compound, such as a binary compound, a ternary compound, or a quaternary compound, may be present in a particle at a uniform concentration distribution or at a non-uniform concentration distribution. For example, a formula may indicate the elements that are included in a compound, but an elemental ratio of the compound may vary. For example, AgInGaS₂ may indicate AgInₓGa₁₋ₓS₂ (wherein x is a real number between 0 and 1).

In an embodiment, a quantum dot may have a core/shell structure in which a quantum dot surrounds another quantum dot. An interface between the core and the shell may have a concentration gradient in which the concentration of an element that is present in the shell decreases toward the center.

In embodiments, a quantum dot may have the above-described core-shell structure that includes a nanocrystal core and a shell that surrounds the core. The shell of a quantum dot may serve as a protection layer that prevents chemical deformation of the core to maintain semiconductor properties and/or may serve as a charging layer that imparts the quantum dot with electrophoretic properties. The shell may be single-layered or multilayered. Examples of a shell of a quantum dot may include a metal oxide, a non-metal oxide, a semiconductor compound, and combinations thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; or a ternary compound such as MgAl₂O₄, CoFe₂O₄, NiFe₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width at half maximum (FWHM) of an emission wavelength spectrum equal to or less than about 45 nm. For example, the quantum dot may have an FWHM of an emission wavelength spectrum equal to or less than about 40 nm. For example, the quantum dot may have an FWHM of an emission wavelength spectrum equal to or less than about 30 nm. Within any of the above ranges, color purity or color reproducibility may be improved. Light emitted through a quantum dot may be emitted in all directions, so that viewing angle properties may be improved.

The shape of a quantum dot may be any shape used in the related art, without specific limitation. For example, a quantum dot may have a spherical shape, a pyramidal shape, a multi-arm shape, or a cubic shape, or a quantum dot may be in the form of a nanoparticle, a nanotube, a nanowire, a nanofiber, a nanoplate particle, etc.

As a size of a quantum dot or an elemental ratio of a quantum dot compound is adjusted, an energy band gap may be accordingly controlled to obtain light of various wavelengths from a quantum dot emission layer. Therefore, by utilizing quantum dots as described above (using quantum dots of different sizes or having different elemental ratios in a quantum dot compound), a light emitting element may emit light of various wavelengths. For example, a size of a quantum dot or an elemental ratio of a quantum dot compound may be adjusted to emit red light, green light, and/or blue light. In an embodiment, quantum dots may be configured to emit white light by combining light of various colors.

In the light emitting element ED according to embodiments, as shown in each of FIG. 3 to FIG. 6, the electron transport region ETR may be provided on the emission layer EML. The electron transport region ETR may include at least one of a hole blocking layer HBL, an electron transport layer ETL, and an electron injection layer EIL. However, embodiments are not limited thereto.

The electron transport region ETR may have a structure consisting of a layer consisting of a single material, a structure consisting of a layer including different materials, or a structure including multiple layers including different materials.

For example, the electron transport region ETR may have a single-layered structure of an electron injection layer EIL or an electron transport layer ETL, or may have a single-layered structure that includes an electron injection material and an electron transport material. In embodiments, the electron transport region ETR may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. A thickness of the electron transport region ETR may be, for example, in a range of about 500 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the electron transport region ETR may include a compound represented by Formula ET-2:

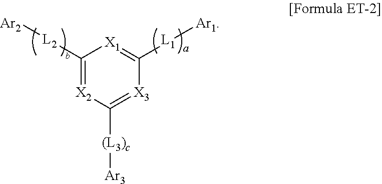

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-2, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each 2 or more, multiple groups of each of L₁ to L₃ may each independently be a substituted or unsubstituted arylene group of 6 to 30 ring-forming carbon atoms or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-5-(4-tert-butylphenyl)-4-phenyl-1,2,4-triazole (TAZ), 4-(naphthalen-1-yl)-3,5-diphenyl-4H-1,2,4-triazole (NTAZ), 2-(4-biphenyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), CNNPTRZ (4′-(4-(4-(4,6-diphenyl-1,3,5-triazin-2-yl)phenyl)naphthalen-1-yl)-[1,1′-biphenyl]-4-carbonitrile), or a mixture thereof, without limitation.

In an embodiment, the electron transport region ETR may include a compound selected from Compound Group 3.

In an embodiment, the electron transport region ETR may include at least one of Compounds ET1 to ET36:

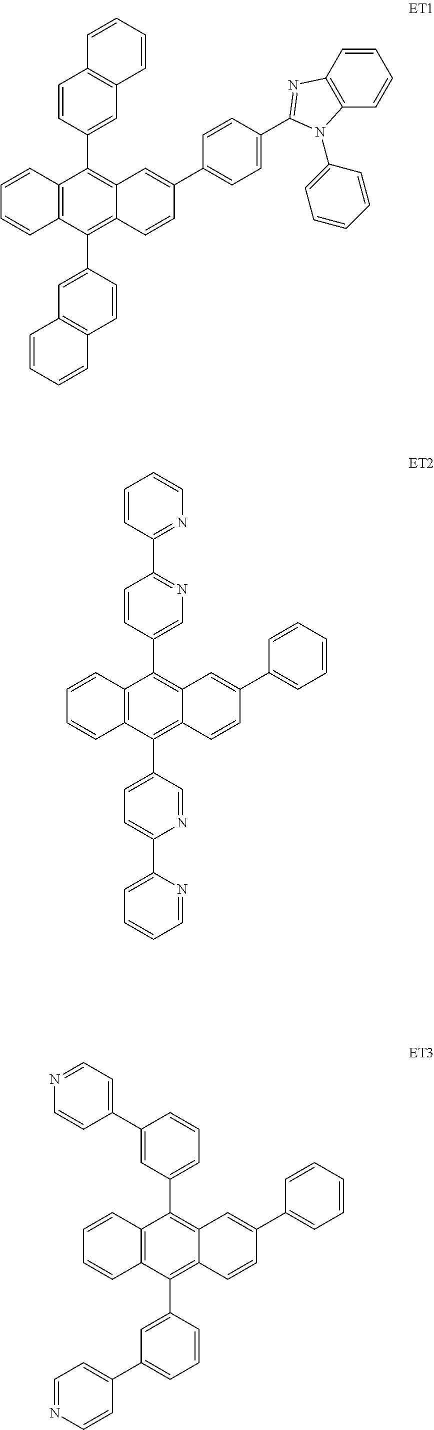 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

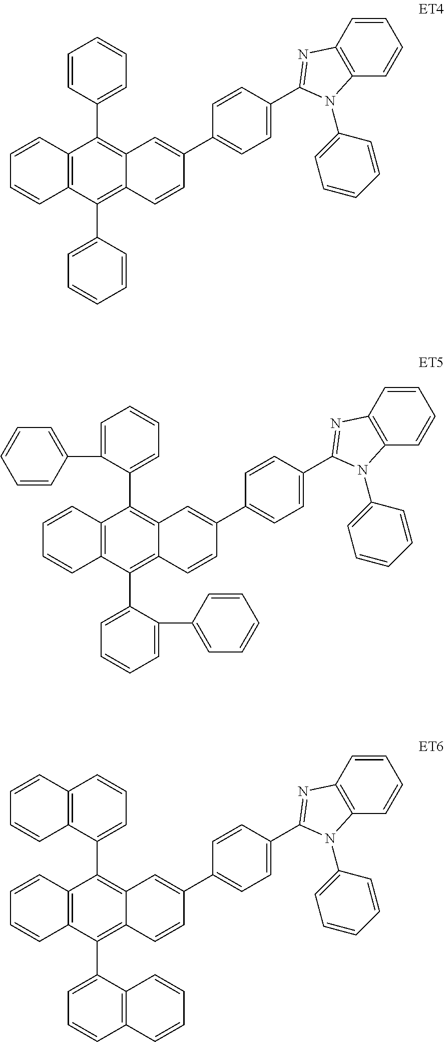 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

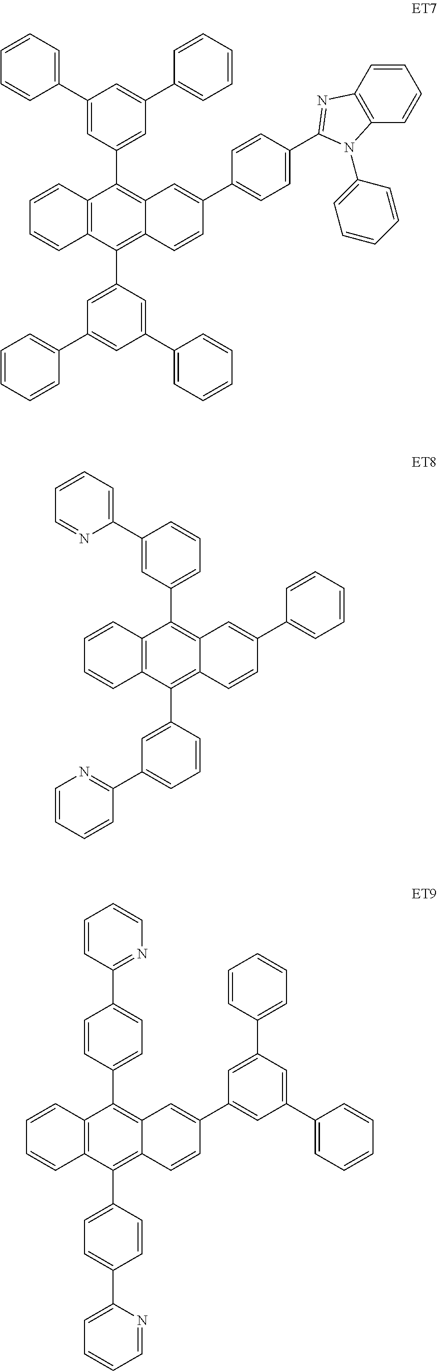 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2ccc3c(-c4cccc(-c5ccccn5)c4)c4ccccc4c(-c4cccc(-c5ccccn5)c4)c3c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

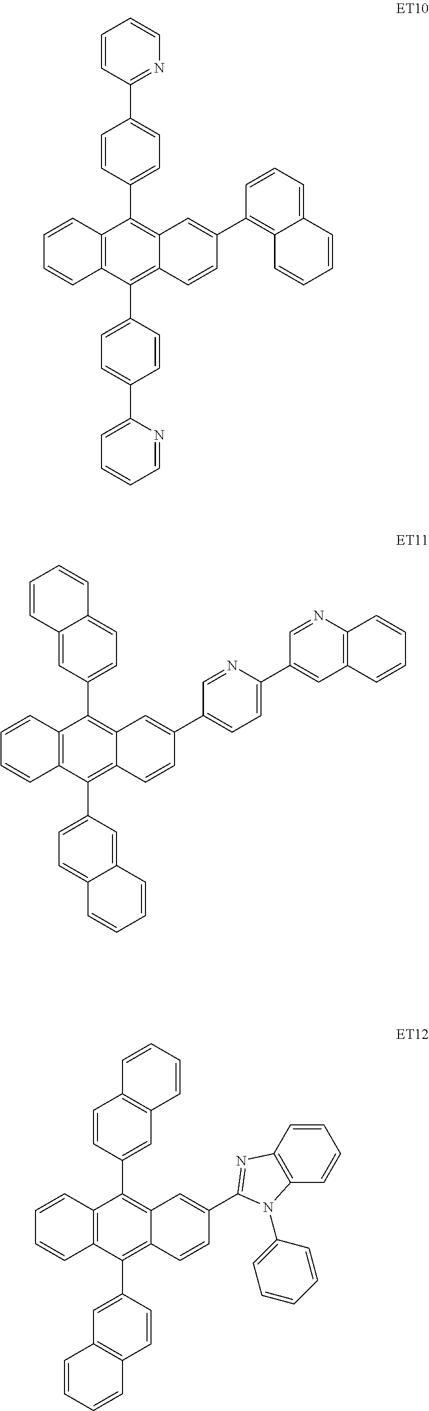 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

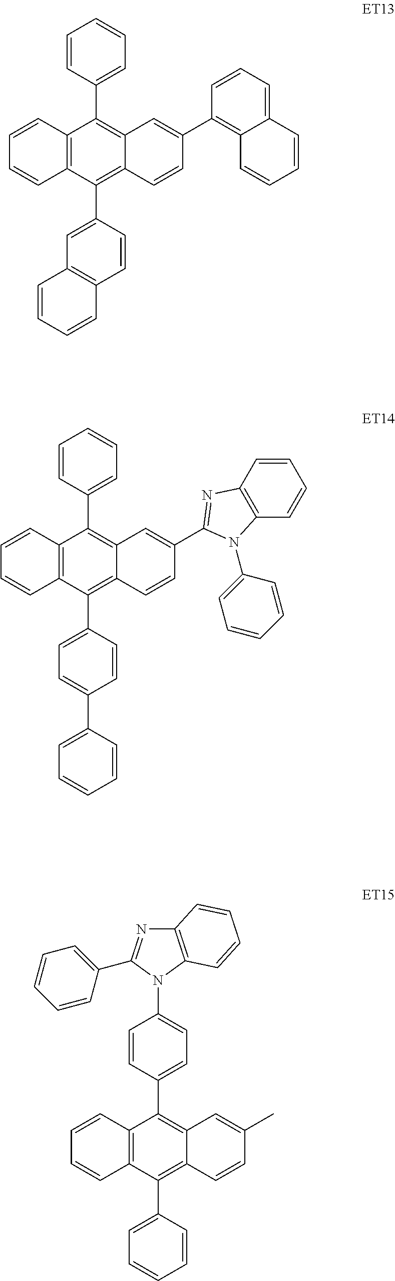

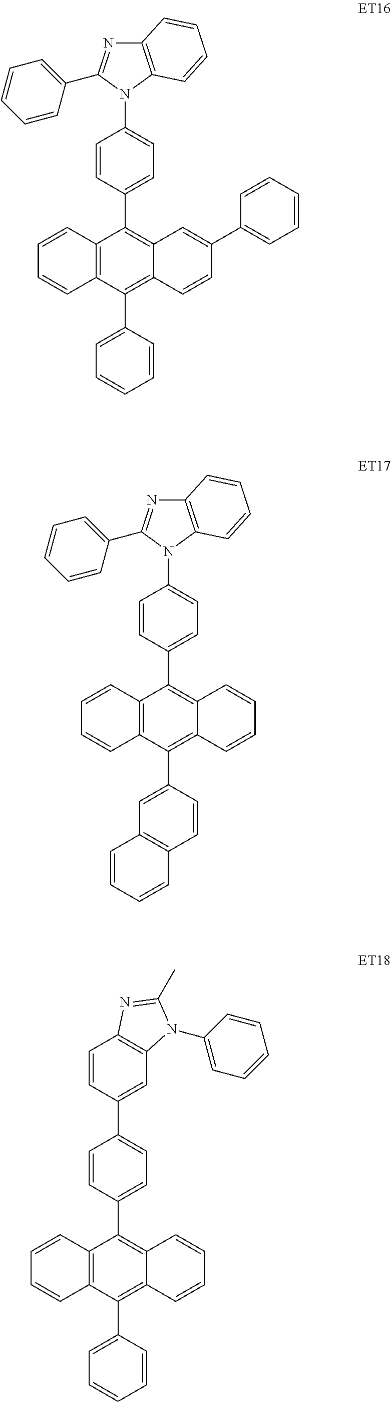 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

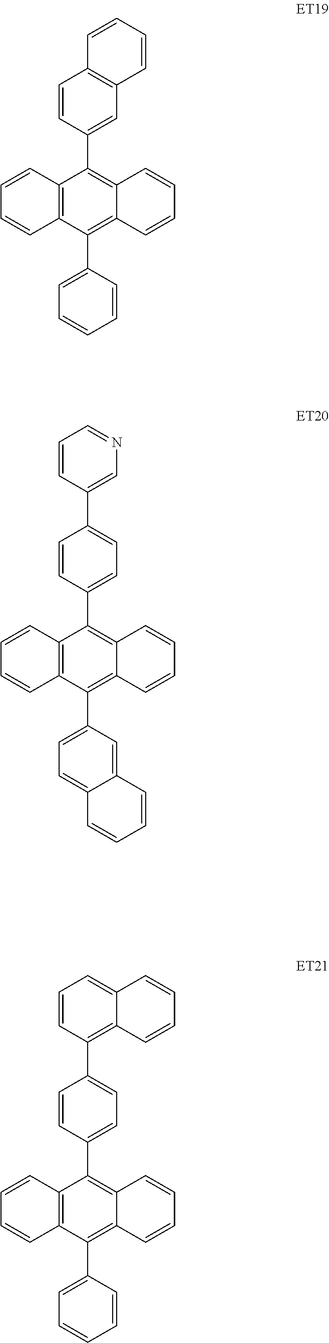

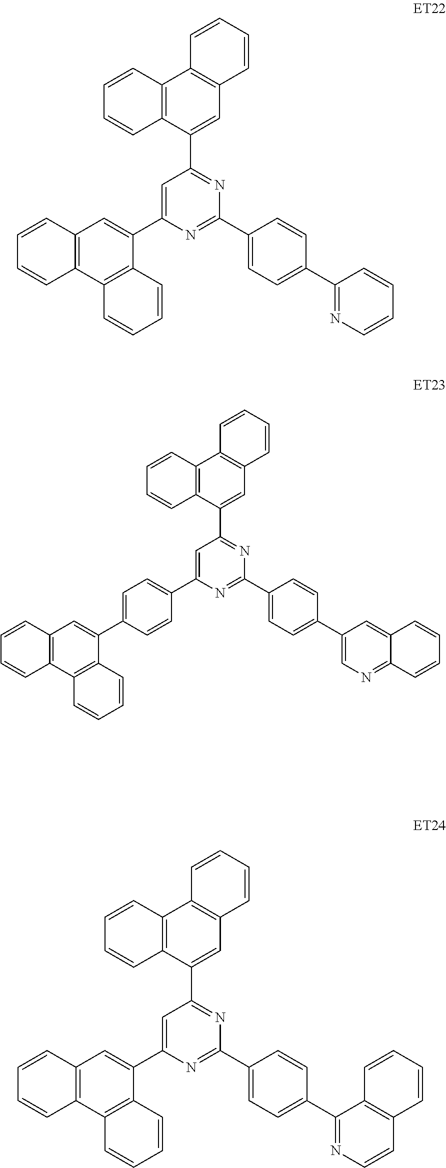 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

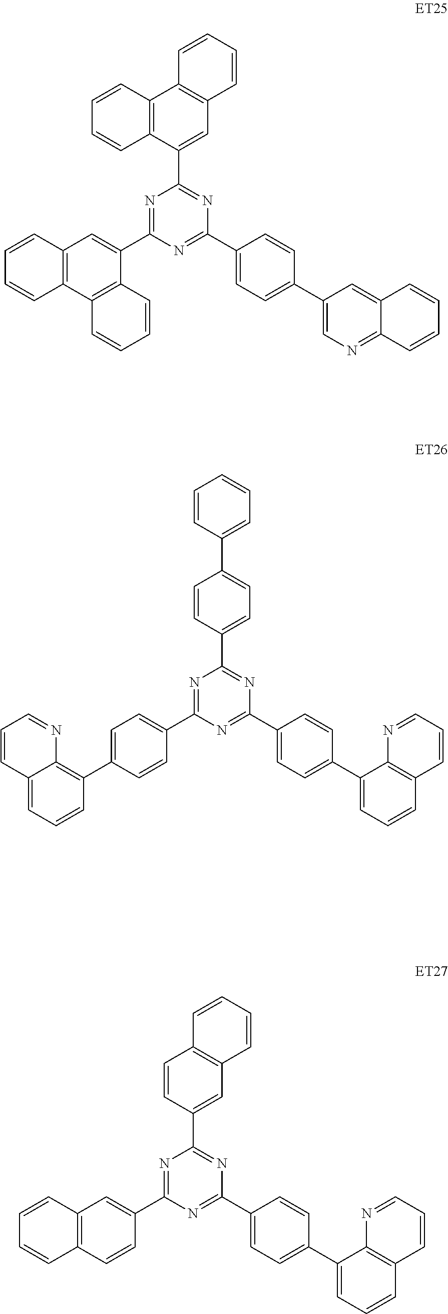 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

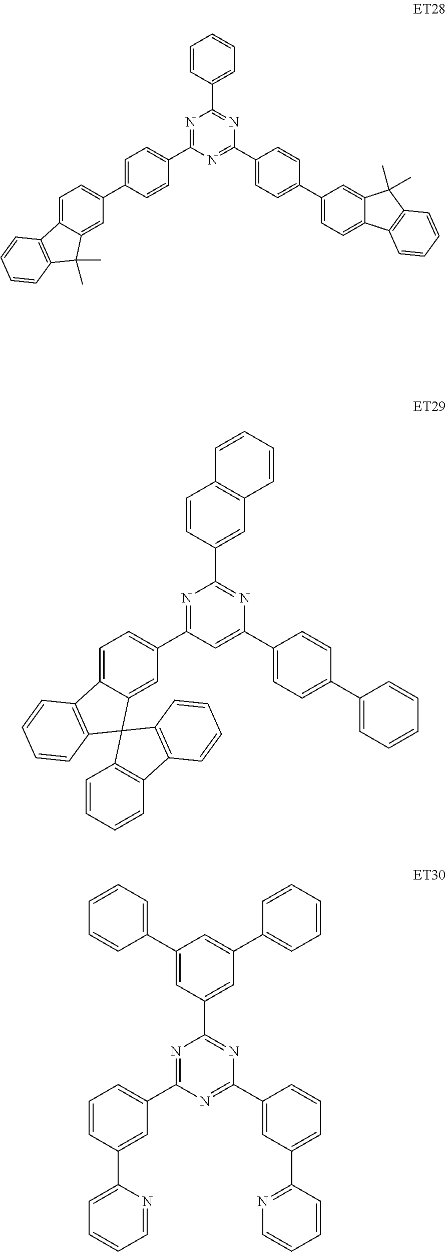 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

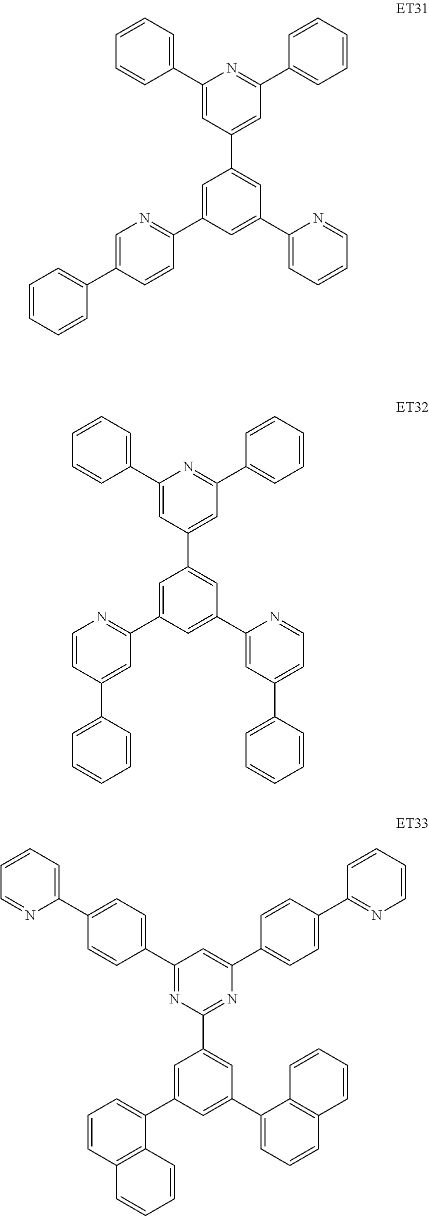 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

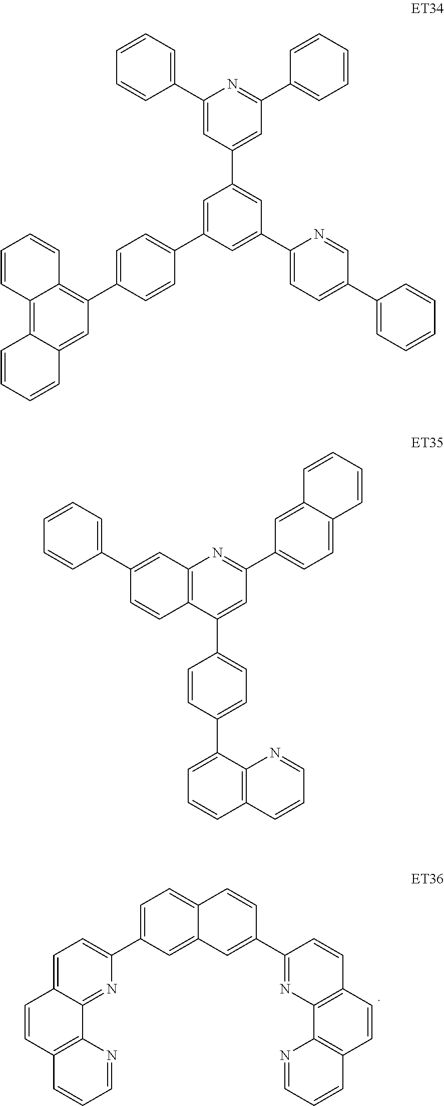 [SMILES: c1ccc(-c2ccc(-c3cc(-c4ccc(-c5cc6ccccc6c6ccccc56)cc4)cc(-c4cc(-c5ccccc5)nc(-c5ccccc5)c4)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide such as Yb; or a co-deposited material of a metal halide and a lanthanide. For example, the electron transport region ETR may include KI:Yb, RbI:Yb, LiF:Yb, etc., as a co-deposited material. The electron transport region ETR may include a metal oxide such as Li₂O and BaO, or 8-hydroxy-lithium quinolate (Liq). However, embodiments are not limited thereto. In another embodiment, the electron transport region ETR may include a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the aforementioned materials. However, embodiments are not limited thereto.

The electron transport region ETR may include the compounds of the electron transport region in at least one of an electron injection layer EIL, an electron transport layer ETL, and a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies any of the above-described ranges, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies any of the above described ranges, satisfactory electron injection properties may be obtained without inducing a substantial increase of driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode, or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayered structure that includes a reflective layer or a transflective layer formed of the above-described materials and a transparent conductive layer formed of ITO, IZO, ZnO, ITZO, etc. For example, the second electrode EL2 may include the aforementioned metal materials, combinations of two or more of the aforementioned metal materials, or oxides of the aforementioned metal materials.

Although not shown in the drawings, in an embodiment, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may have a multilayered structure or a single-layered structure.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, or an acrylate such as methacrylate. In an embodiment, a capping layer CPL may include at least one of Compounds P1 to P5, but embodiments are not limited thereto.

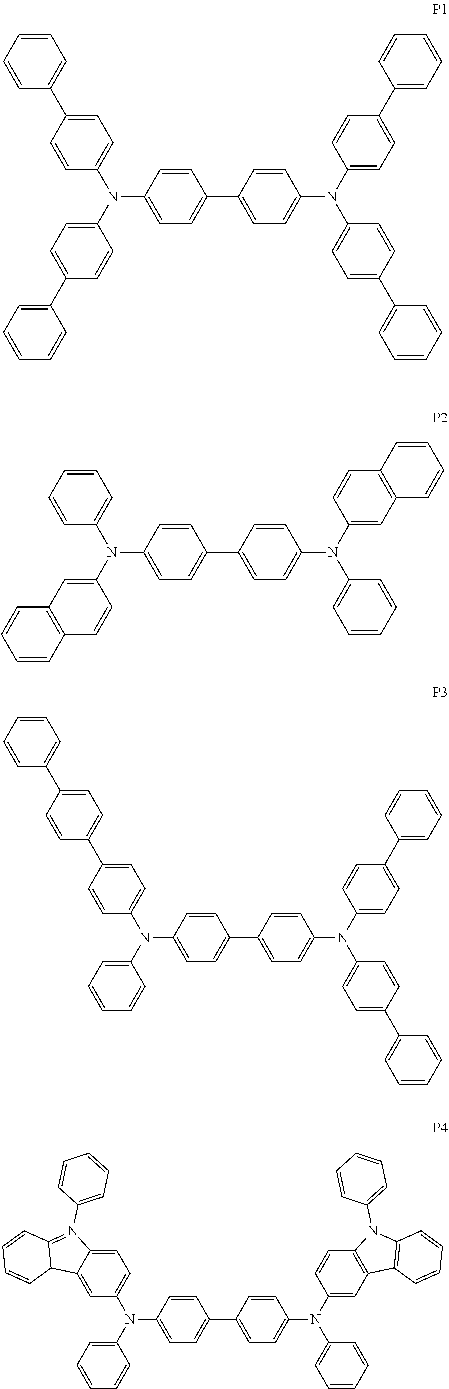

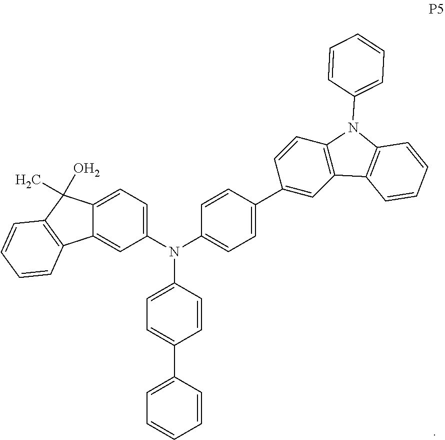 [SMILES: CC1(O)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

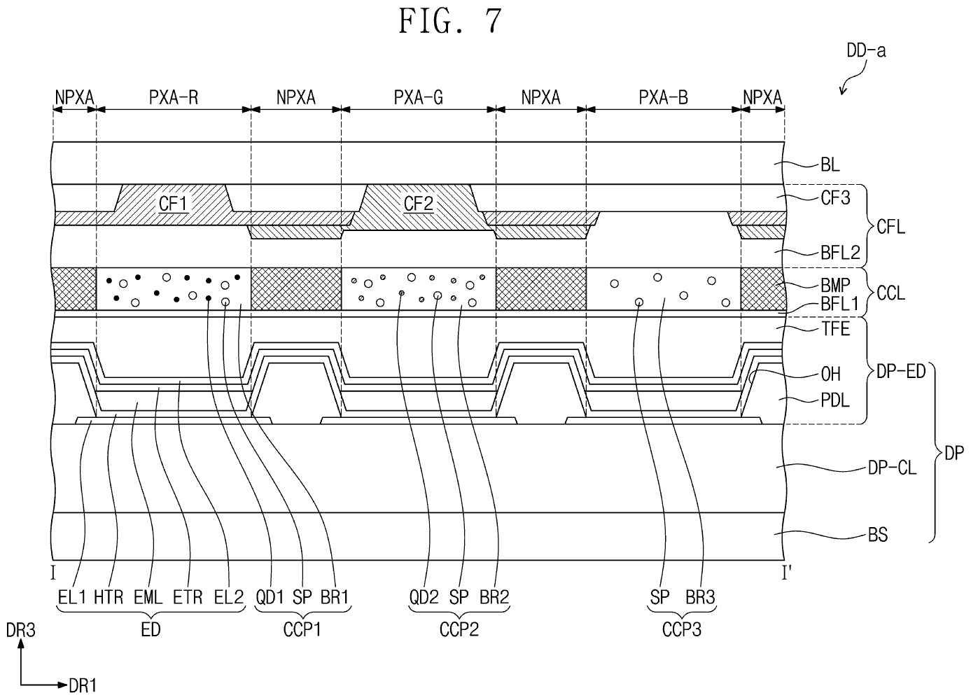

FIG. 7 to FIG. 10 are each a schematic cross-sectional view of a display device according to embodiments. In the explanation on the display devices according to embodiments as shown in FIG. 7 to FIG. 10, the features that have been described above with respect to FIG. 1 to FIG. 6 will not be explained again, and the differing features will be explained.

Referring to FIG. 7, a display device DD-a according to an embodiment may include a display panel DP that includes a display device layer DP-ED, a light controlling layer CCL disposed on the display panel DP, and a color filter layer CFL. In an embodiment shown in FIG. 7, the display panel DP includes a base layer BS, a circuit layer DP-CL provided on the base layer BS, and a display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light-emitting element ED shown in FIG. 7 may be the same as a structure of a light-emitting element according to one of FIG. 3 to FIG. 6 as described above.

An emission layer EML of the light-emitting element ED included in the light-emitting element DD-a according to an embodiment may include the fused polycyclic compound according to an embodiment as described above.

Referring to FIG. 7, the emission layer EML may be disposed in an opening OH defined in a pixel defining film PDL. For example, the emission layer EML, which is separated by the pixel defining film PDL and provided to correspond to each of the light emitting regions PXA-R, PXA-G, and PXA-B, may emit light in a same wavelength region. In the display device DD-a, the emission layer EML may emit blue light. Although not shown in the drawings, in an embodiment, the emission layer EML may be provided as a common layer throughout all of the light emitting regions PXA-R, PXA-G, and PXA-B.

The light controlling layer CCL may be disposed on the display panel DP. The light controlling layer CCL may include a light converter. The light converter may be a quantum dot or a phosphor. The light converter may convert the wavelength of a provided light and emit the resulting light. For example, the light controlling layer CCL may be a layer that includes a quantum dot or a layer that includes a phosphor.

The light controlling layer CCL may include light controlling parts CCP1, CCP2, and CCP3. The light controlling parts CCP1, CCP2, and CCP3 may be spaced apart from each other.

Referring to FIG. 7, a partition pattern BMP may be disposed between the separated light controlling parts CCP1, CCP2, and CCP3, but embodiments are not limited thereto. In FIG. 7, it is shown that the partition pattern BMP does not overlap the light controlling parts CCP1, CCP2, and CCP3, but the edges of the light controlling parts CCP1, CCP2, and CCP3 may overlap at least a portion of the partition pattern BMP.

The light controlling layer CCL may include a first light controlling part CCP1 including a first quantum dot QD1 that converts first color light provided from the light emitting element ED into second color light, a second light controlling part CCP2 including a second quantum dot QD2 that converts first color light into third color light, and a third light controlling part CCP3 that transmits first color light. In an embodiment, the first light controlling part CCP1 may provide red light, which is the second color light, and the second light controlling part CCP2 may provide green light, which is the third color light. The third color controlling part CCP3 may provide blue light by transmitting the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of two or more materials selected from TiO₂, ZnO, Al₂O₃, SiO₂, and hollow silica.

The first light controlling part CCP1, the second light controlling part CCP2, and the third light controlling part CCP3 may respectively include base resins BR1, BR2, and BR3, in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3.

The base resins BR1, BR2, and BR3 are mediums in which the quantum dots QD1 and QD2 and the scatterer SP are dispersed, and may include various resin compositions which may be referred to as a binder. For example, the base resins BR1, BR2, and BR3 may be acrylic resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light controlling layer CCL may include a barrier layer BFL1. The barrier layer BFL1 may block the penetration of moisture and/or oxygen (hereinafter, will be referred to as “humidity/oxygen”). The barrier layer BFL1 may block the light controlling parts CCP1, CCP2, and CCP3 from exposure to humidity/oxygen. The barrier layer BFL1 may cover the light controlling parts CCP1, CCP2, and CCP3. In an embodiment, a color filter layer CFL, which will be explained later, may include a barrier layer BFL2 disposed on the light controlling parts CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film that secures light transmittance. The barrier layers BFL1 and BFL2 may each independently further include an organic layer. The barrier layers BFL1 and BFL2 may have a single-layered structure or a multilayered structure.

In the display device DD-a, the color filter layer CFL may be disposed on the light controlling layer CCL. In an embodiment, the color filter layer CFL may be disposed directly on the light controlling layer CCL. For example, the barrier layer BFL2 may be omitted.

The color filter layer CFL may include filters CF1, CF2, and CF3. The first to third filters CF1, CF2, and CF3 may be disposed so that they respectively correspond to a red light emitting region PXA-R, a green light emitting region PXA-G, and a blue light emitting region PXA-B.

The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. In an embodiment, the first filter CF1 and the second filter CF2 may not be provided as separate filters and may be provided as a unitary filter.

Although not shown in the drawings, in an embodiment, the color filter layer CFL may further include a light blocking part (not shown). The light blocking part (not shown) may be a black matrix. The light blocking part (not shown) may include an organic light blocking material or an inorganic light blocking material, each including a black pigment or a black dye. The light blocking part (not shown) may prevent light leakage, and may separate the boundaries between adjacent filters CF1, CF2, and CF3.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

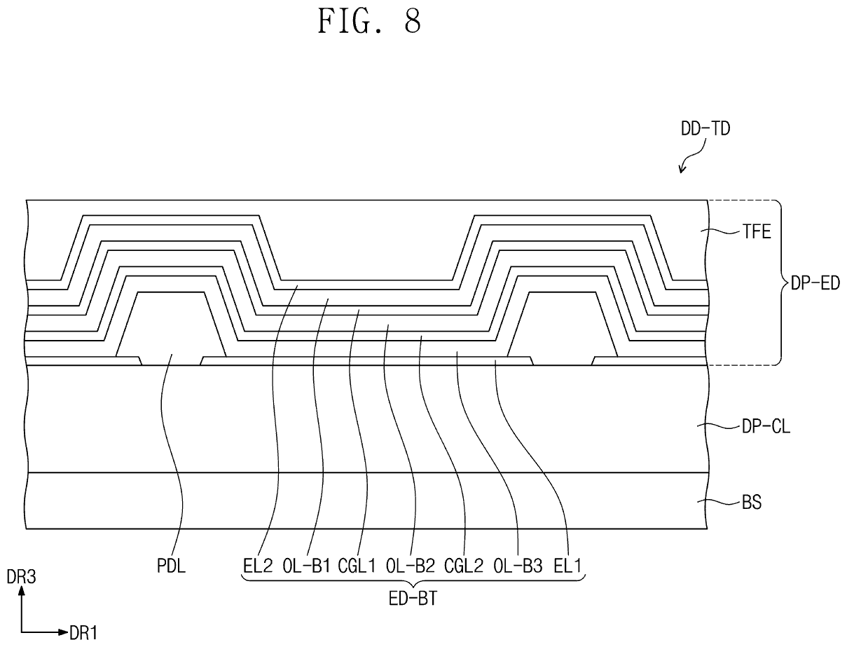

FIG. 8 is a schematic cross-sectional view of a portion of a display device according to an embodiment. In a display device DD-TD according to an embodiment, a light emitting element ED-BT may include light emitting structures OL-B1, OL-B2, and OL-B3. The light emitting element ED-BT may include a first electrode EL1 and a second electrode EL2 that face each other, and light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR, an emission layer EML (FIG. 7), and an electron transport region ETR, which may be disposed in that order between the first electrode EL1 and the second electrode EL2.

For example, the light emitting element ED-BT included in the display device DD-TD may be a light emitting element having a tandem structure that includes multiple emission layers.

In an embodiment shown in FIG. 8, light emitted from the light emitting structures OL-B1, OL-B2, and OL-B3 may each be blue light. However, embodiments are not limited thereto, and the light emitted from the light emitting structures OL-B1, OL-B2, and OL-B3 may have wavelength ranges that are different from each other. For example, the light emitting element ED-BT that includes the light emitting structures OL-B1, OL-B2, and OL-B3, which emit light in different wavelength regions, may emit white light.

Charge generating layers CGL1 and CGL2 may each be disposed between two adjacent light emitting structures among the light emitting structures OL-B1, OL-B2, and OL-B3. The charge generating layers CGL1 and CGL2 may each independently include a p-type charge generating layer and/or an n-type charge generating layer.

The fused polycyclic compound according to an embodiment as described above may be included in at least one of the light emitting structures OL-B1, OL-B2, and OL-B3 in the display device DD-TD. For example, at least one of the emission layers included in the light-emitting element ED-BT may include the fused polycyclic compound according to an embodiment.

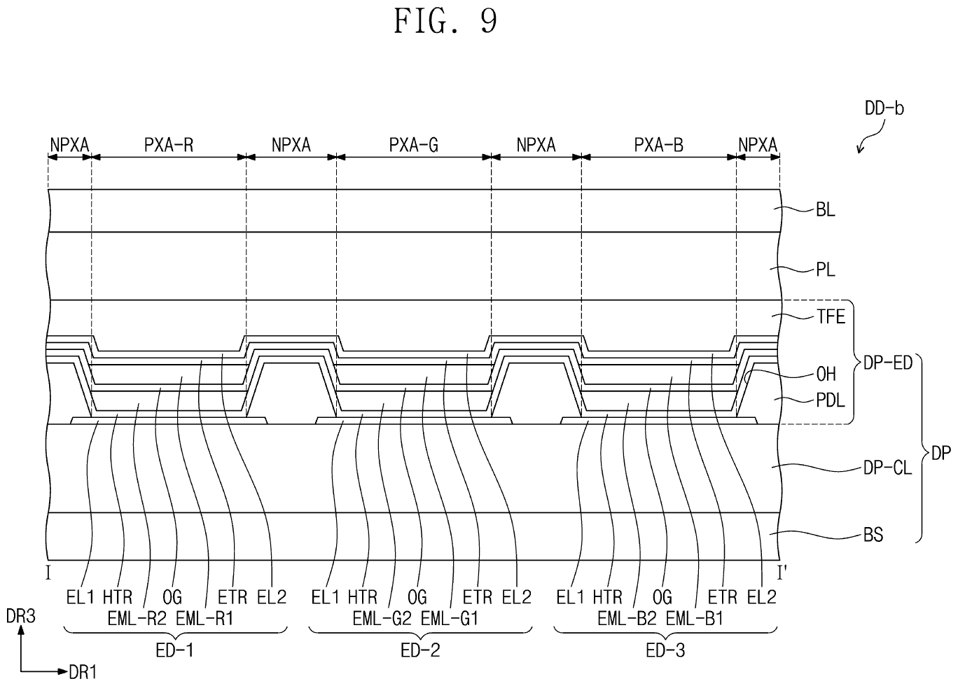

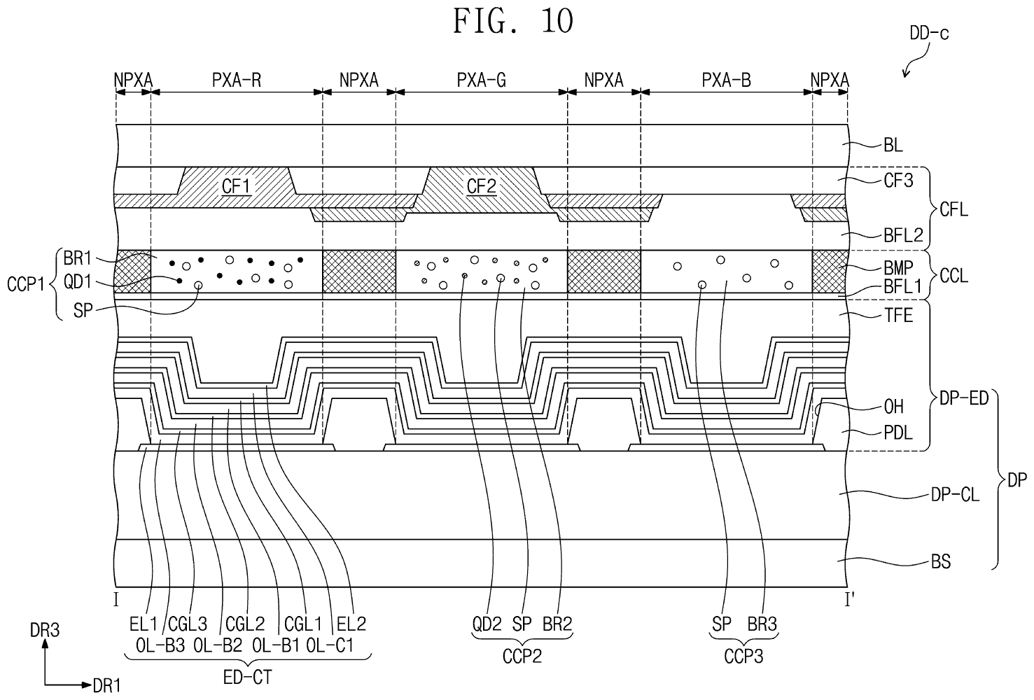

FIG. 9 is a schematic cross-sectional view of a display device DD-b according to an embodiment. FIG. 10 is a schematic cross-sectional view of a display device DD-c according to an embodiment.

Referring to FIG. 9, a display device DD-b according to an embodiment may include light emitting elements ED-1, ED-2, and ED-3, in which two emission layers are stacked. In comparison to the display device DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer throughout the first to third light emitting elements ED-1, ED-2, and ED-3. However, embodiments are not limited thereto, and the emission auxiliary part OG may be provided by being patterned within the openings OH defined in a pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

The first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on a display device layer DP-ED. The optical auxiliary layer PL may include a polarization layer. The optical auxiliary layer PL may be disposed on a display panel DP and may control light that is reflected at the display panel DP from an external light. Although not shown in the drawings, in an embodiment, the optical auxiliary layer PL may be omitted from the display device DD-b.

At least one emission layer included in a display device DD-b shown in FIG. 9 may include the fused polycyclic compound according to an embodiment. For example, in an embodiment, at least one of the first blue emission layer EML-EML and the second blue emission layer EML-B2 may include the fused polycyclic compound according to an embodiment.

In contrast to FIG. 8 and FIG. 9, FIG. 10 shows a display device DD-c that is different at least in that it includes four light emitting structures OL-B1, OL-B2, OL-B3, and OL-C1. A light emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2. In an embodiment, the third light emitting structure OL-B3, the second light emitting structure OL-B2, the first light emitting structure OL-B1, and the fourth light emitting structure OL-C1 may be stacked in the stated order in a thickness direction between the first electrode EL1 and the second electrode EL2.

Charge generating layers CGL1, CGL2, and CGL3 may each be disposed between two adjacent light emitting structures among the first to fourth light emitting structures OL-B1, OL-B2, OL-B3, and OL-C1. For example, a first charge generating layer CGL1 may be disposed between the first light emitting structure OL-B1 and the fourth light emitting structure OL-C1, a second charge generating layer CGL2 may be disposed between the first light emitting structure OL-B1 and the second light emitting structure OL-B2, and a third charge generating layer CGL3 may be disposed between the second light emitting structure OL-B2 and the third light emitting structure OL-B3.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength regions that are different from each other.

The fused polycyclic compound according to an embodiment may be included in at least one of the light emitting structures OL-B1, OL-B2, OL-B3, and OL-C1 included in the display device DD-c. In an embodiment, at least one of the first to third light emitting structures OL-B1, OL-B2, and OL-B3 may each independently include the fused polycyclic compound according to an embodiment.

The light-emitting element ED according to an embodiment may include the fused polycyclic compound represented by Formula 1 in at least one functional layer disposed between the first electrode EL1 and the second electrode EL2, thereby exhibiting excellent luminous efficiency and improved lifespan. For example, the fused polycyclic compound according to an embodiment may be included in an emission layer EML of the light-emitting element ED, and thus the light-emitting element ED may exhibit long lifespan characteristics.

In an embodiment, an electronic apparatus may include a display device that includes multiple light emitting elements, and a control part that controls the display device. The electronic apparatus may be an apparatus activated that is according to electrical signals. The electronic apparatus may include display devices according to various embodiments. Examples of an electronic apparatus may include large, medium-sized, and small devices, such as a television, a monitor, a billboard, a personal computer, a laptop computer, a personal digital terminal, a display device for a vehicle, a game console, a portable electronic device, and a camera.

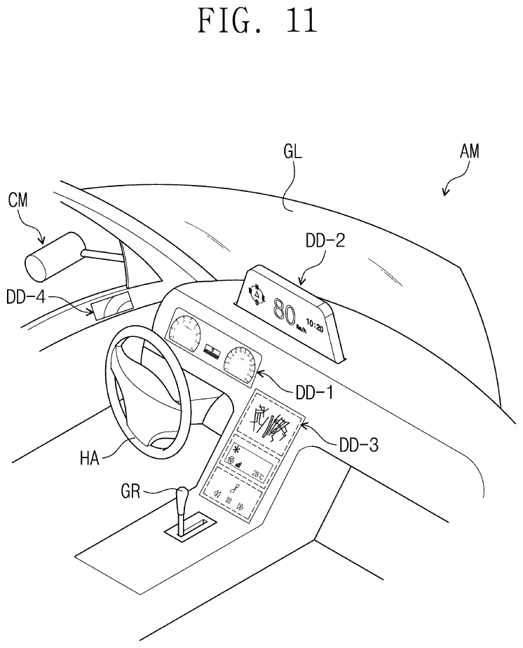

FIG. 11 is a schematic diagram of a vehicle AM in which first to fourth display devices DD-1, DD-2, DD-3, and DD-4 are disposed. At least one of the first to fourth display devices DD-1, DD-2, DD-3, and DD-4 may have a structure according to one of display devices DD, DD-TD, DD-a, DD-b, and DD-c, as described above with reference to FIGS. 1, 2, and 7 to 10.

In FIG. 11, an automobile is shown as a vehicle AM, but this is only an example, and the first to fourth display devices DD-1, DD-2, DD-3, and DD-4 may be disposed in various transportation means such as a bicycle, a motorcycle, a train, a ships, and an airplane. In an embodiment, at least one of the first to fourth display devices DD-1, DD-2, DD-3, and DD-4 having a structure according to one of display devices DD, DD-TD, DD-a, DD-b, and DD-c may be included in a personal computer, a laptop computer, a personal digital terminal, a game console, a portable electronic device, a television, a monitor, a billboard, or the like. However, these are merely provided as examples, and the display device may be included in other electronic devices.

At least one of first to fourth display devices DD-1, DD-2, DD-3, and DD-4 may each independently include a light-emitting element ED according to an embodiment as described with reference to any of FIG. 3 to FIG. 6. The light-emitting element ED may include the fused polycyclic compound according to an embodiment. At least one of the first to fourth display devices DD-1, DD-2, DD-3, and DD-4 may include a light-emitting element ED that includes the fused polycyclic compound according to an embodiment, and thus may have improved display lifespan.

Referring to FIG. 11, the vehicle AM may include a steering wheel HA for operating the vehicle AM and a gearshift GR. The vehicle AM may include a front window GL that is disposed so as to face a driver.

A first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), and images that represent a fuel gauge. The first scale and the second scale may each be represented by digital images.

A second display device DD-2 may be disposed in a second region facing a driver's seat that overlaps the front window GL. The driver's seat may be a seat where the steering wheel HA is disposed. For example, the second display device DD-2 may be a head up display (HUD) that shows second information of the vehicle AM. The second display device DD-2 may be optically transparent. The second information may include digital numbers that indicate a driving speed of the vehicle AM, and may further include information such as the current time. Although not shown in the drawings, in an embodiment, the second information of the second display device DD-2 may be displayed by being projected onto the front window GL.

A third display device DD-3 may be disposed in a third region that is adjacent to the gearshift GR. For example, the third display device DD-3 may be a center information display (CID) for a vehicle that is disposed between a driver's seat and a passenger seat and which displays third information. The passenger seat may be a seat that is spaced apart from the driver's seat, and the gearshift GR may be disposed between the driver's seat and the passenger seat. The third information may include information about traffic conditions (for example, navigation information), about music or radio that is playing, about a video (or image) that is displayed, about temperatures in the vehicle AM, or the like.

A fourth display device DD-4 may be disposed in a fourth region that is spaced apart from the steering wheel HA and the gearshift GR and adjacent to a side of the vehicle AM. For example, the fourth display device DD-4 may be a digital side-view mirror that displays fourth information. The fourth display device DD-4 may display an image that is external to the vehicle AM, which may be taken by a camera module CM that is disposed on the exterior of the vehicle AM. The fourth information may include an exterior image of the vehicle AM.

The first to fourth information as described above are only provided as examples, and the first to fourth display devices DD-1, DD-2, DD-3, and DD-4 may further display information on the interior and exterior of the vehicle AM. The first to fourth information may include information that is different from each other. However, embodiments are not limited thereto, and a portion of the first to fourth information may include a same information.

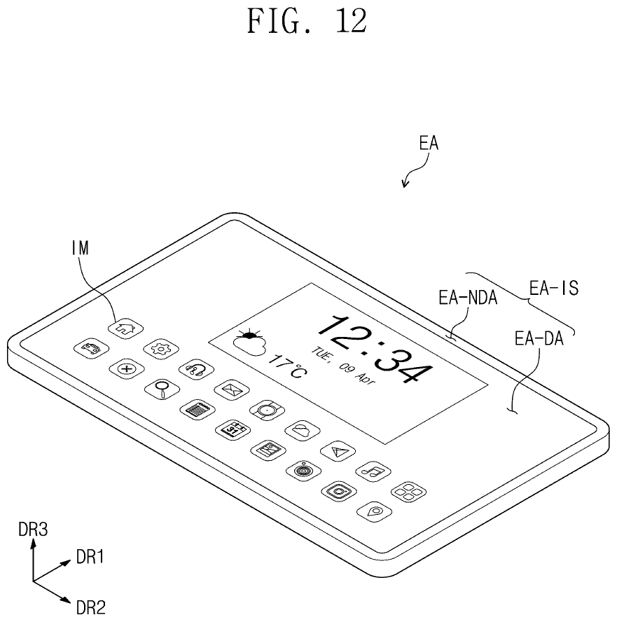

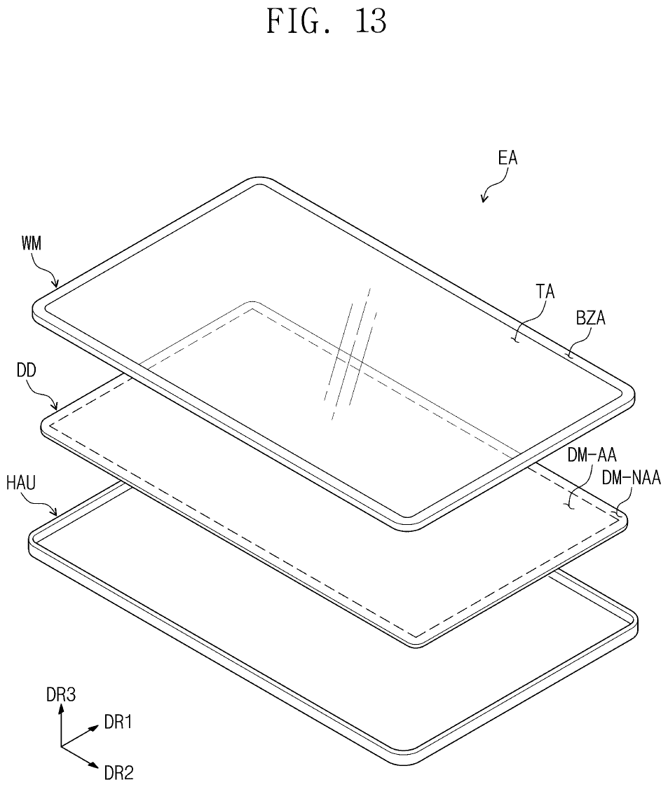

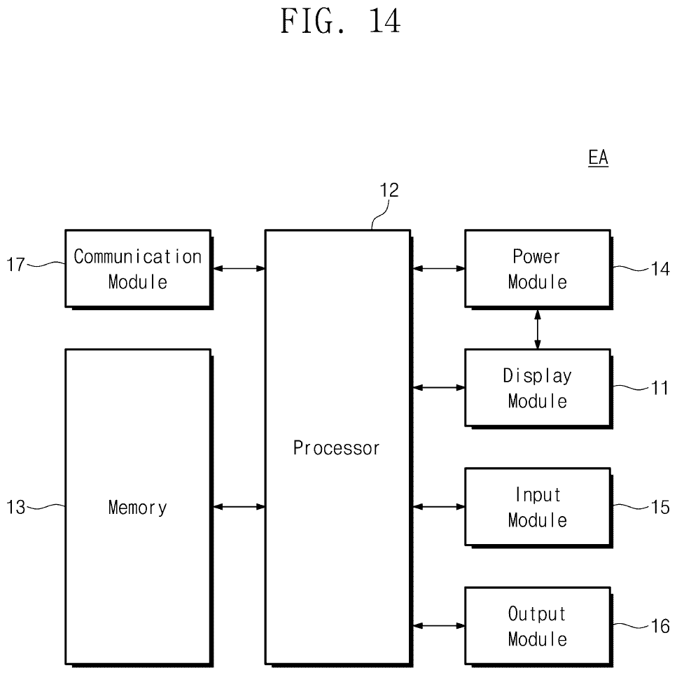

FIG. 12 is a schematic perspective view of an electronic apparatus according to an embodiment. FIG. 13 is an exploded schematic perspective view of an electronic apparatus according to an embodiment.

As shown in FIG. 12, an electronic apparatus EA may display an image IM through a display surface EA-IS. The image IM may be a dynamic image or a static image. The display surface EA-IS may be parallel to a plane defined by a first direction axis DR1 and a second direction axis DR2. FIG. 12 shows that the electronic apparatus EA has a flat display surface EA-IS, but embodiments are not limited thereto. For example, the electronic apparatus EA may have a curved display surface or a three-dimensional display surface. In an embodiment, a three-dimensional display surface may include multiple display areas that are disposed or positioned in different directions from each other.

The display surface EA-IS may include a display area EA-DA and a non-display area EA-NDA. The electronic apparatus EA may display an image IM through the display area EA-DA.

The non-display area EA-NDA may have a selected or given color. The non-display area EA-NDA may be adjacent to the display area EA-DA. In an embodiment, the non-display area EA-NDA may surround the display area EA-DA. Accordingly, the shape of the display area EA-DA may be substantially defined by the non-display area EA-NDA. However, FIG. 12 is only an illustration, and the non-display area EA-NDA may be disposed so that it is adjacent to only a side of the display area EA-DA or the non-display area EA-NDA may be omitted.

Referring to FIG. 13, the electronic apparatus EA may include a display device DD, a window member WM, and a housing HAU.

The window member WM may cover an outer surface of the electronic apparatus EA. For example, the window member WM may cover the entire outer surface of the electronic apparatus EA. The window member WM may include a transparent area TA and a bezel area BZA. The front surface of the window member WM that includes the transparent area TA and the bezel area BZA may correspond to a front surface of the electronic apparatus EA. The transparent area TA may correspond to the display area EA-DA of the electronic apparatus EA shown in FIG. 12, and the bezel area BZA may correspond to the non-display area EA-NDA of the electronic apparatus EA shown in FIG. 12.

The transparent area TA may be an optically transparent area. The bezel area BZA may be an area having a relatively low light transmittance, as compared to the transparent area TA. The bezel area BZA may have a selected or given color. The bezel area BZA may be adjacent to the transparent area TA and may surround the transparent area TA. The bezel area BZA may define the shape of the transparent area TA. However, embodiments are not limited thereto, and the bezel area BZA may be disposed so that it is adjacent to only a side of the transparent area TA, or a portion thereof may be omitted.

The housing HAU may include a material having relatively high rigidity. For example, the housing HAU may include a frame and/or a plate made of glass, plastic, or metal. The frames and/or plates may be provided as multiple pieces. The housing HAU may provide an enclosure for the display device DD. The display device DD may be contained in the enclosure and protected from external impact.

The display device DD may have a configuration according to one of display devices DD, DD-TD, DD-a, DD-b, and DD-c as described above with reference to FIGS. 1, 2, and 7 to 10. The display device DD may include at least one light emitting element ED according to an embodiment as described with reference to any of FIGS. 3 to 6. Accordingly, the electronic apparatus EA including the display device DD according to an embodiment may exhibit excellent reliability.

An active area DM-AA and a peripheral area DM-NAA may be defined in the display device DD. The active area DM-AA may overlap the display area EA-DA shown in FIG. 12, and the peripheral area DM-NAA may overlap the non-display area EA-NDA shown in FIG. 12.

The active area DM-AA may be an area that is activated according to an electrical signal. The peripheral area DM-NAA may be an area that is adjacent to at least one side of the active area DM-AA. The active area DM-AA may include the non-light emitting regions NPXA and the light emitting regions PXA-R, PXA-G, and PXA-B, as shown in FIG. 1. The peripheral area DM-NAA may surround the active area DM-AA. However, embodiments are not limited thereto. In another embodiment, at least a portion of the peripheral areas DM-NAA may be omitted. A driving circuit or driving wiring for driving the active area DM-AA may be disposed in the peripheral area DM-NAA.

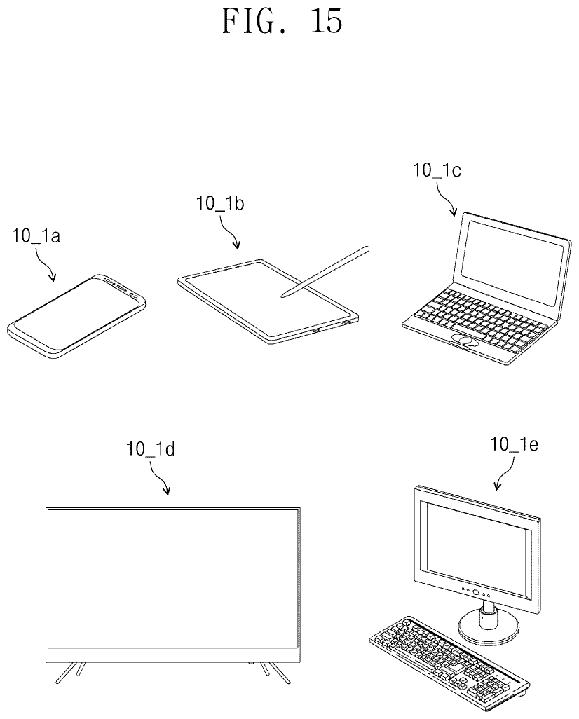

The electronic apparatus EA according to an embodiment includes the display device DD as described above, and may further include a module or device having an additional function. FIG. 14 is a block diagram of an electronic apparatus EA according to an embodiment. Referring to FIG. 14, an electronic apparatus EA according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. Data for the operation of the processor 12 or the display module 11 may be stored in the memory 13. If the processor 12 executes an application stored in the memory 13, an image data signal and/or an input control signal are transmitted to the display module 11, and the display module 11 may process the received signal and output image information through a display screen.

The power module 14 may include a power supply module such as a power adapter or a battery device, and a power conversion module that converts the power supplied by the power supply module to generate power for the operation of the electronic apparatus EA.

The display module 11 may have a configuration according to one of display devices DD, DD-TD, DD-a, DD-b, and DD-c, as described above with reference to FIGS. 1, 2, and 7 to 10. For example, a configuration of the display module 11 may include a base layer BS, a circuit layer DP-CL, and a display element layer DP-ED, as shown in display devices DD, DD-TD, DD-a, DD-b, and DD-c, as described with reference to FIGS. 1, 2, and 7 to 10. The display module 11 may further include at least one of an optical layer PP (FIG. 2), a light control layer CCL (FIGS. 7 and 10), a color filter layer CFL (FIGS. 7 and 10), and an optical auxiliary layer PL (FIG. 10).

The electronic apparatus EA may further include an input module 15, a non-image output module 16, and/or a communication module 17.

The input module 15 may provide input information to the processor 12 and/or the display module 11. The input module 15 may include various sensor modules as well as physical buttons, a keyboard, and a microphone. Examples of sensor modules may include touch sensors, pressure sensors, distance sensors, position sensors, digitizers, motion recognition sensors, camera sensors, photodetector, photoelectric conversion sensors, temperature sensors, and biosensors such as blood pressure sensors, blood sugar sensors, electrocardiogram sensors, and heart rate sensors.

The non-image output module 16 may receive information other than images that are transmitted from the processor 12 and may provide the information to the user. Examples of the non-image output module 16 may include an audio module, a haptic module, a light emitting module, and the like, and may include other electronic device-specific functional modules (e.g., a cooling module for a refrigerator, and the like).

The communication module 17 is a module that transmits and receives information between the electronic apparatus EA and an external device, and may include a receiving part and a transmitting part. The communication module 17 may include various wireless communication modules such as a mobile communication module, a Wi-Fi module, and a Bluetooth module, or various wired communication modules.

In an embodiment, one or more of the individual modules that are functionally included in one module may be included in the display device, and other modules may be provided separately from the display device. For example, the display device may include the display module 11, and the processor 12, the memory 13, and the power module 14 may be included in other devices within the electronic apparatus EA other than the display device.

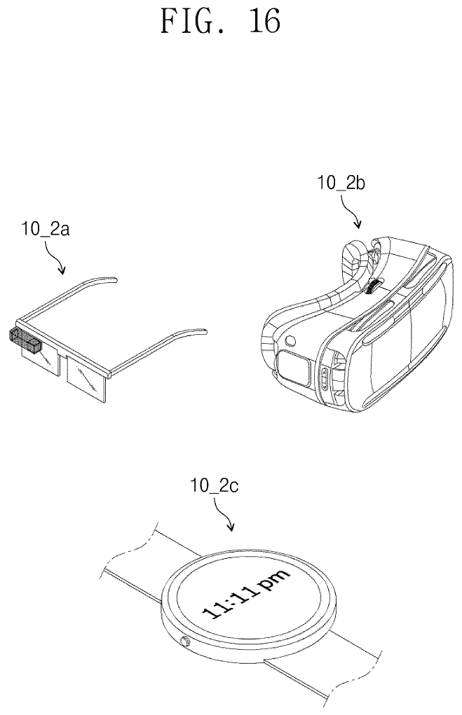

FIGS. 15 and 16 are each a schematic diagram of an electronic apparatus according to embodiments. Referring to FIGS. 15 and 16, various electronic apparatuses may include a display device (for example, at least one of DD, DD-TD, DD-a, DD-b, and DD-c, as shown in FIGS. 1, 2, and 7 to 10) according to an embodiment, and examples of such electronic apparatuses may include not only image display electronic apparatuses, such as a smart phone 10_1a, a tablet computer 10_1b, a laptop computer 10_1c, a television 10_1d, and a desktop monitor 10_1e, and such examples may also include wearable electronic apparatuses that include display modules such as smart glasses 10_2a, a head-mounted display 10_2b, and a smart watch 10_2c. However, these embodiments are only shown as examples, and the electronic apparatus according to embodiments is not limited thereto.

Hereinafter, a fused polycyclic compound according to an embodiment and a light-emitting element according to an embodiment will be described in detail with reference to the Examples and the Comparative Examples. The Examples described below are only provided to aid in understanding the disclosure, and the scope thereof is not limited thereto.

### EXAMPLES

### 1. Synthesis of Fused Polycyclic Compound

Synthesis methods for fused polycyclic compounds according to embodiments will be described in detail by describing synthesis methods for Compounds 4, 54, 192, 226, 260, and 291. In the following descriptions, the synthesis methods for the fused polycyclic compounds are only provided as examples, and the synthesis method of the fused polycyclic compound is not limited to the Examples below.

### (1) Synthesis of Compound 4

Compound 4 according to an embodiment may be synthesized by, for example, the following reaction.

### (Synthesis of Intermediate 4-1)

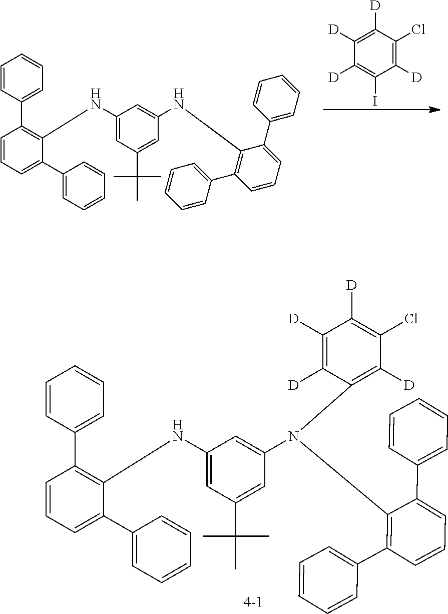

Under a nitrogen atmosphere, N¹,N³-di([1,1′:3′,1″-terphenyl]-2′-yl)-5-(tert-butyl)benzene-1,3-diamine (1 eq), 1-chloro-3-iodobenzene-2,4,5,6-d₄ (1.1 eq), Pd₂(dba)₃ (0.2 eq), tris-tert-butyl phosphine (0.4 eq), and sodium tert-butoxide (5 eq) were added and dissolved in o-xylene, and the reaction solution was stirred at about 140° C. for about one day. After cooling, water and ethyl acetate were added and extraction was performed, and organic layers were collected, dried with MgSO₄, and filtered. The solvent of the filtrate solution was removed under reduced pressure, and the obtained reaction product was purified and separated by column chromatography using silica gel to obtain Intermediate 4-1. (yield: 62%)

### (Synthesis of Intermediate 4-2)

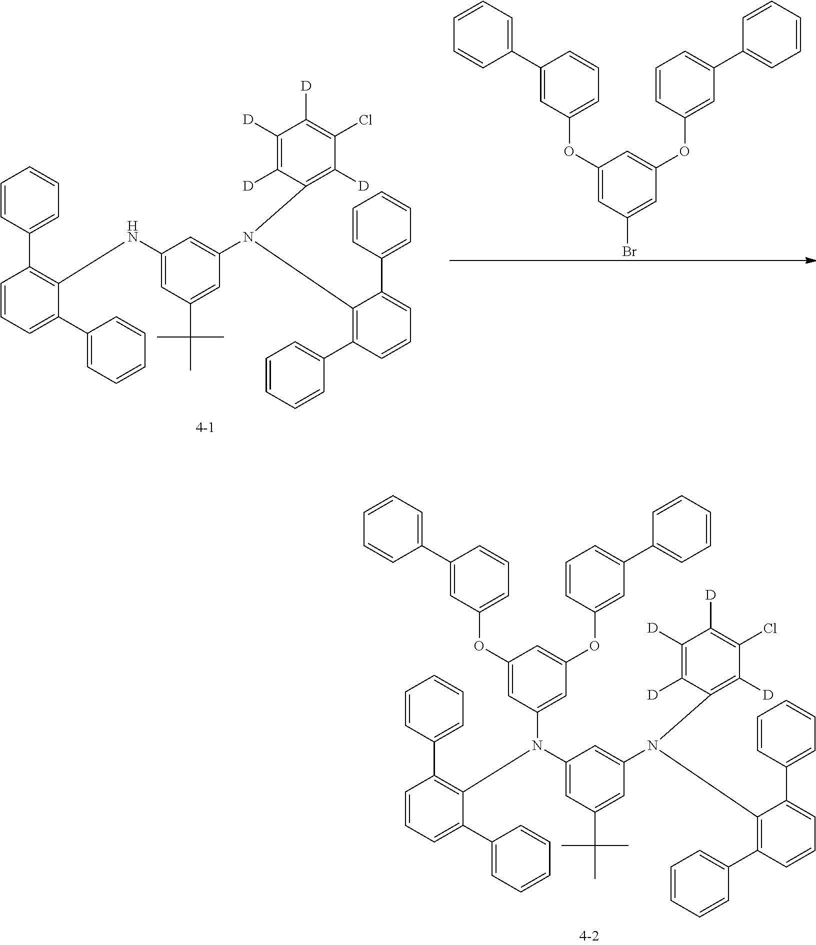 [SMILES: [2H]c1c([2H])c(Cl)c([2H])c(N(c2cc(Nc3c(-c4ccccc4)cccc3-c3ccccc3)cc(C(C)(C)C)c2)c2c(-c3ccccc3)cccc2-c2ccccc2)c1[2H] ; Brc1cc(Oc2cccc(-c3ccccc3)c2)cc(Oc2cccc(-c3ccccc3)c2)c1 ; [2H]c1c([2H])c(Cl)c([2H])c(N(c2cc(N(c3cc(Oc4cccc(-c5ccccc5)c4)cc(Oc4cccc(-c5ccccc5)c4)c3)c3c(-c4ccccc4)cccc3-c3ccccc3)cc(C(C)(C)C)c2)c2c(-c3ccccc3)cccc2-c2ccccc2)c1[2H]]

Under a nitrogen atmosphere, Intermediate 4-1 (1 eq), 3,3″-((5-bromo-1,3-phenylene)bis(oxy))di-1,1′-biphenyl (1.1 eq), Pd₂(dba)₃ (0.2 eq), tris-tert-butyl phosphine (0.4 eq), and sodium tert-butoxide (5 eq) were added and dissolved in o-xylene, and the reaction solution was stirred at about 160° C. for about 3 days. After cooling, water and ethyl acetate were added and extraction was performed, and organic layers were collected, dried with MgSO₄, and filtered. The solvent of the filtrate solution was removed under reduced pressure, and the obtained reaction product was purified and separated by column chromatography using silica gel to obtain Intermediate 4-2. (yield: 59%)

### (Synthesis of Intermediate 4-3)

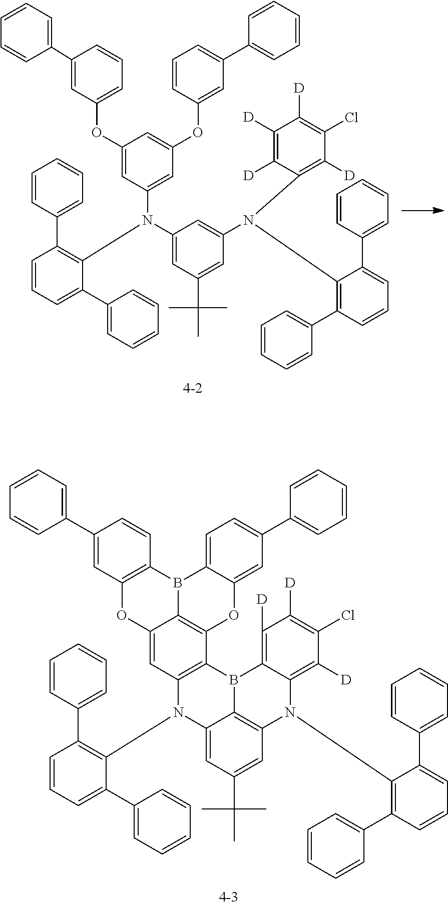 [SMILES: [2H]c1c([2H])c(Cl)c([2H])c(N(c2cc(N(c3cc(Oc4cccc(-c5ccccc5)c4)cc(Oc4cccc(-c5ccccc5)c4)c3)c3c(-c4ccccc4)cccc3-c3ccccc3)cc(C(C)(C)C)c2)c2c(-c3ccccc3)cccc2-c2ccccc2)c1[2H] ; [2H]c1c([2H])c2c(c([2H])c1Cl)N(c1c(-c3ccccc3)cccc1-c1ccccc1)c1cc(C(C)(C)C)cc3c1B2c1c(cc2c4c1Oc1cc(-c5ccccc5)ccc1B4c1ccc(-c4ccccc4)cc1O2)N3c1c(-c2ccccc2)cccc1-c1ccccc1]

Under a nitrogen atmosphere, Intermediate 4-2 (1 eq) was dissolved in o-dichlorobenzene, the mixture was cooled using ice water, BBr₃ (5 eq) was slowly added dropwise, and the reaction solution was stirred at about 180° C. for about 24 hours. After cooling, triethylamine (5 eq) was added to terminate the reaction, extraction was performed using H₂O and CH₂Cl₂, organic layers were collected, dried over MgSO₄, and filtered. The solvent of the filtrate solution was removed under reduced pressure, was purified and recrystallized by column chromatography using silica gel to obtain Intermediate 4-3. (yield: 55%)

### (Synthesis of Compound 4)

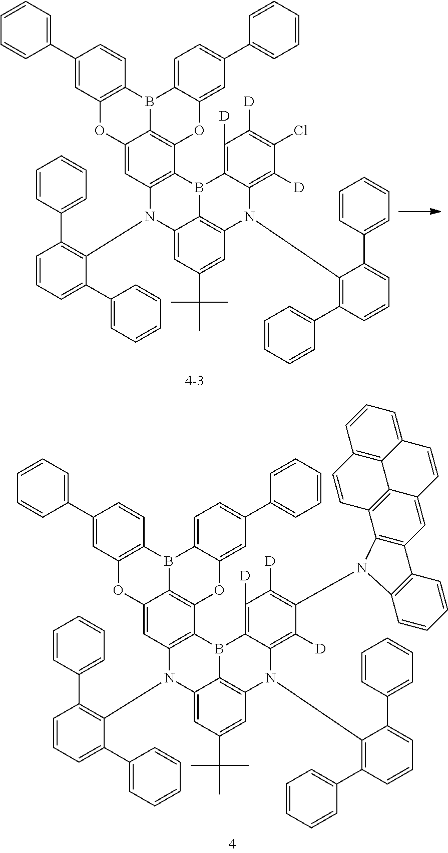 [SMILES: [2H]c1c([2H])c2c(c([2H])c1Cl)N(c1c(-c3ccccc3)cccc1-c1ccccc1)c1cc(C(C)(C)C)cc3c1B2c1c(cc2c4c1Oc1cc(-c5ccccc5)ccc1B4c1ccc(-c4ccccc4)cc1O2)N3c1c(-c2ccccc2)cccc1-c1ccccc1 ; [2H]c1c([2H])c(-n2c3ccccc3c3cc4ccc5cccc6ccc(c4c56)c32)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccccc2)ccc1B4c1ccc(-c2ccccc2)cc1O3]

Under a nitrogen atmosphere, Intermediate 4-3 (1 eq), 11H-phenaleno[1,9-ab]carbazole (1.1 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about one day. After cooling, water and ethyl acetate were added and extraction was performed, and organic layers were collected, dried with MgSO₄, and filtered. The solvent of the filtrate solution was removed under reduced pressure, and the obtained reaction product was purified and recrystallized by column chromatography using silica gel to obtain Compound 4. (yield: 58%)

### (2) Synthesis of Compound 54

Compound 54 according to an embodiment may be synthesized by, for example, the following reaction.

### (Synthesis of Intermediate 54-1)

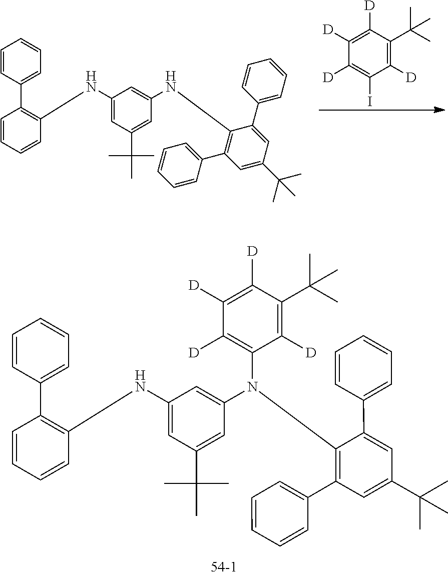

Under a nitrogen atmosphere, N¹-([1,1′-biphenyl]-2-yl)-5-(tert-butyl)-N³-(5′-(tert-butyl)-[1,1′:3′,1″-terphenyl]-2′-yl)benzene-1,3-diamine (1 eq), 1-(tert-butyl)-3-iodobenzene-2,4,5,6-d₄ (1.1 eq), Pd₂(dba)₃ (0.2 eq), tris-tert-butyl phosphine (0.4 eq), and sodium tert-butoxide (5 eq) were added and dissolved in o-xylene, and the reaction solution was stirred at about 140° C. for about one day. After cooling, water and ethyl acetate were added and extraction was performed, and organic layers were collected, dried with MgSO₄, and filtered. The solvent of the filtrate solution was removed under reduced pressure, and the obtained reaction product was purified and separated by column chromatography using silica gel to obtain Intermediate 54-1. (yield: 60%)

### (Synthesis of Intermediate 54-2)

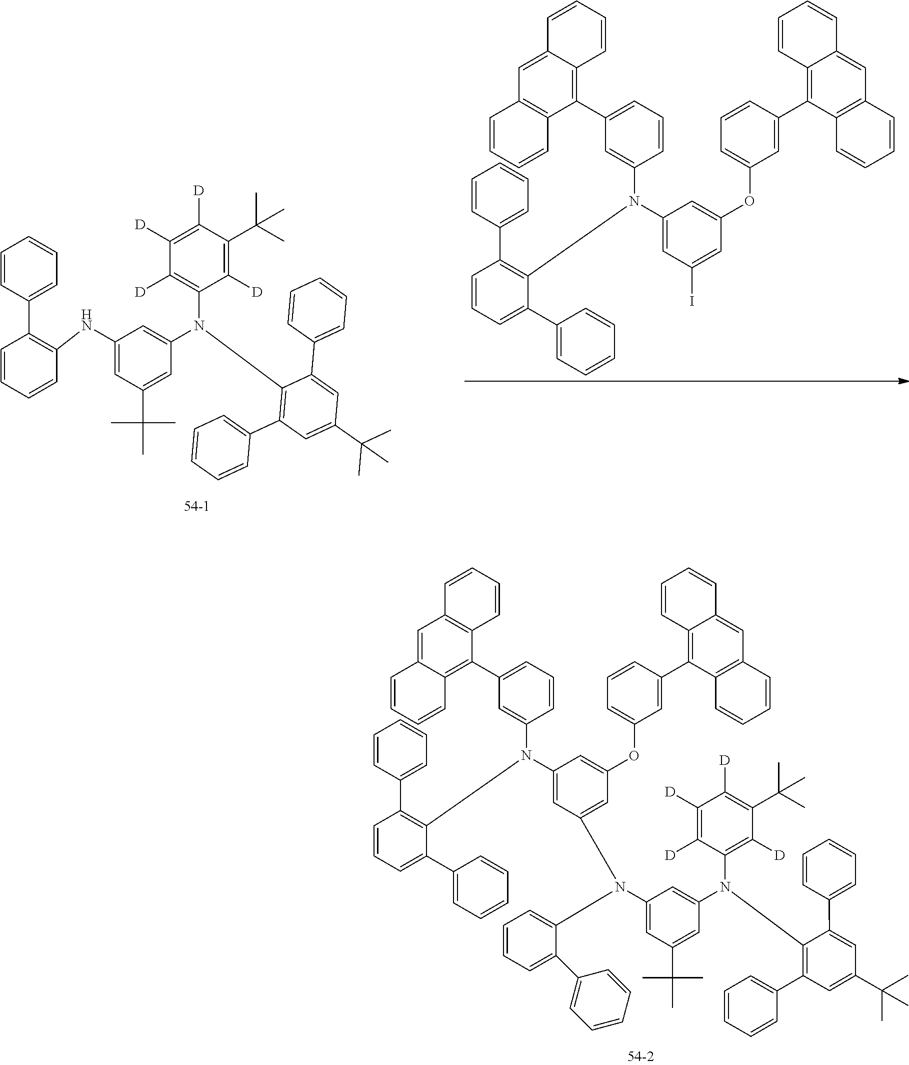 [SMILES: [2H]c1c([2H])c(N(c2cc(Nc3ccccc3-c3ccccc3)cc(C(C)(C)C)c2)c2c(-c3ccccc3)cc(C(C)(C)C)cc2-c2ccccc2)c([2H])c(C(C)(C)C)c1[2H] ; Ic1cc(Oc2cccc(-c3c4ccccc4cc4ccccc34)c2)cc(N(c2cccc(-c3c4ccccc4cc4ccccc34)c2)c2c(-c3ccccc3)cccc2-c2ccccc2)c1 ; [2H]c1c([2H])c(N(c2cc(N(c3cc(Oc4cccc(-c5c6ccccc6cc6ccccc56)c4)cc(N(c4cccc(-c5c6ccccc6cc6ccccc56)c4)c4c(-c5ccccc5)cccc4-c4ccccc4)c3)c3ccccc3-c3ccccc3)cc(C(C)(C)C)c2)c2c(-c3ccccc3)cc(C(C)(C)C)cc2-c2ccccc2)c([2H])c(C(C)(C)C)c1[2H]]

Under a nitrogen atmosphere, Intermediate 54-1 (1 eq), N-(3-(3-(anthracen-9-yl)phenoxy)-5-iodophenyl)-N-(3-(anthracen-9-yl)phenyl)-[1,1′:3′,1″-terphenyl]-2′-amine (1.1 eq), Pd₂(dba)₃ (0.2 eq), tris-tert-butyl phosphine (0.4 eq), and sodium tert-butoxide (5 eq) were added and dissolved in o-xylene, and the reaction solution was stirred at about 160° C. for about 3 days. After cooling, water and ethyl acetate were added and extraction was performed, and organic layers were collected, dried with MgSO₄, and filtered. The solvent of the filtrate solution was removed under reduced pressure, and the obtained reaction product was purified and separated by column chromatography using silica gel to obtain Intermediate 54-2. (yield: 54%)

### (Synthesis of Compound 54)

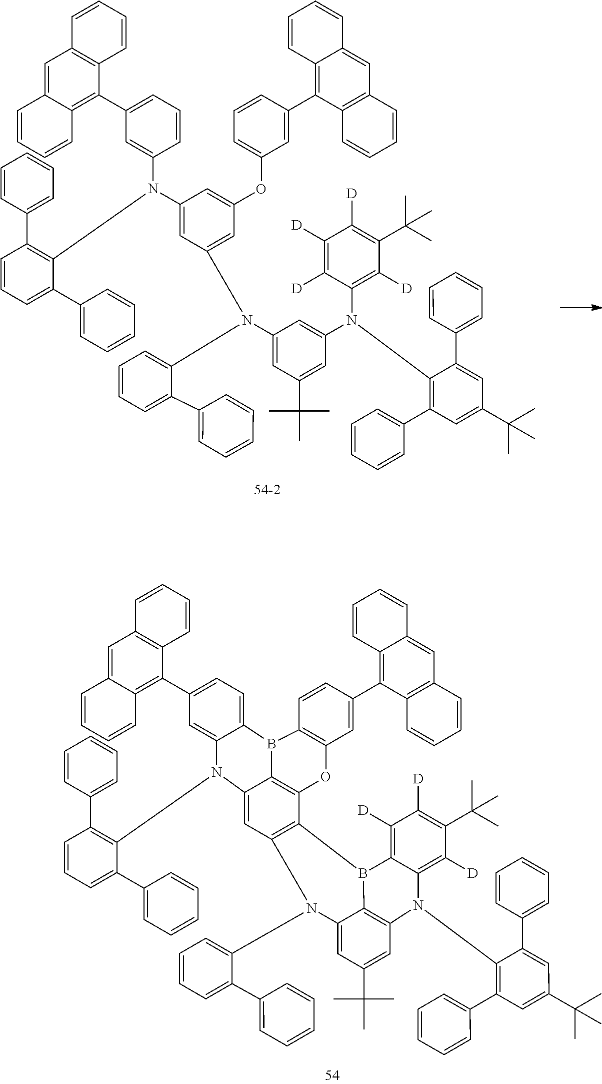 [SMILES: [2H]c1c([2H])c(N(c2cc(N(c3cc(Oc4cccc(-c5c6ccccc6cc6ccccc56)c4)cc(N(c4cccc(-c5c6ccccc6cc6ccccc56)c4)c4c(-c5ccccc5)cccc4-c4ccccc4)c3)c3ccccc3-c3ccccc3)cc(C(C)(C)C)c2)c2c(-c3ccccc3)cc(C(C)(C)C)cc2-c2ccccc2)c([2H])c(C(C)(C)C)c1[2H] ; [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1]

Under a nitrogen atmosphere, Intermediate 54-2 (1 eq) was dissolved in o-dichlorobenzene, the mixture was cooled using ice water, BBr₃ (5 eq) was slowly added dropwise, and the reaction solution was stirred at about 180° C. for about 24 hours. After cooling, triethylamine (5 eq) was added to terminate the reaction, extraction was performed using H₂O and CH₂Cl₂, organic layers were collected, dried over MgSO₄, and filtered. The solvent of the filtrate solution was removed under reduced pressure, was purified and recrystallized by column chromatography using silica gel to obtain Compound 54. (yield: 50%)

### (3) Synthesis of Compound 192

Compound 192 according to an embodiment may be synthesized by, for example, the following reaction.

### (Synthesis of Intermediate 192-1)

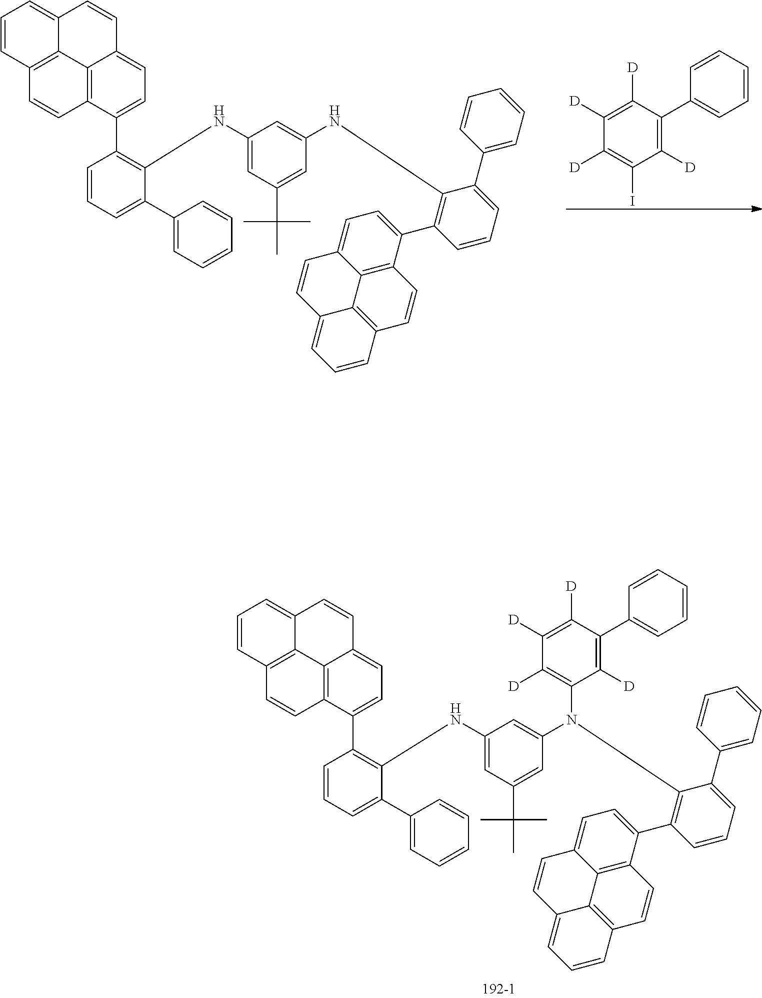 [SMILES: CC(C)(C)c1cc(Nc2c(-c3ccccc3)cccc2-c2ccc3ccc4cccc5ccc2c3c45)cc(Nc2c(-c3ccccc3)cccc2-c2ccc3ccc4cccc5ccc2c3c45)c1 ; [2H]c1c([2H])c(I)c([2H])c(-c2ccccc2)c1[2H] ; [2H]c1c([2H])c(-c2ccccc2)c([2H])c(N(c2cc(Nc3c(-c4ccccc4)cccc3-c3ccc4ccc5cccc6ccc3c4c56)cc(C(C)(C)C)c2)c2c(-c3ccccc3)cccc2-c2ccc3ccc4cccc5ccc2c3c45)c1[2H]]

Under a nitrogen atmosphere, 5-(tert-butyl)-N¹,N³-bis(3-(pyren-1-yl)-[1,1′-biphenyl]-2-yl)benzene-1,3-diamine (1 eq), 3-iodo-1,1′-biphenyl-2,4,5,6-d₄ (1.1 eq), Pd₂(dba)₃ (0.2 eq), tris-tert-butyl phosphine (0.4 eq), and sodium tert-butoxide (5 eq) were added and dissolved in o-xylene, and the reaction solution was stirred at about 140° C. for about one day. After cooling, water and ethyl acetate were added and extraction was performed, and organic layers were collected, dried with MgSO₄, and filtered. The solvent of the filtrate solution was removed under reduced pressure, and the obtained reaction product was purified and separated by column chromatography using silica gel to obtain Intermediate 192-1. (yield: 68%)

### (Synthesis of Intermediate 192-2)

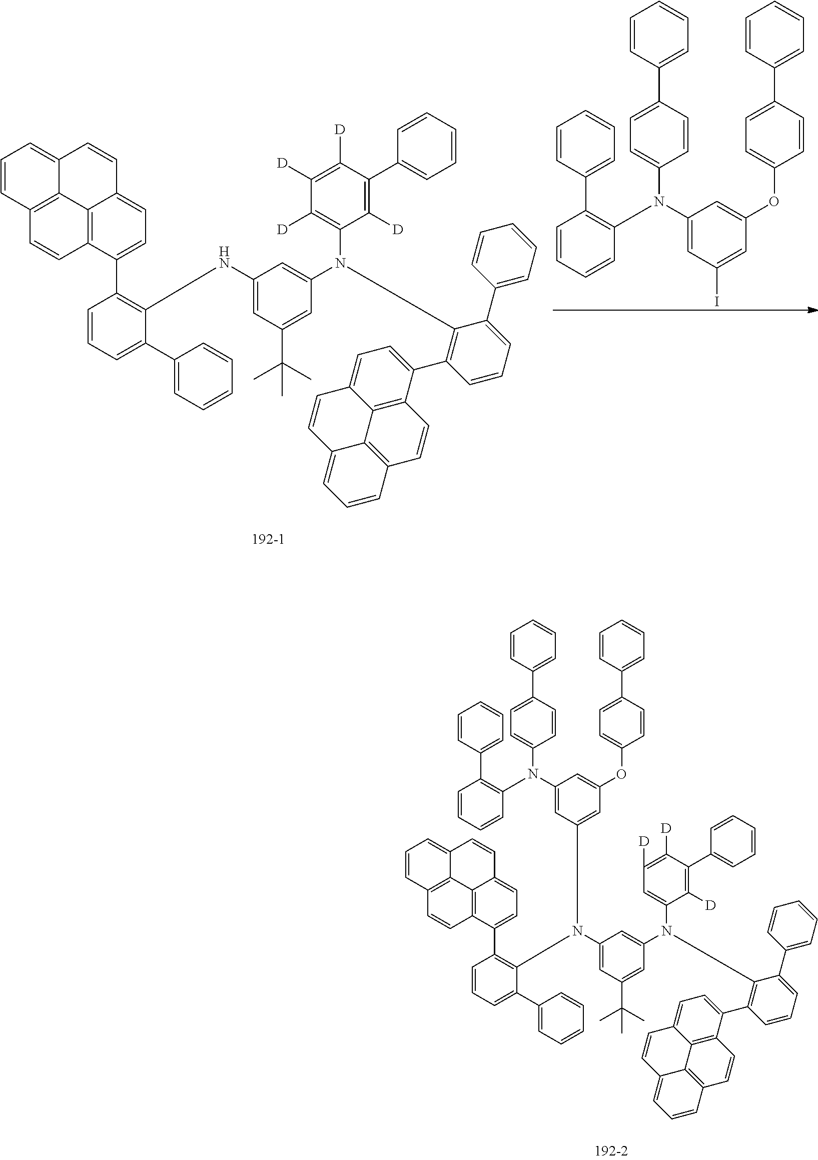

Under a nitrogen atmosphere, Intermediate 192-1 (1 eq), N-([1,1′-biphenyl]-4-yl)-N-(3-([1,1′-biphenyl]-4-yloxy)-5-iodophenyl)-[1,1′-biphenyl]-2-amine (1.1 eq), Pd₂(dba)₃ (0.2 eq), tris-tert-butyl phosphine (0.4 eq), and sodium tert-butoxide (5 eq) were added and dissolved in o-xylene, and the reaction solution was stirred at about 160° C. for about 3 days. After cooling, water and ethyl acetate were added and extraction was performed, and organic layers were collected, dried with MgSO₄, and filtered. The solvent of the filtrate solution was removed under reduced pressure, and the obtained reaction product was purified and separated by column chromatography using silica gel to obtain Intermediate 192-2. (yield: 55%)

### (Synthesis of Compound 192)

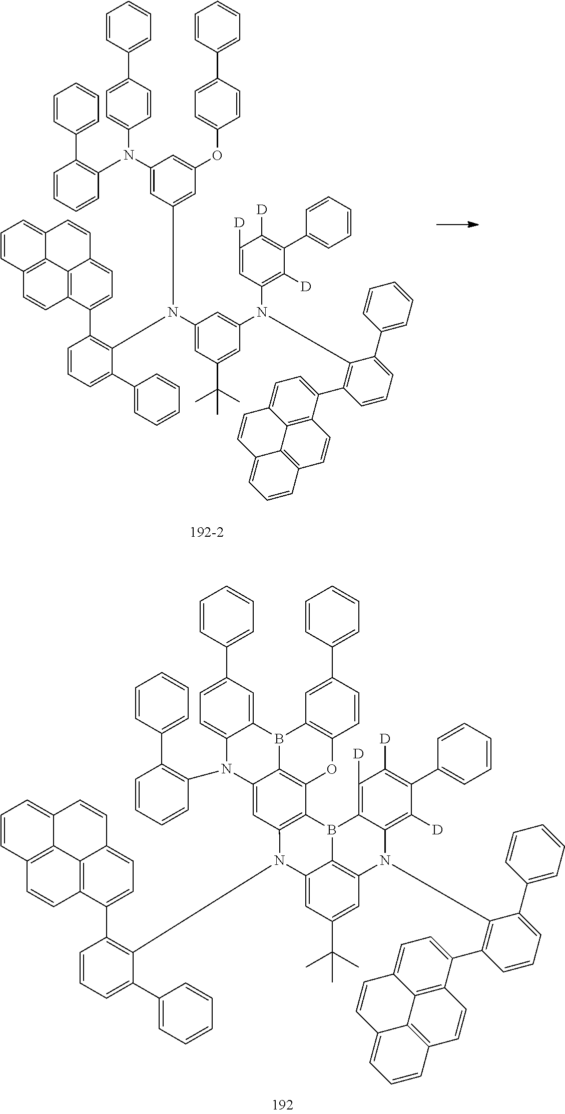 [SMILES: [2H]c1cc(N(c2cc(N(c3cc(Oc4ccc(-c5ccccc5)cc4)cc(N(c4ccc(-c5ccccc5)cc4)c4ccccc4-c4ccccc4)c3)c3c(-c4ccccc4)cccc3-c3ccc4ccc5cccc6ccc3c4c56)cc(C(C)(C)C)c2)c2c(-c3ccccc3)cccc2-c2ccc3ccc4cccc5ccc2c3c45)c([2H])c(-c2ccccc2)c1[2H] ; [2H]c1c([2H])c(-c2ccccc2)c([2H])c2c1B1c3c(cc(C(C)(C)C)cc3N2c2c(-c3ccccc3)cccc2-c2ccc3ccc4cccc5ccc2c3c45)N(c2c(-c3ccccc3)cccc2-c2ccc3ccc4cccc5ccc2c3c45)c2cc3c4c(c21)Oc1ccc(-c2ccccc2)cc1B4c1cc(-c2ccccc2)ccc1N3c1ccccc1-c1ccccc1]

Under a nitrogen atmosphere, Intermediate 192-2 (1 eq) was dissolved in o-dichlorobenzene, the mixture was cooled using ice water, BBr₃ (5 eq) was slowly added dropwise, and the reaction solution was stirred at about 180° C. for about 24 hours. After cooling, triethylamine (5 eq) was added to terminate the reaction, extraction was performed using H₂O and CH₂Cl₂, and organic layers were collected, dried over MgSO₄, and filtered. The solvent of the filtrate solution was removed under reduced pressure, was purified and recrystallized by column chromatography using silica gel to obtain Compound 192. (yield: 46%)

### (4) Synthesis of Compound 226

Compound 226 according to an embodiment may be synthesized by, for example, the following reaction.

### (Synthesis of Intermediate 226-1)

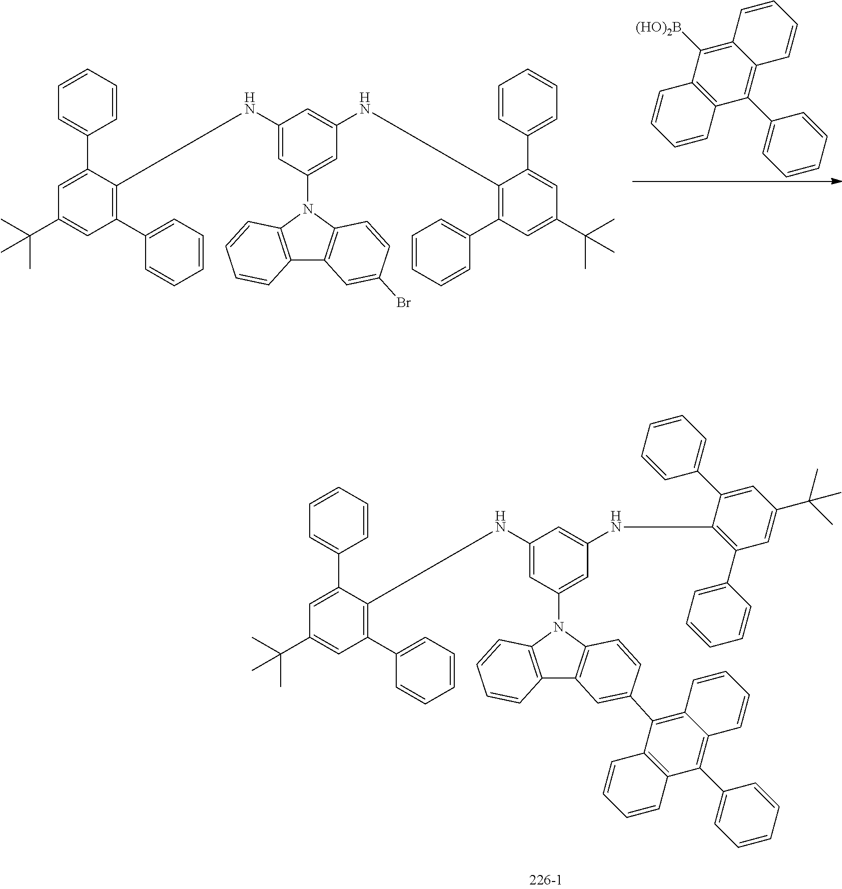

Under a nitrogen atmosphere, (10-phenylanthracen-9-yl)boronic acid (1.1 eq), Pd(PPh₃)₄ (0.05 eq), and potassium carbonate (2 eq) were added to 5-(3-bromo-9H-carbazol-9-yl)-N¹,N³-bis(5′-(tert-butyl)-[1,1′:3′,1″-terphenyl]-2′-yl)benzene-1,3-diamine (1 eq), the mixture was dissolved in 500 mL of toluene and 200 mL of H₂O, and the reaction solution was stirred at about 100° C. for about 12 hours. After cooling, water (300 mL) was added, extraction was performed, and organic layers were collected, dried with MgSO₄, and filtered. The solvent of the filtrate solution was removed under reduced pressure, and the obtained solid was purified by column chromatography using silica gel with CH₂Cl₂ and hexane as a developing solvent, followed by recrystallization to obtain intermediate 226-1. (yield: 72%)

### (Synthesis of Intermediate 226-2)

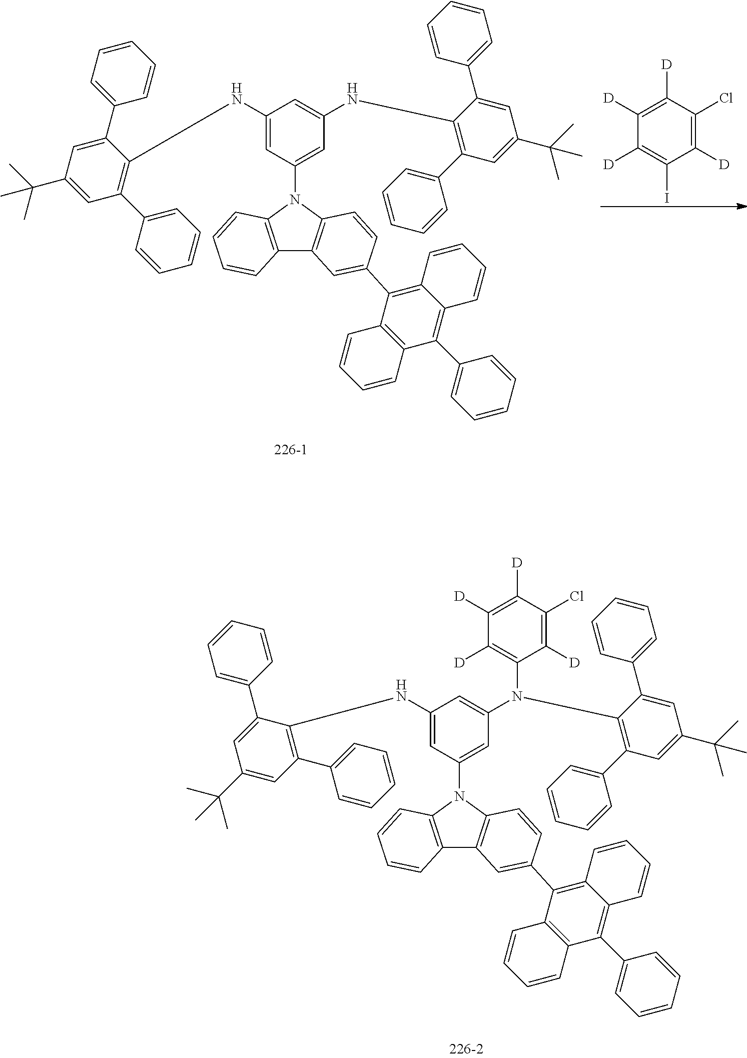

Under a nitrogen atmosphere, Intermediate 226-1 (1 eq), 1-chloro-3-iodobenzene-2,4,5,6-d₄ (1.1 eq), Pd₂(dba)₃ (0.2 eq), tris-tert-butyl phosphine (0.4 eq), and sodium tert-butoxide (5 eq) were added and dissolved in o-xylene, and the reaction solution was stirred at about 140° C. for about 1 day. After cooling, water and ethyl acetate were added, extraction was performed, and organic layers were collected, dried with MgSO₄, and filtered. The solvent of the filtrate solution was removed under reduced pressure, and the obtained solid was purified and separated by column chromatography using silica gel to obtain intermediate 226-2. (yield: 65%)

### (Intermediate 226-3)

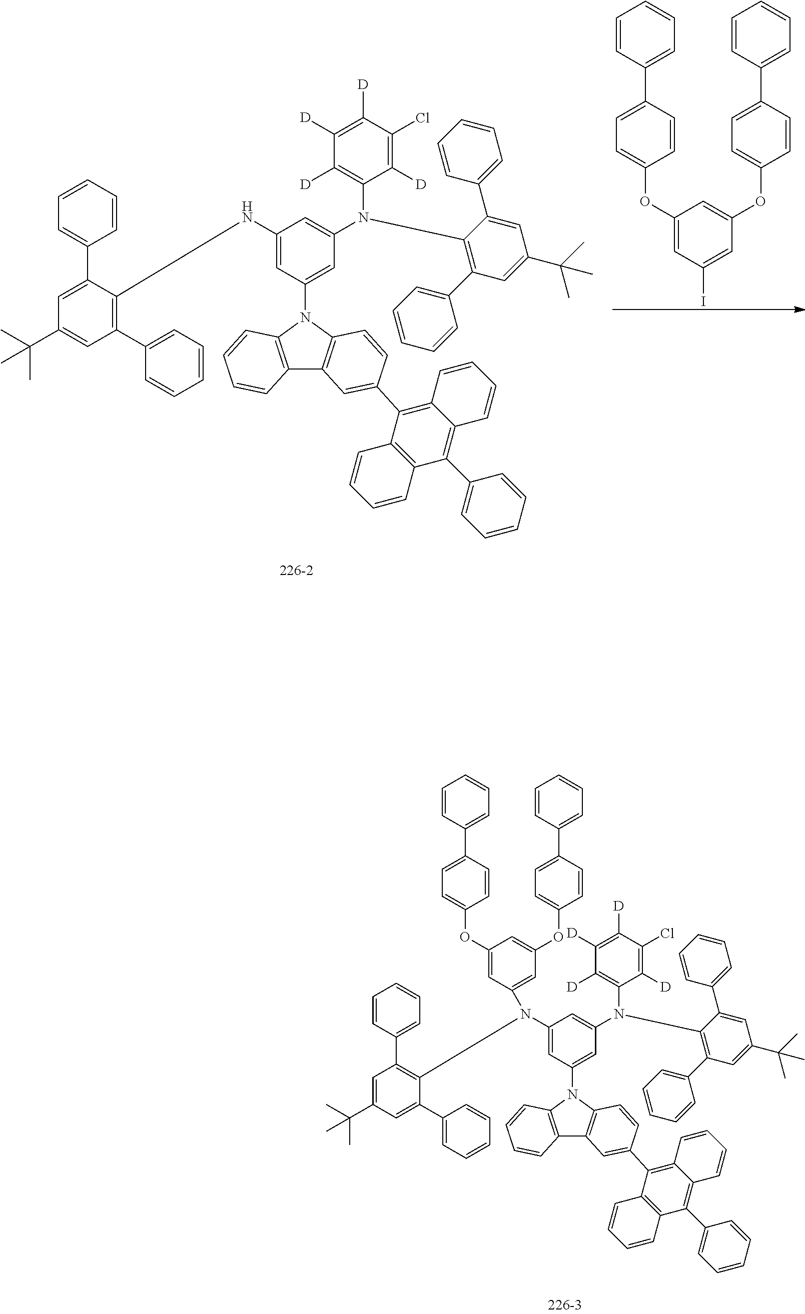

Under a nitrogen atmosphere, Intermediate 226-2 (1 eq), 4,4″-((5-iodo-1,3-phenylene)bis(oxy))di-1,1′-biphenyl (1.1 eq), Pd₂(dba)₃ (0.2 eq), tris-tert-butyl phosphine (0.4 eq), and sodium tert-butoxide (5 eq) were added, and dissolved in o-dichlorobenzene, and the reaction solution was stirred at about 160° C. for about three days. After cooling, water and ethyl acetate were added, extraction was performed using water and ethyl acetate, and organic layers were collected, dried over MgSO₄, and filtered. The solvent of the filtrate solution was removed under reduced pressure, and the obtained product was purified and separated by column chromatography using silica gel to obtain Intermediate 226-3. (yield: 52%)

### (Synthesis of Intermediate 226-4)

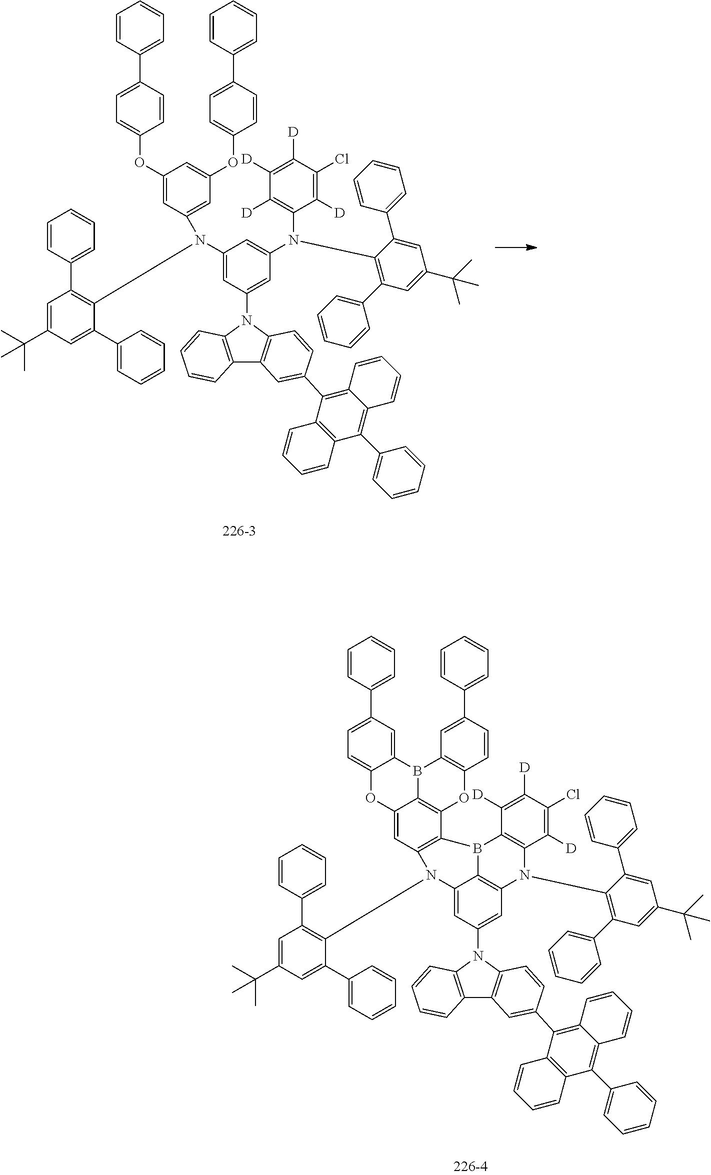

Under a nitrogen atmosphere, Intermediate 226-3 (1 eq) was dissolved in o-dichlorobenzene, the mixture was cooled using ice water, BBr₃ (5 eq) was slowly added dropwise, and the reaction solution was stirred at about 180° C. for about 24 hours. After cooling, triethylamine (5 eq) was added to terminate the reaction, extraction was performed using H₂O and CH₂Cl₂, and organic layers were collected, dried over MgSO₄, and filtered. The solvent of the filtrate solution was removed under reduced pressure, was purified and recrystallized by column chromatography using silica gel to obtain Intermediate 226-4. (yield: 59%)

### (Synthesis of Compound 226)

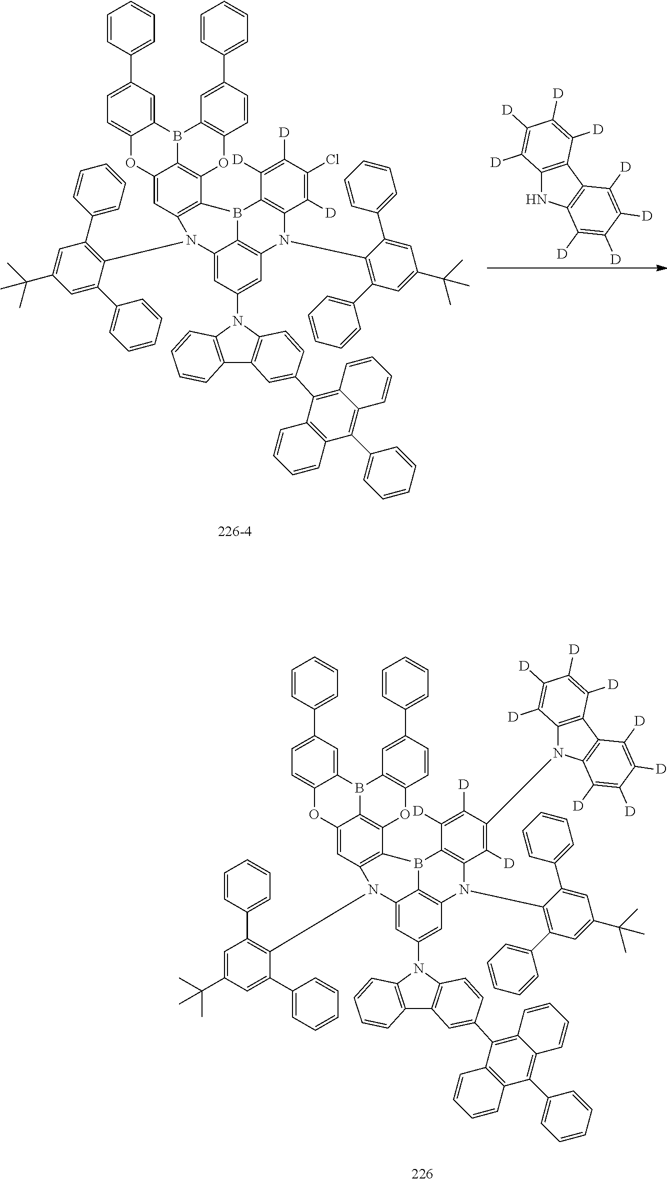

Under a nitrogen atmosphere, Intermediate 226-4 (1 eq), 9H-carbazole-1,2,3,4,5,6,7,8-d₈ (1.1 eq), Pd₂(dba)₃ (0.05 eq), tris-tert-butyl phosphine (0.1 eq), and sodium tert-butoxide (3 eq) were added and dissolved in o-dichlorobenzene, and the reaction solution was stirred at about 140° C. for about 1 day. After cooling, water and ethyl acetate were added, extraction was performed, and organic layers were collected, dried over MgSO₄, and filtered. The solvent of the filtrate solution was removed under reduced pressure, and the obtained product was purified and recrystallized by column chromatography using silica gel to obtain Compound 226. (yield: 66%)

### (5) Synthesis of Compound 260

Compound 260 according to an embodiment may be synthesized by, for example, the following reaction.

### (Synthesis of Intermediate 260-1)

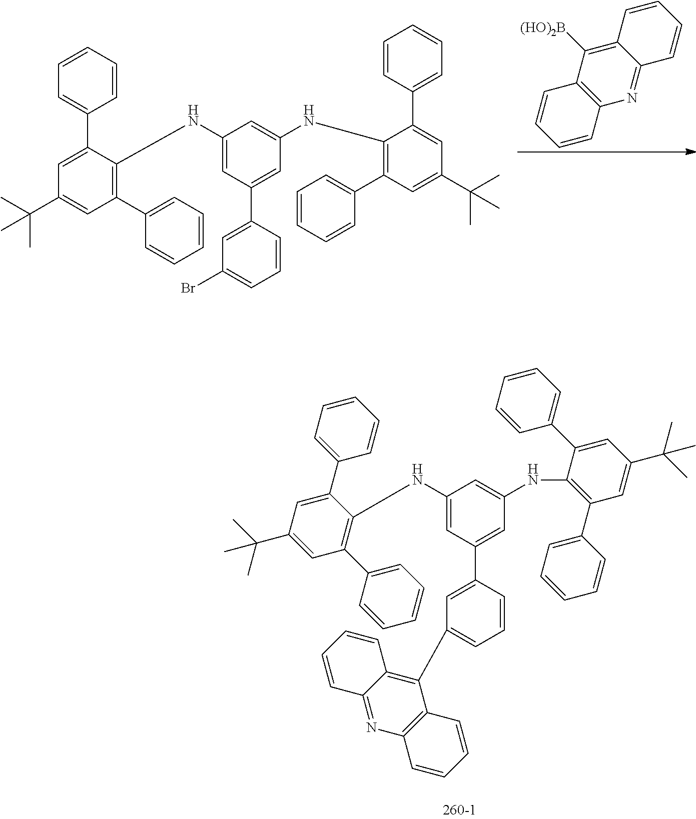

Under a nitrogen atmosphere, acridin-9-ylboronic acid (1.1 eq), Pd(PPh₃)₄ (0.05 eq), and potassium carbonate (2 eq) were added to 3′-bromo-N³,N⁵-bis(5′-(tert-butyl)-[1,1′:3′,1″-terphenyl]-2′-yl)-[1,1′-biphenyl]-3,5-diamine (1 eq) and dissolved in 500 mL of toluene, and 200 mL of H₂O, and the mixture was stirred at about 100° C. for about 12 hours. After cooling, water (300 mL) was added, extraction was performed, and organic layers were collected, dried over MgSO₄, and filtered. The solvent of the filtrate solution was removed under reduced pressure, the obtained solid was purified and recrystallized by column chromatography using silica gel with CH₂Cl₂ and hexane as a developing solvent to obtain Intermediate 260-1. (yield: 78%)

### (Synthesis of Intermediate 260-2)

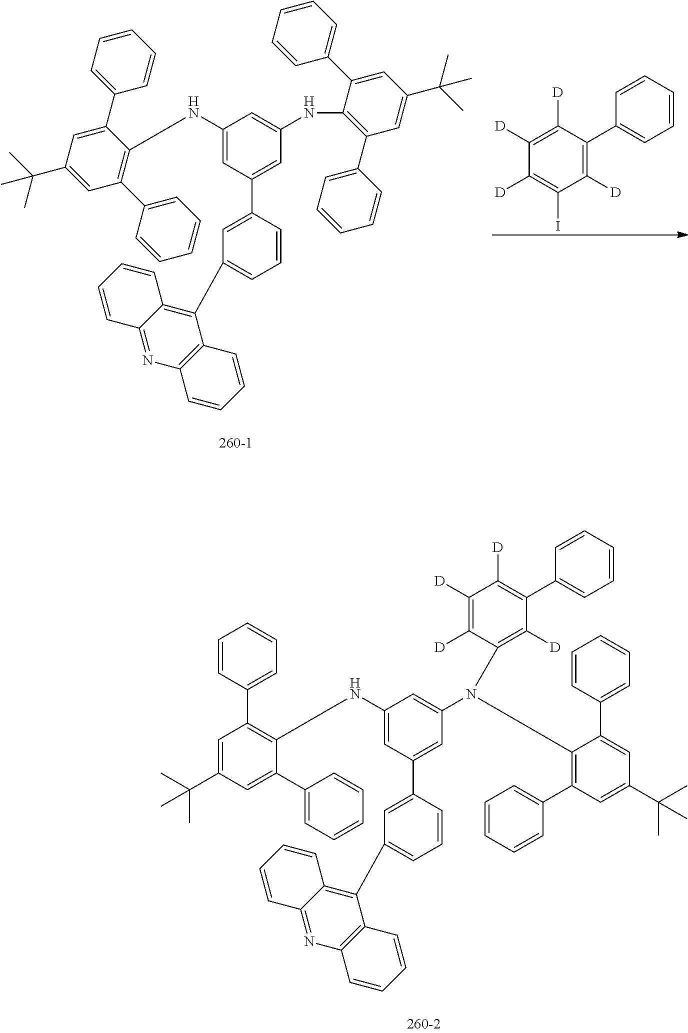

Under a nitrogen atmosphere, Intermediate 260-1 (1 eq), 3-iodo-1,1′-biphenyl-2,4,5,6-d4 (1.1 eq), Pd₂(dba)₃ (0.2 eq), tris-tert-butyl phosphine (0.4 eq), and sodium tert-butoxide (5 eq) were added and dissolved in o-xylene, and the mixture was stirred at about 140° C. for about one day. After cooling, water and ethyl acetate were added, extraction was performed, and organic layers were collected, dried over MgSO₄, and filtered. The solvent of the filtrate solution was removed under reduced pressure, and the obtained product was purified and recrystallized by column chromatography using silica gel to obtain Intermediate 260-2. (yield: 78%)

### (Synthesis of Intermediate 260-3)

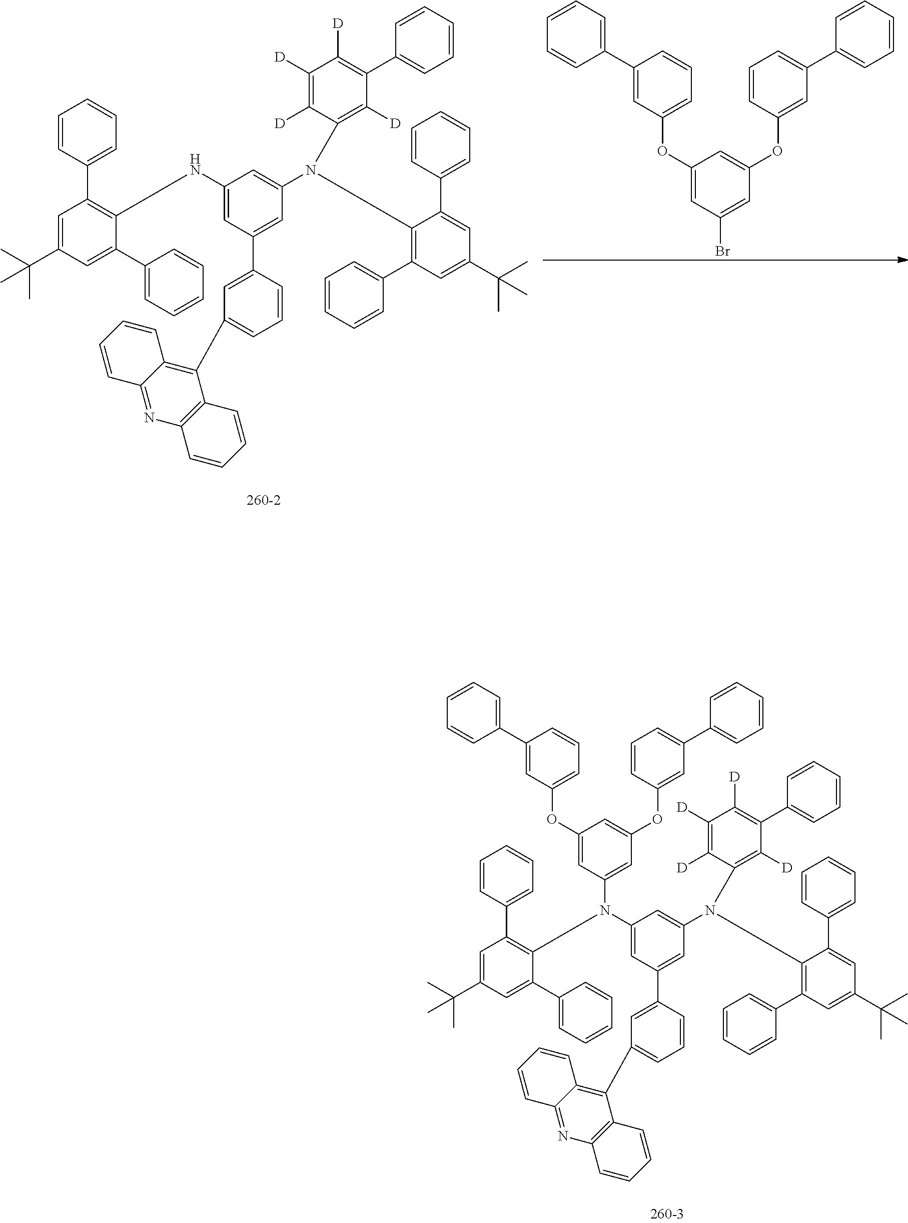 [SMILES: [2H]c1c([2H])c(-c2ccccc2)c([2H])c(N(c2cc(Nc3c(-c4ccccc4)cc(C(C)(C)C)cc3-c3ccccc3)cc(-c3cccc(-c4c5ccccc5nc5ccccc45)c3)c2)c2c(-c3ccccc3)cc(C(C)(C)C)cc2-c2ccccc2)c1[2H] ; Brc1cc(Oc2cccc(-c3ccccc3)c2)cc(Oc2cccc(-c3ccccc3)c2)c1 ; [2H]c1c([2H])c(-c2ccccc2)c([2H])c(N(c2cc(-c3cccc(-c4c5ccccc5nc5ccccc45)c3)cc(N(c3cc(Oc4cccc(-c5ccccc5)c4)cc(Oc4cccc(-c5ccccc5)c4)c3)c3c(-c4ccccc4)cc(C(C)(C)C)cc3-c3ccccc3)c2)c2c(-c3ccccc3)cc(C(C)(C)C)cc2-c2ccccc2)c1[2H]]

Under a nitrogen atmosphere, Intermediate 260-2 (1 eq), 3,3″-((5-bromo-1,3-phenylene)bis(oxy))di-1,1′-biphenyl (1.1 eq), Pd₂(dba)₃ (0.2 eq), tris-tert-butyl phosphine (0.4 eq), and sodium tert-butoxide (5 eq) were added and dissolved in o-xylene, and the mixture was stirred at about 160° C. for about three days. After cooling, water and ethyl acetate were added, extraction was performed, and organic layers were collected, dried over MgSO₄, and filtered. The solvent of the filtrate solution was removed under reduced pressure, the obtained product was purified and recrystallized by column chromatography using silica gel to obtain Intermediate 260-3. (yield: 62%)

### (Synthesis of Compound 260)

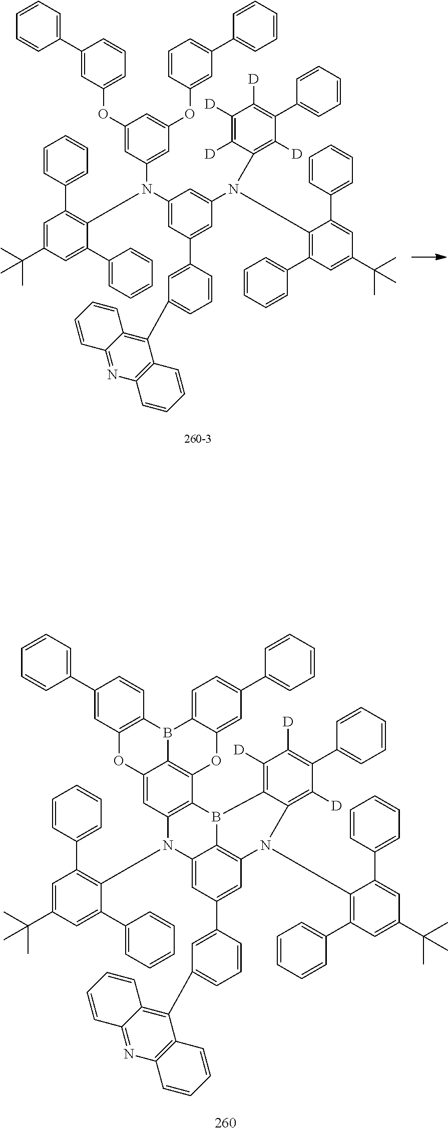

Under a nitrogen atmosphere, Intermediate 260-3 (1 eq) was dissolved in o-dichlorobenzene, the mixture was cooled using ice water, BBr₃ (5 eq) was slowly added dropwise, and the reaction solution was stirred at about 180° C. for about 24 hours. After cooling, triethylamine (5 eq) was added to terminate the reaction, extraction was performed using H₂O and CH₂Cl₂, and organic layers were collected, dried over MgSO₄, and filtered. The solvent of the filtrate solution was removed under reduced pressure, and the obtained was purified and recrystallized by column chromatography using silica gel to obtain Compound 260. (yield: 60%)

### (6) Synthesis of Compound 291

Compound 291 according to an embodiment may be synthesized by, for example, the following reaction.

### (Synthesis of Intermediate 291-1)

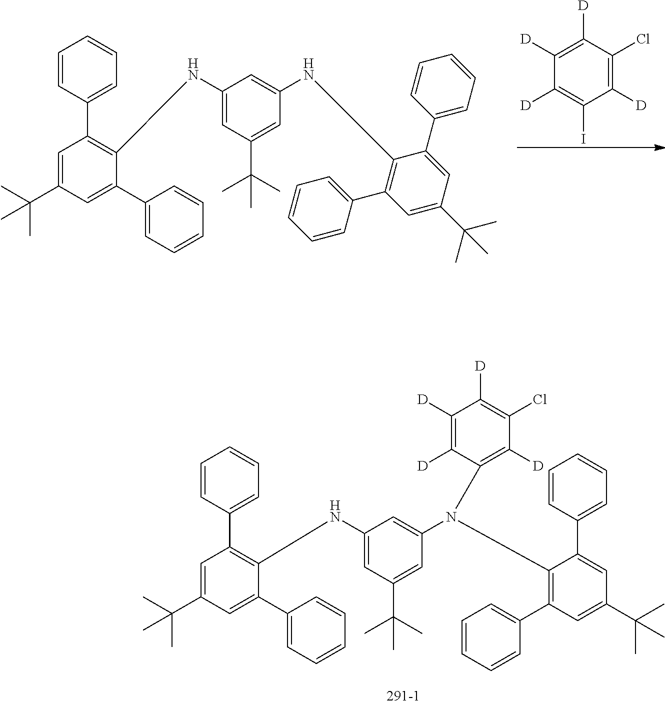

Under a nitrogen atmosphere, 5-(tert-butyl)-N¹,N³-bis(5′-(tert-butyl)-[1,1′:3′,1″-terphenyl]-2′-yl)benzene-1,3-diamine (1 eq), 1-chloro-3-iodobenzene-2,4,5,6-d₄ (1.1 eq), Pd₂(dba)₃ (0.2 eq), tris-tert-butyl phosphine (0.4 eq), and sodium tert-butoxide (5 eq) were added and dissolved in o-xylene, and the reaction solution was stirred at about 140° C. for about one day. After cooling, water and ethyl acetate were added, extraction was performed, and organic layers were collected, dried over MgSO₄, and filtered. The solvent of the filtrate solution was removed under reduced pressure, and the obtained product was purified and separated by column chromatography using silica gel to obtain Intermediate 291-1. (yield: 59%)

### (Synthesis of Intermediate 291-2)

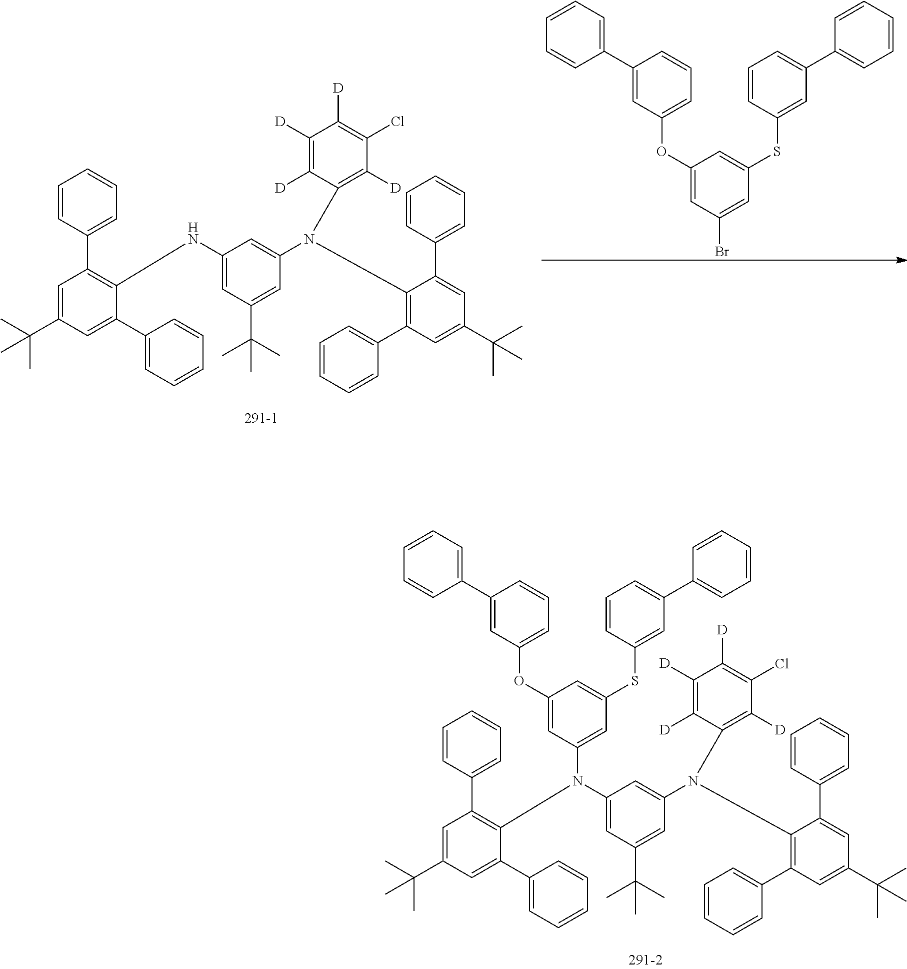 [SMILES: [2H]c1c([2H])c(Cl)c([2H])c(N(c2cc(Nc3c(-c4ccccc4)cc(C(C)(C)C)cc3-c3ccccc3)cc(C(C)(C)C)c2)c2c(-c3ccccc3)cc(C(C)(C)C)cc2-c2ccccc2)c1[2H] ; Brc1cc(Oc2cccc(-c3ccccc3)c2)cc(Sc2cccc(-c3ccccc3)c2)c1 ; [2H]c1c([2H])c(Cl)c([2H])c(N(c2cc(N(c3cc(Oc4cccc(-c5ccccc5)c4)cc(Sc4cccc(-c5ccccc5)c4)c3)c3c(-c4ccccc4)cc(C(C)(C)C)cc3-c3ccccc3)cc(C(C)(C)C)c2)c2c(-c3ccccc3)cc(C(C)(C)C)cc2-c2ccccc2)c1[2H]]

Under a nitrogen atmosphere, Intermediate 291-1 (1 eq), [1,1′-biphenyl]-3-yl(3-([1,1′-biphenyl]-3-yloxy)-5-bromophenyl)sulfane (1.1 eq), Pd₂(dba)₃ (0.2 eq), tris-tert-butyl phosphine (0.4 eq), and sodium tert-butoxide (5 eq) were added and dissolved in o-xylene, and the reaction solution was stirred at about 160° C. for about three days. After cooling, water and ethyl acetate were added, extraction was performed, and organic layers were collected, dried over MgSO₄, and filtered. The solvent of the filtrate solution was removed under reduced pressure, and the obtained product was purified and separated by column chromatography using silica gel to obtain Intermediate 291-2. (yield: 48%)

### (Synthesis of Intermediate 291-3)

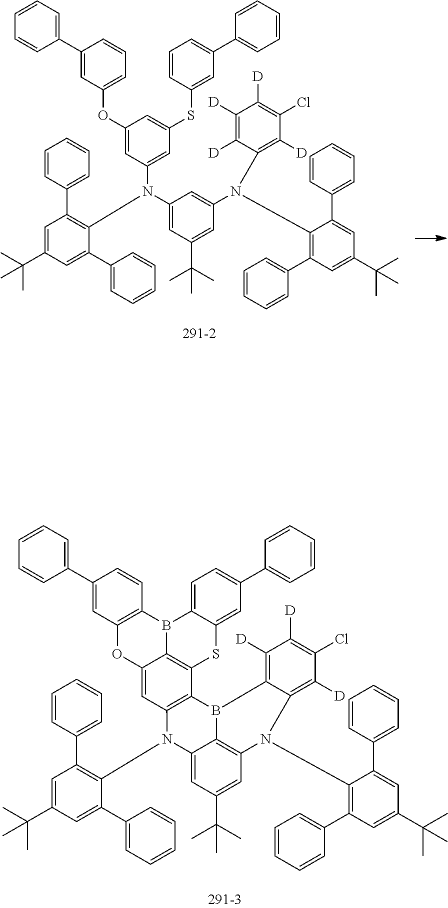

Under a nitrogen atmosphere, Intermediate 291-2 (1 eq) was dissolved in o-dichlorobenzene, the mixture was cooled using ice water, BBr₃ (5 eq) was slowly added dropwise, and the reaction solution was stirred at about 180° C. for about 24 hours. After cooling, triethylamine (5 eq) was added to terminate the reaction, extraction was performed using H₂O and CH₂Cl₂, and organic layers were collected, dried over MgSO₄, and filtered. The solvent of the filtrate solution was removed under reduced pressure, and the obtained was purified and recrystallized by column chromatography using silica gel to obtain Intermediate 291-3. (yield: 47%)

### (Synthesis of Compound 291)

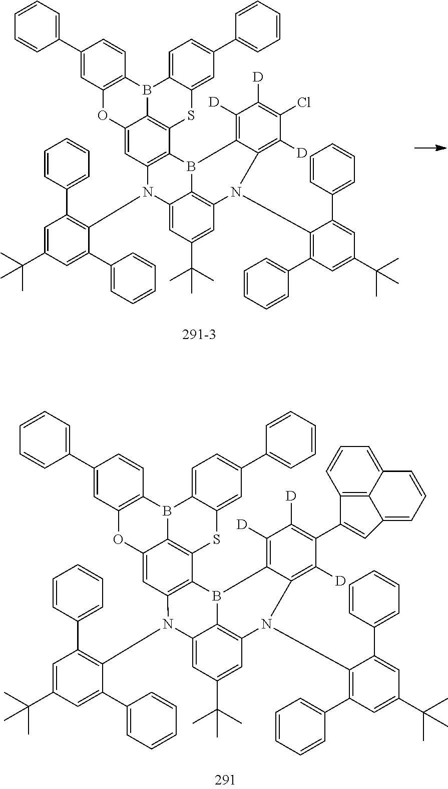

Under a nitrogen atmosphere, Intermediate 291-3 (1 eq), acenaphthylene (1.1 eq), Pd₂(dba)₃ (0.5 eq), tris-tert-butyl phosphine (1 eq), sodium tert-butoxide (4 eq) were added and dissolved in o-xylene, and the reaction solution was stirred at about 140° C. for about one day. After cooling, water and ethyl acetate were added, extraction was performed, and organic layers were collected, dried over MgSO₄, and filtered. The solvent of the filtrate solution was removed under reduced pressure, and the obtained product was purified and recrystallized by column chromatography using silica gel to obtain Compound 291. (yield: 68%)

### 2. Manufacture and Evaluation of Light-Emitting Element

A light-emitting element according to an embodiment including a fused polycyclic compound according to an embodiment in the emission layer was manufactured by the following method. Light-emitting elements according to Example 1 to Example 12 were manufactured with Compounds 4, 54, 192, 226, 260, and 291, which are Example Compounds, as dopant materials for an emission layer. Light-emitting elements according to Comparative Example 1 to Comparative Example 10 correspond to light-emitting elements manufactured by respectively using Comparative Example Compound C1 to Comparative Example Compound C5 as dopant materials for an emission layer.

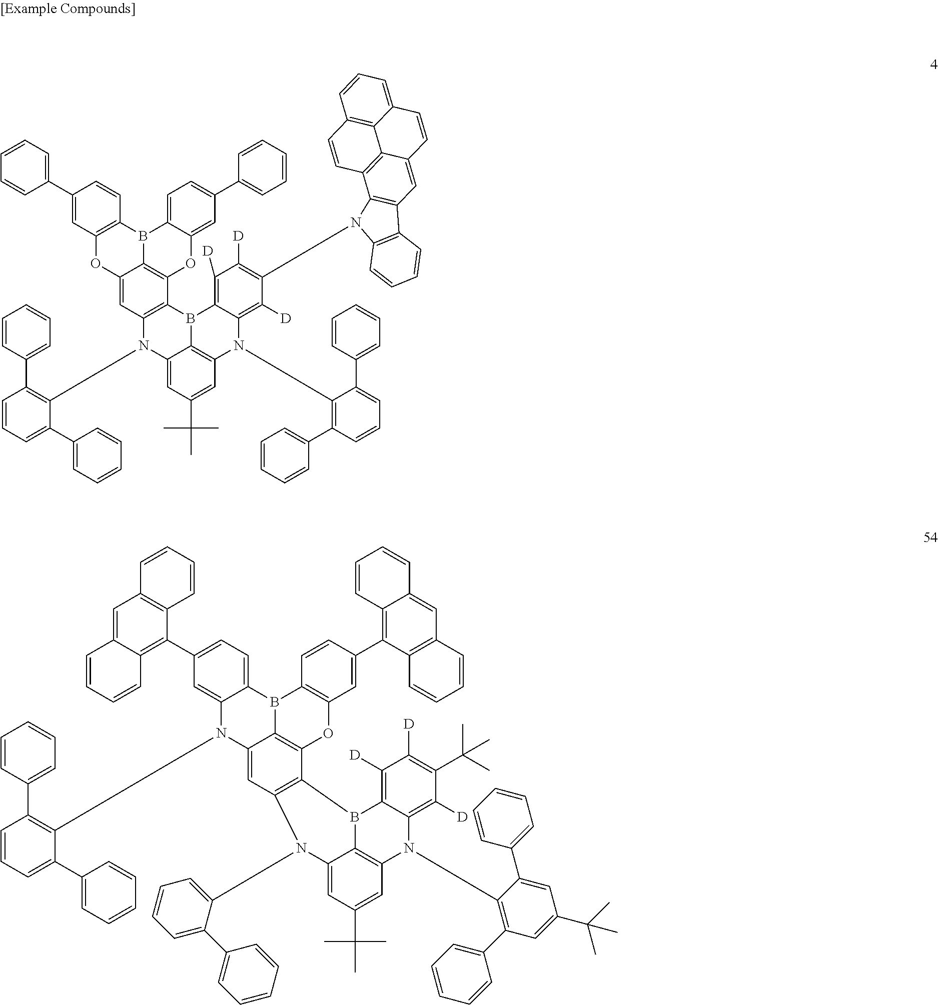 [SMILES: [2H]c1c([2H])c(-n2c3ccccc3c3cc4ccc5cccc6ccc(c4c56)c32)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccccc2)ccc1B4c1ccc(-c2ccccc2)cc1O3 ; [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1]

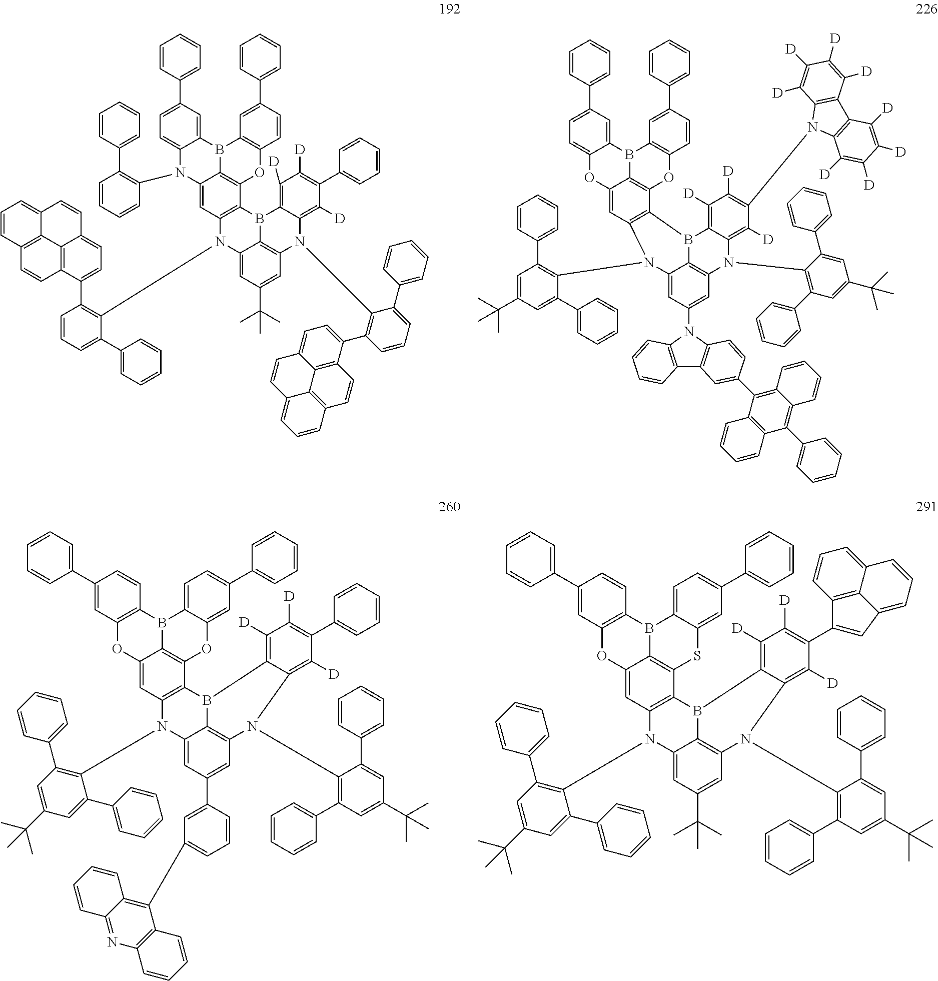

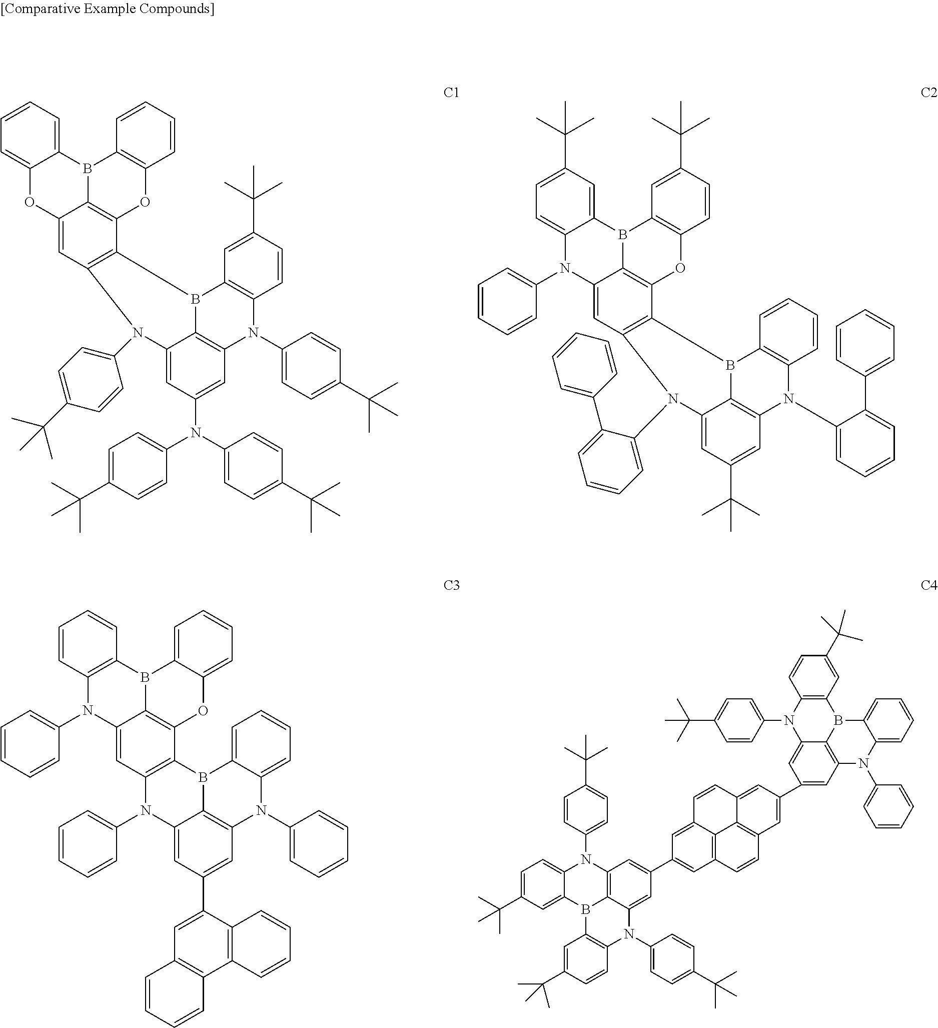

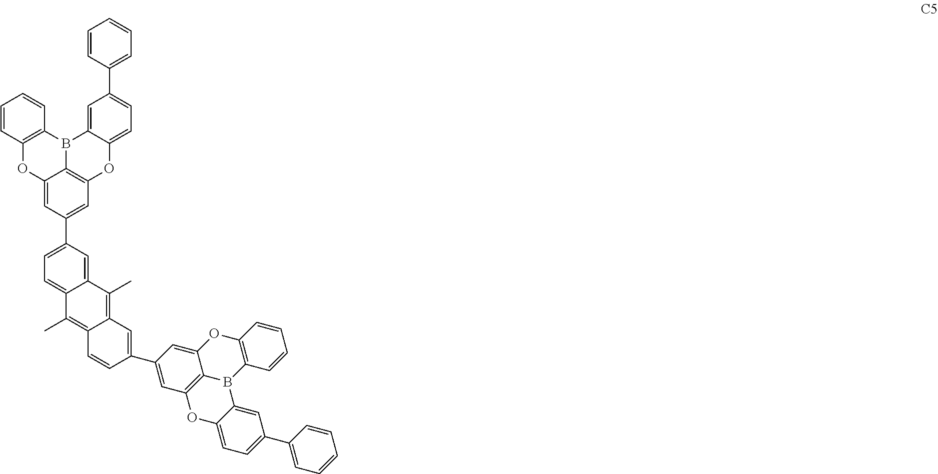 [SMILES: Cc1c2ccc(-c3cc4c5c(c3)Oc3ccc(-c6ccccc6)cc3B5c3ccccc3O4)cc2c(C)c2cc(-c3cc4c5c(c3)Oc3ccc(-c6ccccc6)cc3B5c3ccccc3O4)ccc12]

### (Manufacture of Light-Emitting Element)

In the light-emitting elements according to the Examples and the Comparative Examples, for the formation of an anode, a glass substrate (made by Corning Incorporated), on which 15 Ω/cm² (1,200 Å) of an ITO electrode was formed, was cut to a size of about 50 mm×50 mm×0.7 mm, washed by ultrasonic waves using isopropyl alcohol and pure water for about 5 minutes each, and cleaned by exposure to ultraviolet rays for about 30 minutes and exposure to ozone, and the glass substrate was installed in a vacuum deposition apparatus.

On the anode, NPD was deposited to form a hole injection layer having a thickness of about 300 Å. On the hole injection layer, Compound H-1-1 was deposited to form a hole transport layer having a thickness of about 200 Å. On the hole transport layer, CzSi was deposited to form an electron blocking layer having a thickness of about 100 Å.

A mixed host in which a second compound according to an embodiment and a third compound according to an embodiment were mixed at a ratio of about 1:1, a fourth compound according to an embodiment, and an Example Compound or a Comparative Example Compound were co-deposited at a weight ratio of about 85:14:1 to form an emission layer of about 200 Å. On the emission layer, TSPO1 was deposited to form a hole blocking layer having a thickness of about 200 Å. TBPi was deposited on the hole blocking layer to form an electron transport layer having a thickness of about 300 Å. On the electron transport layer, LiF was deposited to form an electron injection layer having a thickness of about 10 Å. A LiF/Al electrode having thickness of about 3,000 Å was formed as a second electrode on the electron injection layer. On the second electrode, a capping layer was formed by depositing Compound P4 at a thickness of about 700 Å.

Each layer was formed by a vacuum deposition. Compounds HT2 and HT3 from Compound Group 2 were used as the second compound; Compounds ETH66 and ETH86 from Compound Group 3 were used as the third compound; and Compounds AD-37 and AD-38 from Compound Group 4 were used as the fourth compound.

The compounds used in the manufacture of the light-emitting elements according to the Examples and the Comparative Examples are disclosed below. The following materials are used in the manufacture of the light-emitting elements after purification by sublimation of commercially available materials.

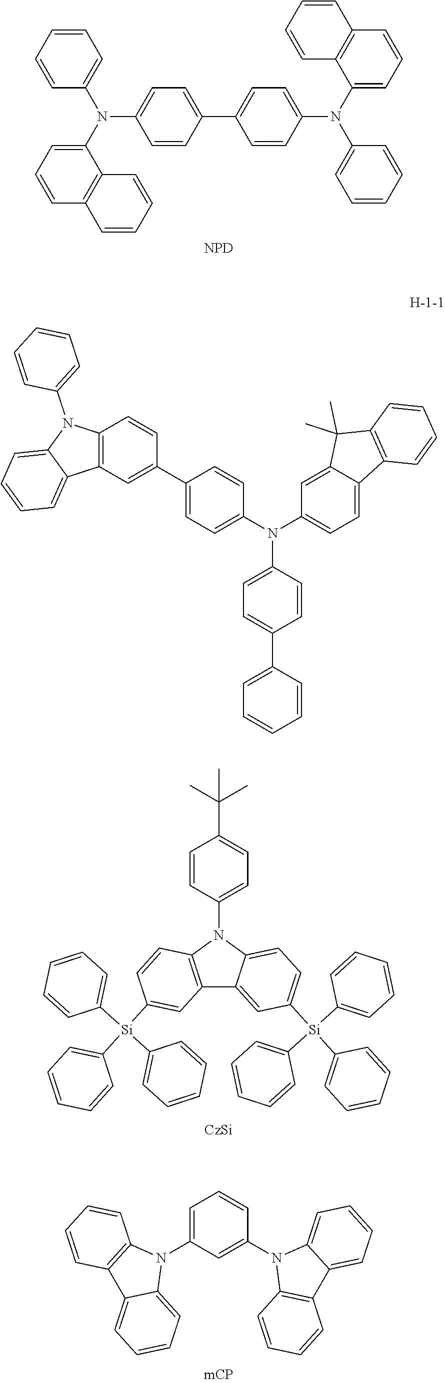

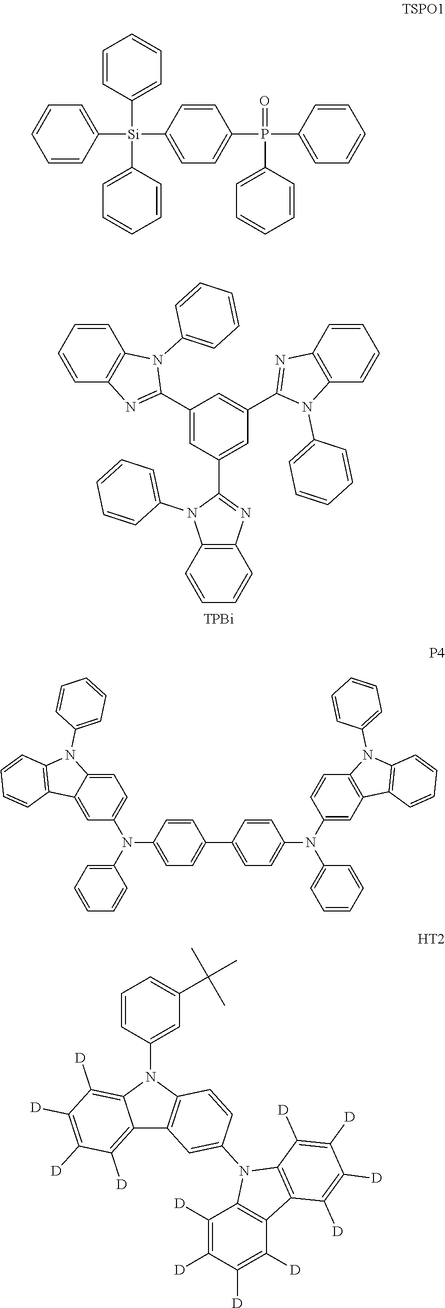

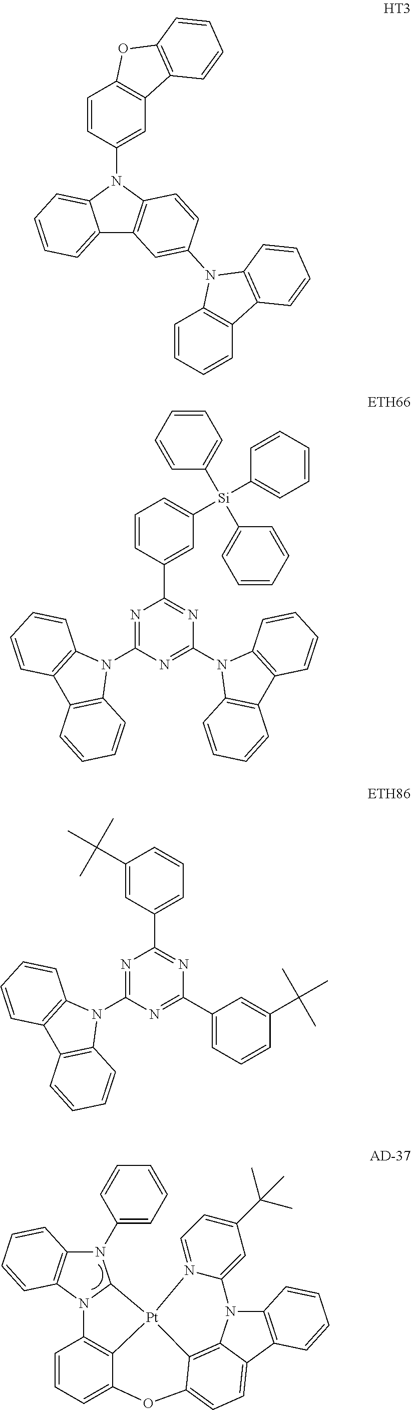

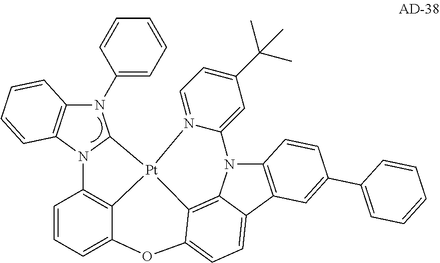

### (Evaluation of Characteristics of Light-Emitting Element)

The light-emitting elements manufactured using Compounds 4, 54, 192, 226, 260, and 291, and Comparative Example Compounds C1 to C5 were evaluated for driving voltage, element efficiency, emission wavelength, and element lifespan. The evaluation results for the light-emitting elements according to Example 1 to Example 12, and Comparative Example 1 to Comparative Example 10 are listed in Table 1. In the results of evaluation of characteristics for the light-emitting elements according to the Examples and the Comparative Examples shown in Table 1, driving voltage and current density were measured using V7000 OLED IVL Test System, (Polaronix). For evaluation of the characteristics of the light-emitting elements manufactured according to Examples 1 to 12 and Comparative Examples 1 to 10, driving voltage and efficiency (cd/A) were measured at a current density of 10 mA/cm². Lifespan (T95) shows a relative element value based on the time for luminance to deteriorate from an initial value to about 95% when continuously driving the light emitting element of Comparative Example 2 at a current density of about 10 mA/cm².

TABLE 1

| | Host | | | | | | |
|---|---|---|---|---|---|---|---|
| | (Second | | | | | | Lifespan |
| | Compound:Third | | | Driving | | | ratio |
| | Compound = | Fourth | First | Voltage | Efficiency | Emission | (%) |
| | 5:5) | Compound | Compound | (%) | (cd/A) | color | (T95) |
| Example 1 | HT2/ETH66 | AD-37 | Compound 4 | 3.7 | 23.8 | blue | 4.7 |
| Example 2 | HT2/ETH66 | AD-37 | Compound 54 | 3.6 | 19.2 | blue | 3.8 |
| Example 3 | HT2/ETH66 | AD-37 | Compound 192 | 3.5 | 22.6 | blue | 4.5 |
| Example 4 | HT2/ETH66 | AD-37 | Compound 226 | 3.6 | 20.1 | blue | 4.1 |
| Example 5 | HT2/ETH66 | AD-37 | Compound 260 | 3.6 | 21.9 | blue | 4.3 |
| Example 6 | HT2/ETH66 | AD-37 | Compound 291 | 3.7 | 23.4 | blue | 4.6 |
| Example 7 | HT3/ETH86 | AD-38 | Compound 4 | 3.5 | 22.6 | blue | 4.5 |
| Example 8 | HT3/ETH86 | AD-38 | Compound 54 | 3.6 | 20.0 | blue | 3.7 |
| Example 9 | HT3/ETH86 | AD-38 | Compound 192 | 3.8 | 22.5 | blue | 4.5 |
| Example 10 | HT3/ETH86 | AD-38 | Compound 226 | 3.8 | 21.4 | blue | 3.9 |
| Example 11 | HT3/ETH86 | AD-38 | Compound 260 | 3.7 | 22.1 | blue | 4.1 |
| Example 12 | HT3/ETH86 | AD-38 | Compound 291 | 3.7 | 21.8 | blue | 4.4 |
| Comparative | HT2/ETH66 | AD-37 | Comparative | 4.3 | 11.6 | blue | 0.7 |
| Example 1 | | | Example | | | | |
| | | | Compound C1 | | | | |
| Comparative | HT2/ETH66 | AD-37 | Comparative | 4.0 | 13.3 | blue | 1.0 |
| Example 2 | | | Example | | | | |
| | | | Compound C2 | | | | |
| Comparative | HT3/ETH86 | AD-37 | Comparative | 4.4 | 12.3 | blue | 0.6 |
| Example 3 | | | Example | | | | |
| | | | Compound C3 | | | | |
| Comparative | HT3/ETH86 | AD-37 | Comparative | 5.2 | 4.5 | blue | 0.3 |
| Example 4 | | | Example | | | | |
| | | | Compound C4 | | | | |
| Comparative | HT3/ETH86 | AD-37 | Comparative | 5.0 | 4.1 | blue | 0.2 |
| Example 5 | | | Example | | | | |
| | | | Compound C5 | | | | |
| Comparative | HT3/ETH86 | AD-38 | Comparative | 4.4 | 12.1 | blue | 0.7 |
| Example 6 | | | Example | | | | |
| | | | Compound C1 | | | | |
| Comparative | HT3/ETH86 | AD-38 | Comparative | 4.3 | 13.7 | blue | 1.0 |
| Example 7 | | | Example | | | | |
| | | | Compound C2 | | | | |
| Comparative | HT3/ETH86 | AD-38 | Comparative | 4.4 | 11.8 | blue | 0.5 |
| Example 8 | | | Example | | | | |
| | | | Compound C3 | | | | |
| Comparative | HT3/ETH86 | AD-38 | Comparative | 5.3 | 4.0 | blue | 0.2 |
| Example 9 | | | Example | | | | |
| | | | Compound C4 | | | | |
| Comparative | HT3/ETH86 | AD-38 | Comparative | 5.2 | 3.6 | blue | 0.2 |
| Example 10 | | | Example | | | | |
| | | | Compound C5 | | | | |

Referring to Table 1, it can be confirmed that the light-emitting elements according to the Examples, which use the fused polycyclic compound according to an embodiment as emission materials, have improved characteristics of luminous efficiency and lifespan, as compared to the light-emitting elements according to the Comparative Examples. The fused polycyclic compound according to embodiments may have a fused structure of two aromatic hydrocarbon rings to a specific position of a fused ring core via a boron atom and two heteroatoms and include at least one first substituent, and thus improvements in high efficiency and long lifespan may be achieved. The fused polycyclic compound according to embodiments includes a first substituent including a first sub substituent having a lowest excited triplet energy level equal to or less than about 2.0 eV, and thus characteristics of high efficiency and long lifespan may be exhibited. Since the fused polycyclic compound according to an embodiment includes the first substituent, characteristics in that the lowest excited triplet energy level is low may be shown and the accumulation of triplet excitons within a molecule is prevented, thereby achieving improved lifespan. The light-emitting element according to an embodiment includes the fused polycyclic compound according to an embodiment as an emission dopant of a thermally activated delayed fluorescence (TADF) light-emitting element, and thus high element efficiency and improved lifespan characteristics may be achieved in a blue light wavelength region.

The light-emitting elements according to Comparative Examples 1 to 3 and 6 to 8 exhibit results in that element lifespan and efficiency thereof are lower than the light-emitting elements according to the Examples. Each of Comparative Example Compounds C1 to C3 contained in the light-emitting elements according to Comparative Examples 1 to 3 and 6 to 8 includes a fused ring core that includes a boron atom and two nitrogen atoms, and two benzene rings are further fused to the fused ring core via a boron atom and two heteroatoms. However, since, in a fused skeleton of each of Comparative Example Compounds C1 to C3, the first substituent according to embodiments is not included, it can be confirmed that when the Comparative Example Compounds are applied to the element, the light-emitting element has reduced luminous efficiency and lifespan compared to the light-emitting element according to the Examples. By comparison, it can be confirmed that since the Example Compounds include an anthracene group, a pyrene group an acenaphthene group, or an acridine group as a first substituent, degradation caused by triplet-triplet annihilation (TTA) or triplet-polaron quenching (TPQ) is reduced, thereby imparting characteristics high efficiency and long lifespan.

Comparative Example Compound C3 corresponds to a compound including a phenanthrene group as a substituent. A lowest excited triplet energy level (T1 level) of the phenanthrene group is about 2.68 eV, which is higher than the lowest excited triplet energy level (T1 level) of the first substituent according to embodiments. Therefore, when the phenanthrene group is included as a substituent of the fused ring core, an effect such as prevention of the accumulation of the triplet excitons, as previously described, may not be exhibited, and thus efficiency and lifespan characteristics of the light-emitting elements are reduced, as compared to the light-emitting elements that include an Example Compound.

The light-emitting elements according to Comparative Examples 4, 5, 9, and 10 exhibit results in that element lifespan and efficiency thereof are lower than the light-emitting elements according to the Examples. Each of Comparative Example Compounds C4 and C5 included in the light-emitting elements according to Comparative Examples 4, 5, 9, and 10 includes a pyrene or an anthracene as a substituent but has a fused structure that is different from the Example Compounds. Each of Comparative Example Compounds C4 and C5 includes a dimer structure in which two fused ring cores that each include a boron atom are connected to each other via a pyrene moiety or an anthracene moiety. In the case of a compound in which two fused ring cores are merely connected to each other via a substituent, such as Comparative Example Compounds C4 and C5, such a compound lacks a steric advantage that appears in a diboron compound, such as the Example Compounds that form a single fused structure centered on two boron atoms. A compound having such a structure has lower stability in its own molecular structure than the Example Compounds, which decreases efficiency and lifespan.

The light-emitting element according to an embodiment may exhibit improved element characteristics of high efficiency and long lifespan.

The fused polycyclic compound according to an embodiment is included in the emission layer and thus may contribute to improvements in high efficiency and long lifespan of the light-emitting element.

The display device according to an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first electrode;
a second electrode disposed on the first electrode; and
an emission layer disposed between the first electrode and the second electrode, wherein
the emission layer includes a first compound represented by Formula 1: 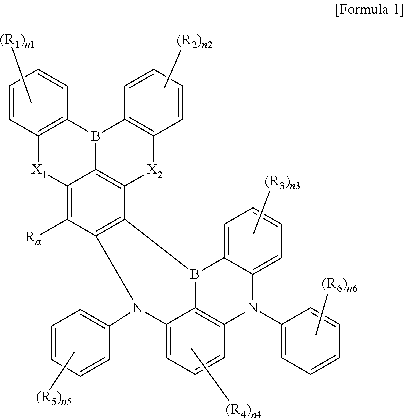
wherein in Formula 1,
X₁ is O, S, Se, or a moiety represented by Formula 2, and
X₂ is O, S, Se, or N(R₈); 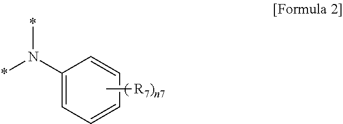
wherein in Formula 1 and Formula 2,
Rₐ and R₁ to R₇ are each independently a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
R₈ is a substituted or unsubstituted aryl group having 6 to 30 ring-forming carbons or a substituted or unsubstituted heteroaryl group having 2 to 30 ring-forming carbons,
at least one of R₁ to R₇ each independently includes a substituted or unsubstituted anthracene group, a substituted or unsubstituted pyrene group, a substituted or unsubstituted acenaphthyl group, or a substituted or unsubstituted acridine group,
n1 to n3 are each independently an integer from 0 to 4,
n4 is an integer from 0 to 3, and
n5 to n7 are each independently an integer from 0 to 5, and
wherein in Formula 2,
-* represents a bond to Formula 1.

2. The light-emitting element of claim 1, wherein in Formula 1, at least one of R₁ to R₇ is each independently a group represented by Formula 3-1 or Formula 3-2: 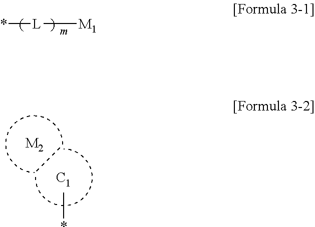
wherein in Formula 3-1 and Formula 3-2,
M₁ a substituted or unsubstituted anthracene group, a substituted or unsubstituted pyrene group, a substituted or unsubstituted acenaphthyl group, or a substituted or unsubstituted acridine group,
L is a direct linkage, a substituted or unsubstituted arylene group having 6 to 30 ring-forming carbons, or a substituted or unsubstituted heteroarylene group having 2 to 30 ring-forming carbons,
m is an integer from 1 to 3,
M₂ is a substituted or unsubstituted anthracene ring, a substituted or unsubstituted pyrene ring, a substituted or unsubstituted acenaphthyl ring, or a substituted or unsubstituted acridine ring,
C₁ is a substituted or unsubstituted aromatic hydrocarbon ring having 6 to 30 ring-forming carbons or a substituted or unsubstituted aromatic heterocycle having 2 to 30 ring-forming carbons, and
-* represents a bond to Formula 1.

3. The light-emitting element of claim 2, wherein in Formula 3-1, L is a direct linkage, a substituted or unsubstituted phenylene group, or a substituted or unsubstituted divalent carbazole group.

4. The light-emitting element of claim 1, wherein in Formula 1, at least one of R₁ to R₇ is each independently a group represented by one of Formula 4-1 to Formula 4-5: 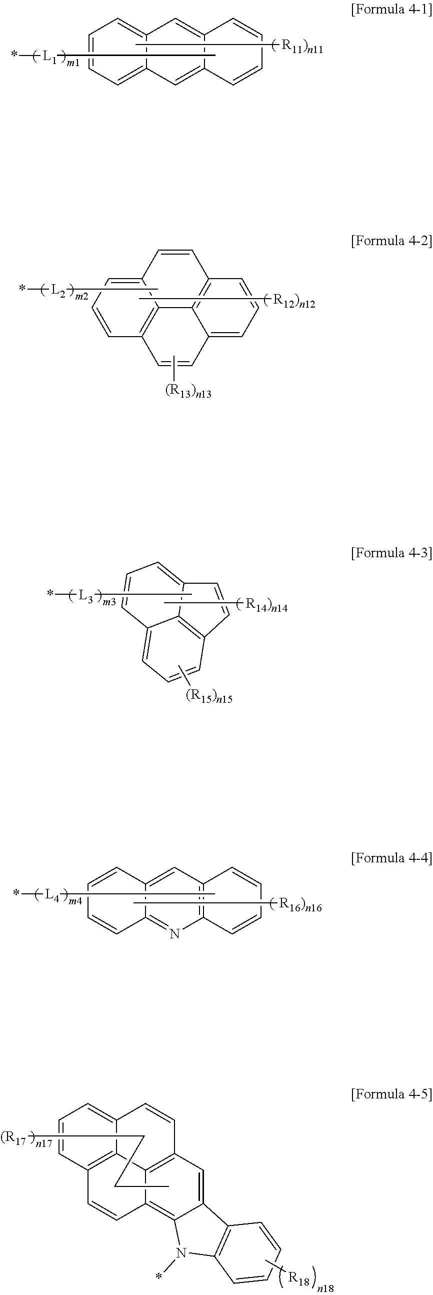
wherein in Formula 4-1 to Formula 4-5,
L₁ to L₄ are each independently a direct linkage, a substituted or unsubstituted arylene group having 6 to 30 ring-forming carbons, or a substituted or unsubstituted heteroarylene group having 2 to 30 ring-forming carbons,
R₁₁ to R₁₈ are each independently a hydrogen atom, a deuterium atom, a halogen atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons,
m1 to m4 are each independently an integer from 1 to 3,
n11 is an integer from 0 to 9,
n12 is an integer from 0 to 7,
n13 is an integer from 0 to 2,
n14 and n18 are each independently an integer from 0 to 4,
n15 is an integer from 0 to 3,
n16 and n17 are each independently an integer from 0 to 8, and
-* represents a bond to Formula 1.

5. The light-emitting element of claim 1, wherein the first compound is represented by Formula 5-1 or Formula 5-2: 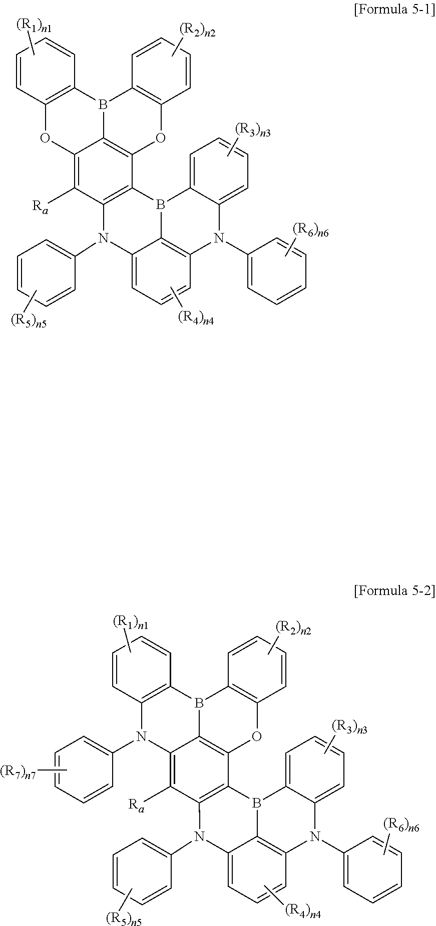
wherein in Formula 5-1 and Formula 5-2,
Rₐ, R₁ to R₇, and n1 to n7 are the same as defined in Formula 1.

6. The light-emitting element of claim 1, wherein the first compound is represented by Formula 6-1 or Formula 6-2: 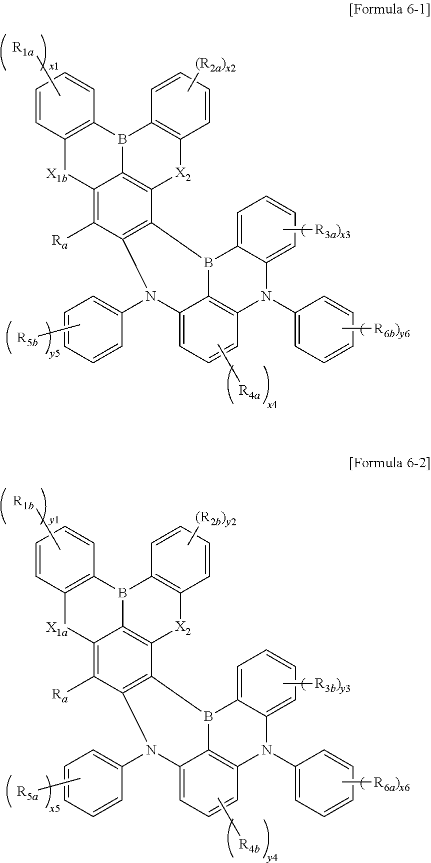
wherein in Formula 6-1 and Formula 6-2,
X₁ₐ is O, S, Se, or a moiety represented by Formula 2-a, and
X_{1b} is O, S, Se, or a moiety represented by Formula 2-b: 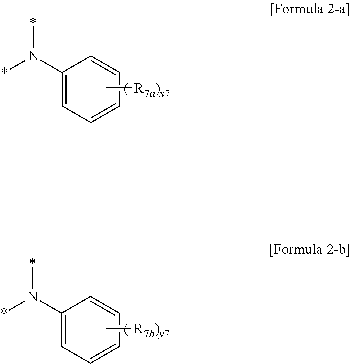
wherein in Formula 6-1, Formula 6-2, Formula 2-a, and Formula 2-b,
R₁ₐ to R₇ₐ and R_{1b} to R_{7b} are each independently a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
x1 to x3 and y1 to y3 are each independently an integer from 0 to 4,
x4 and y4 are each independently an integer from 0 to 3,
x5 to x7 and y5 to y7 are each independently an integer from 0 to 5, and
-* represents a bond to Formula 1,
wherein in Formula 6-1,
at least one of R₁ₐ to R₄ₐ each independently comprises a substituted or unsubstituted anthracene group, a substituted or unsubstituted pyrene group, a substituted or unsubstituted acenaphthyl group, or a substituted or unsubstituted acridine group,
wherein in Formula 6-2,
at least one of R₅ₐ to R₇ₐ each independently comprises a substituted or unsubstituted anthracene group, a substituted or unsubstituted pyrene group, a substituted or unsubstituted acenaphthyl group, or a substituted or unsubstituted acridine group, and
wherein in Formula 6-1 and Formula 6-2,
Rₐ and X₂ are the same as defined in Formula 1.

7. The light-emitting element of claim 1, wherein the first compound is represented by Formula 7-1 or Formula 7-2: 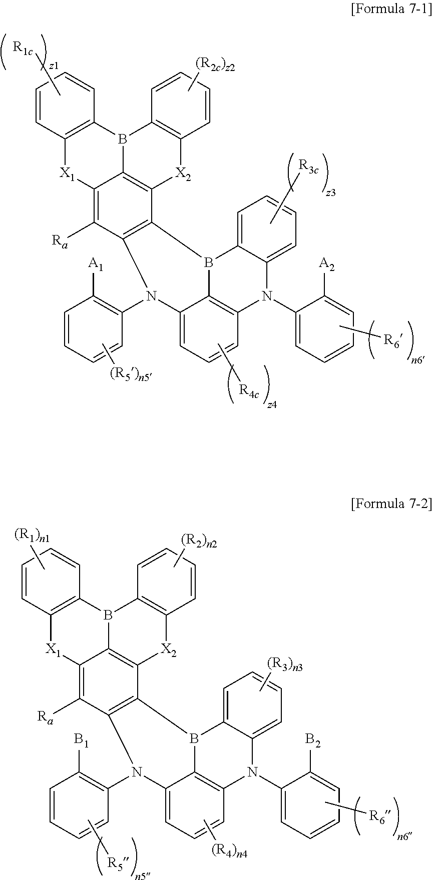
wherein in Formula 7-1 and Formula 7-2,
R_{1c} to R_{4c}, R₅′, R₆′, R₅″, and R₆″ are each independently a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
z1 to z3, n5′, n6′, n5″, and n6″ are each independently an integer from 0 to 4,
z4 is an integer from 0 to 3,
at least one of R_{1c} to R_{4c} is each independently a group represented by Formula 3-1 or Formula 3-2,
A₁ and A₂ are each independently a substituted or unsubstituted aryl group having 6 to 30 ring-forming carbons or a substituted or unsubstituted heteroaryl group having 2 to 30 ring-forming carbons,
at least one of B₁ and B₂ is each independently a group represented by Formula 3-1 or Formula 3-2, and
the remainder of B₁ and B₂ is a substituted or unsubstituted aryl group having 6 to 30 ring-forming carbons or a substituted or unsubstituted heteroaryl group having 2 to 30 ring-forming carbons: 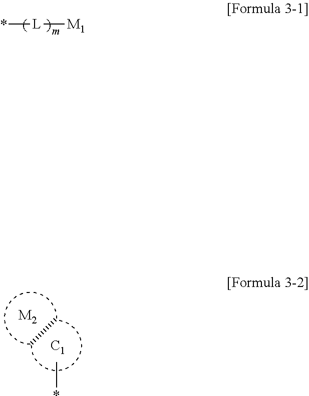
wherein in Formula 3-1 and Formula 3-2,
M₁ is a substituted or unsubstituted anthracene group, a substituted or unsubstituted pyrene group, a substituted or unsubstituted acenaphthyl group, or a substituted or unsubstituted acridine group,
L is a direct linkage, a substituted or unsubstituted arylene group having 6 to 30 ring-forming carbons, or a substituted or unsubstituted heteroarylene group having 2 to 30 ring-forming carbons
m is an integer from 0 to 3,
M₂ is a substituted or unsubstituted anthracene ring, a substituted or unsubstituted pyrene ring, a substituted or unsubstituted acenaphthyl ring, or a substituted or unsubstituted acridine ring,
C₁ is a substituted or unsubstituted aromatic hydrocarbon ring having 6 to 30 ring-forming carbons or a substituted or unsubstituted aromatic heterocycle having 2 to 30 ring-forming carbons, and
-* represents a bond to Formula 1, and
wherein in Formula 7-1 and Formula 7-2,
X₁, X₂, Rₐ, R₁ to R₄, and n1 to n4 are the same as defined in Formula 1.

8. The light-emitting element of claim 1, wherein the first compound is represented by one of Formula 8-1 to Formula 8-3: 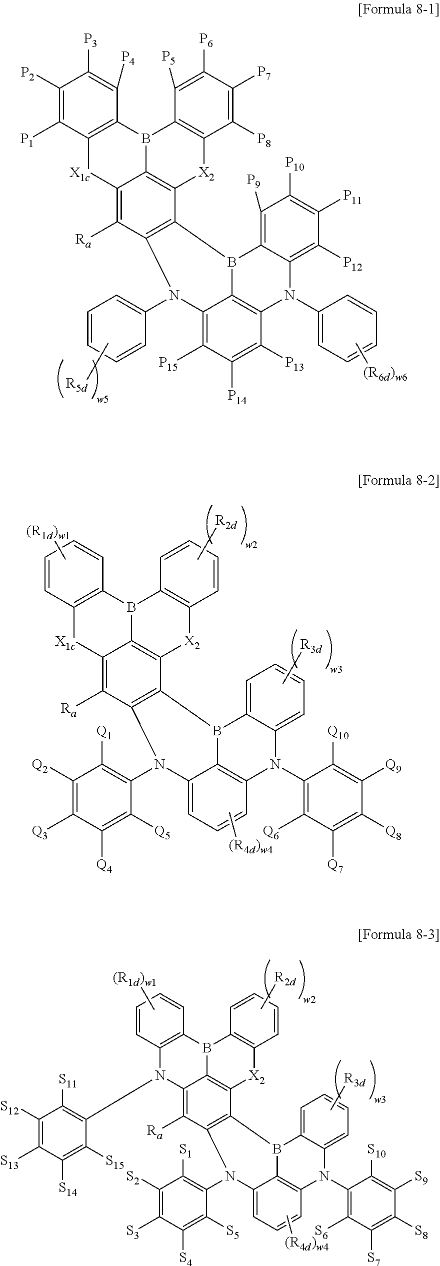
wherein in Formula 8-1 to Formula 8-3,
X_{1c} is O, S, or Se,
R_{1d} to R_{6d} are each independently a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
w1 to w3 are each independently an integer from 0 to 4,
w4 is an integer from 0 to 3, and
w5 and w6 are each independently an integer from 0 to 5,
wherein in Formula 8-1,
at least one of P₁ to P₁₅ is each independently a group represented by one of Formula 4-1 to Formula 4-5, and
the remainder of P₁ to P₁₅ are each independently a hydrogen atom, a deuterium atom, a substituted or unsubstituted t-butyl group, a substituted or unsubstituted phenyl group, a substituted or unsubstituted biphenyl group, or a substituted or unsubstituted carbazole group,
wherein in Formula 8-2,
at least one of Q₁ to Q₁₀ is each independently a group represented by one of Formula 4-1 to Formula 4-5, and
the remainder of Q₁ to Q₁₀ are each independently a hydrogen atom, a deuterium atom, a substituted or unsubstituted t-butyl group, a substituted or unsubstituted phenyl group, a substituted or unsubstituted biphenyl group, or a substituted or unsubstituted carbazole group,
wherein in Formula 8-3,
at least one of S₁ to S₁₅ is each independently a group represented by one of Formula 4-1 to Formula 4-5, and
the remainder of S₁ to S₁₅ are each independently a hydrogen atom, a deuterium atom, a substituted or unsubstituted t-butyl group, a substituted or unsubstituted phenyl group, a substituted or unsubstituted biphenyl group, or a substituted or unsubstituted carbazole group; 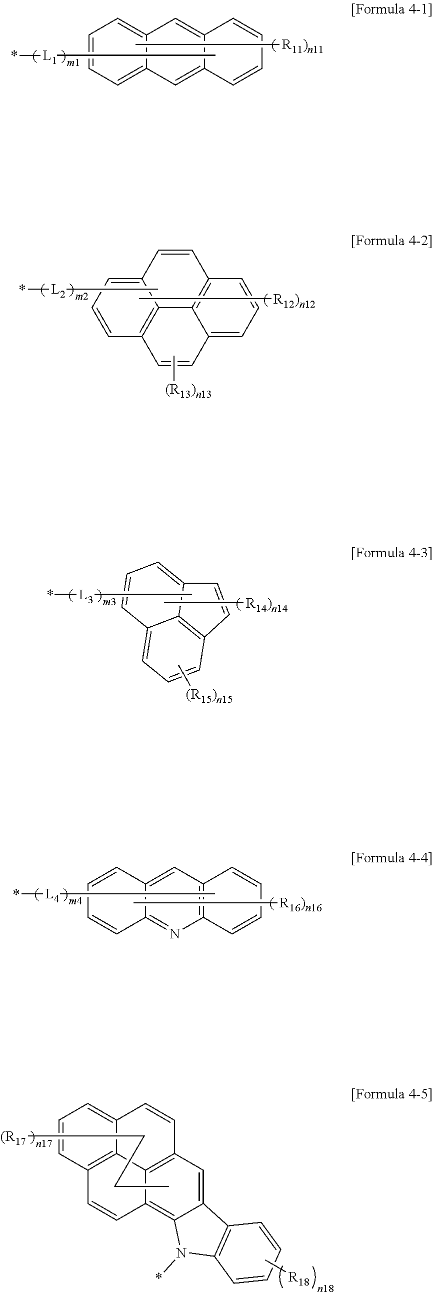
wherein in Formula 4-1 to Formula 4-5,
L₁ to L₄ are each independently a direct linkage, a substituted or unsubstituted arylene group having 6 to 30 ring-forming carbons, or a substituted or unsubstituted heteroarylene group having 2 to 30 ring-forming carbons,
R₁₁ to R₁₈ are each independently a hydrogen atom, a deuterium atom, a halogen atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons,
m1 to m4 are each independently an integer from 1 to 3,
n11 is an integer from 0 to 9,
n12 is an integer from 0 to 7,
n13 is an integer from 0 to 2,
n14 and n18 are each independently an integer from 0 to 4,
n15 is an integer from 0 to 3,
n16 and n17 are each independently an integer from 0 to 8, and
-* represents a bond to Formula 1, and
wherein in Formula 8-1 to Formula 8-3,
Rₐ and X₂ are the same as defined in Formula 1.

9. The light-emitting element of claim 1, wherein the first compound includes at least one compound selected from Compound Group 1:

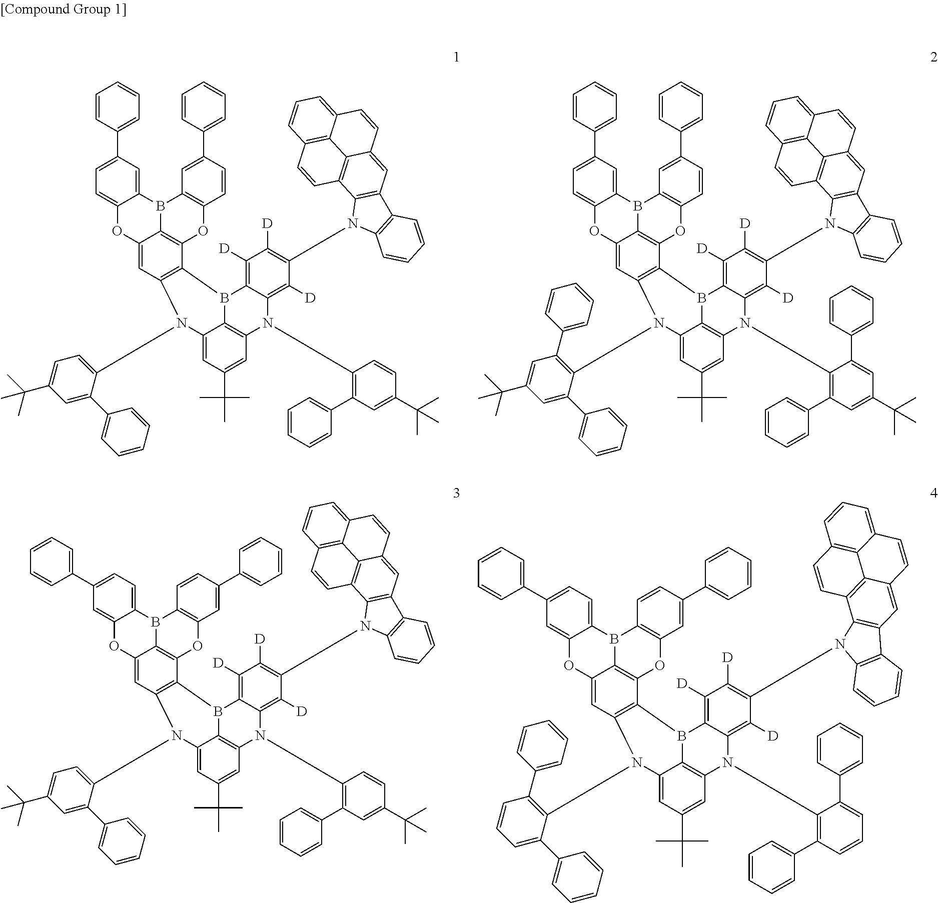

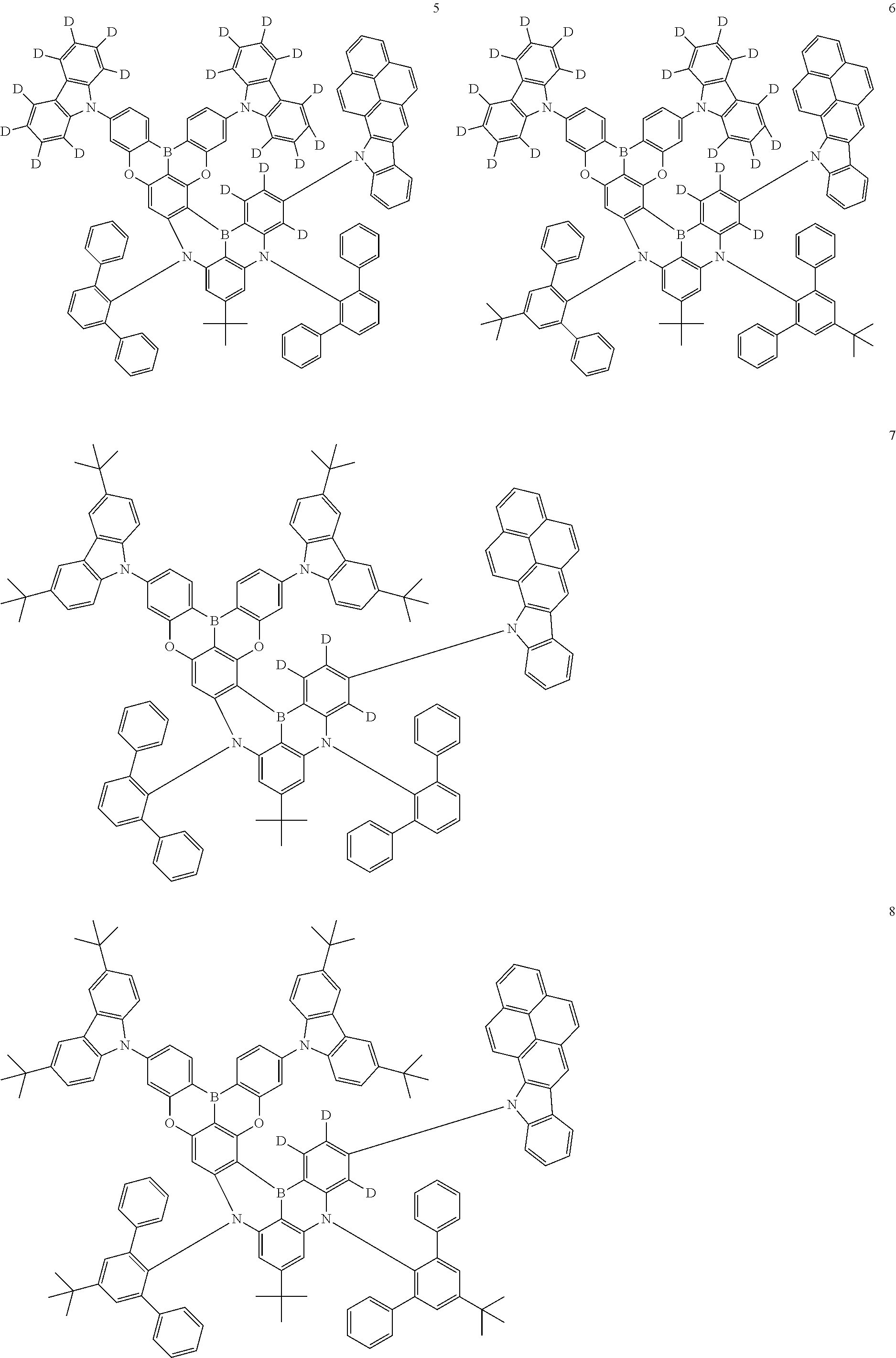

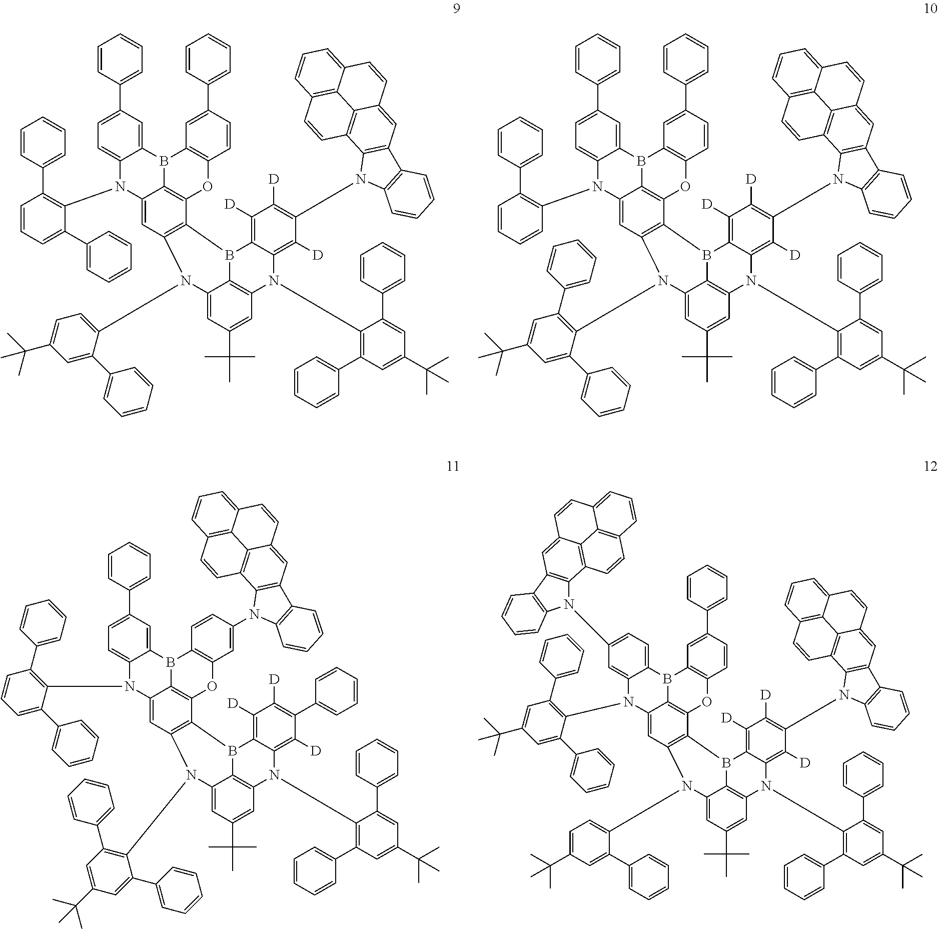

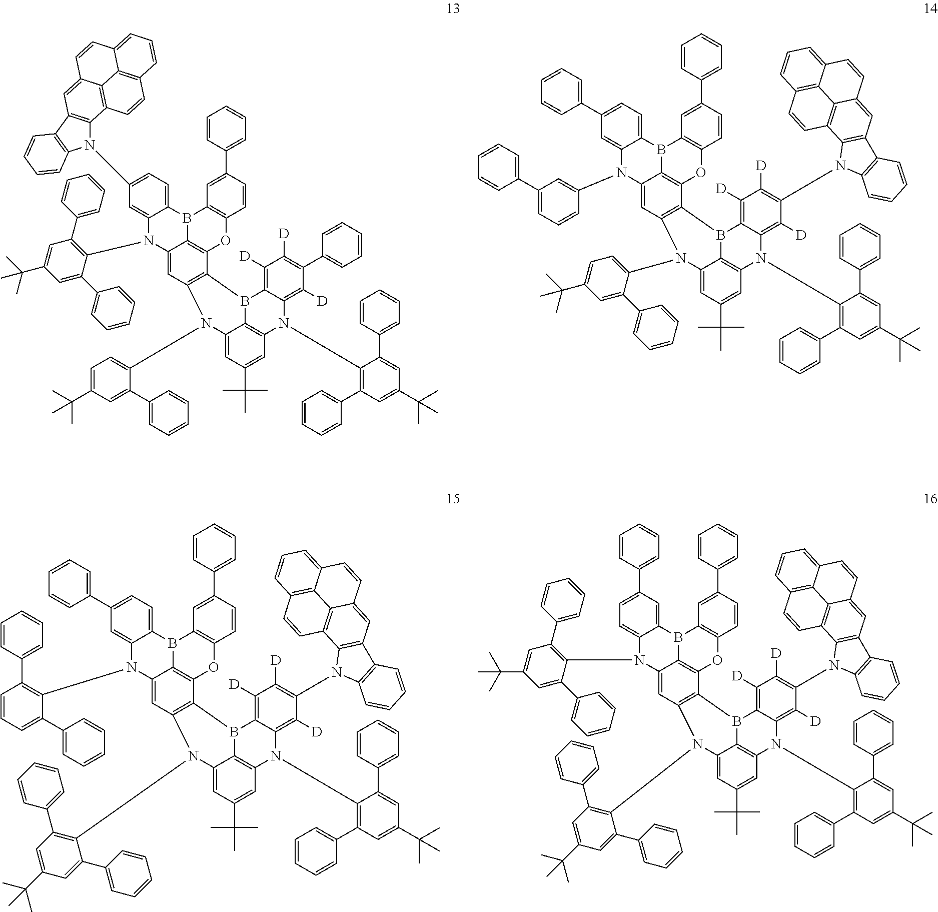

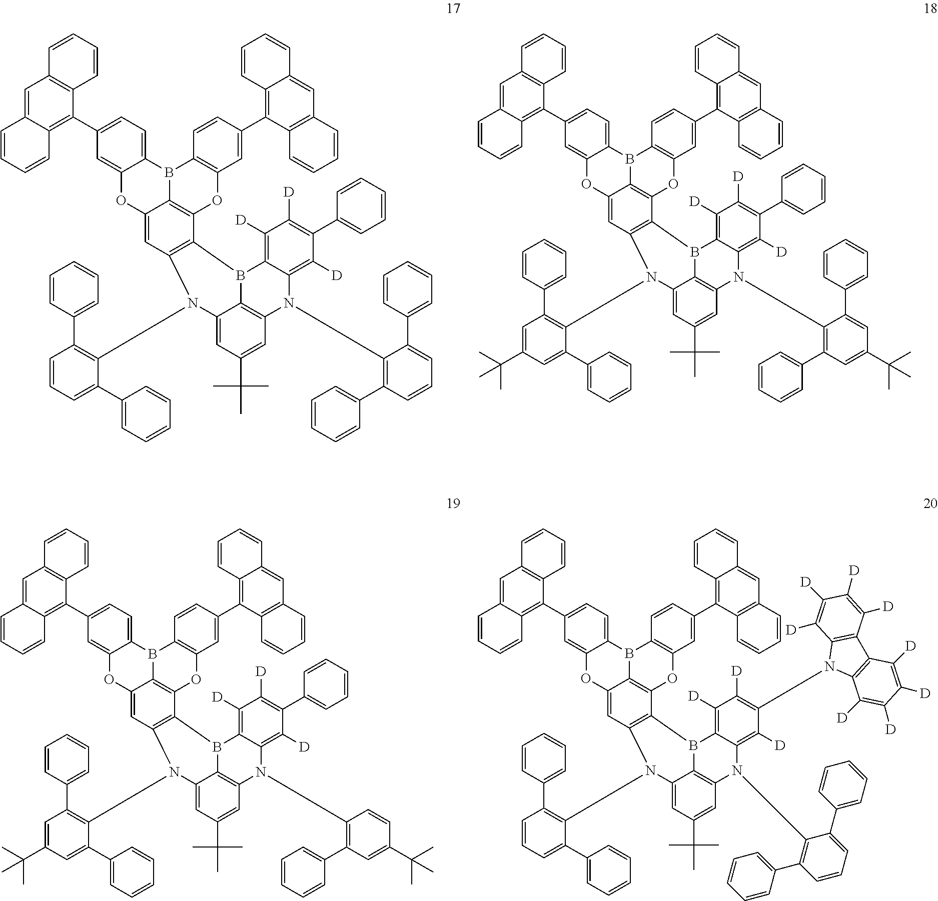

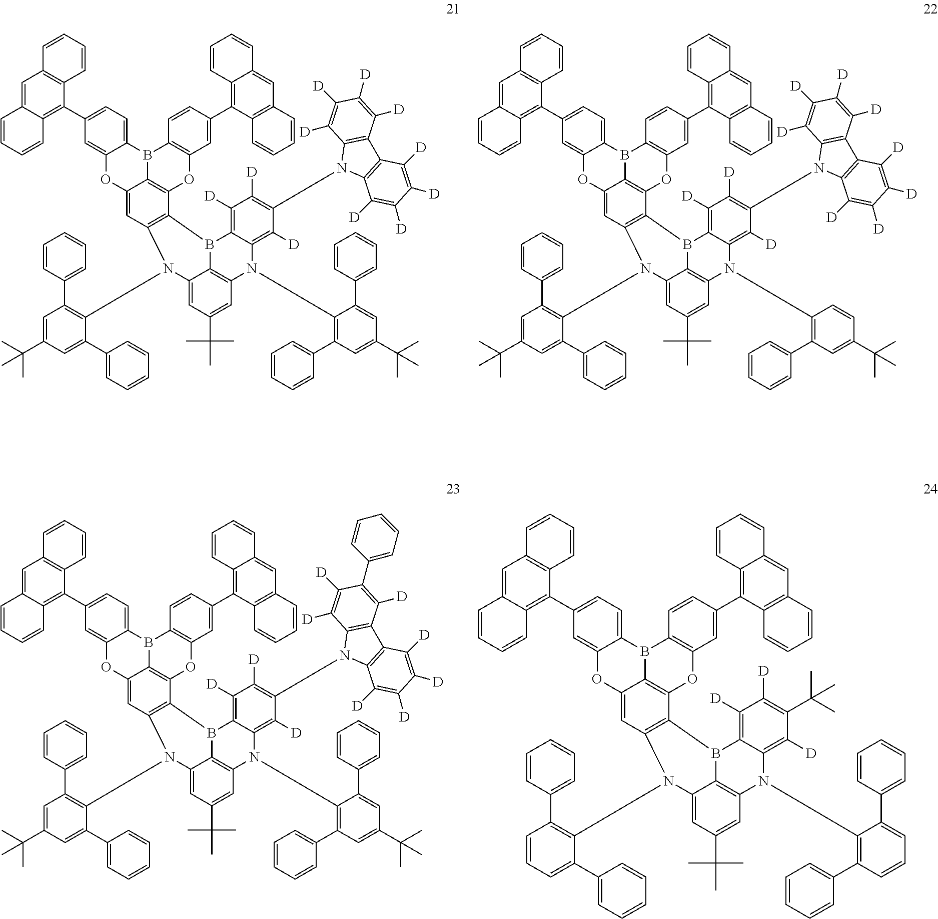

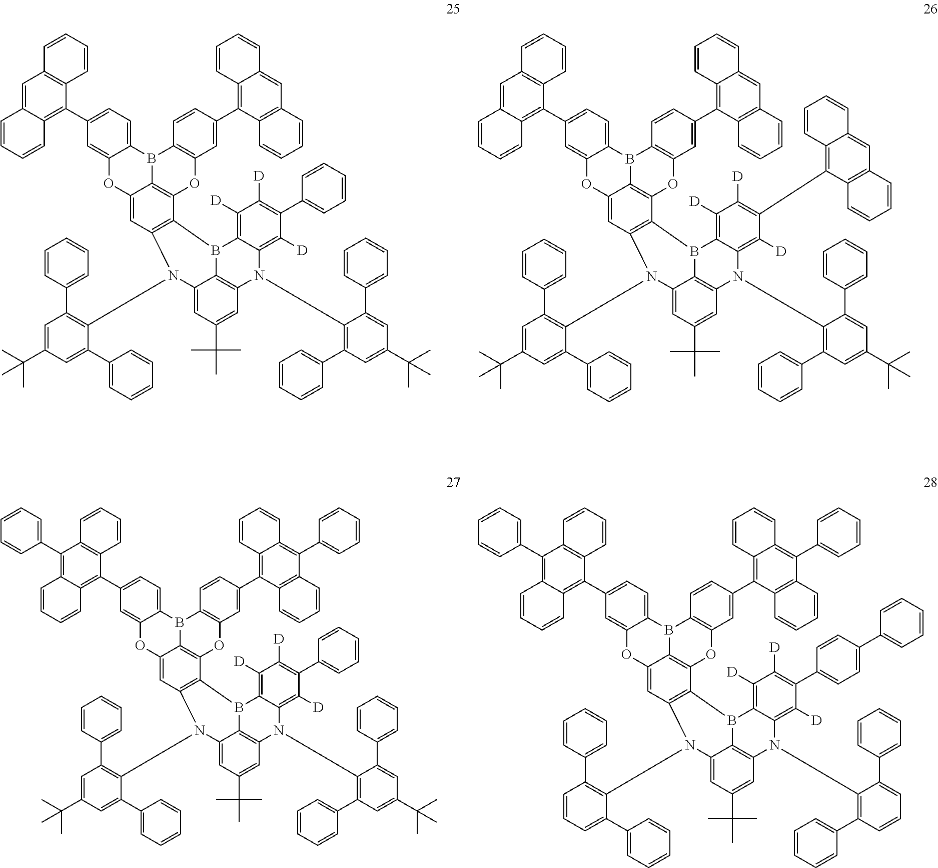

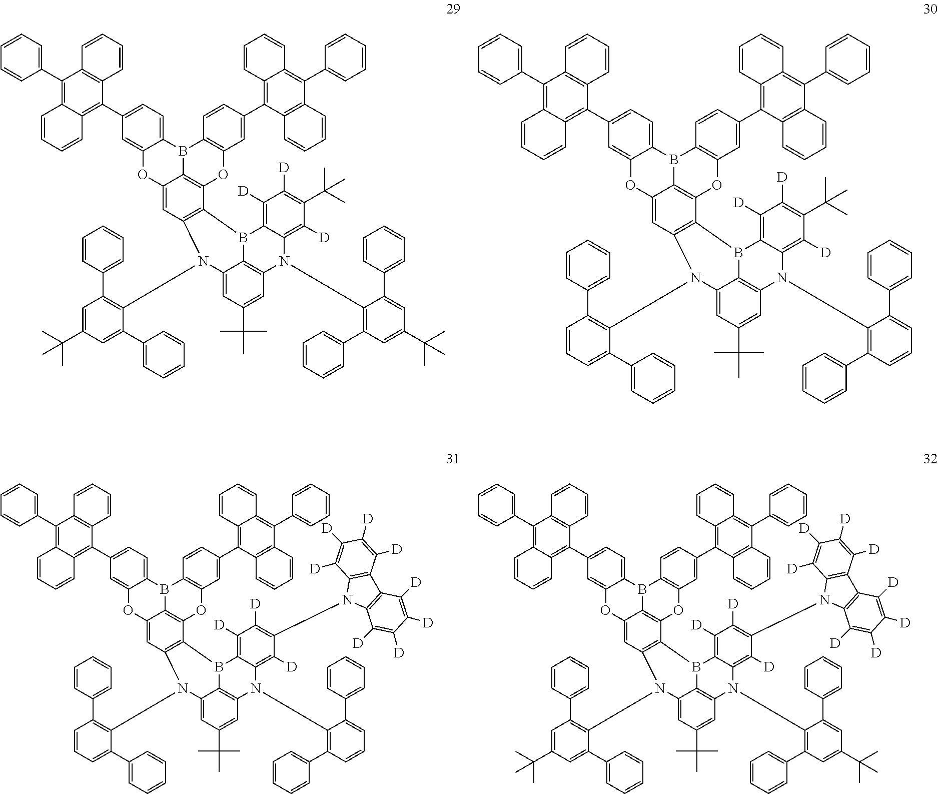

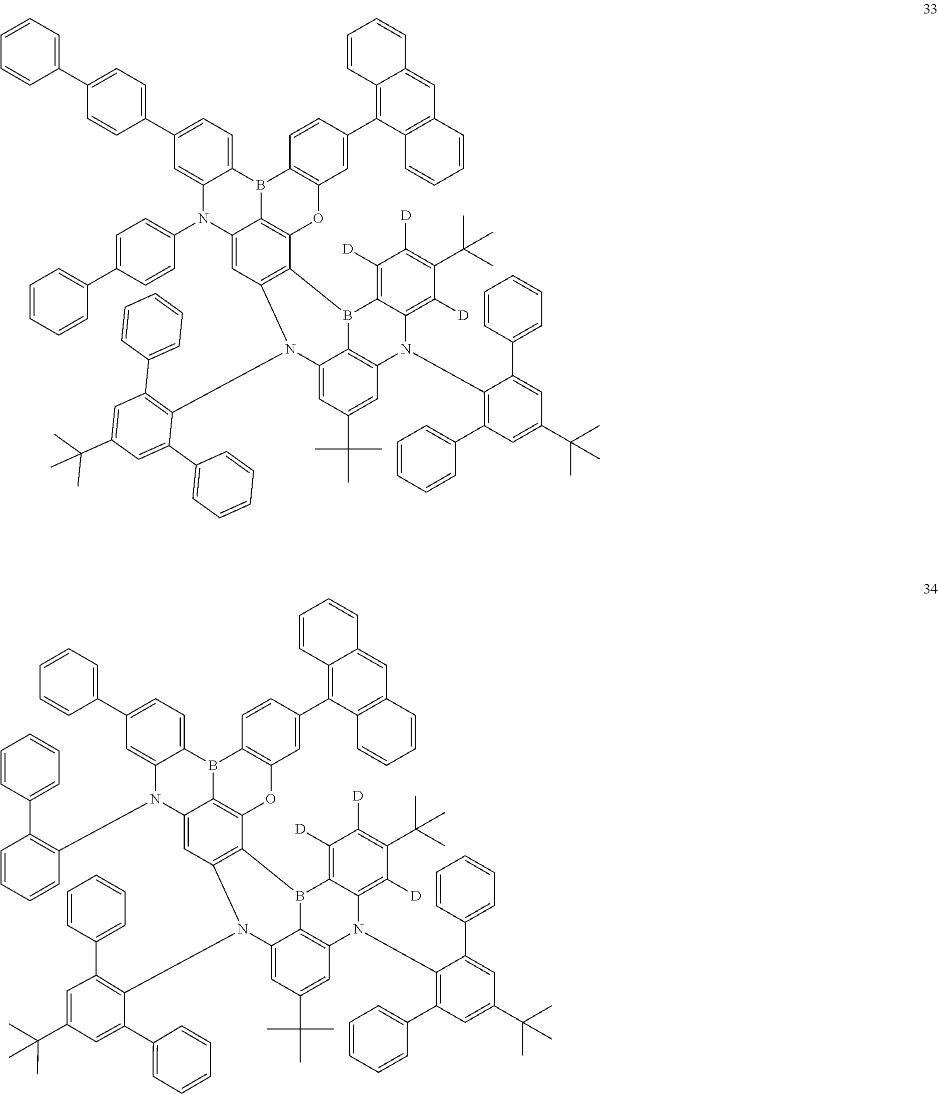 [SMILES: [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2c5ccccc5cc5ccccc25)ccc1B4c1ccc(-c2ccc(-c4ccccc4)cc2)cc1N3c1ccc(-c2ccccc2)cc1 ; [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2c5ccccc5cc5ccccc25)ccc1B4c1ccc(-c2ccccc2)cc1N3c1ccccc1-c1ccccc1]

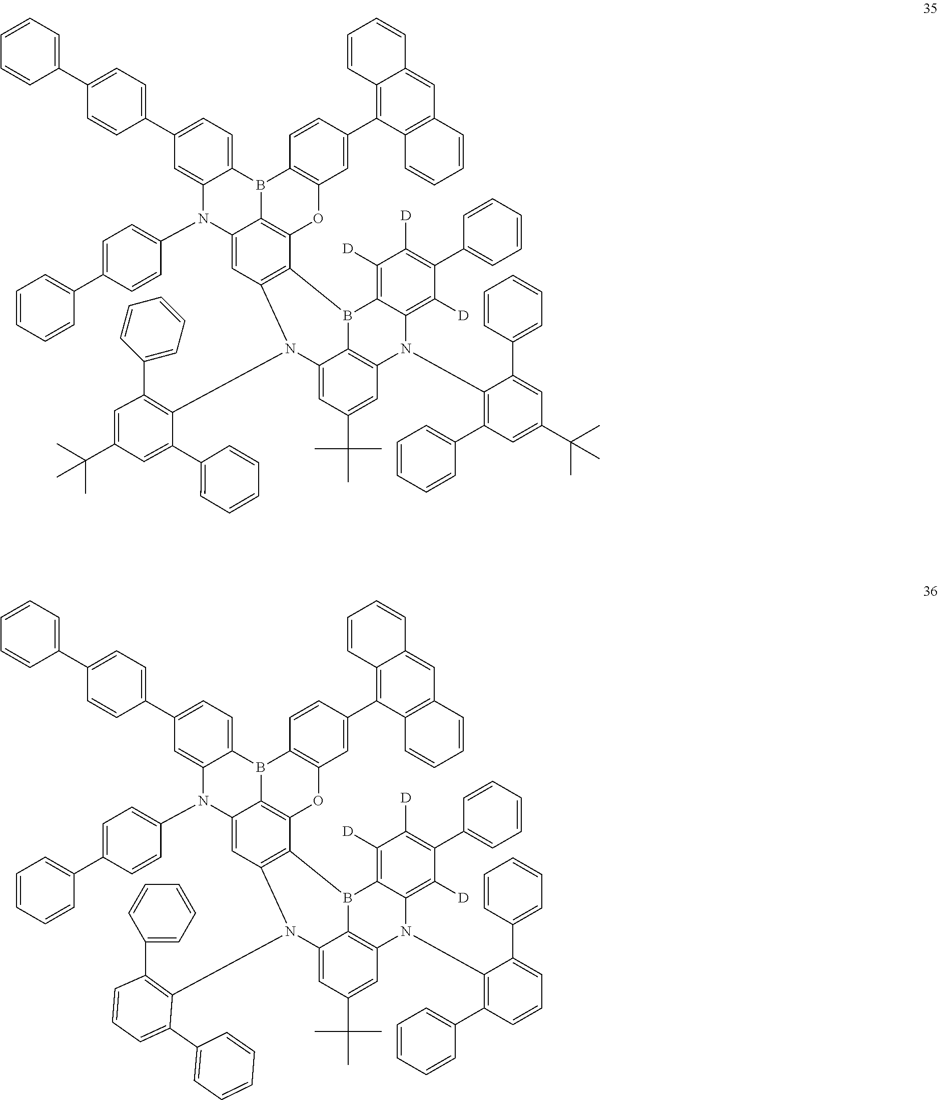 [SMILES: [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2c5ccccc5cc5ccccc25)ccc1B4c1ccc(-c2ccc(-c4ccccc4)cc2)cc1N3c1ccc(-c2ccccc2)cc1 ; [2H]c1c([2H])c(-c2ccccc2)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2c5ccccc5cc5ccccc25)ccc1B4c1ccc(-c2ccc(-c4ccccc4)cc2)cc1N3c1ccc(-c2ccccc2)cc1]

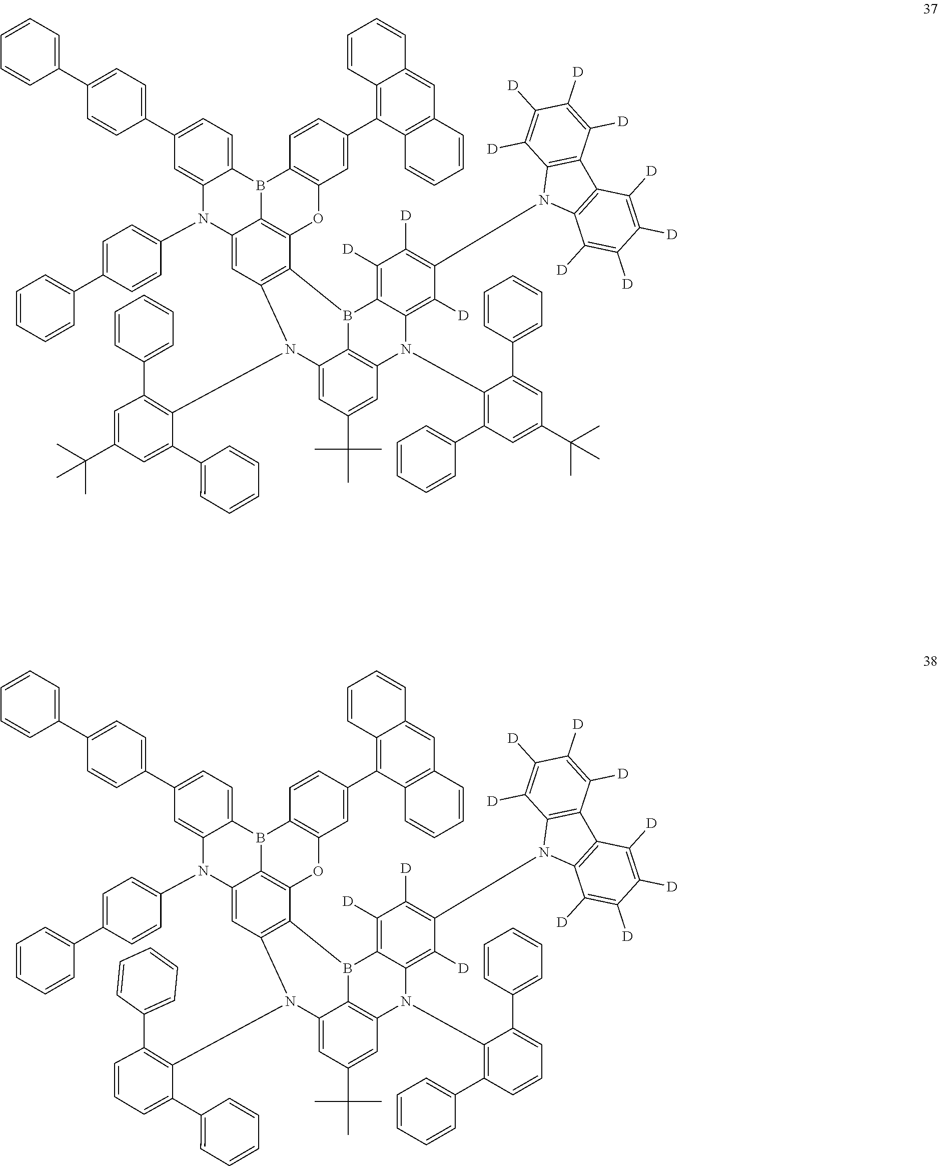

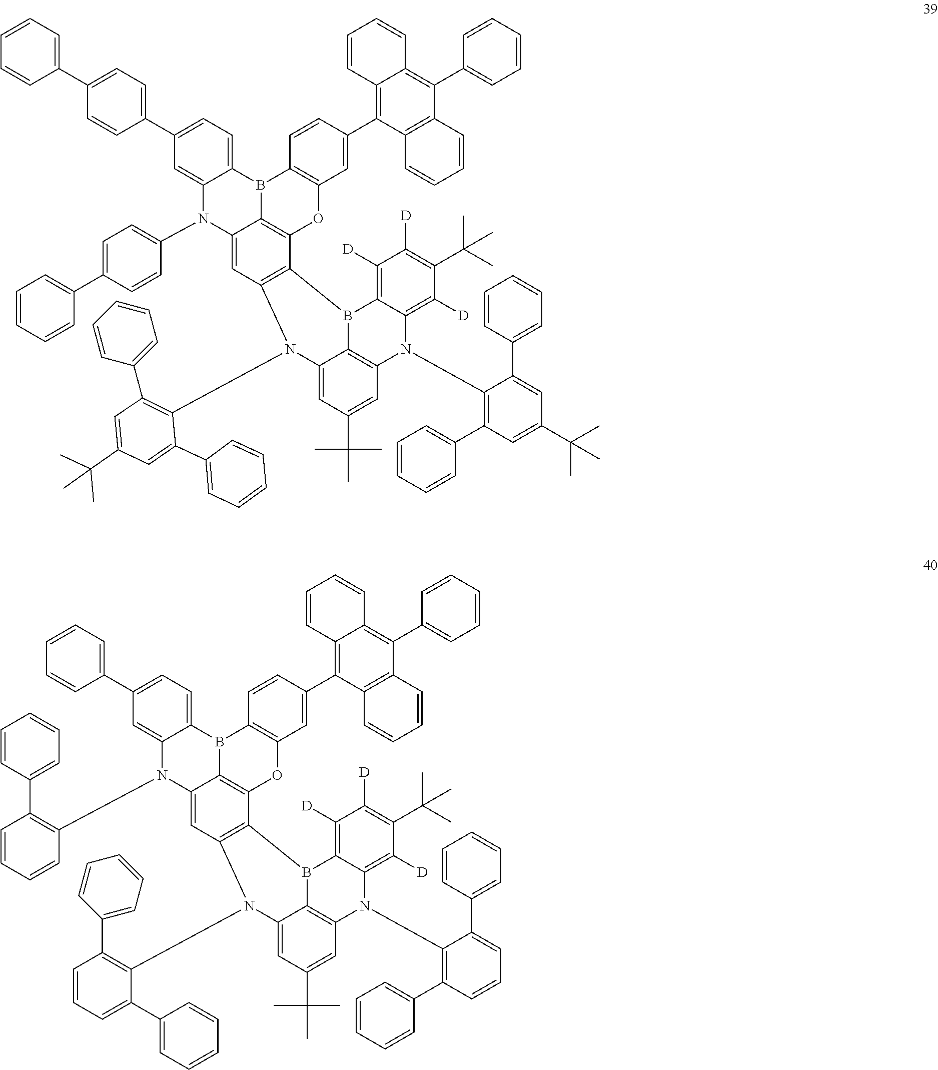 [SMILES: [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2c5ccccc5c(-c5ccccc5)c5ccccc25)ccc1B4c1ccc(-c2ccc(-c4ccccc4)cc2)cc1N3c1ccc(-c2ccccc2)cc1 ; [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2c5ccccc5c(-c5ccccc5)c5ccccc25)ccc1B4c1ccc(-c2ccccc2)cc1N3c1ccccc1-c1ccccc1]

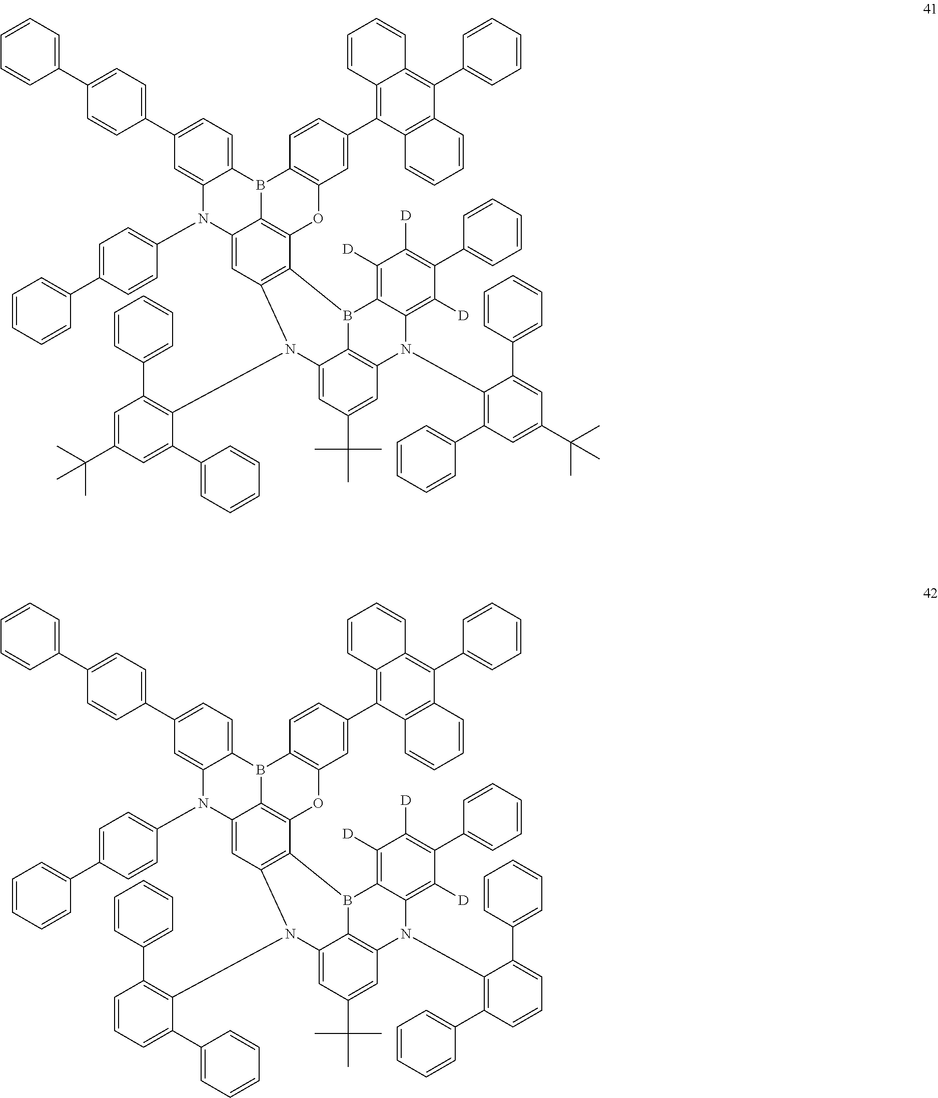 [SMILES: [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2c5ccccc5c(-c5ccccc5)c5ccccc25)ccc1B4c1ccc(-c2ccc(-c4ccccc4)cc2)cc1N3c1ccc(-c2ccccc2)cc1 ; [2H]c1c([2H])c(-c2ccccc2)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2c5ccccc5c(-c5ccccc5)c5ccccc25)ccc1B4c1ccc(-c2ccc(-c4ccccc4)cc2)cc1N3c1ccc(-c2ccccc2)cc1]

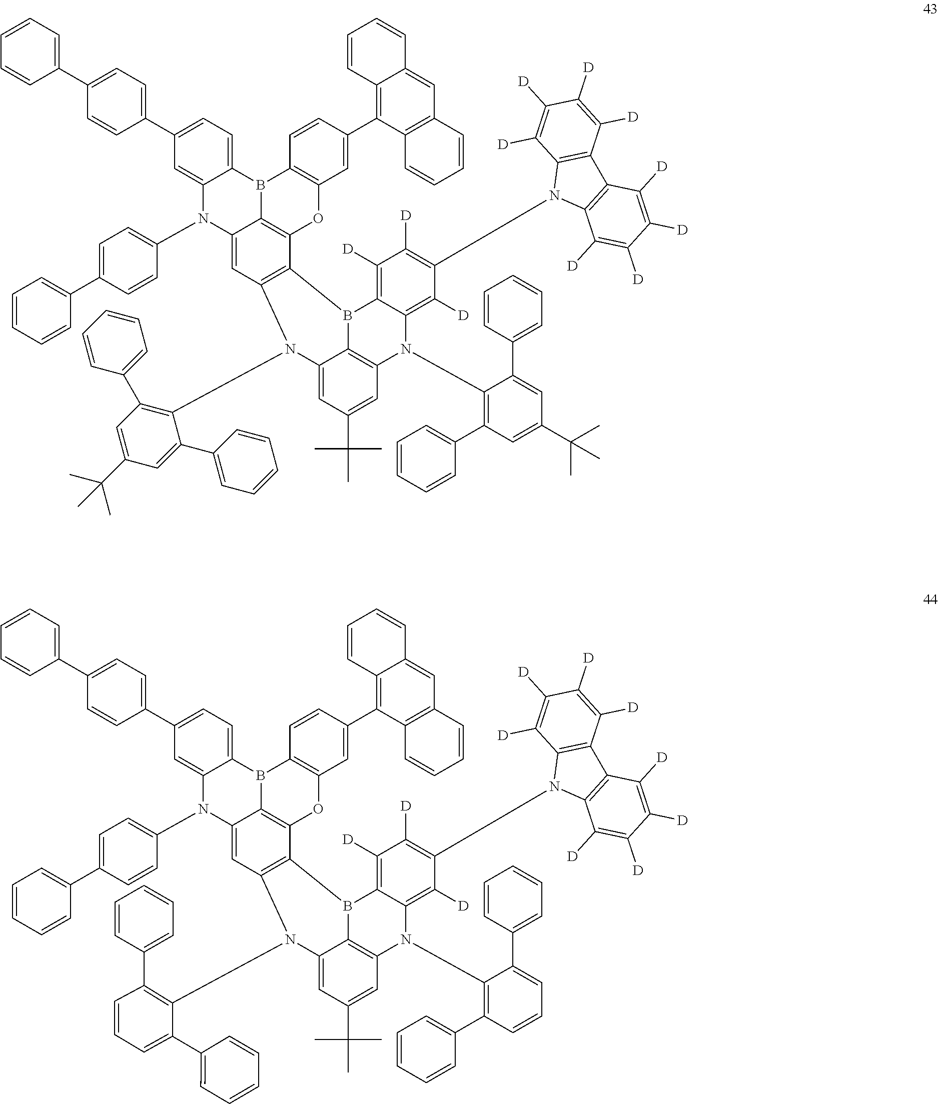

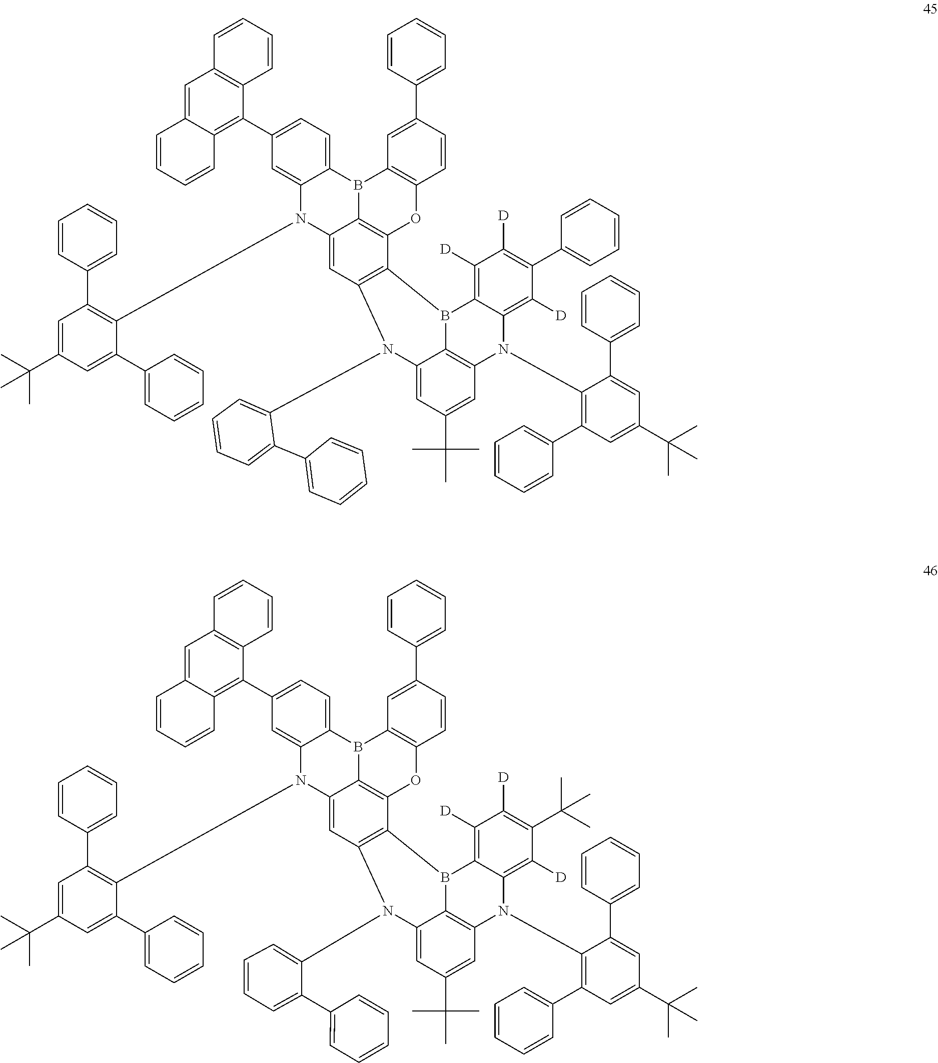

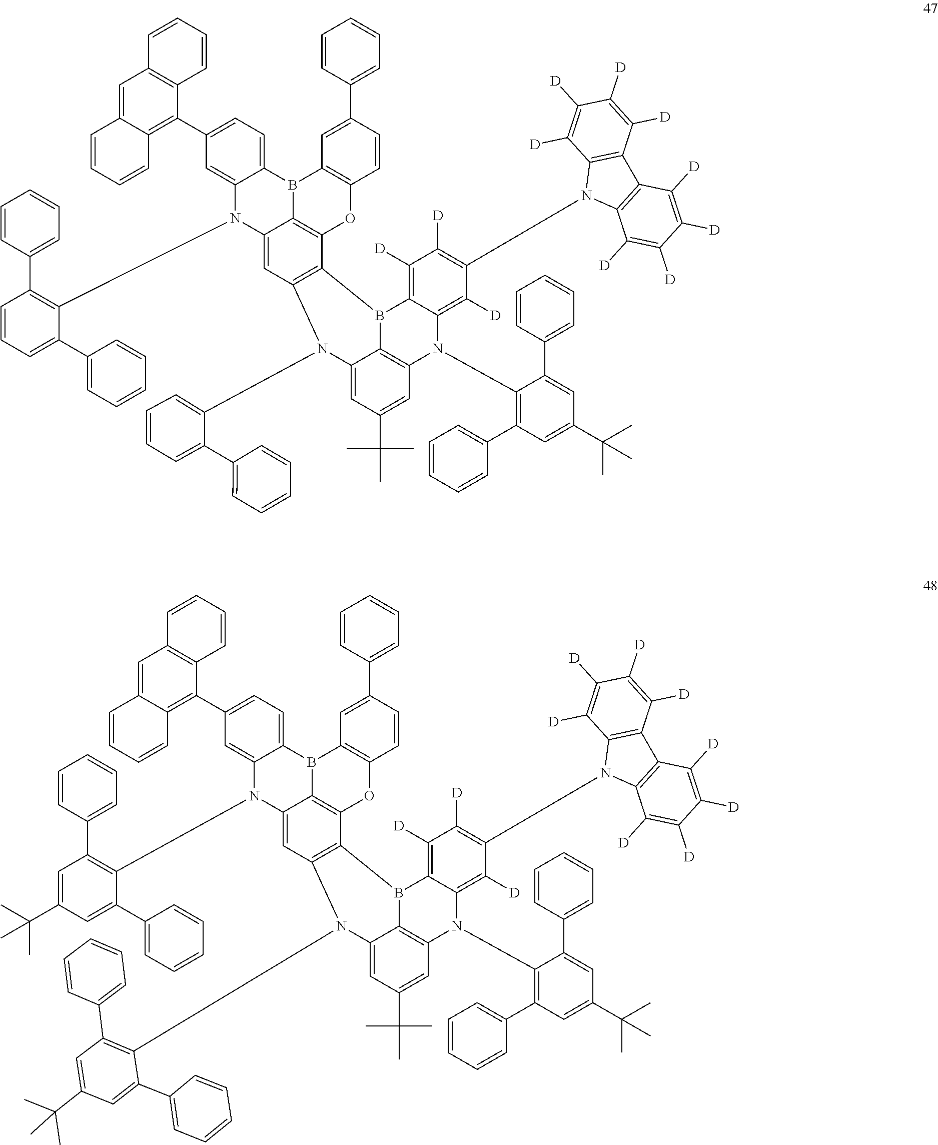

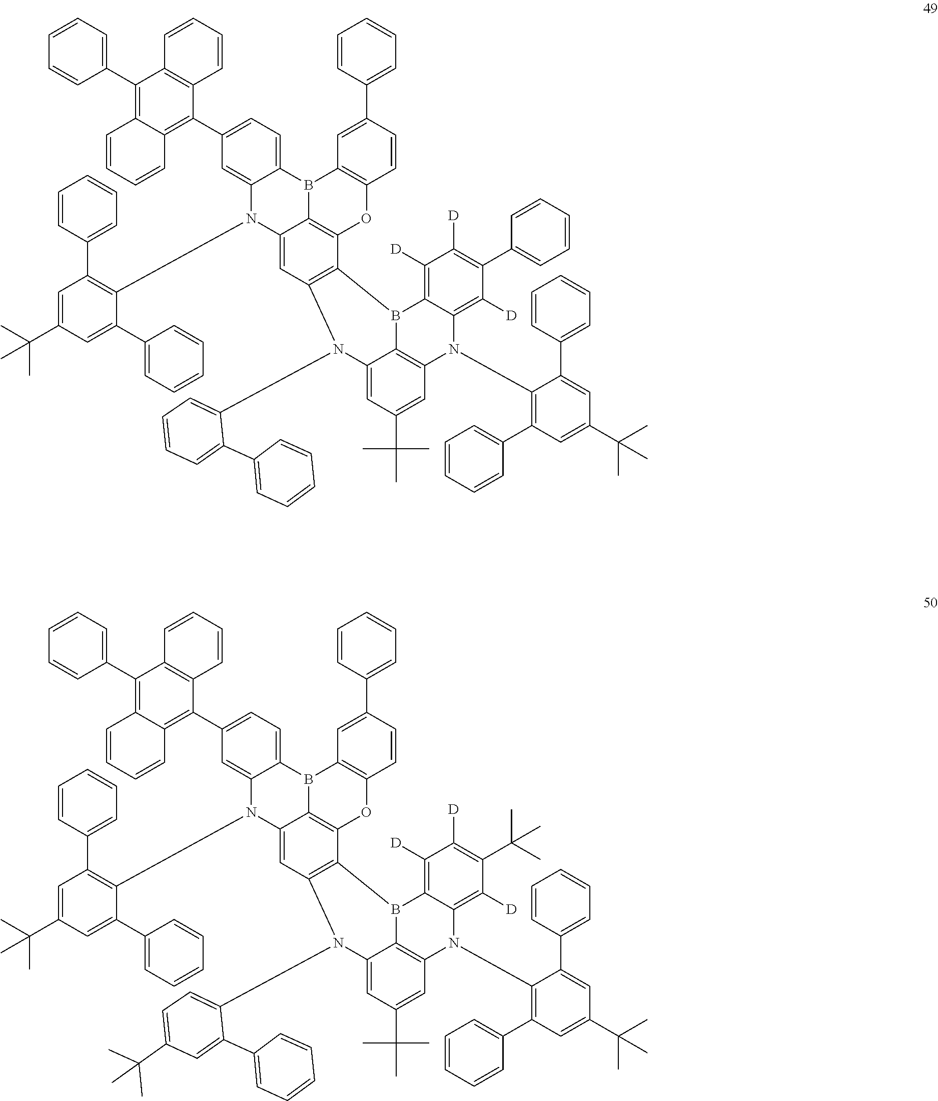

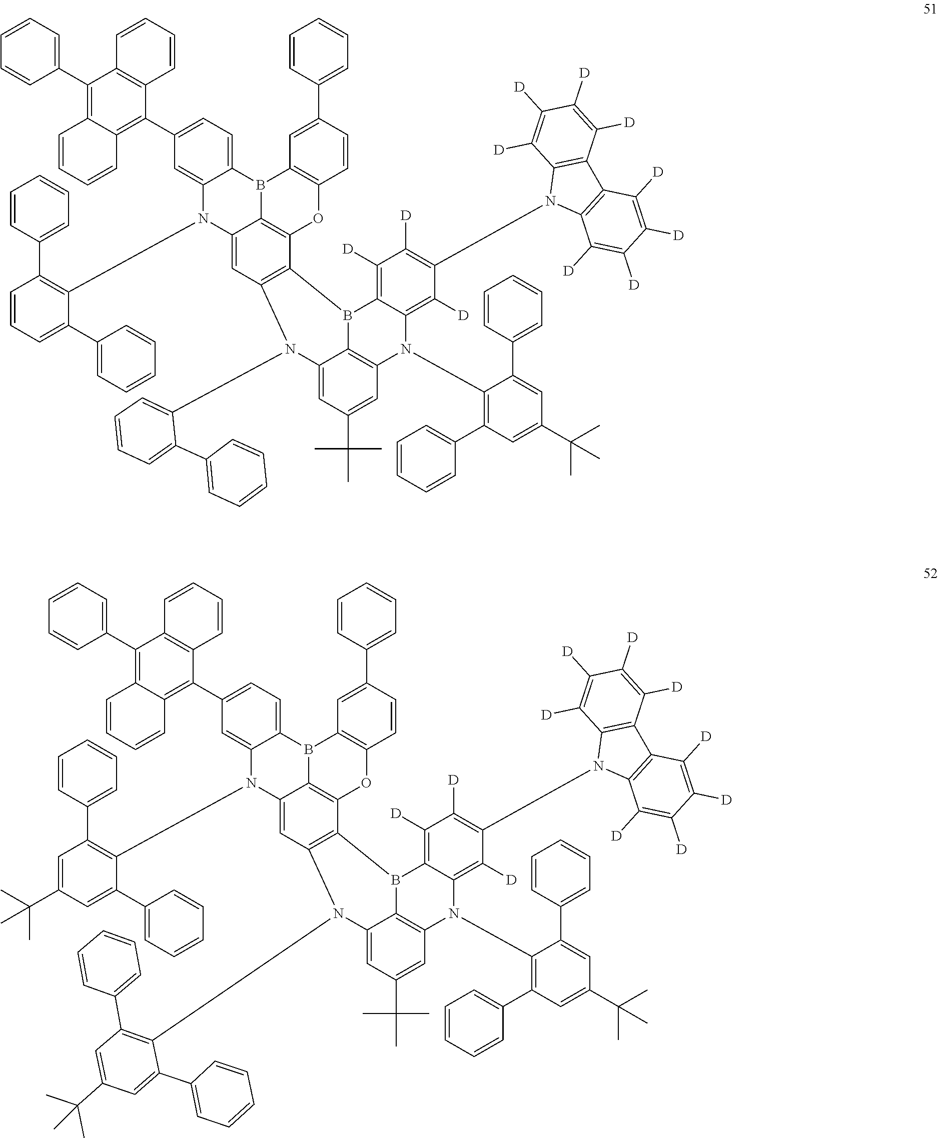

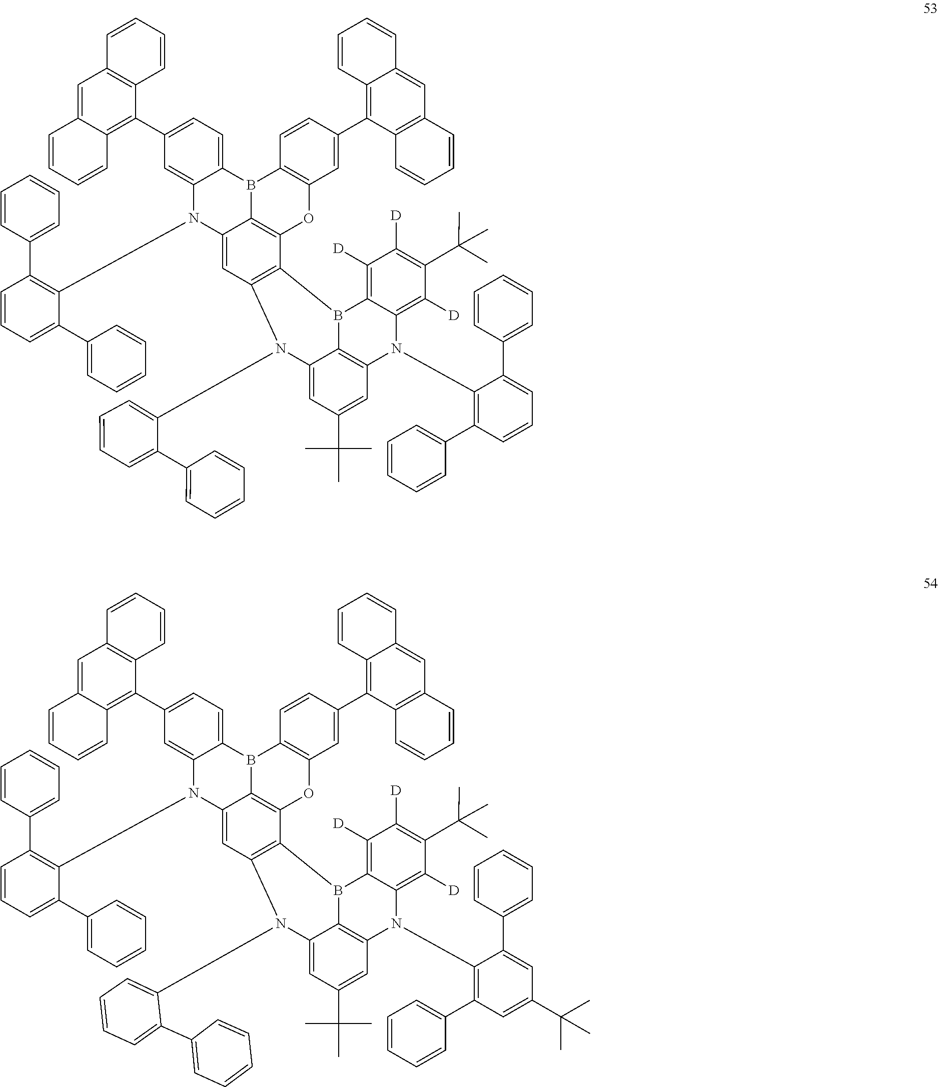 [SMILES: [2H]c1c([2H])c(C(C)(C)C)c([2H])c2c1B1c3c(cc(C(C)(C)C)cc3N2c2c(-c3ccccc3)cccc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1 ; [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1]

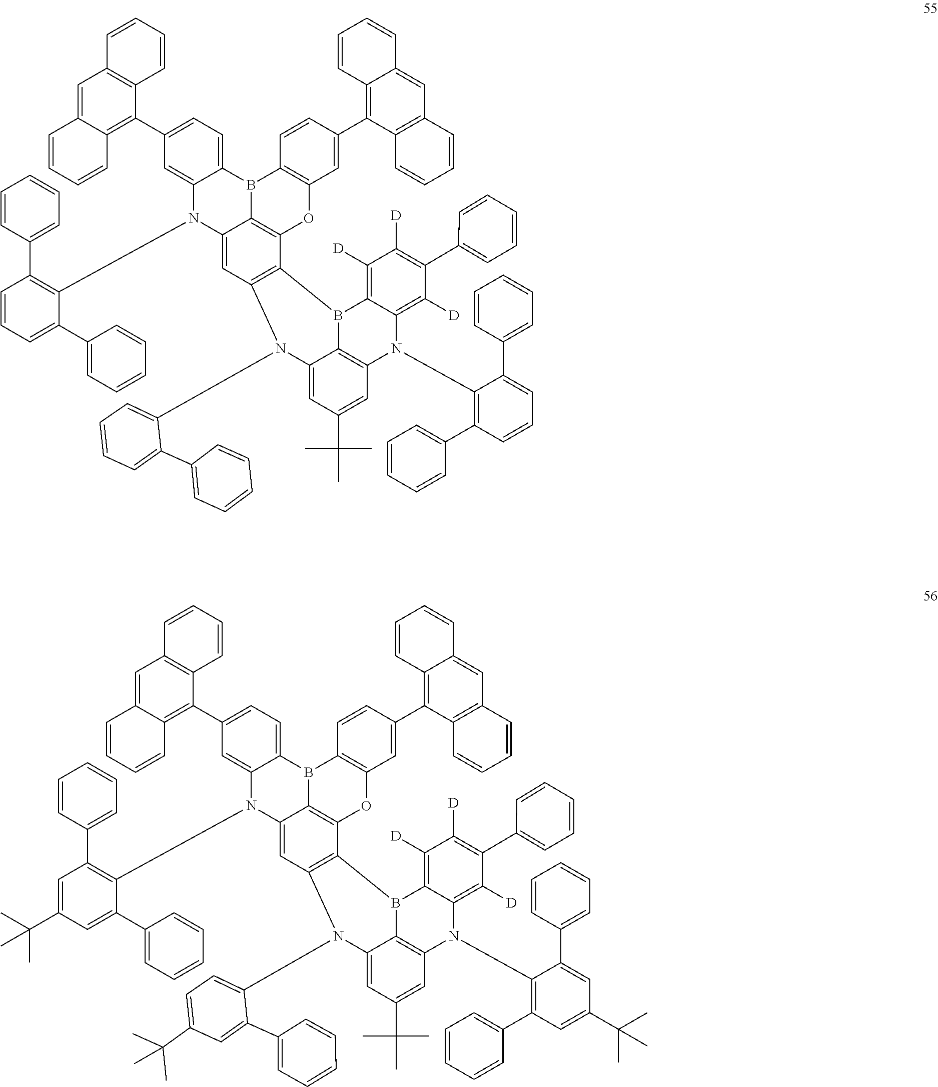 [SMILES: [2H]c1c([2H])c(-c2ccccc2)c([2H])c2c1B1c3c(cc(C(C)(C)C)cc3N2c2c(-c3ccccc3)cccc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1 ; [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2ccc(C(C)(C)C)cc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cc(C(C)(C)C)cc1-c1ccccc1]

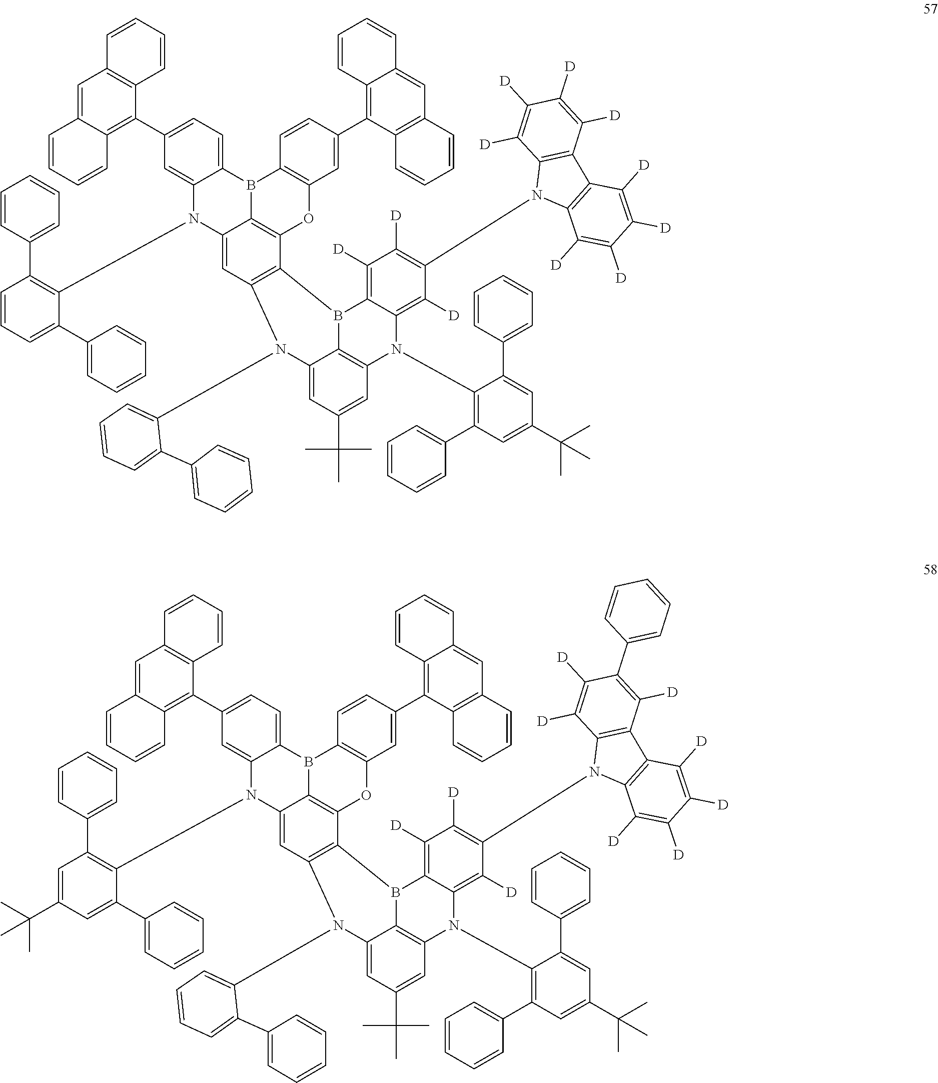

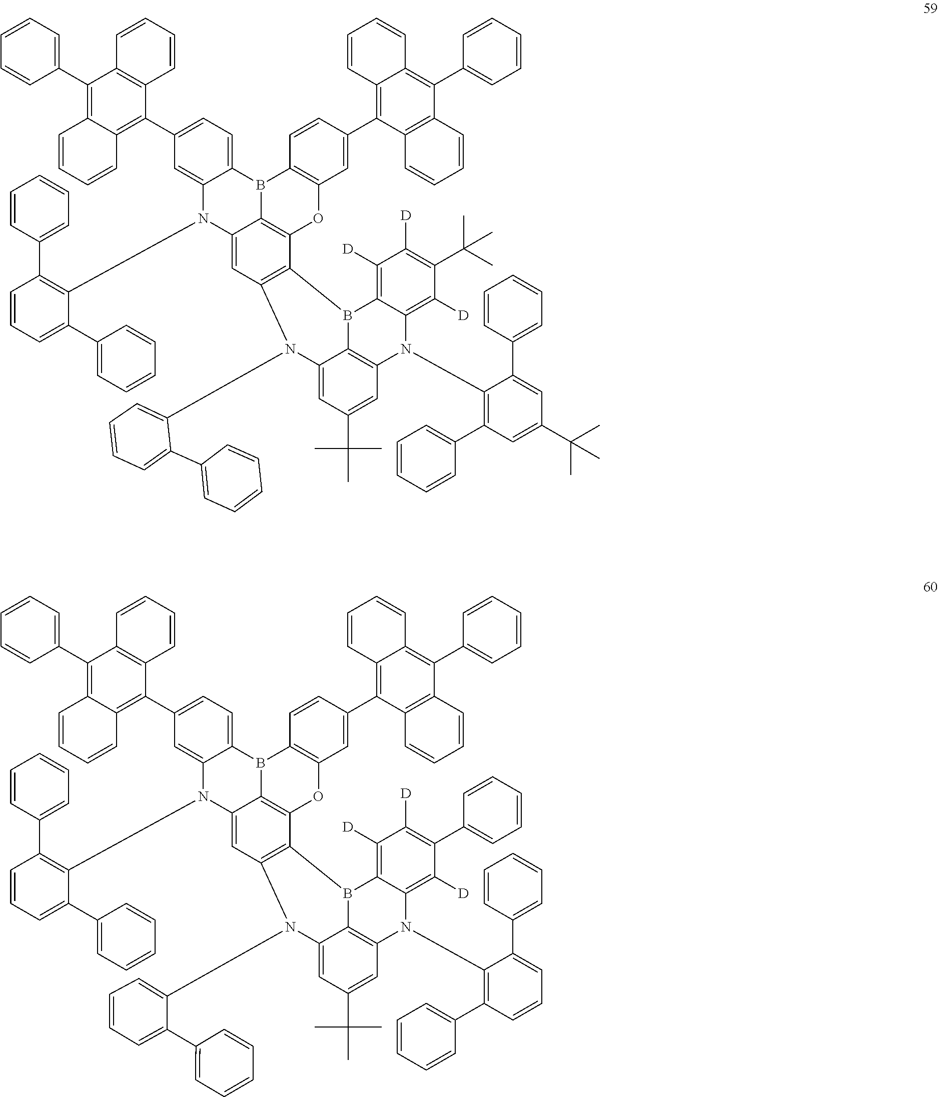 [SMILES: [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5c(-c5ccccc5)c5ccccc25)ccc1B4c1ccc(-c2c4ccccc4c(-c4ccccc4)c4ccccc24)cc1N3c1c(-c2ccccc2)cccc1-c1ccccc1 ; [2H]c1c([2H])c(-c2ccccc2)c([2H])c2c1B1c3c(cc(C(C)(C)C)cc3N2c2c(-c3ccccc3)cccc2-c2ccccc2)N(c2ccccc2-c2ccccc2)c2cc3c4c(c21)Oc1cc(-c2c5ccccc5c(-c5ccccc5)c5ccccc25)ccc1B4c1ccc(-c2c4ccccc4c(-c4ccccc4)c4ccccc24)cc1N3c1c(-c2ccccc2)cccc1-c1ccccc1]

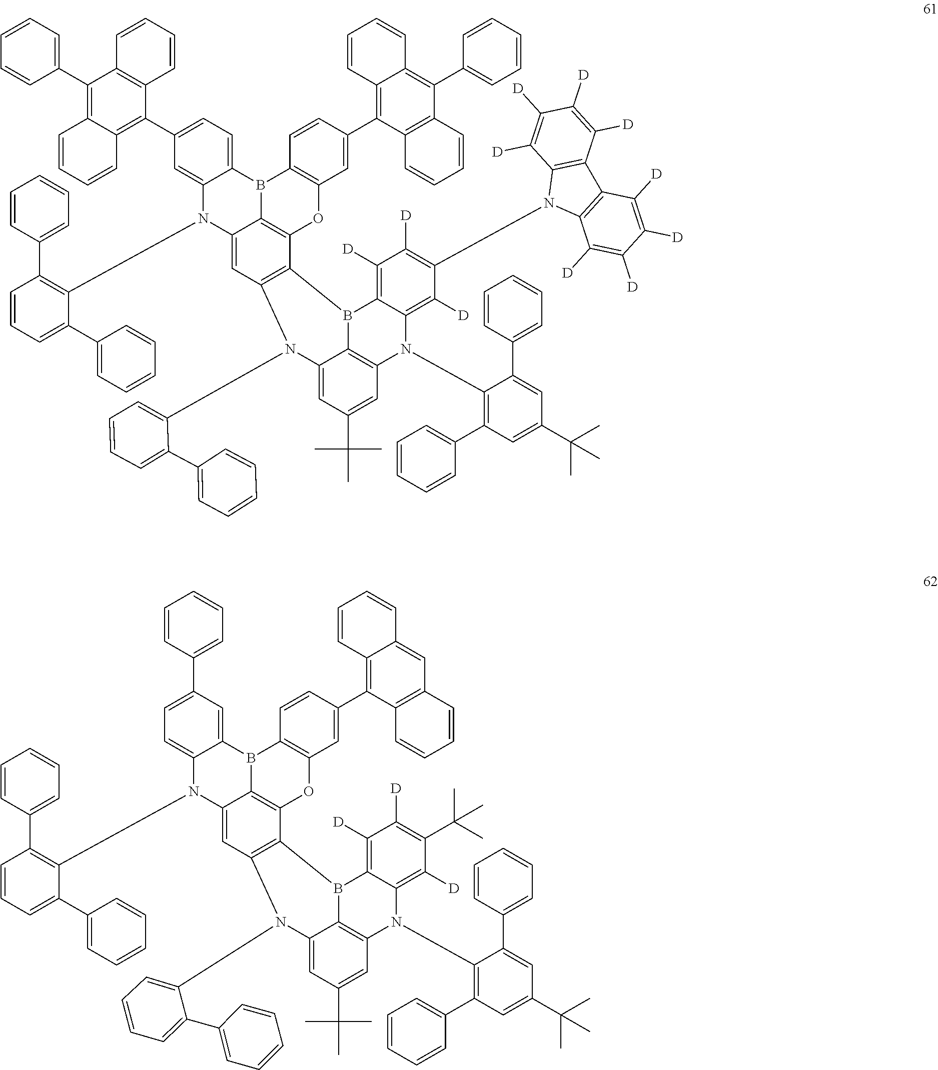

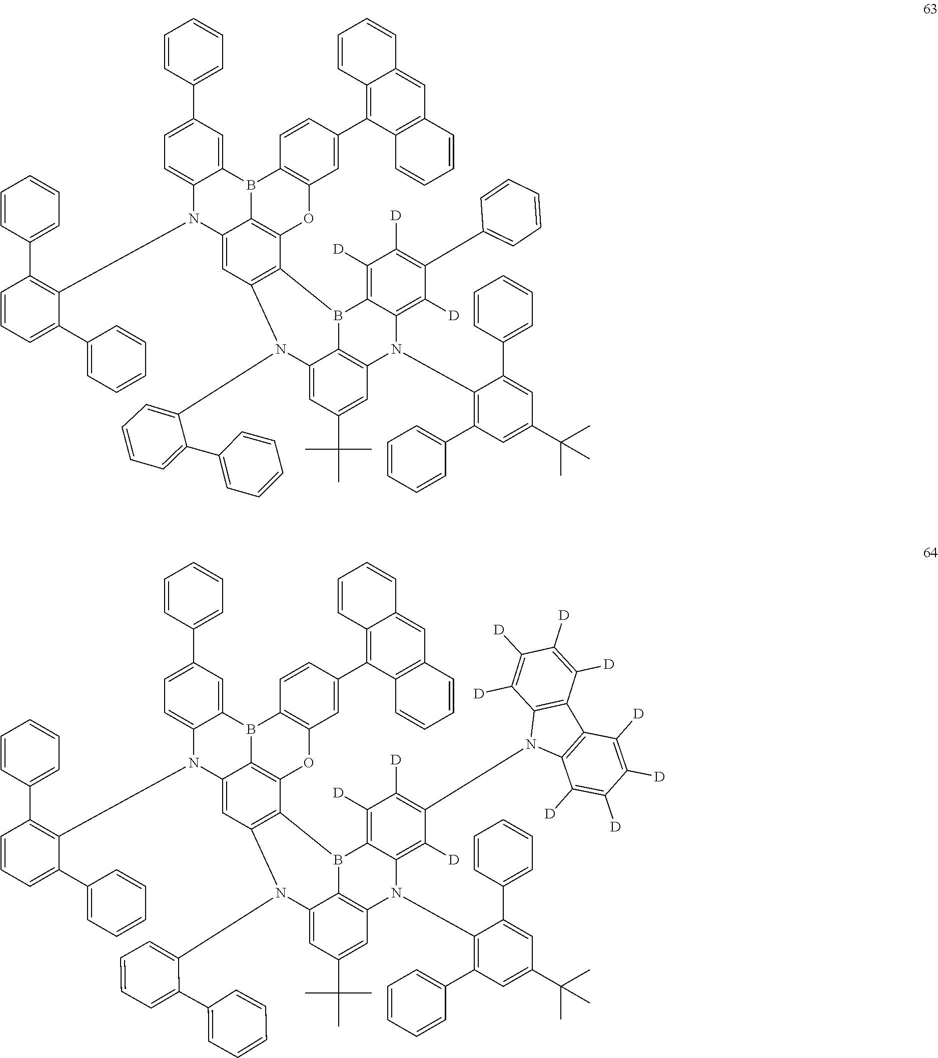 [SMILES: [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1cc(-c2ccccc2)ccc1N3c1c(-c2ccccc2)cccc1-c1ccccc1 ; [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1cc(-c2ccccc2)ccc1N3c1c(-c2ccccc2)cccc1-c1ccccc1]

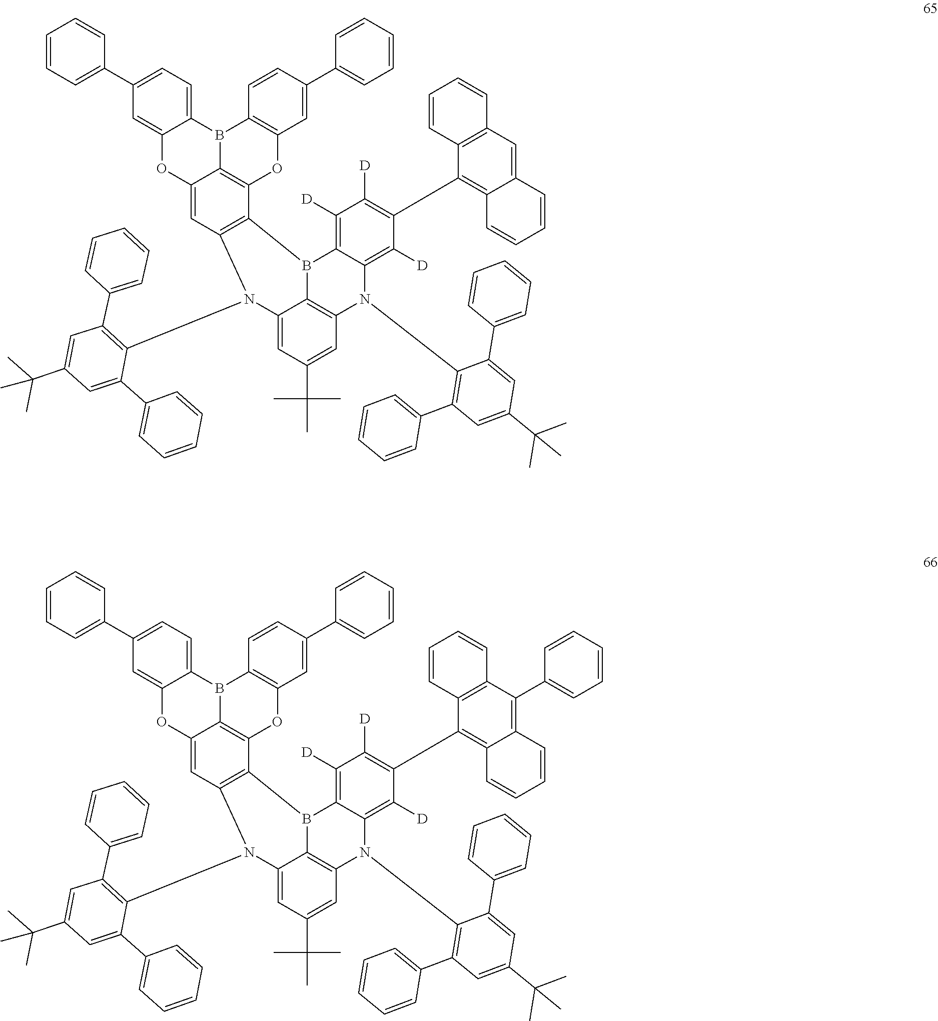

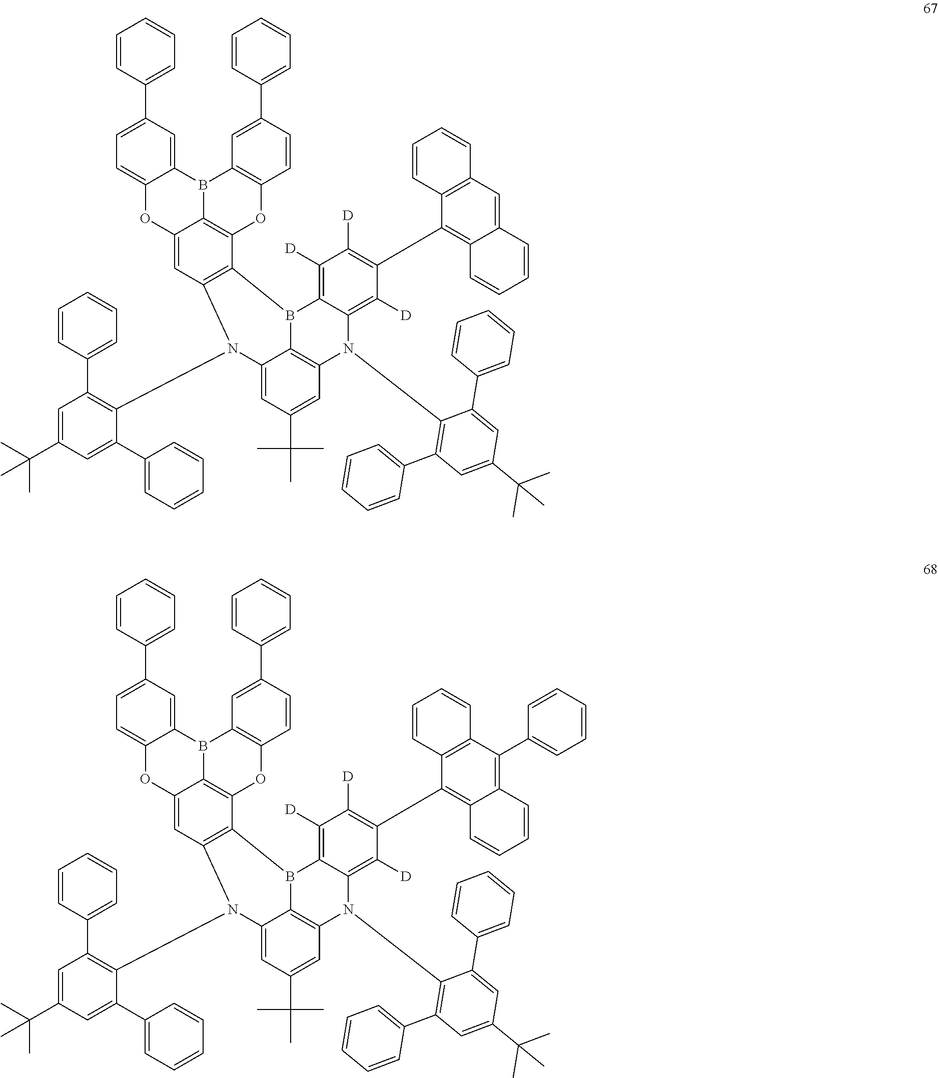

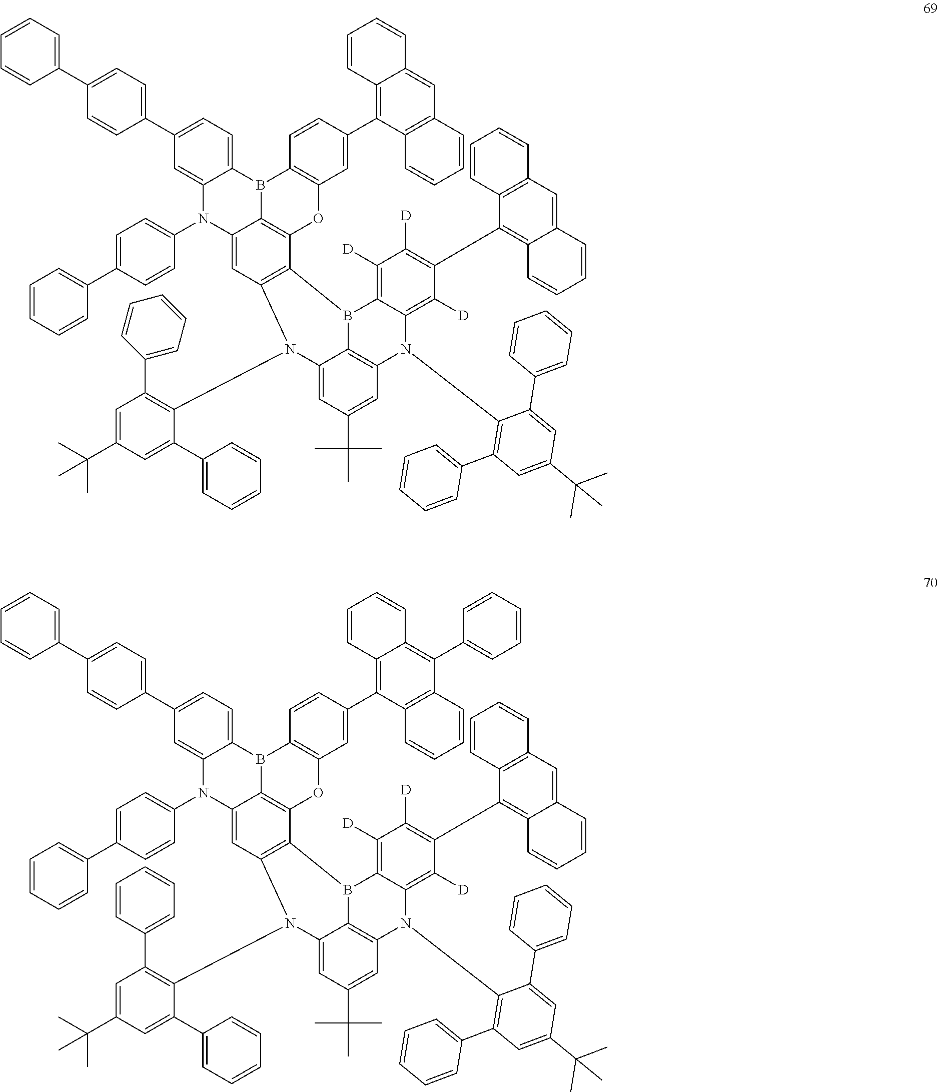

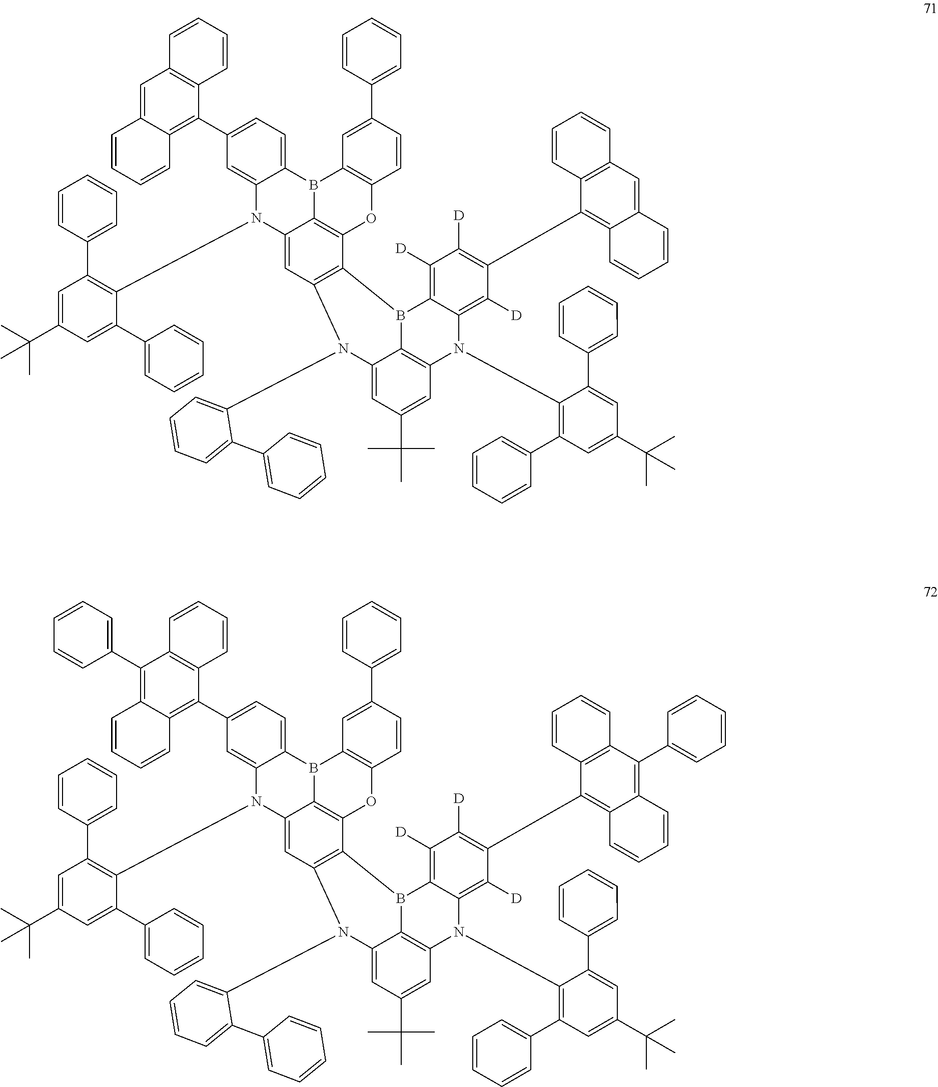

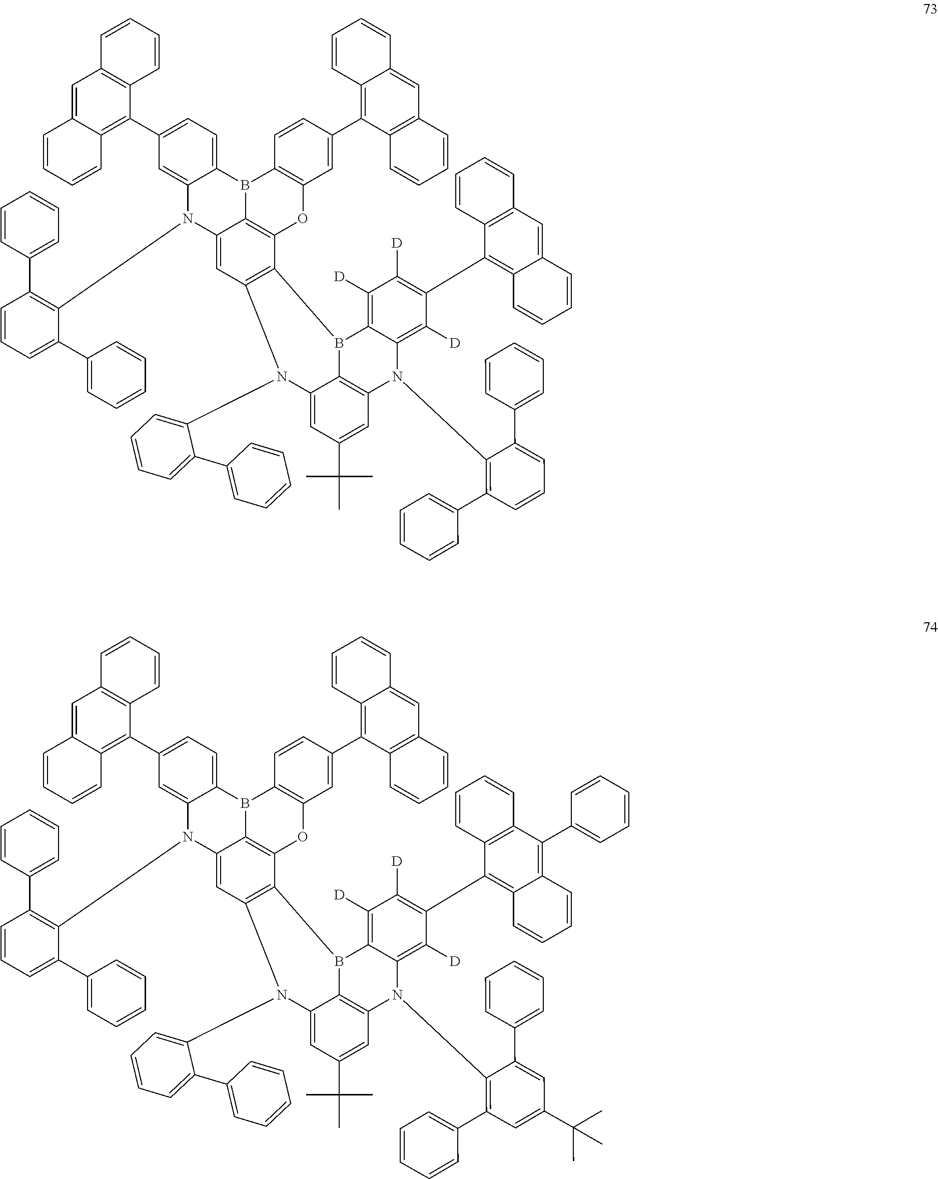 [SMILES: [2H]c1c([2H])c(-c2c3ccccc3cc3ccccc23)c([2H])c2c1B1c3c(cc(C(C)(C)C)cc3N2c2c(-c3ccccc3)cccc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1 ; [2H]c1c([2H])c(-c2c3ccccc3c(-c3ccccc3)c3ccccc23)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1]

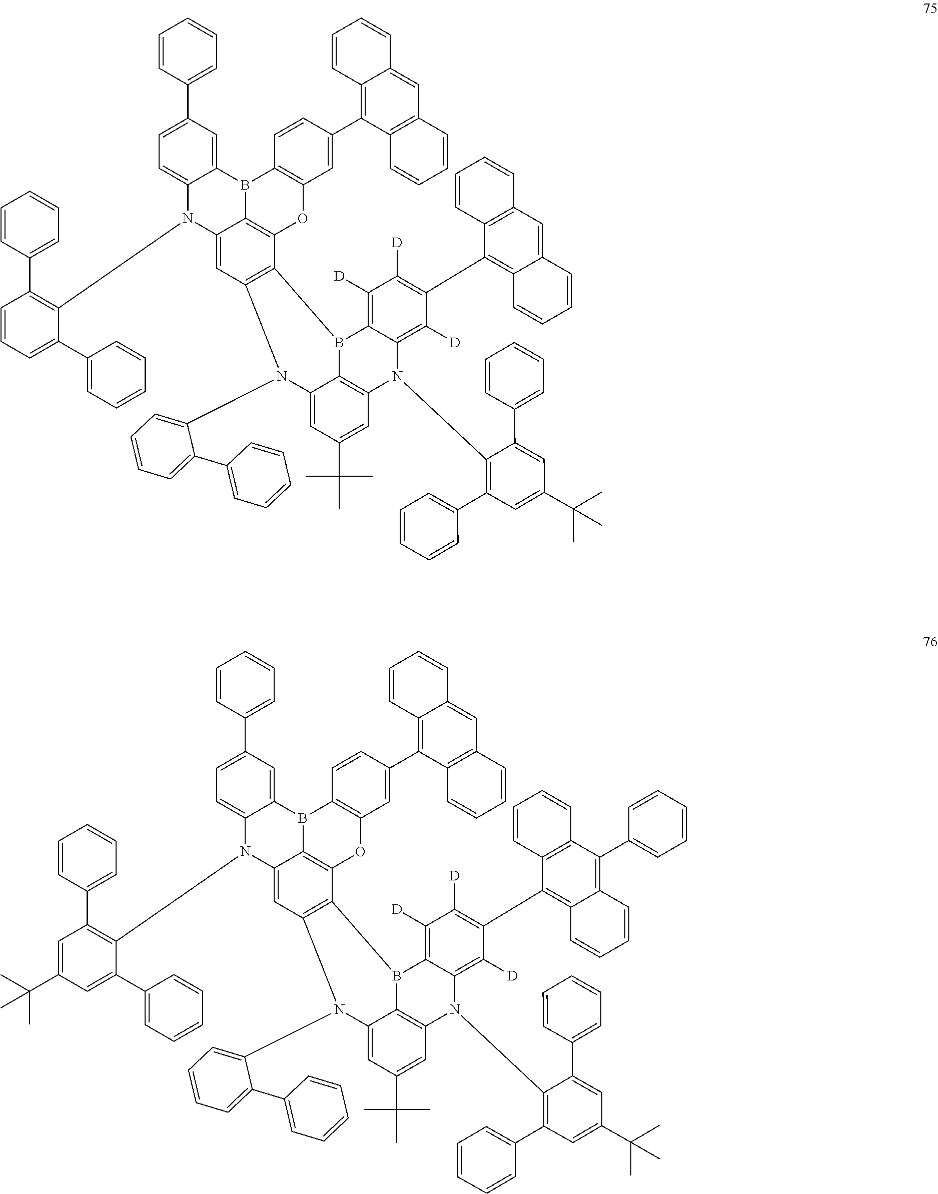

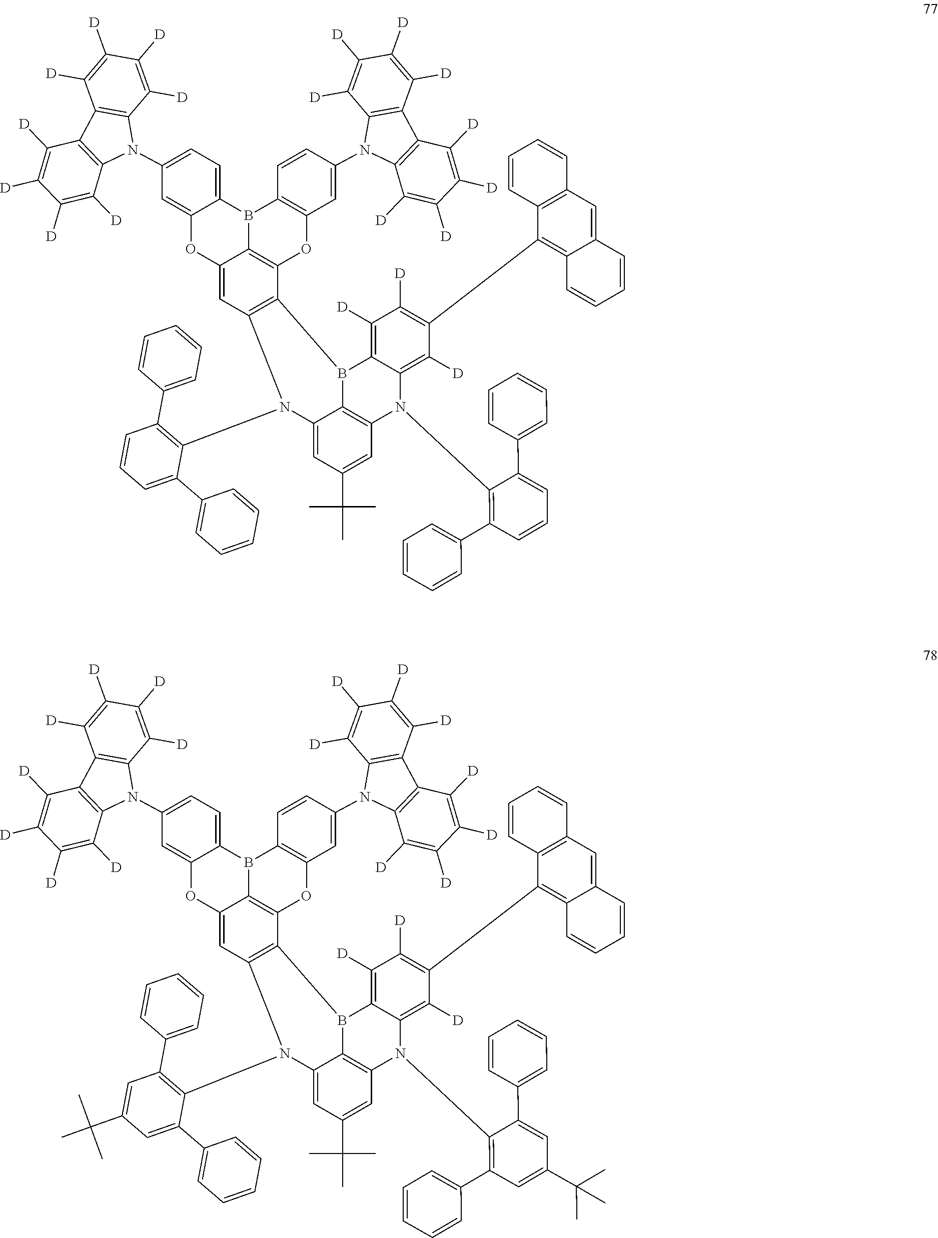

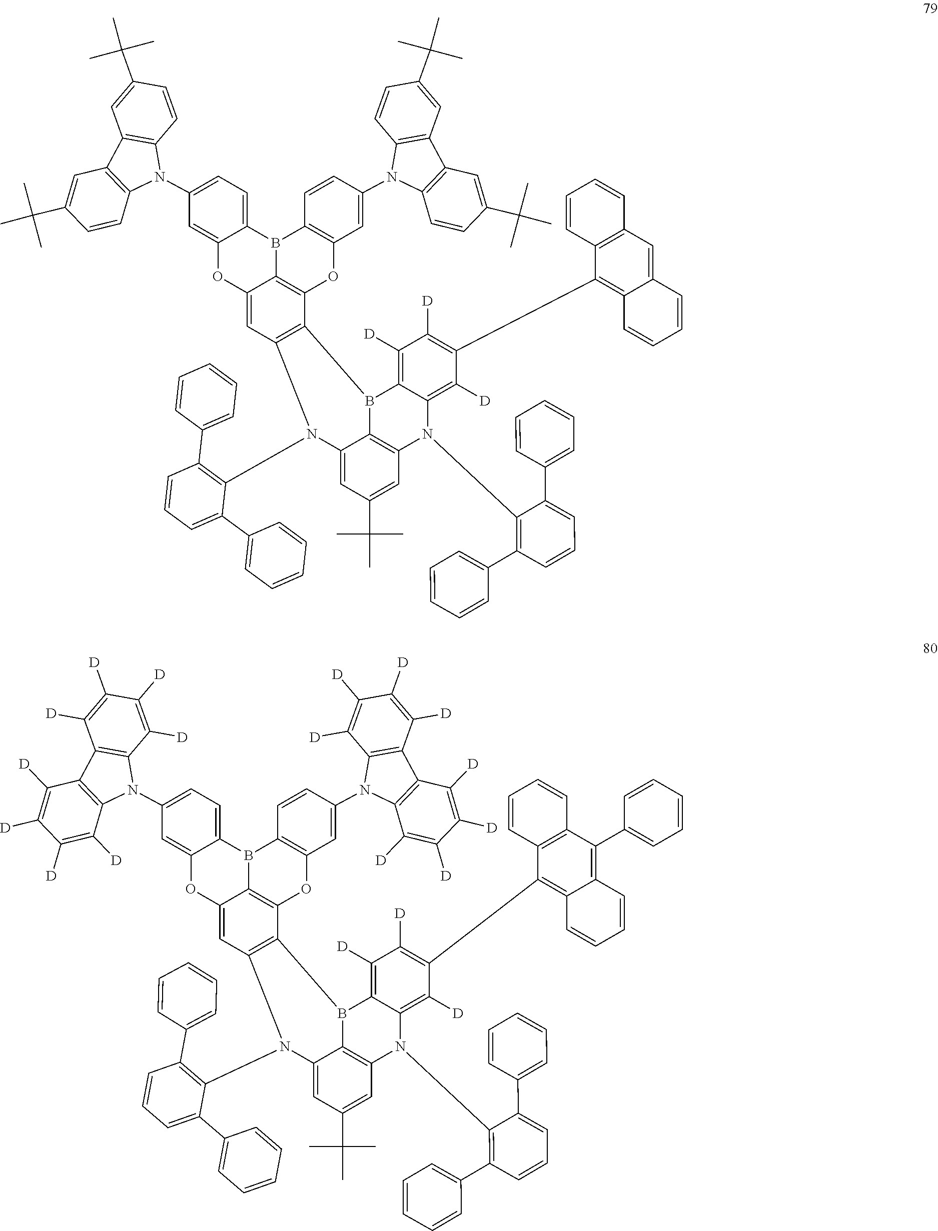

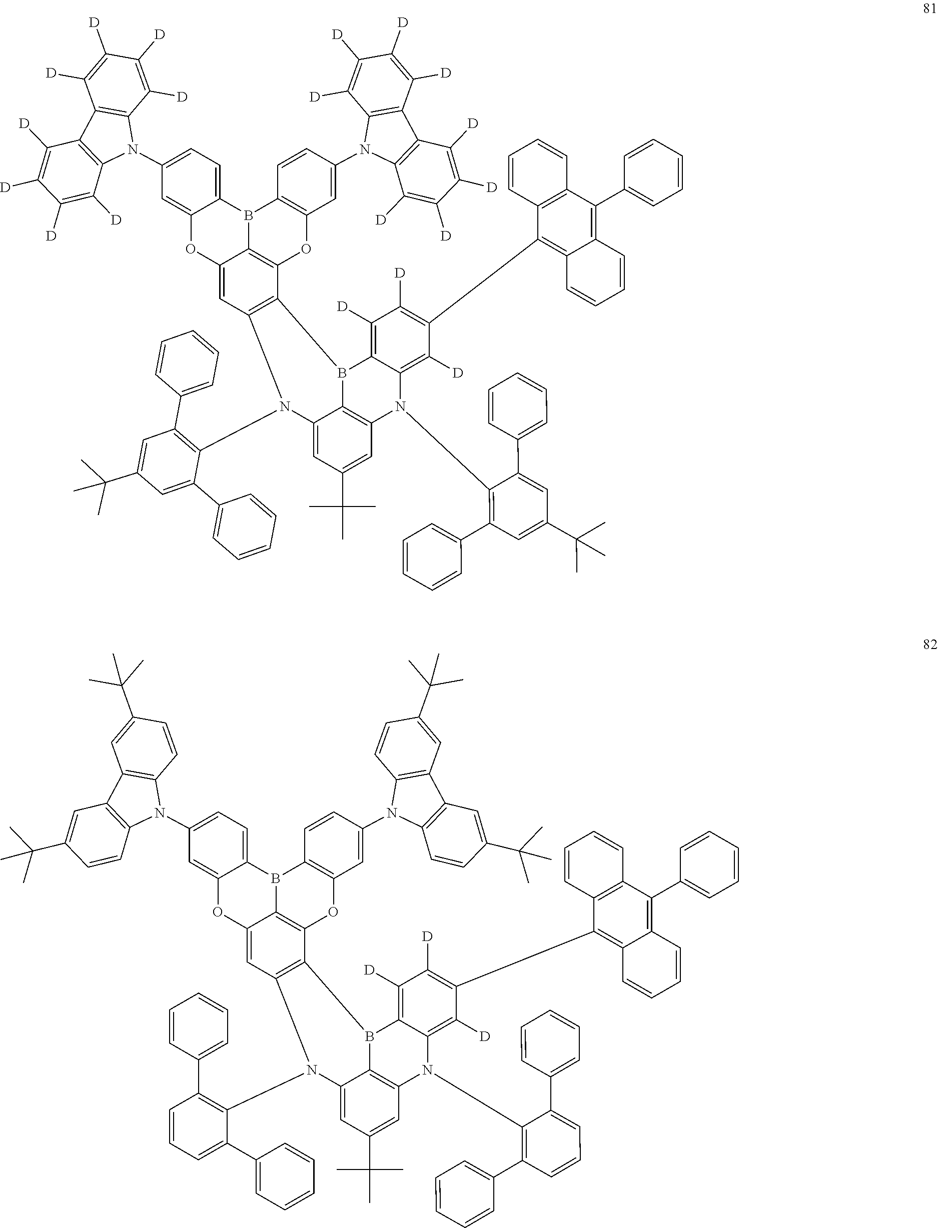

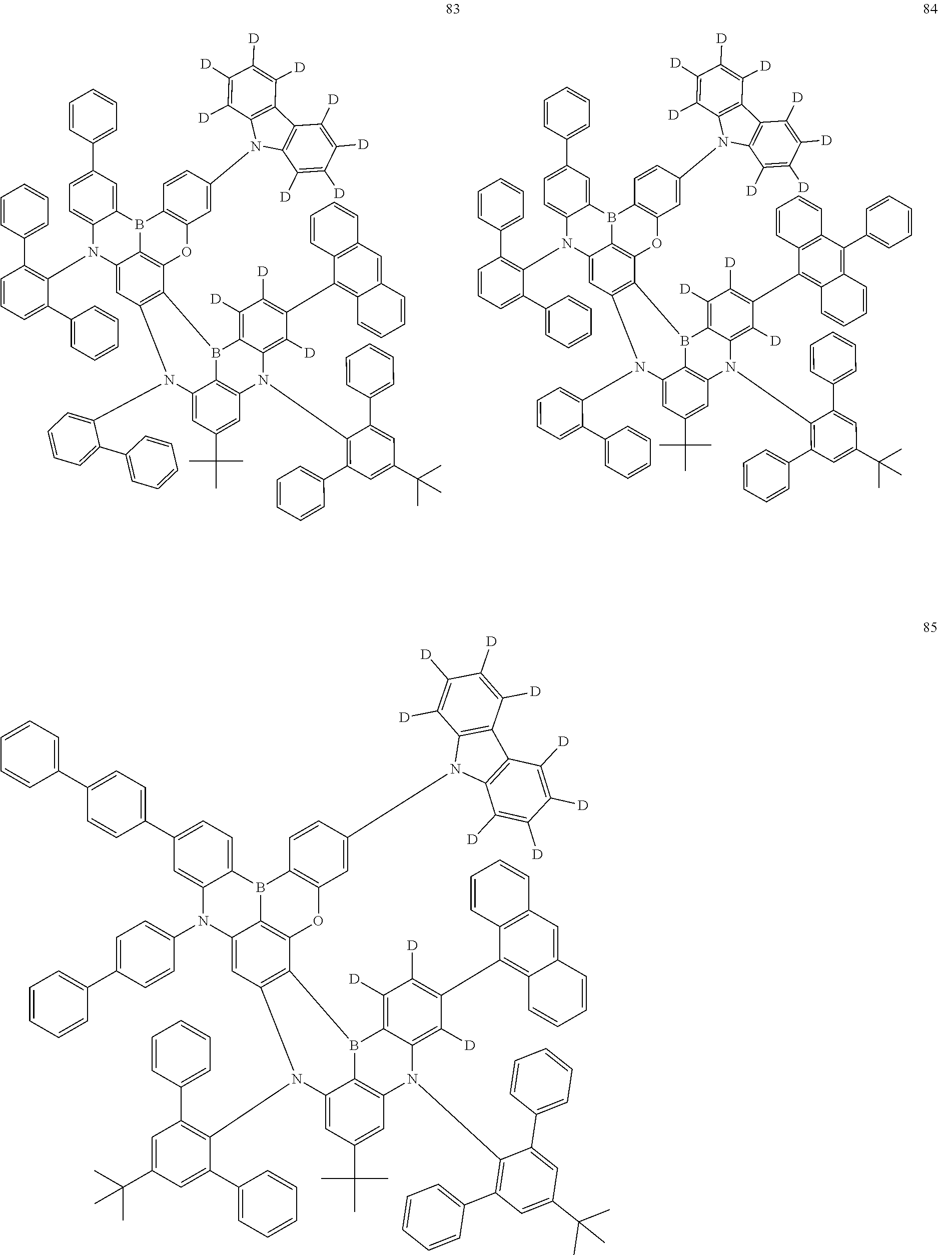

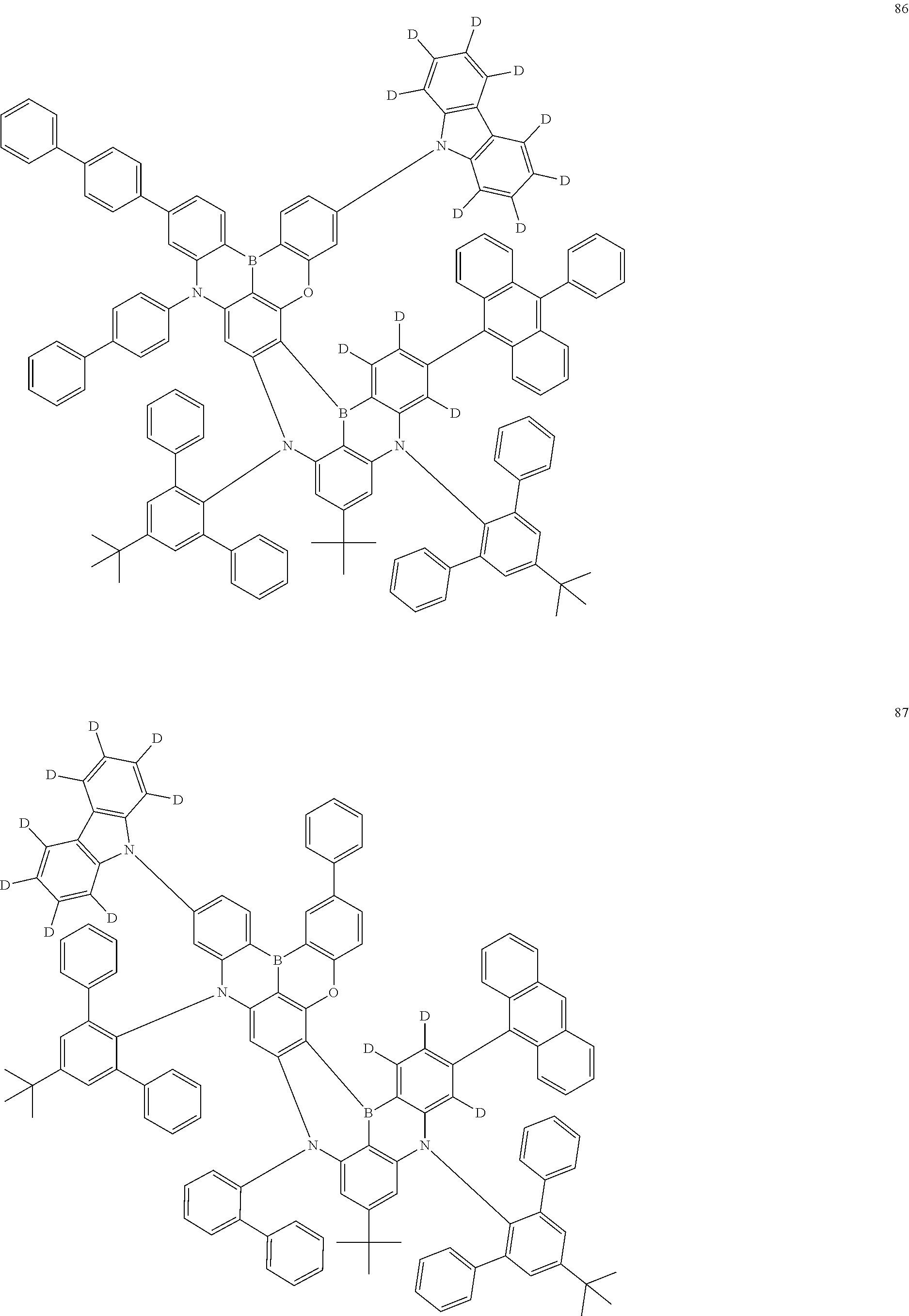

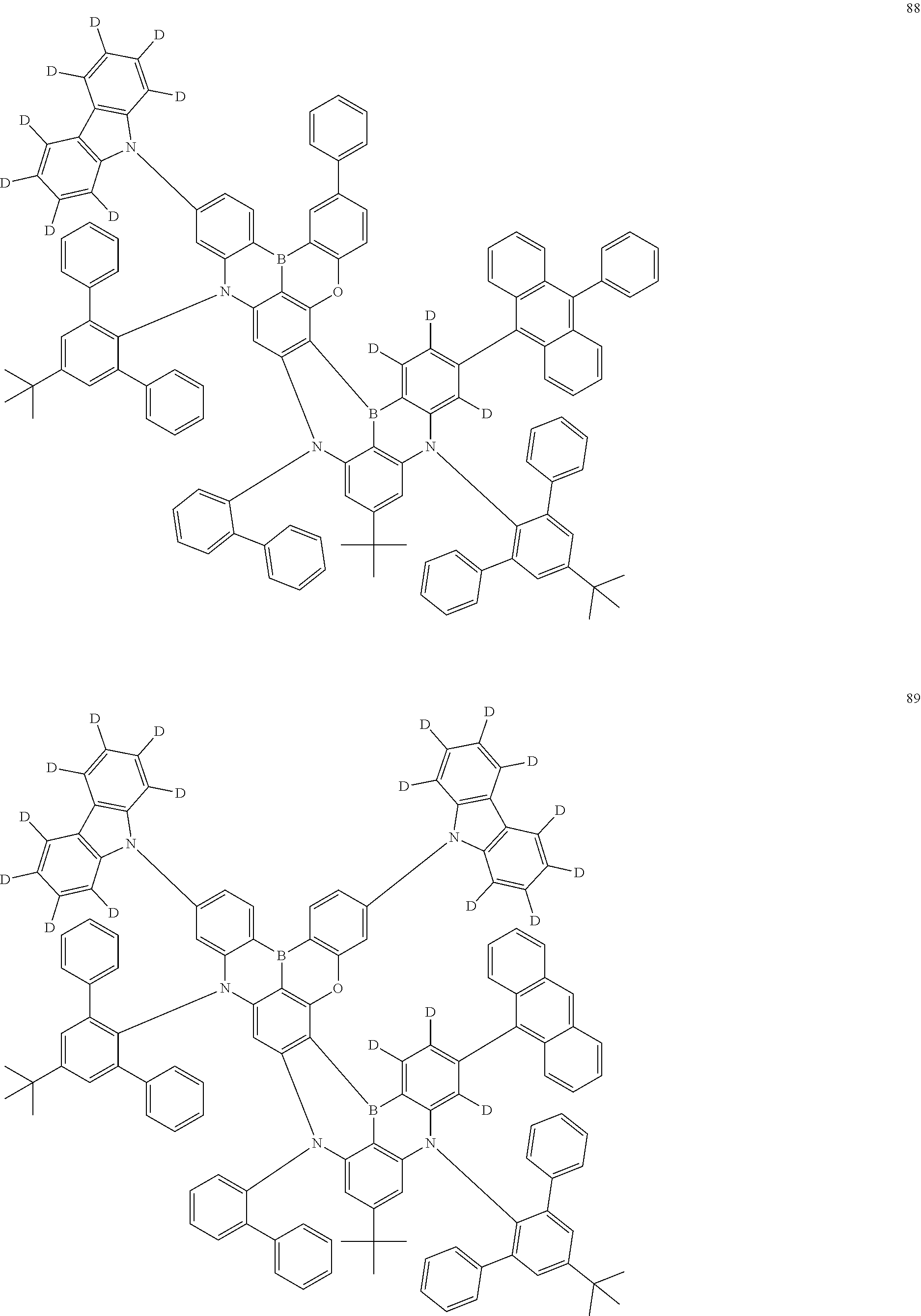

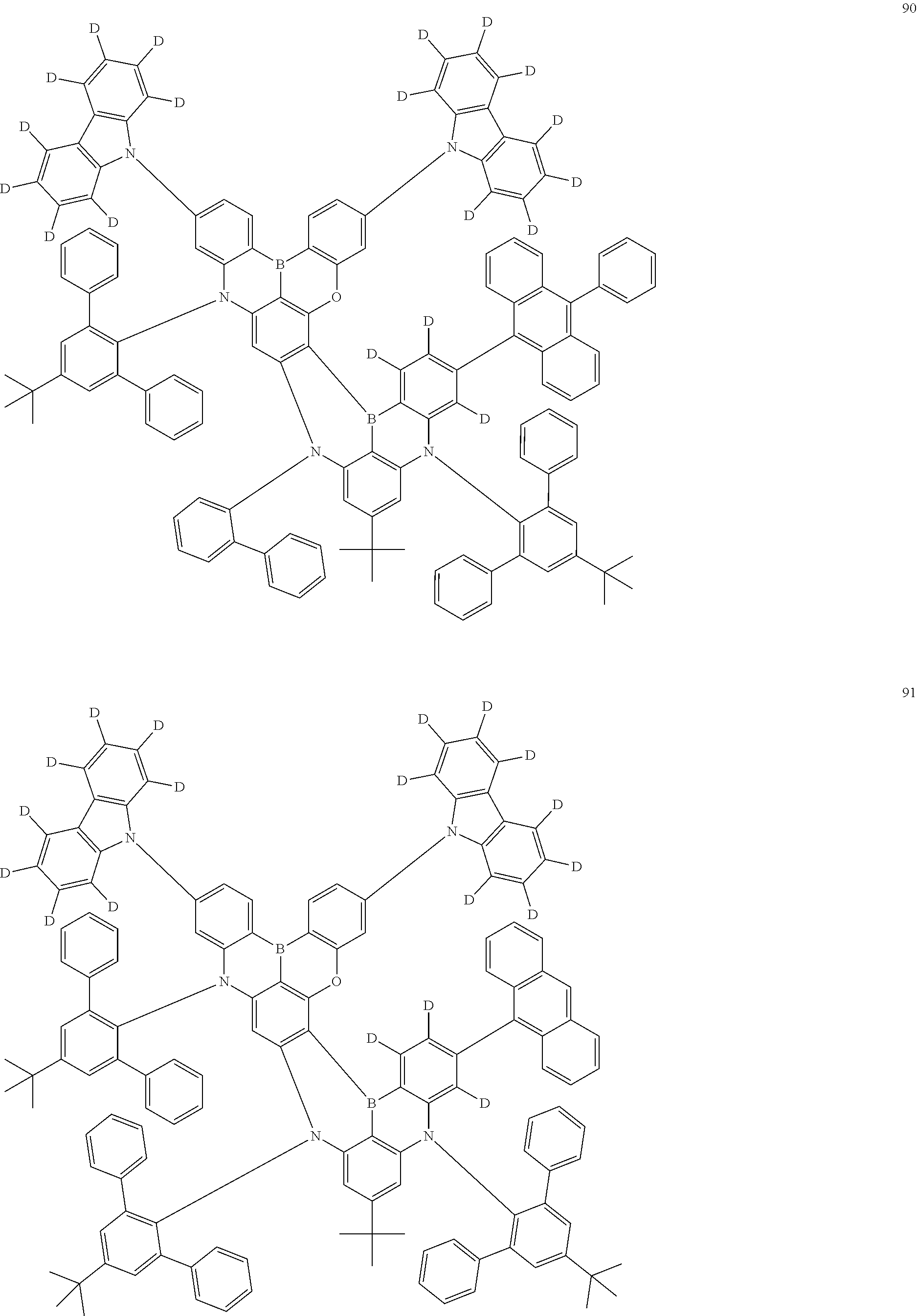

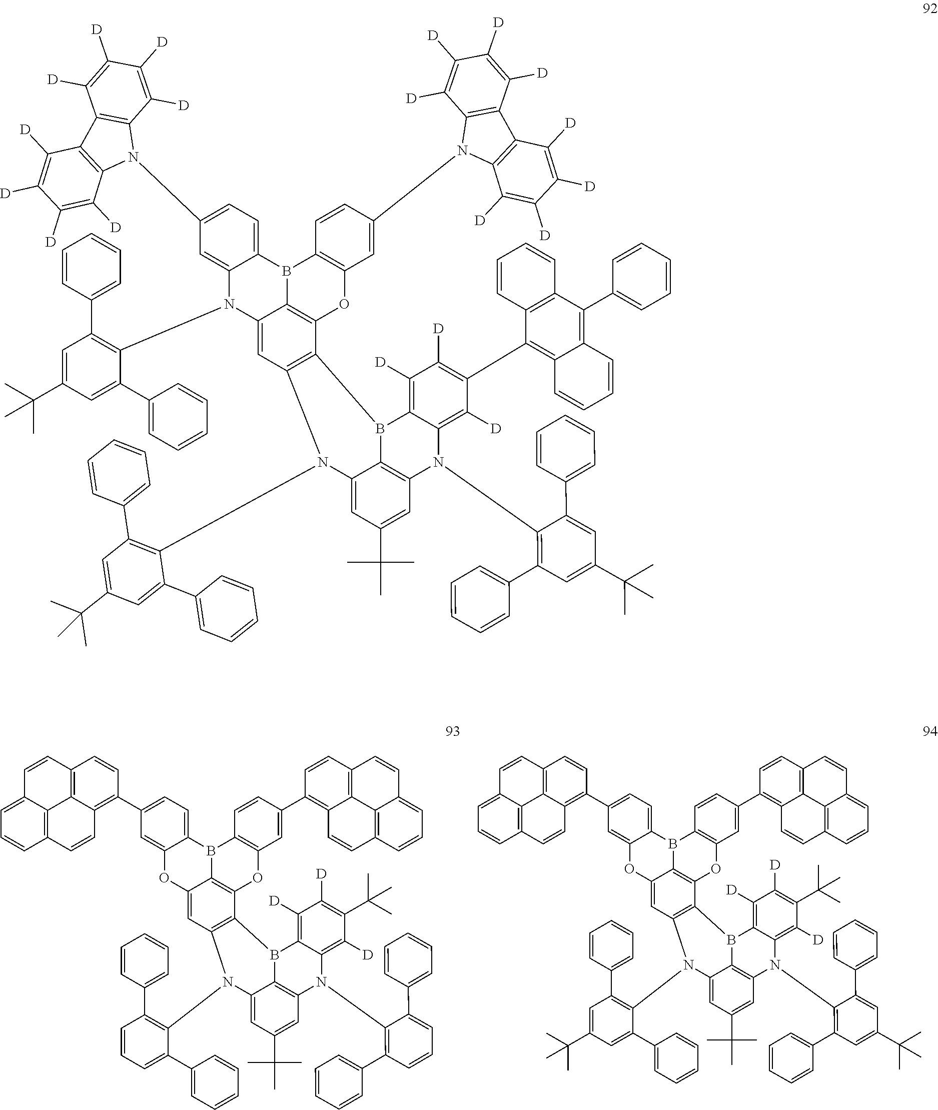

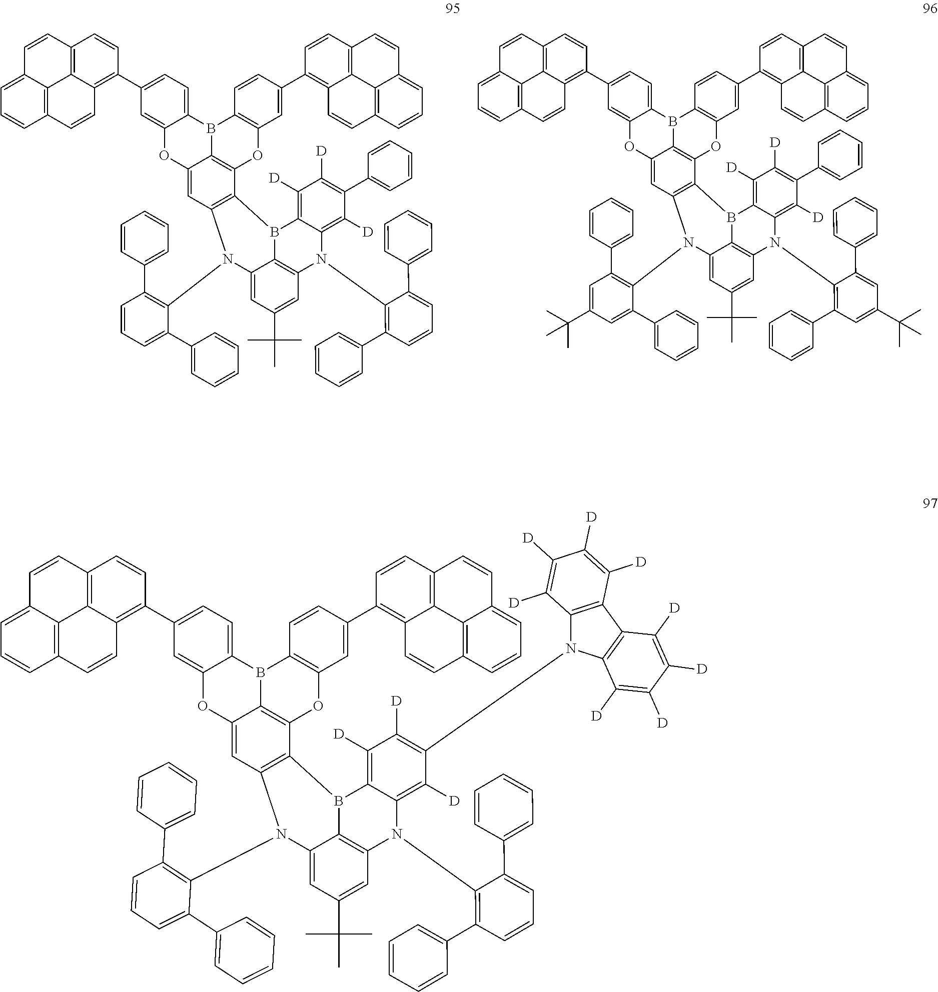

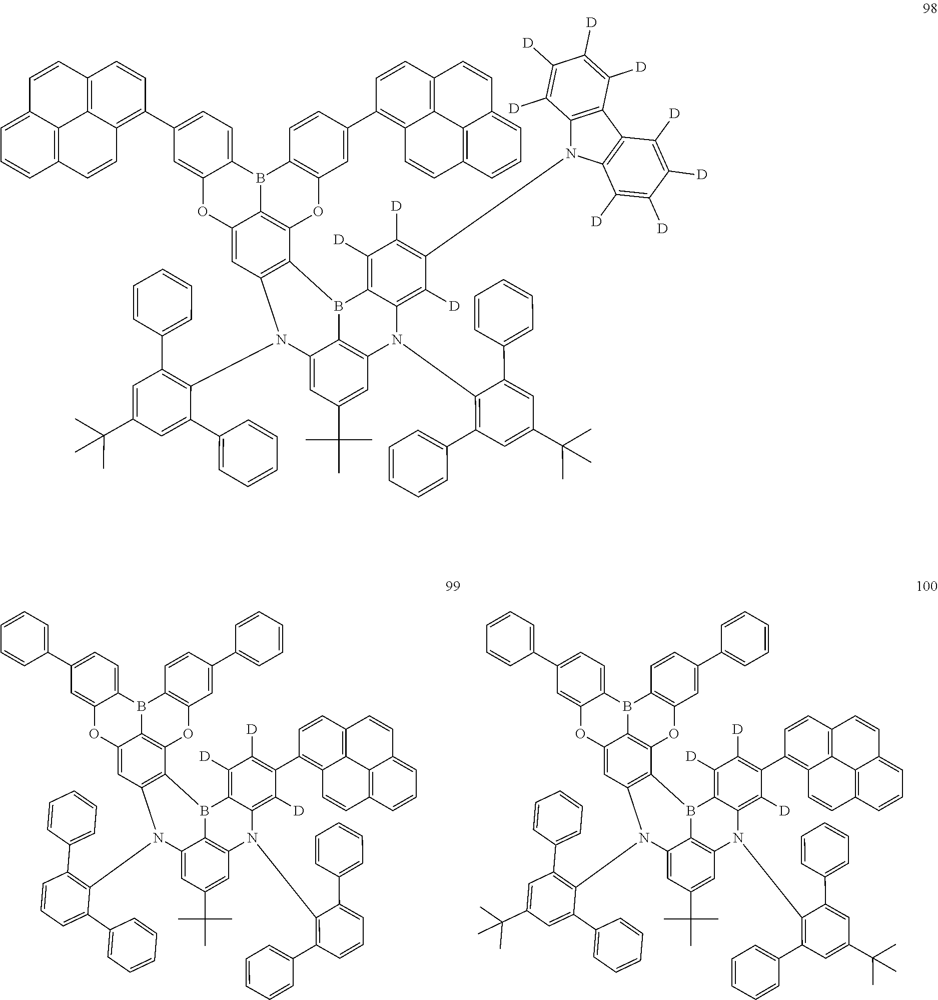

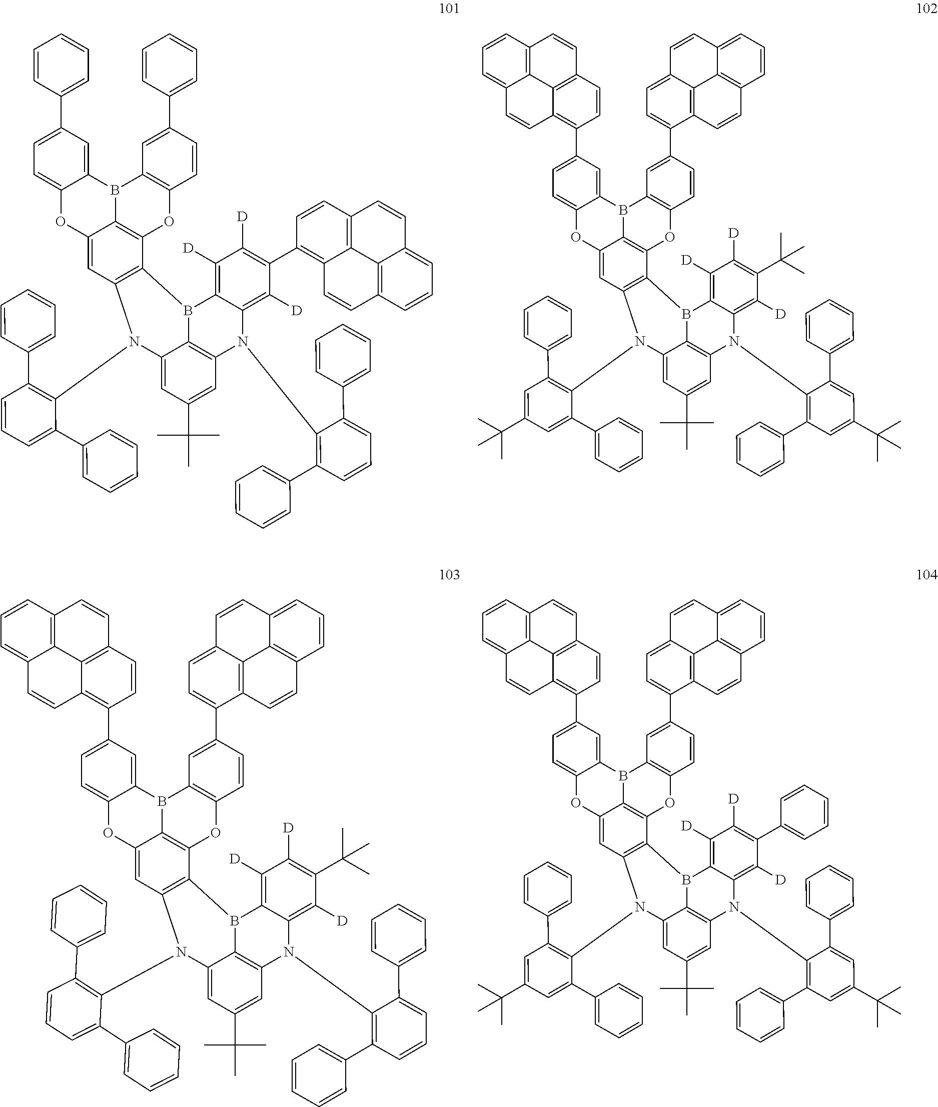

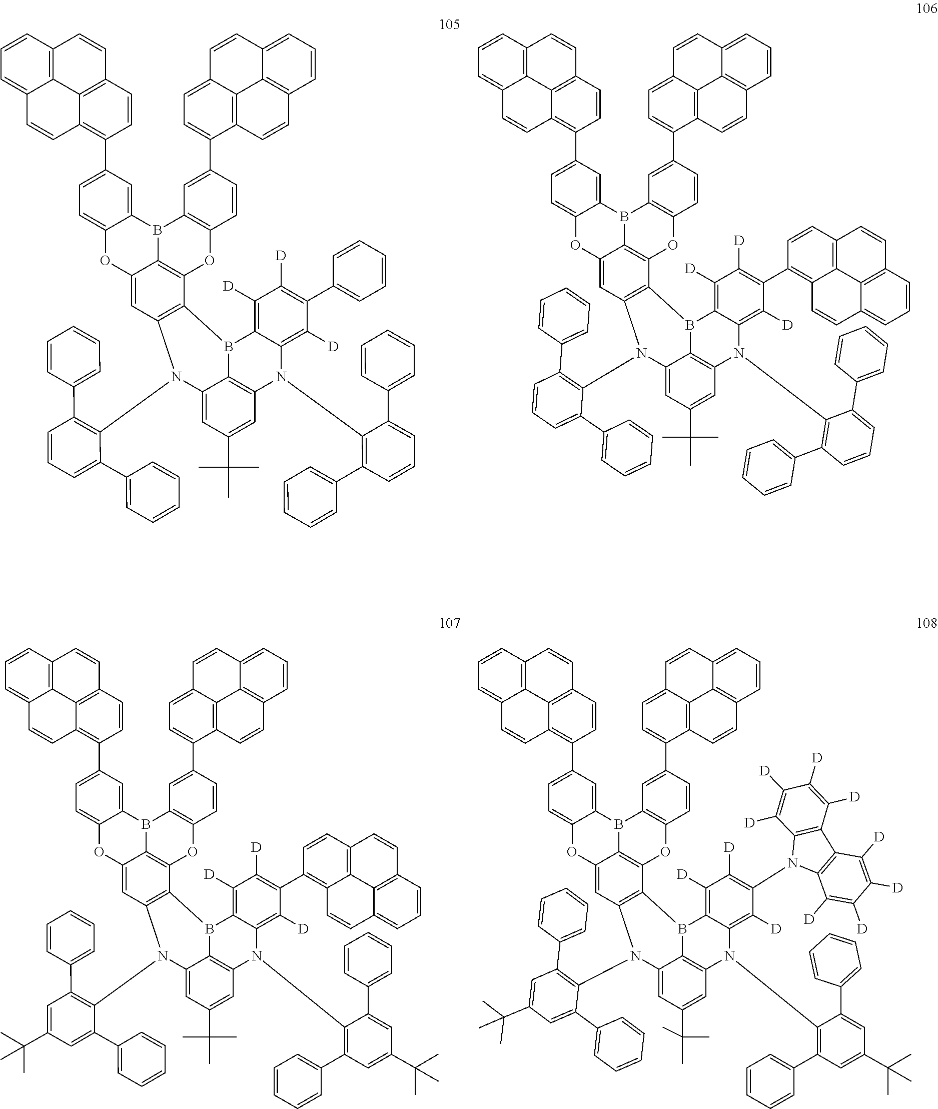

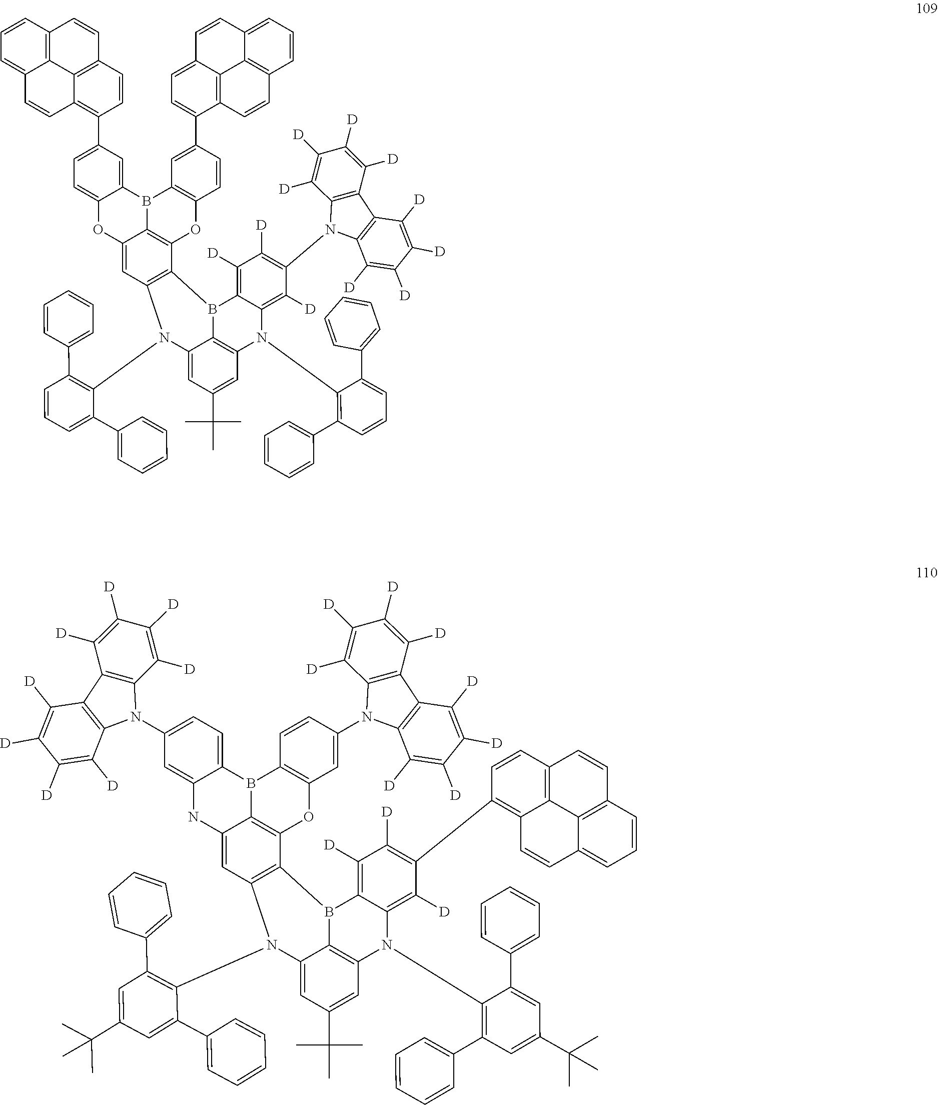

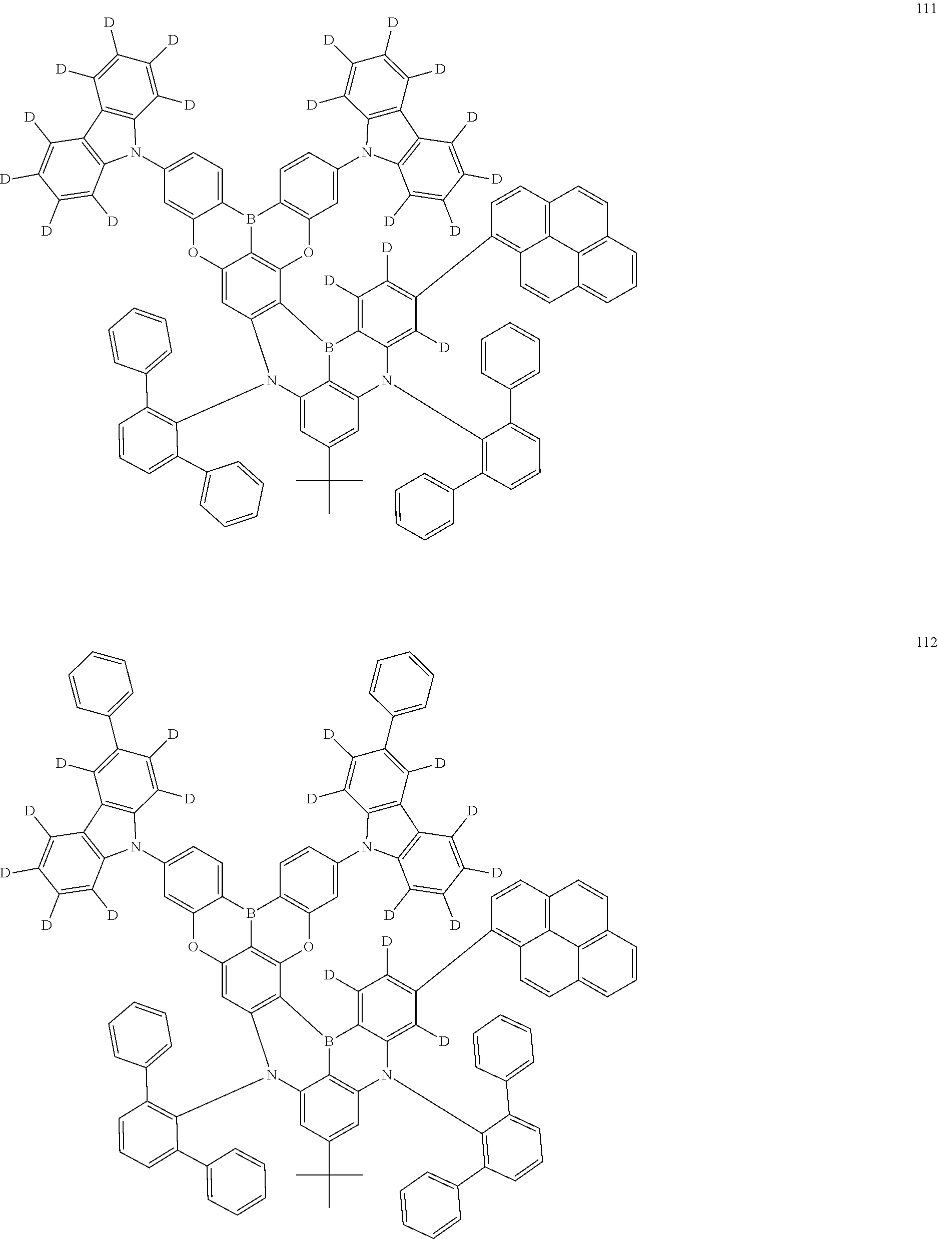

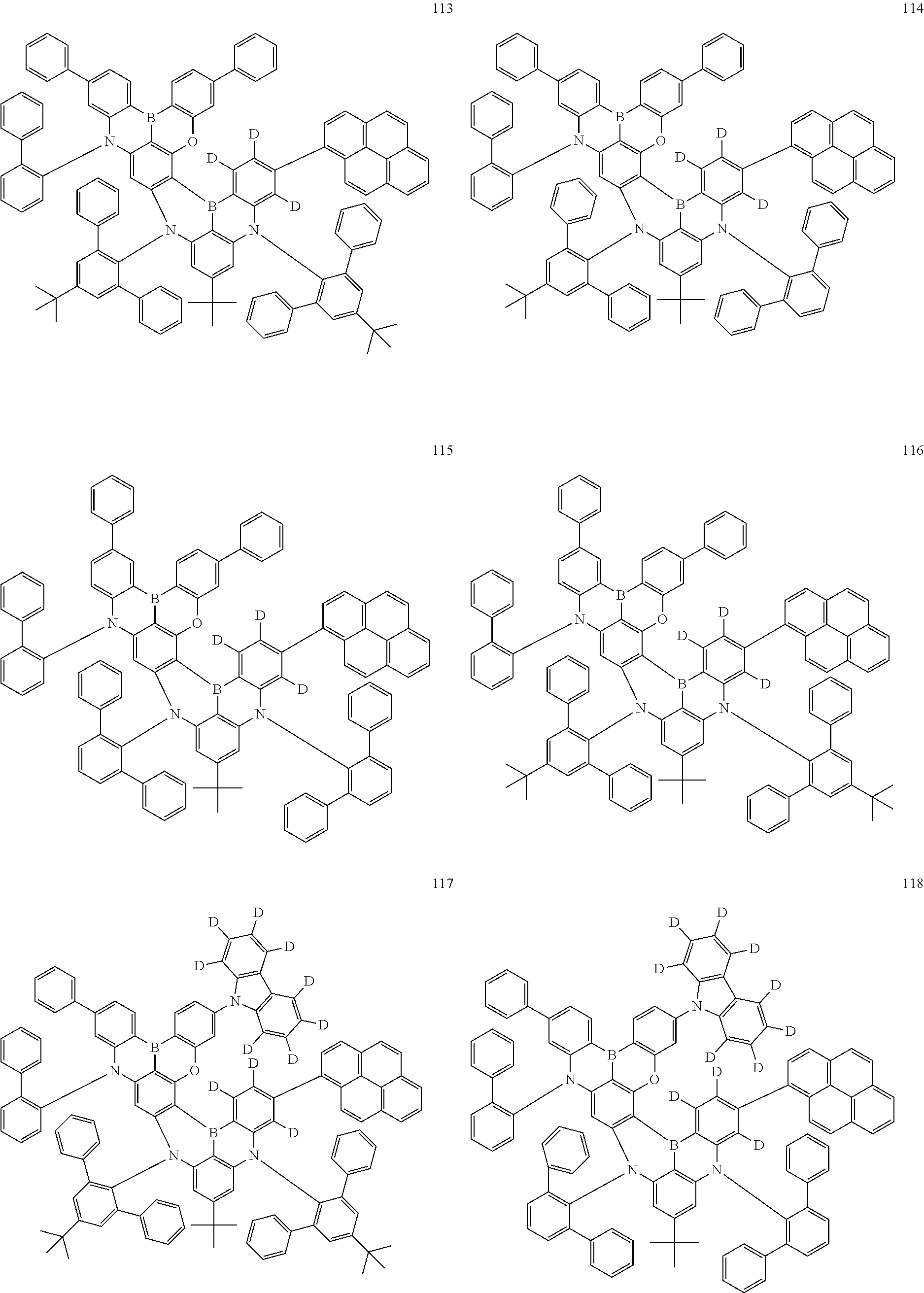

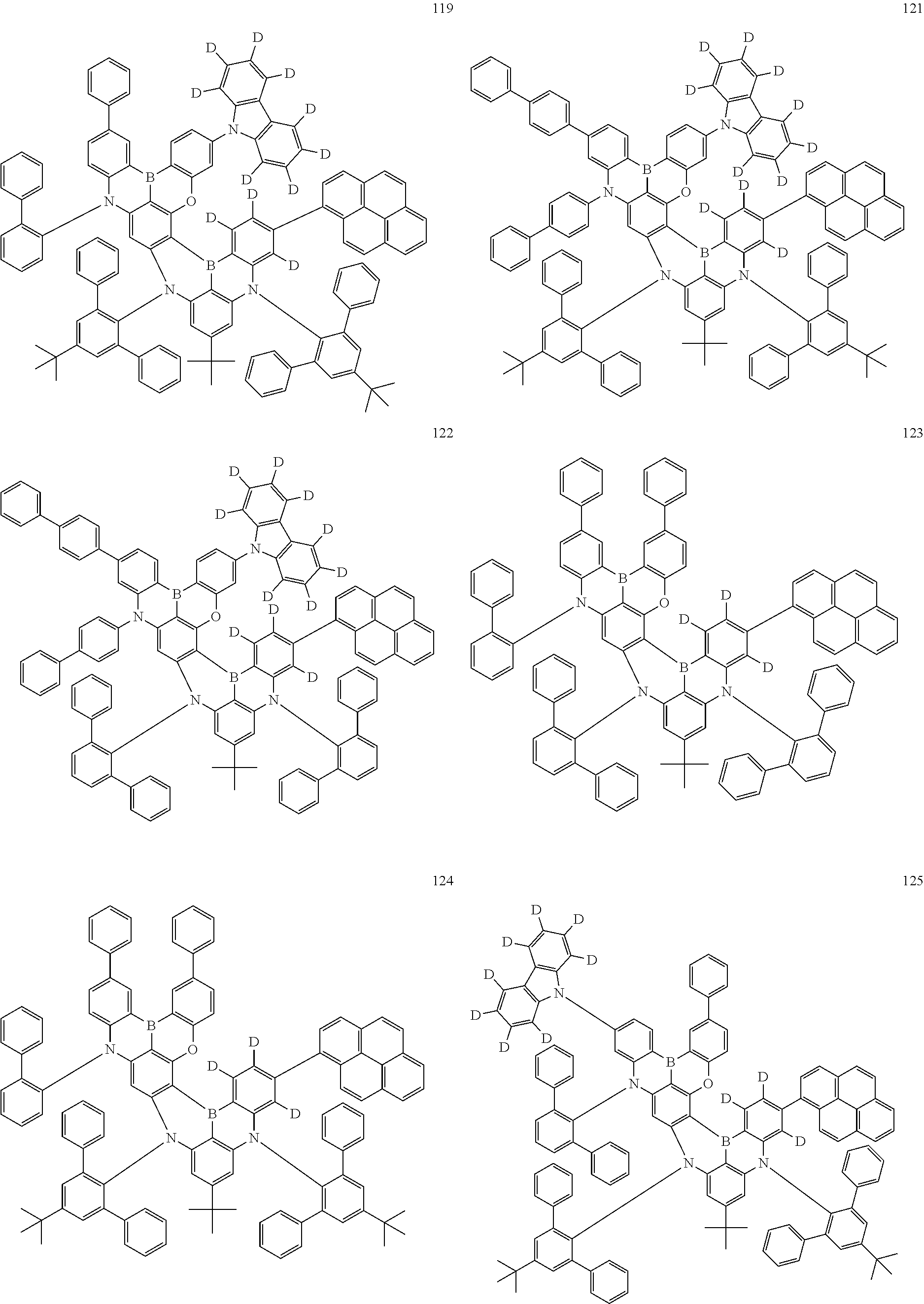

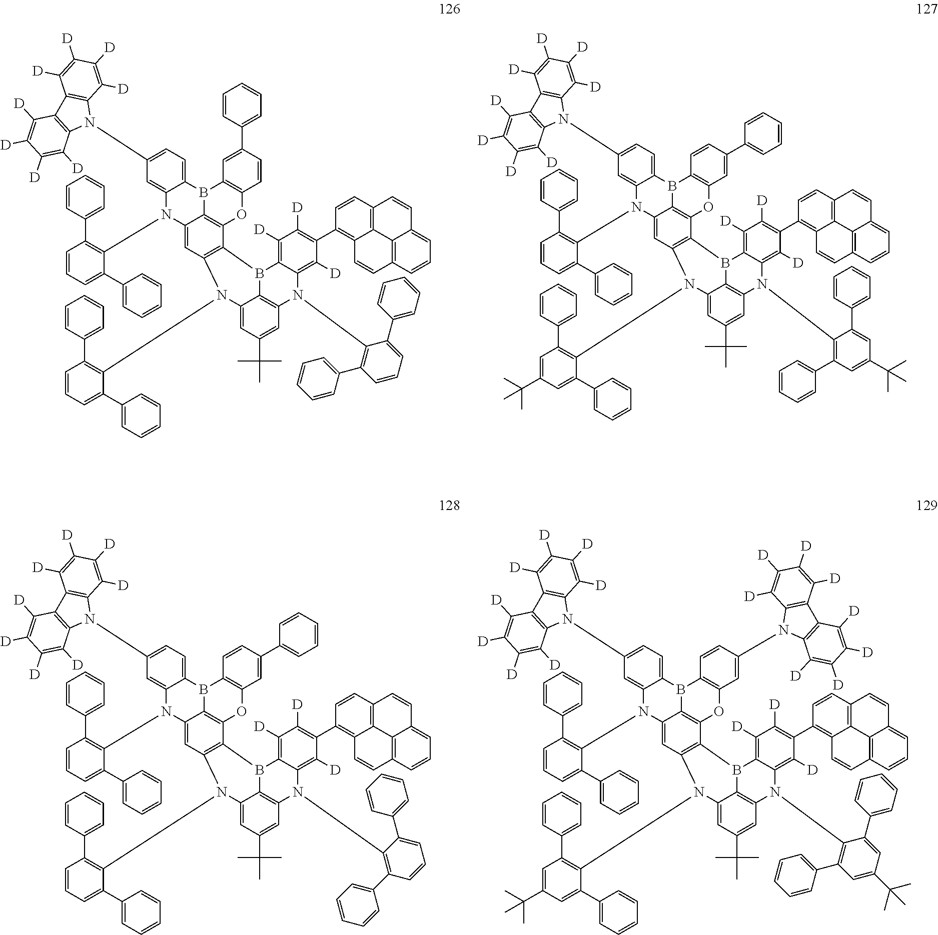

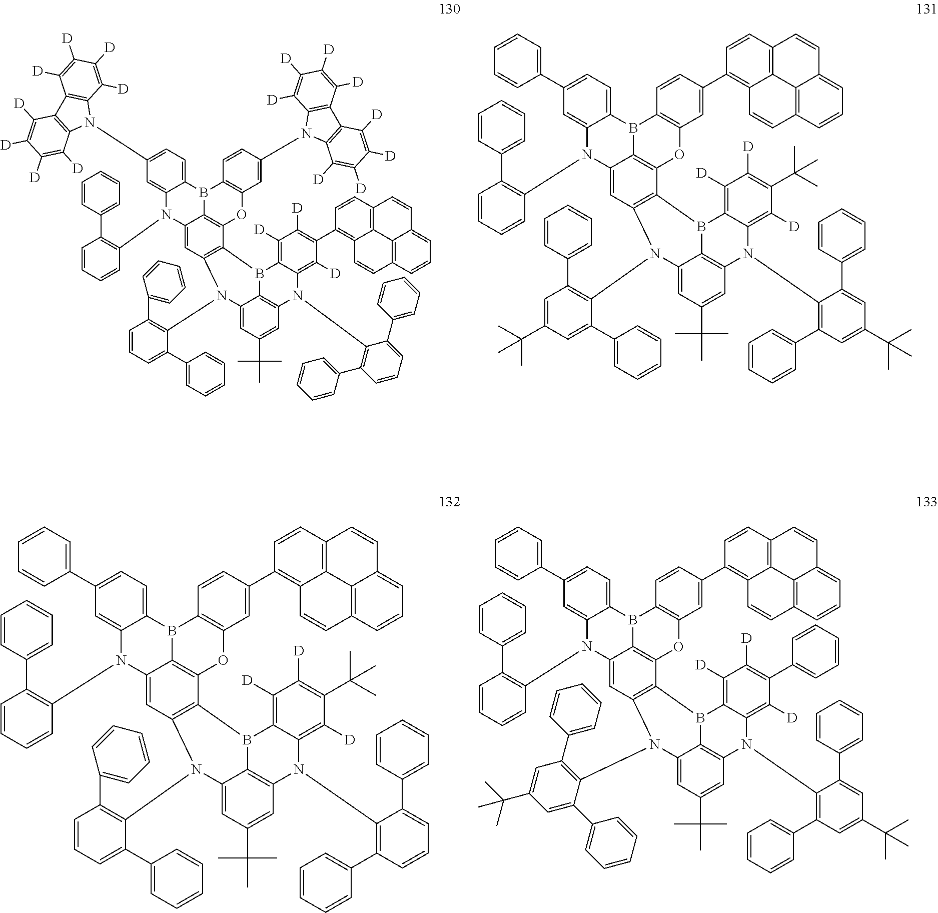

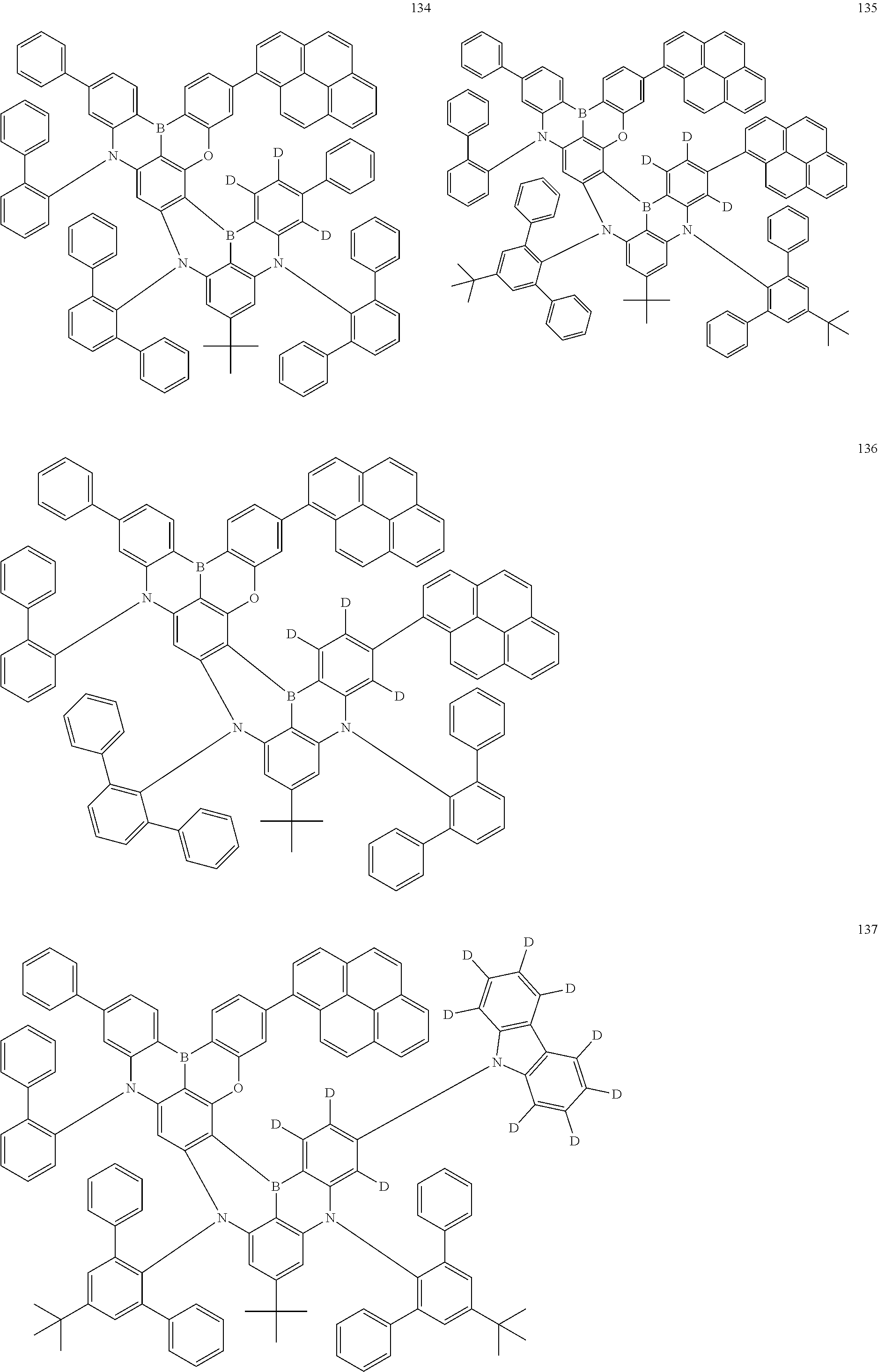

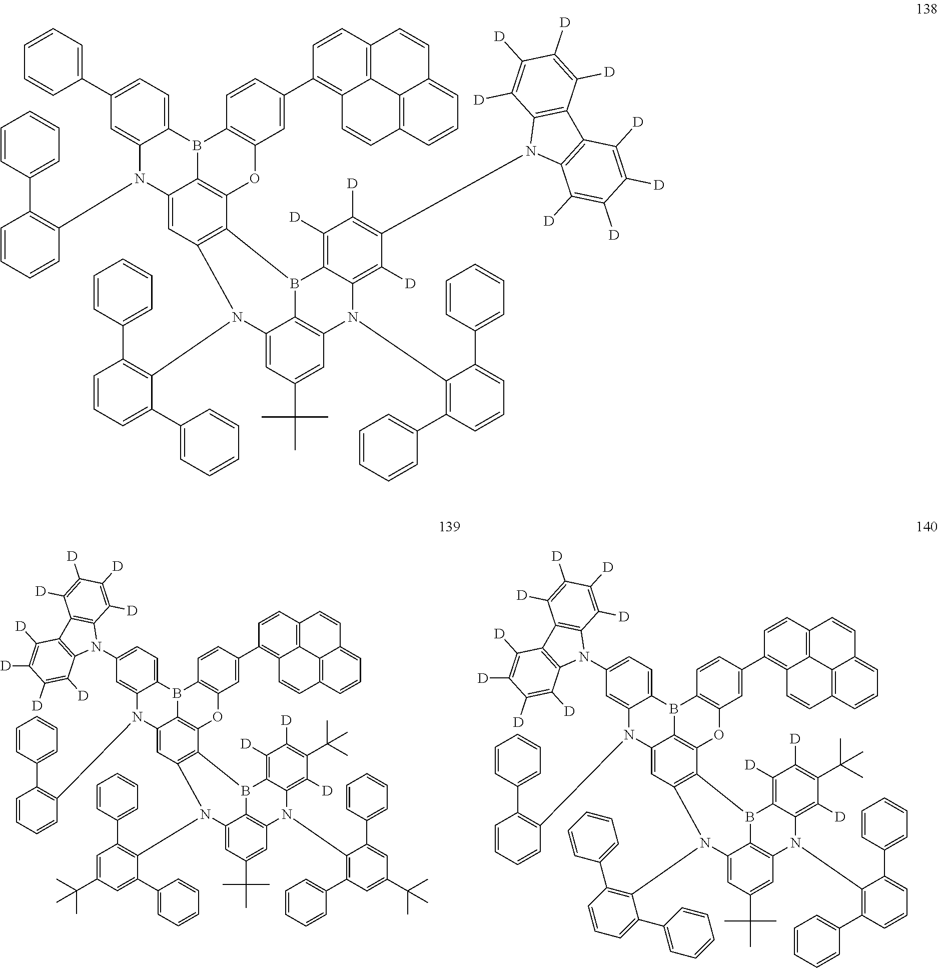

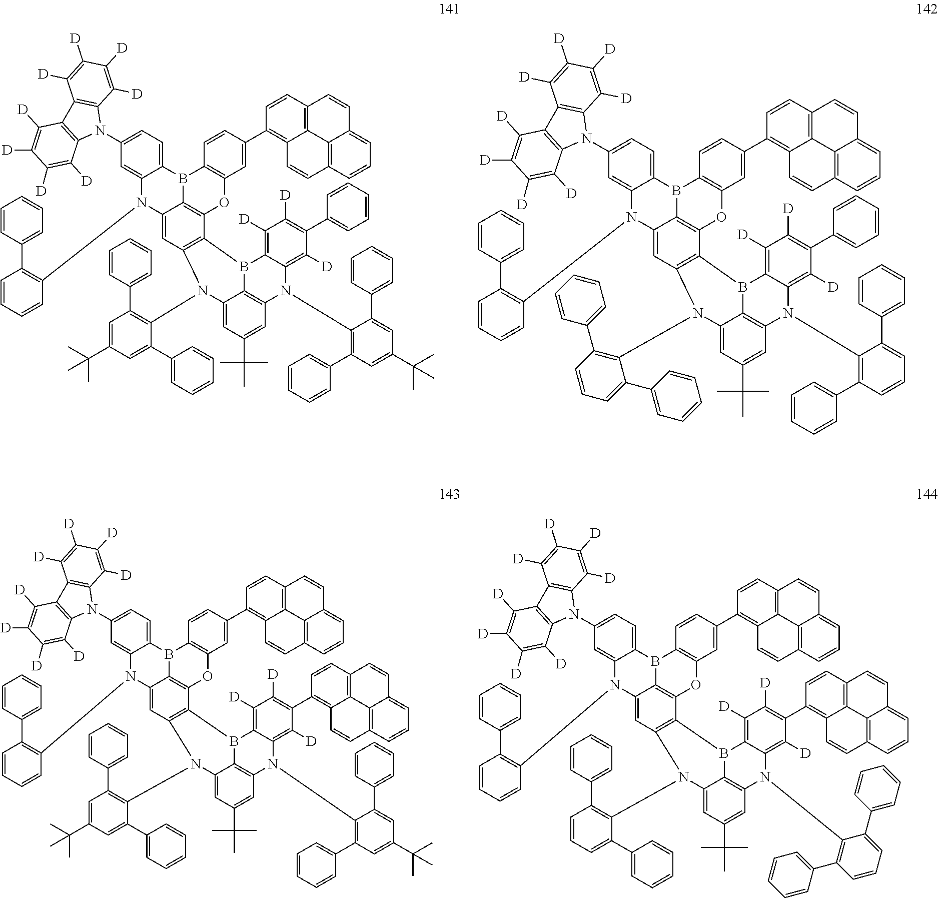

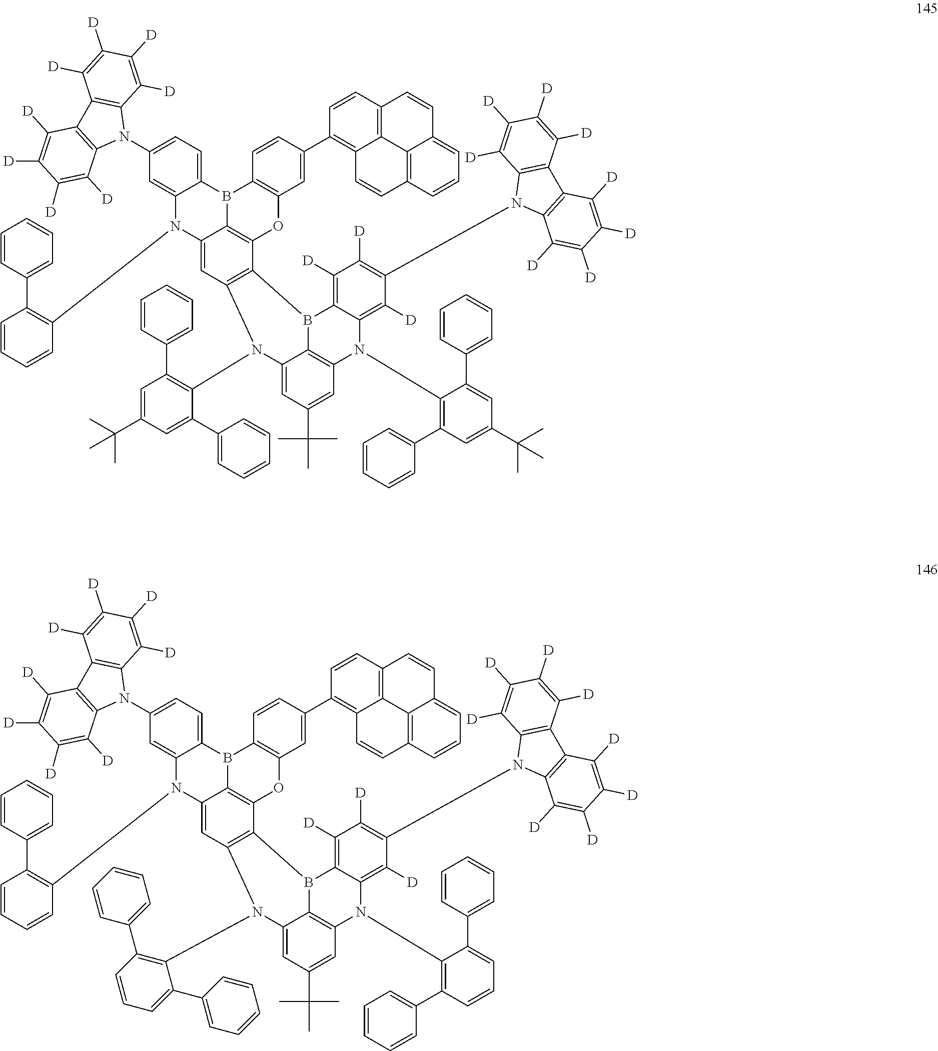

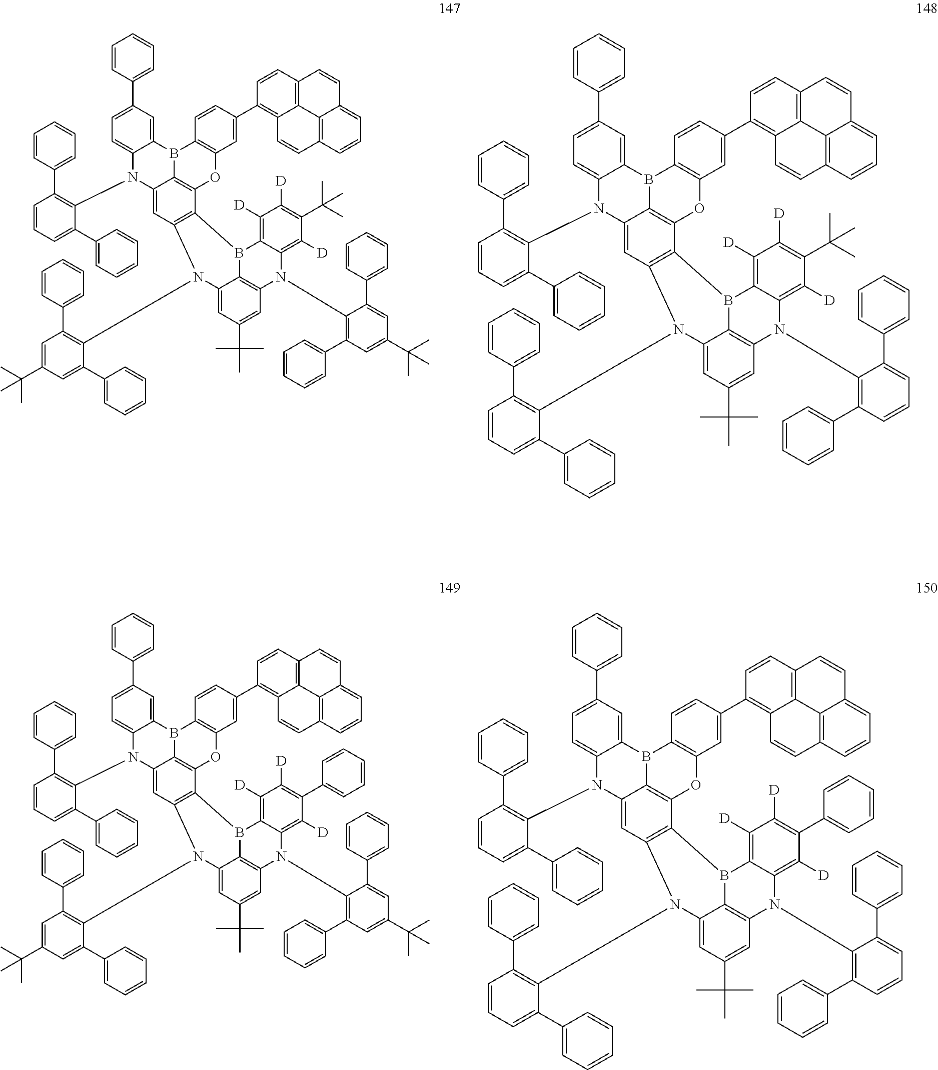

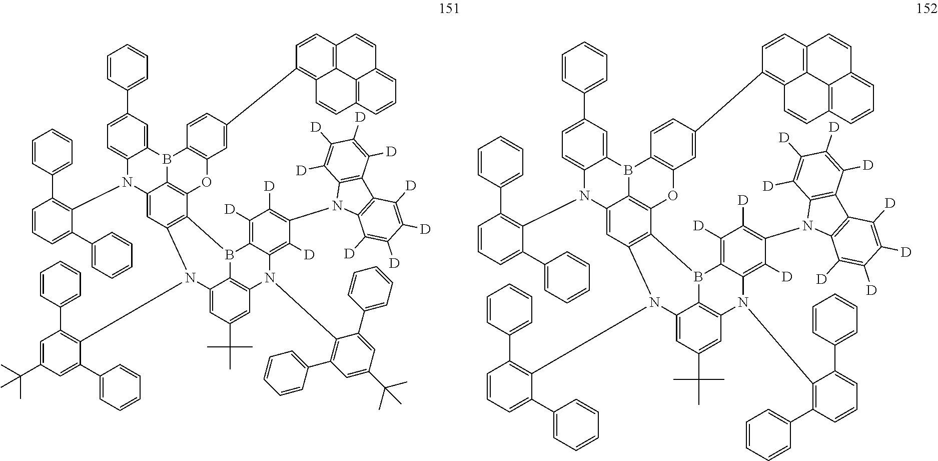

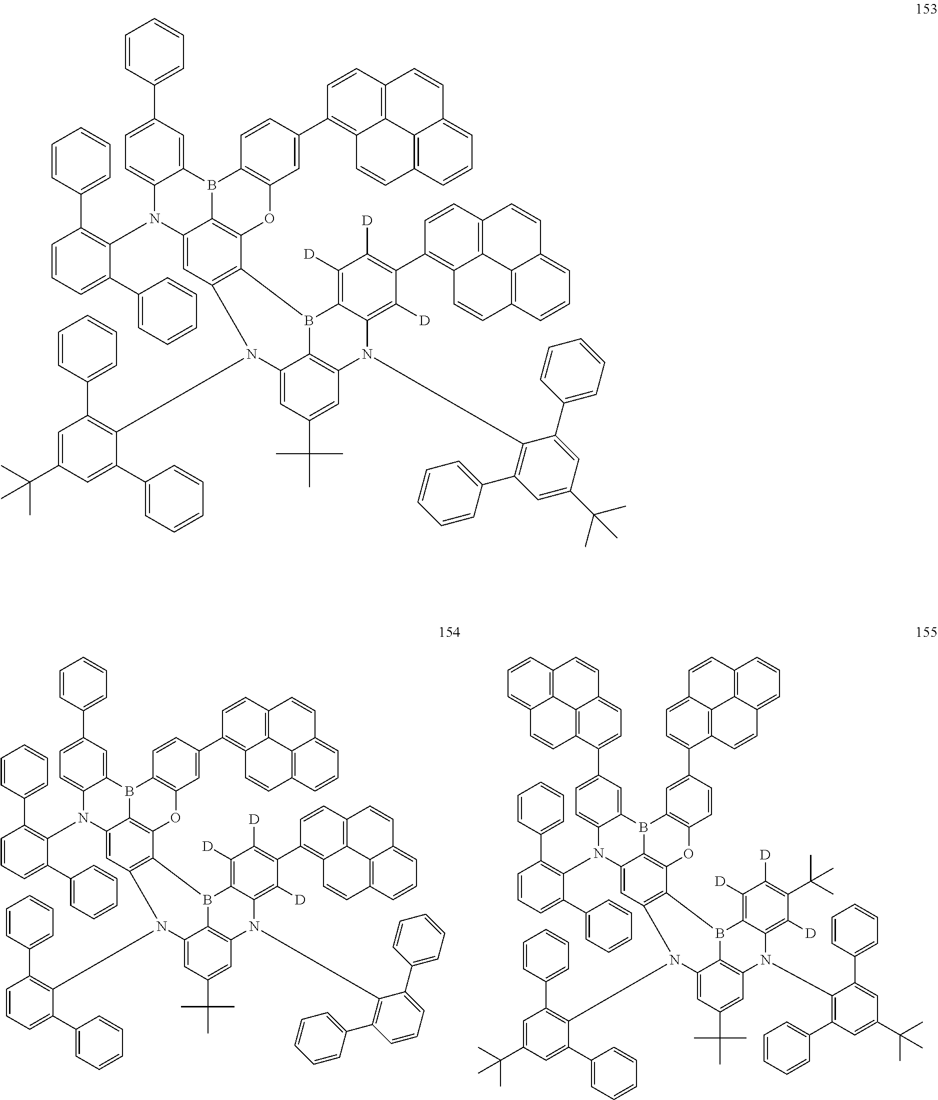

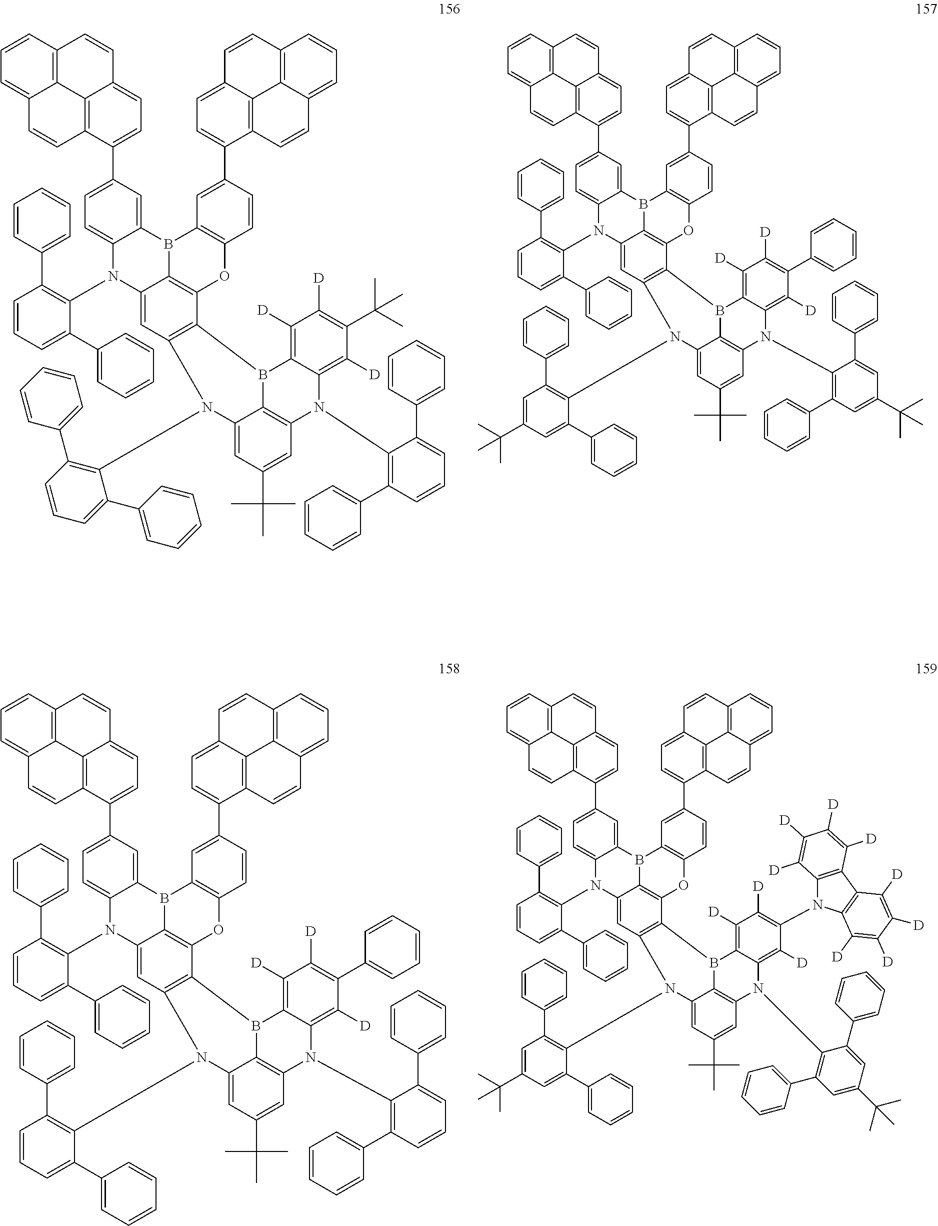

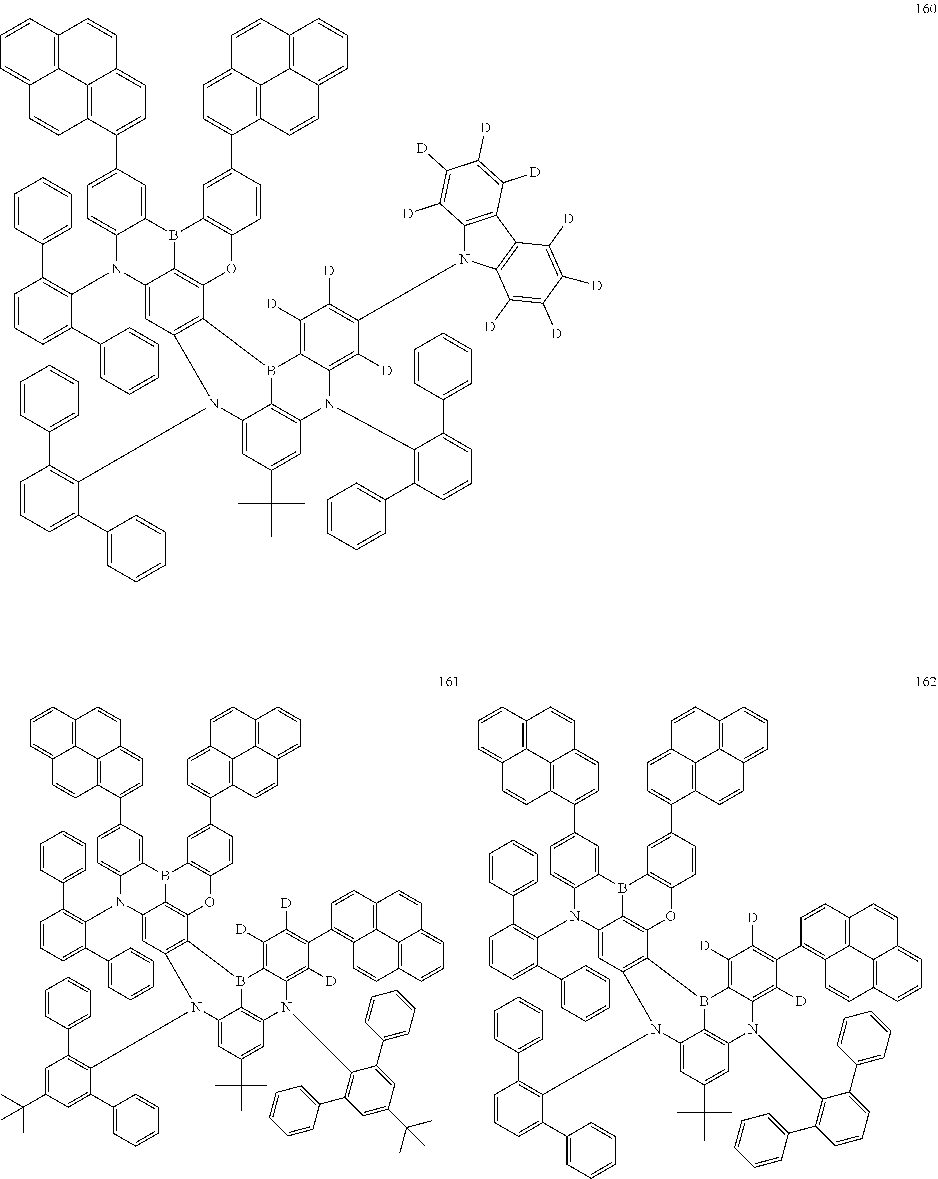

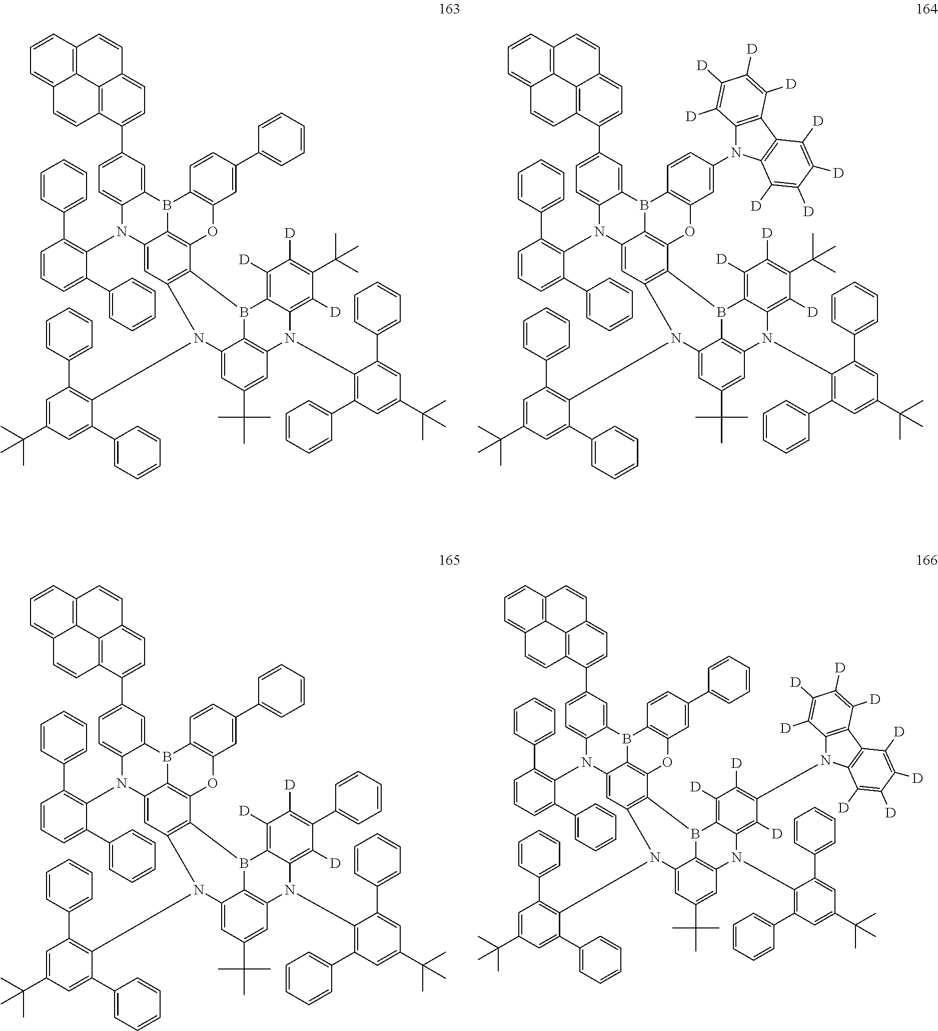

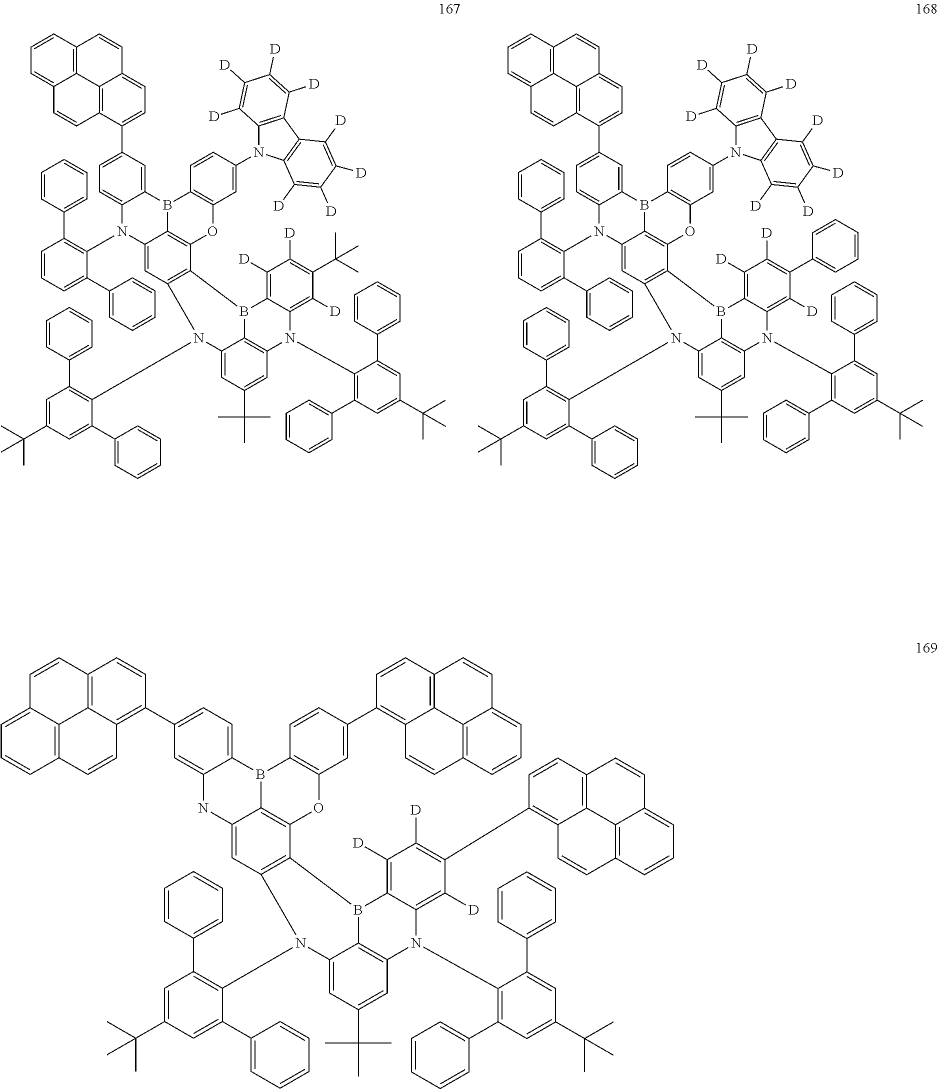

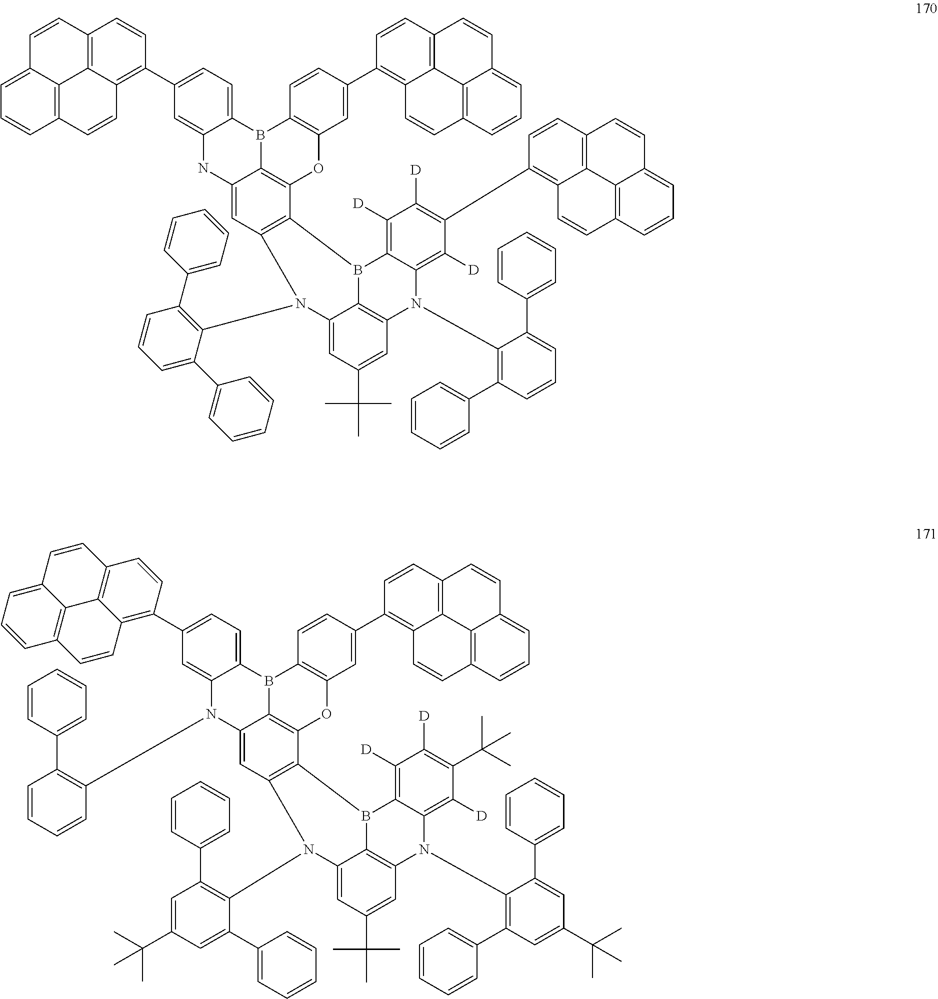 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3 ; [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1]

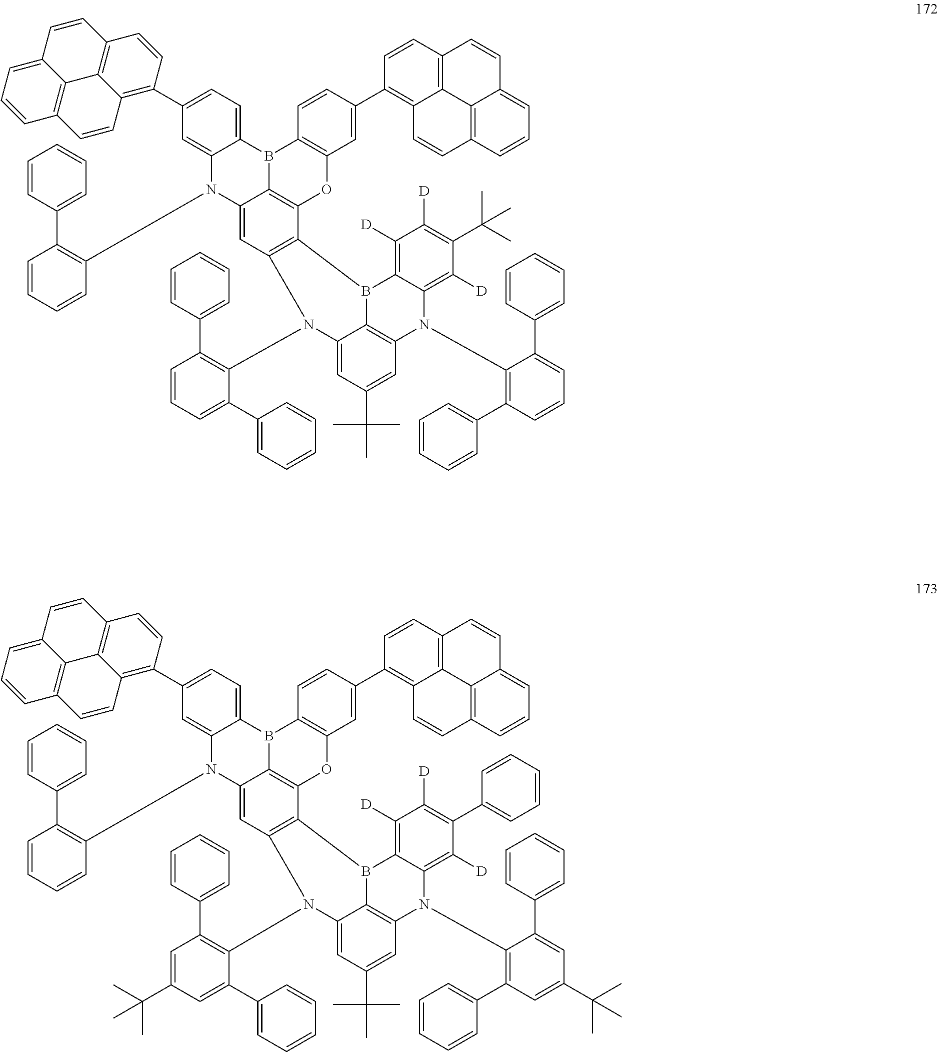 [SMILES: [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1 ; [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1]

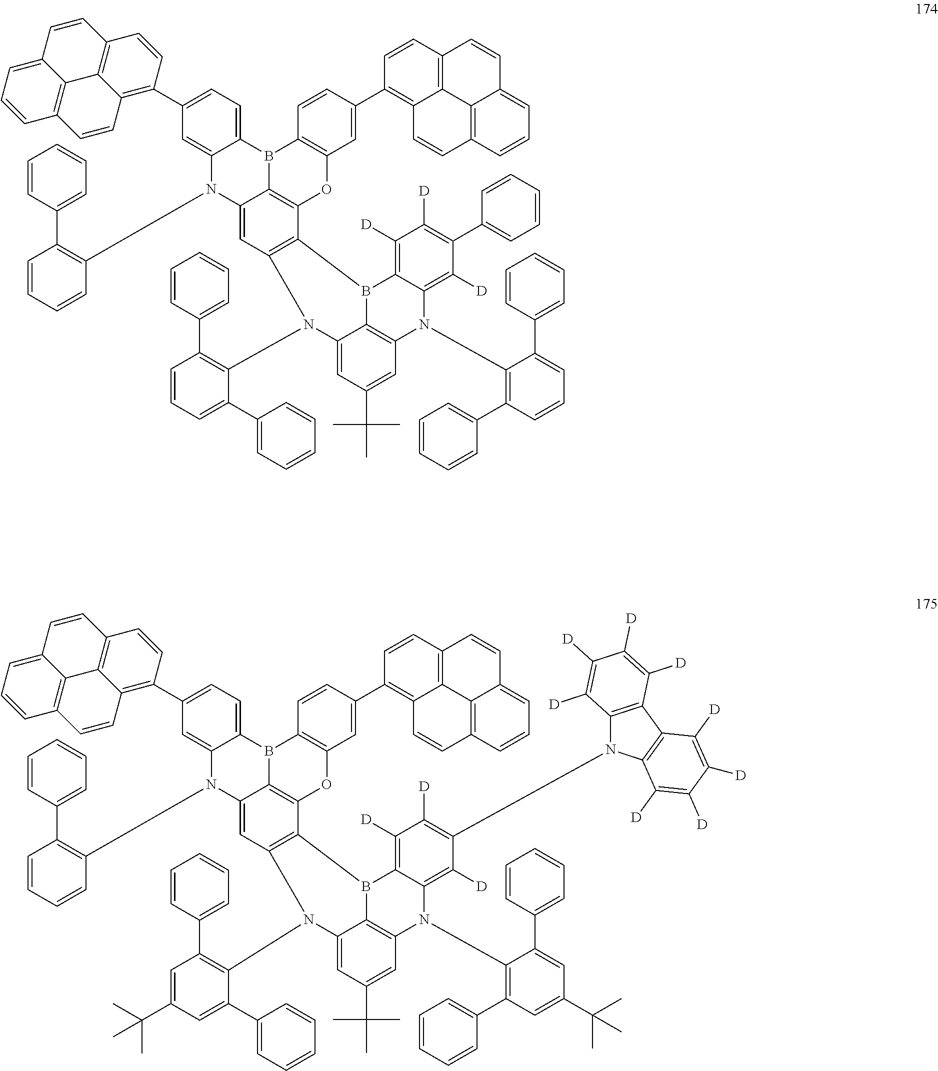

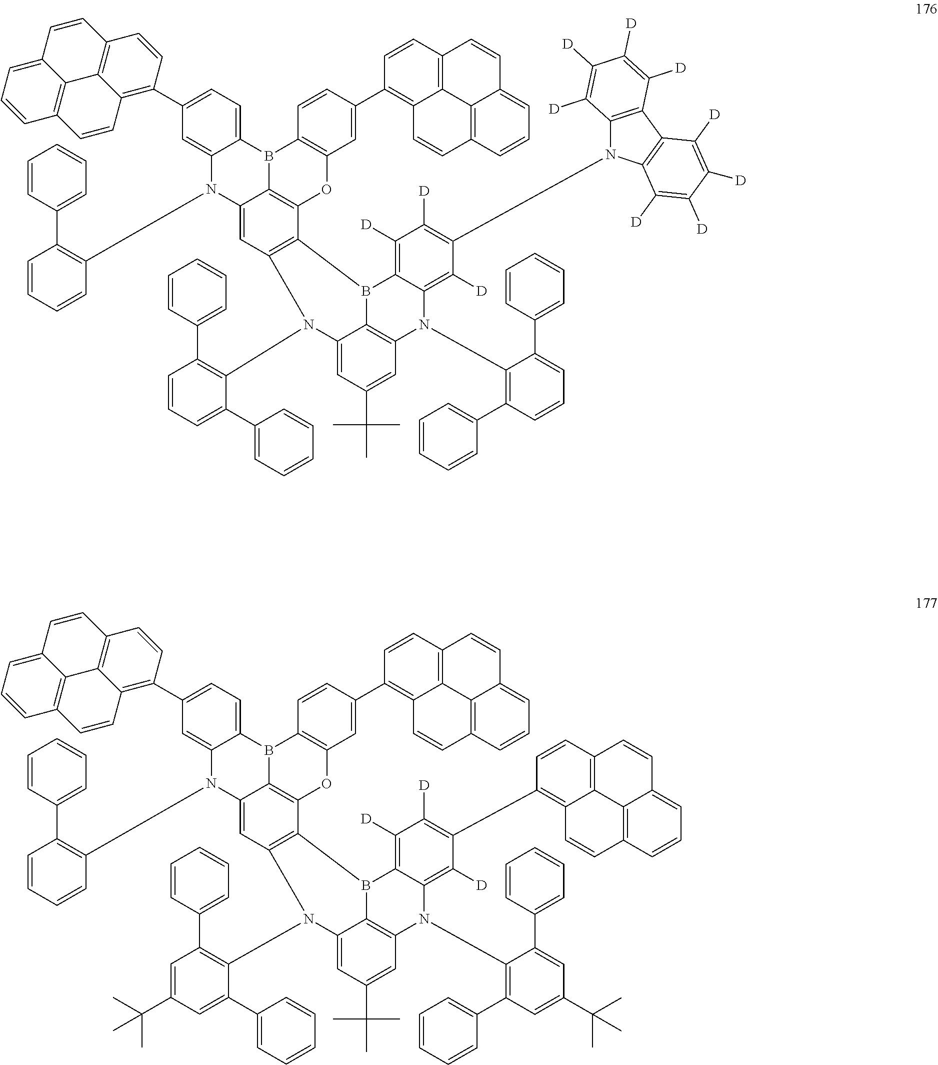

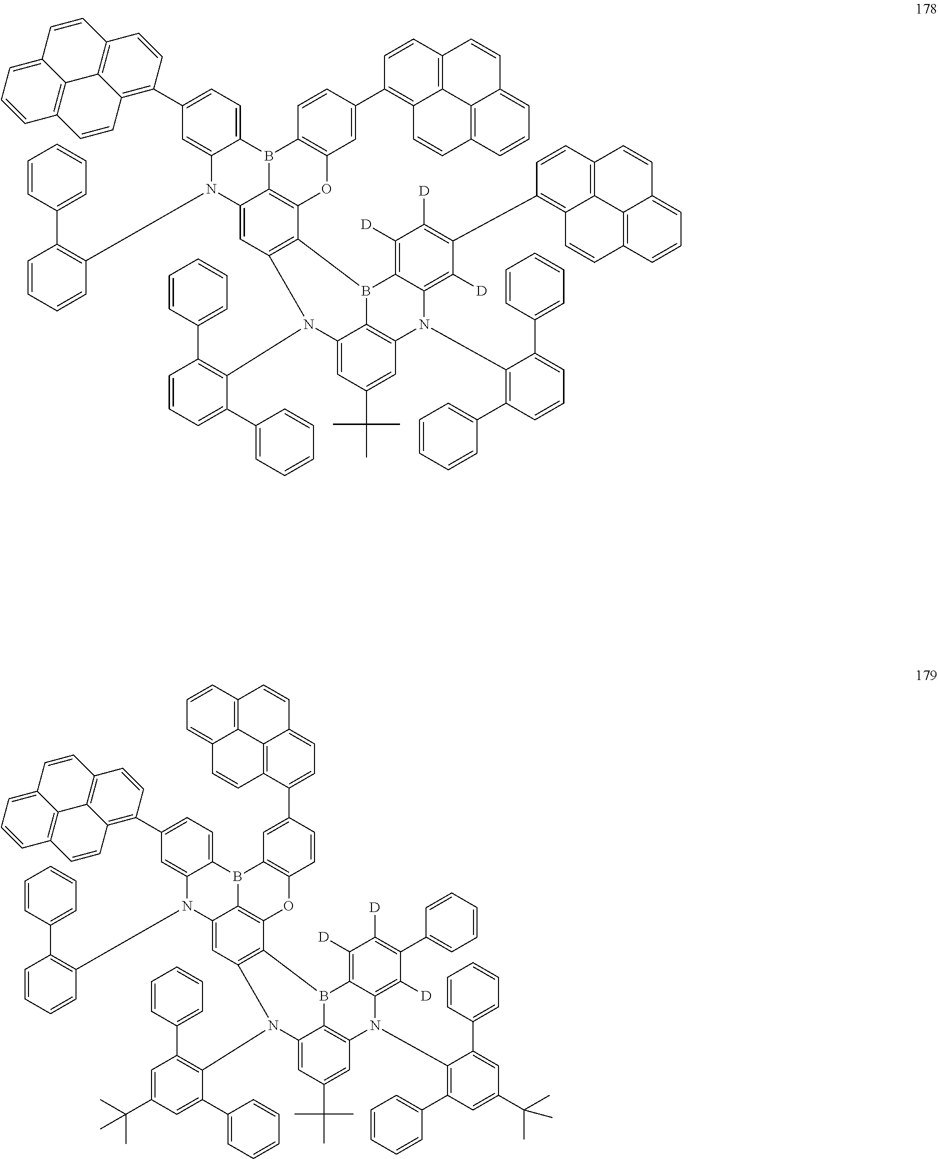 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1 ; [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1ccc(-c2ccc5ccc6cccc7ccc2c5c67)cc1B4c1ccc(-c2ccc4ccc5cccc6ccc2c4c56)cc1N3c1ccccc1-c1ccccc1]

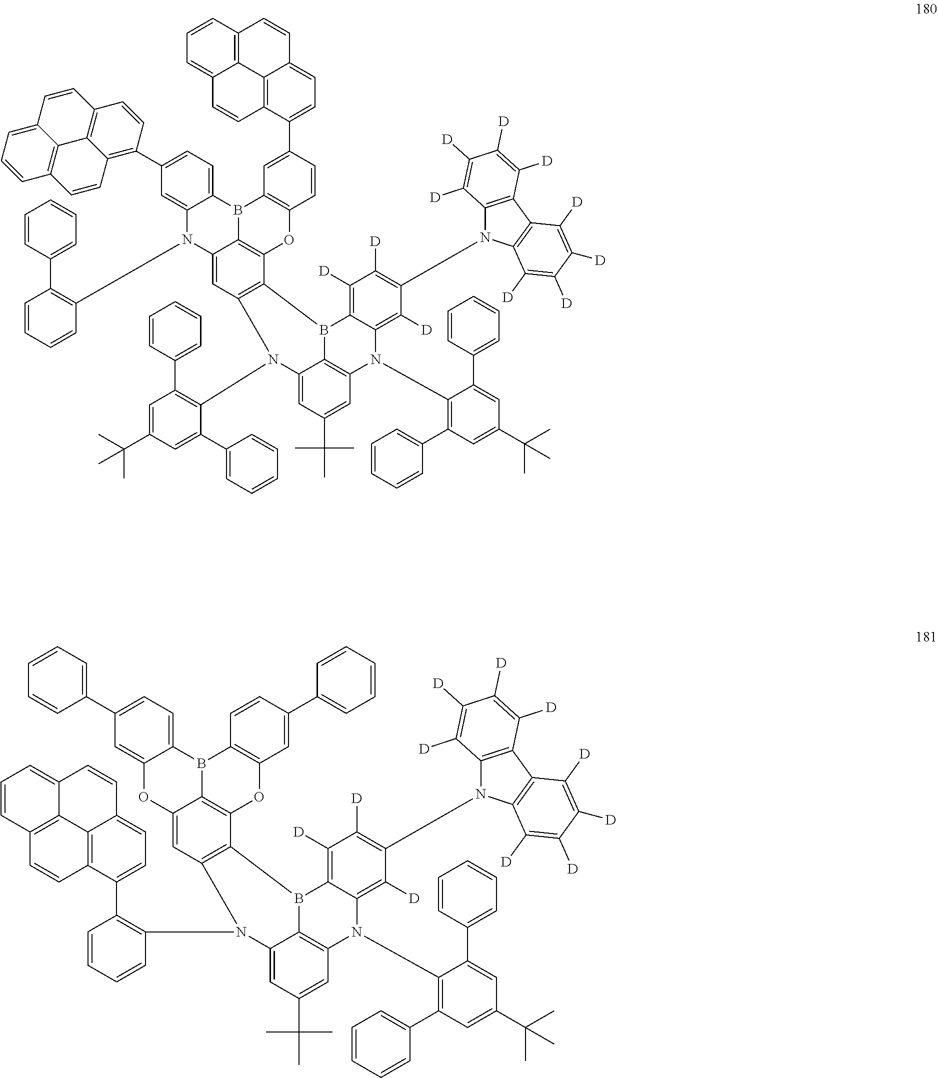

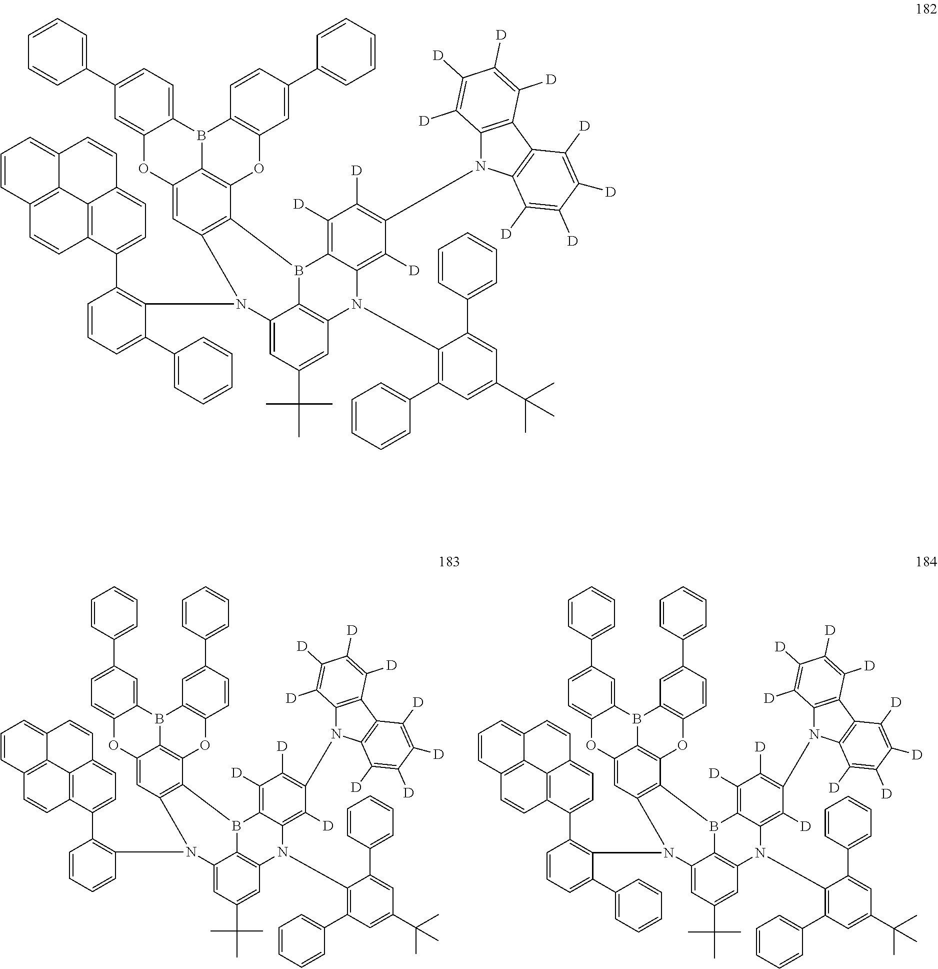

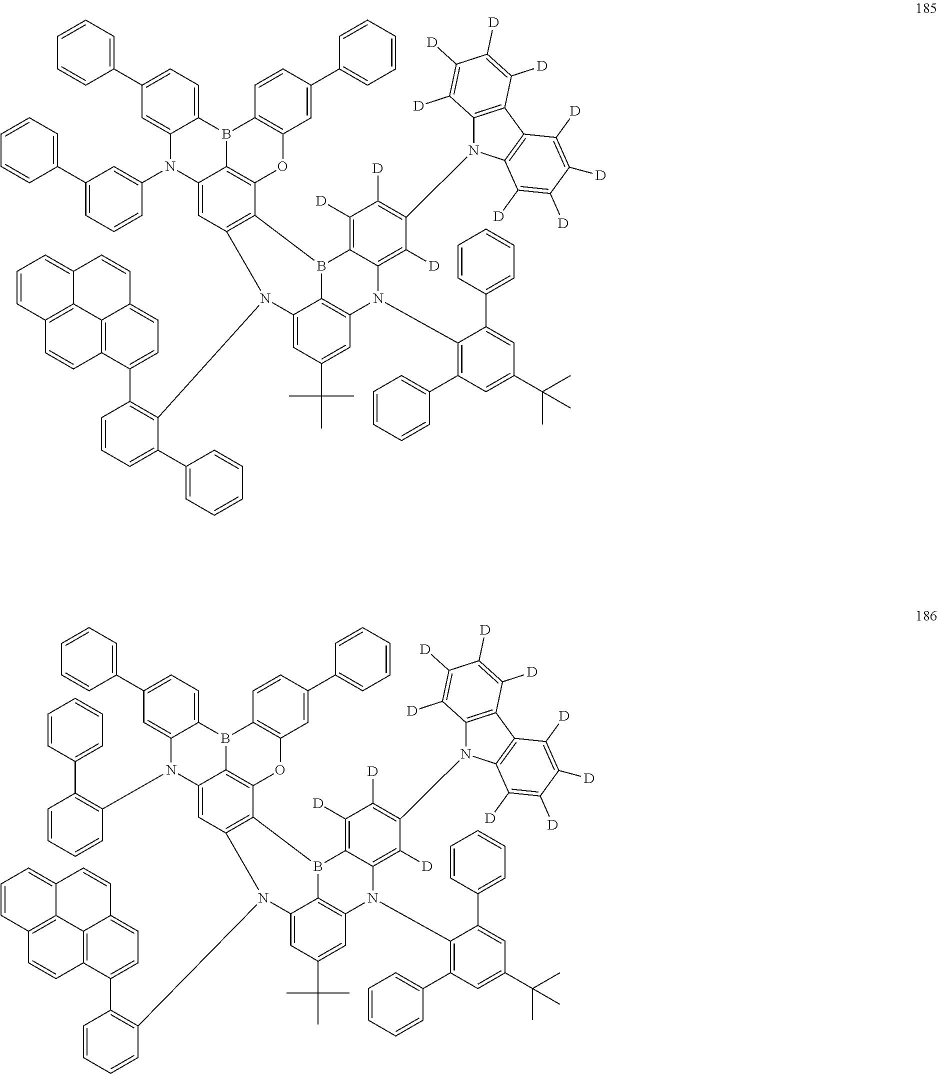

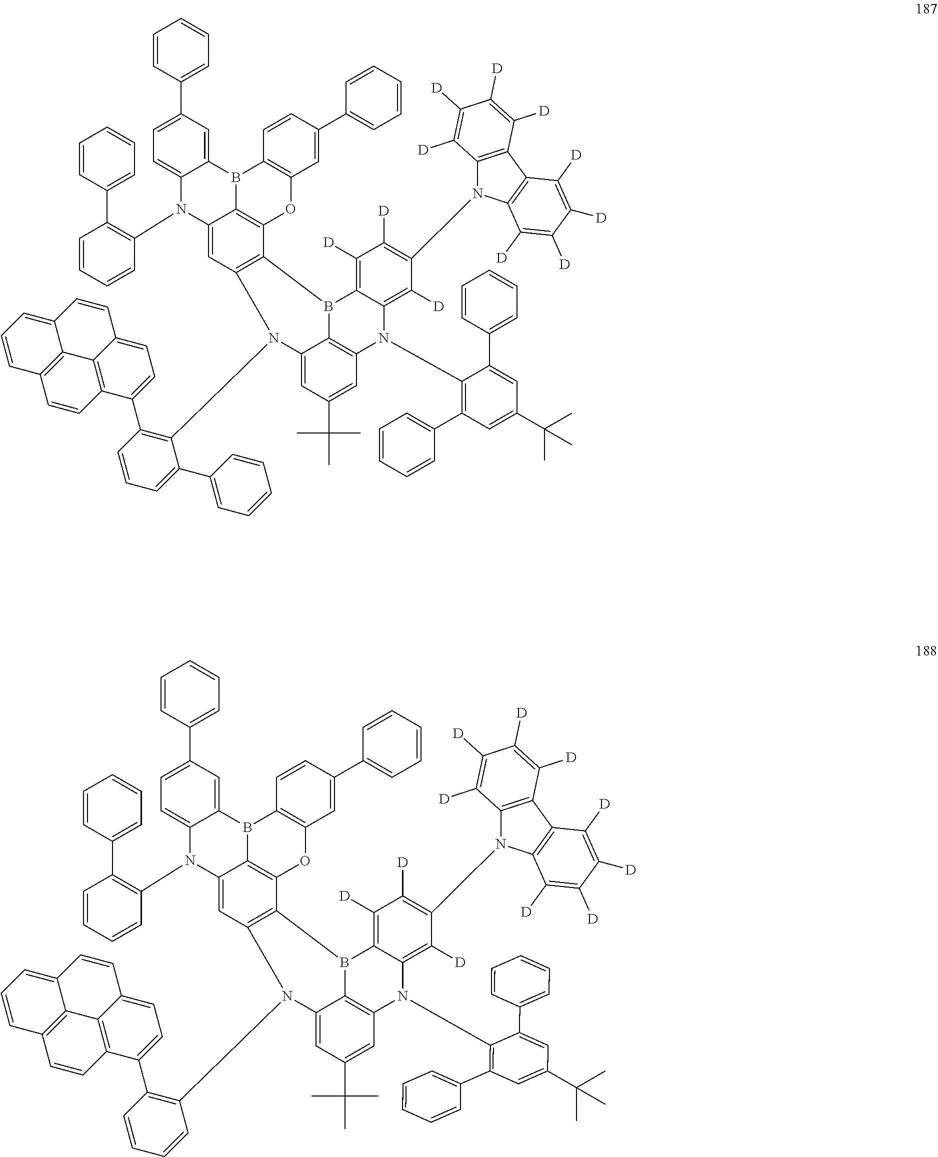

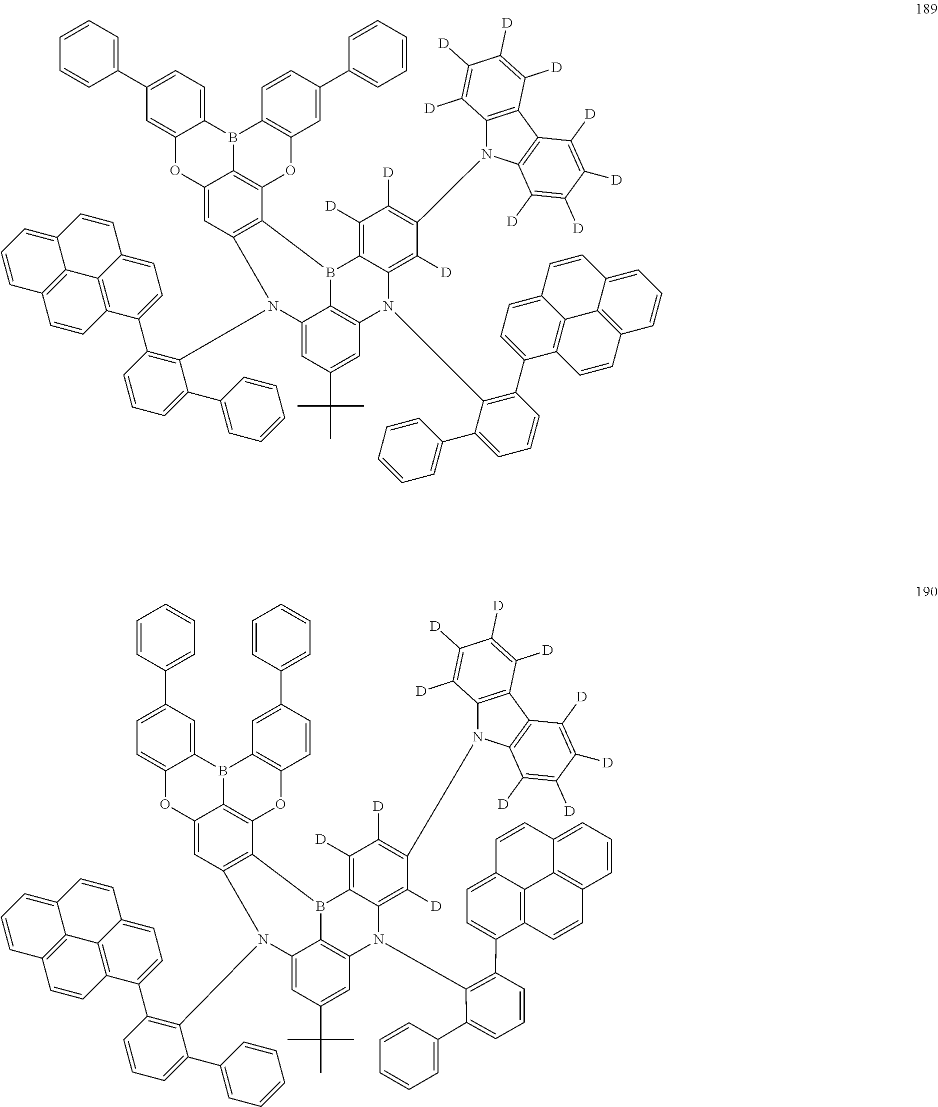

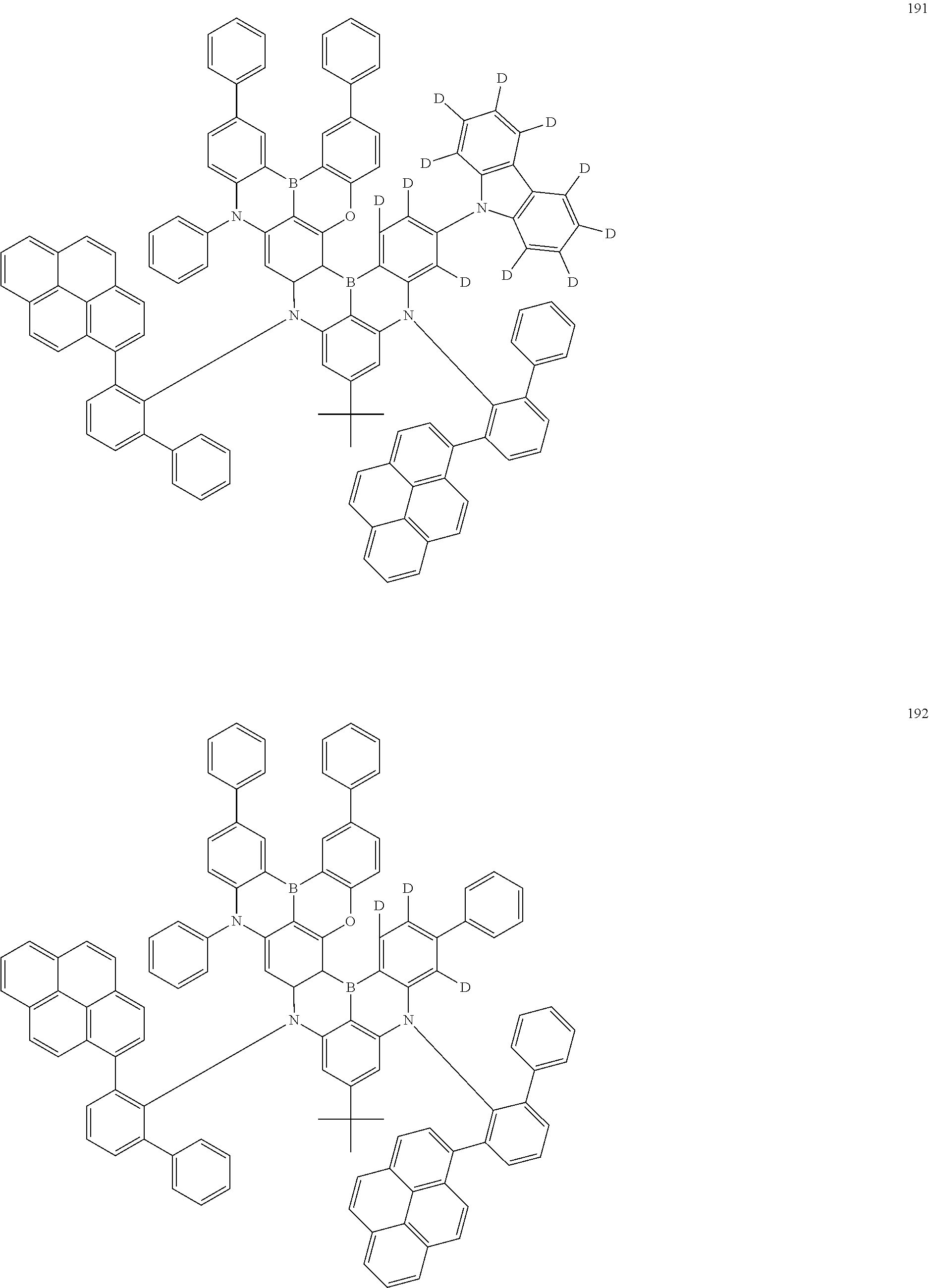 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N(c3c(-c4ccccc4)cccc3-c3ccc4ccc5cccc6ccc3c4c56)C3C=C4C5=C(Oc6ccc(-c7ccccc7)cc6B5c5cc(-c6ccccc6)ccc5N4c4ccccc4)C13)N2c1c(-c2ccccc2)cccc1-c1ccc2ccc3cccc4ccc1c2c34 ; [2H]c1c([2H])c(-c2ccccc2)c([2H])c2c1B1c3c(cc(C(C)(C)C)cc3N(c3c(-c4ccccc4)cccc3-c3ccc4ccc5cccc6ccc3c4c56)C3C=C4C5=C(Oc6ccc(-c7ccccc7)cc6B5c5cc(-c6ccccc6)ccc5N4c4ccccc4)C13)N2c1c(-c2ccccc2)cccc1-c1ccc2ccc3cccc4ccc1c2c34]

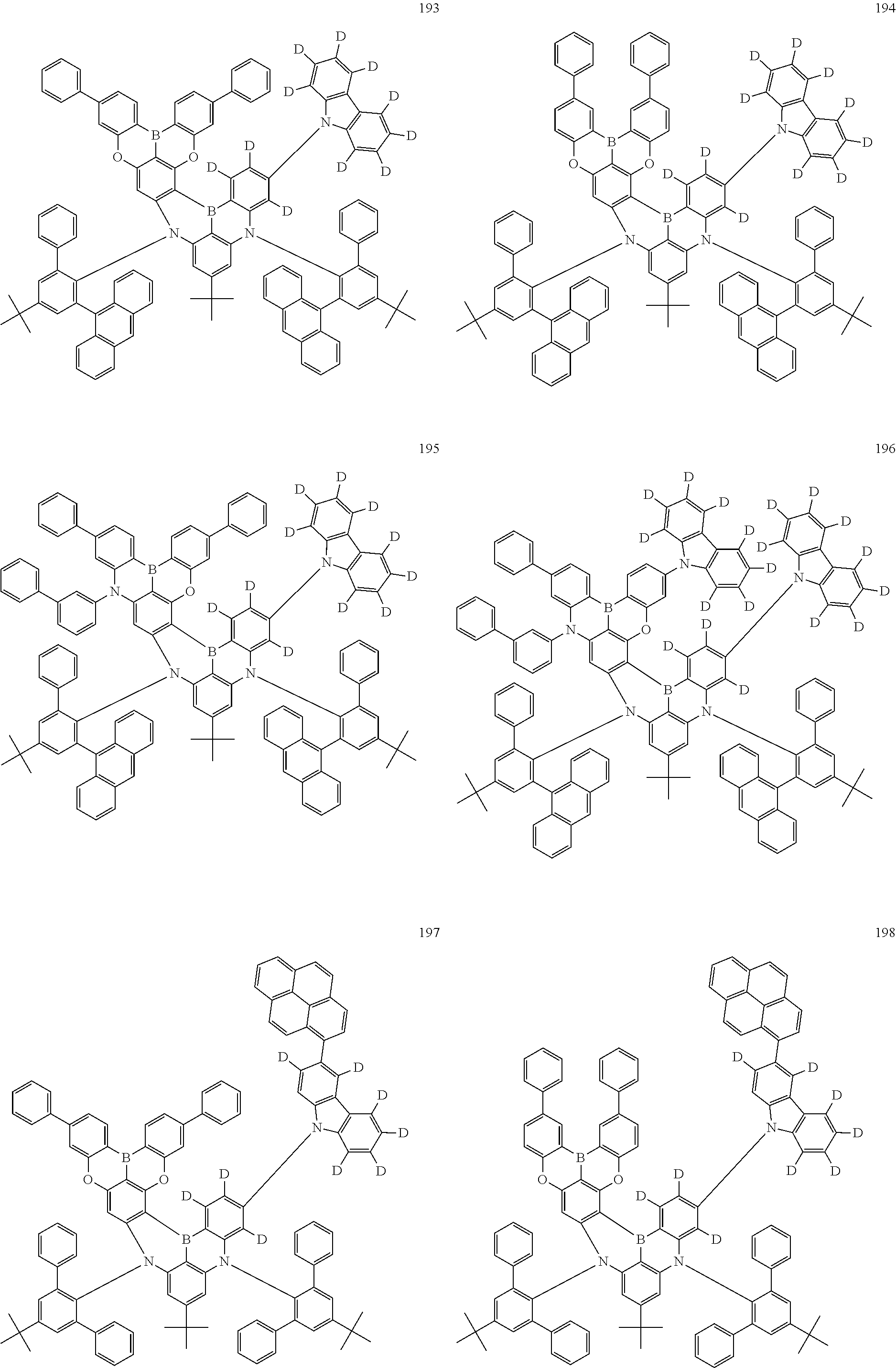

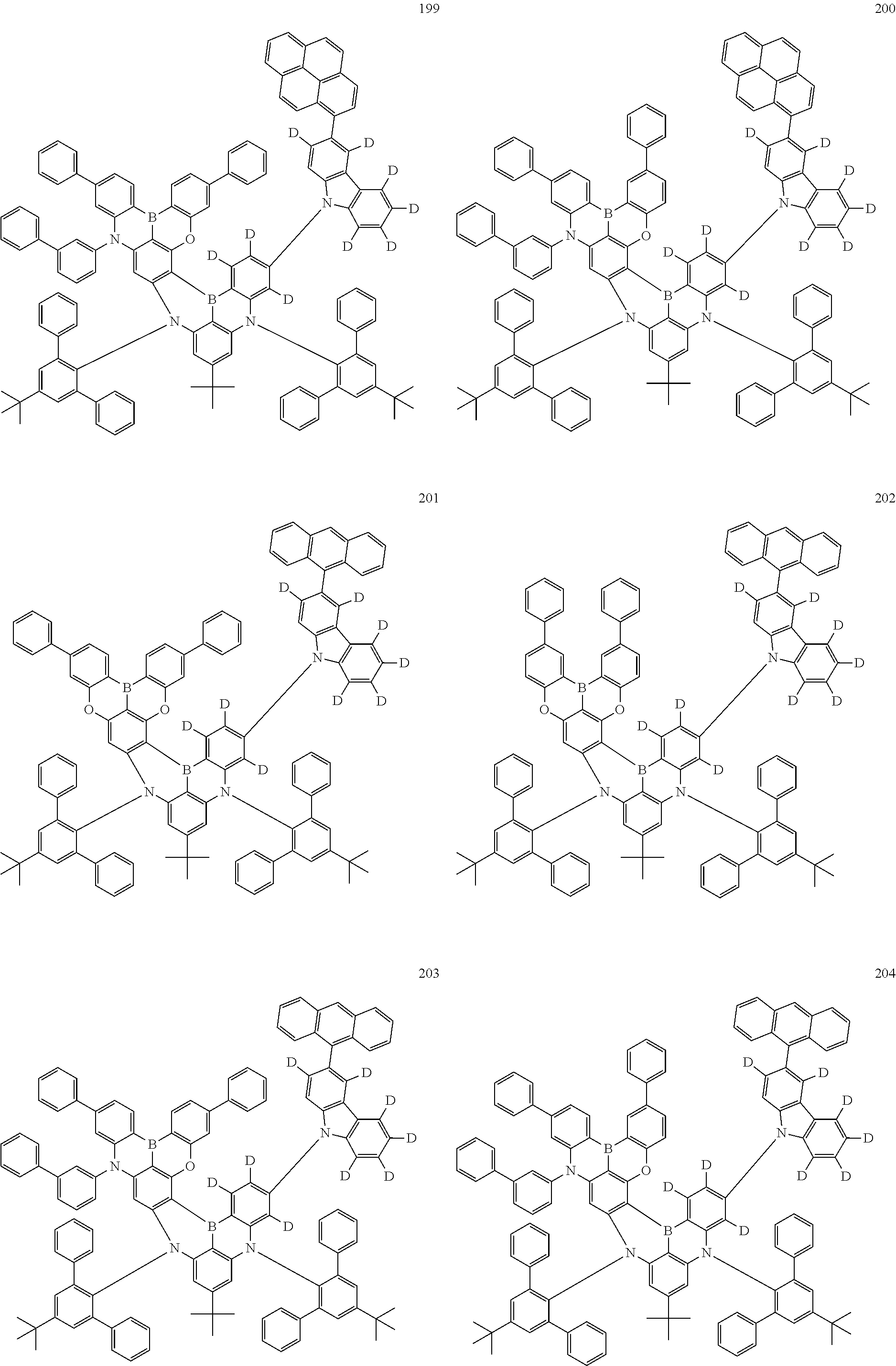

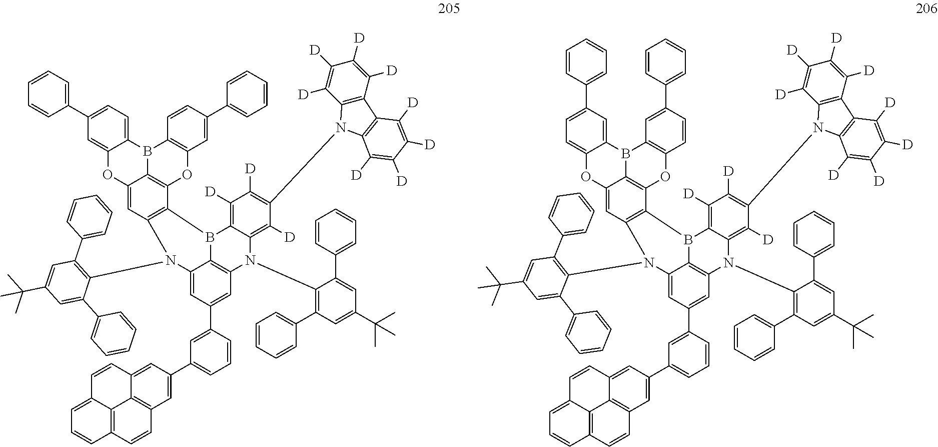

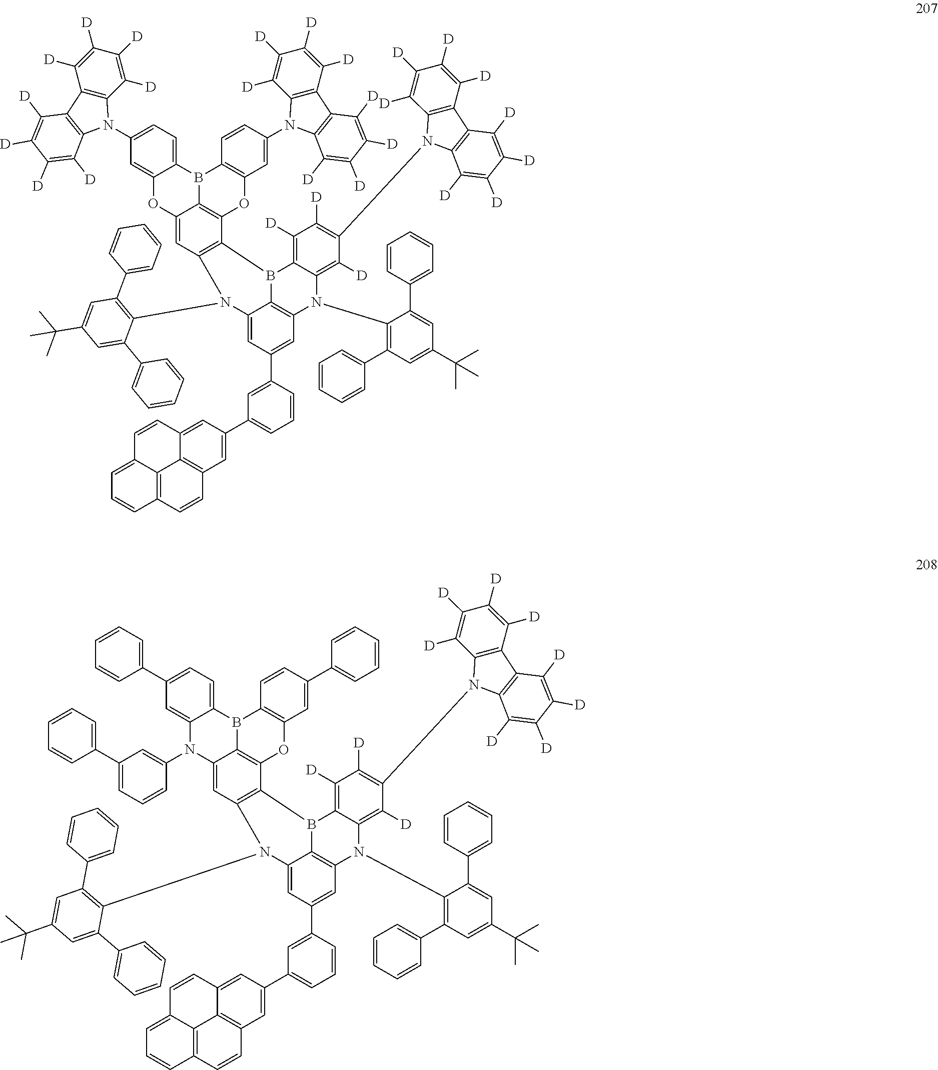

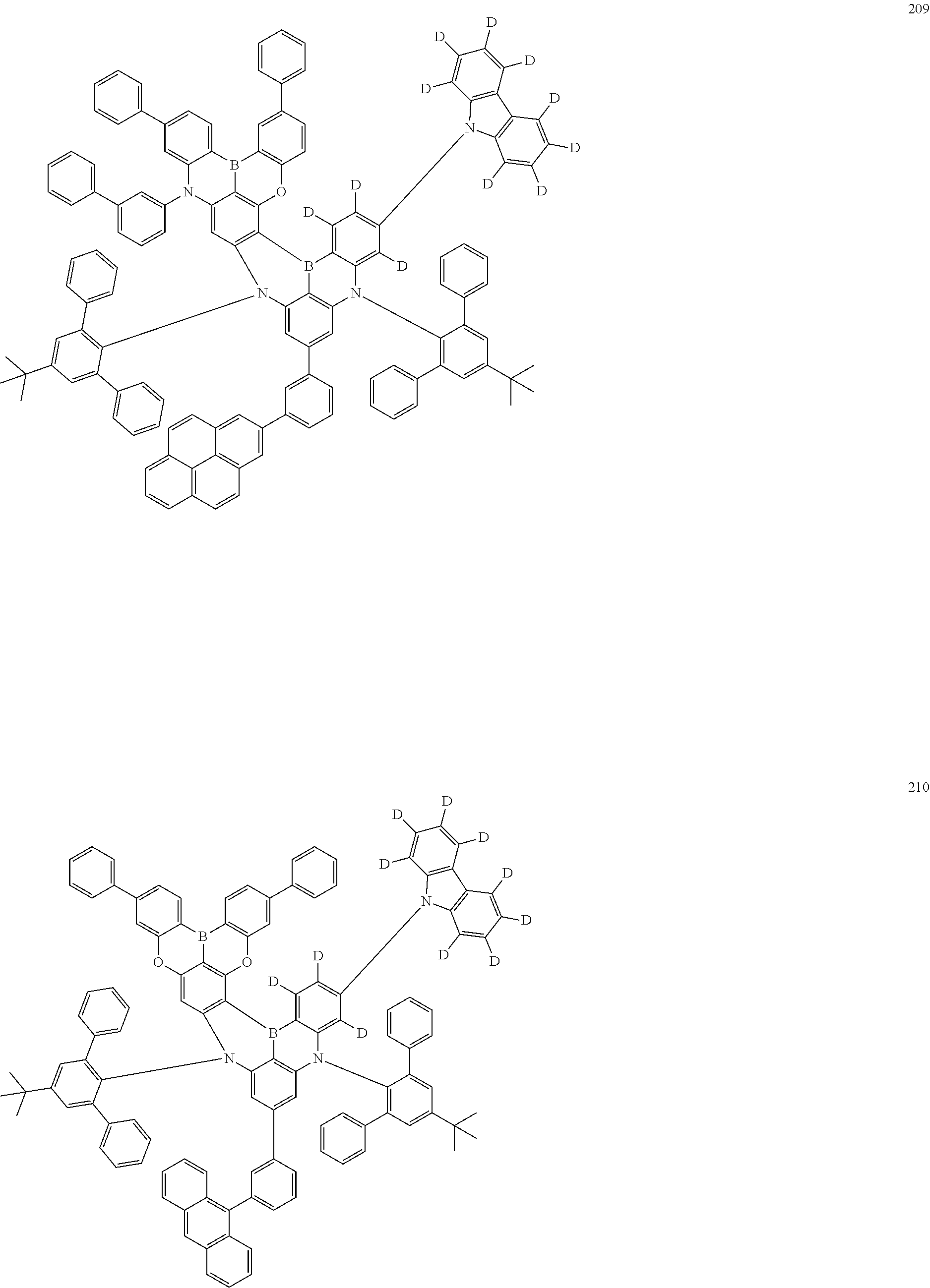

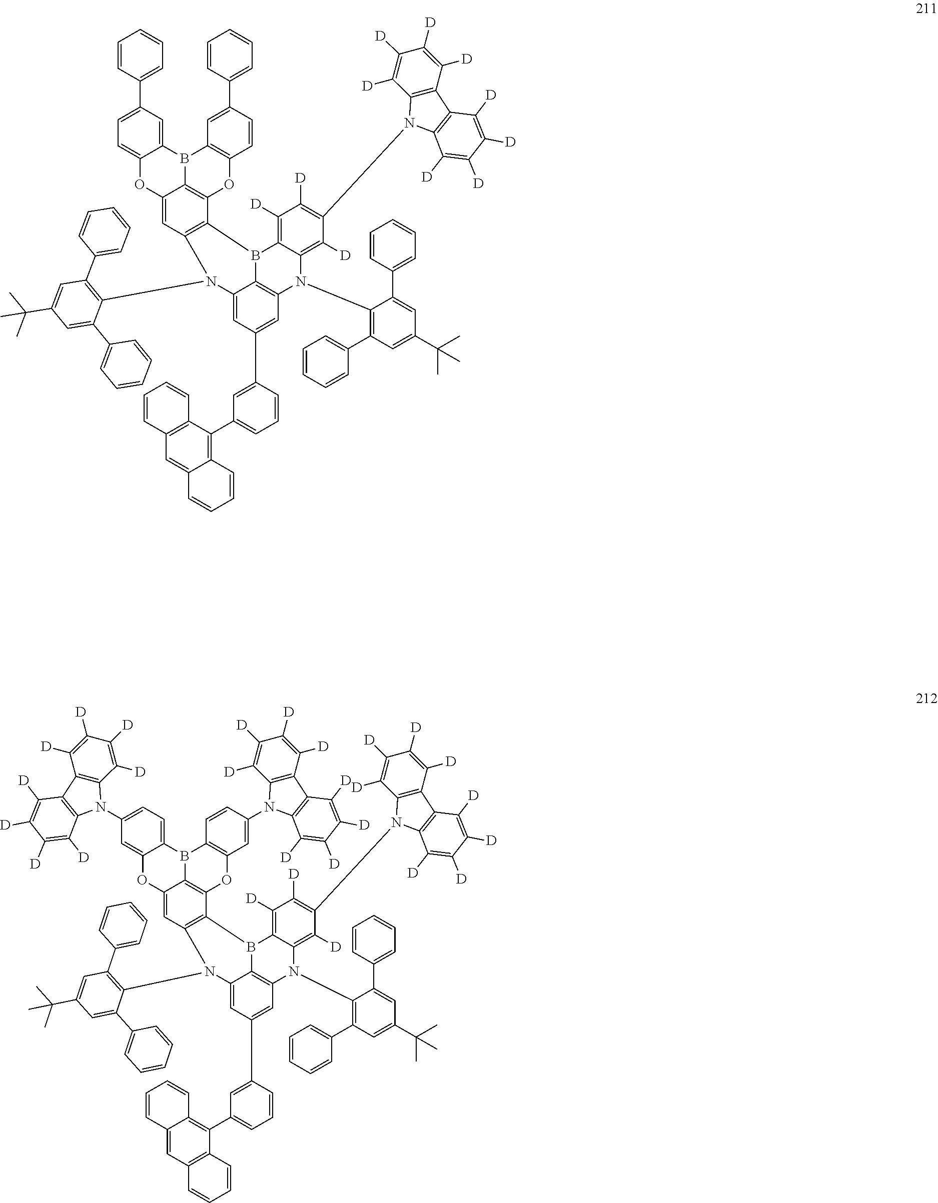

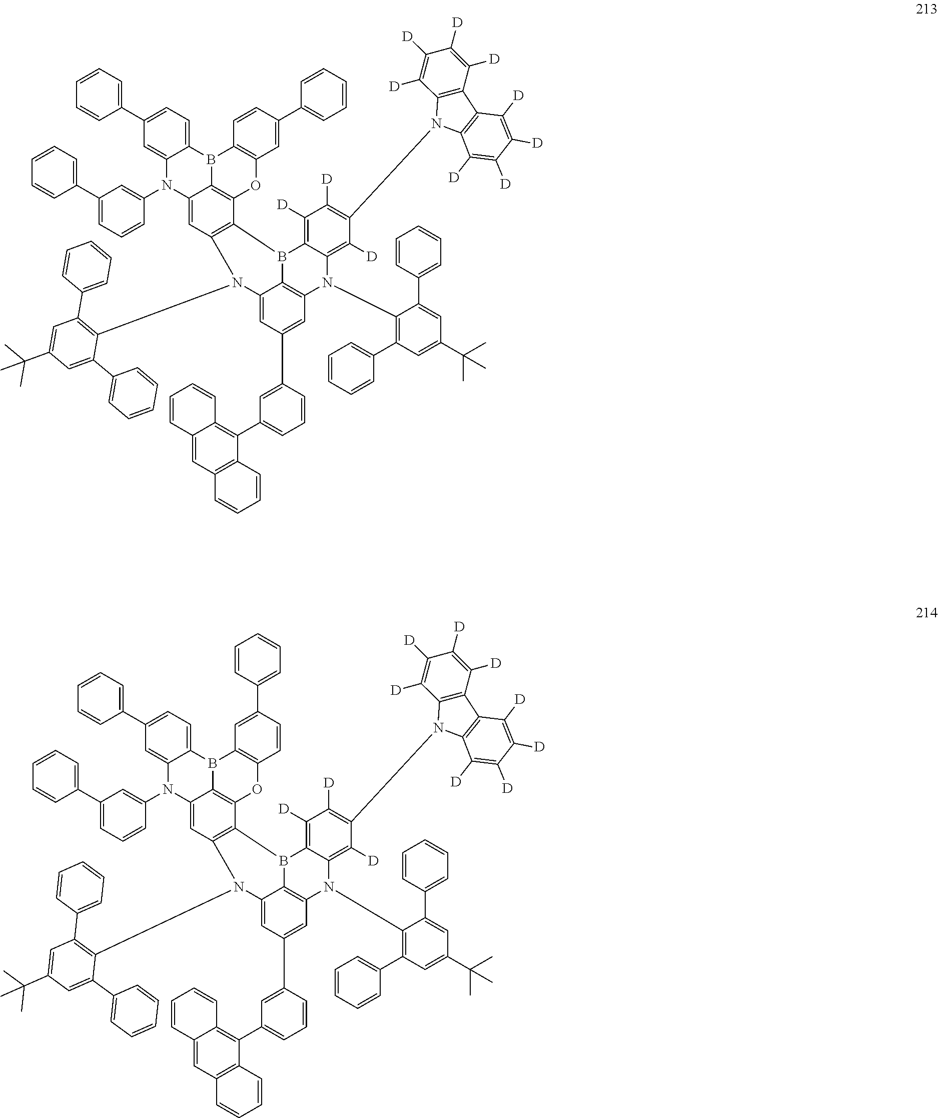

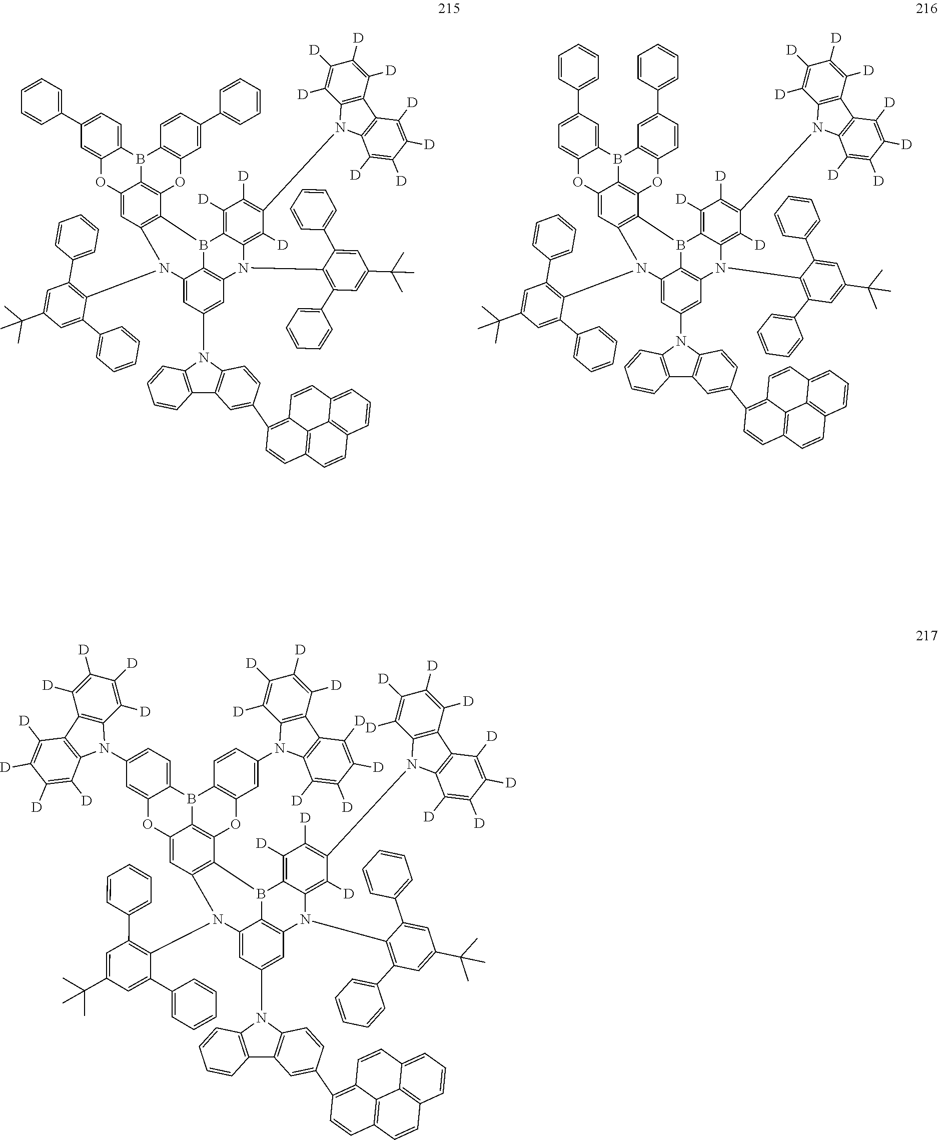

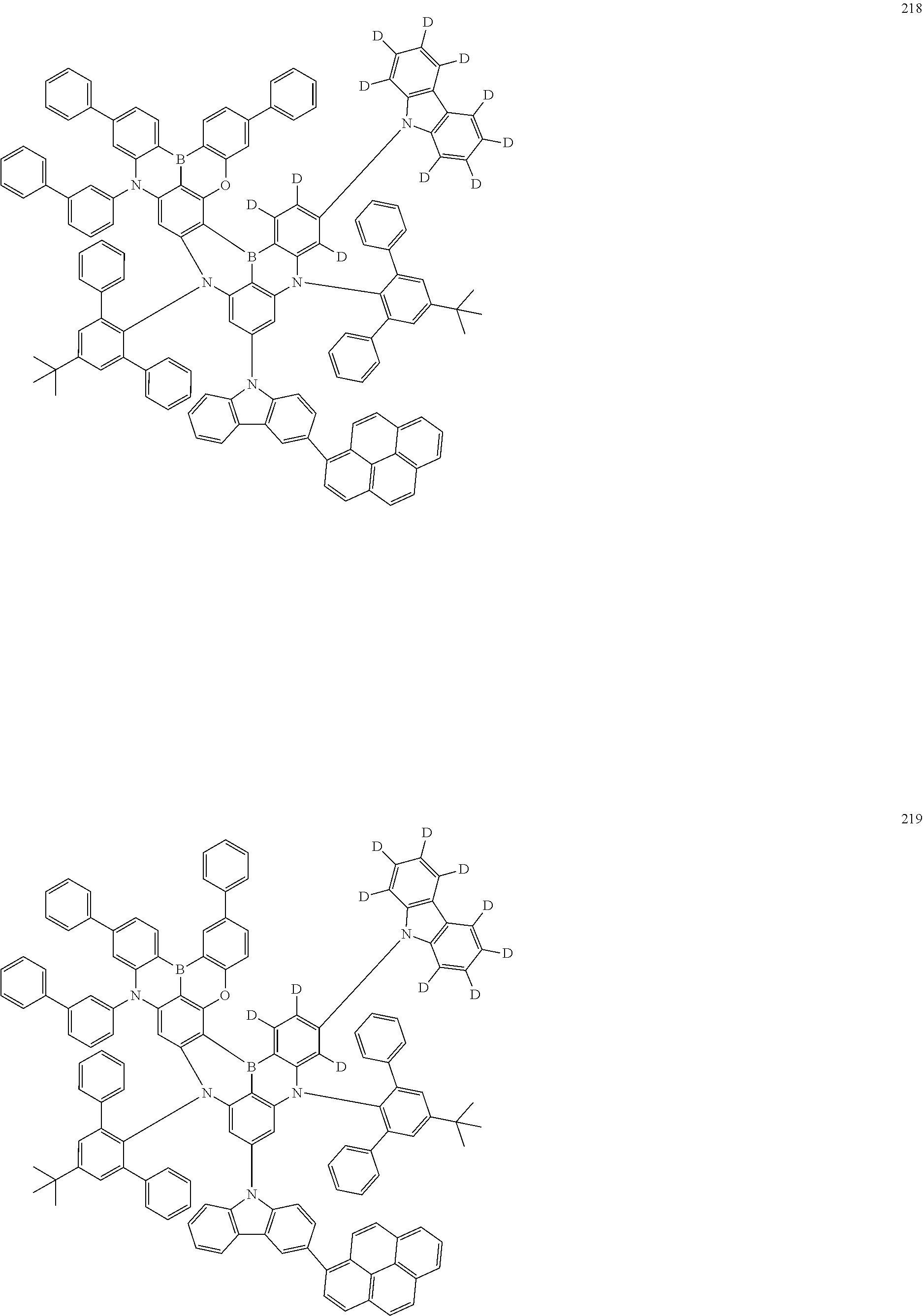

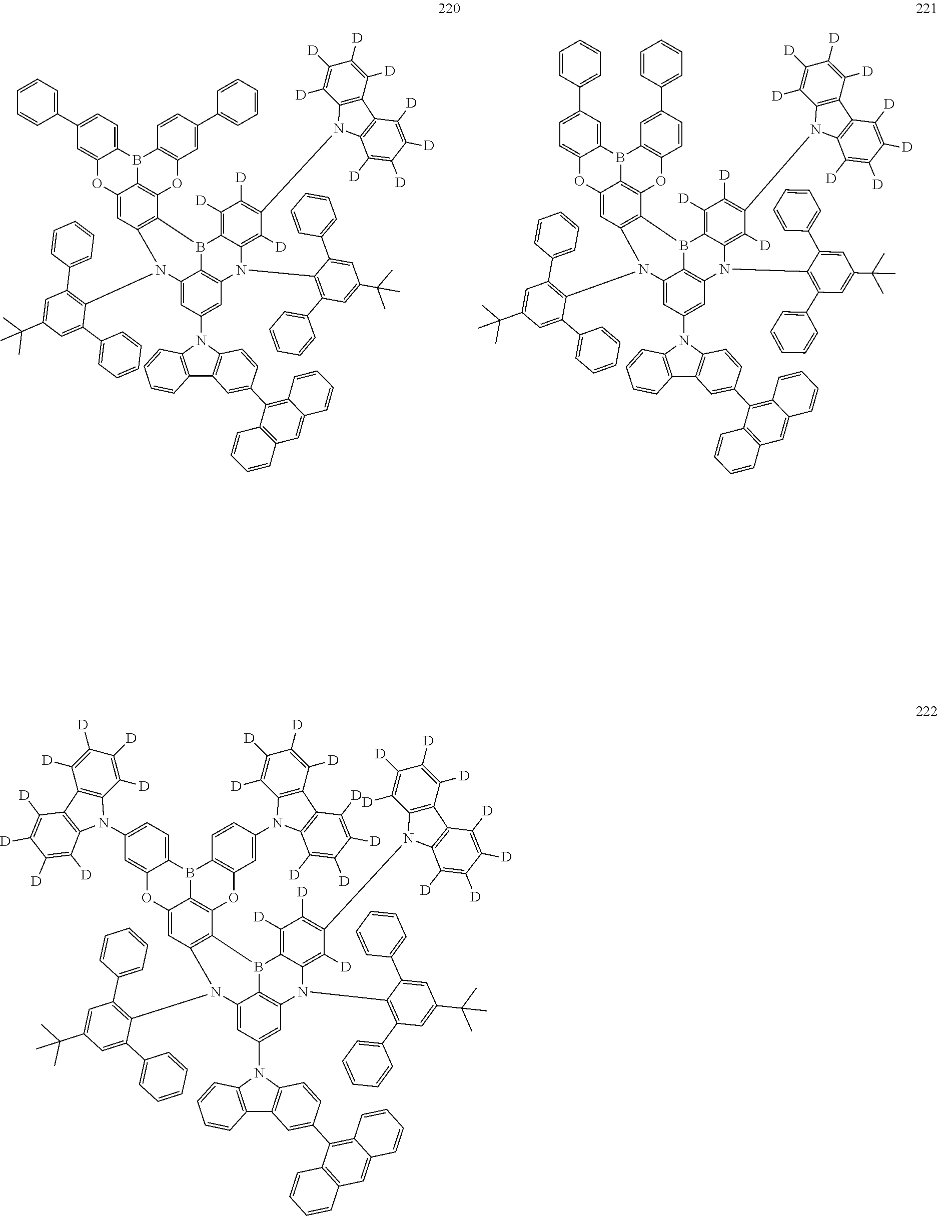

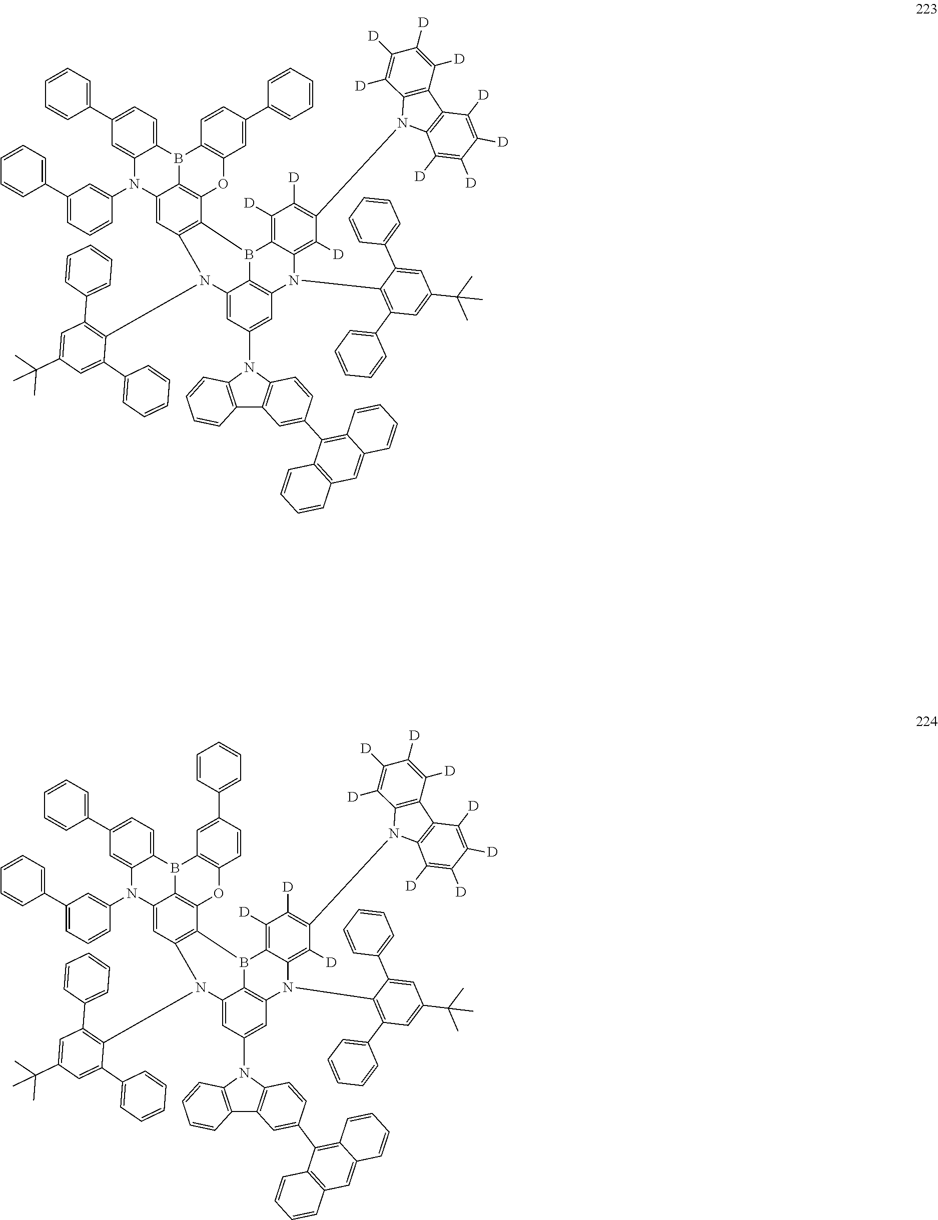

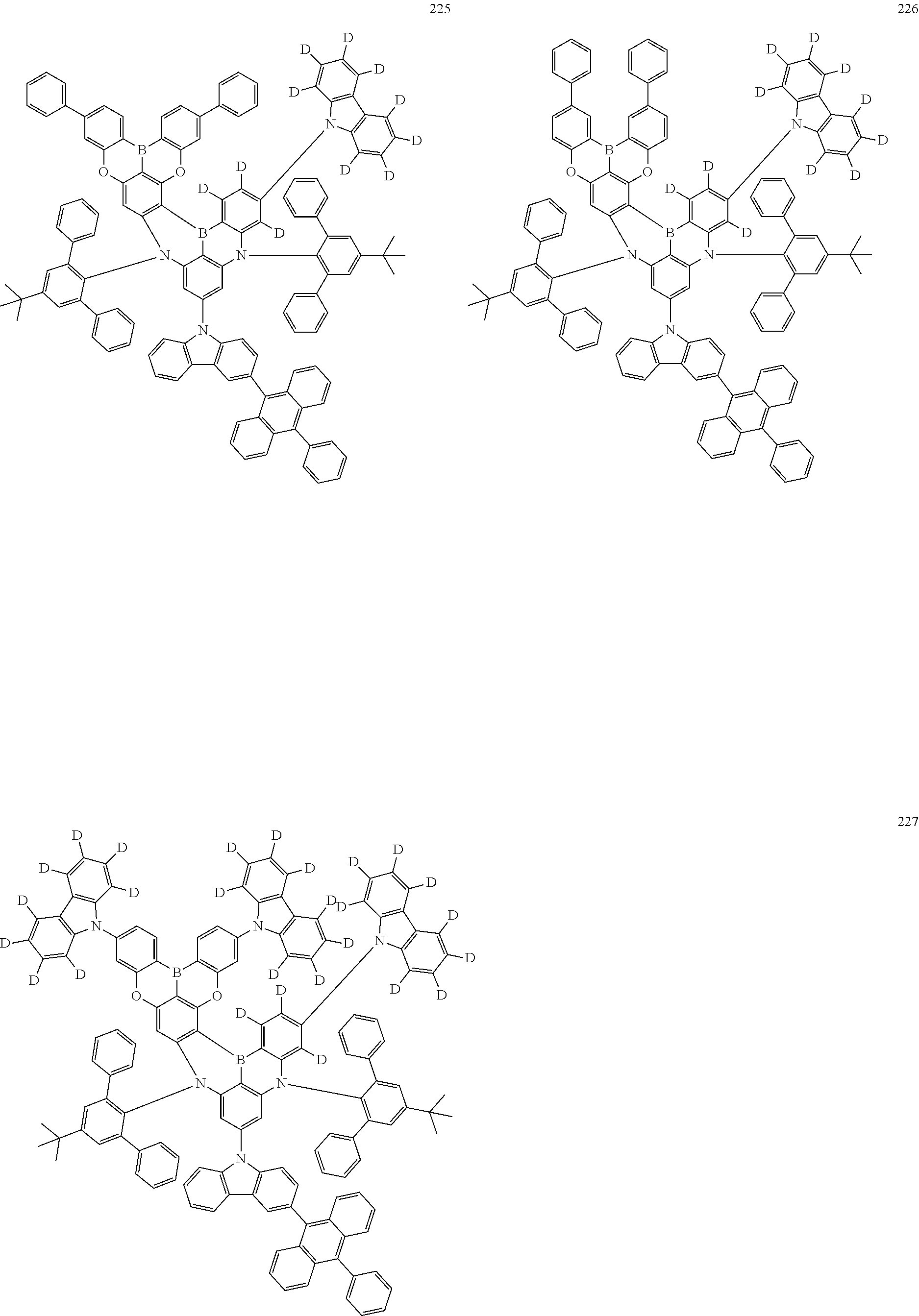

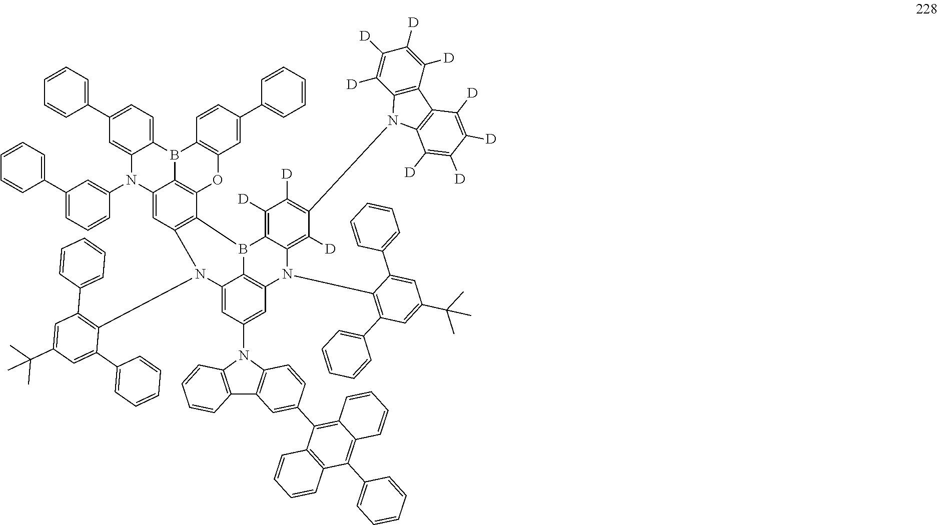 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(-n4c5ccccc5c5cc(-c6c7ccccc7c(-c7ccccc7)c7ccccc67)ccc54)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccccc2)ccc1B4c1ccc(-c2ccccc2)cc1N3c1cccc(-c2ccccc2)c1]

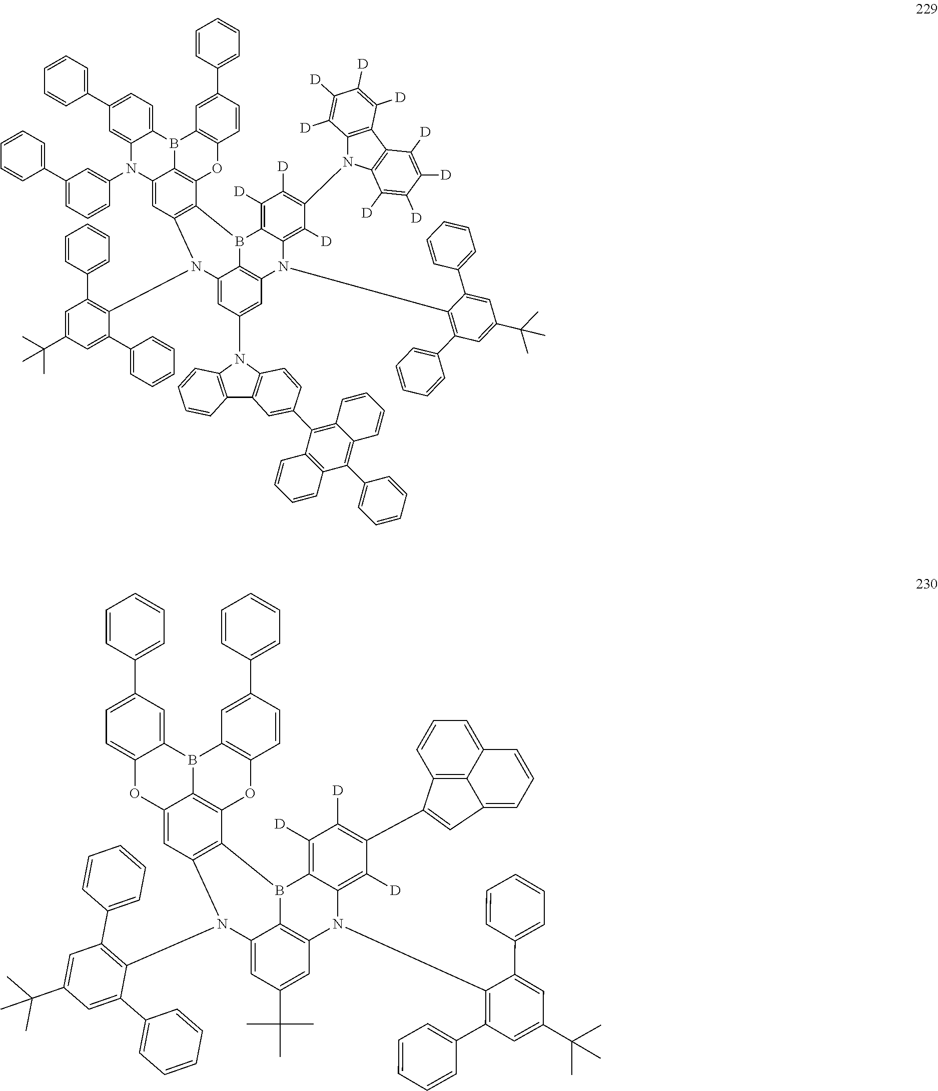

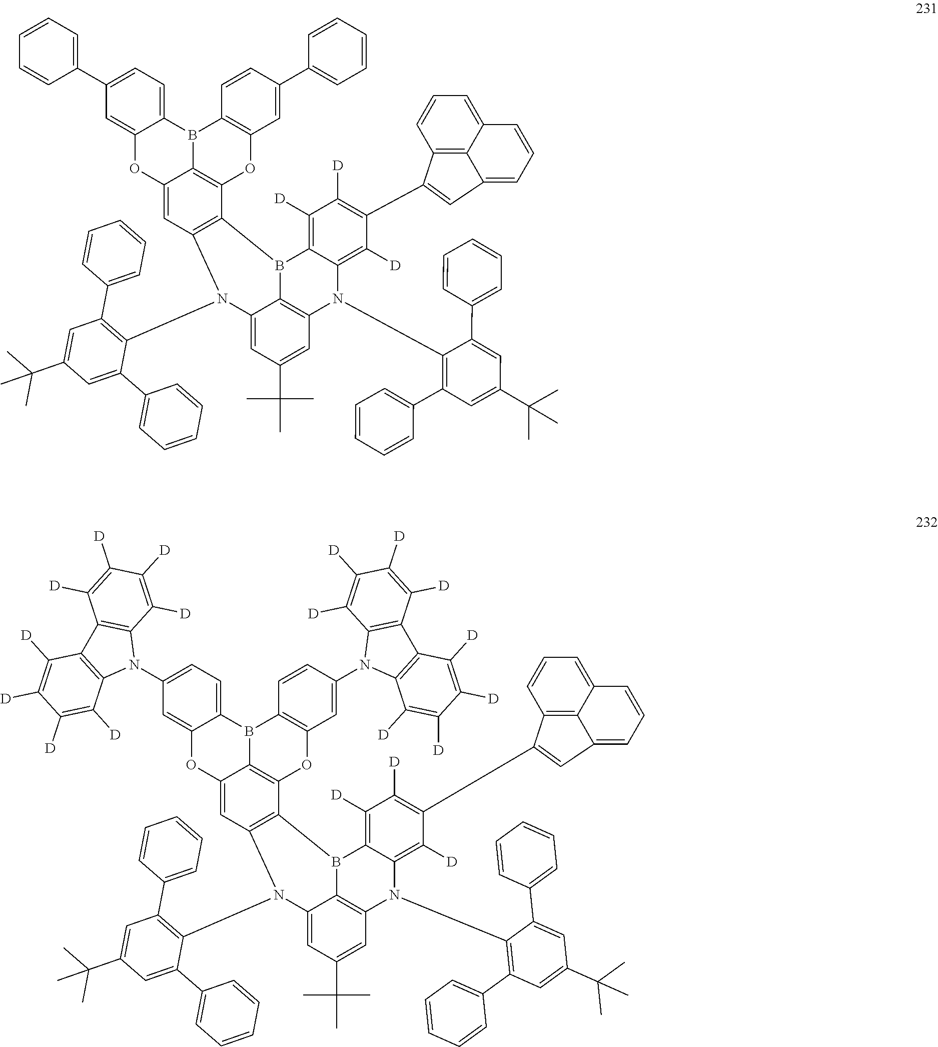

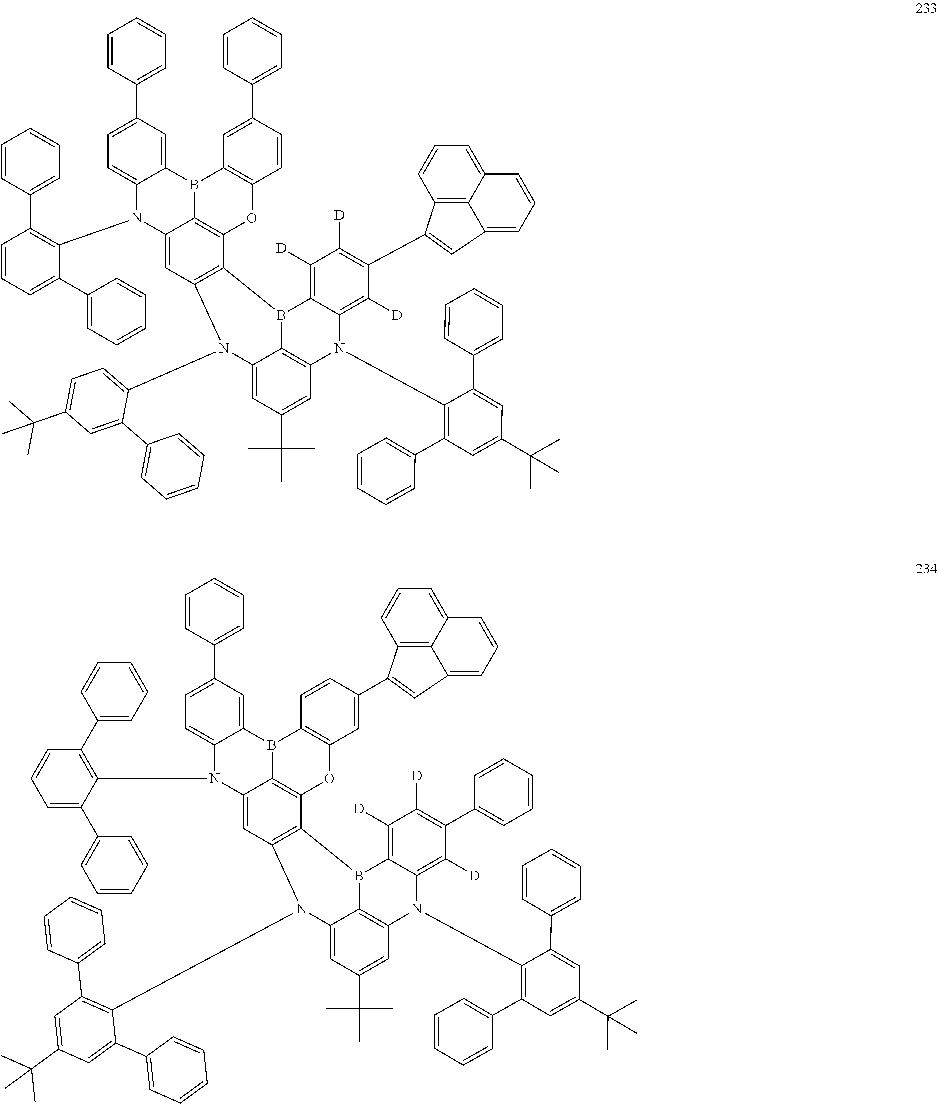

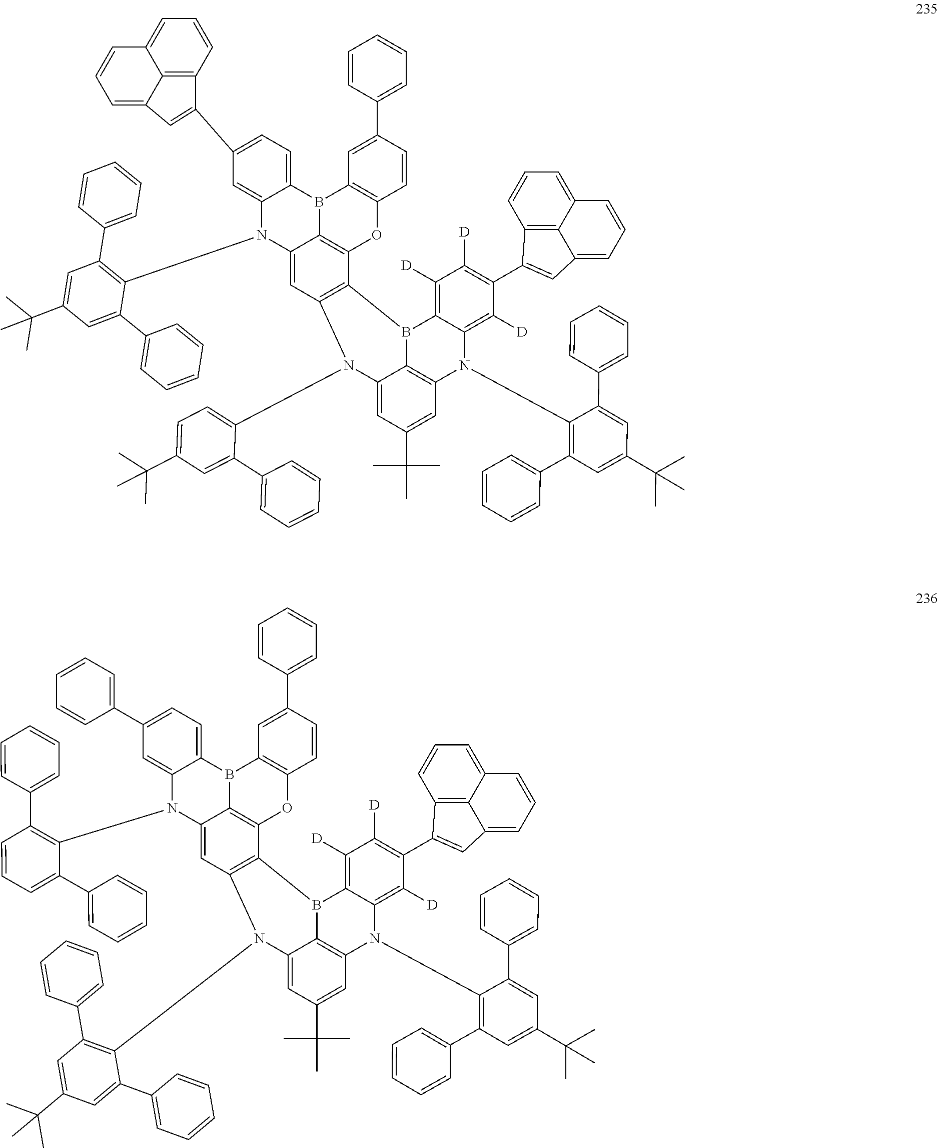 [SMILES: [2H]c1c([2H])c(C2=Cc3cccc4cccc2c34)c([2H])c2c1B1c3c(cc(C(C)(C)C)cc3N2c2c(-c3ccccc3)cc(C(C)(C)C)cc2-c2ccccc2)N(c2ccc(C(C)(C)C)cc2-c2ccccc2)c2cc3c4c(c21)Oc1ccc(-c2ccccc2)cc1B4c1ccc(C2=Cc4cccc5cccc2c45)cc1N3c1c(-c2ccccc2)cc(C(C)(C)C)cc1-c1ccccc1 ; [2H]c1c([2H])c(C2=Cc3cccc4cccc2c34)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1ccc(-c2ccccc2)cc1B4c1ccc(-c2ccccc2)cc1N3c1c(-c2ccccc2)cccc1-c1ccccc1]

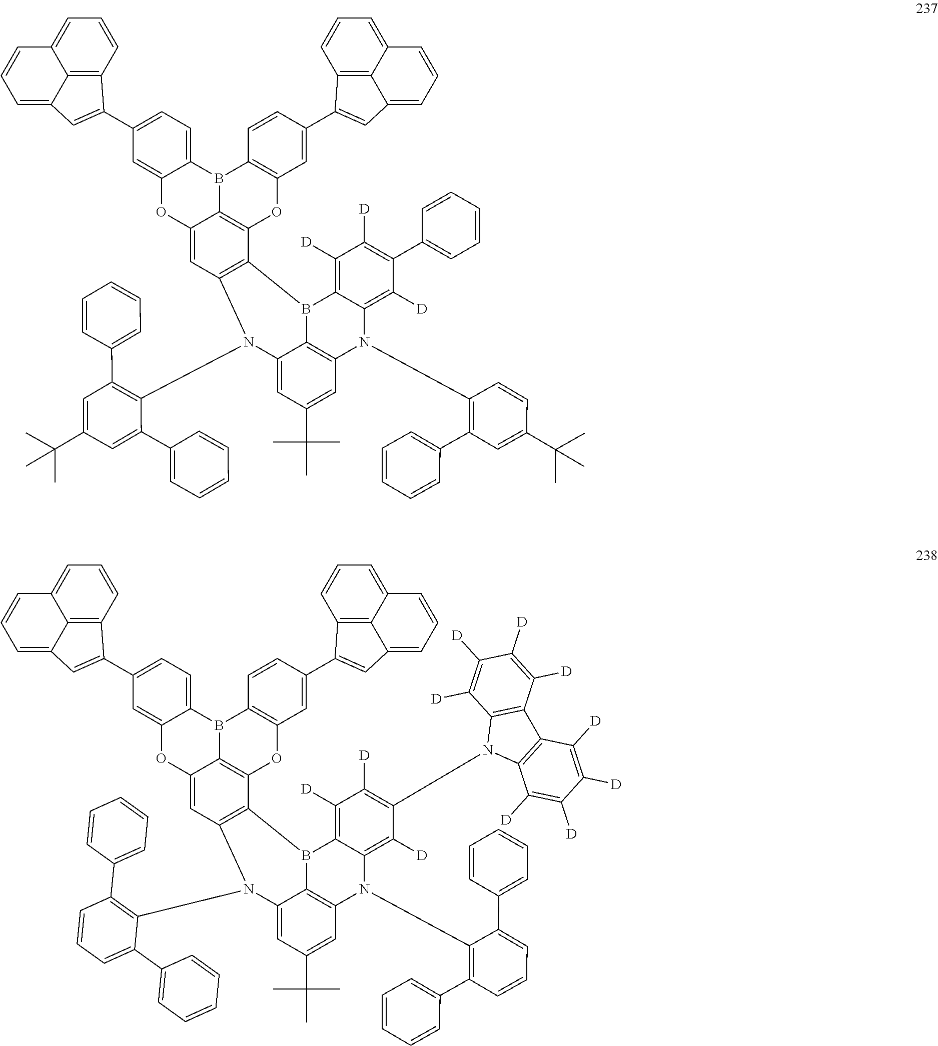 [SMILES: [2H]c1c([2H])c(-c2ccccc2)c([2H])c2c1B1c3c(cc(C(C)(C)C)cc3N2c2ccc(C(C)(C)C)cc2-c2ccccc2)N(c2c(-c3ccccc3)cc(C(C)(C)C)cc2-c2ccccc2)c2cc3c4c(c21)Oc1cc(C2=Cc5cccc6cccc2c56)ccc1B4c1ccc(C2=Cc4cccc5cccc2c45)cc1O3 ; [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(C2=Cc5cccc6cccc2c56)ccc1B4c1ccc(C2=Cc4cccc5cccc2c45)cc1O3]

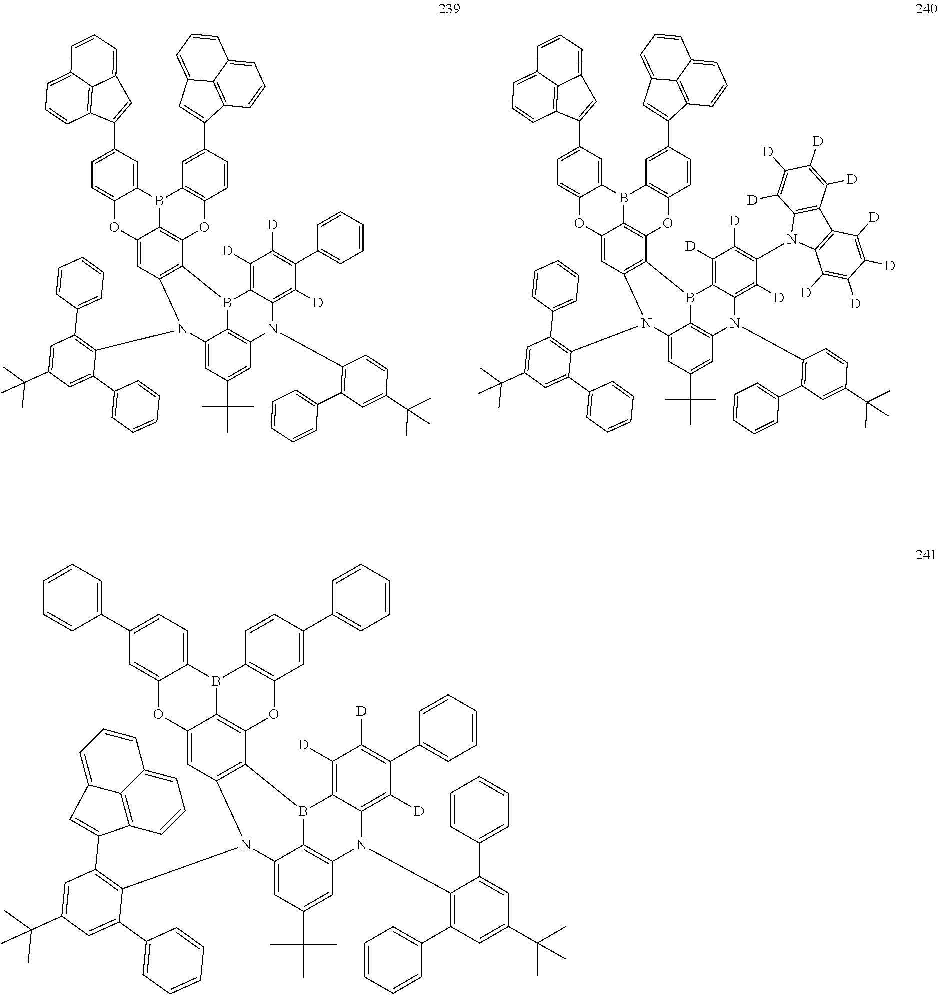

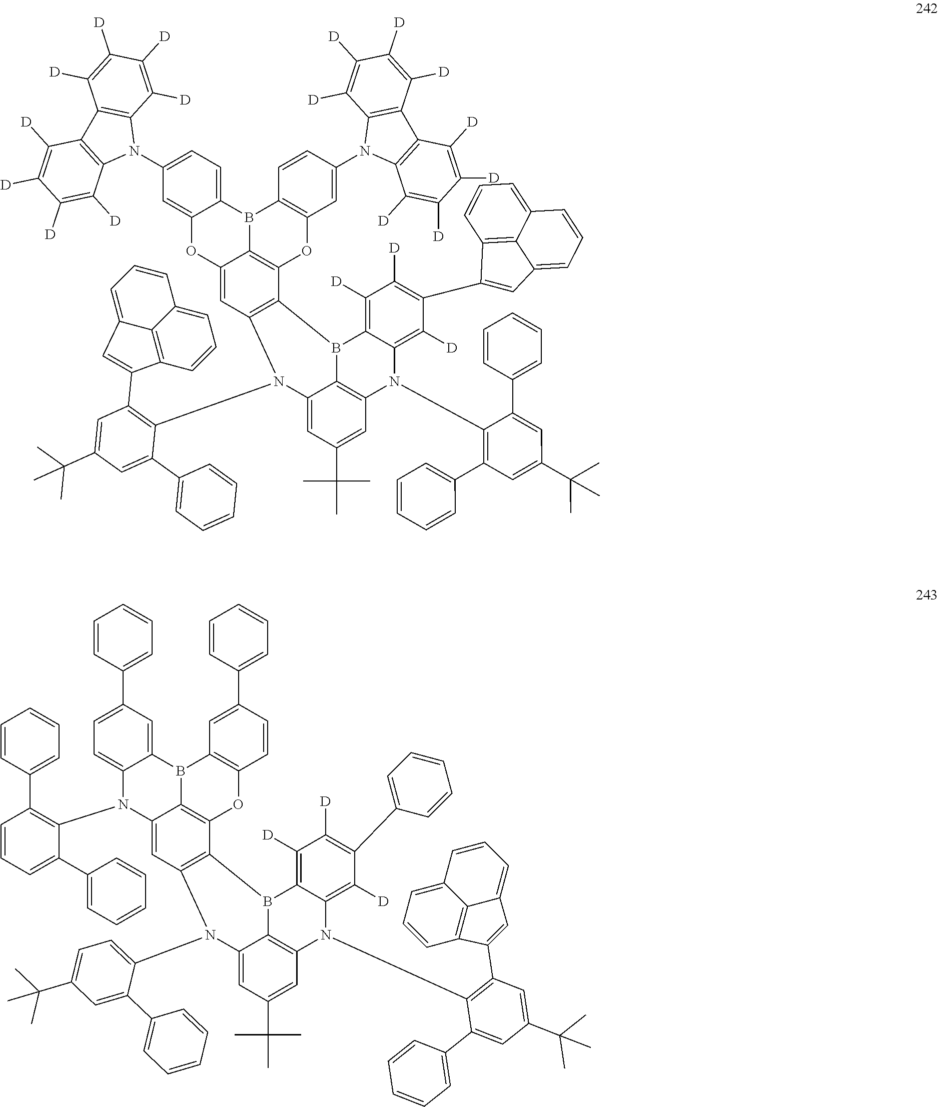

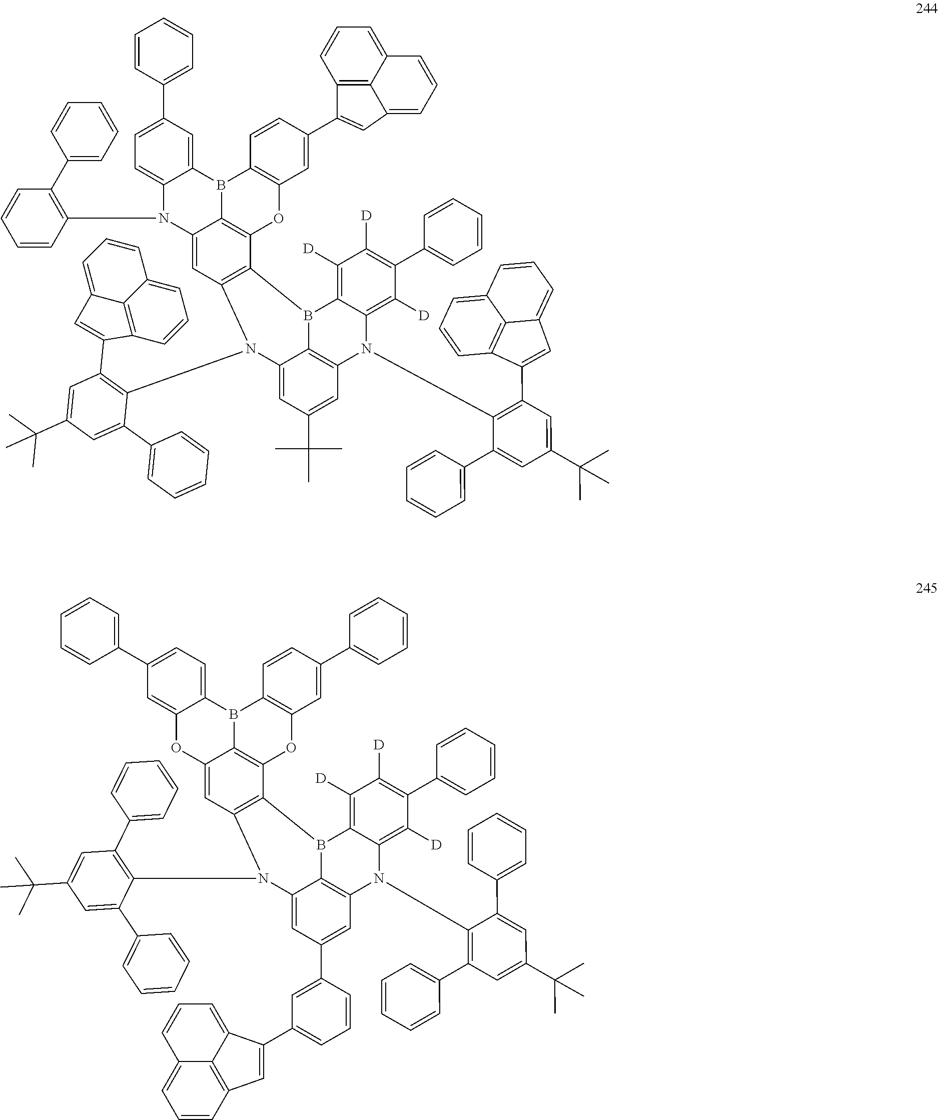

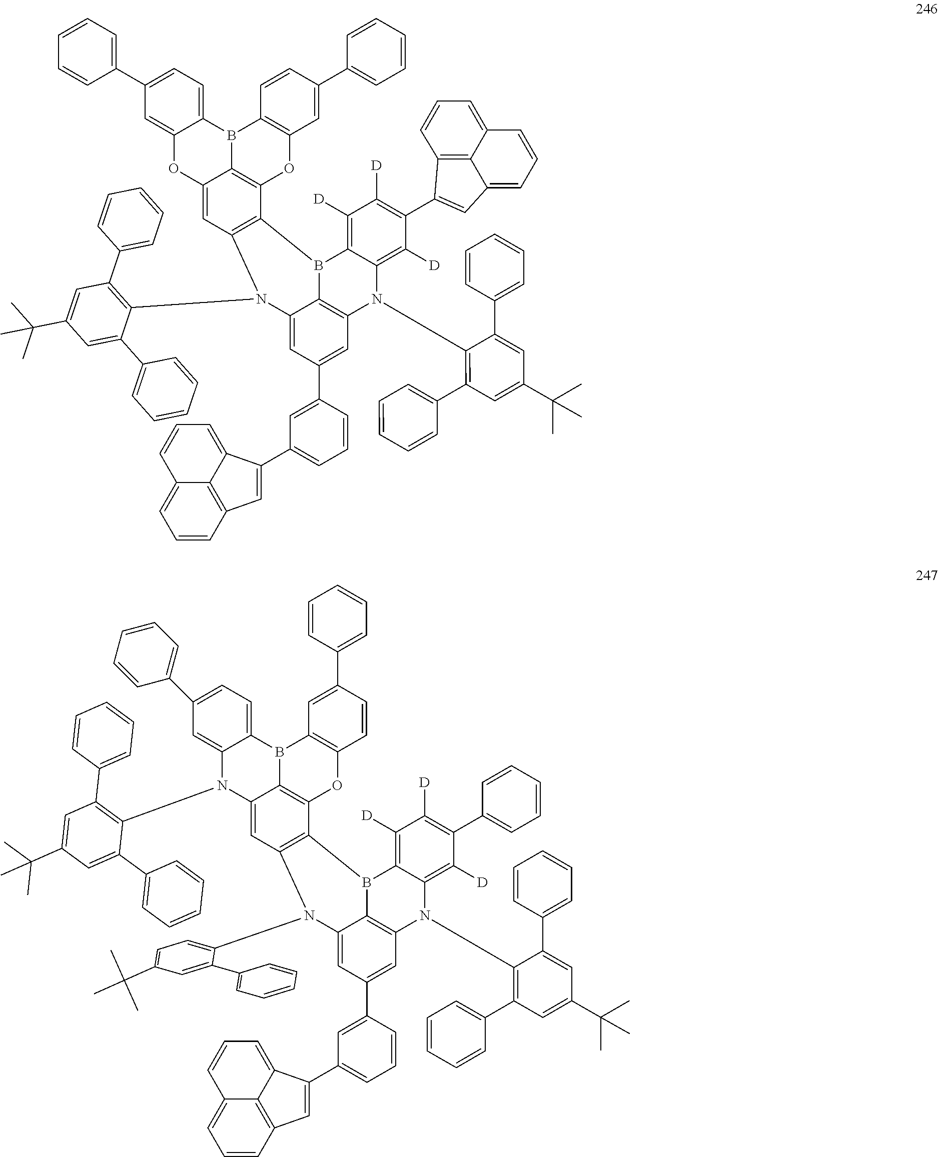

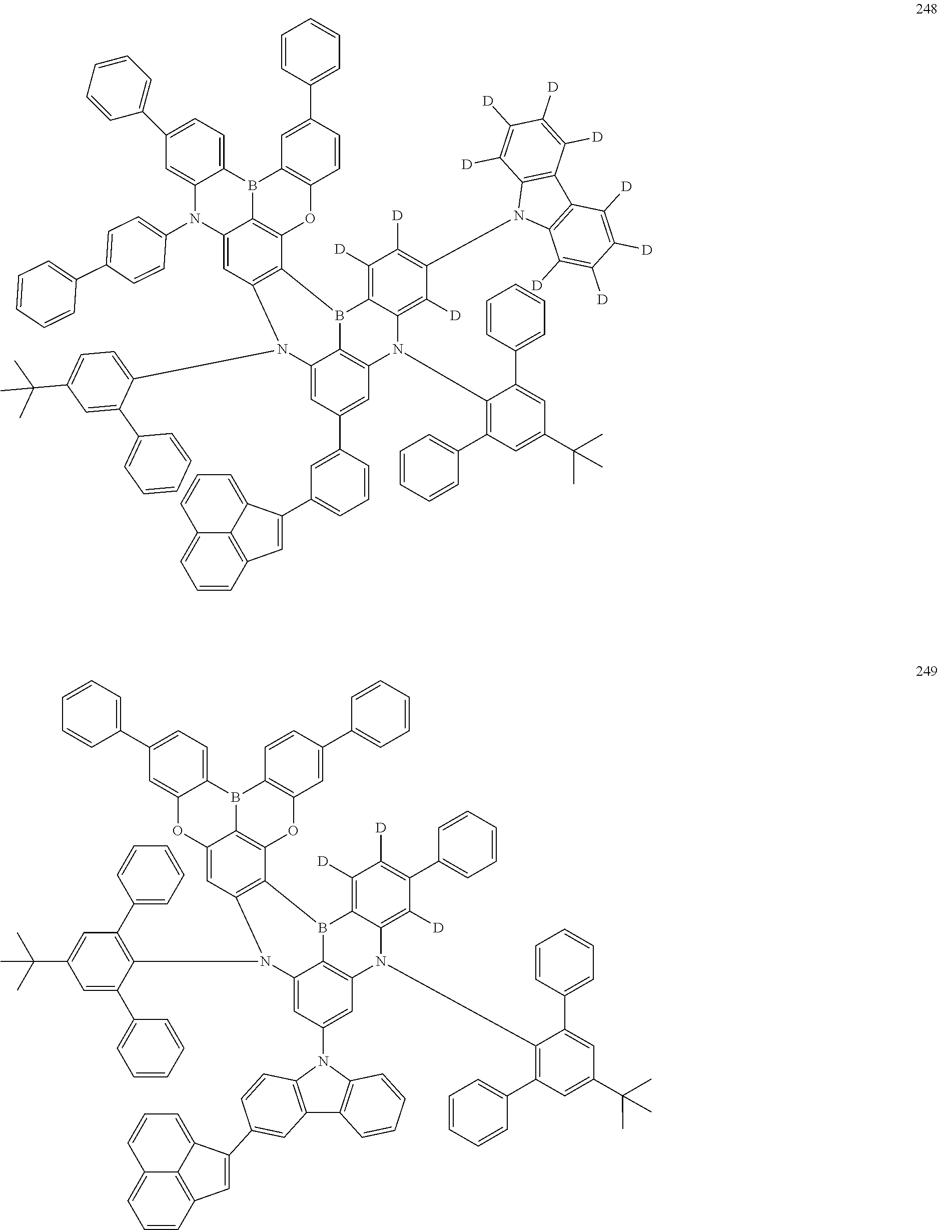

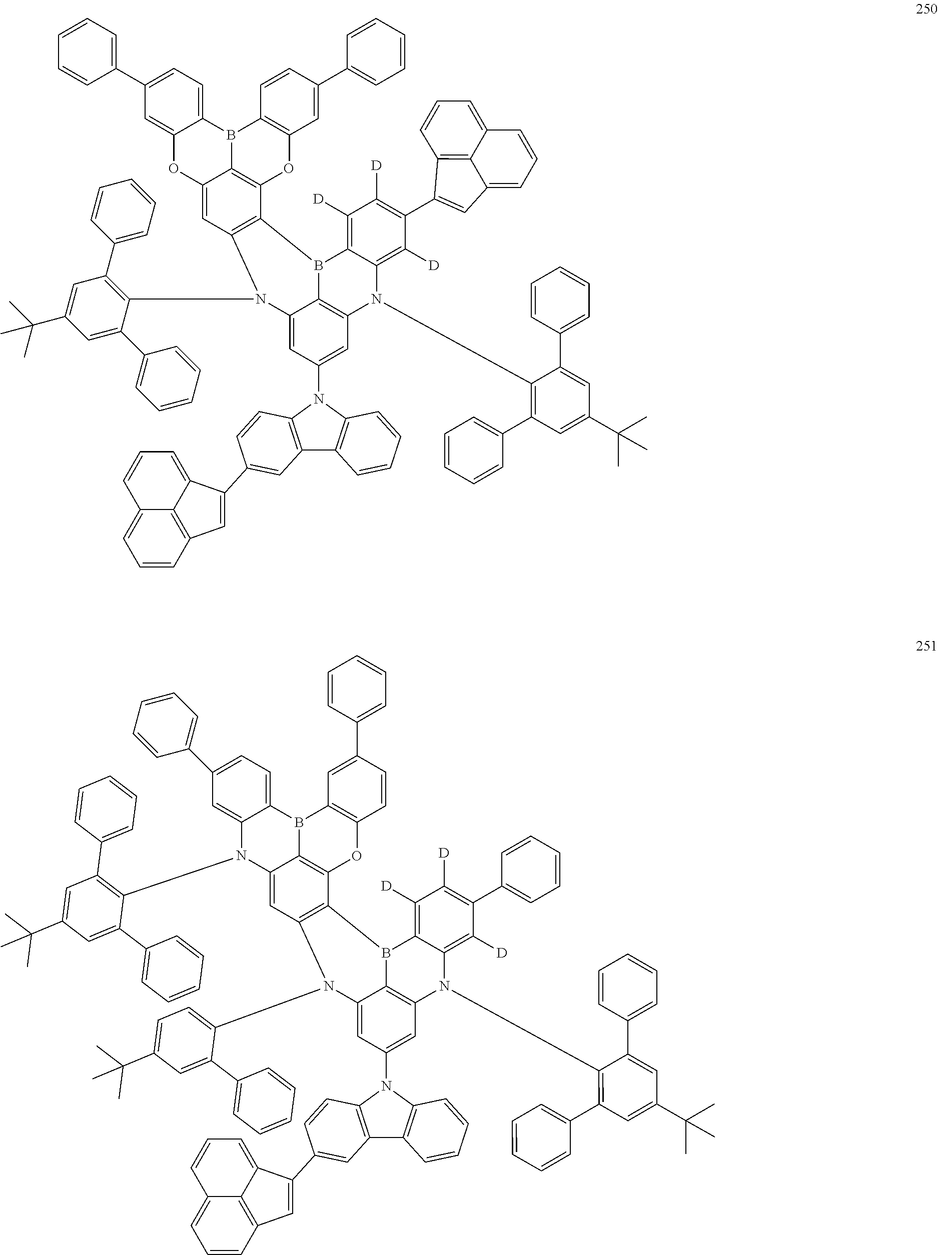

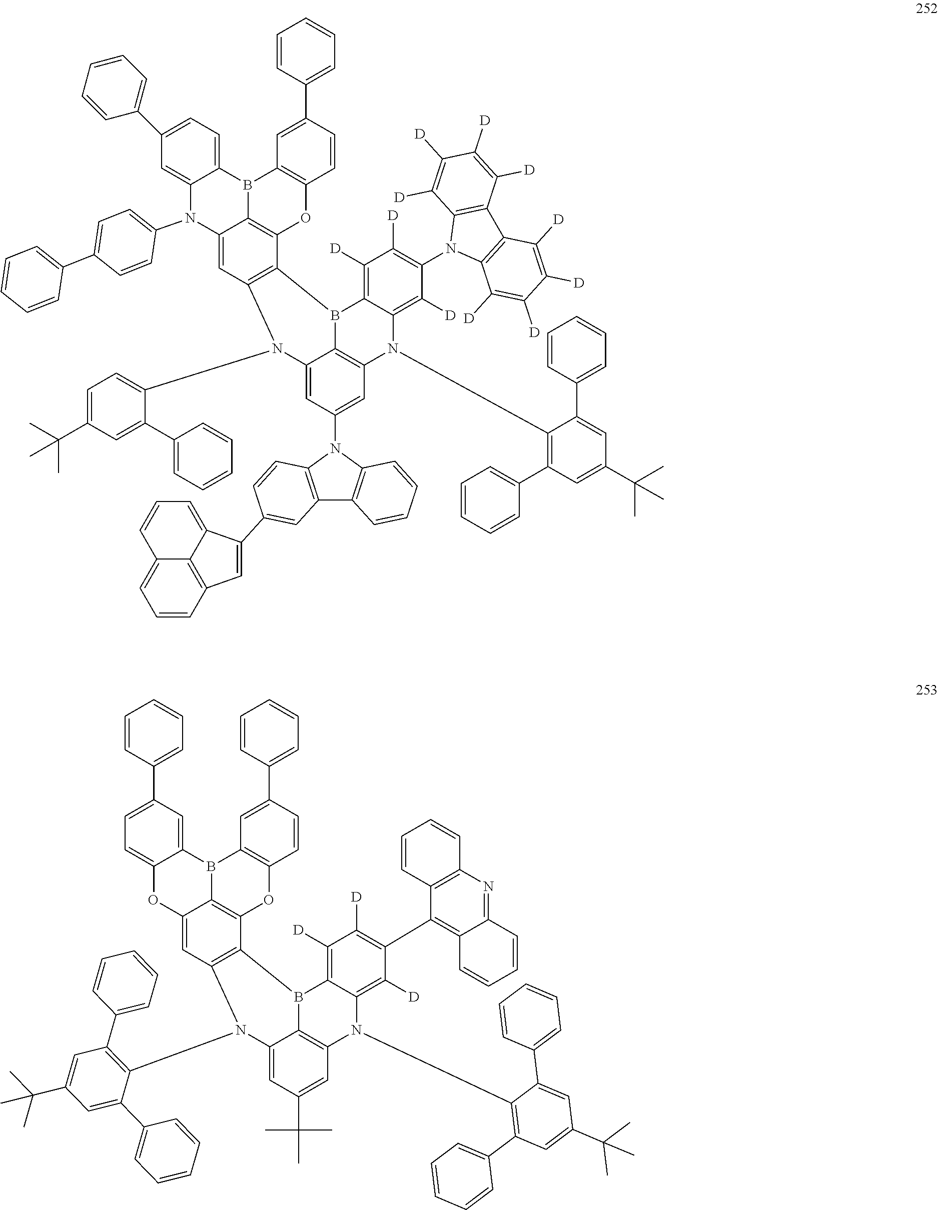

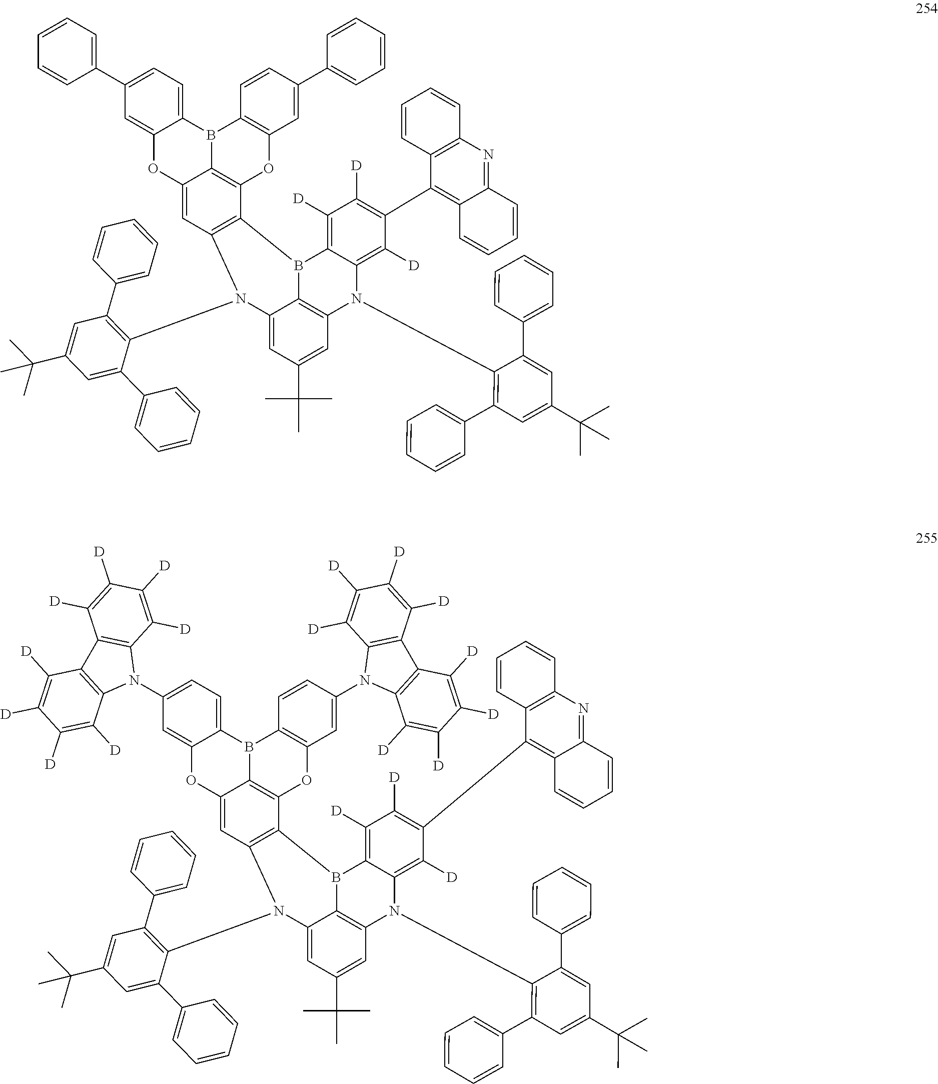

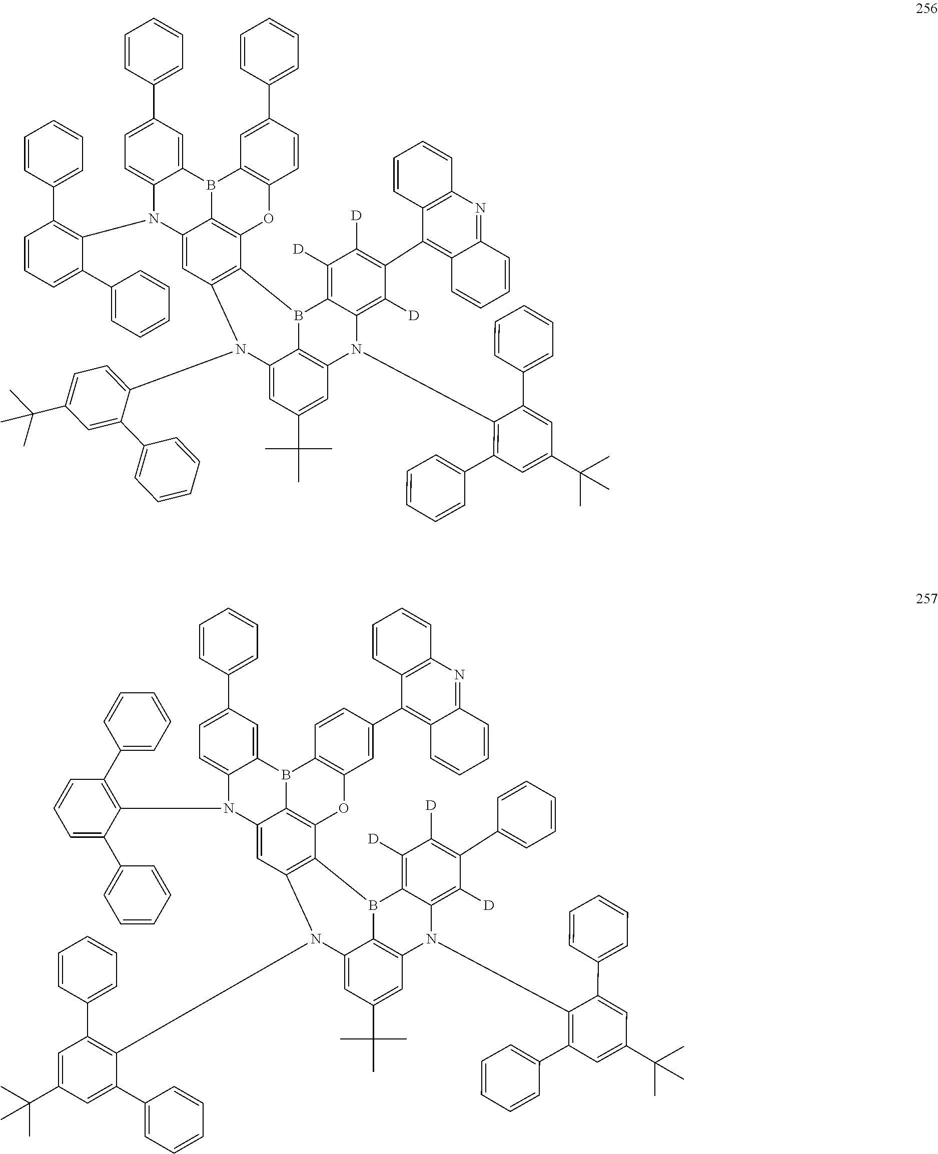

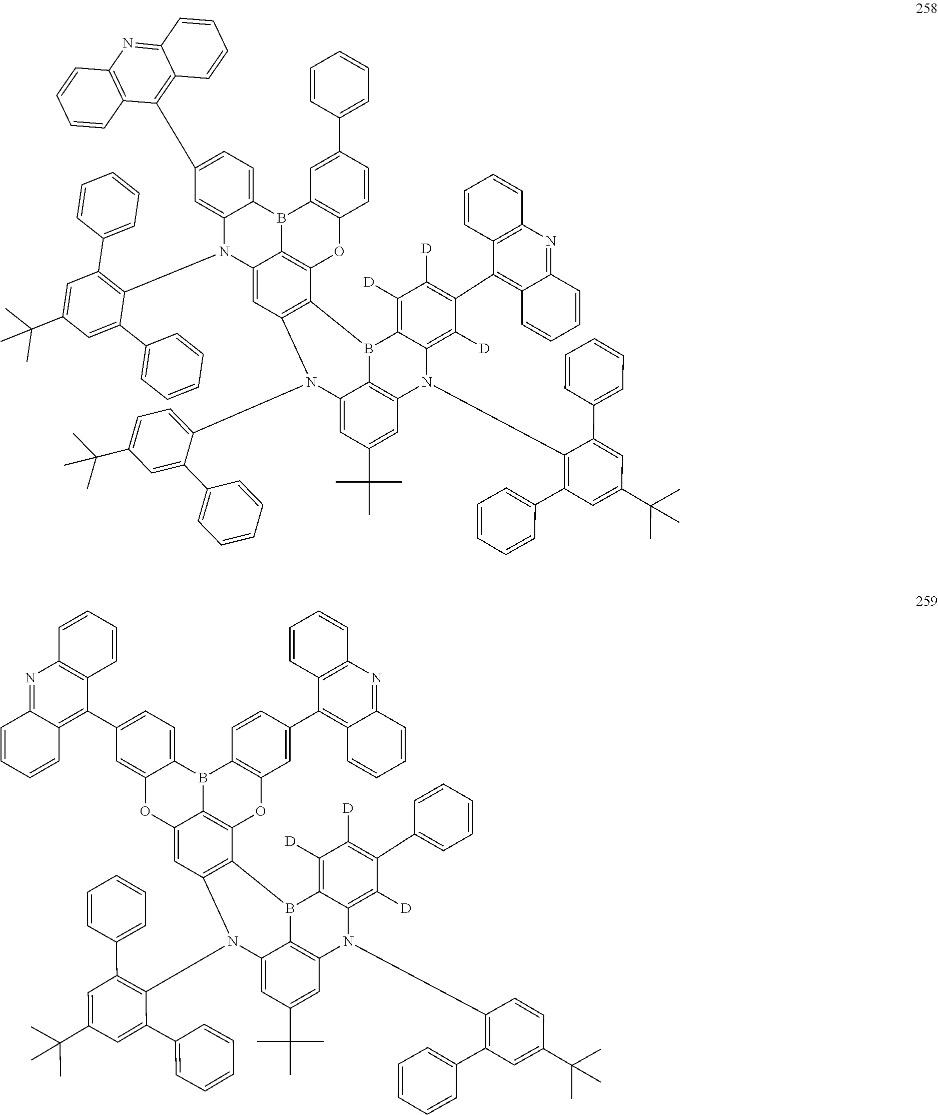 [SMILES: [2H]c1c([2H])c(-c2c3ccccc3nc3ccccc23)c([2H])c2c1B1c3c(cc(C(C)(C)C)cc3N2c2c(-c3ccccc3)cc(C(C)(C)C)cc2-c2ccccc2)N(c2ccc(C(C)(C)C)cc2-c2ccccc2)c2cc3c4c(c21)Oc1ccc(-c2ccccc2)cc1B4c1ccc(-c2c4ccccc4nc4ccccc24)cc1N3c1c(-c2ccccc2)cc(C(C)(C)C)cc1-c1ccccc1 ; [2H]c1c([2H])c(-c2ccccc2)c([2H])c2c1B1c3c(cc(C(C)(C)C)cc3N2c2ccc(C(C)(C)C)cc2-c2ccccc2)N(c2c(-c3ccccc3)cc(C(C)(C)C)cc2-c2ccccc2)c2cc3c4c(c21)Oc1cc(-c2c5ccccc5nc5ccccc25)ccc1B4c1ccc(-c2c4ccccc4nc4ccccc24)cc1O3]

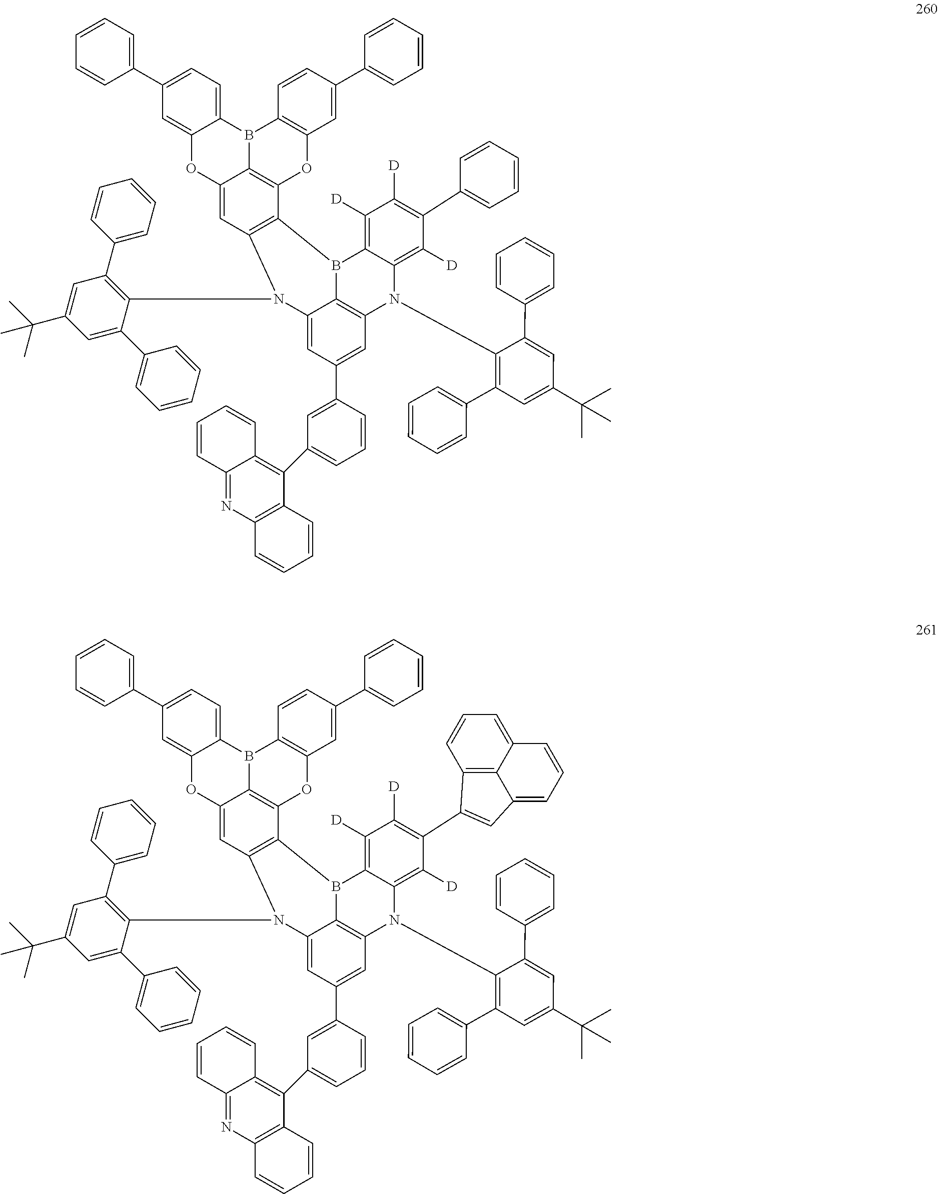

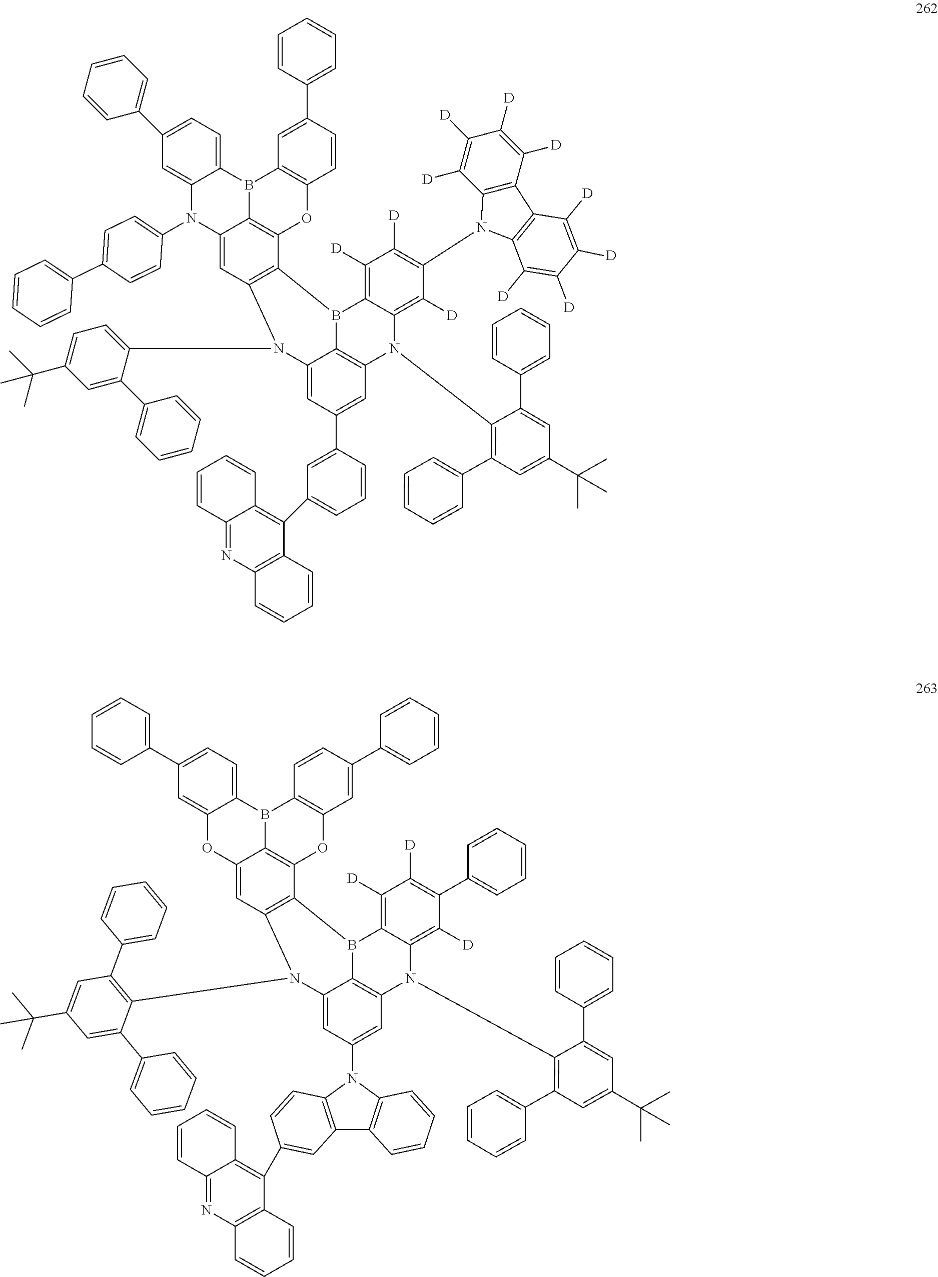

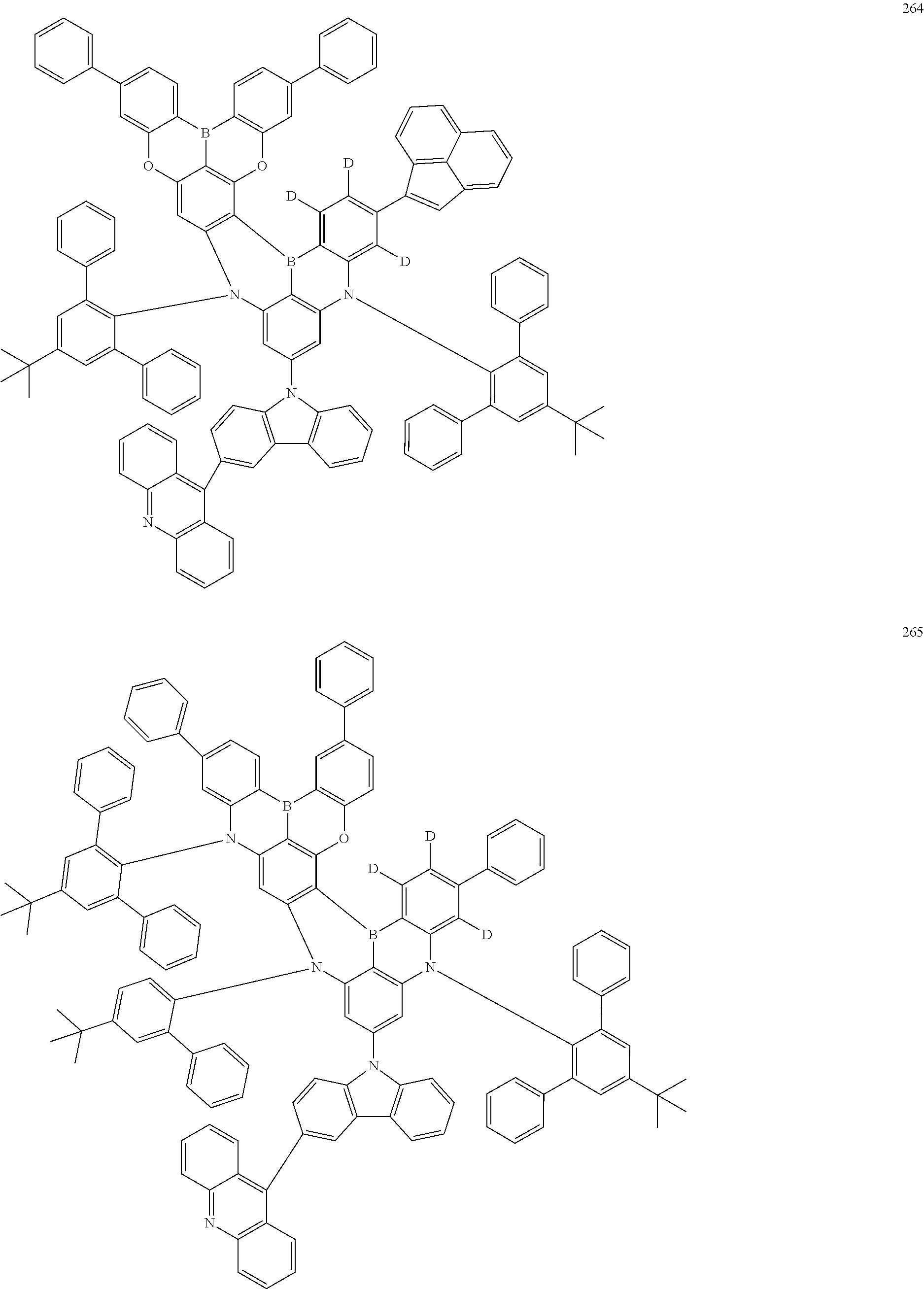

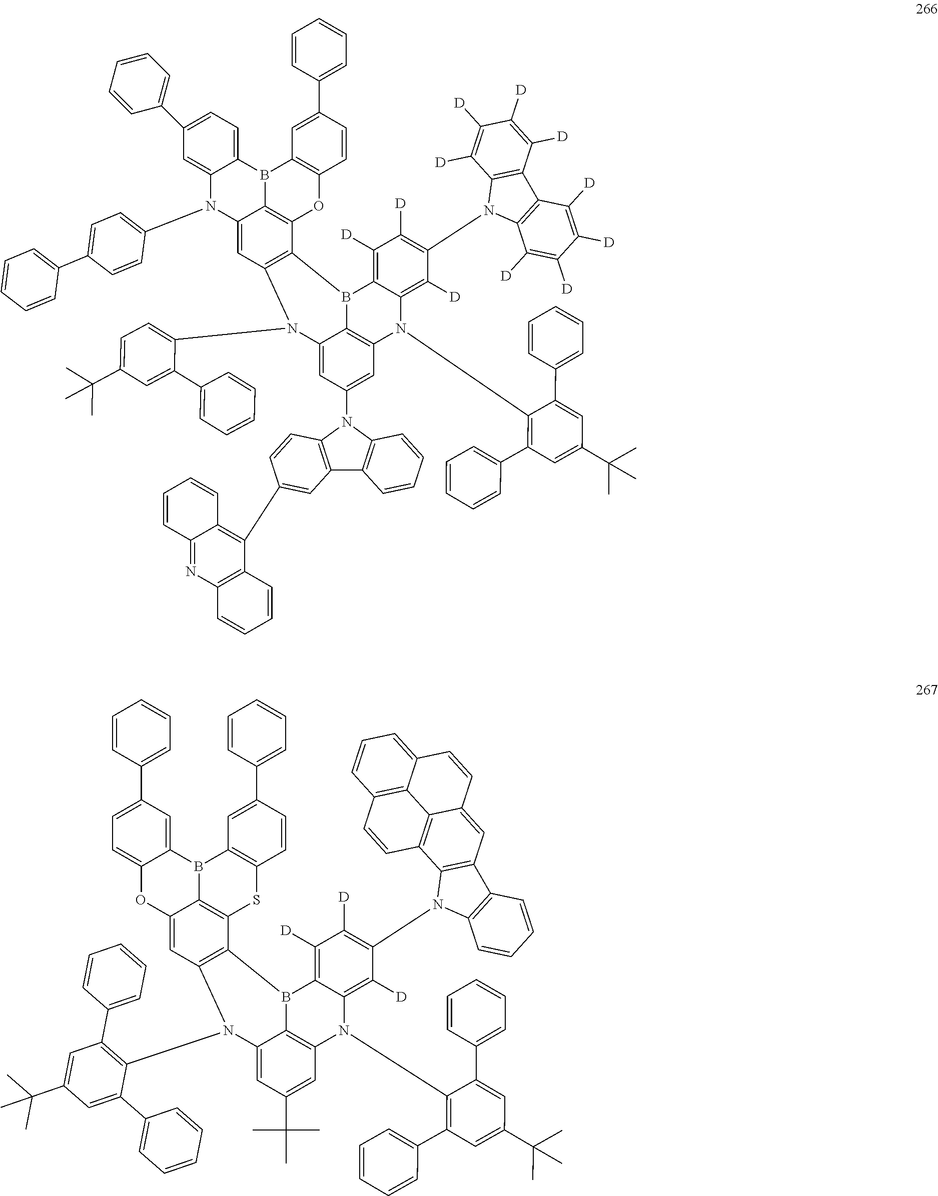

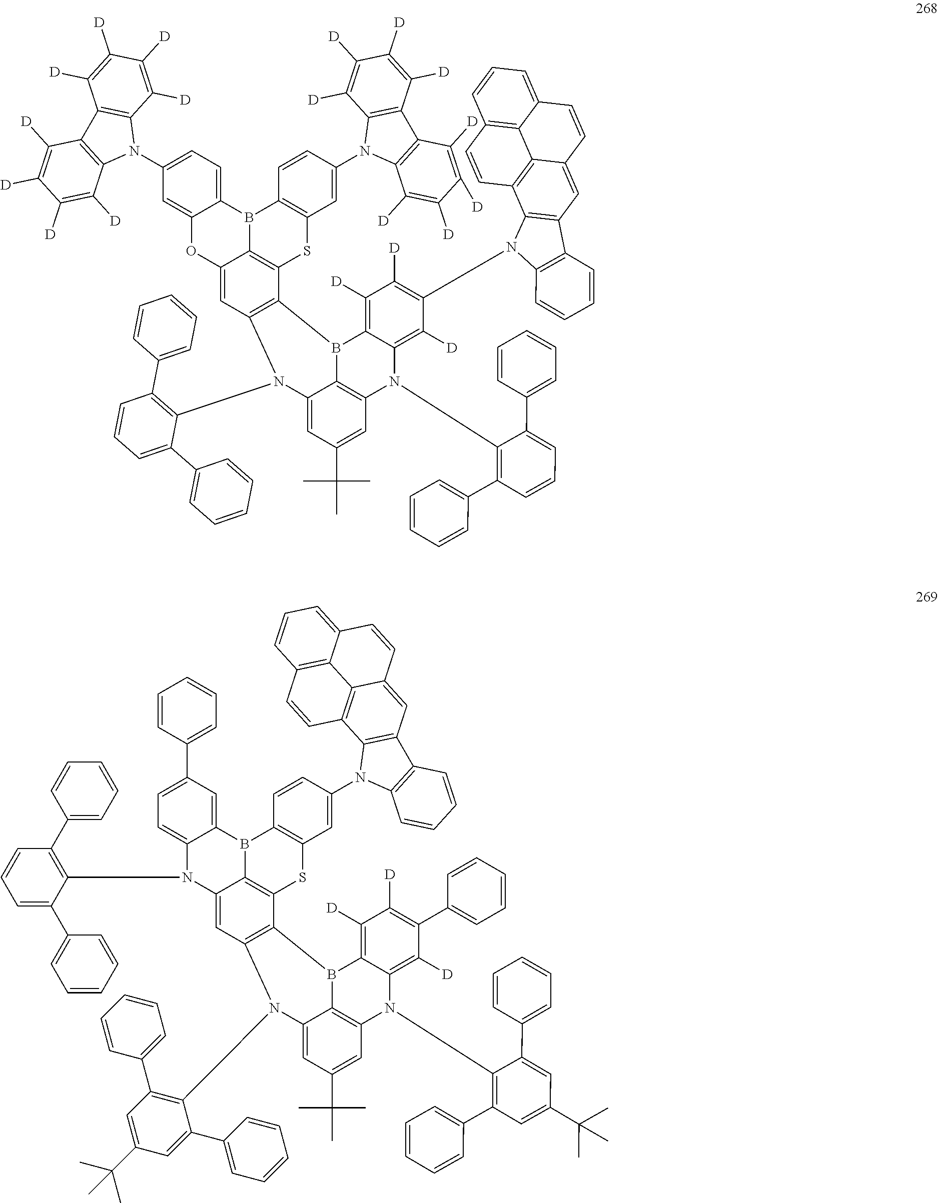

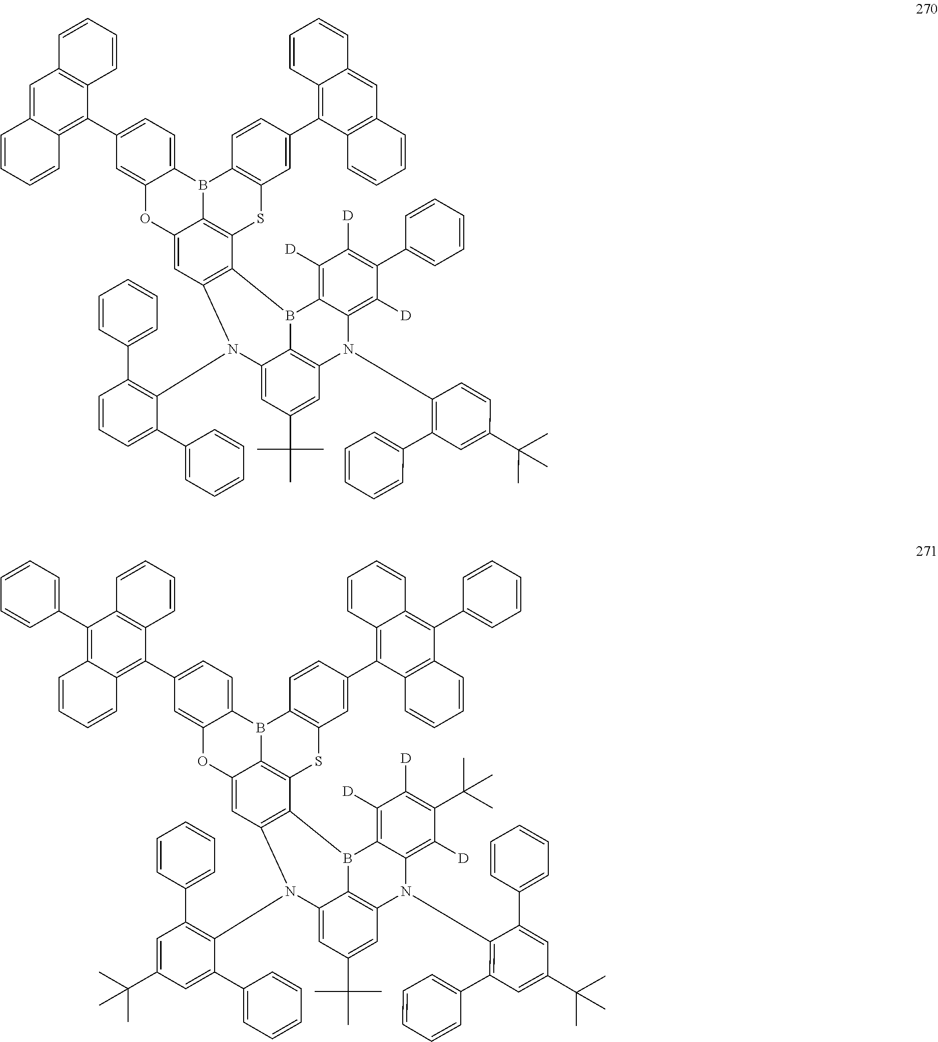 [SMILES: [2H]c1c([2H])c(-c2ccccc2)c([2H])c2c1B1c3c(cc(C(C)(C)C)cc3N2c2ccc(C(C)(C)C)cc2-c2ccccc2)N(c2c(-c3ccccc3)cccc2-c2ccccc2)c2cc3c4c(c21)Sc1cc(-c2c5ccccc5cc5ccccc25)ccc1B4c1ccc(-c2c4ccccc4cc4ccccc24)cc1O3 ; [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Sc1cc(-c2c5ccccc5c(-c5ccccc5)c5ccccc25)ccc1B4c1ccc(-c2c4ccccc4c(-c4ccccc4)c4ccccc24)cc1O3]

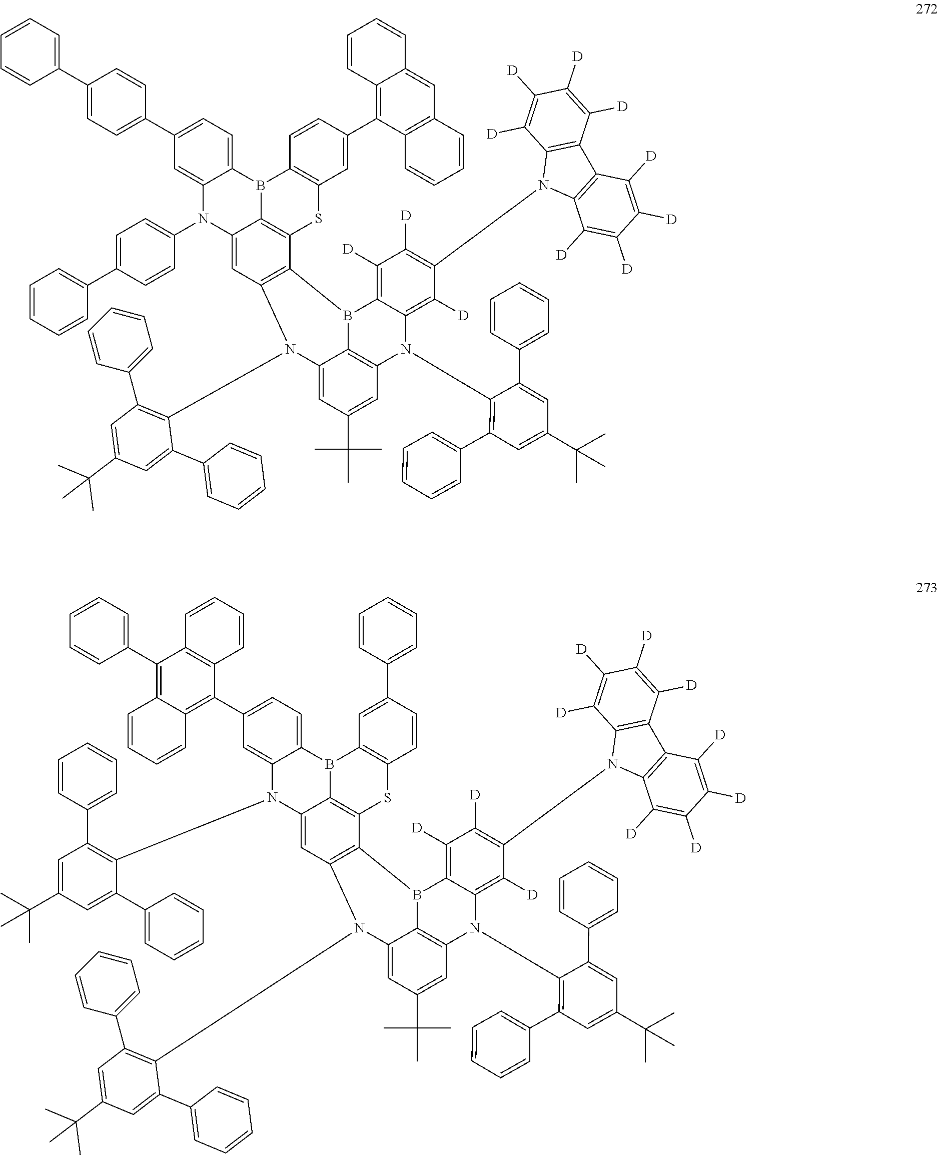

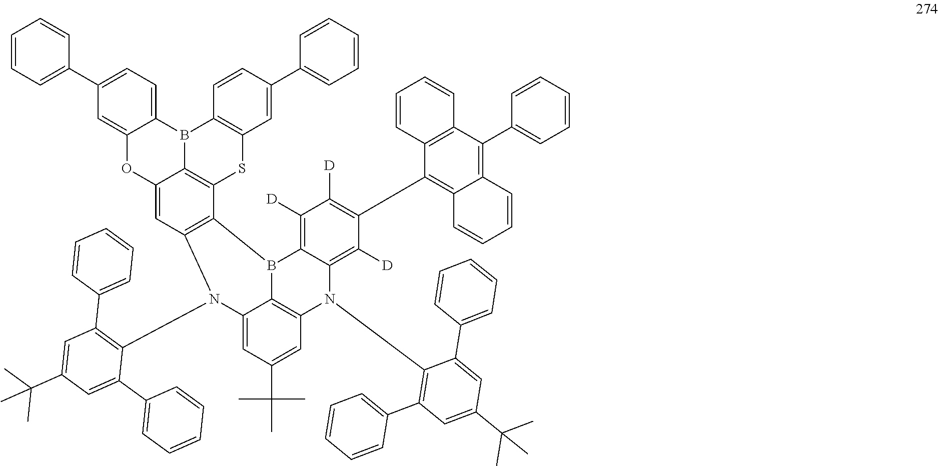 [SMILES: [2H]c1c([2H])c(-c2c3ccccc3c(-c3ccccc3)c3ccccc23)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Sc1cc(-c2ccccc2)ccc1B4c1ccc(-c2ccccc2)cc1O3]

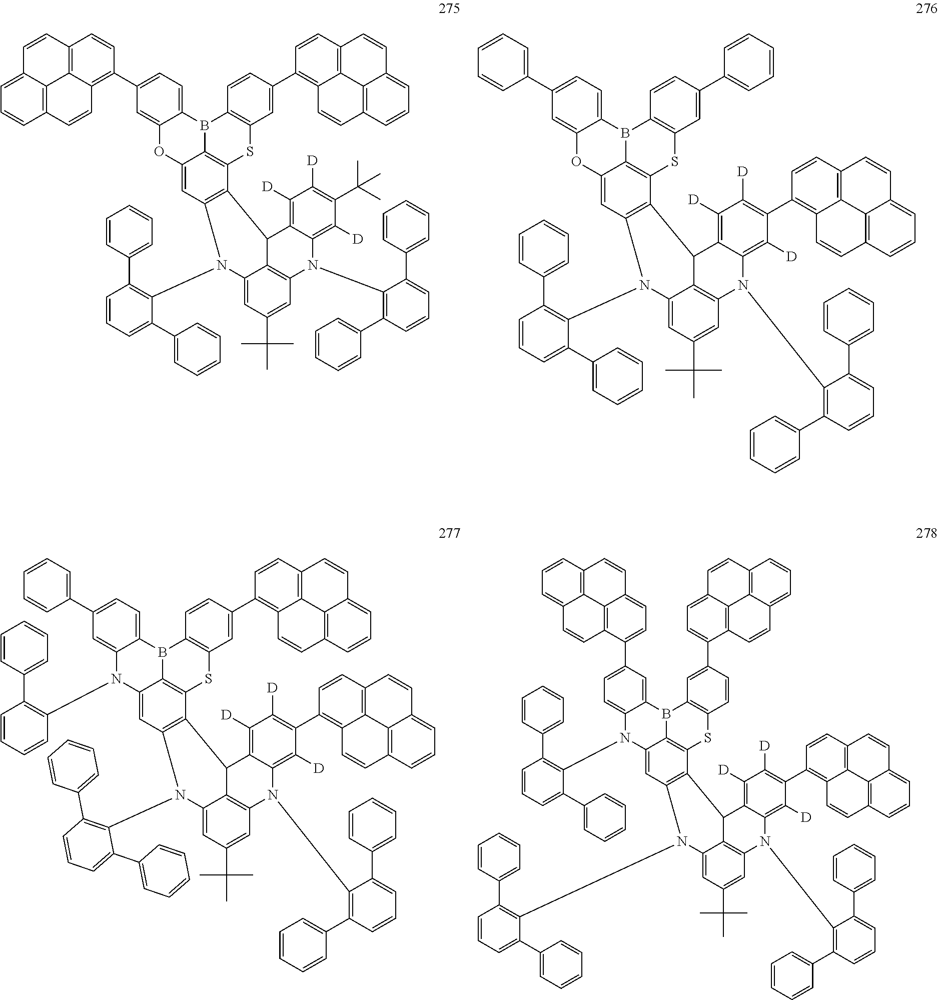

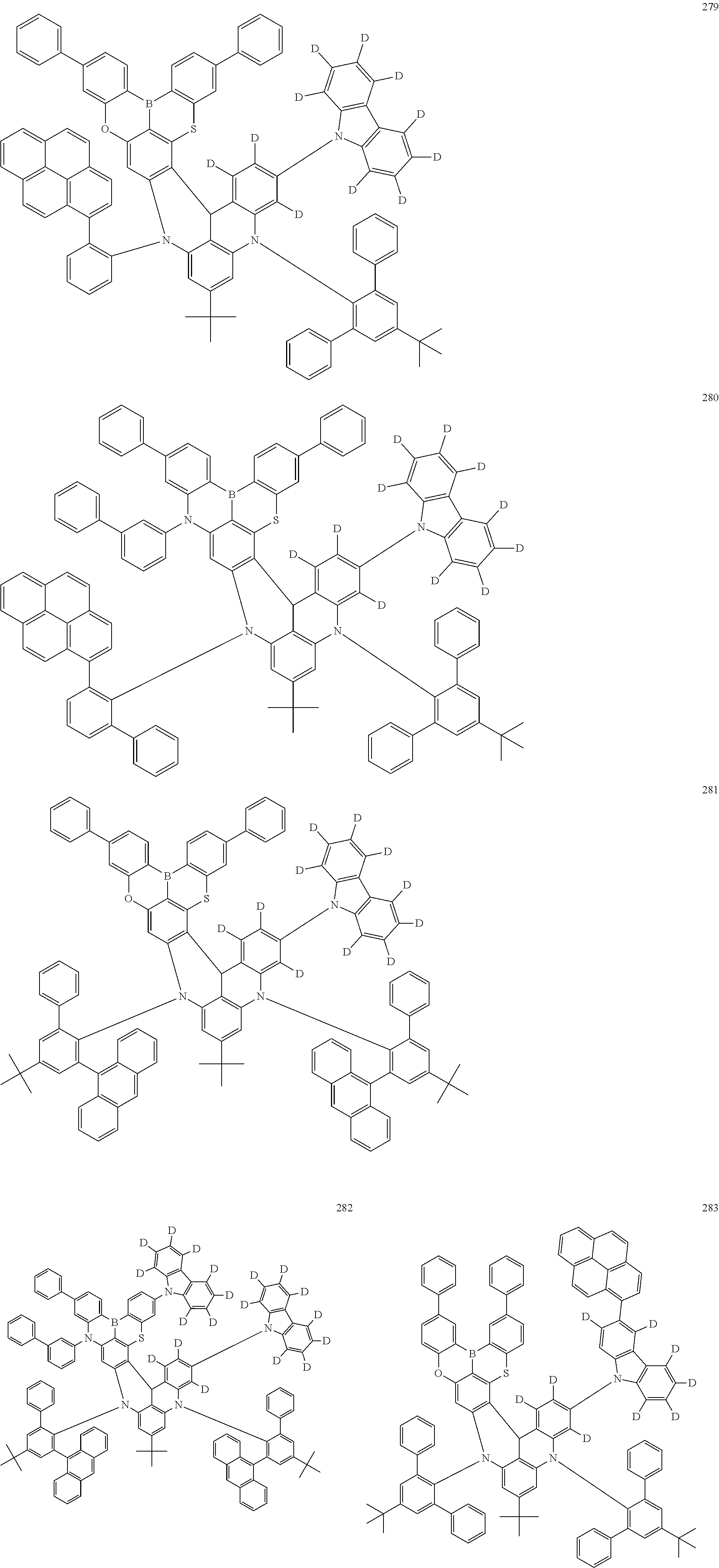

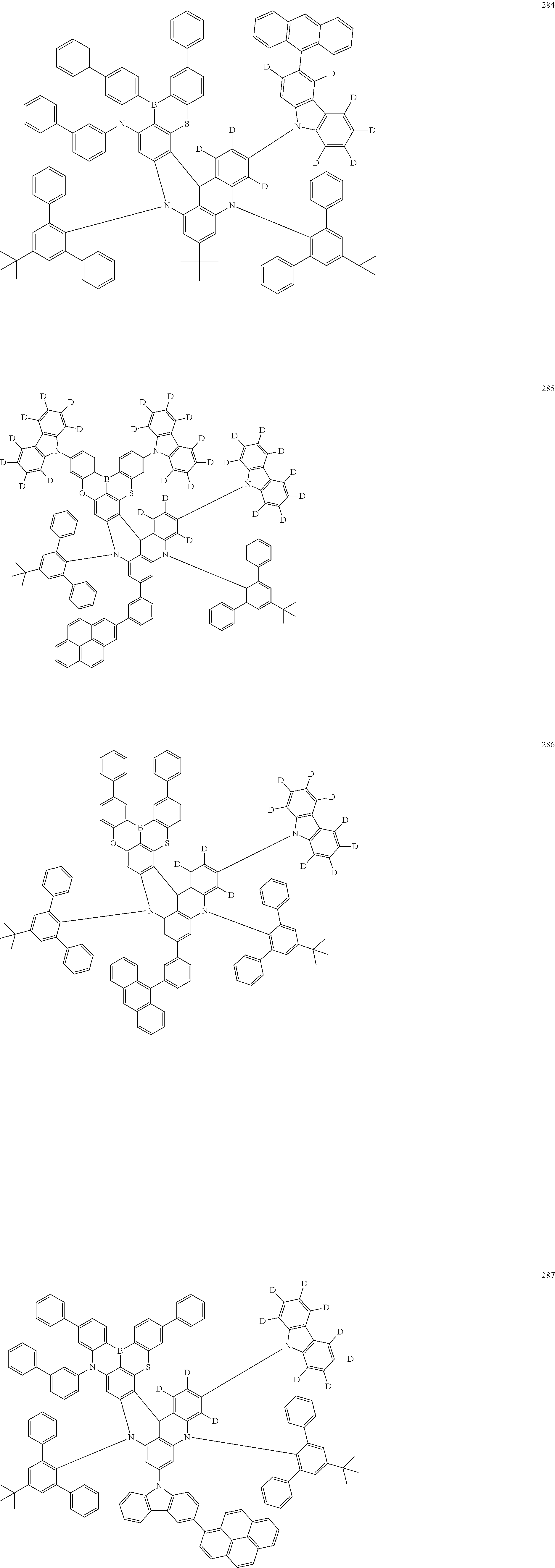

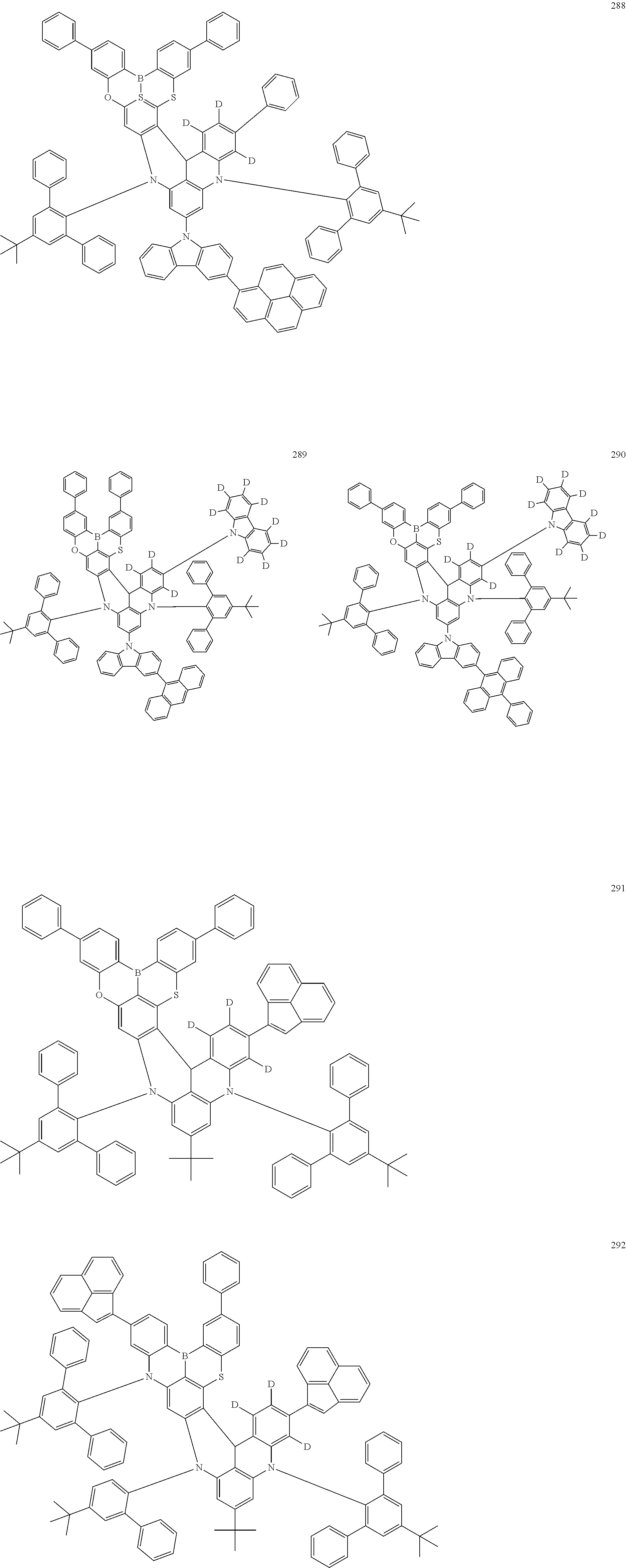

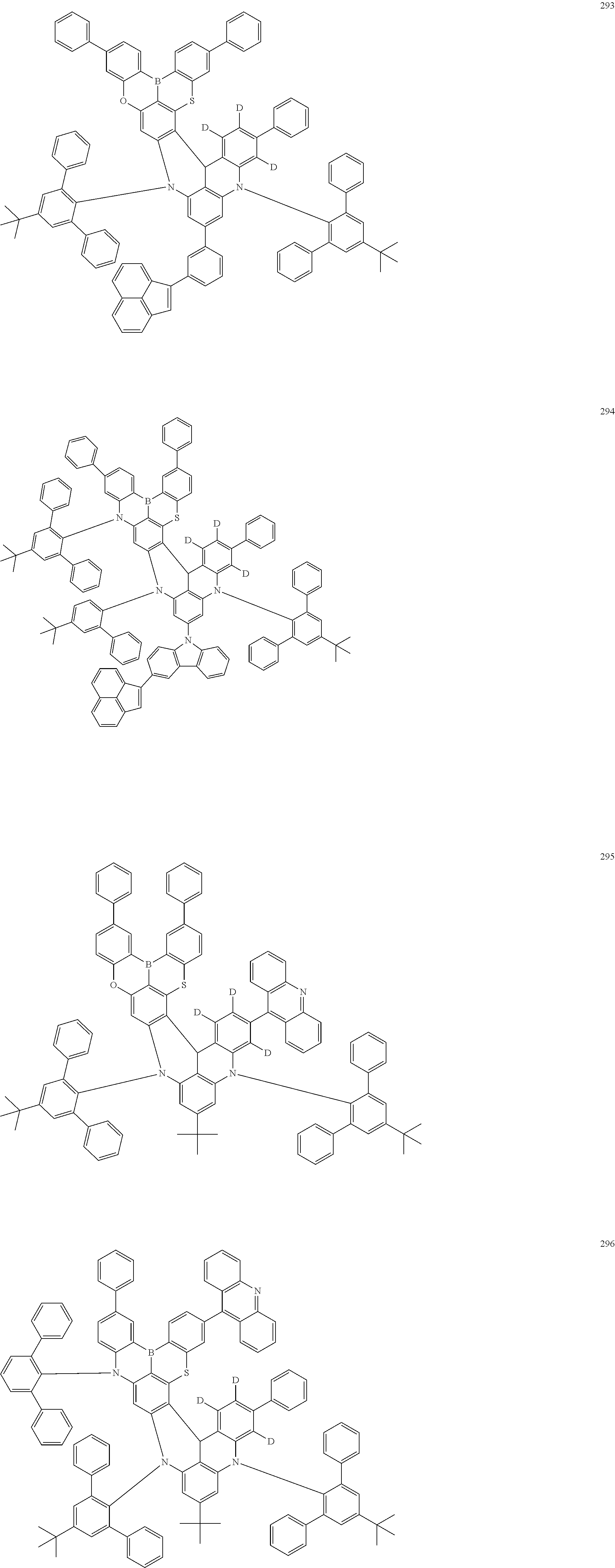

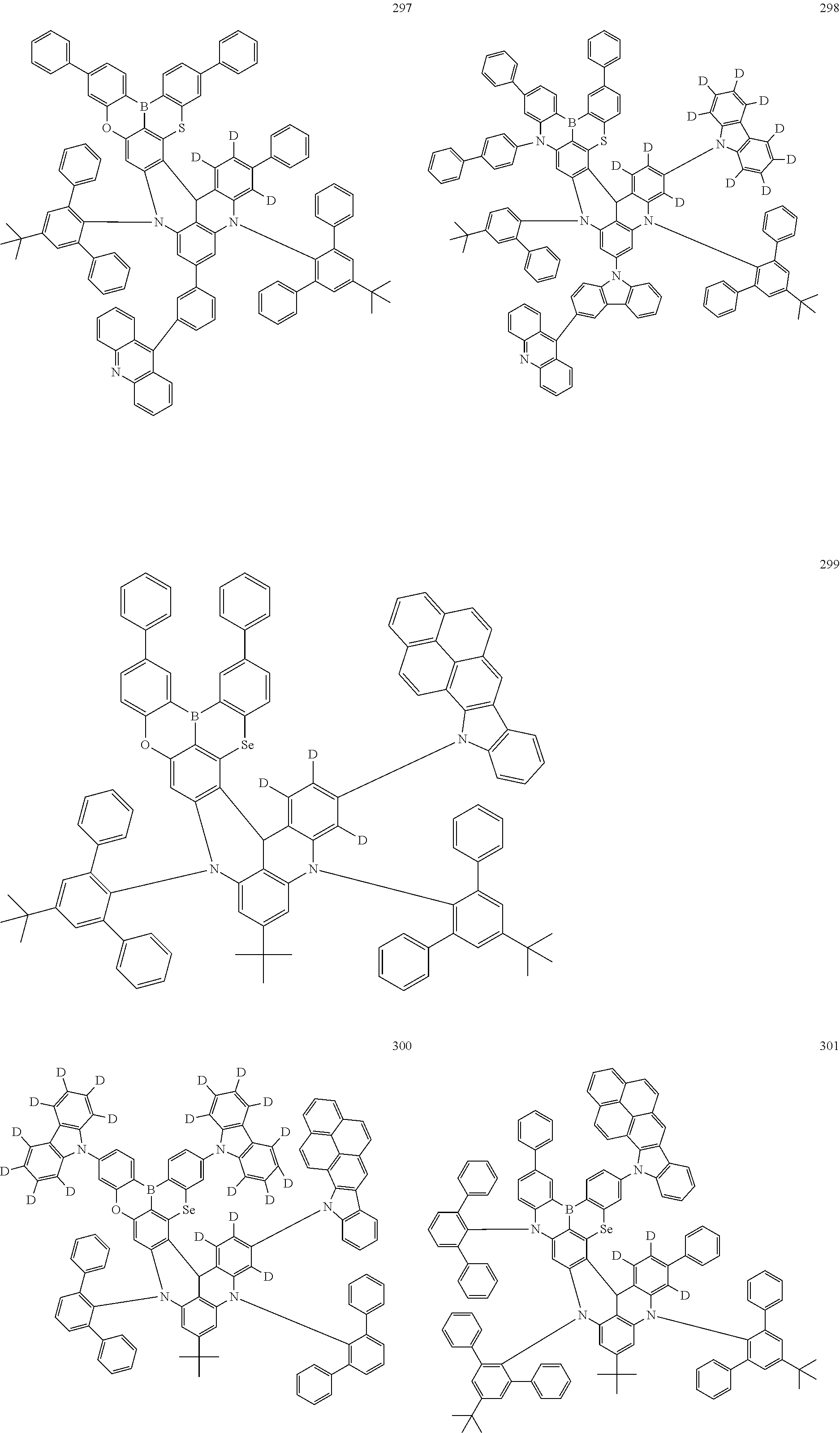

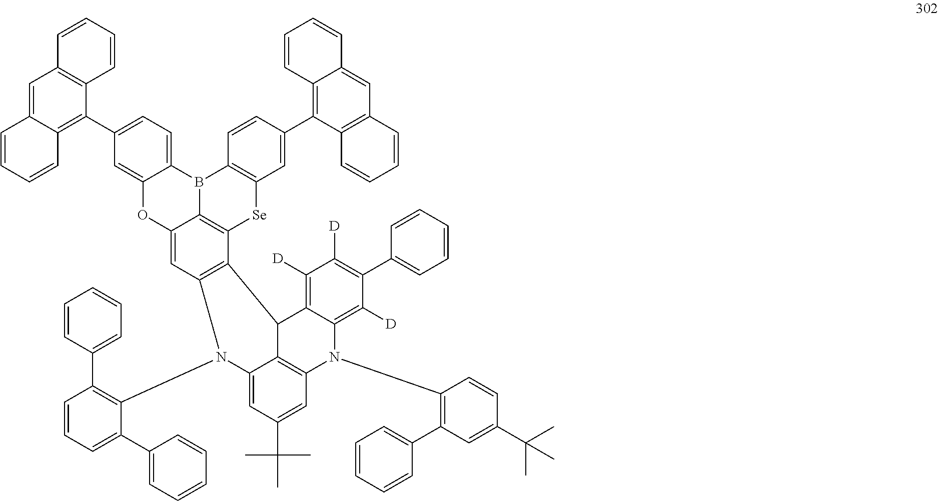 [SMILES: [2H]c1c([2H])c2c(c([2H])c1-c1ccccc1)N(c1ccc(C(C)(C)C)cc1-c1ccccc1)c1cc(C(C)(C)C)cc3c1C2c1c(cc2c4c1[Se]c1cc(-c5c6ccccc6cc6ccccc56)ccc1B4c1ccc(-c4c5ccccc5cc5ccccc45)cc1O2)N3c1c(-c2ccccc2)cccc1-c1ccccc1]

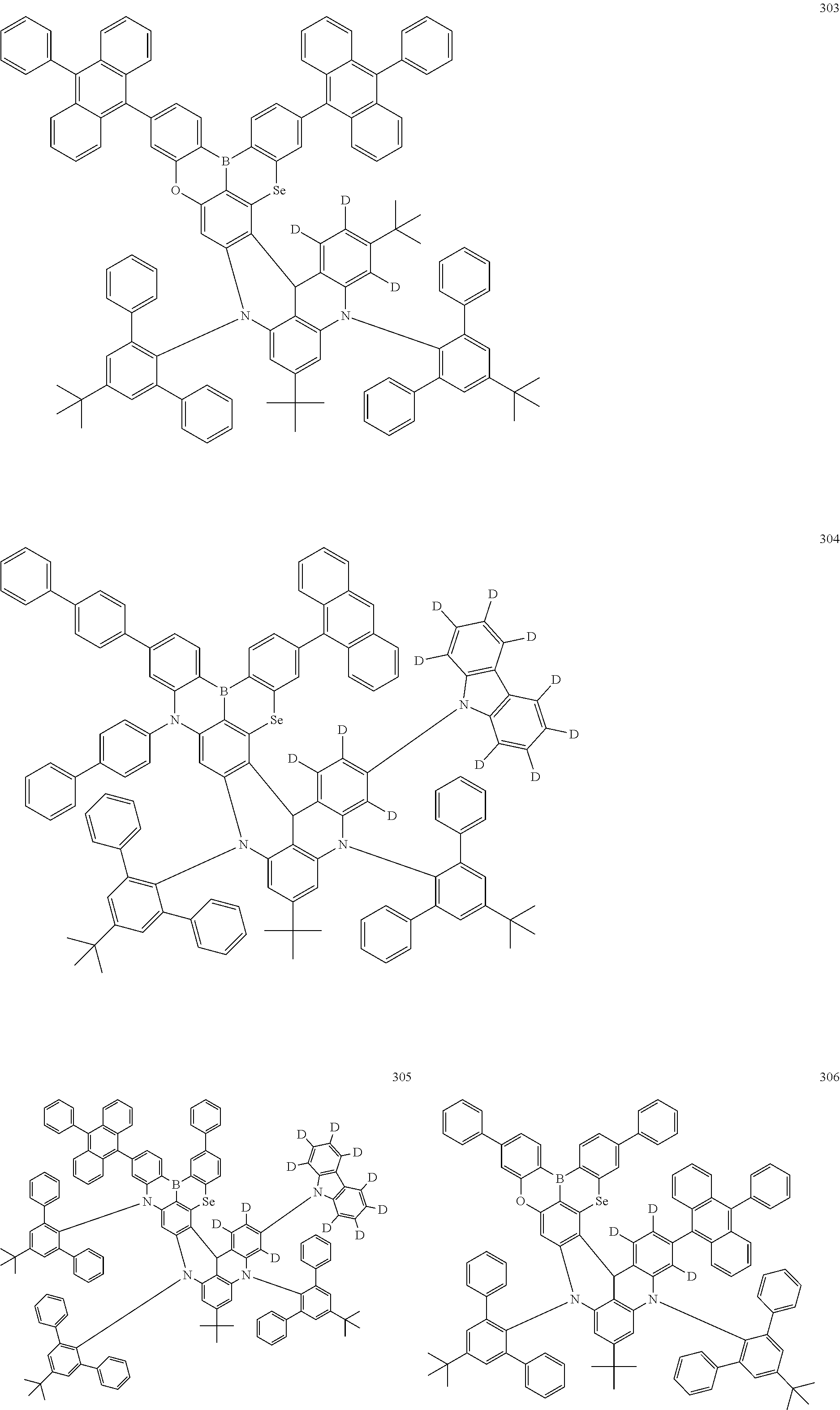

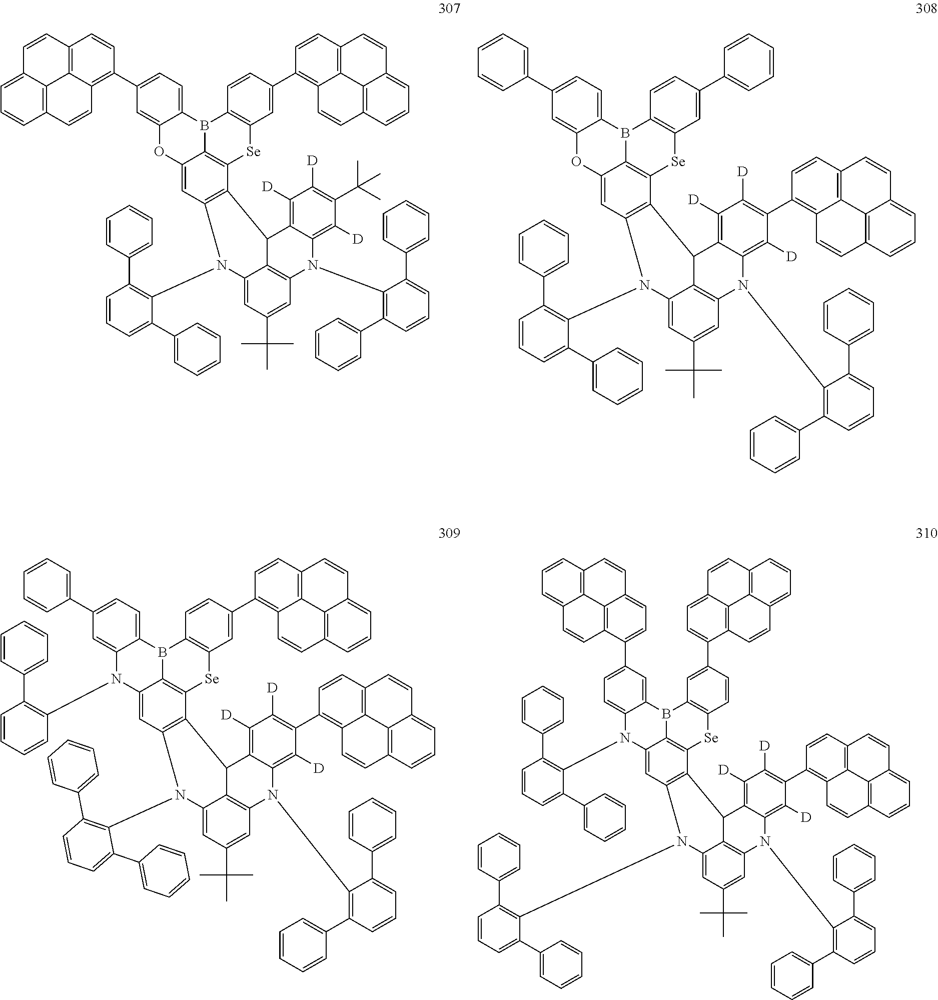

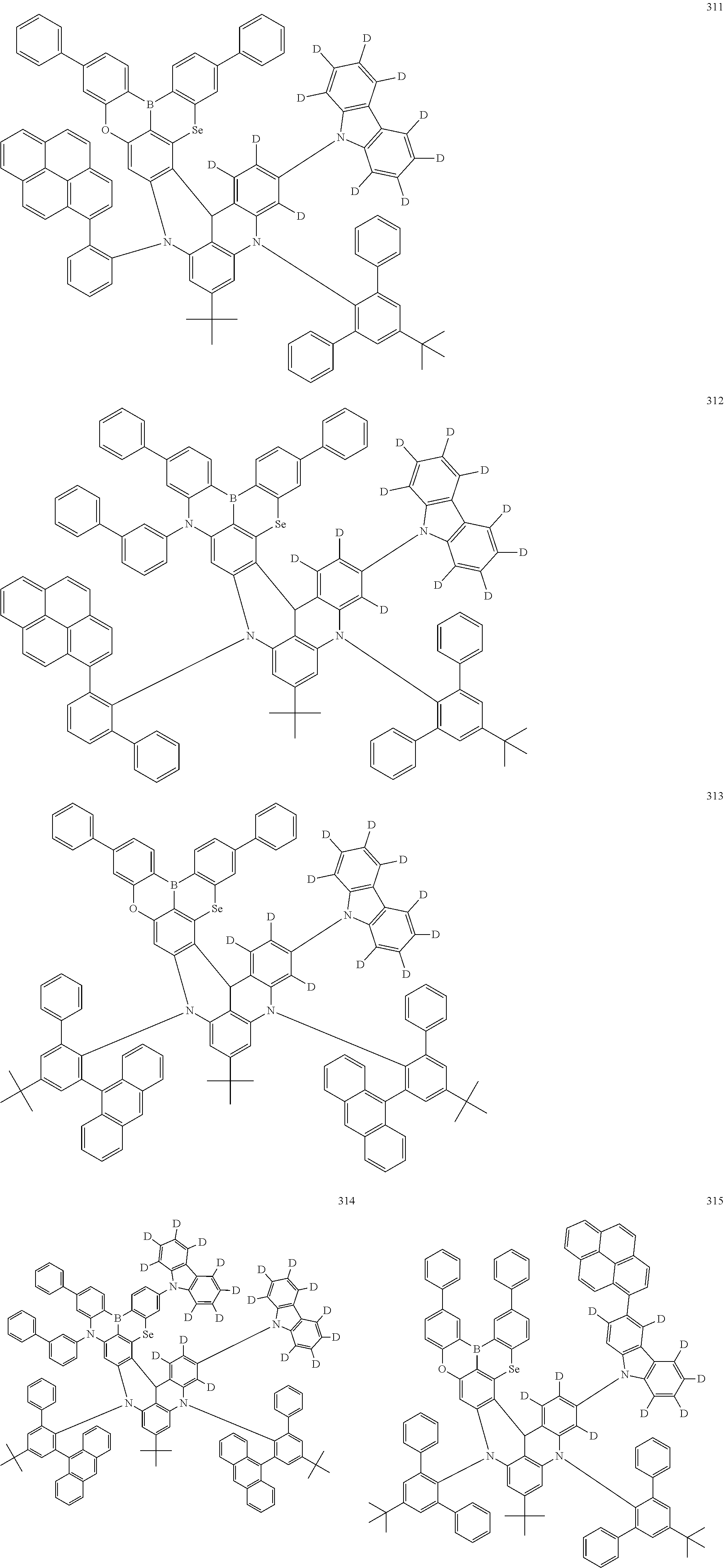

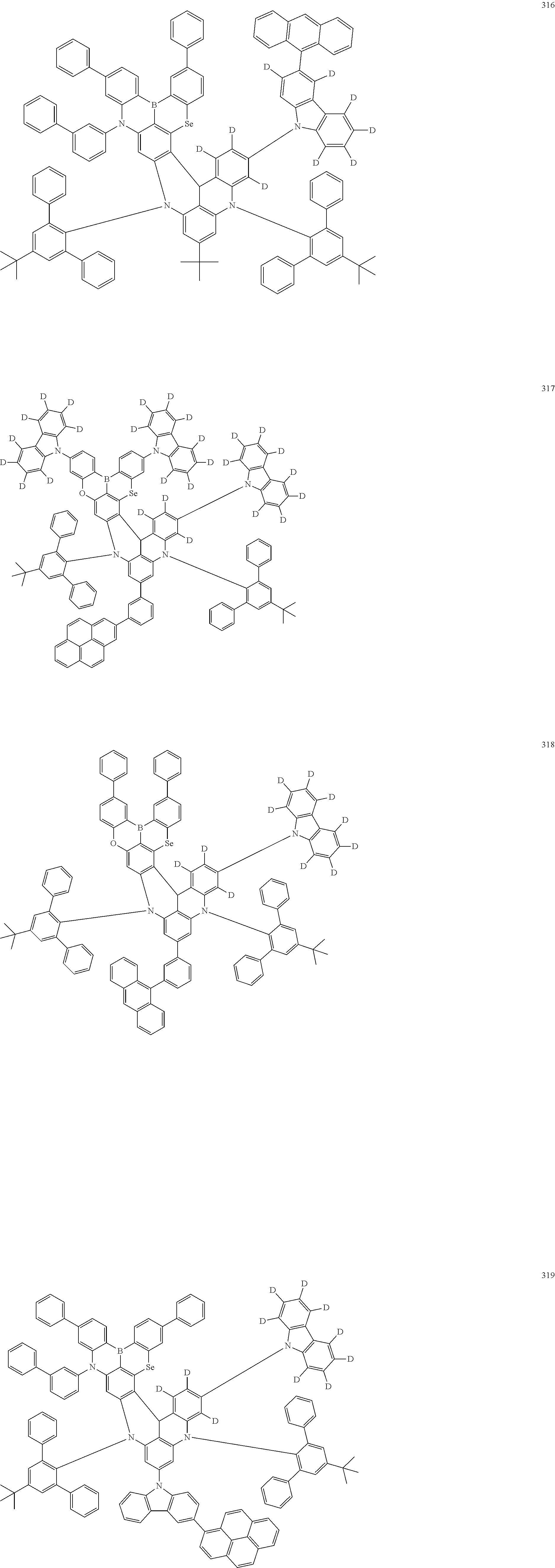

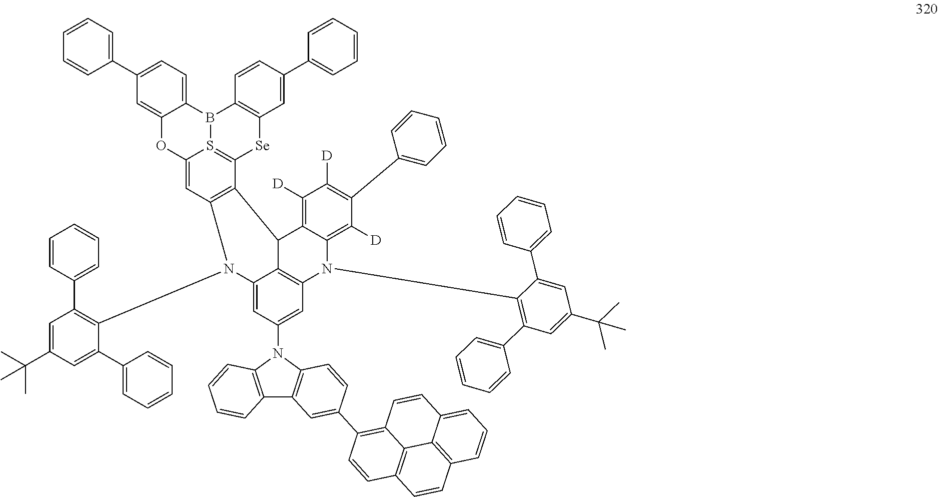 [SMILES: [2H]c1c([2H])c2c(c([2H])c1-c1ccccc1)N(c1c(-c3ccccc3)cc(C(C)(C)C)cc1-c1ccccc1)c1cc(-n3c4ccccc4c4cc(-c5ccc6ccc7cccc8ccc5c6c78)ccc43)cc3c1C2C1=C(C=C2Oc4cc(-c5ccccc5)ccc4B4c5ccc(-c6ccccc6)cc5[Se]C1=S42)N3c1c(-c2ccccc2)cc(C(C)(C)C)cc1-c1ccccc1]

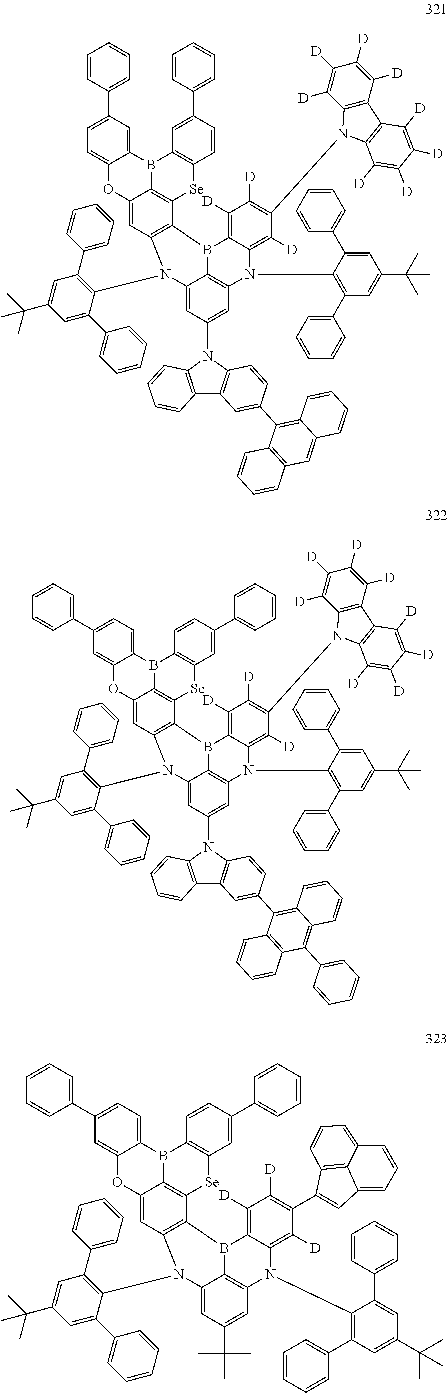

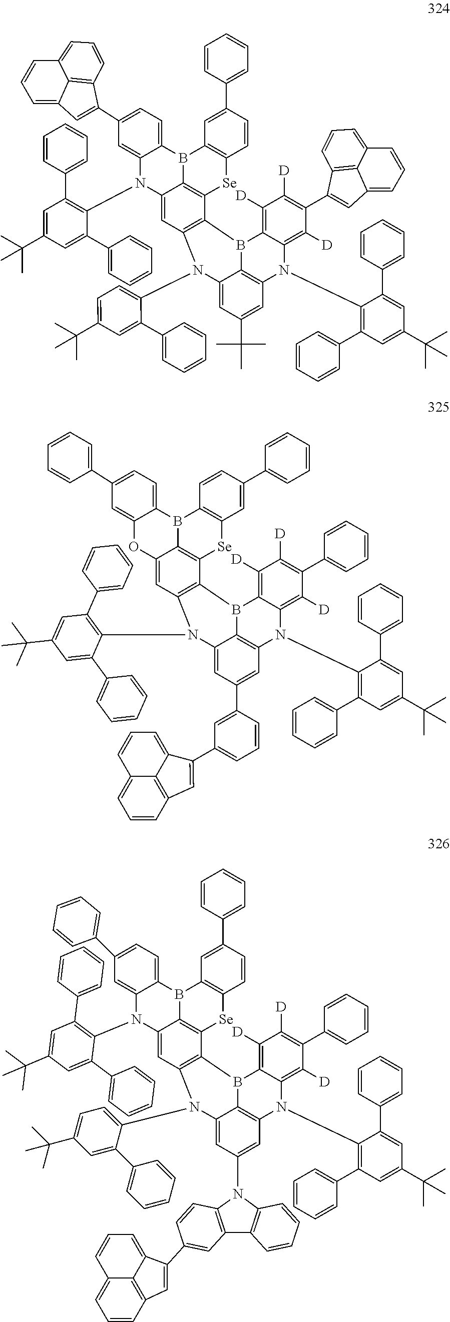

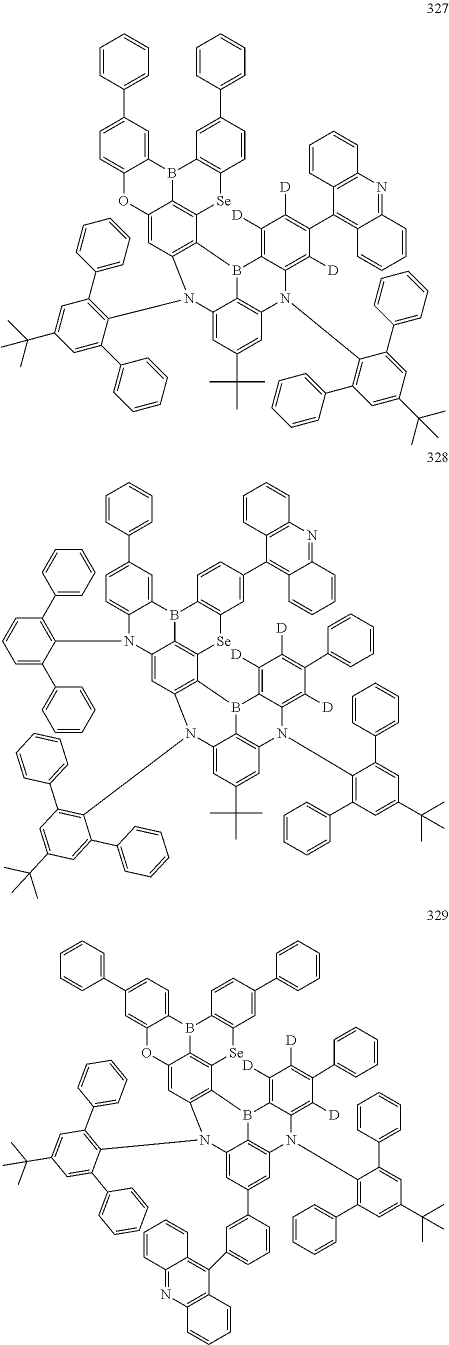

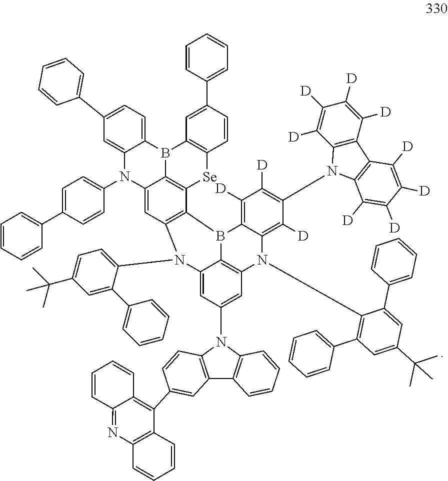 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(-n4c5ccccc5c5cc(-c6c7ccccc7nc7ccccc67)ccc54)cc3N2c2c(-c3ccccc3)cc(C(C)(C)C)cc2-c2ccccc2)N(c2ccc(C(C)(C)C)cc2-c2ccccc2)c2cc3c4c(c21)[Se]c1ccc(-c2ccccc2)cc1B4c1ccc(-c2ccccc2)cc1N3c1ccc(-c2ccccc2)cc1]

10. The light-emitting element of claim 1, wherein the emission layer further includes at least one of a second compound represented by Formula HT-1, a third compound represented by Formula ET-1, and a fourth compound represented by Formula D-1: 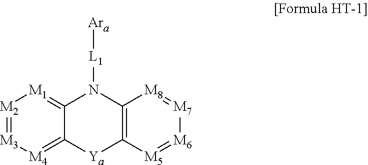
wherein in Formula HT-1,
M₁ to M₈ are each independently N or C(R₅₁),
Lₐ is a direct linkage, a substituted or unsubstituted arylene group having 6 to 30 ring-forming carbons, or a substituted or unsubstituted heteroarylene group having 2 to 30 ring-forming carbons,
Yₐ is a direct linkage, C(R₅₂)(R₅₃), or Si(R₅₄)(R₅₅),
Arₐ is a substituted or unsubstituted aryl group having 6 to 30 ring-forming carbons or a substituted or unsubstituted heteroaryl group having 2 to 30 ring-forming carbons, and
R₅₁ to R₅₅ are each independently a hydrogen atom, a deuterium atom, a halogen atom, a cyano group, a silyl group, a substituted or unsubstituted thio group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring; 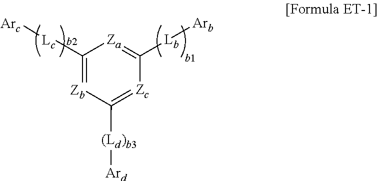
wherein in Formula ET-1,
at least one of Zₐ to Z_{c} is N,
the remainder of Zₐ to Z_{c} are each independently C(R₅₆),
R₅₆ is a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons,
b1 to b3 are each independently an integer from 0 to 10,
Ar_{b} to Ar_{d} are each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
L_{b} to L_{d} are each independently a direct linkage, a substituted or unsubstituted arylene group having 6 to 30 ring-forming carbons, or a substituted or unsubstituted heteroarylene group having 2 to 30 ring-forming carbons; 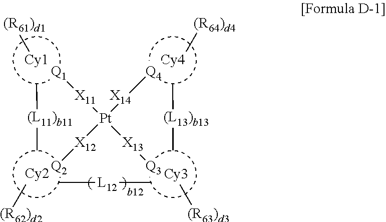
wherein in Formula D-1,
Q₁ to Q₄ are each independently C or N,
Cy1 to Cy4 are each independently a substituted or unsubstituted hydrocarbon ring having 5 to 30 ring-forming carbons or a substituted or unsubstituted heterocycle having 2 to 30 ring-forming carbons,
X₁₁ to X₁₄ may be each independently a direct linkage or *—O—*,
L₁₁ to L₁₃ are each independently a direct linkage, 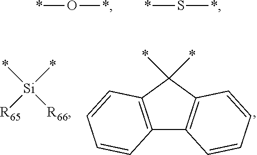
a substituted or unsubstituted alkylene group having 1 to 20 carbons, a substituted or unsubstituted arylene group having 6 to 30 ring-forming carbons, or a substituted or unsubstituted heteroarylene group having 2 to 30 ring-forming carbons,
b11 to b13 are each independently 0 or 1,
R₆₁ to R₆₆ are each independently a hydrogen atom, a deuterium atom, a halogen atom, a cyano group, a nitro group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, and
d1 to d4 are each independently an integer from 0 to 4.

11. An electronic apparatus comprising:
a circuit layer disposed on a base layer; and
a display element layer disposed on the circuit layer, the display element layer including a light-emitting element, wherein
the light-emitting element comprises:
a first electrode;
a second electrode disposed on the first electrode; and
an emission layer disposed between the first electrode and the second electrode, and
the emission layer includes a first compound represented by Formula 1: 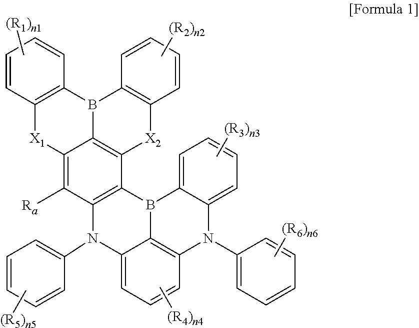
wherein in Formula 1,
X₁ is O, S, Se, or a moiety represented by Formula 2, and
X₂ is O, S, Se, or N(R₈); 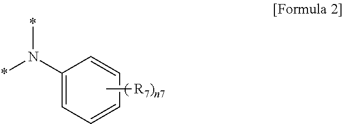
wherein in Formula 1 and Formula 2,
Rₐ and R₁ to R₇ are each independently a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
R₈ is a substituted or unsubstituted aryl group having 6 to 30 ring-forming carbons or a substituted or unsubstituted heteroaryl group having 2 to 30 ring-forming carbons,
at least one of R₁ to R₇ each independently includes a substituted or unsubstituted anthracene group, a substituted or unsubstituted pyrene group, a substituted or unsubstituted acenaphthyl group, or a substituted or unsubstituted acridine group,
n1 to n3 are each independently an integer from 0 to 4,
n4 is an integer from 0 to 3, and
n5 to n7 are each independently an integer from 0 to 5, and
wherein in Formula 2,
-* represents a bond to Formula 1.

12. The electronic apparatus of claim 11, wherein
the light-emitting element further comprises a capping layer disposed on the second electrode, and
the capping layer has a refractive index equal to or greater than about 1.6 with respect to light in a wavelength range of about 550 nm to about 660 nm.

13. The electronic apparatus of claim 11 further comprising:
an optical control layer disposed on the display element layer, wherein
the light-emitting element emits a first color light, and
the optical control layer includes:
a first optical control part that includes a first quantum dot that converts the first color light to a second color light having a longer wavelength region than the first color light;
a second optical control part that includes a second quantum dot that converts the first color light to a third color light having a longer wavelength region than the first color light and the second color light; and
a third optical control part that transmits the first color light.

14. The electronic apparatus of claim 13, further comprising:
a color filter layer disposed on the optical control layer, wherein
the color filter layer includes:
a first filter that transmits the second color light;
a second filter that transmits the third color light; and
a third filter that transmits the first color light.

15. A fused polycyclic compound represented by Formula 1: 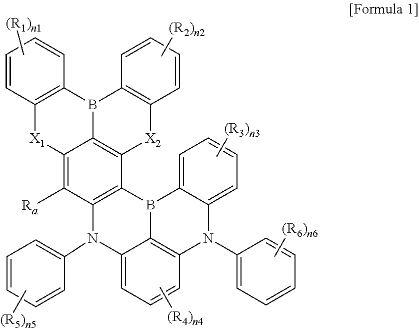
wherein in Formula 1,
X₁ is O, S, Se, or a moiety represented by Formula 2, and
X₂ is O, S, Se, or N(R₈); 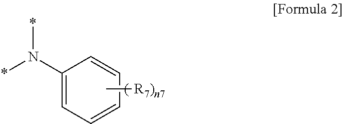
wherein in Formula 1 and Formula 2,
Rₐ and R₁ to R₇ are each independently a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
R₈ is a substituted or unsubstituted aryl group having 6 to 30 ring-forming carbons or a substituted or unsubstituted heteroaryl group having 2 to 30 ring-forming carbons,
at least one of R₁ to R₇ each independently includes a substituted or unsubstituted anthracene group, a substituted or unsubstituted pyrene group, a substituted or unsubstituted acenaphthyl group, a substituted or unsubstituted acridine group,
n1 to n3 are each independently an integer from 0 to 4,
n4 is an integer from 0 to 3, and
n5 to n7 each independently an integer from 0 to 5, and
wherein in Formula 2,
-* represents a bond to Formula 1.

16. The fused polycyclic compound of claim 15, wherein in Formula 1, at least one of R₁ to R₇ is each independently a group represented by Formula 3-1 or Formula 3-2: 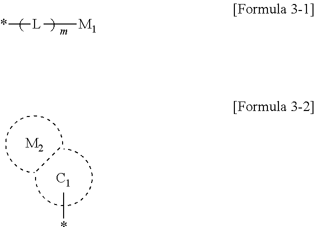
wherein in Formula 3-1 and Formula 3-2,
M₁ a substituted or unsubstituted anthracene group, a substituted or unsubstituted pyrene group, a substituted or unsubstituted acenaphthyl group, or a substituted or unsubstituted acridine group,
L is a direct linkage, a substituted or unsubstituted arylene group having 6 to 30 ring-forming carbons, or a substituted or unsubstituted heteroarylene group having 2 to 30 ring-forming carbons,
m is an integer from 1 to 3,
M₂ is a substituted or unsubstituted anthracene ring, a substituted or unsubstituted pyrene ring, a substituted or unsubstituted acenaphthyl ring, a substituted or unsubstituted acridine ring,
C₁ is a substituted or unsubstituted aromatic hydrocarbon ring having 6 to 30 ring-forming carbons or a substituted or unsubstituted aromatic heterocycle having 2 to 30 ring-forming carbons, and
-* represents a bond to Formula 1.

17. The fused polycyclic compound of claim 15, wherein in Formula 1, at least one of R₁ to R₇ is each independently a group represented by one of Formula 4-1 to Formula 4-5: 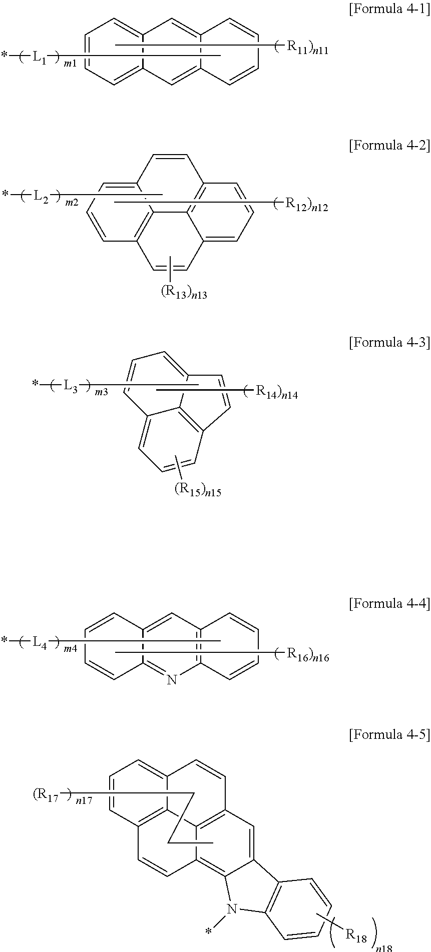
wherein in Formula 4-1 to Formula 4-5,
L₁ to L₄ are each independently a direct linkage, a substituted or unsubstituted arylene group having 6 to 30 ring-forming carbons, or a substituted or unsubstituted heteroarylene group having 2 to 30 ring-forming carbons,
R₁₁ to R₁₈ are each independently a hydrogen atom, a deuterium atom, a halogen atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons,
m1 to m4 are each independently an integer from 1 to 3,
n11 is an integer from 0 to 9,
n12 is an integer from 0 to 7,
n13 is an integer from 0 to 2,
n14 and n18 are each independently an integer from 0 to 4,
n15 is an integer from 0 to 3,
n16 and n17 are each independently an integer from 0 to 8, and
-* represents a bond to Formula 1.

18. The fused polycyclic compound of claim 15, wherein the fused polycyclic compound is represented by Formula 5-1 or Formula 5-2: 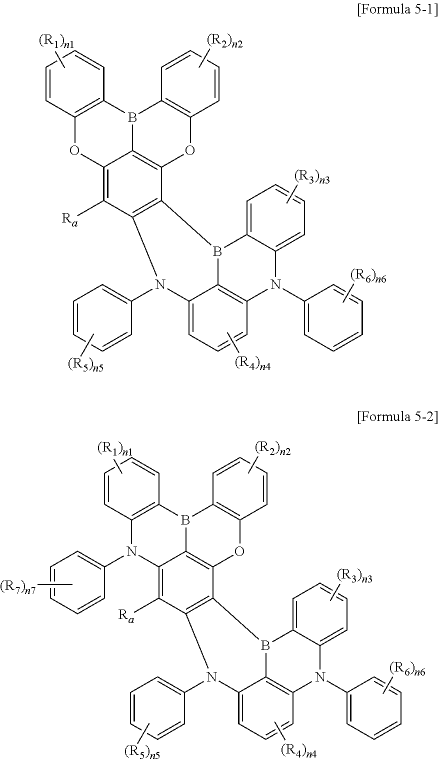
wherein in Formula 5-1 and Formula 5-2,
Rₐ, R₁ to R₇, and n1 to n7 are the same as defined in Formula 1.

19. The fused polycyclic compound of claim 15, wherein the fused polycyclic compound is represented by Formula 6-1 or Formula 6-2: 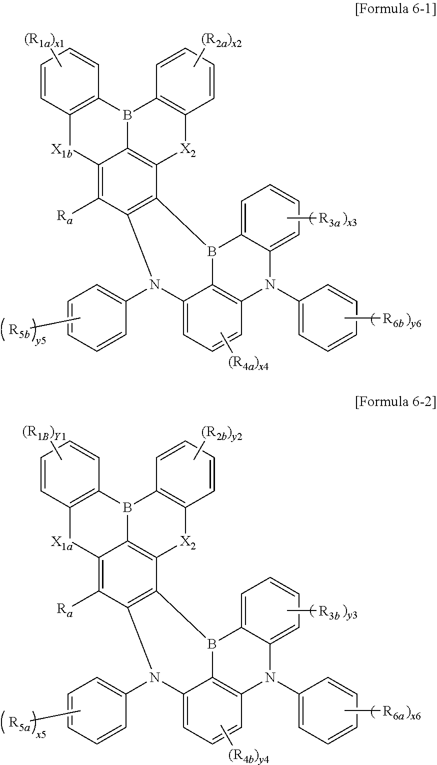
wherein in Formula 6-1 and Formula 6-2,
X₁ₐ is O, S, Se, or a moiety represented by Formula 2-a, and
X_{1b} is O, S, Se, or a moiety represented by Formula 2-b: 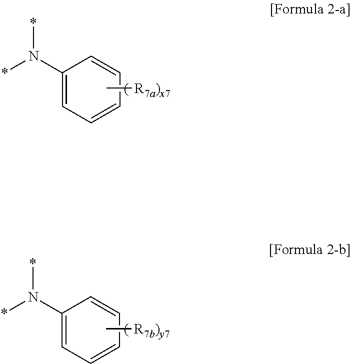
wherein in Formula 6-1, Formula 6-2, Formula 2-a, and Formula 2-b,
R₁ₐ to R₇ₐ and R_{1b} to R_{7b} are each independently a hydrogen atom, a deuterium atom, a halogen atom, a cyano group, a nitro group, a substituted or unsubstituted oxy group, a substituted or unsubstituted amine group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, or bonded to an adjacent group to form a ring,
x1 to x3 and y1 to y3 are each independently an integer from 0 to 4,
x4 and y4 are each independently an integer from 0 to 3,
x5 to x7 and y5 to y7 are each independently an integer from 0 to 5, and
-* represents a bond to Formula 1,
wherein in Formula 6-1,
at least one of R₁ₐ to R₄ₐ each independently comprises a substituted or unsubstituted anthracene group, a substituted or unsubstituted pyrene group, a substituted or unsubstituted acenaphthyl group, or a substituted or unsubstituted acridine group,
wherein in Formula 6-2,
at least one among R₅ₐ to R₇ₐ each independently comprises a substituted or unsubstituted anthracene group, a substituted or unsubstituted pyrene group, a substituted or unsubstituted acenaphthyl group, or a substituted or unsubstituted acridine group, and
wherein in Formula 6-1 and Formula 6-2,
Rₐ and X₂ are the same as defined in Formula 1.

20. The fused polycyclic compound of claim 15, wherein the fused polycyclic compound is selected from Compound Group 1: 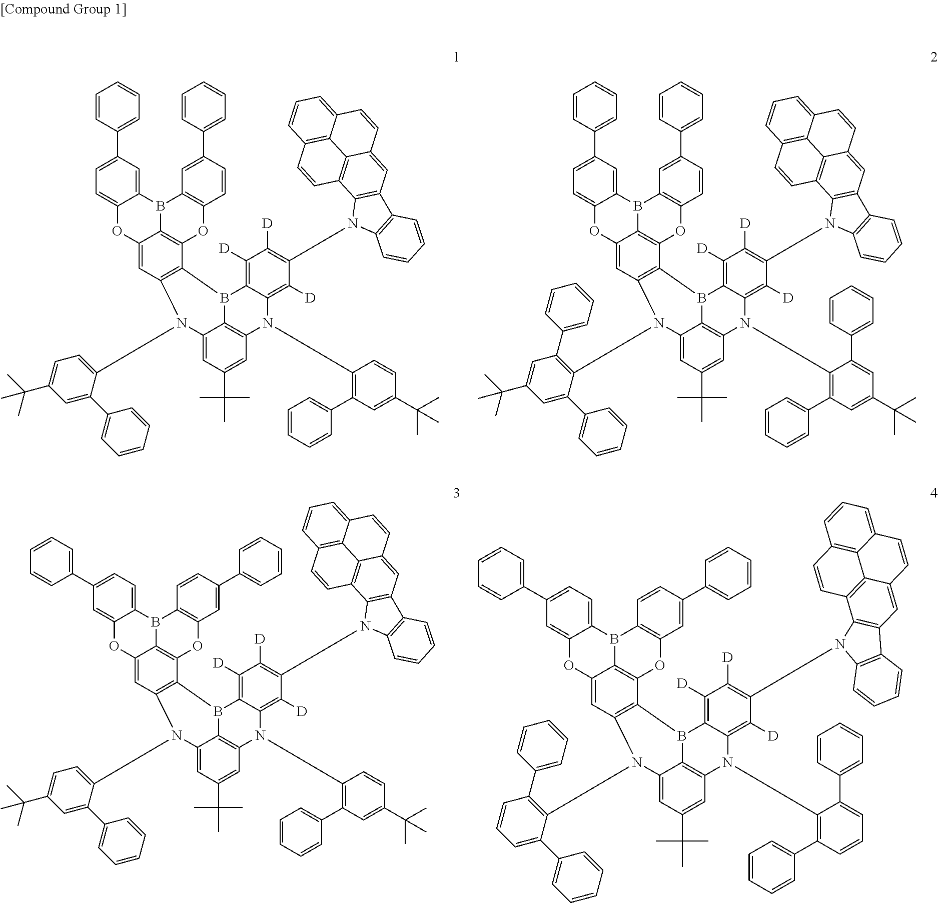 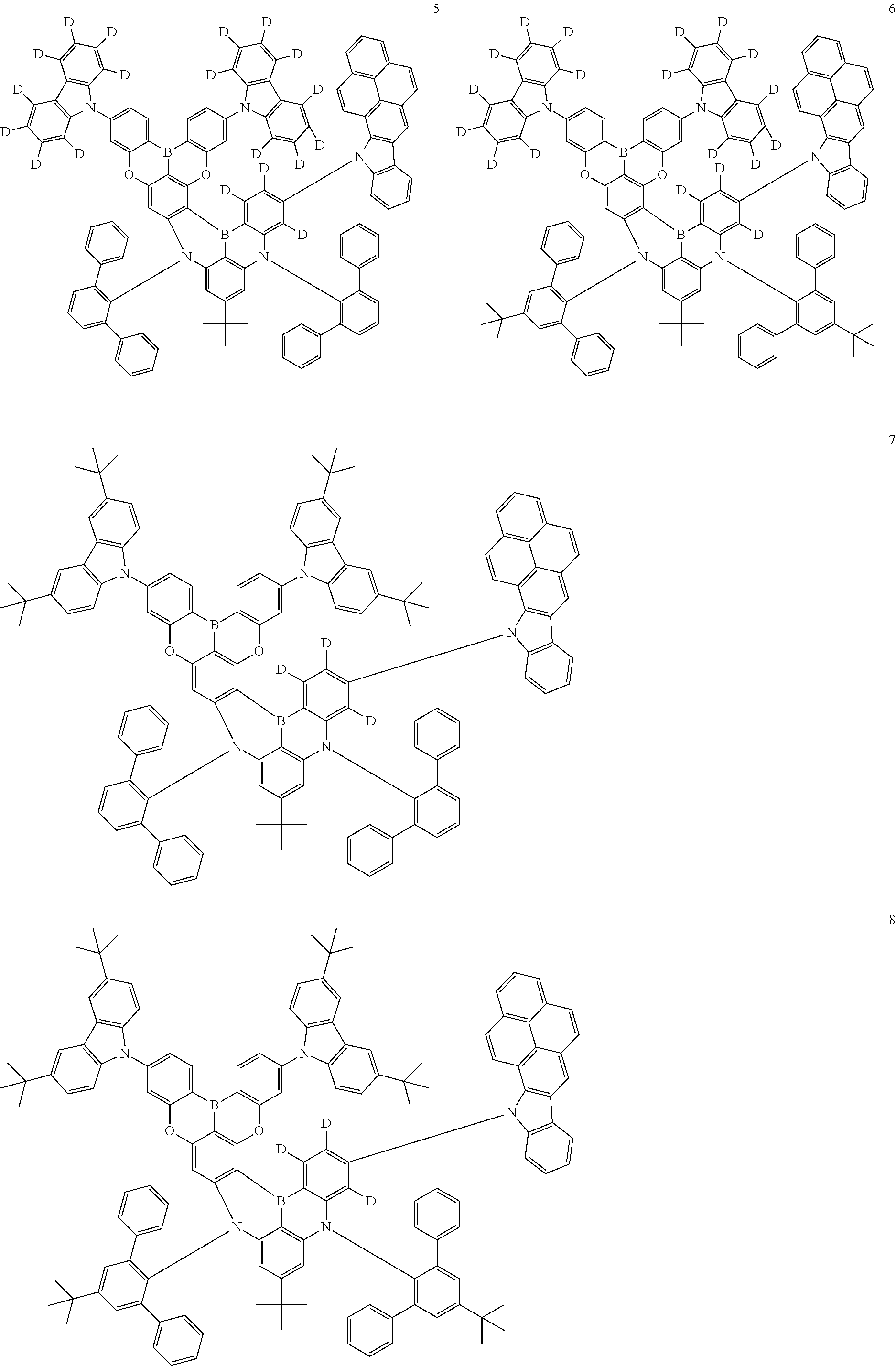 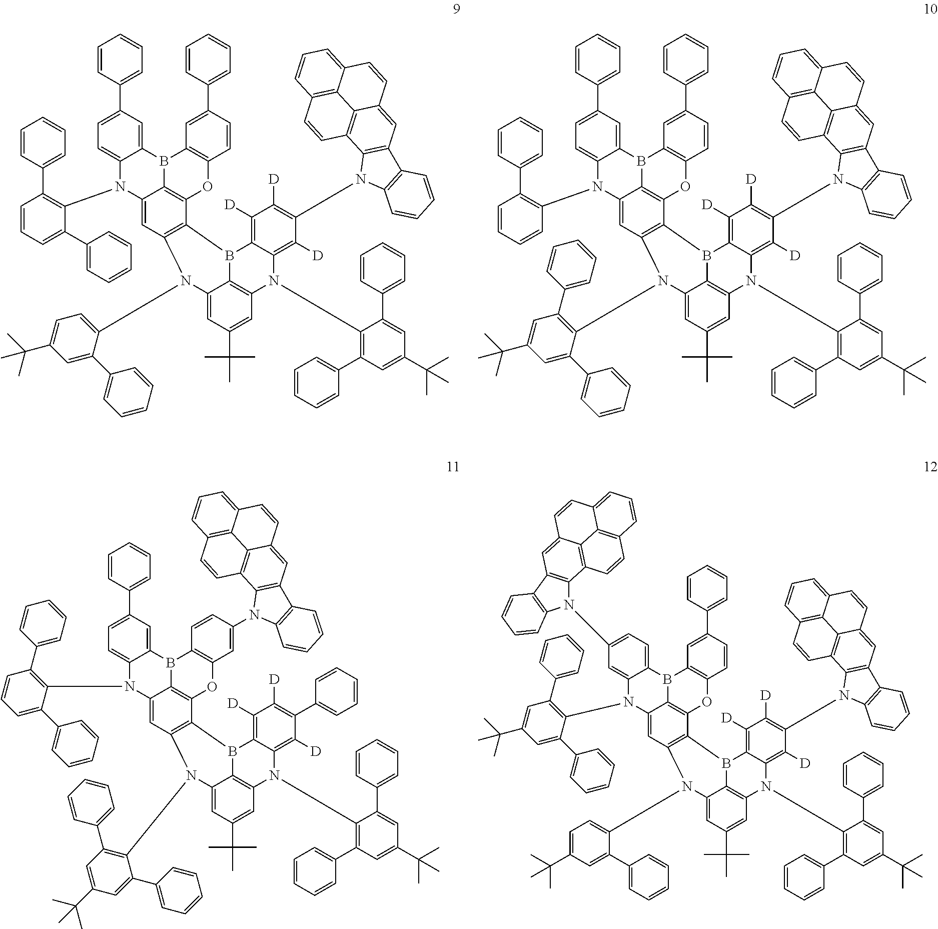 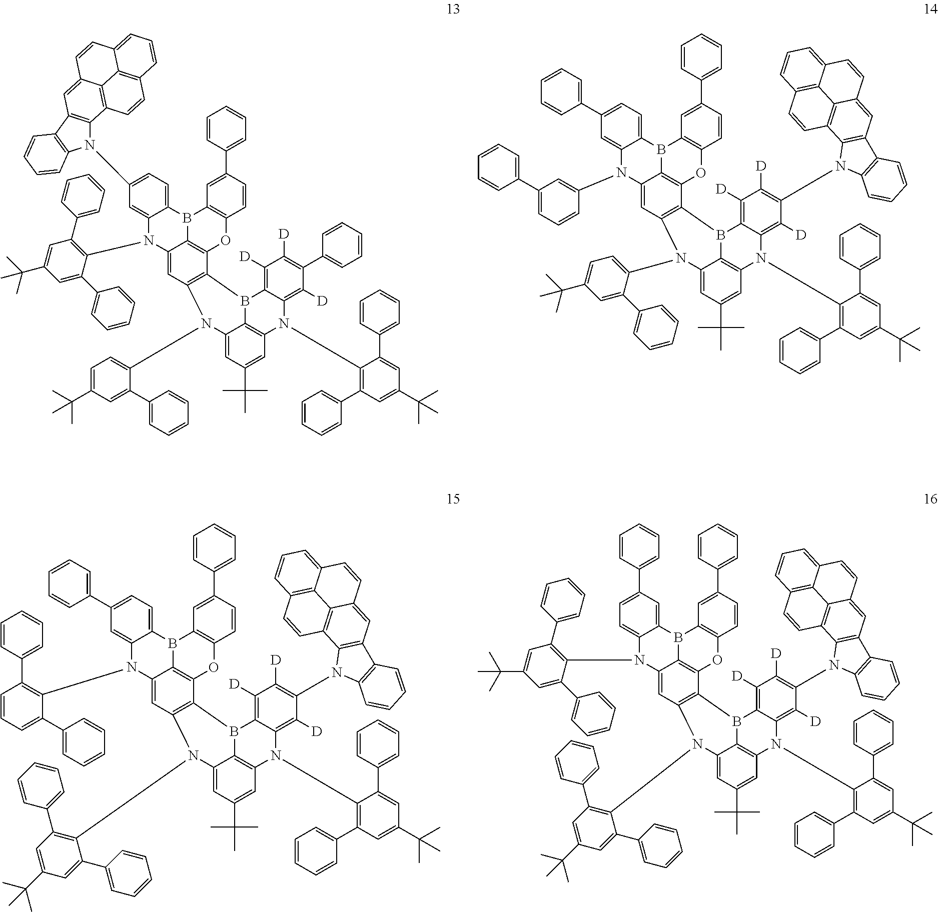 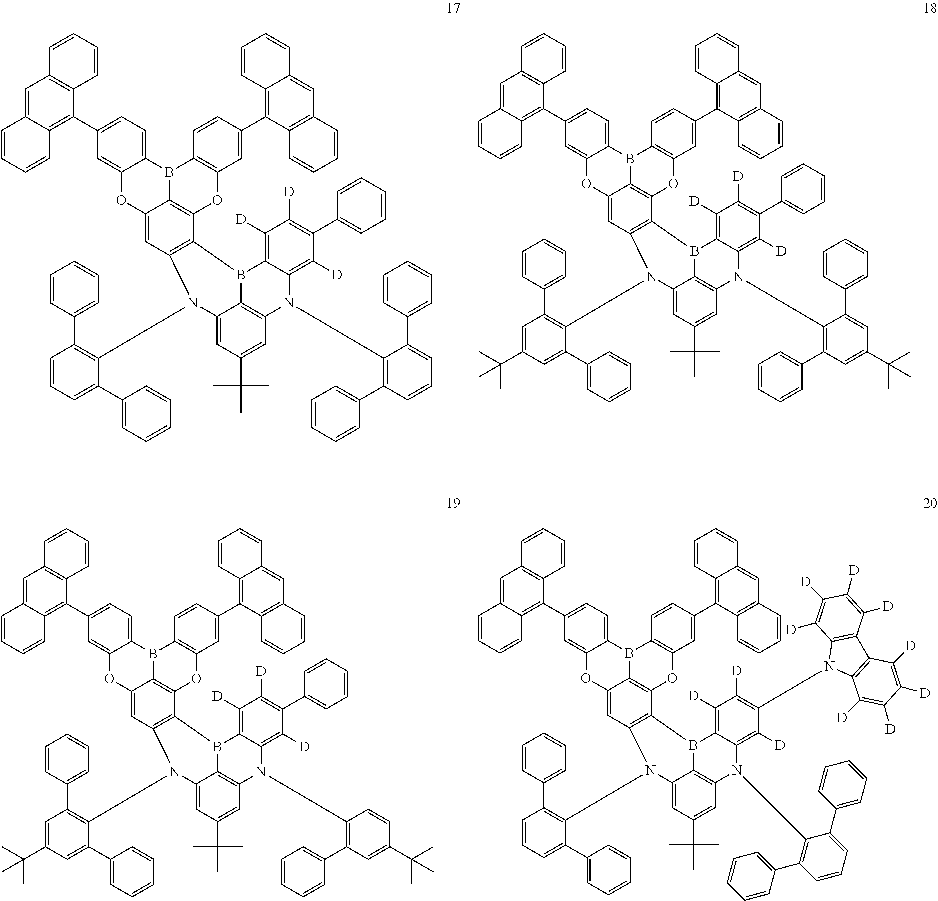 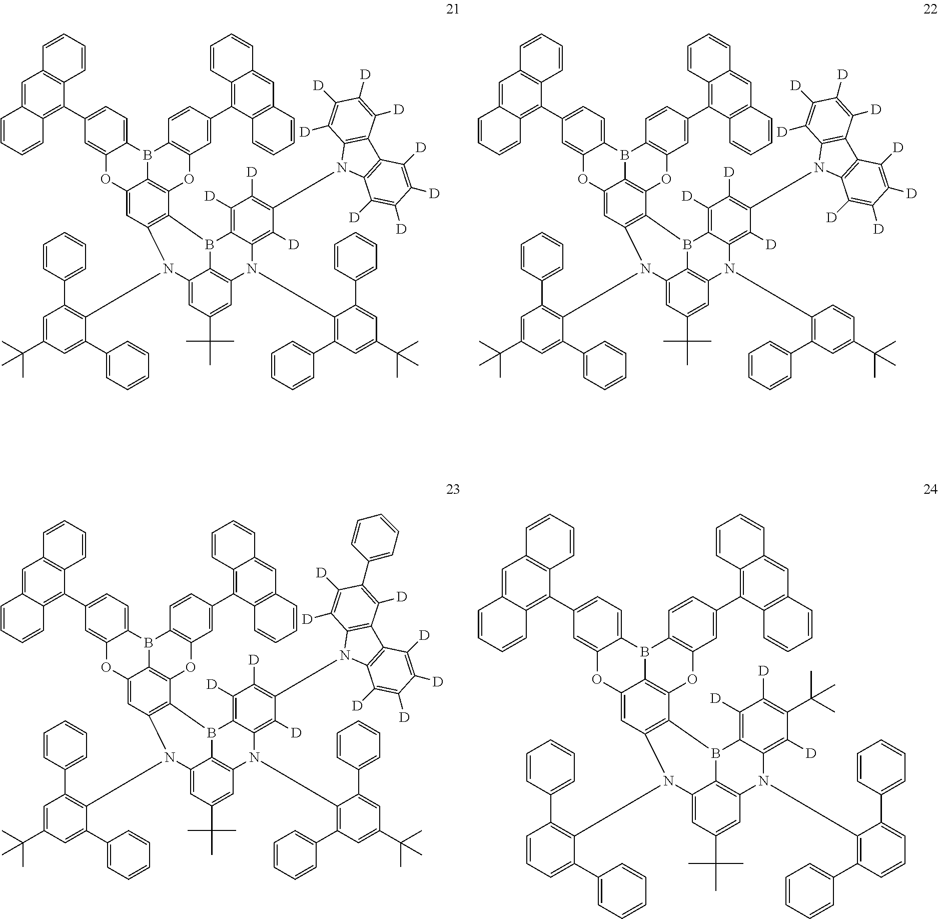 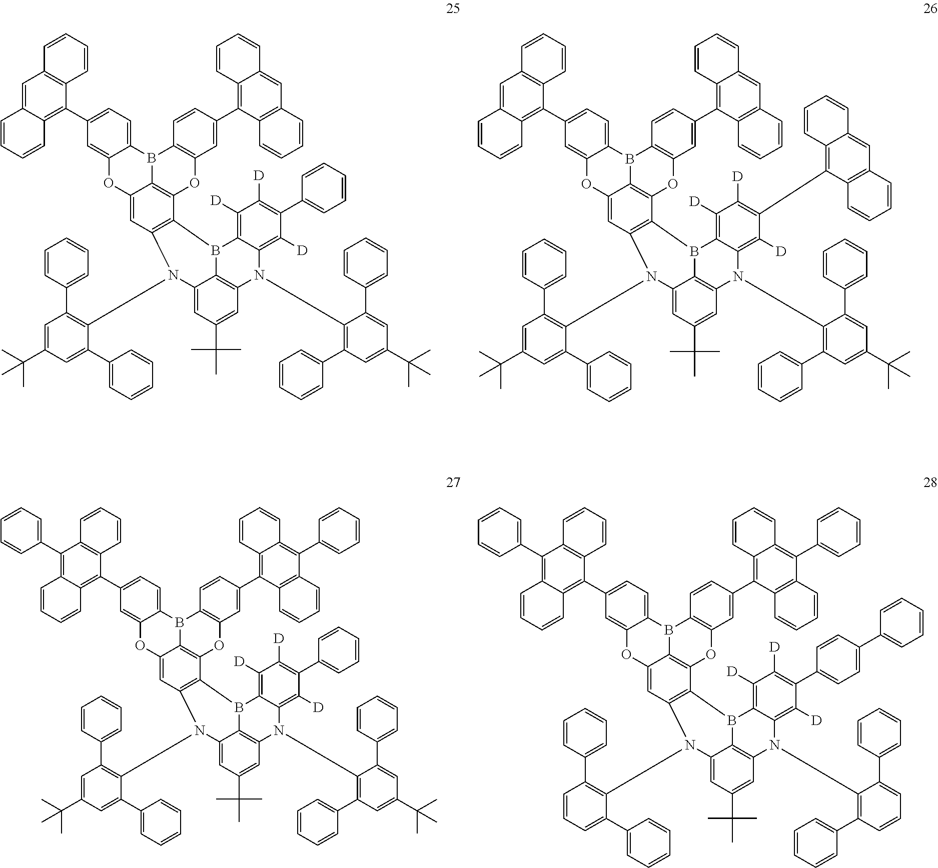 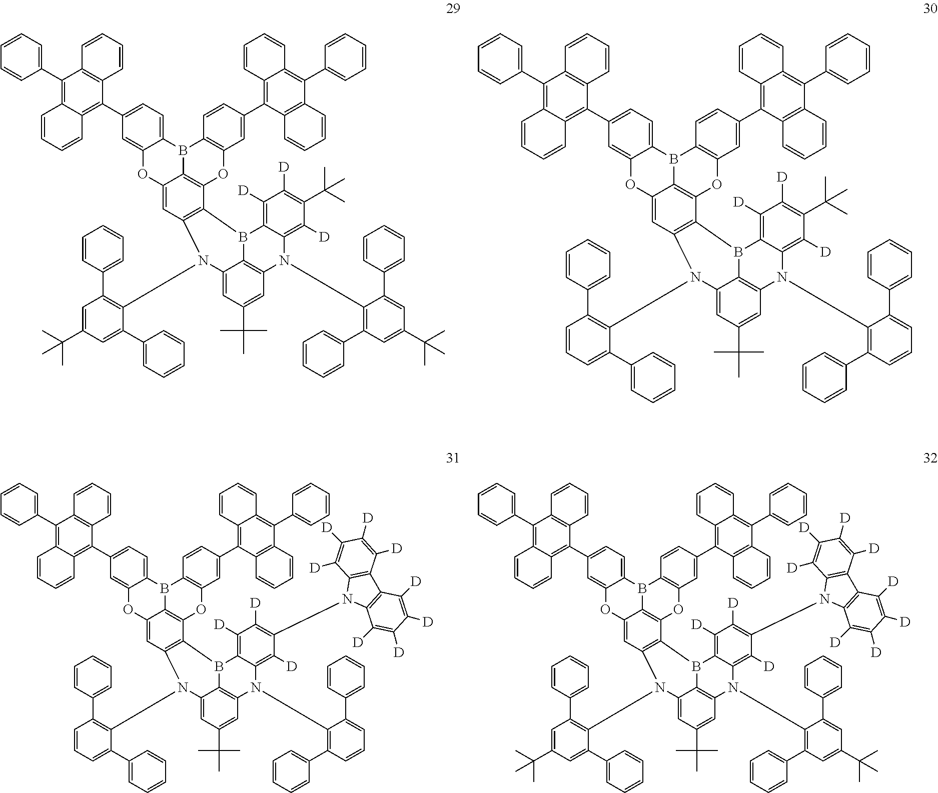 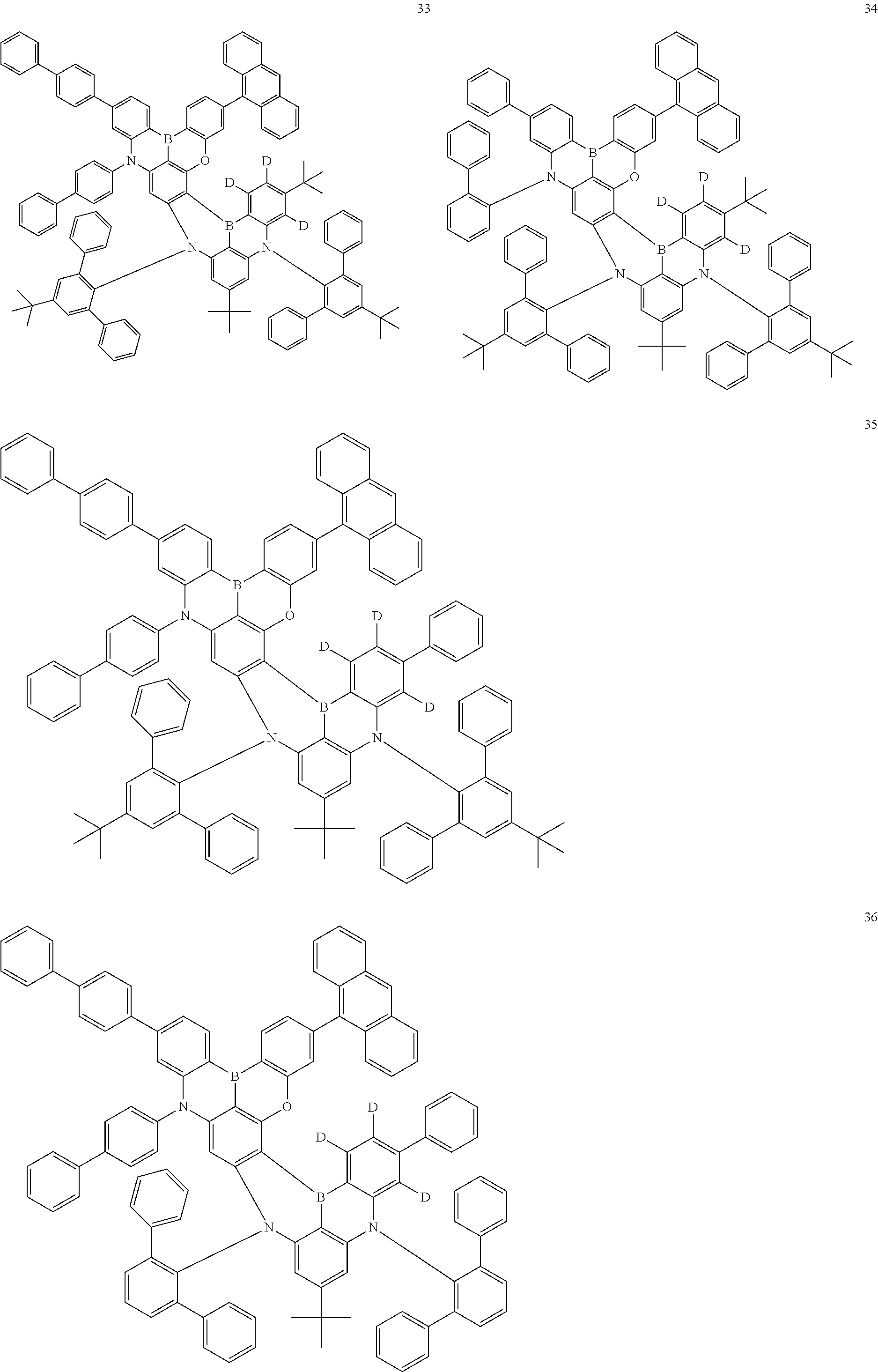 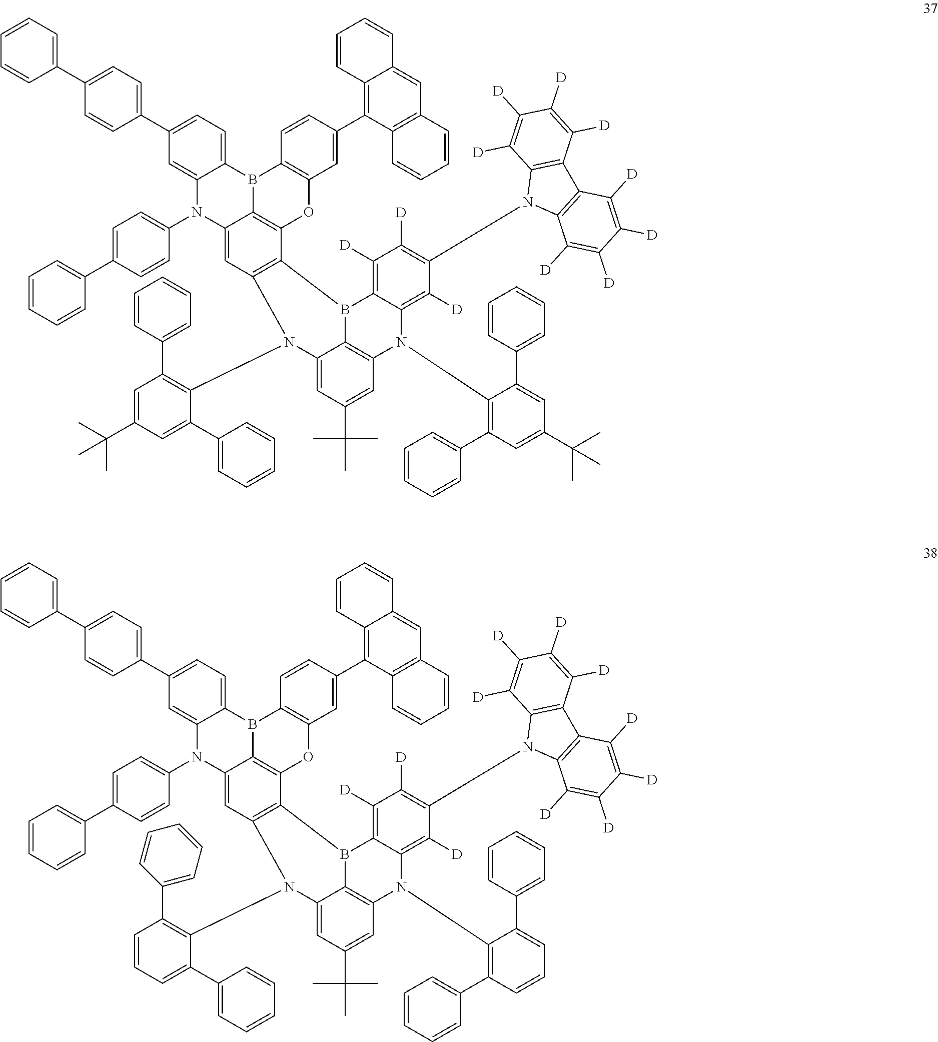 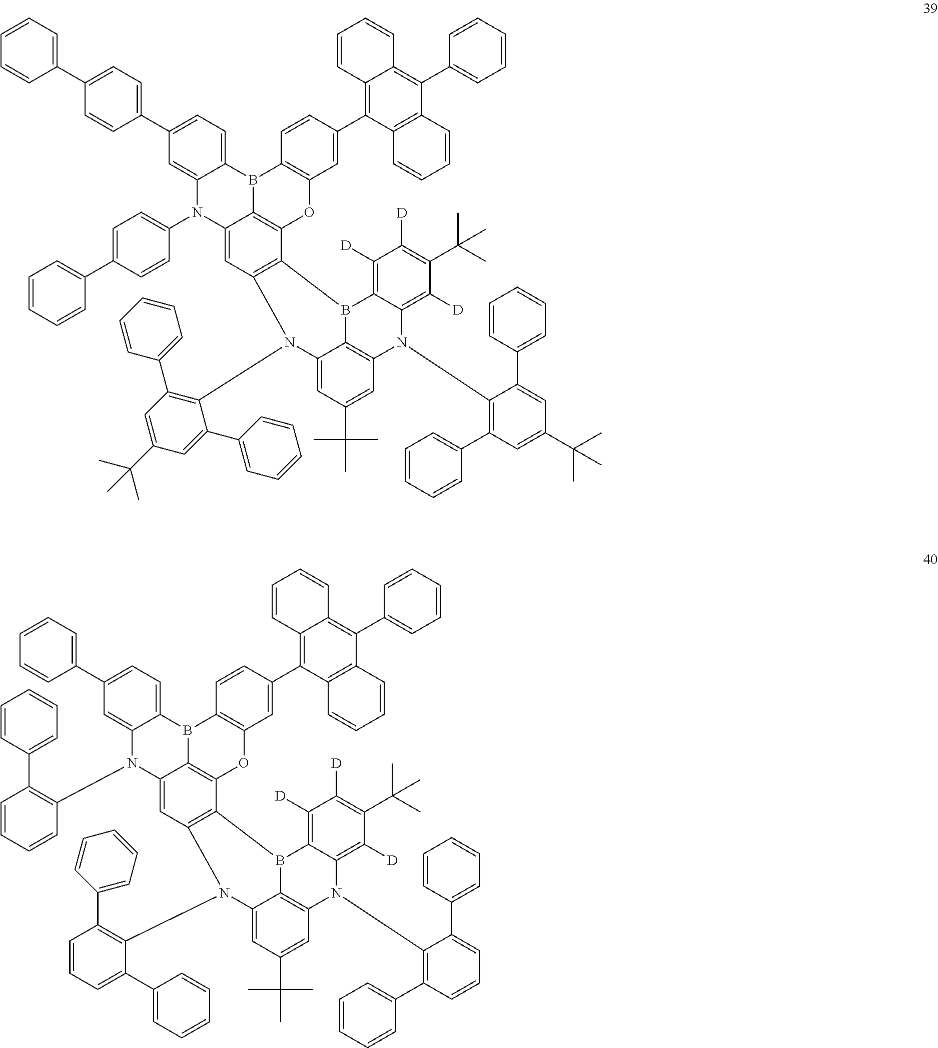 [SMILES: [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2c5ccccc5c(-c5ccccc5)c5ccccc25)ccc1B4c1ccc(-c2ccc(-c4ccccc4)cc2)cc1N3c1ccc(-c2ccccc2)cc1 ; [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2c5ccccc5c(-c5ccccc5)c5ccccc25)ccc1B4c1ccc(-c2ccccc2)cc1N3c1ccccc1-c1ccccc1] 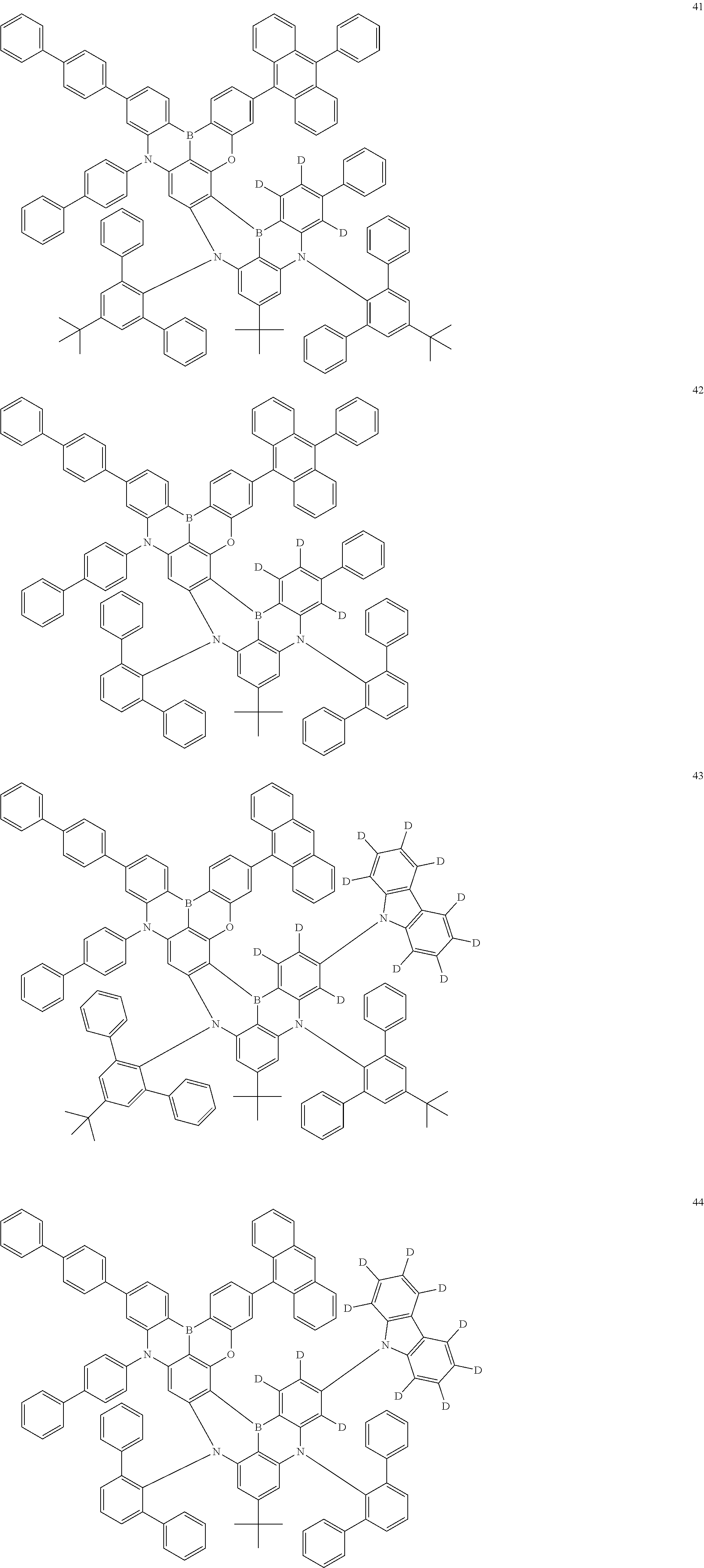 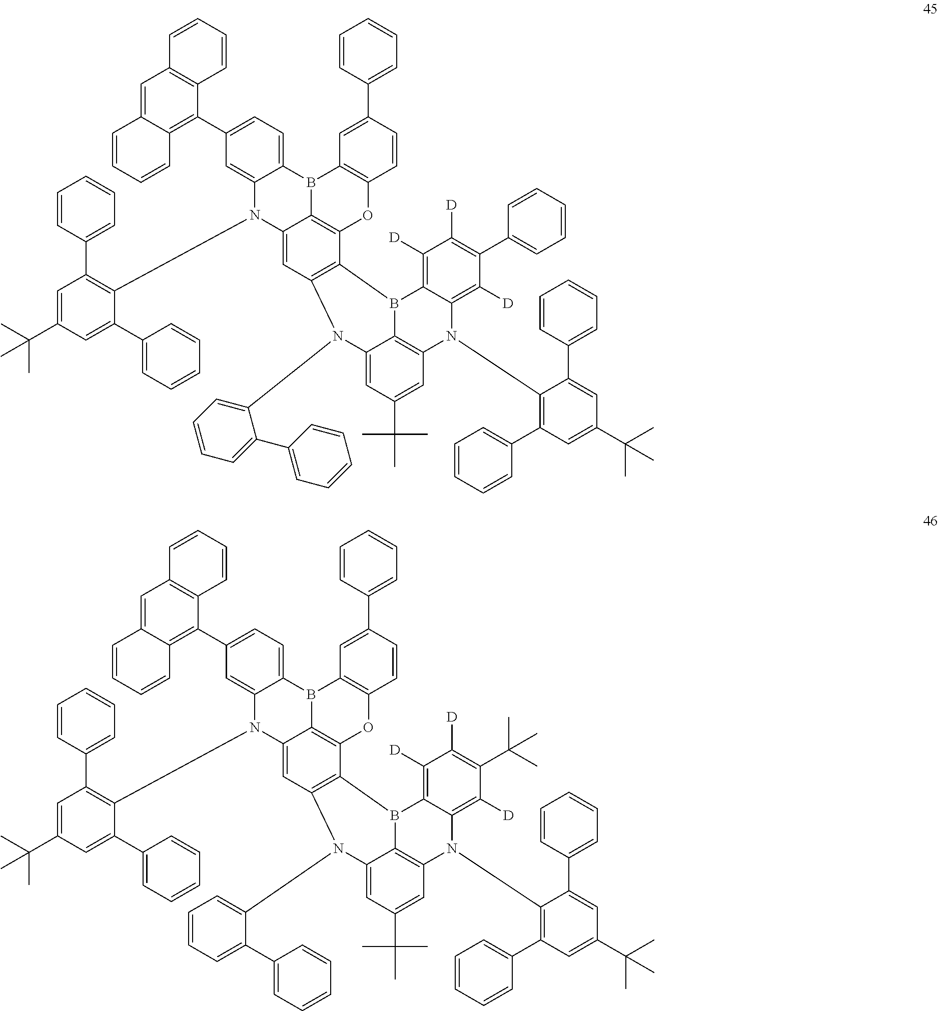 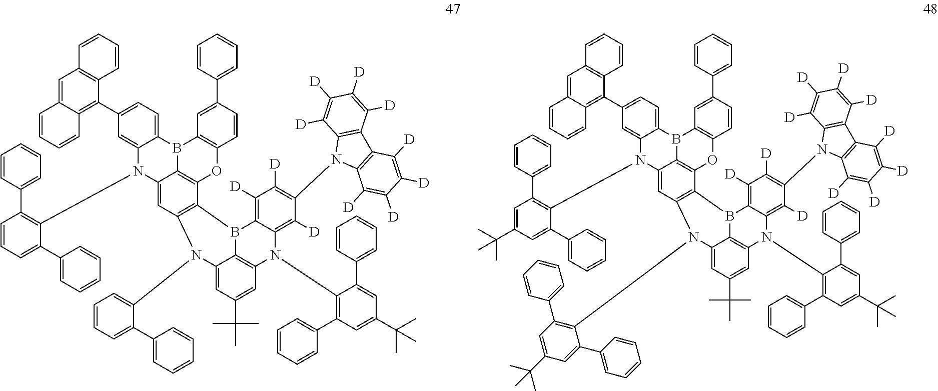 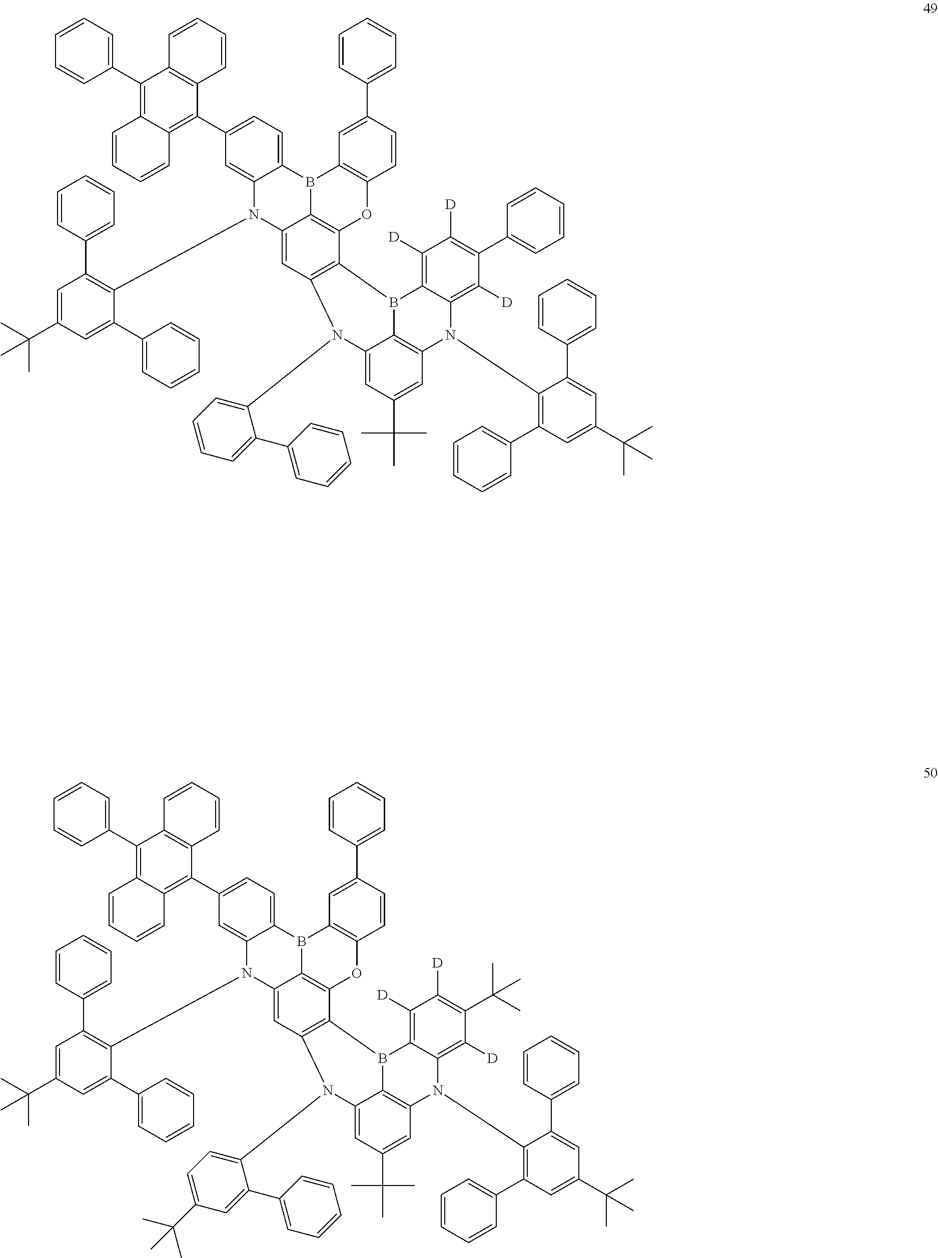 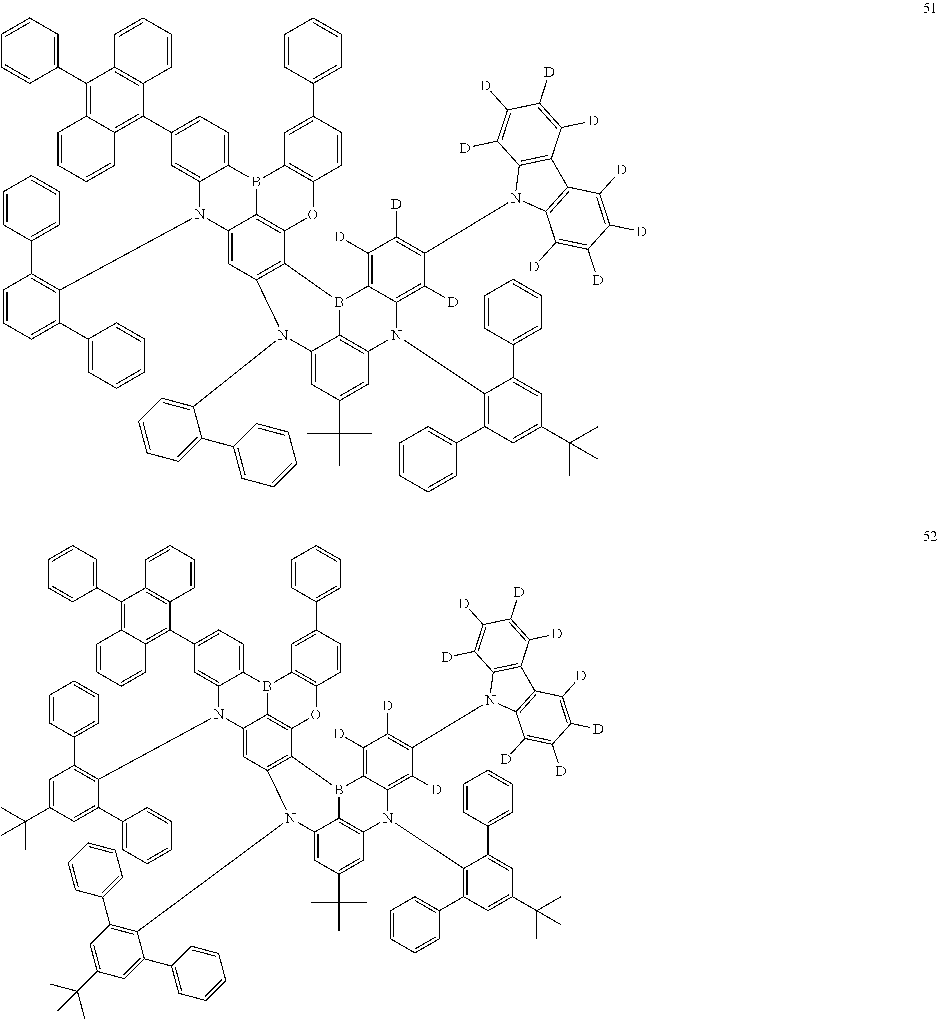 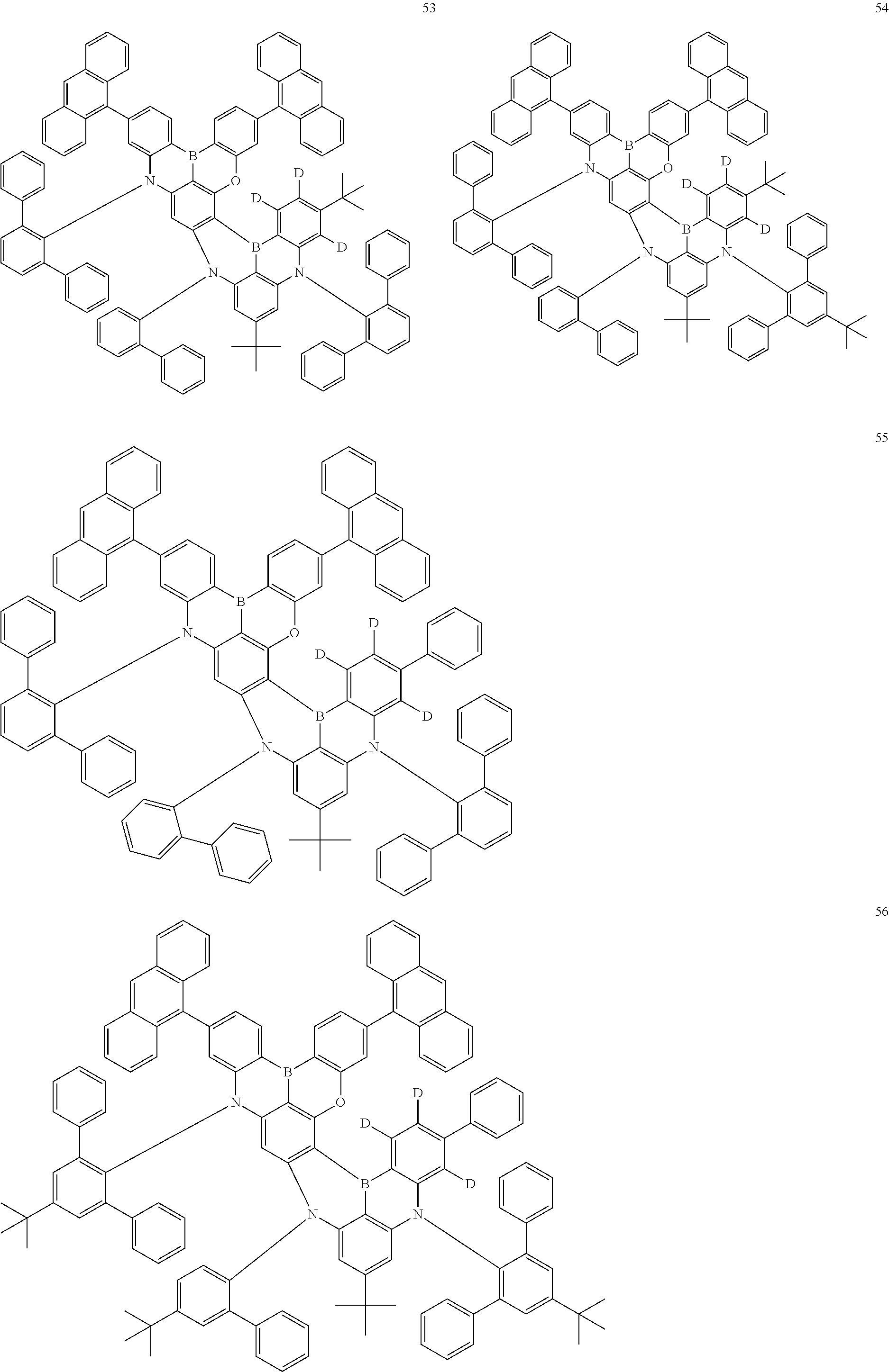 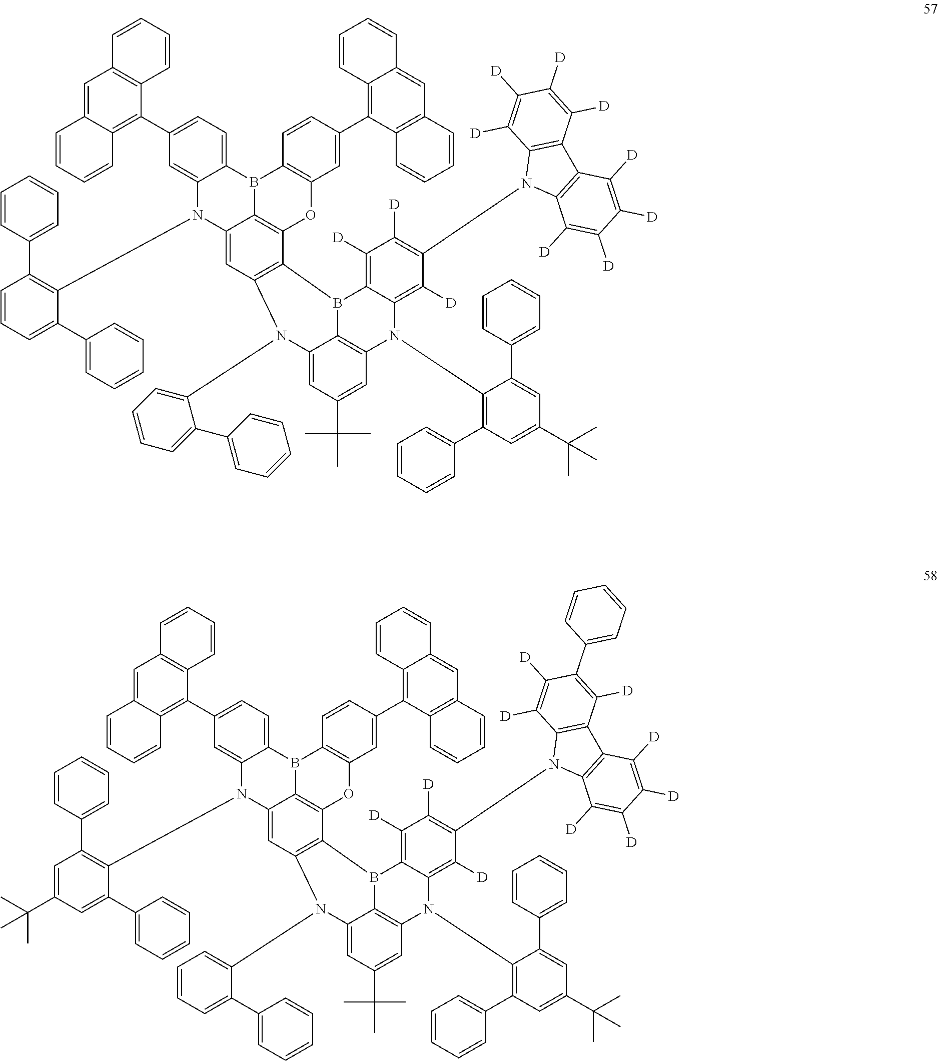 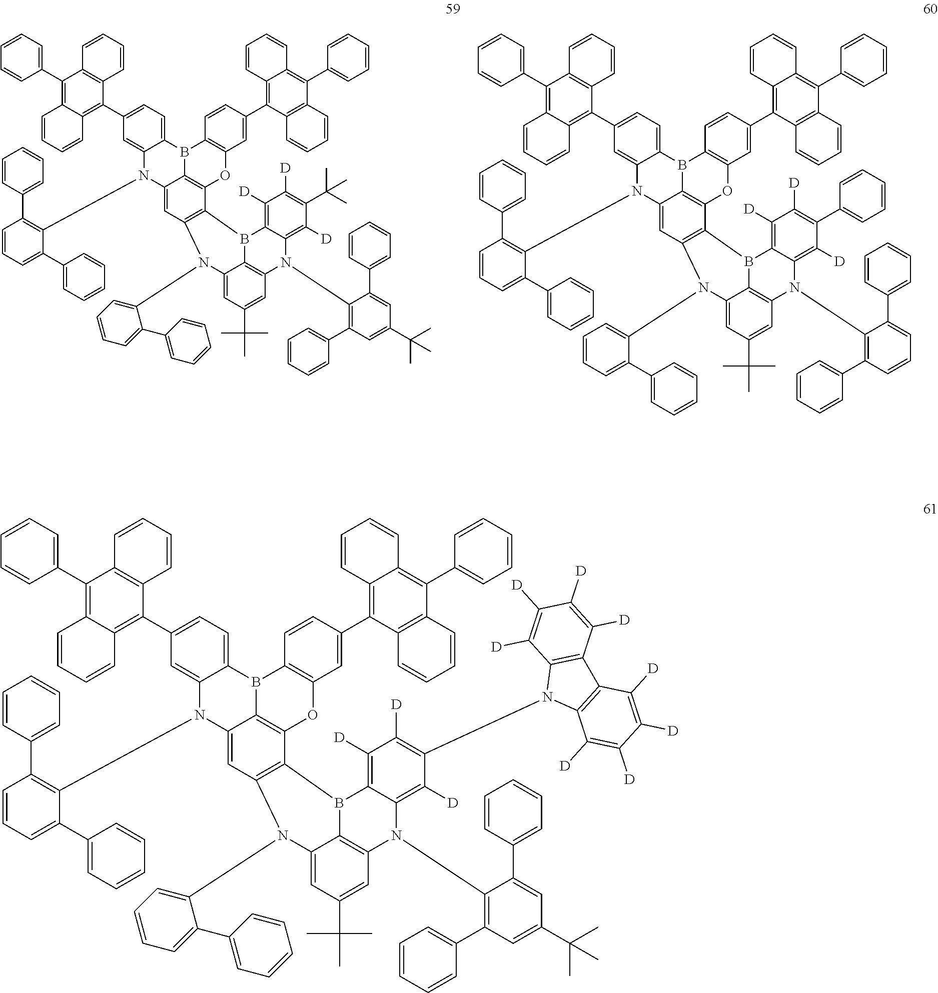 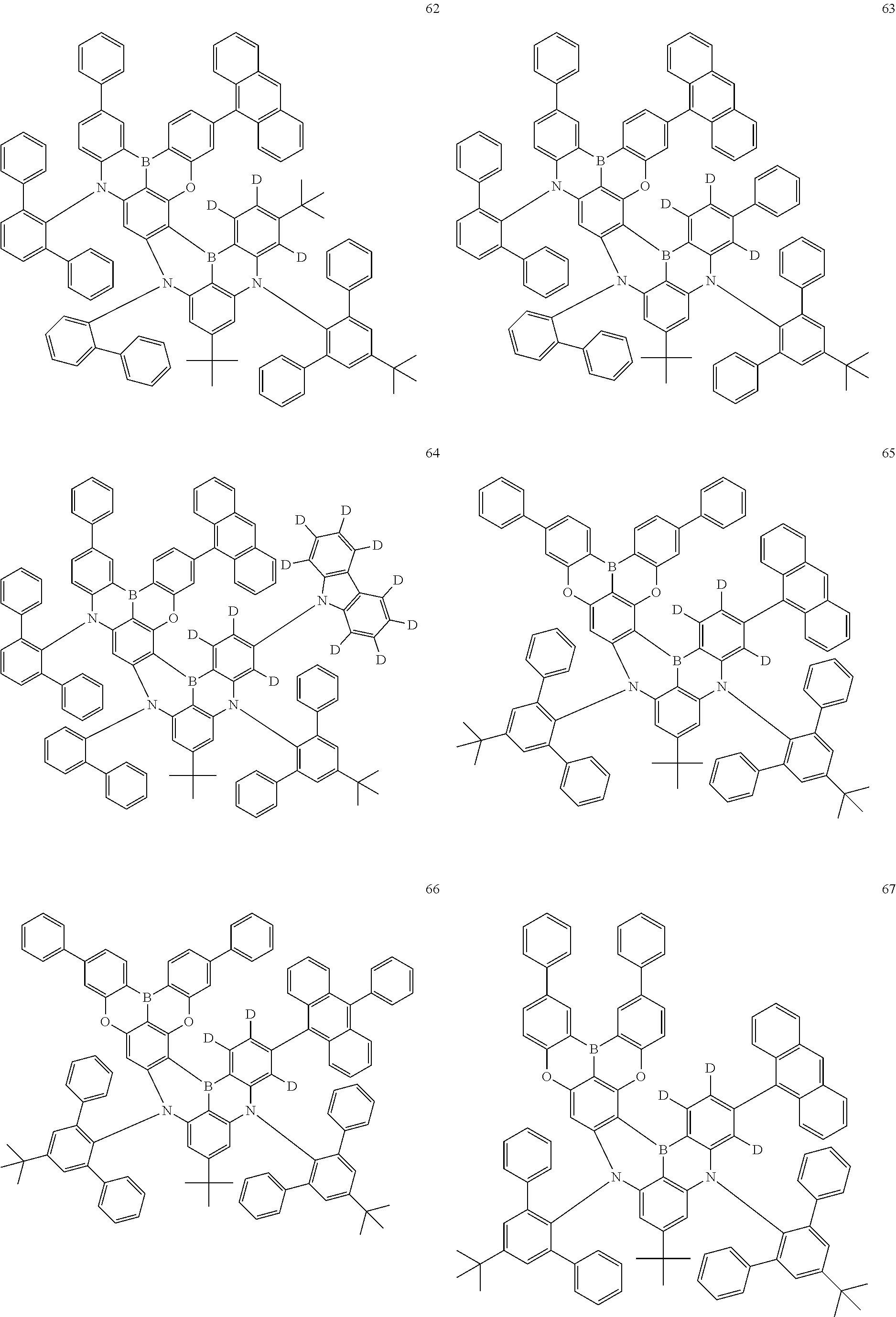 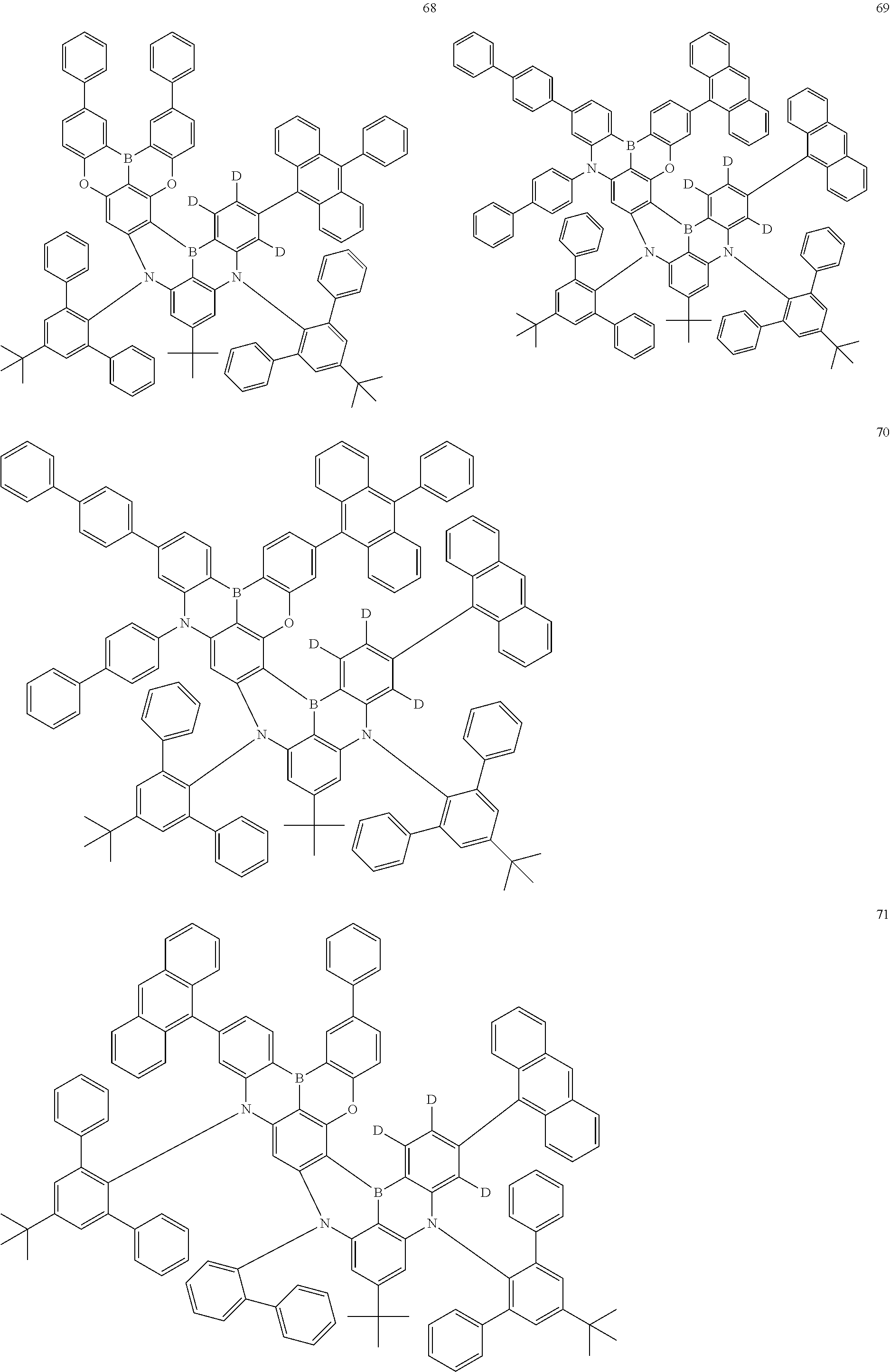 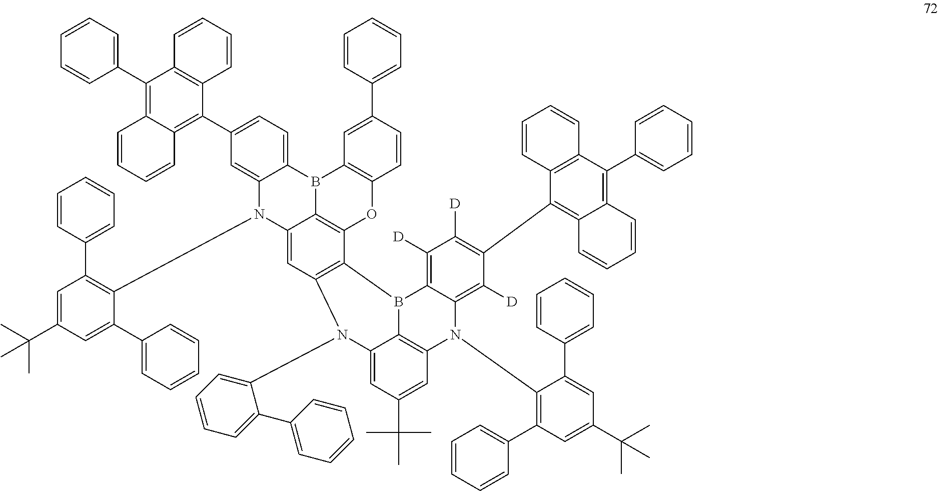 [SMILES: [2H]c1c([2H])c(-c2c3ccccc3c(-c3ccccc3)c3ccccc23)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1ccc(-c2ccccc2)cc1B4c1ccc(-c2c4ccccc4c(-c4ccccc4)c4ccccc24)cc1N3c1c(-c2ccccc2)cc(C(C)(C)C)cc1-c1ccccc1] 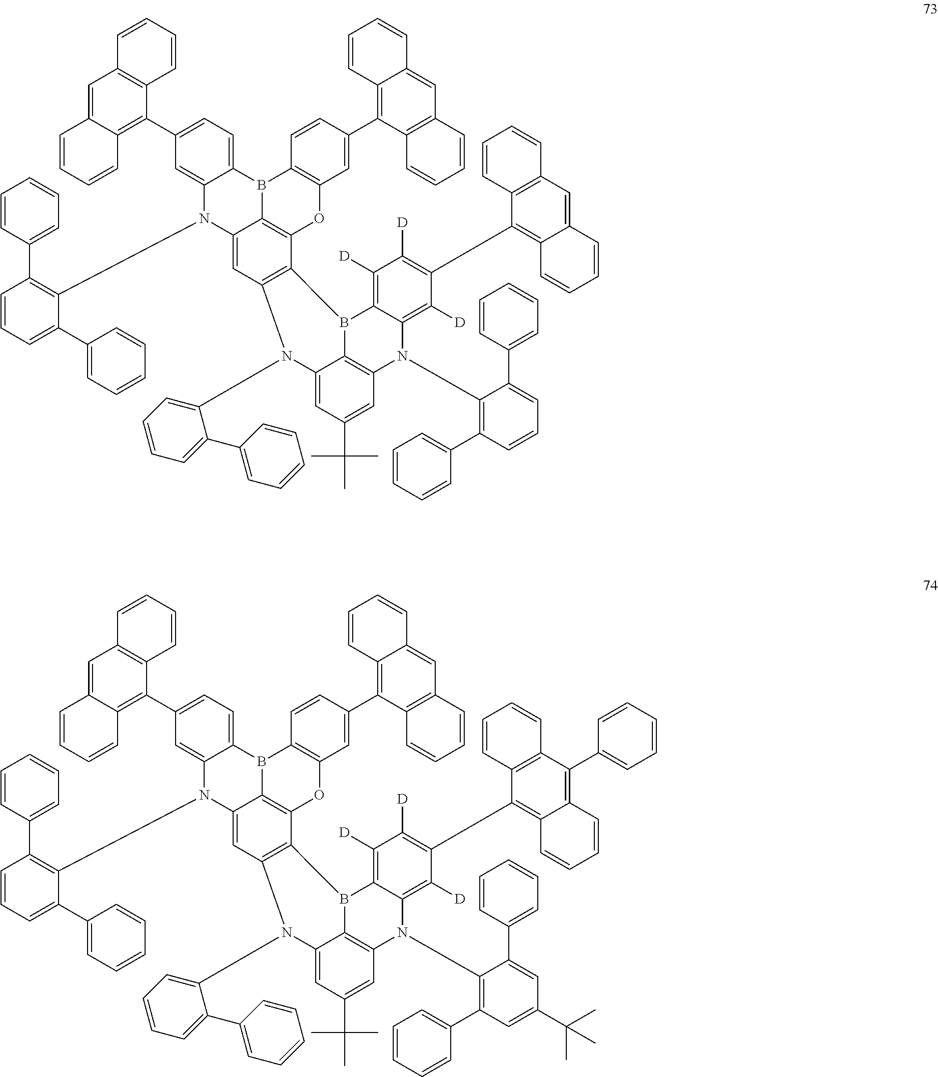 [SMILES: [2H]c1c([2H])c(-c2c3ccccc3cc3ccccc23)c([2H])c2c1B1c3c(cc(C(C)(C)C)cc3N2c2c(-c3ccccc3)cccc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1 ; [2H]c1c([2H])c(-c2c3ccccc3c(-c3ccccc3)c3ccccc23)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1ccc(-c2c4ccccc4cc4ccccc24)cc1N3c1c(-c2ccccc2)cccc1-c1ccccc1] 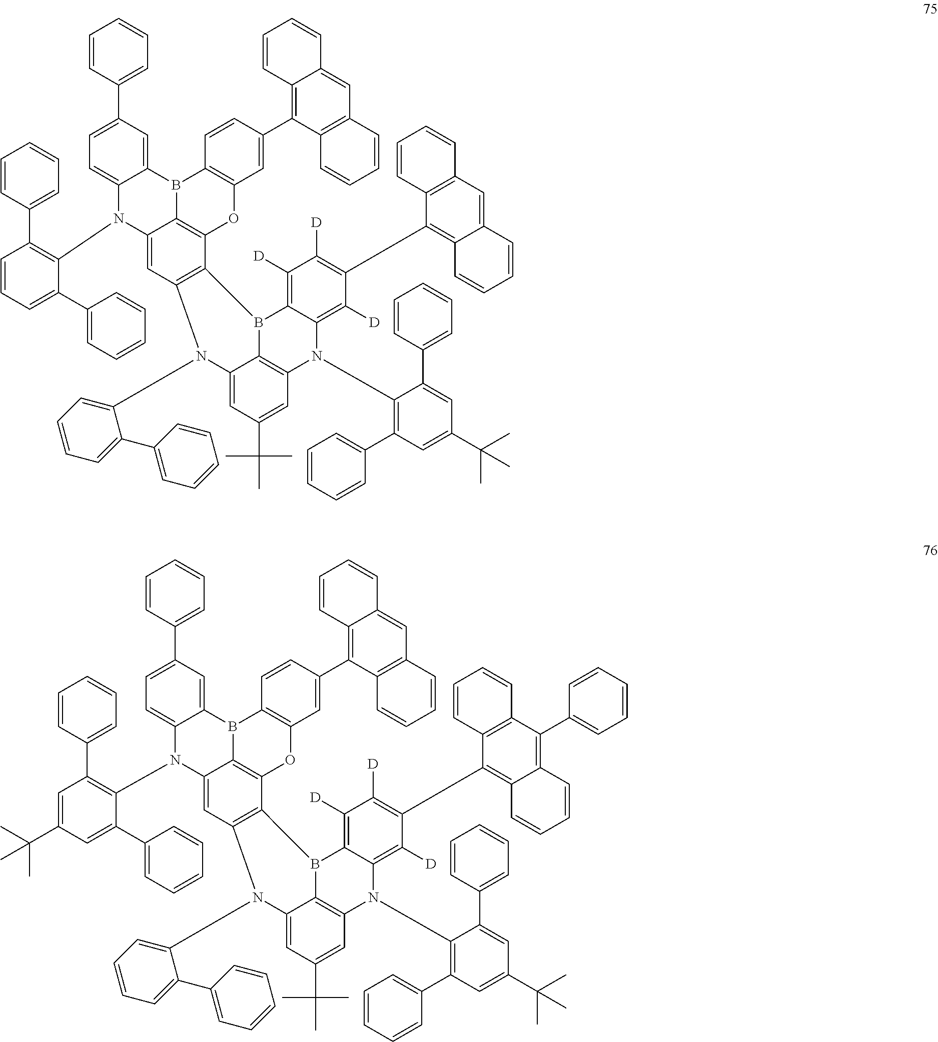 [SMILES: [2H]c1c([2H])c(-c2c3ccccc3cc3ccccc23)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1cc(-c2ccccc2)ccc1N3c1c(-c2ccccc2)cccc1-c1ccccc1 ; [2H]c1c([2H])c(-c2c3ccccc3c(-c3ccccc3)c3ccccc23)c([2H])c2c1B1c3c(cc(C(C)(C)C)cc3N2c2c(-c3ccccc3)cc(C(C)(C)C)cc2-c2ccccc2)N(c2ccccc2-c2ccccc2)c2cc3c4c(c21)Oc1cc(-c2c5ccccc5cc5ccccc25)ccc1B4c1cc(-c2ccccc2)ccc1N3c1c(-c2ccccc2)cc(C(C)(C)C)cc1-c1ccccc1] 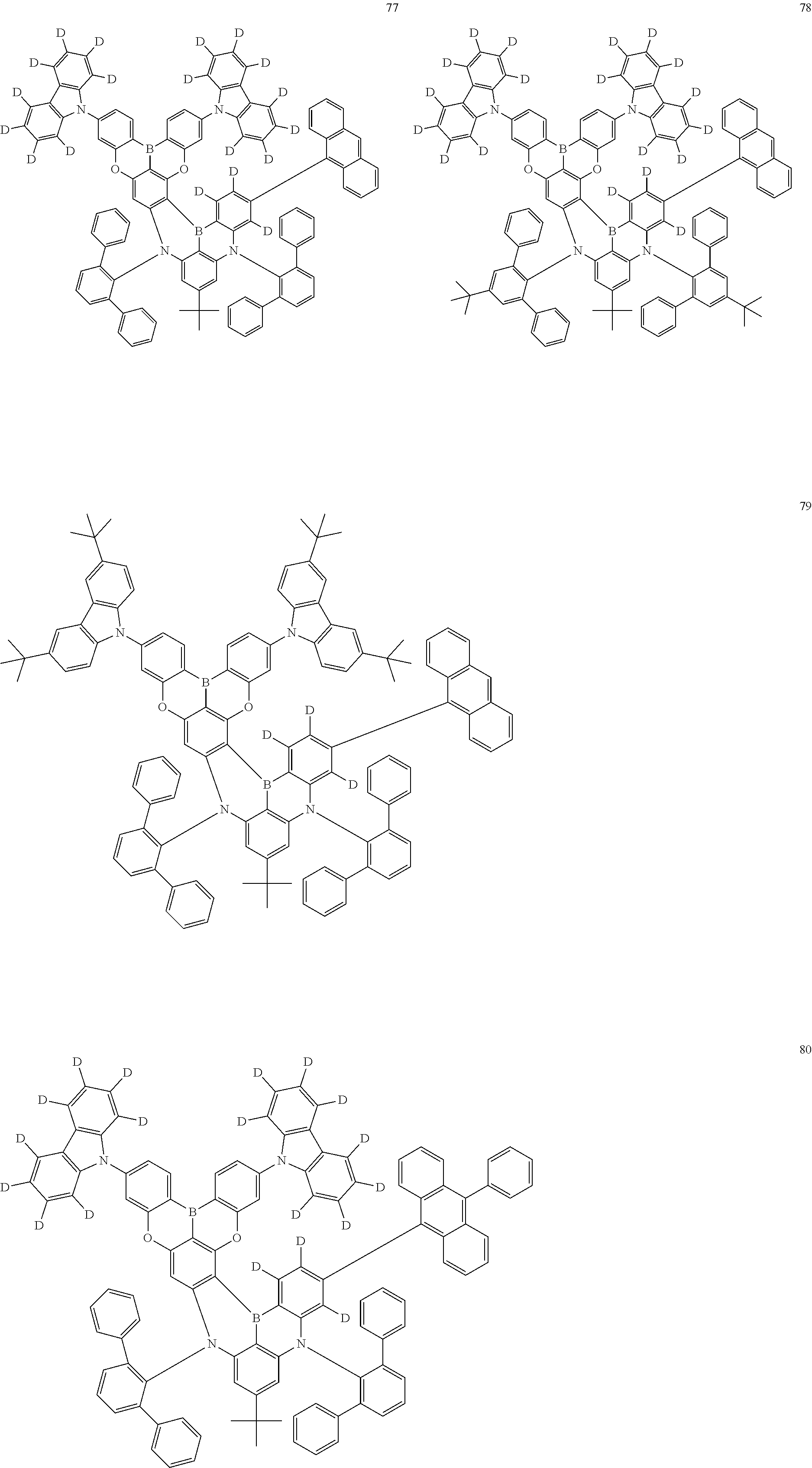 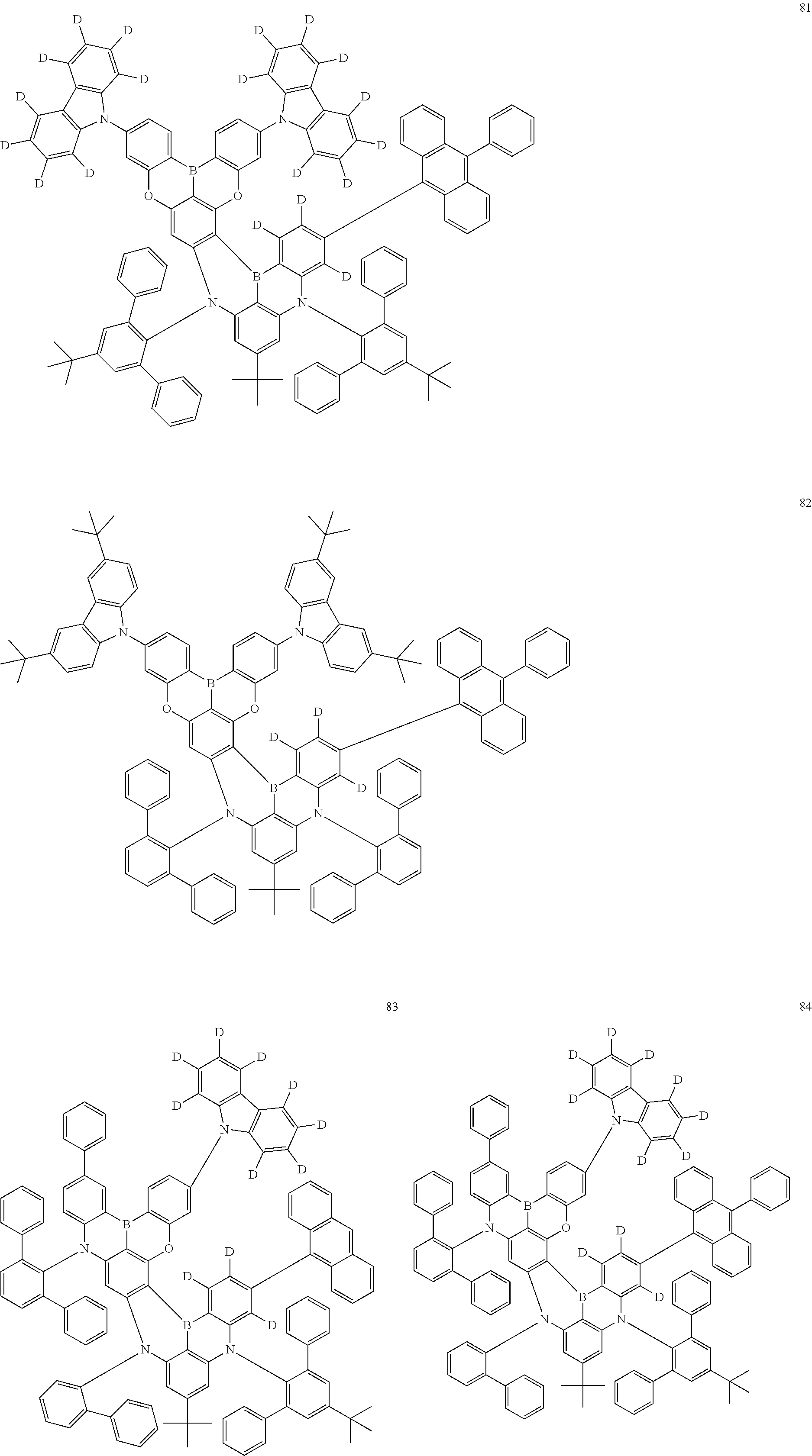 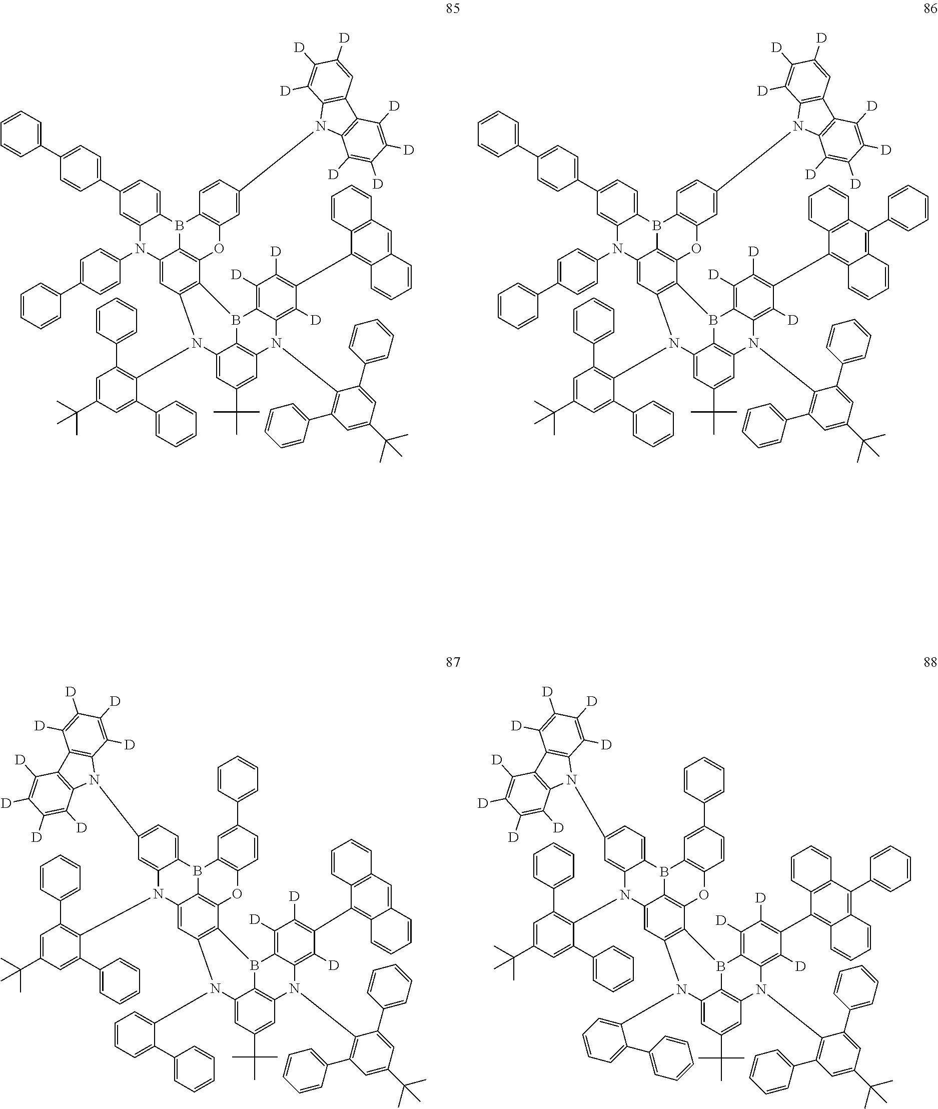 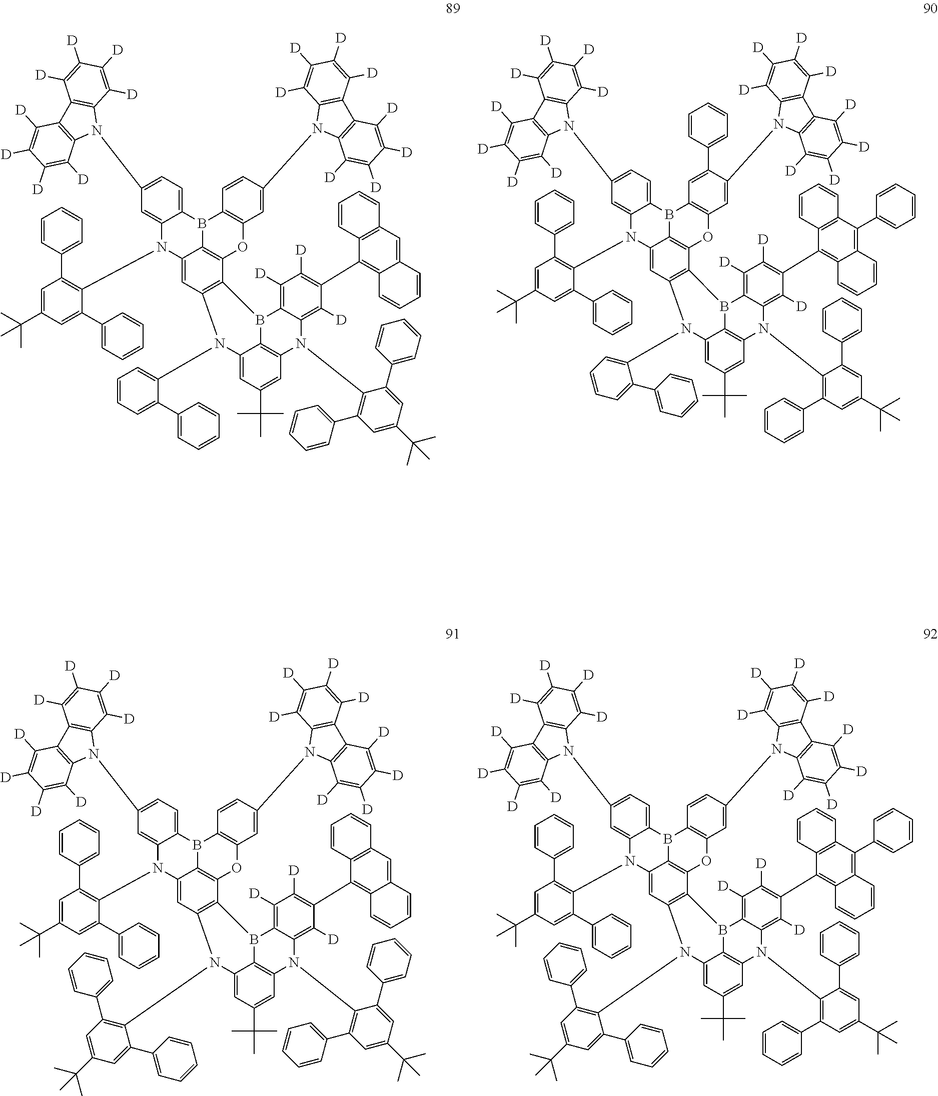 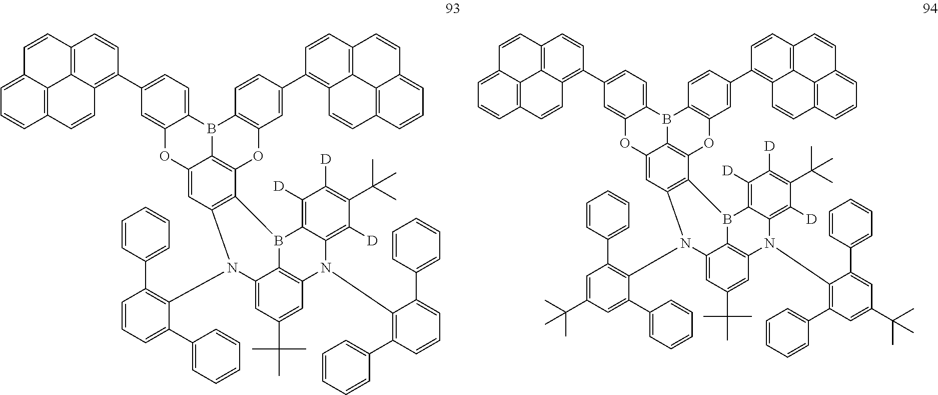 [SMILES: [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1O3 ; [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1O3] 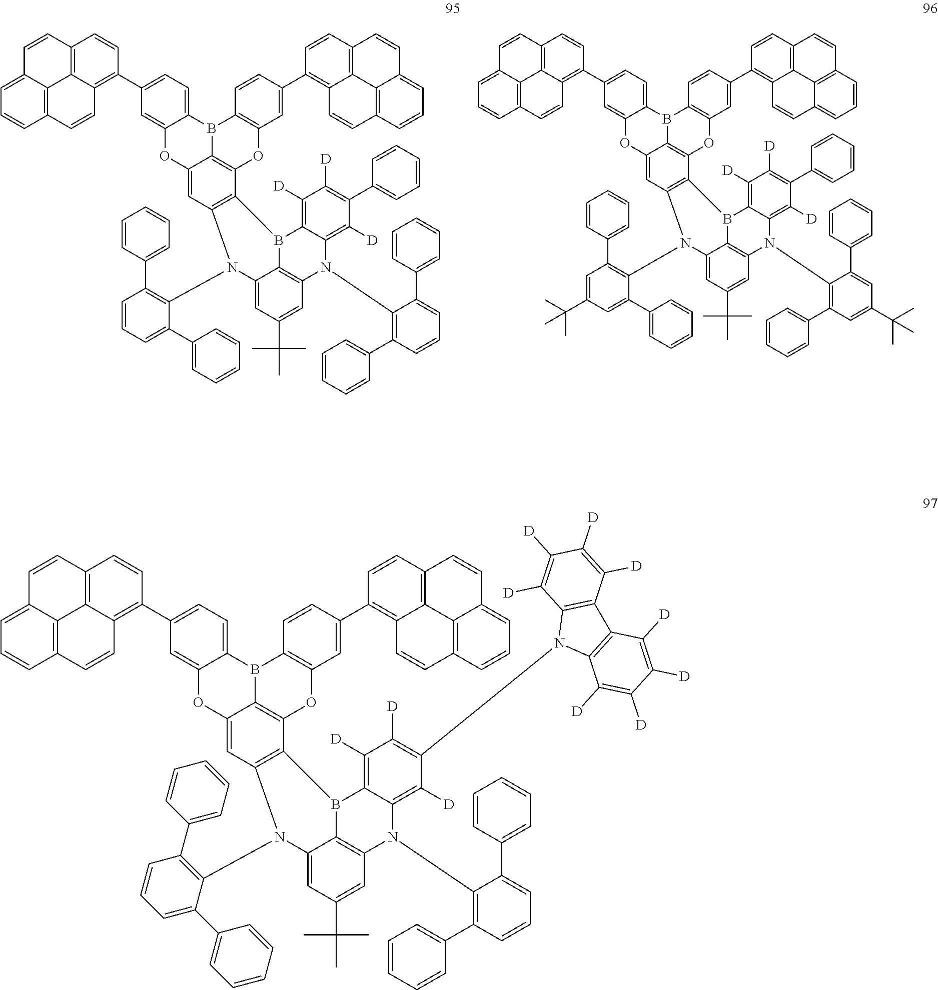 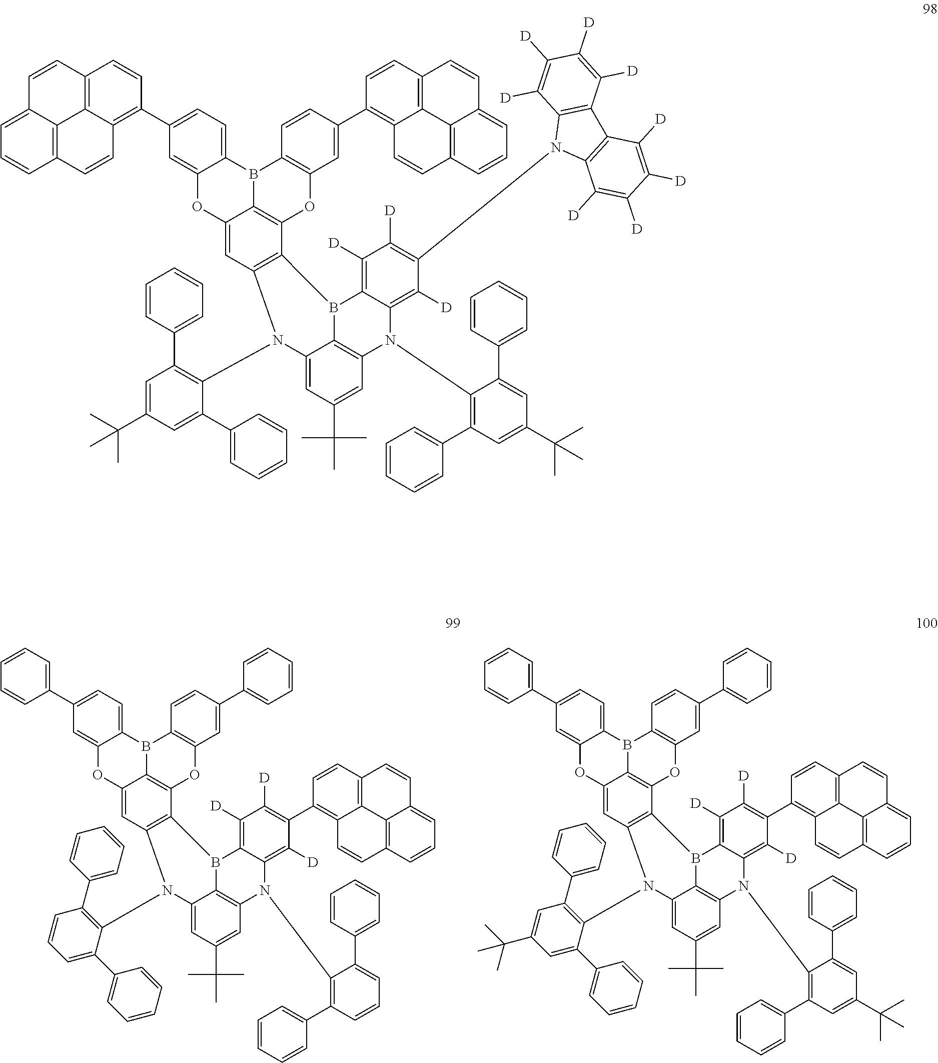 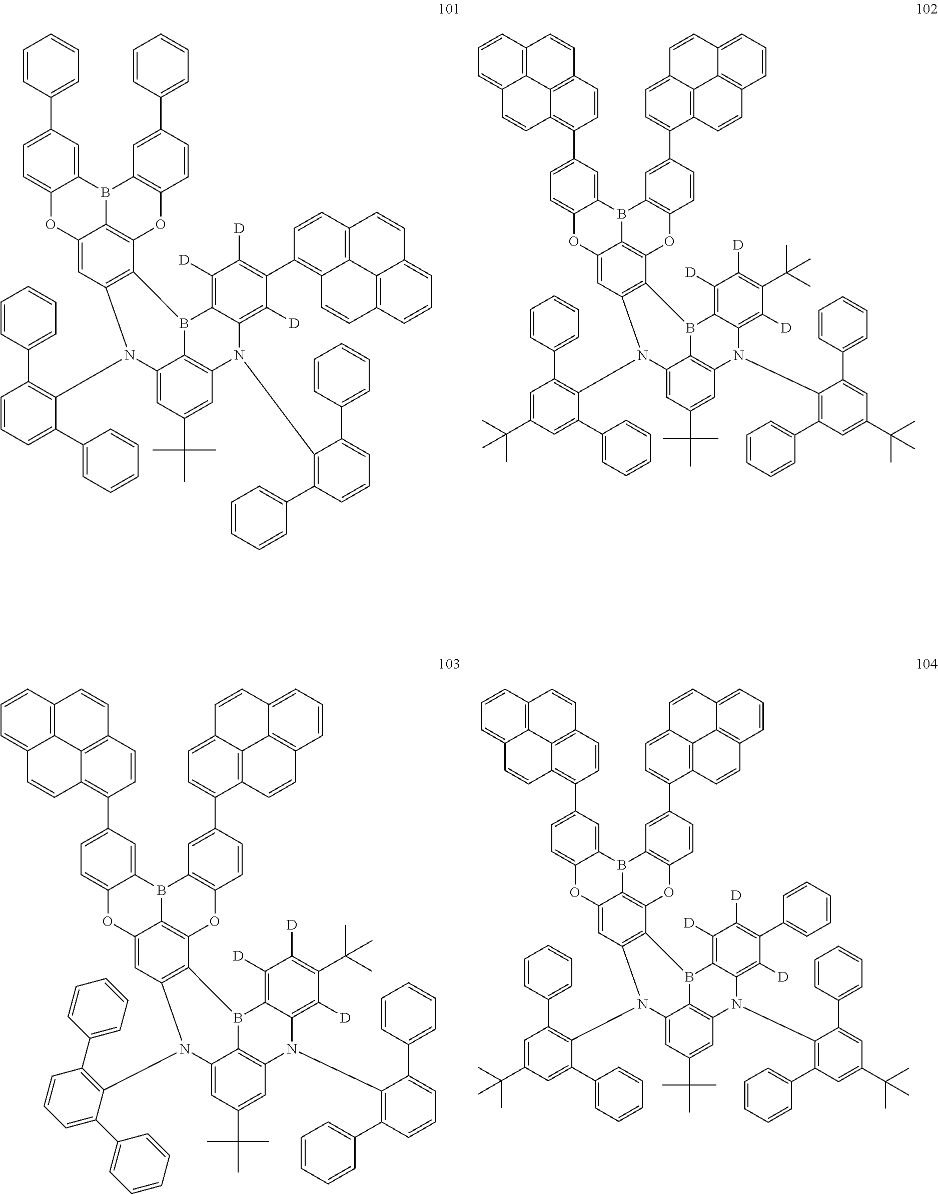 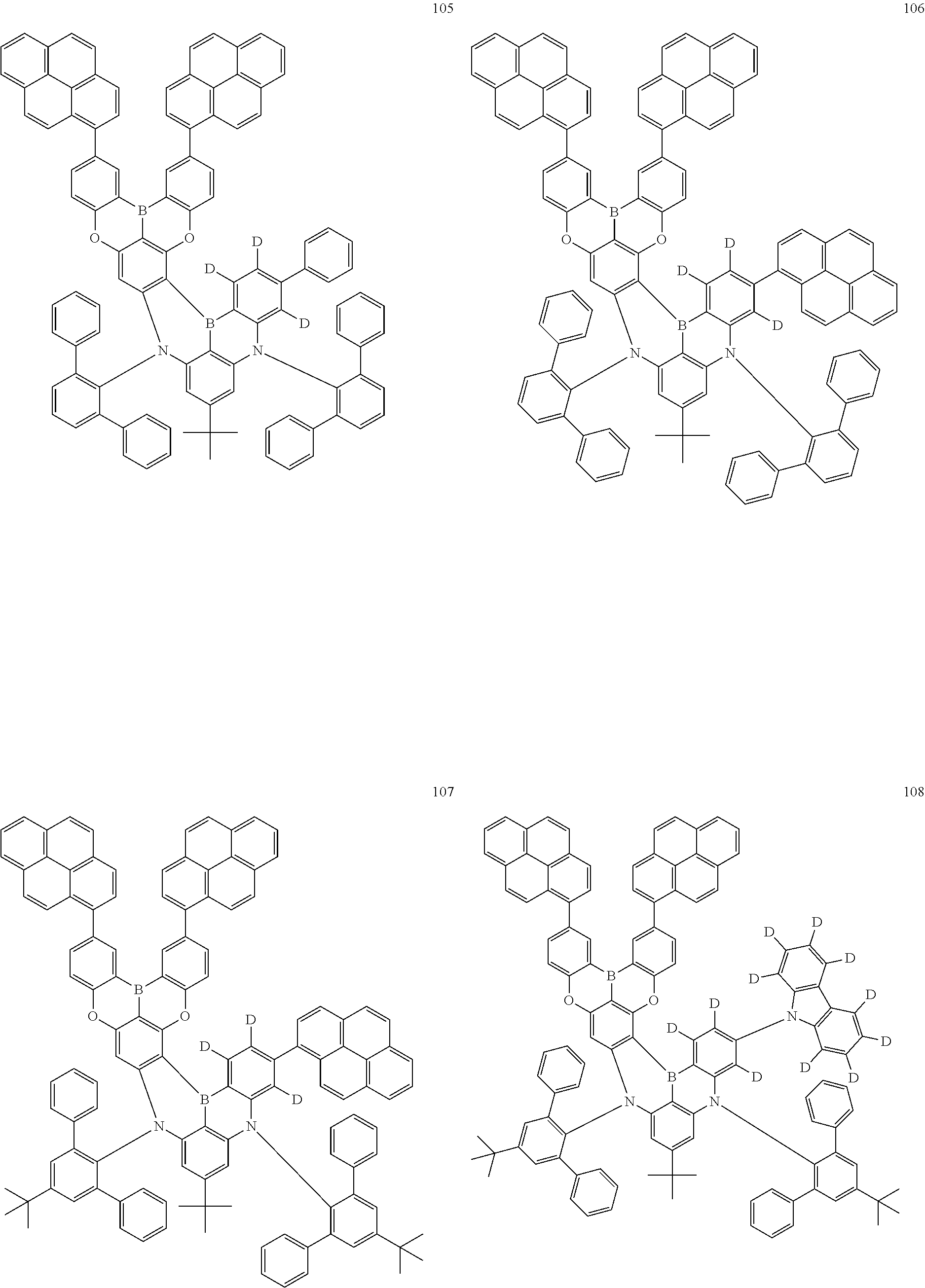 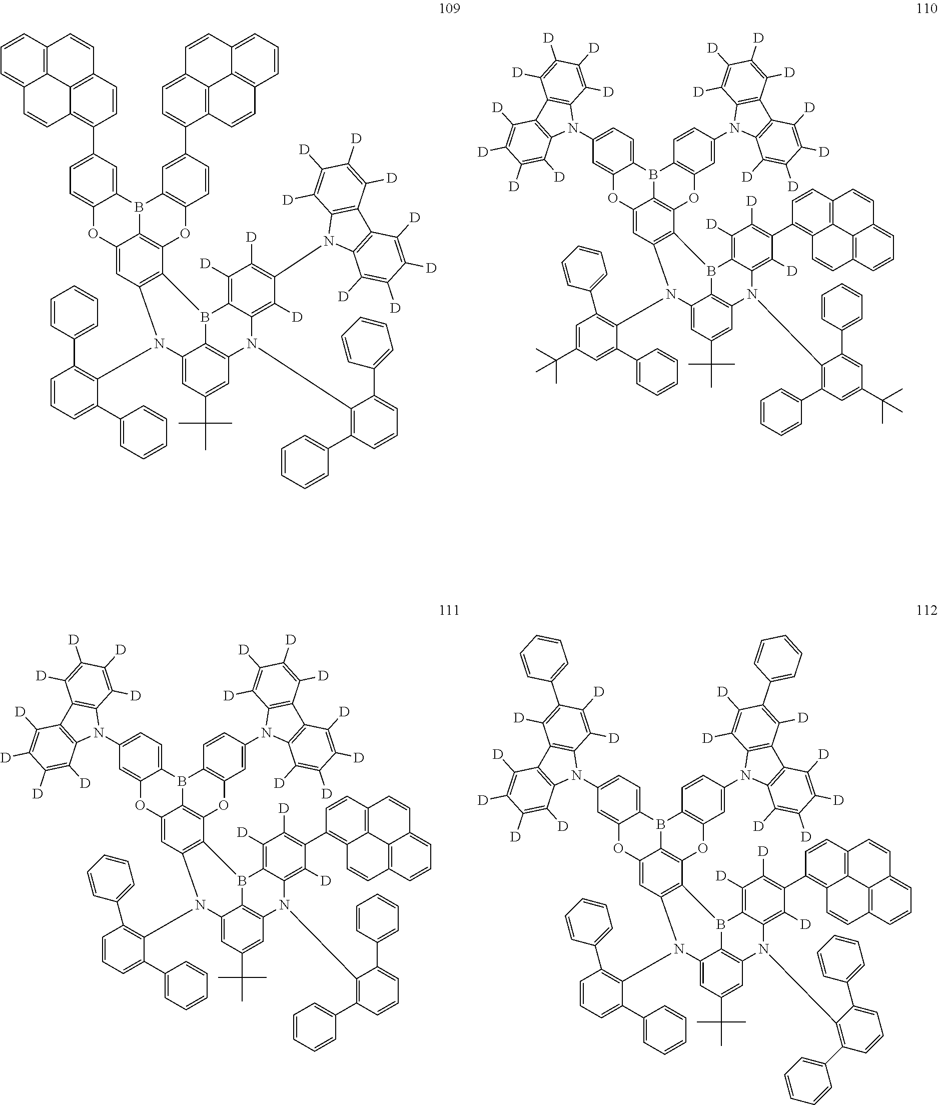 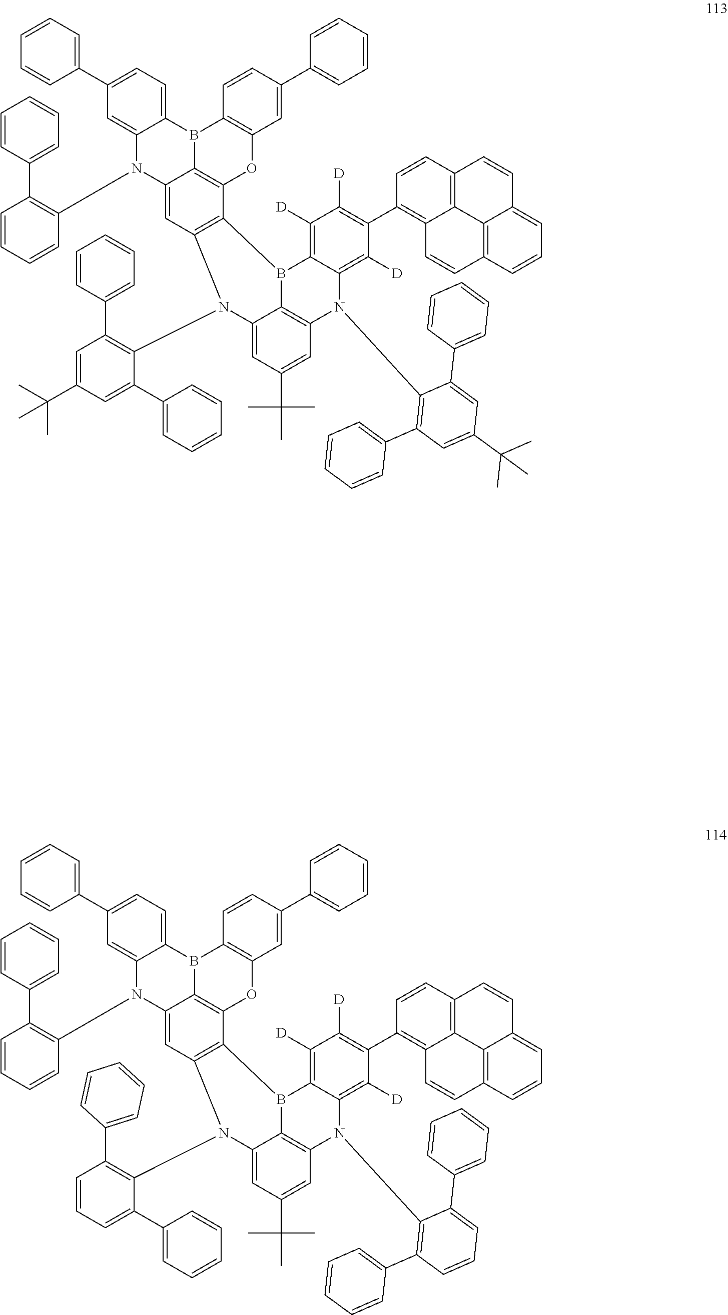 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccccc2)ccc1B4c1ccc(-c2ccccc2)cc1N3c1ccccc1-c1ccccc1 ; [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccccc2)ccc1B4c1ccc(-c2ccccc2)cc1N3c1ccccc1-c1ccccc1] 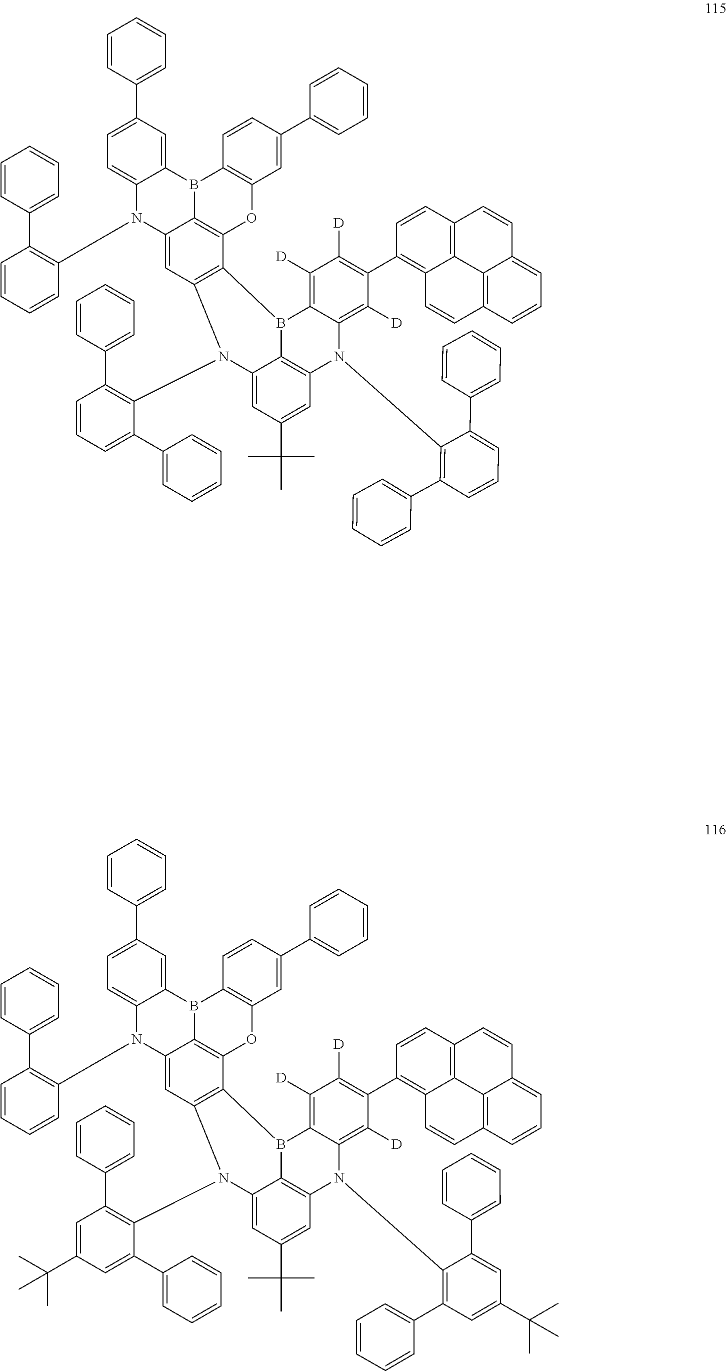 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccccc2)ccc1B4c1cc(-c2ccccc2)ccc1N3c1ccccc1-c1ccccc1 ; [2H]c1c([2H])c(-c2ccc3ccc4cccc5ccc2c3c45)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccccc2)ccc1B4c1cc(-c2ccccc2)ccc1N3c1ccccc1-c1ccccc1] 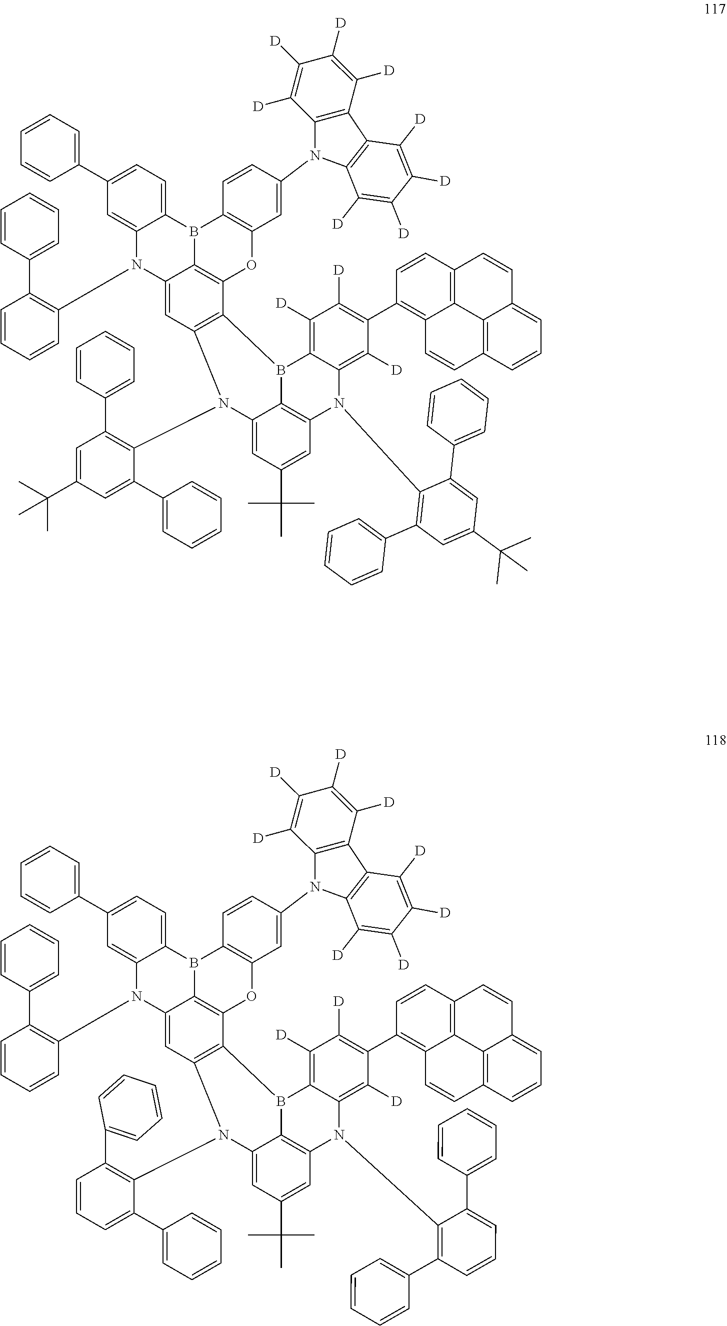 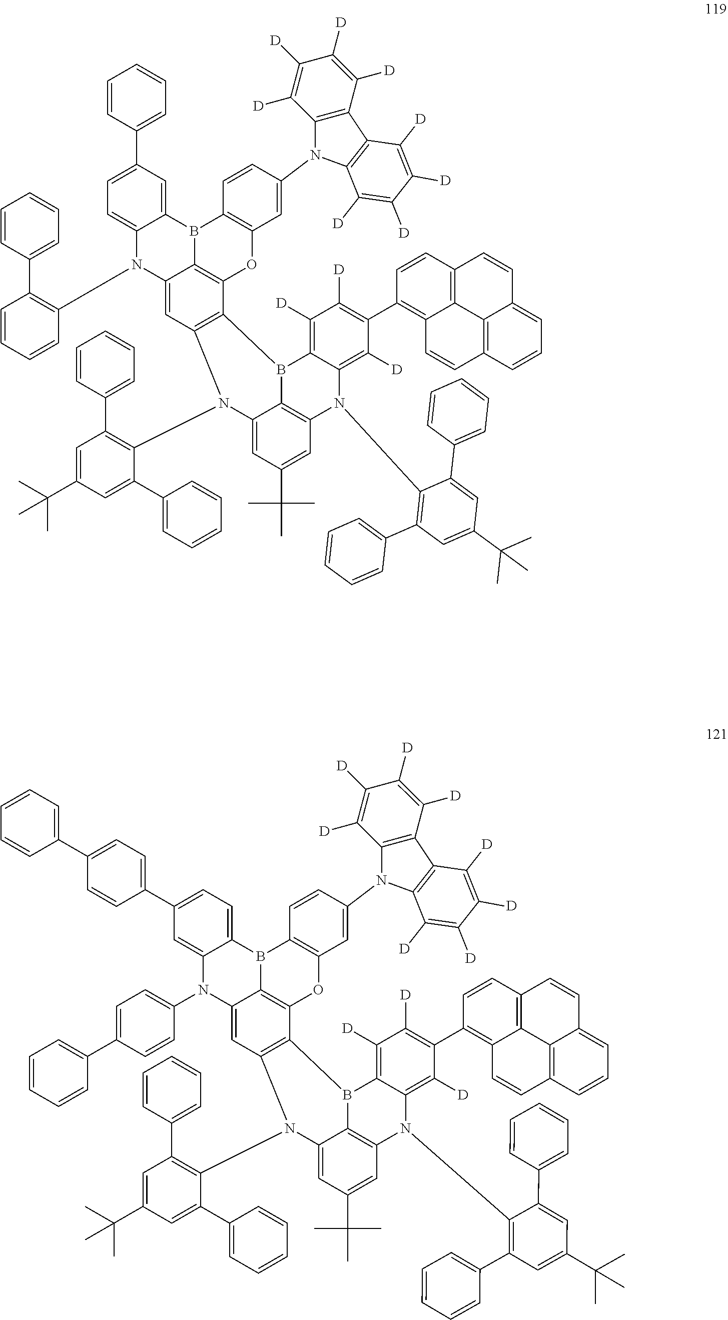 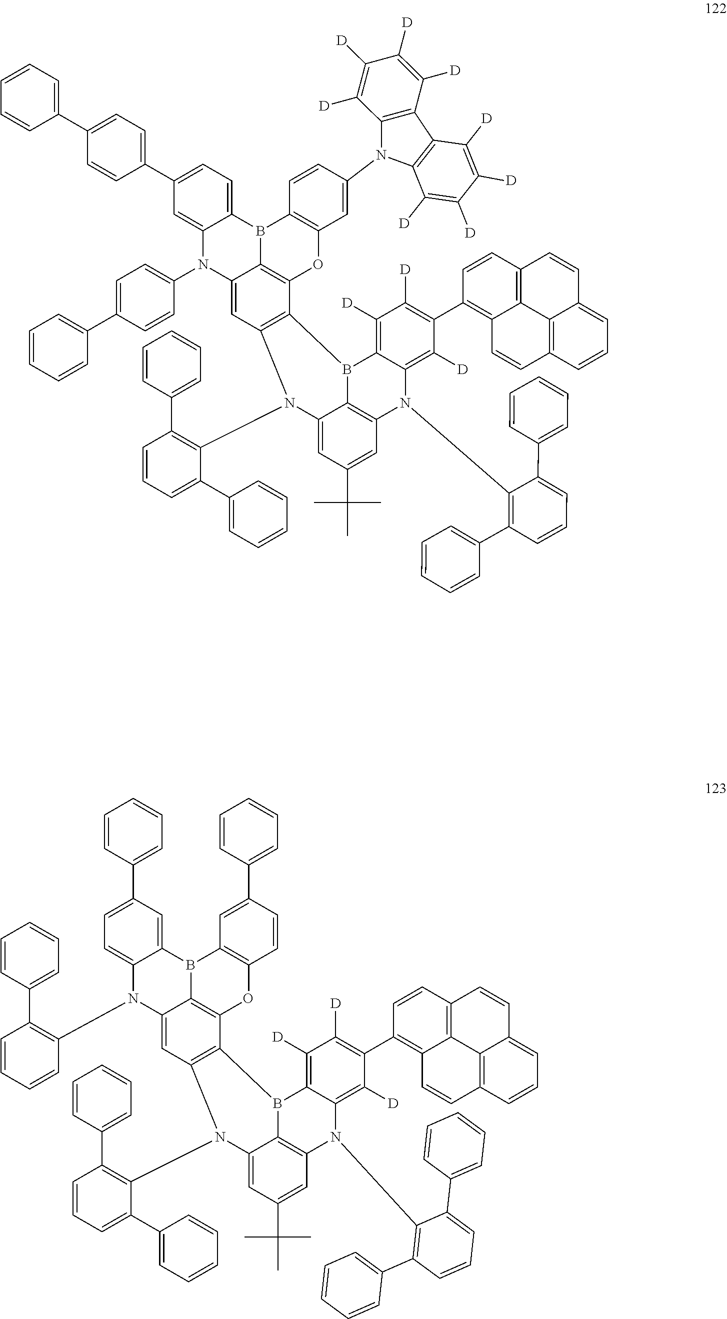 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-n2c5c([2H])c([2H])c([2H])c([2H])c5c5c([2H])c([2H])c([2H])c([2H])c52)ccc1B4c1ccc(-c2ccc(-c4ccccc4)cc2)cc1N3c1ccc(-c2ccccc2)cc1 ; [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1ccc(-c2ccccc2)cc1B4c1cc(-c2ccccc2)ccc1N3c1ccccc1-c1ccccc1] 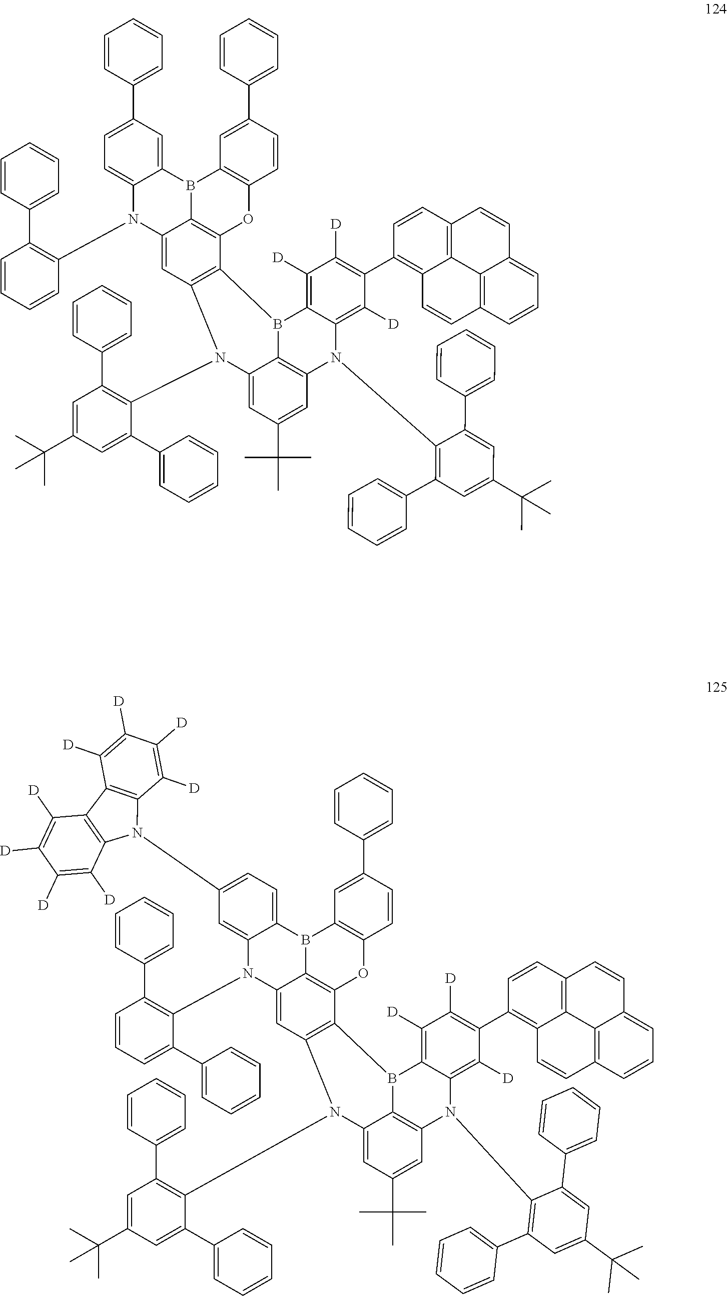 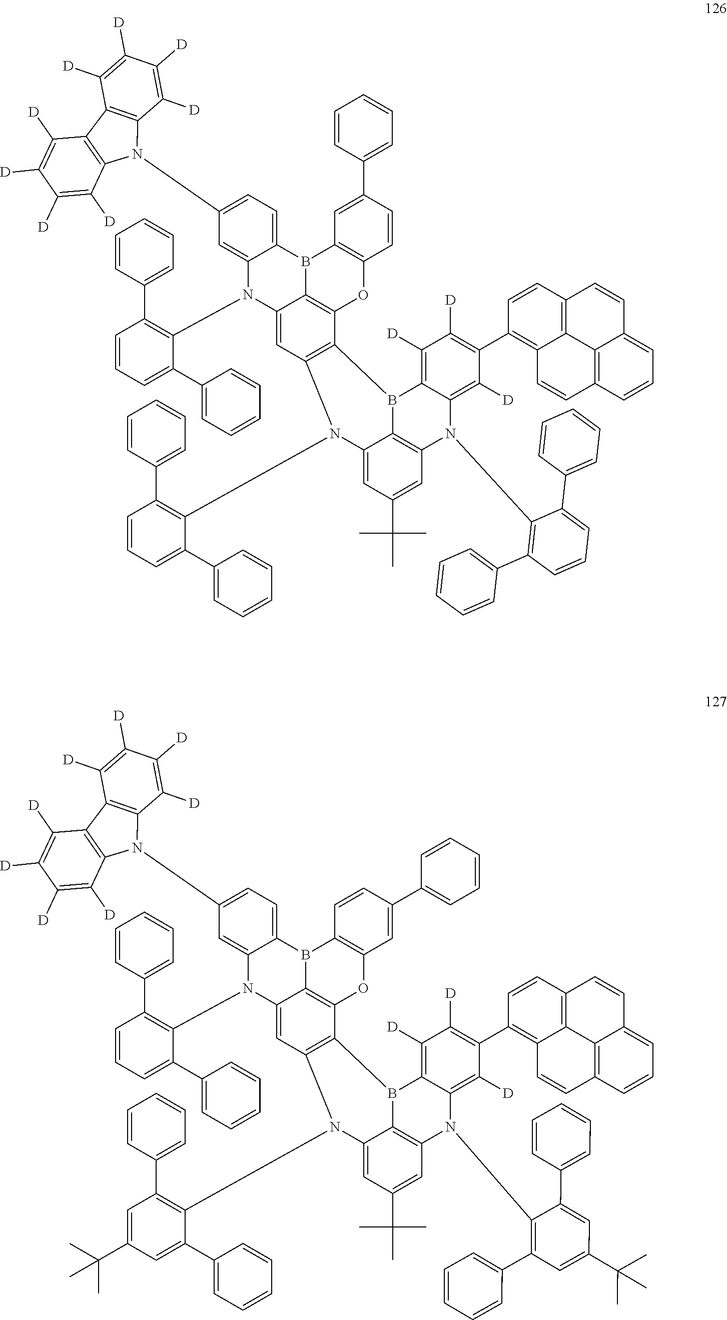 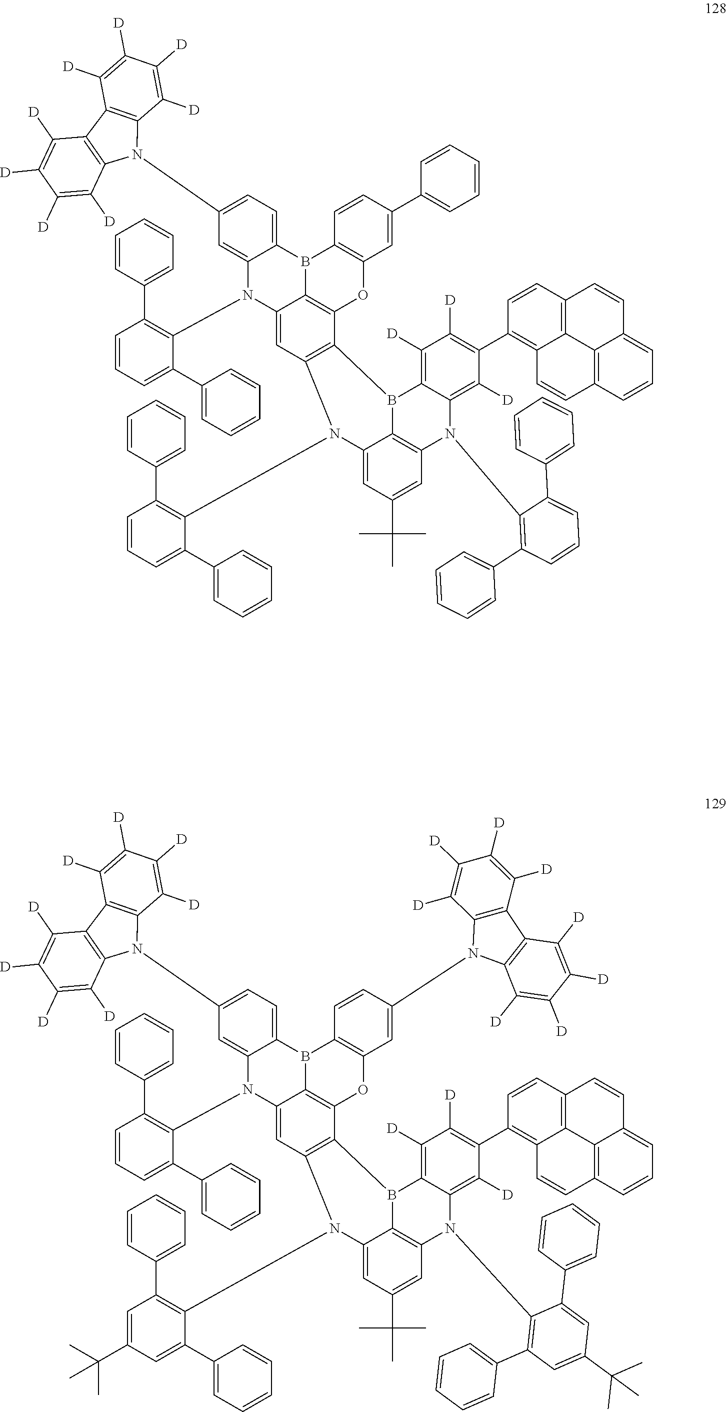 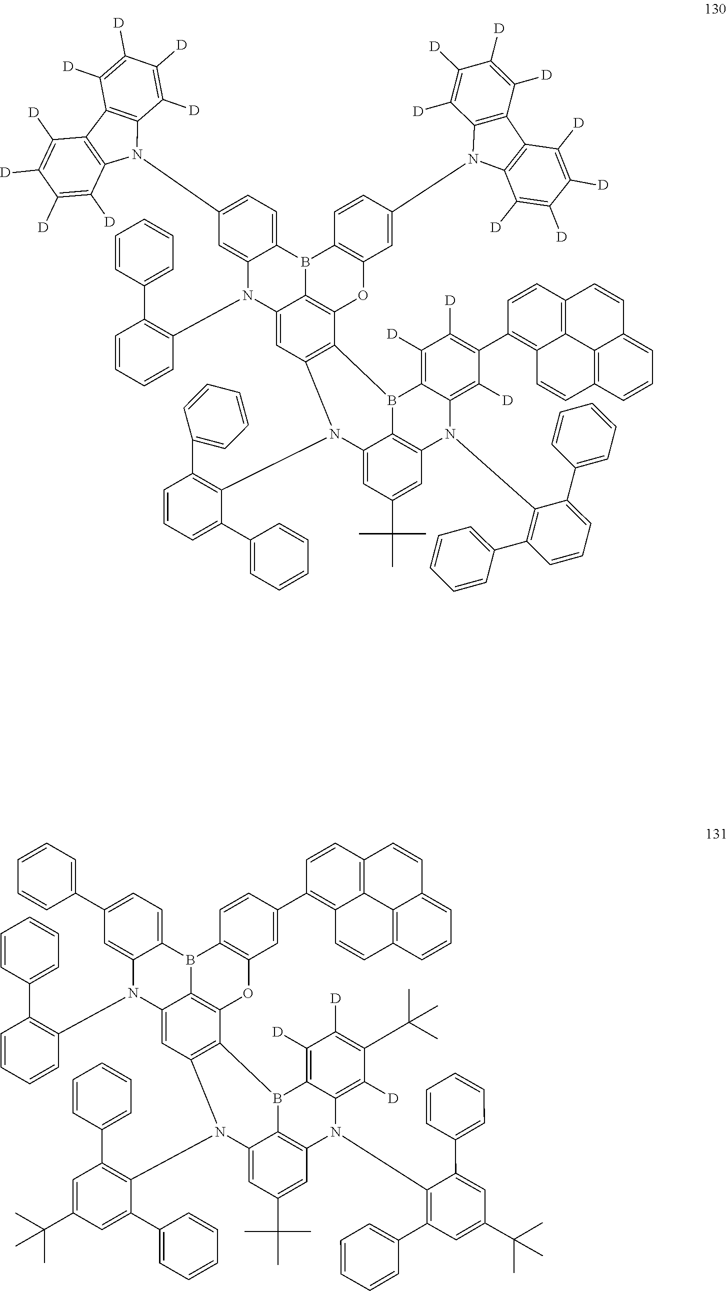 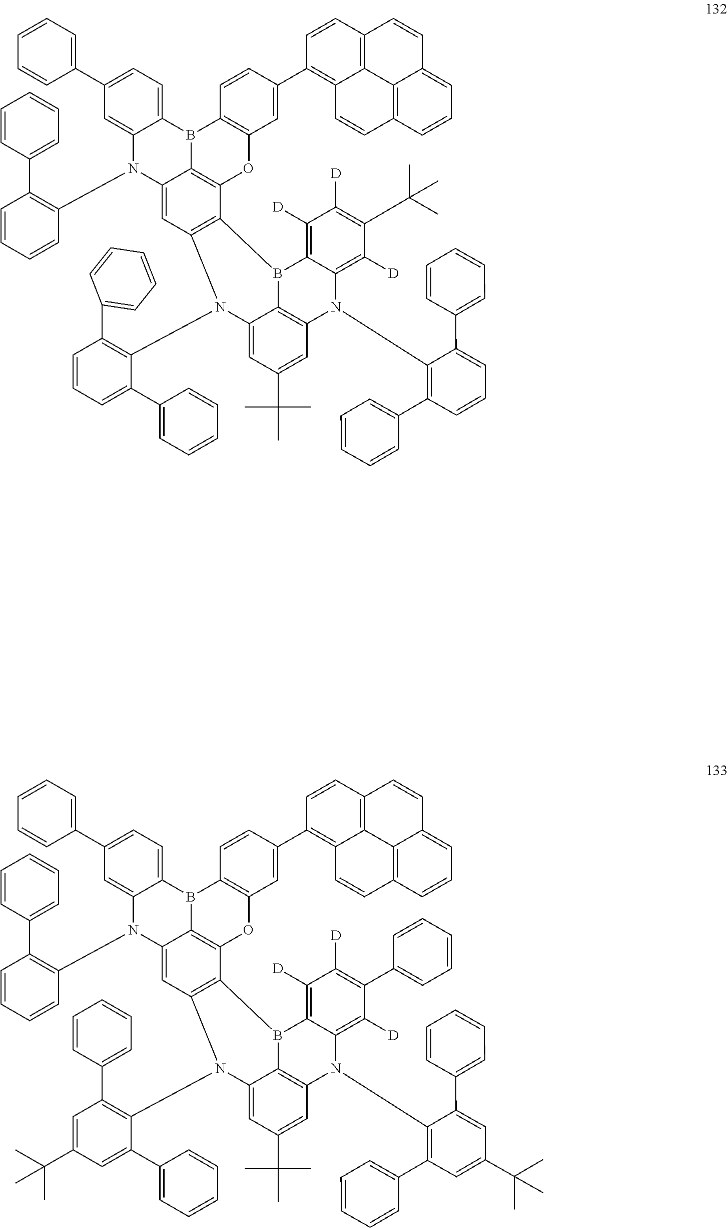 [SMILES: [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccccc2)cc1N3c1ccccc1-c1ccccc1 ; [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccccc2)cc1N3c1ccccc1-c1ccccc1] 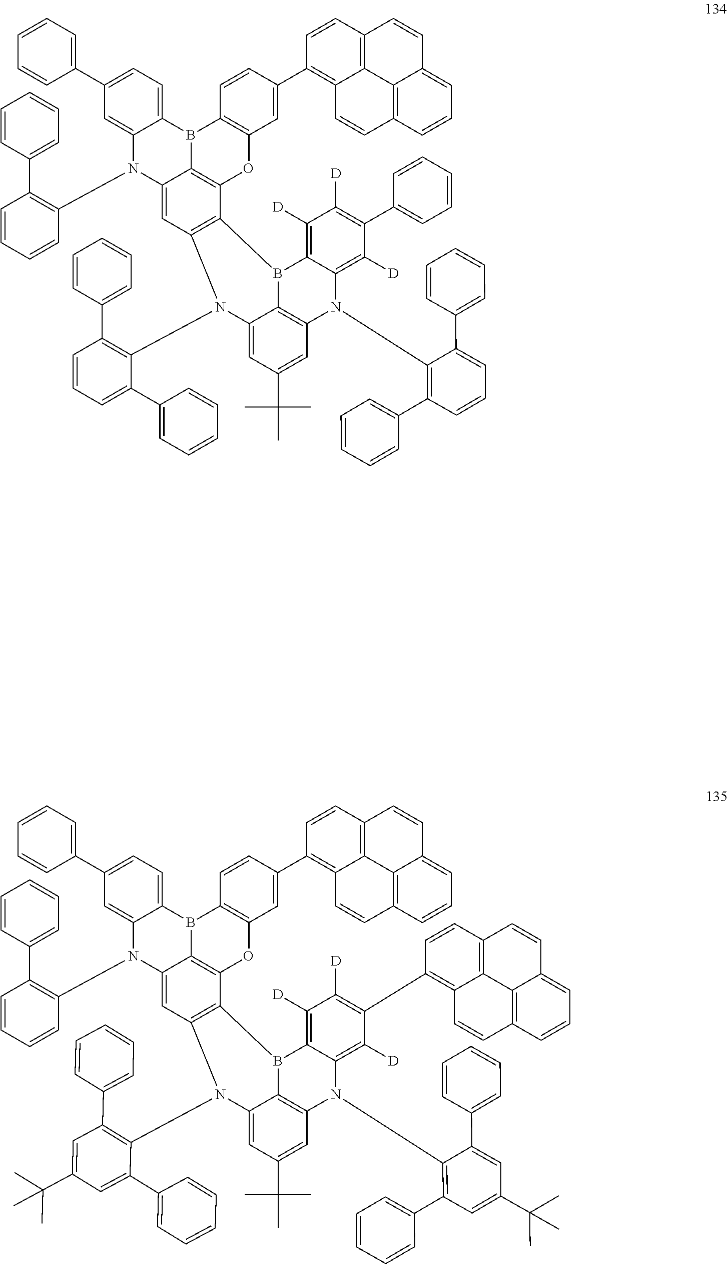 [SMILES: [2H]c1c([2H])c(-c2ccccc2)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccccc2)cc1N3c1ccccc1-c1ccccc1 ; [2H]c1c([2H])c(-c2ccc3ccc4cccc5ccc2c3c45)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccccc2)cc1N3c1ccccc1-c1ccccc1] 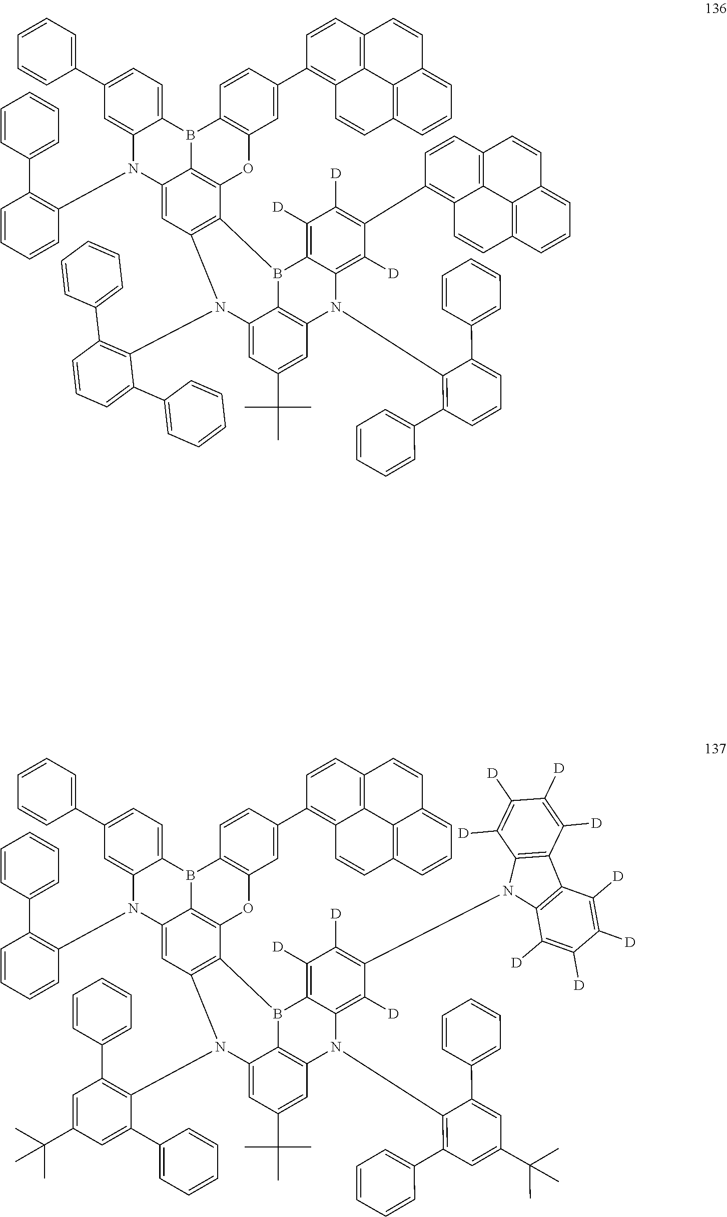 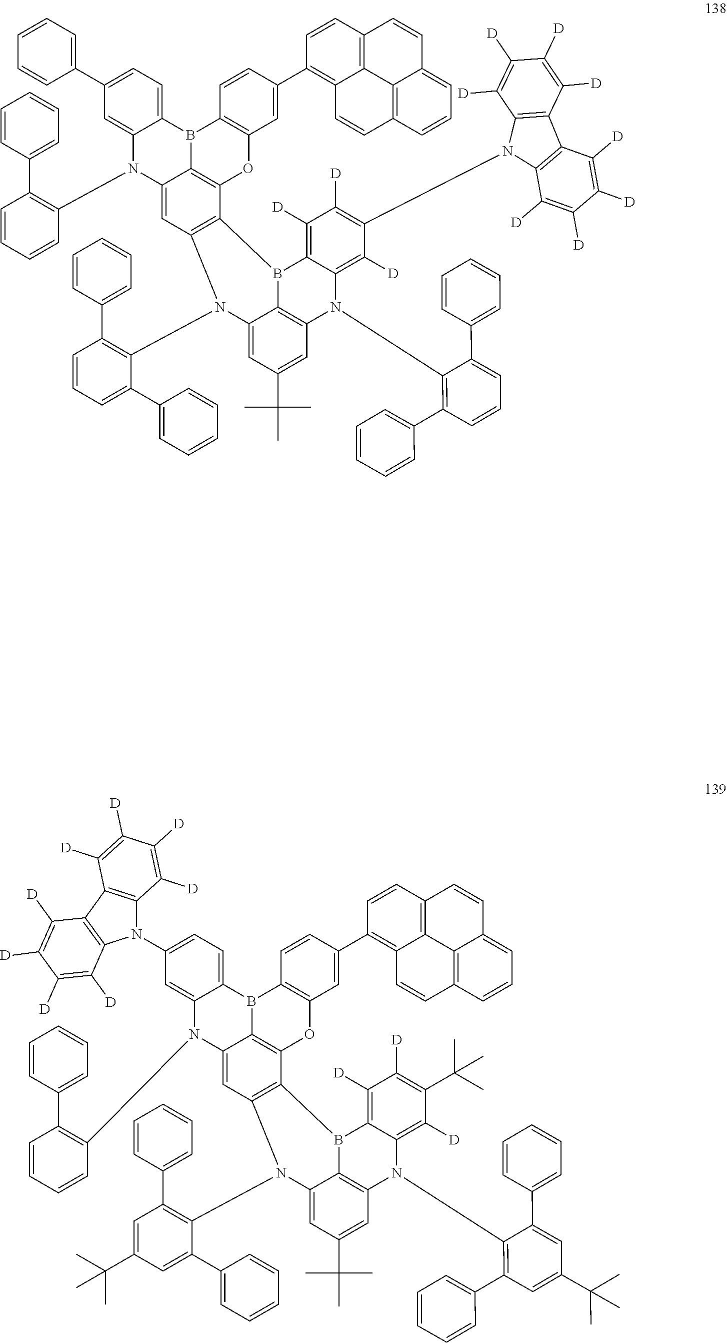 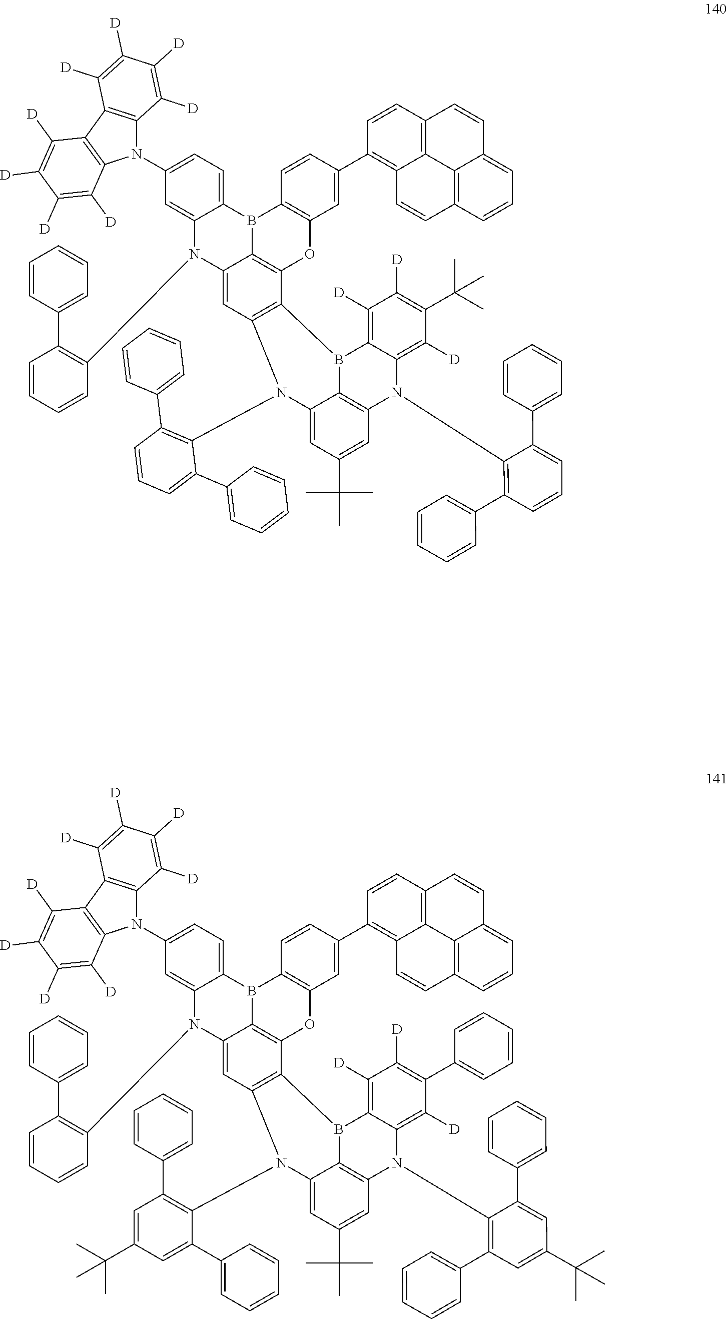 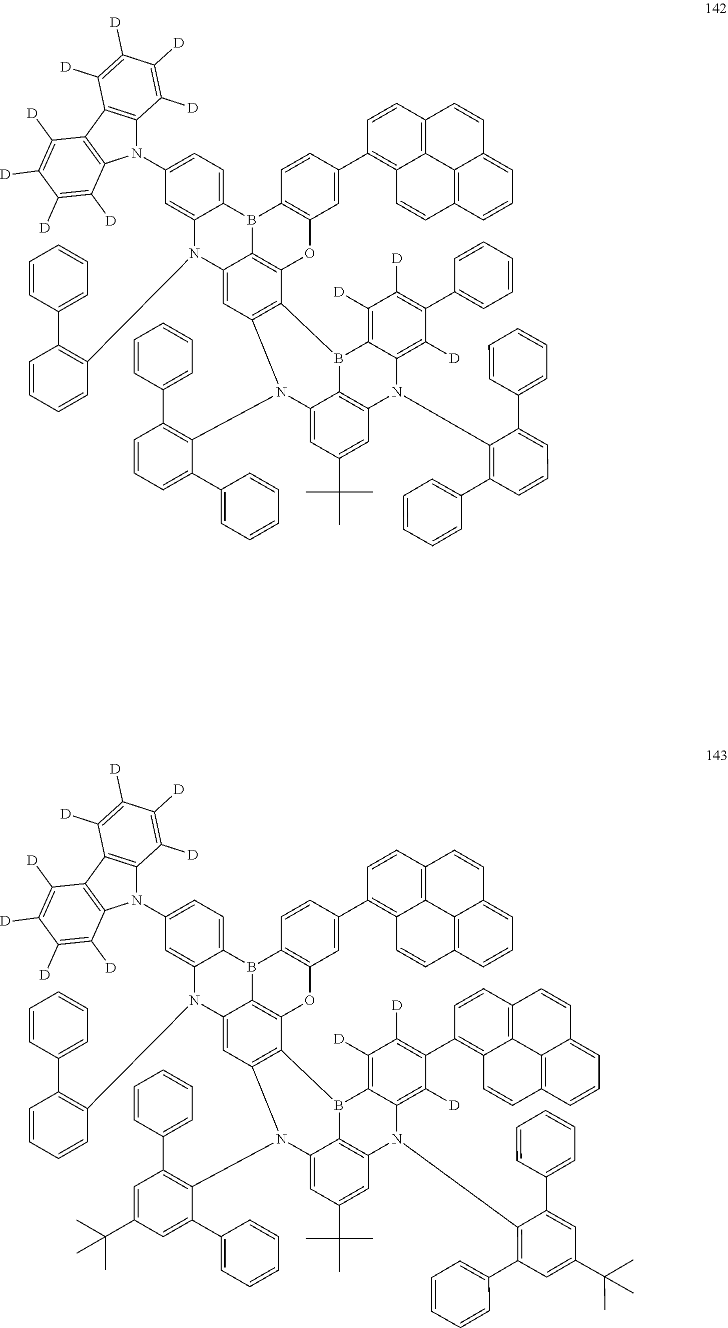 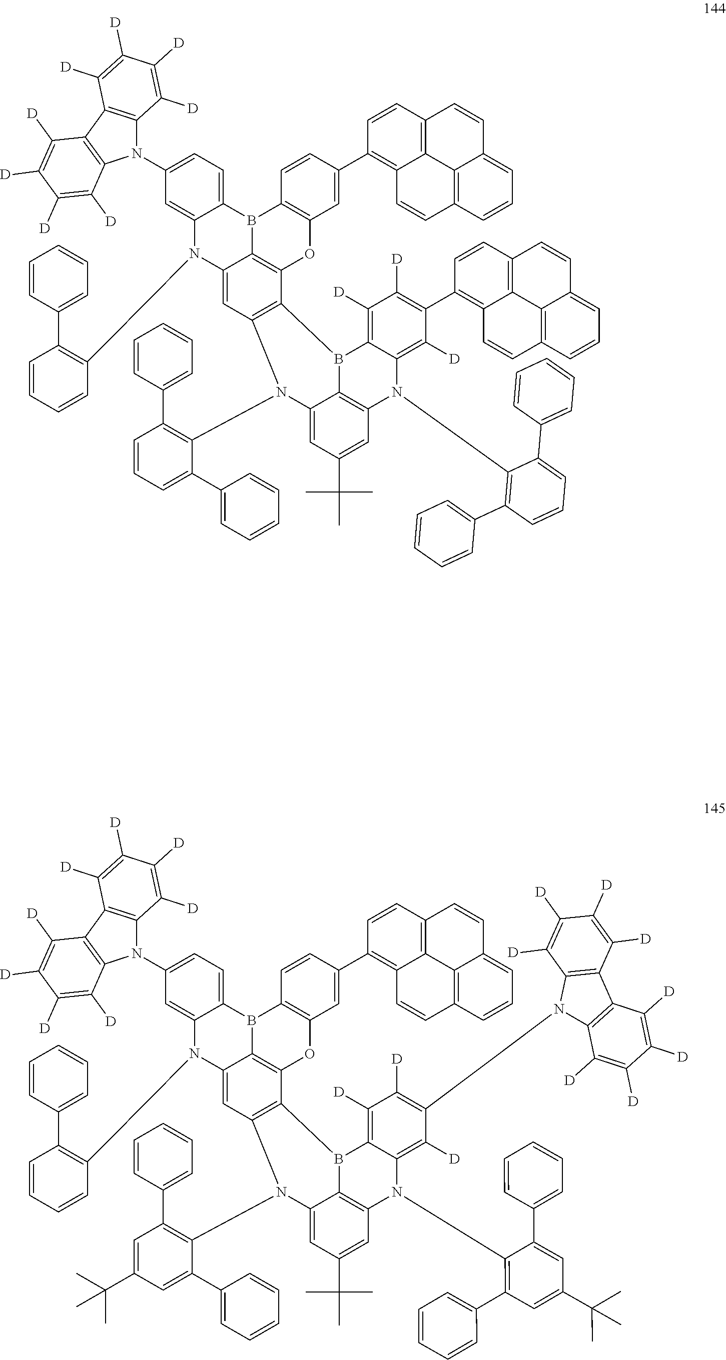 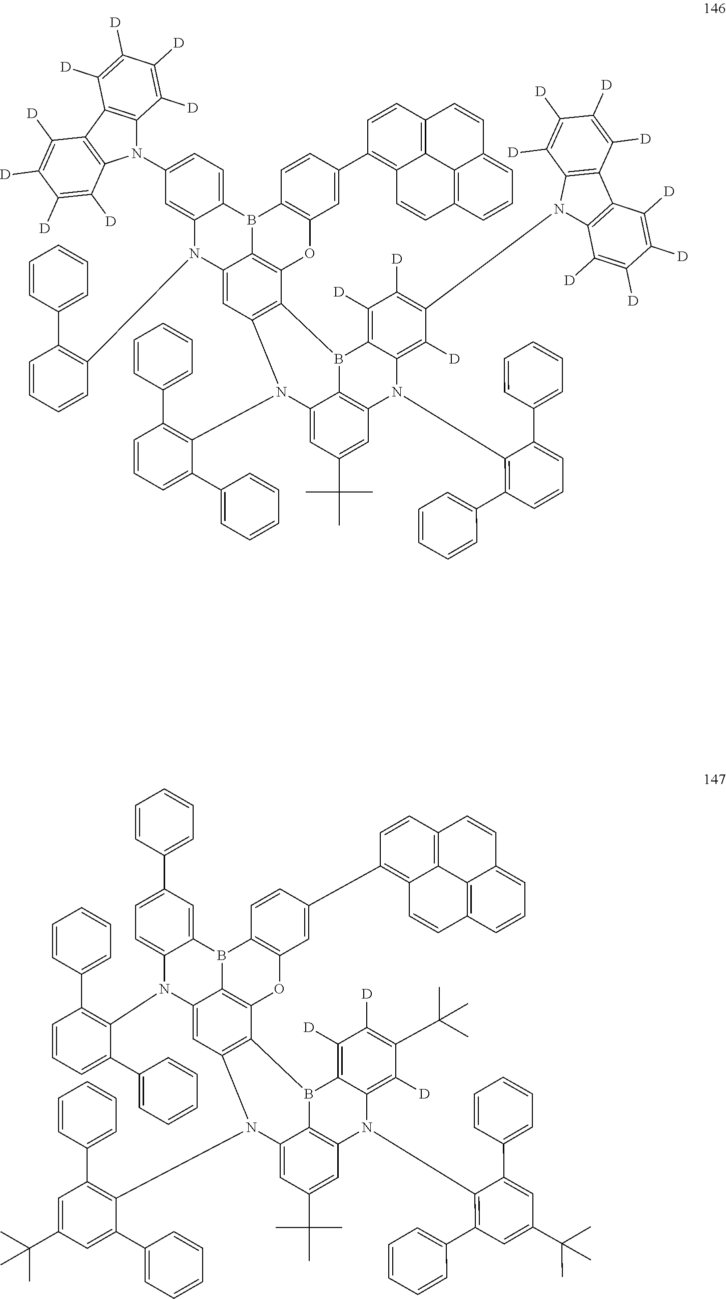 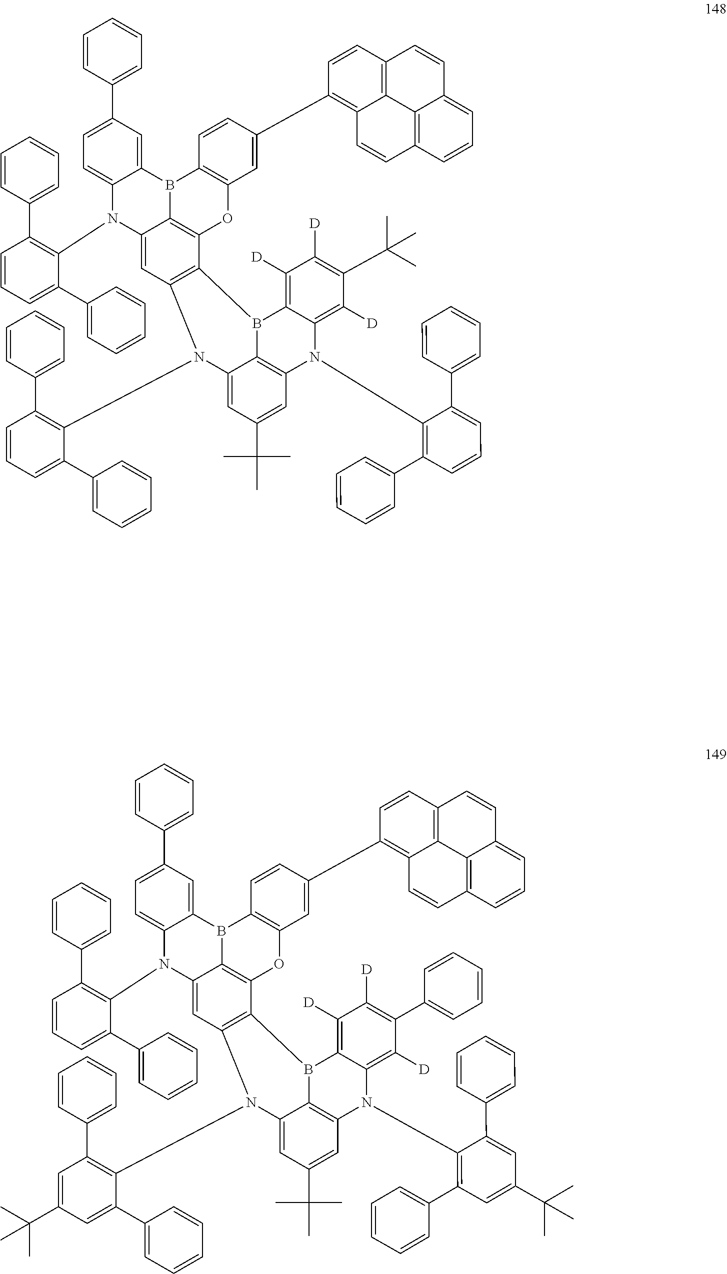 [SMILES: [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1cc(-c2ccccc2)ccc1N3c1c(-c2ccccc2)cccc1-c1ccccc1 ; [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1cc(-c2ccccc2)ccc1N3c1c(-c2ccccc2)cccc1-c1ccccc1] 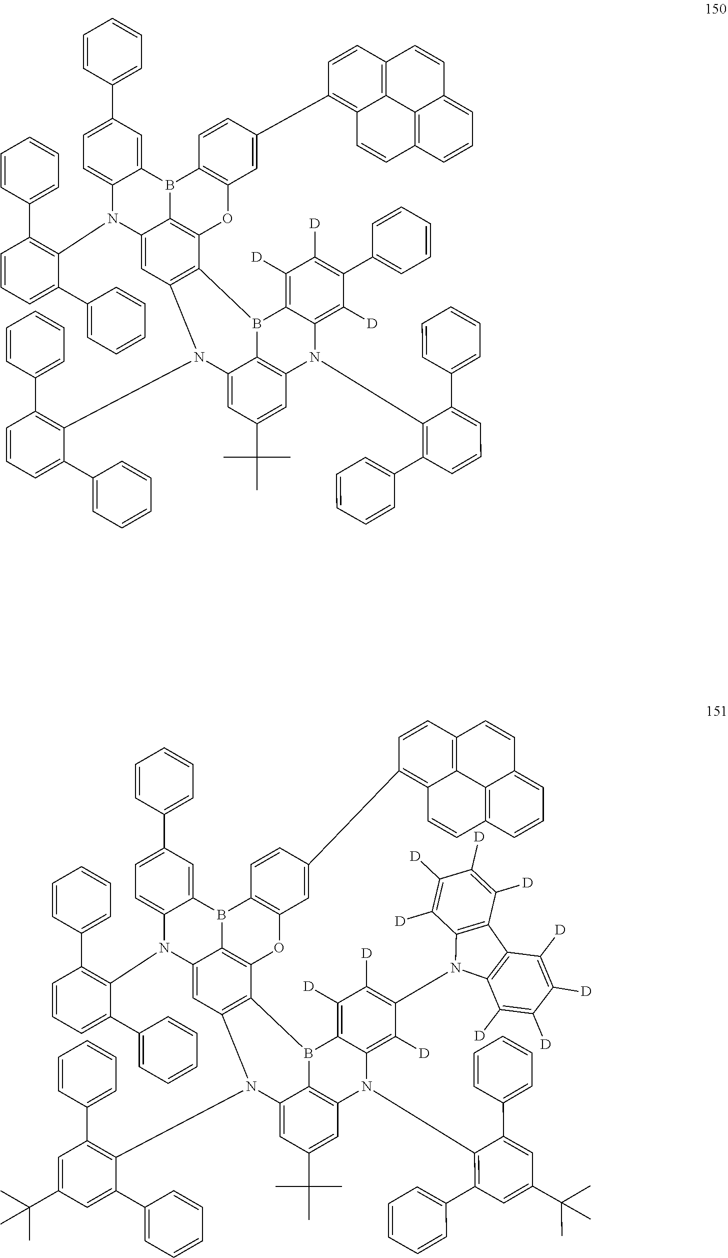 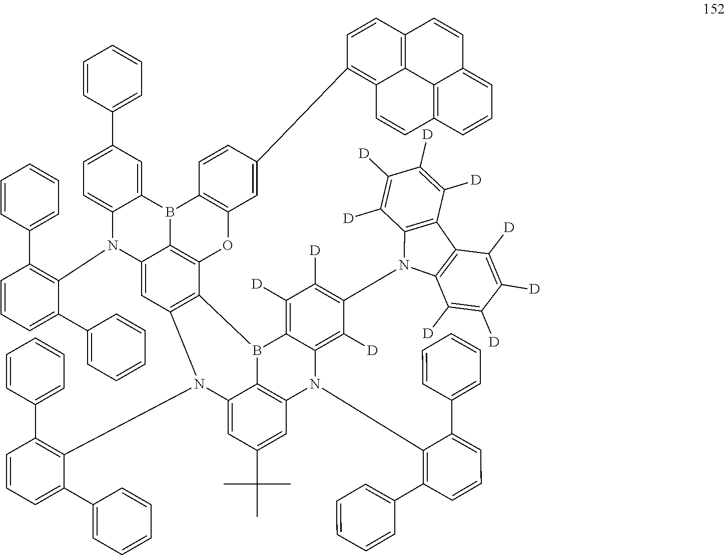 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1cc(-c2ccccc2)ccc1N3c1c(-c2ccccc2)cccc1-c1ccccc1] 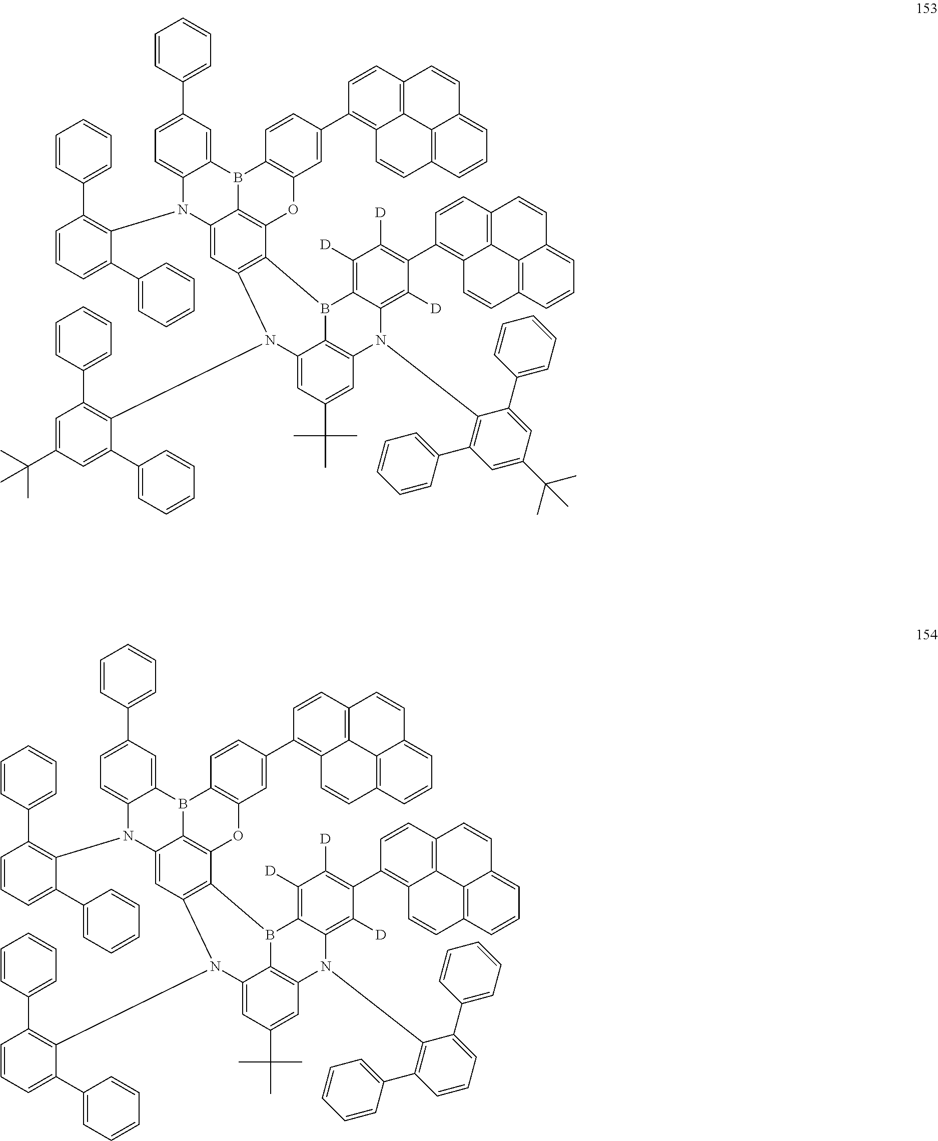 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1cc(-c2ccccc2)ccc1N3c1c(-c2ccccc2)cccc1-c1ccccc1 ; [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1cc(-c2ccccc2)ccc1N3c1c(-c2ccccc2)cccc1-c1ccccc1] 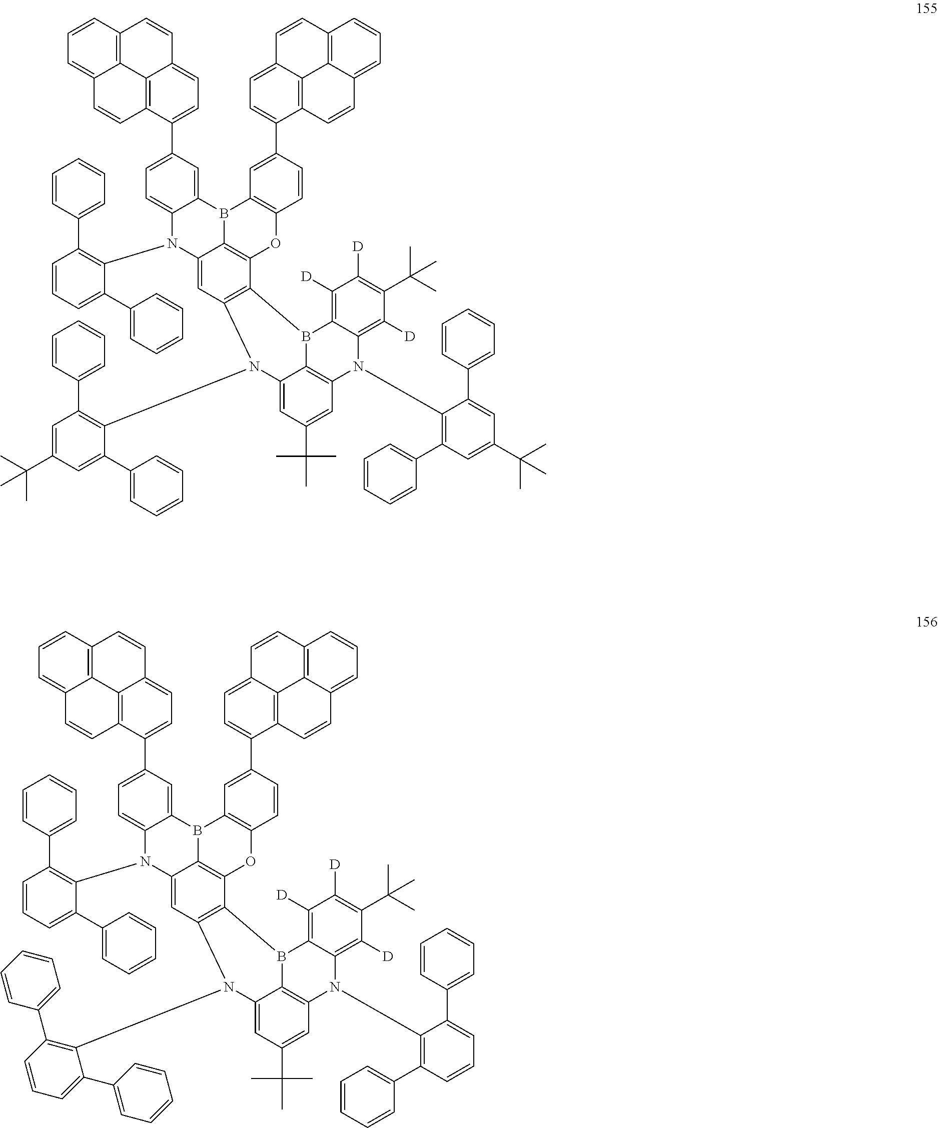 [SMILES: [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1ccc(-c2ccc5ccc6cccc7ccc2c5c67)cc1B4c1cc(-c2ccc4ccc5cccc6ccc2c4c56)ccc1N3c1c(-c2ccccc2)cccc1-c1ccccc1 ; [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1ccc(-c2ccc5ccc6cccc7ccc2c5c67)cc1B4c1cc(-c2ccc4ccc5cccc6ccc2c4c56)ccc1N3c1c(-c2ccccc2)cccc1-c1ccccc1] 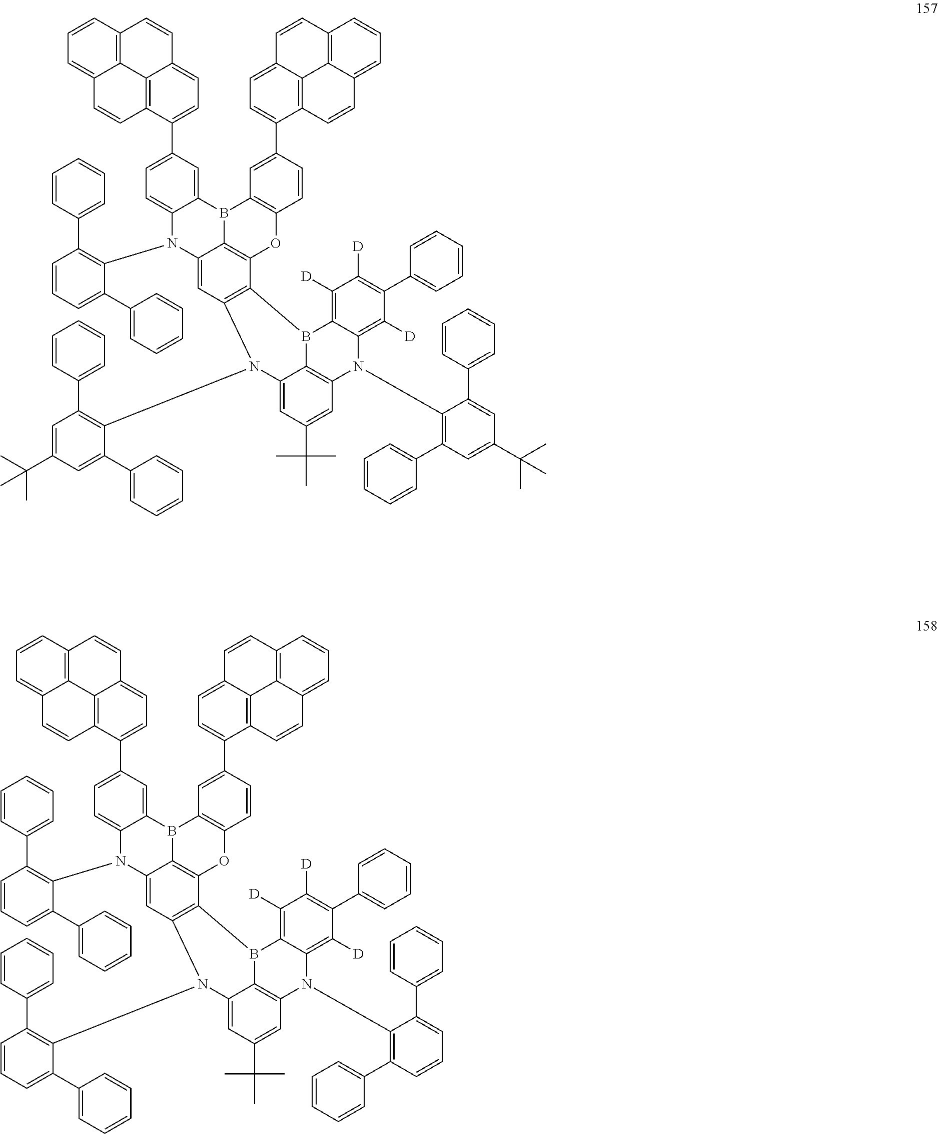 [SMILES: [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1ccc(-c2ccc5ccc6cccc7ccc2c5c67)cc1B4c1cc(-c2ccc4ccc5cccc6ccc2c4c56)ccc1N3c1c(-c2ccccc2)cccc1-c1ccccc1 ; [2H]c1c([2H])c(-c2ccccc2)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1ccc(-c2ccc5ccc6cccc7ccc2c5c67)cc1B4c1cc(-c2ccc4ccc5cccc6ccc2c4c56)ccc1N3c1c(-c2ccccc2)cccc1-c1ccccc1] 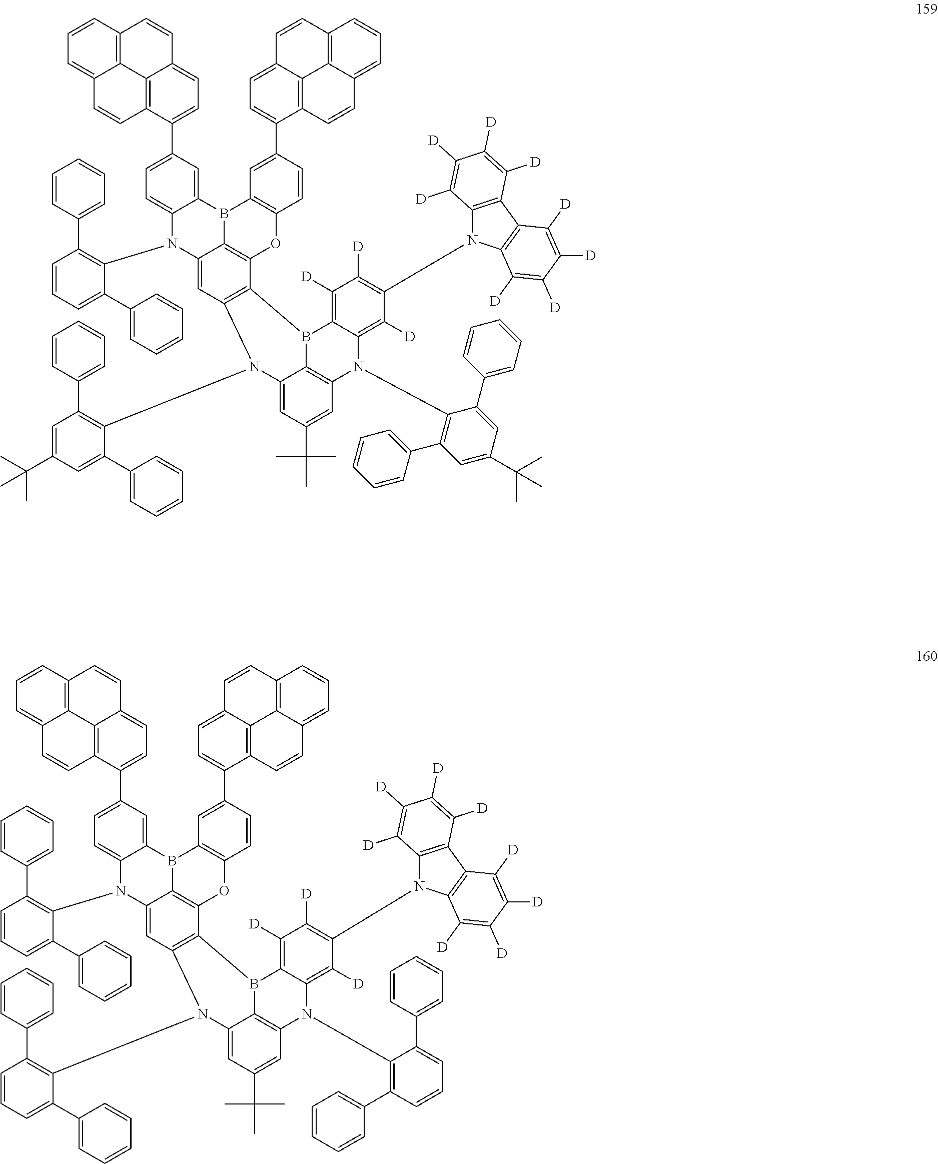 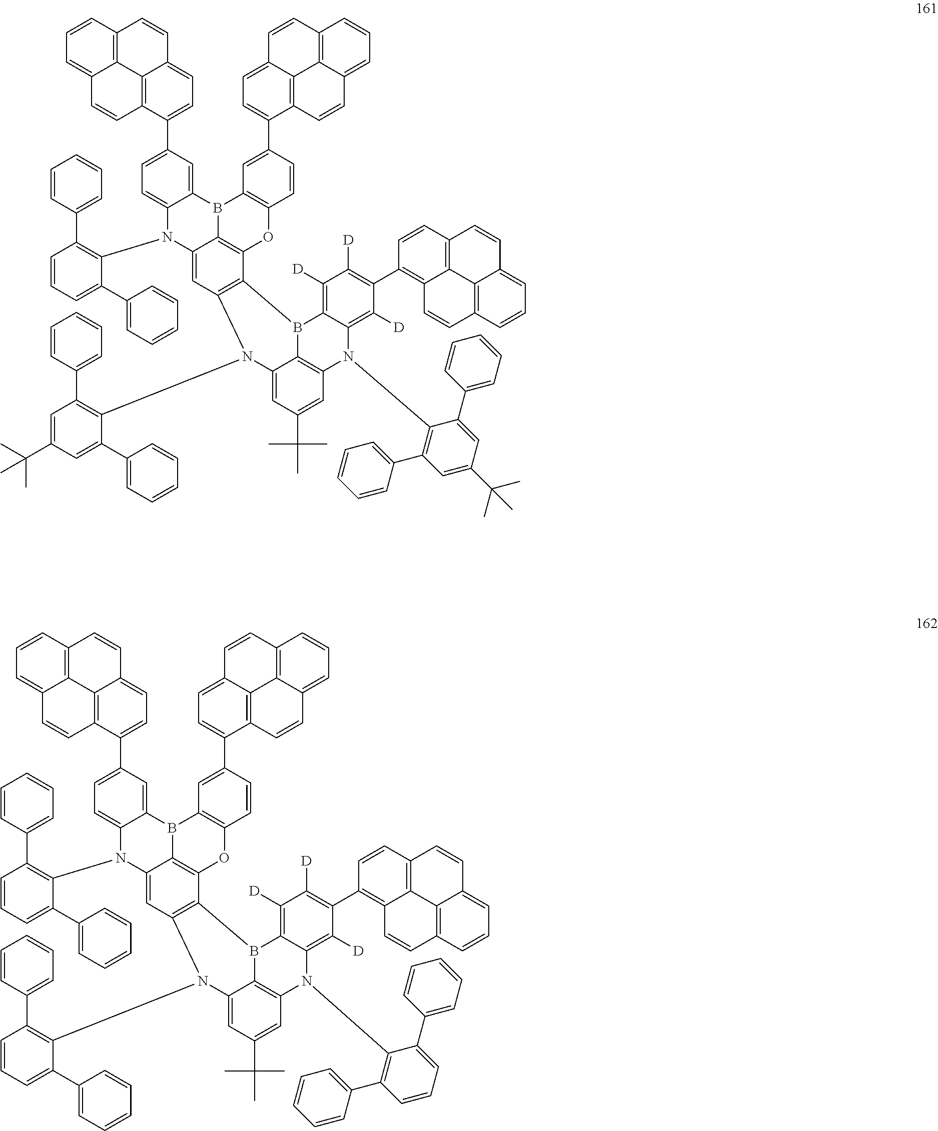 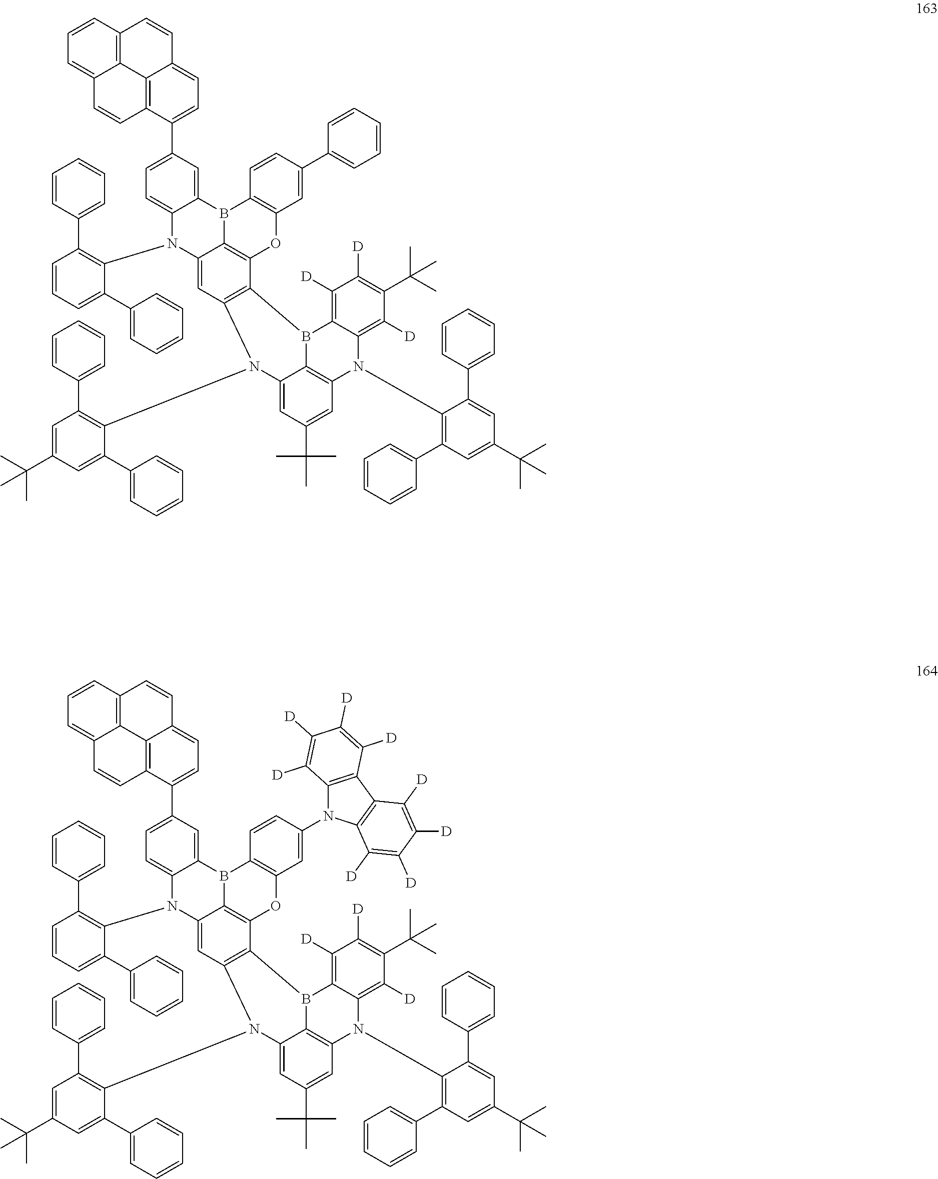 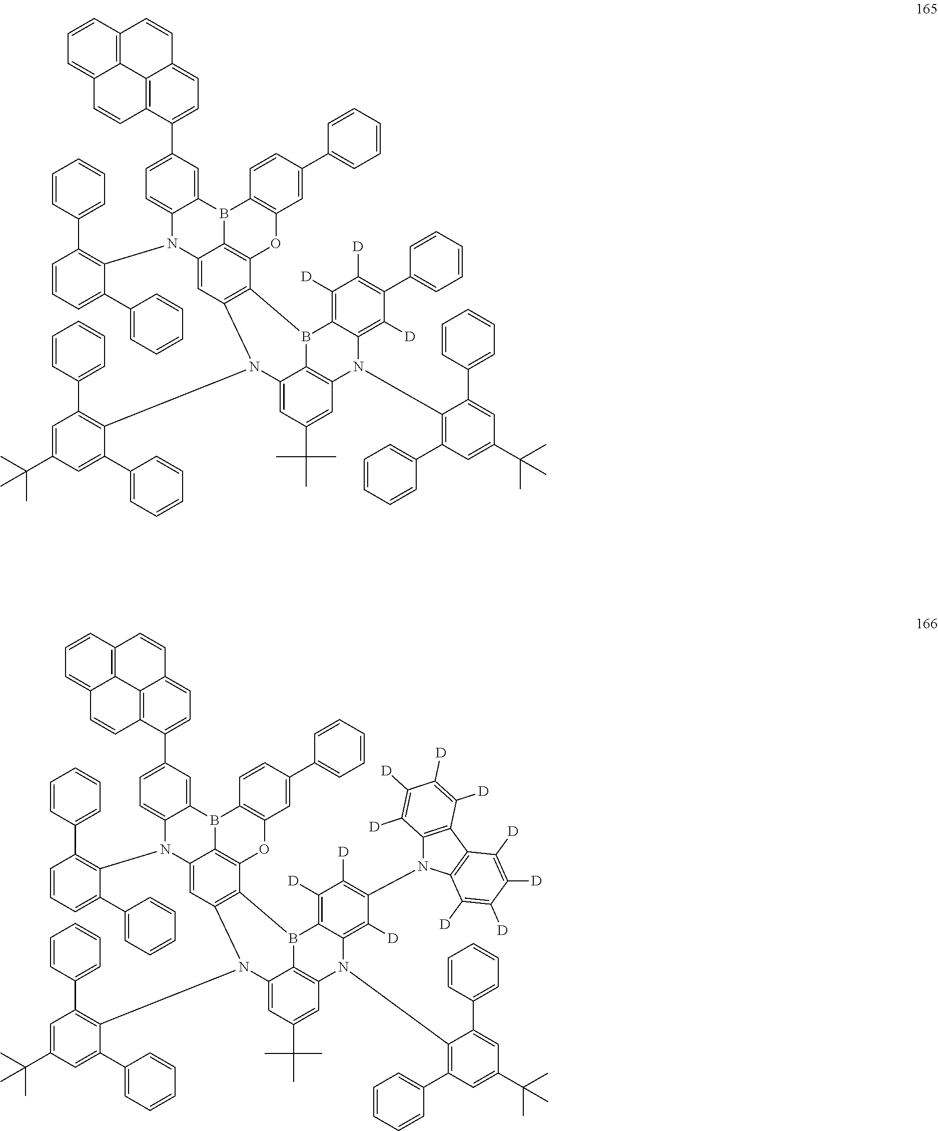 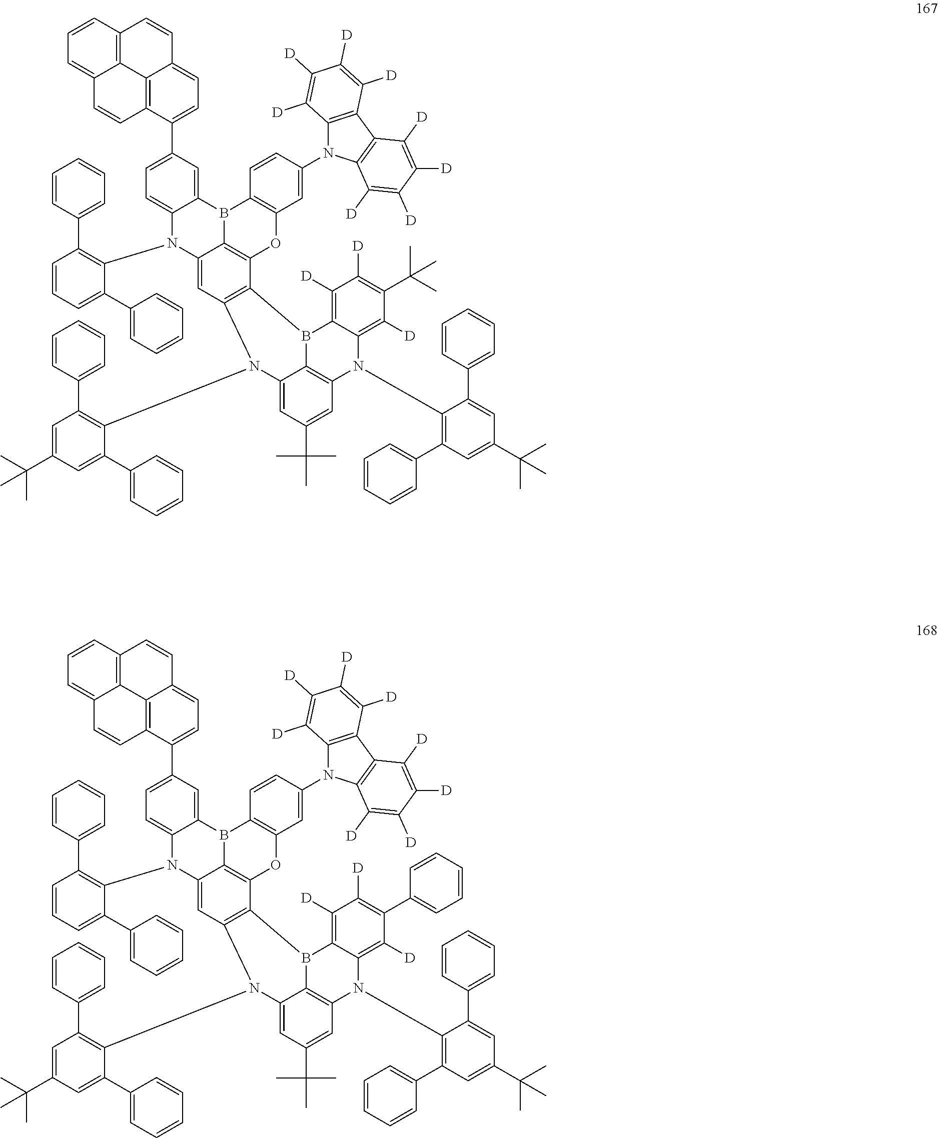 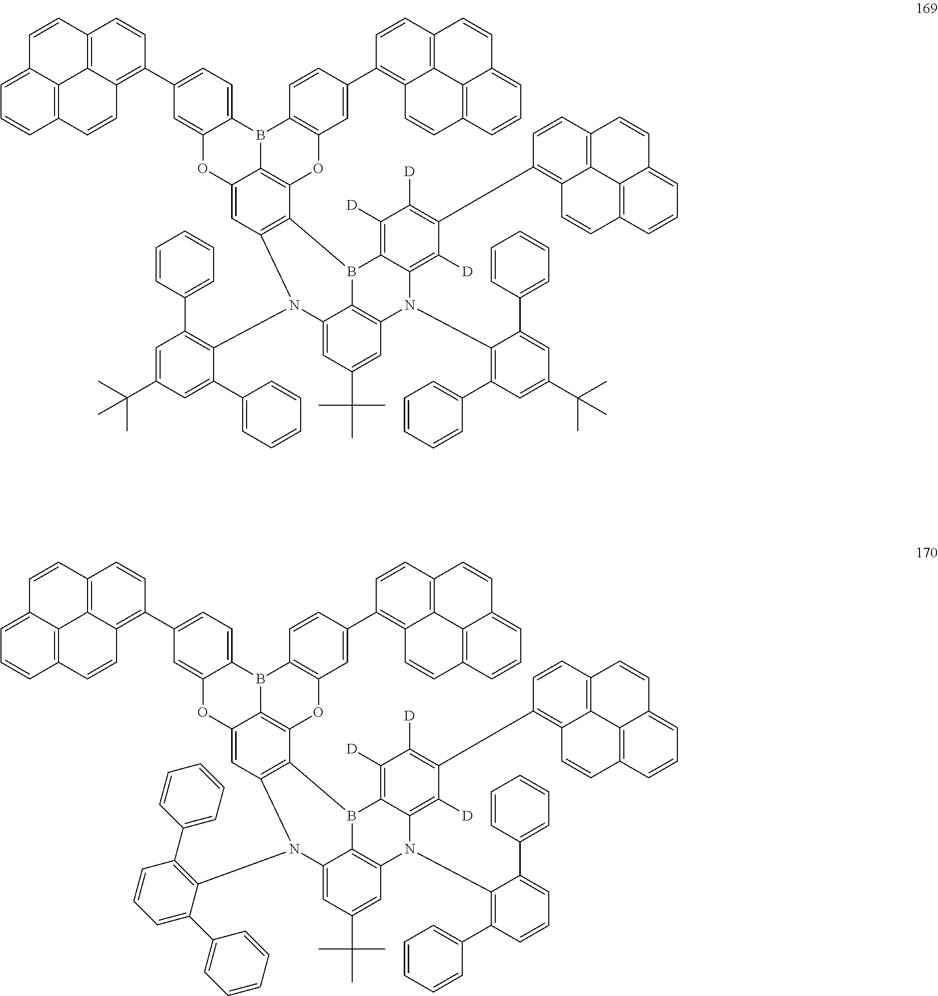 [SMILES: [2H]c1c([2H])c(-c2ccc3ccc4cccc5ccc2c3c45)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1O3 ; [2H]c1c([2H])c(-c2ccc3ccc4cccc5ccc2c3c45)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1O3] 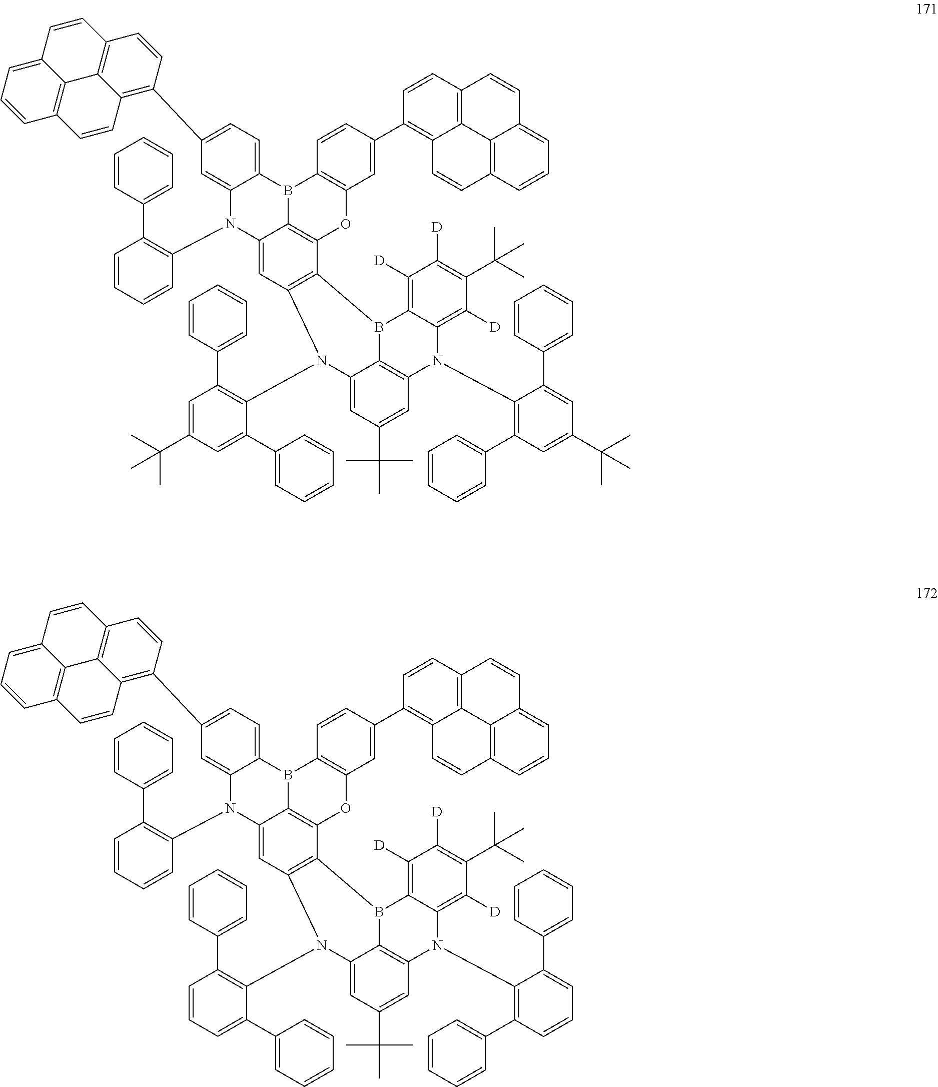 [SMILES: [2H]c1c([2H])c(C(C)(C)C)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1 ; [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1] 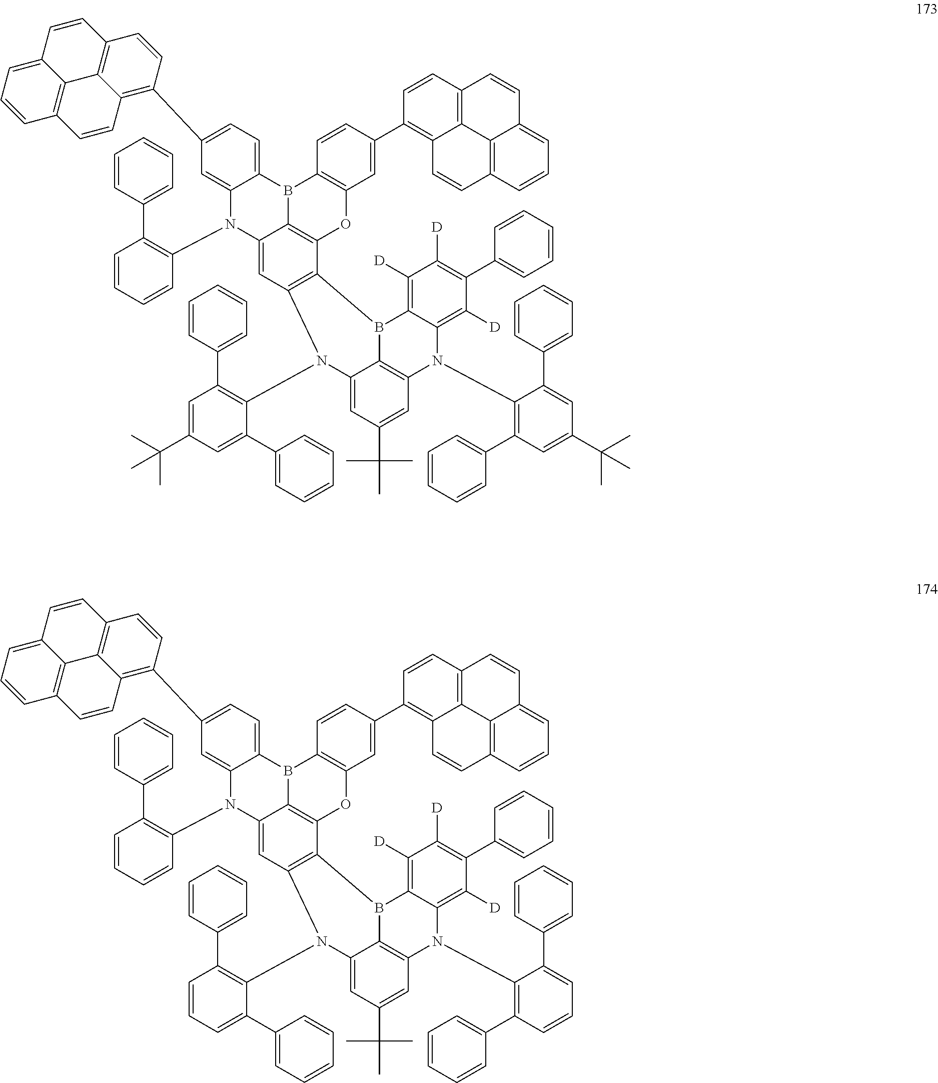 [SMILES: [2H]c1c([2H])c(-c2ccccc2)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1 ; [2H]c1c([2H])c(-c2ccccc2)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)Oc1cc(-c2ccc5ccc6cccc7ccc2c5c67)ccc1B4c1ccc(-c2ccc4ccc5cccc6ccc2c4c56)cc1N3c1ccccc1-c1ccccc1] 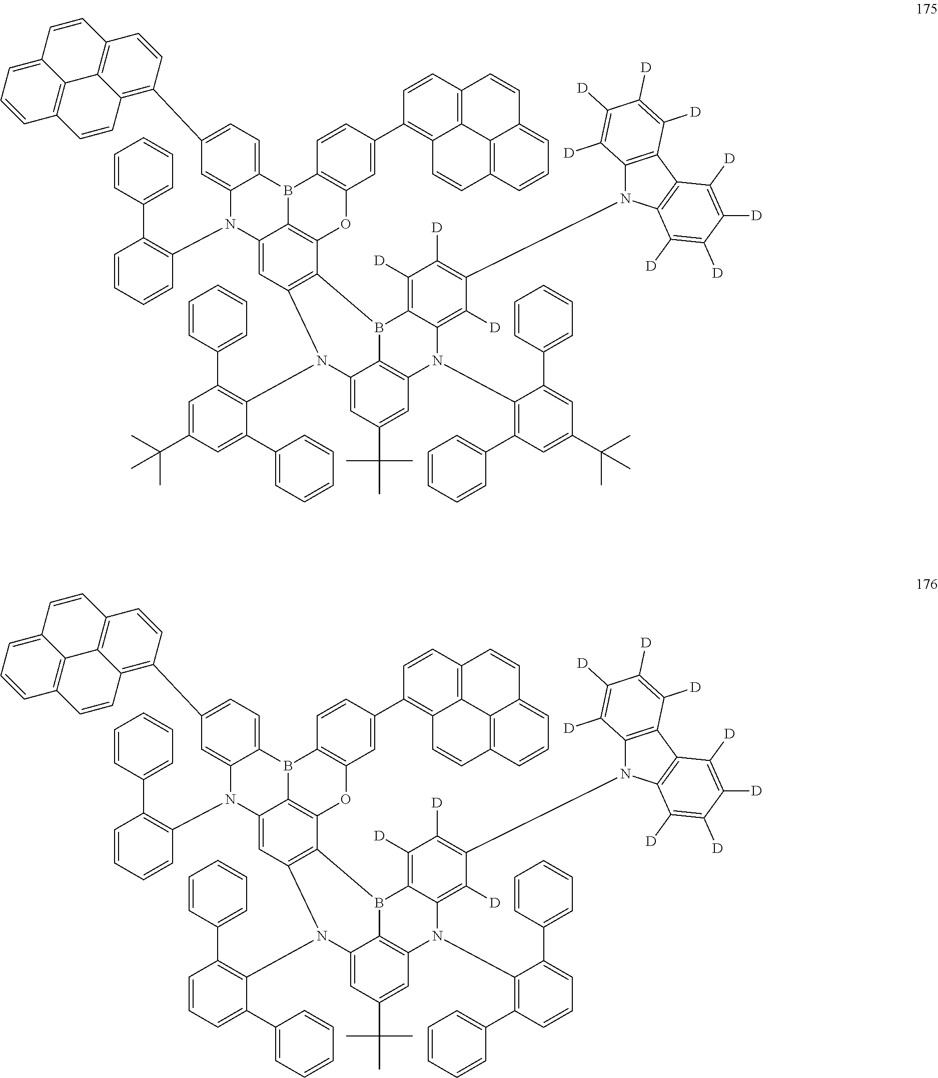 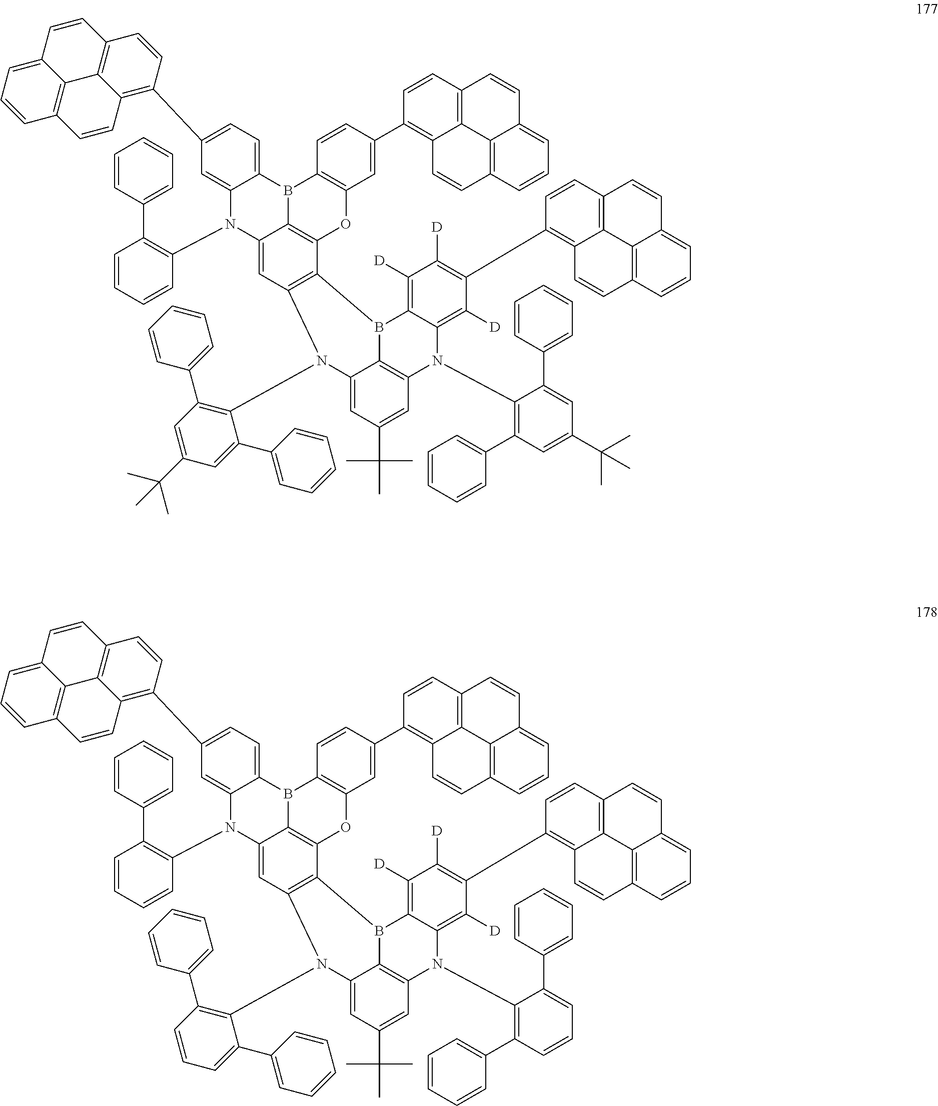 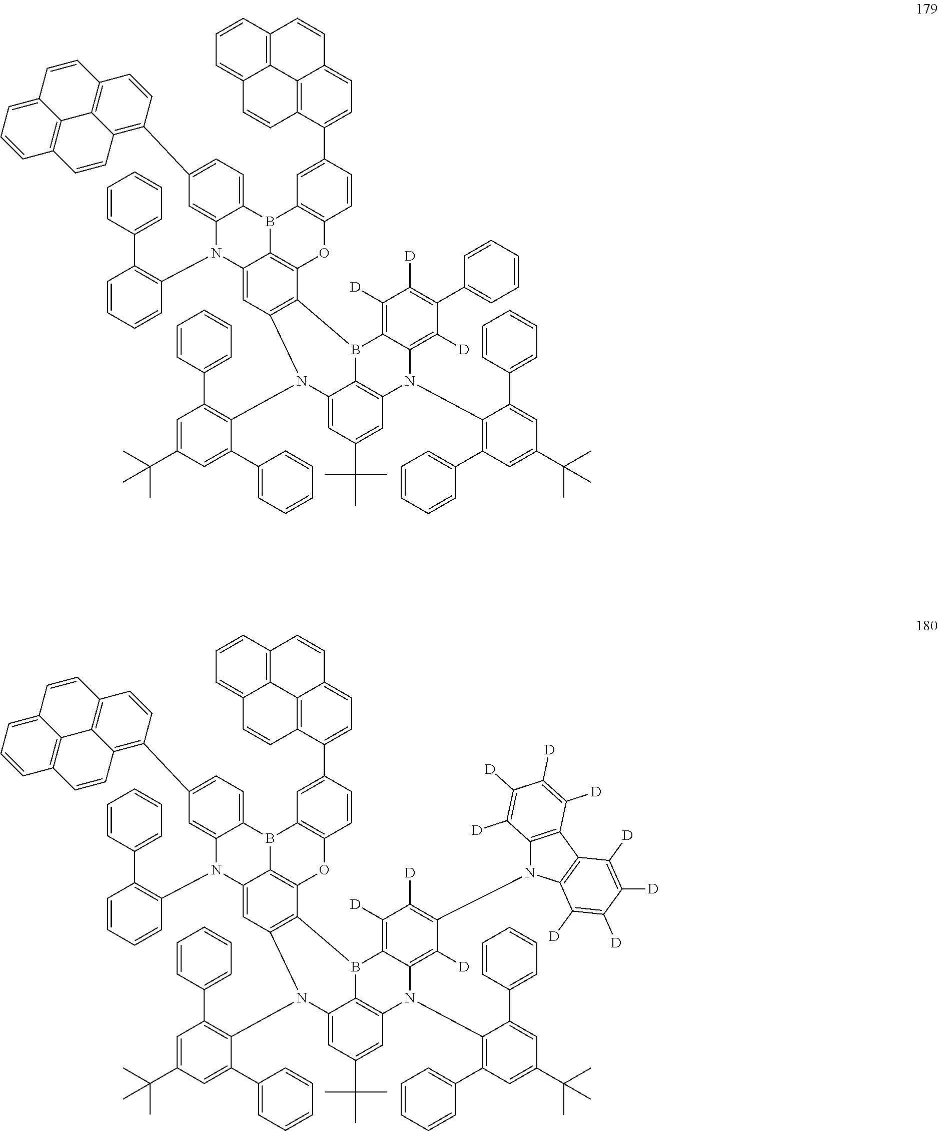 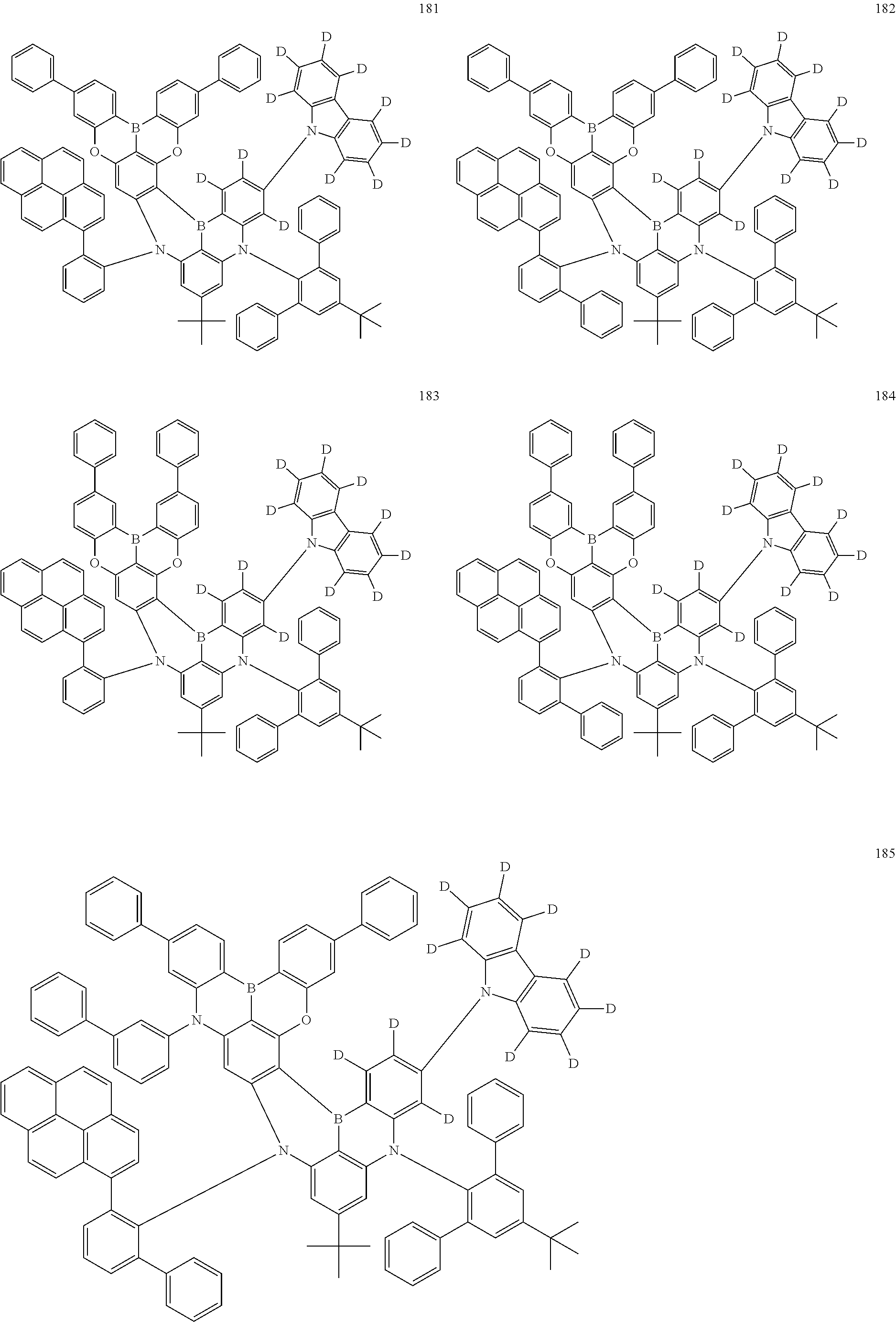 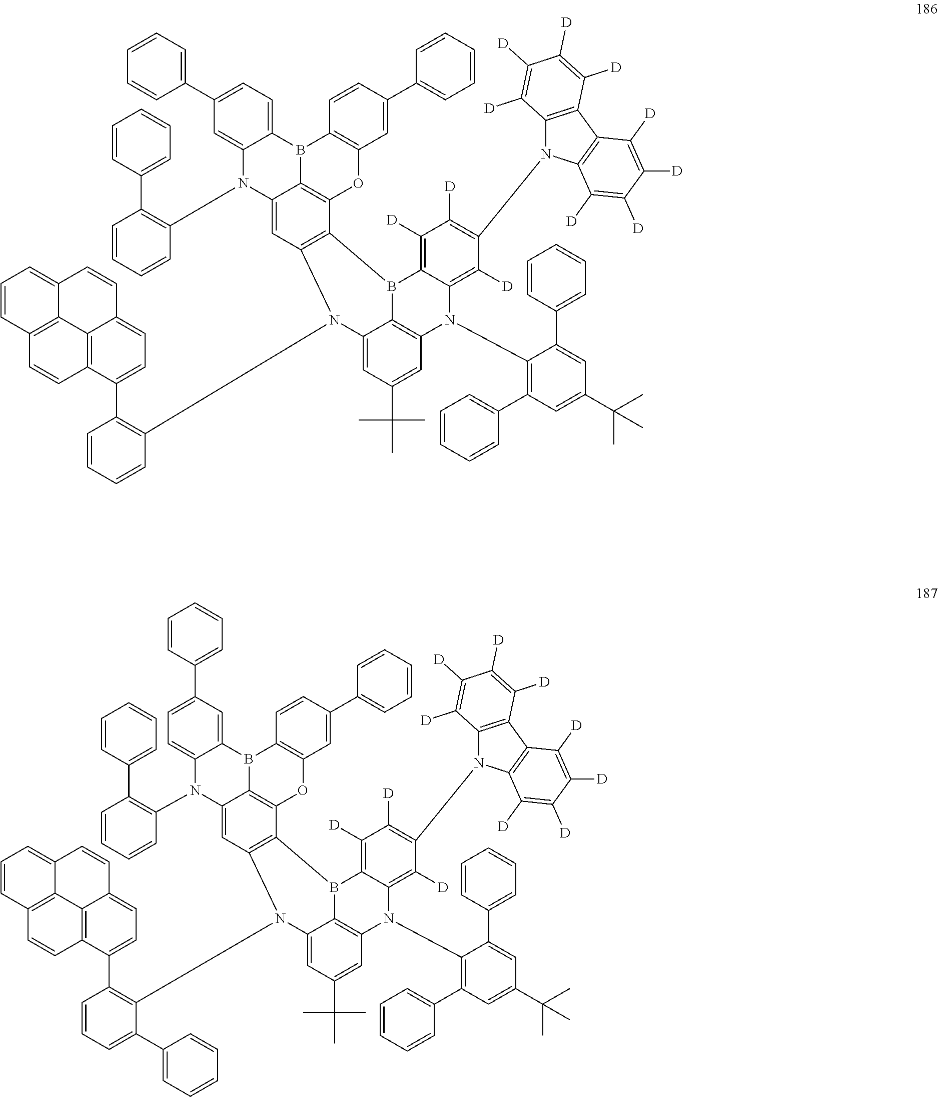 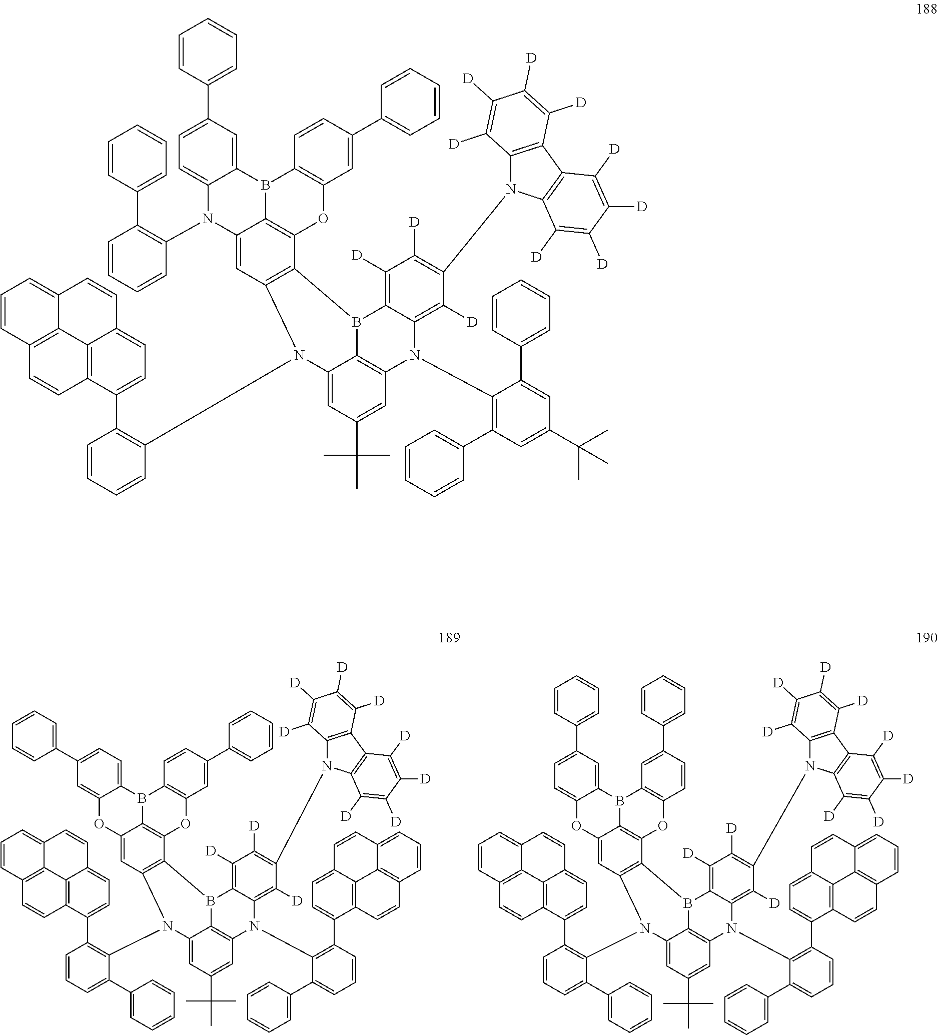 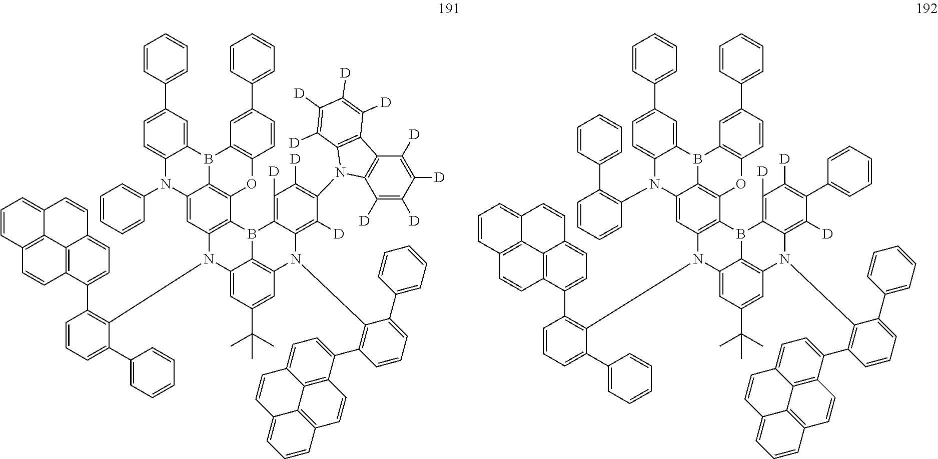 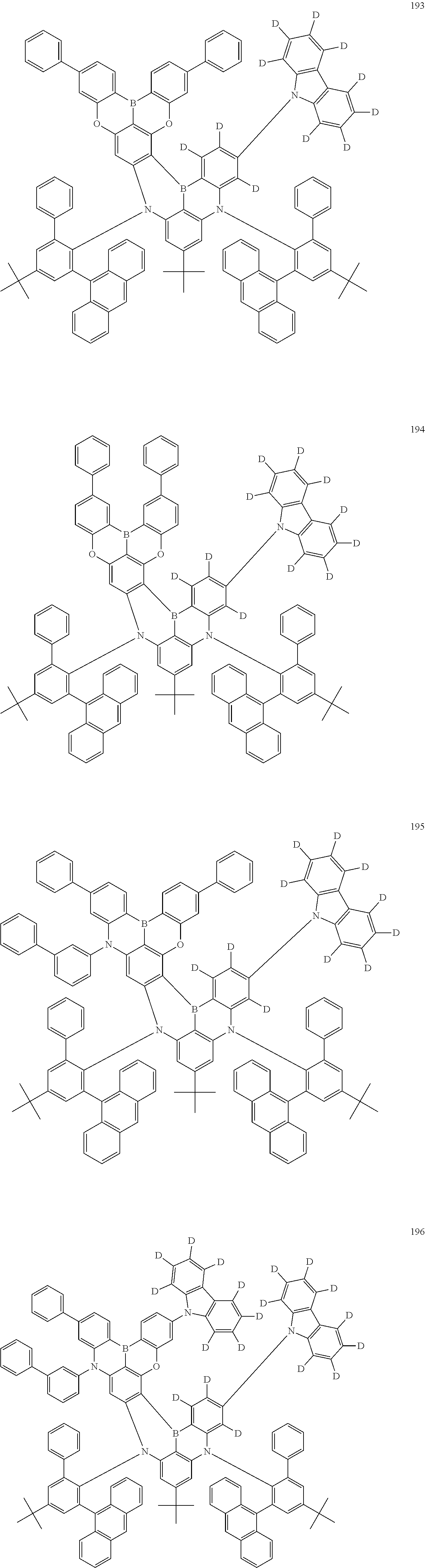 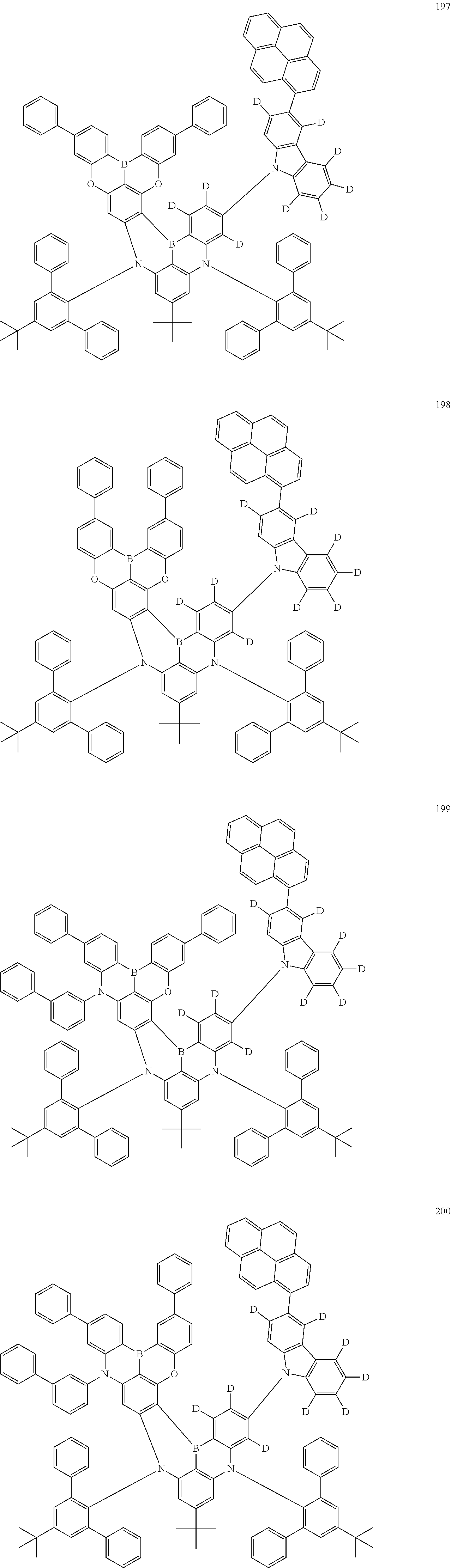 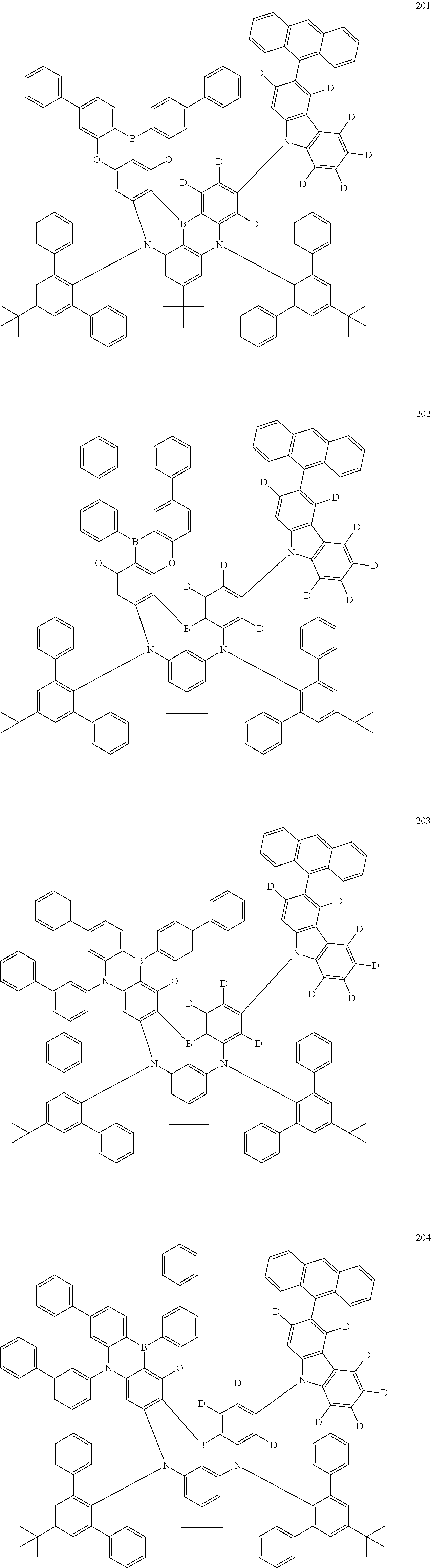 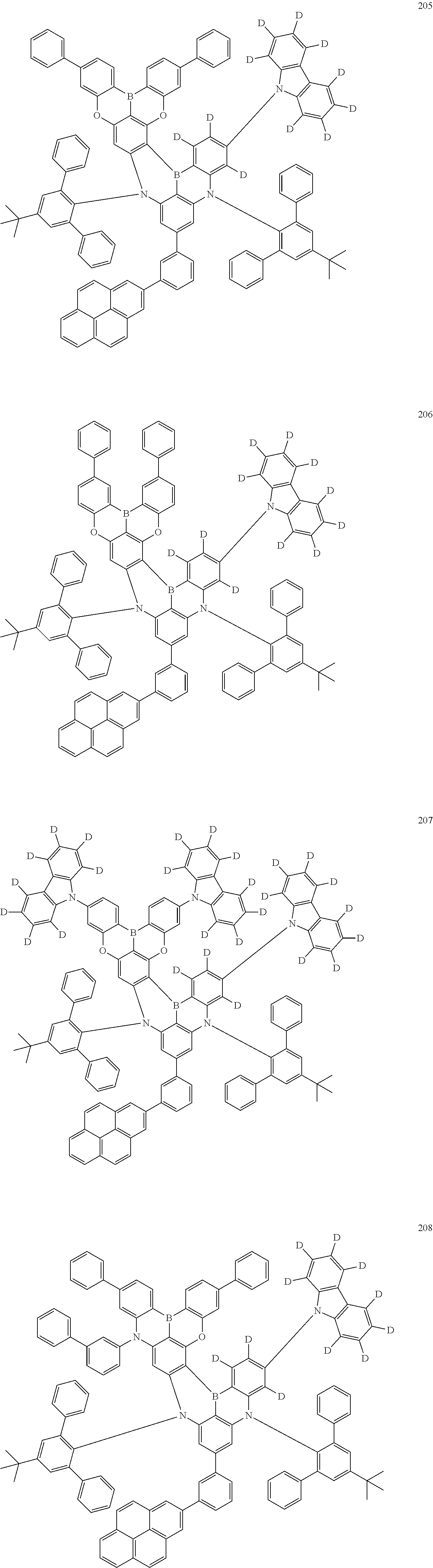 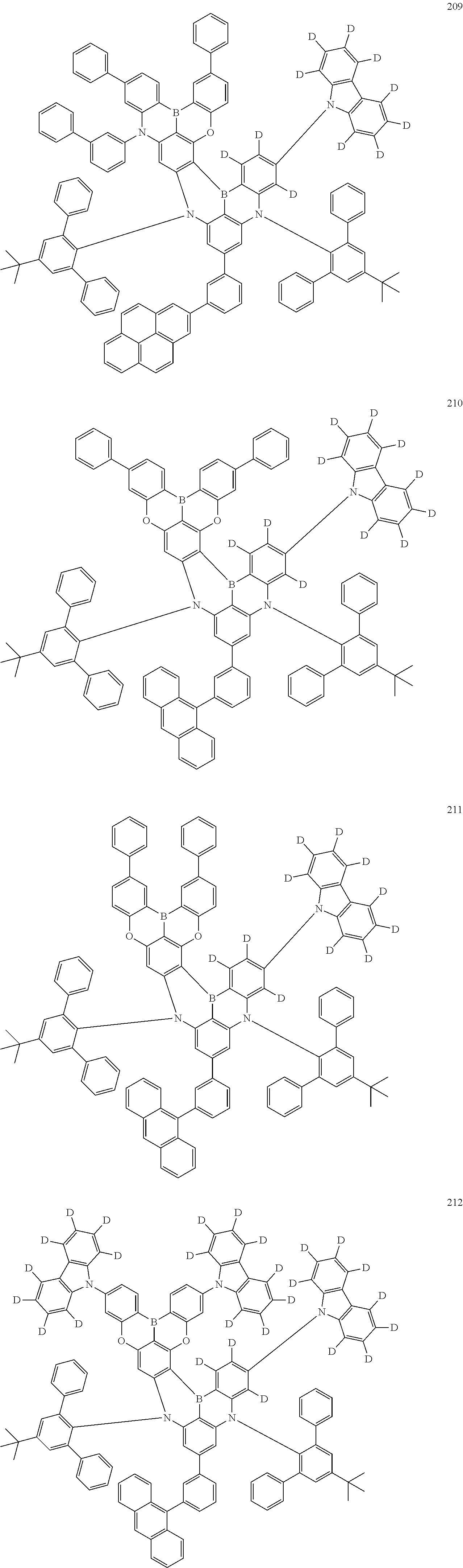 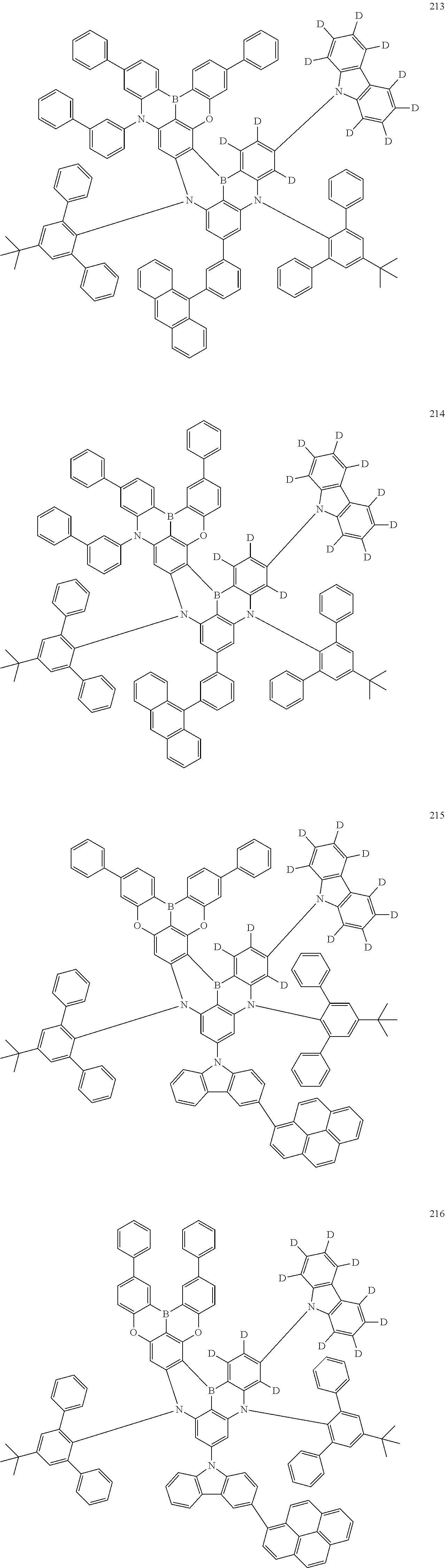 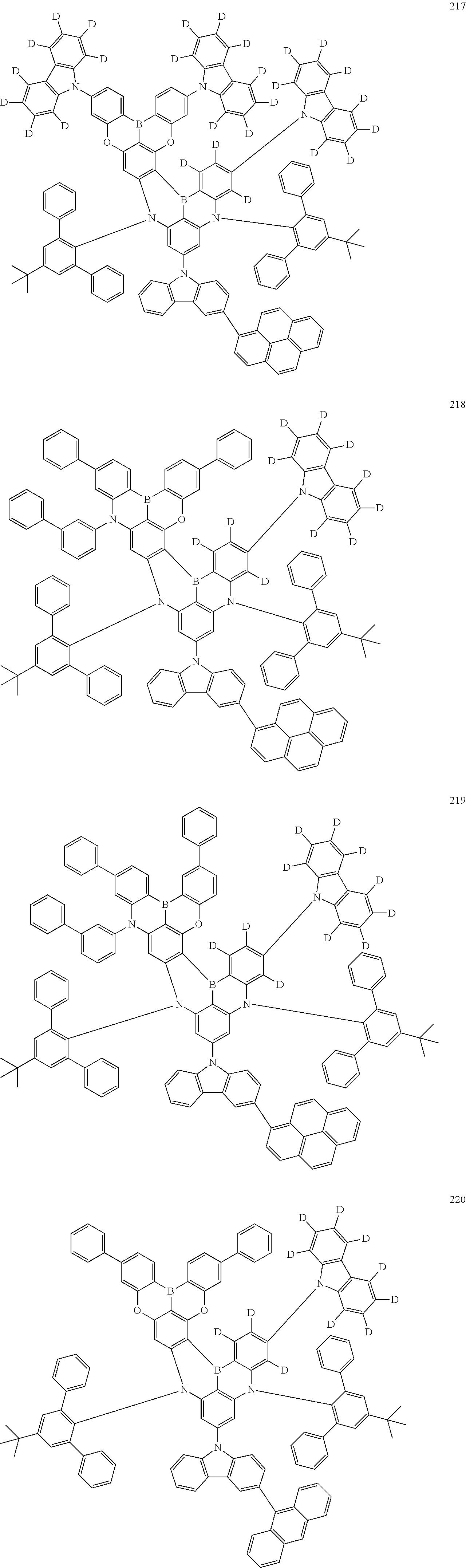 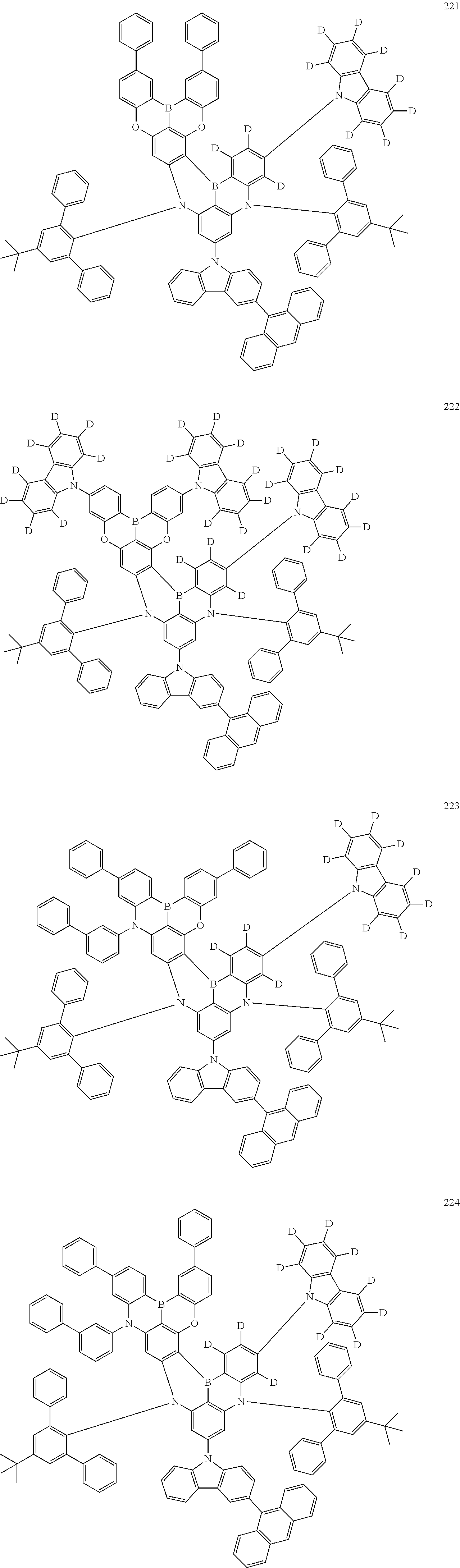 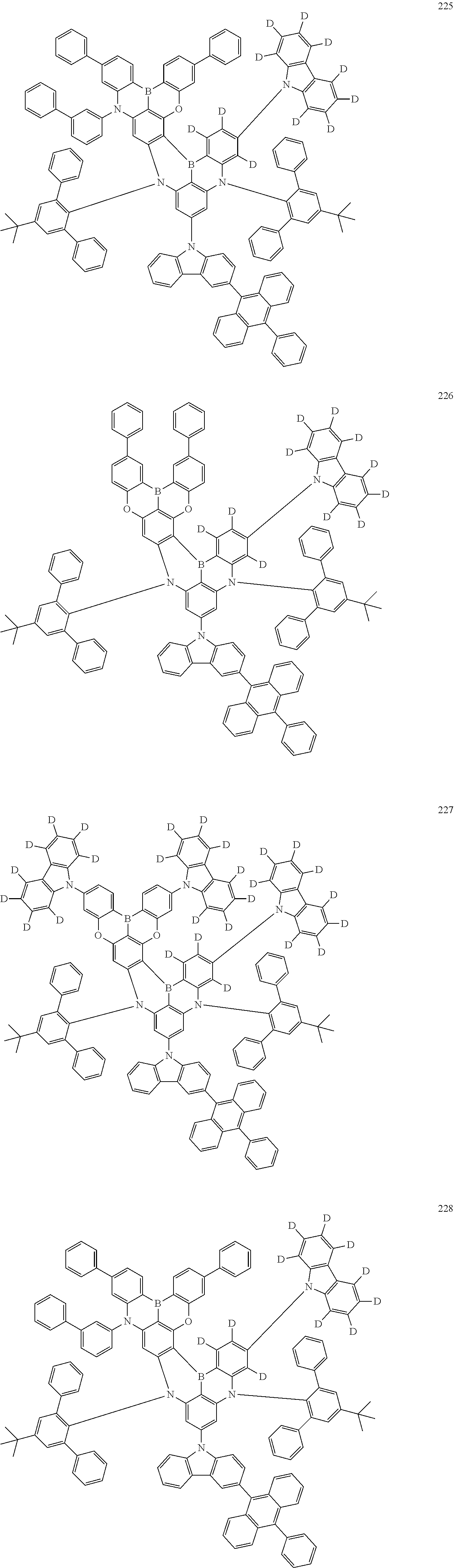 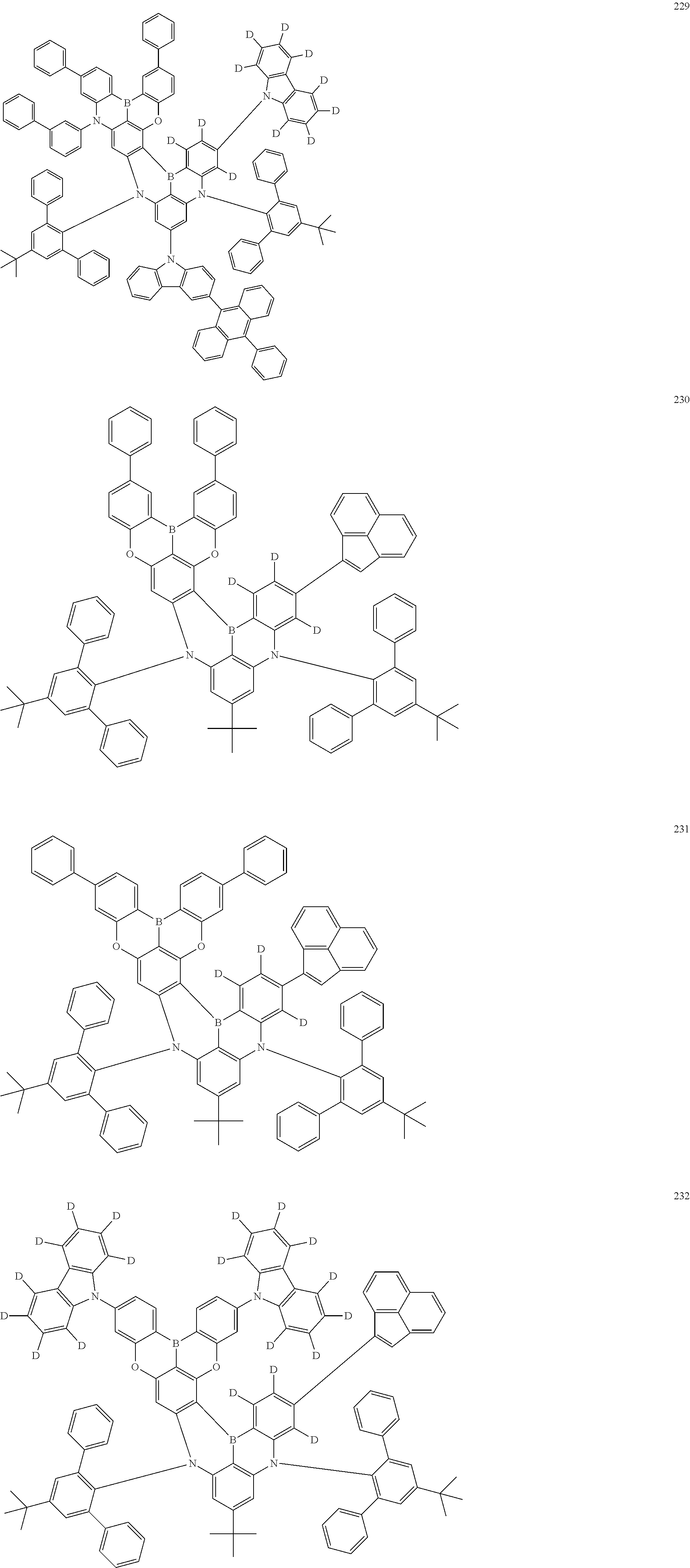 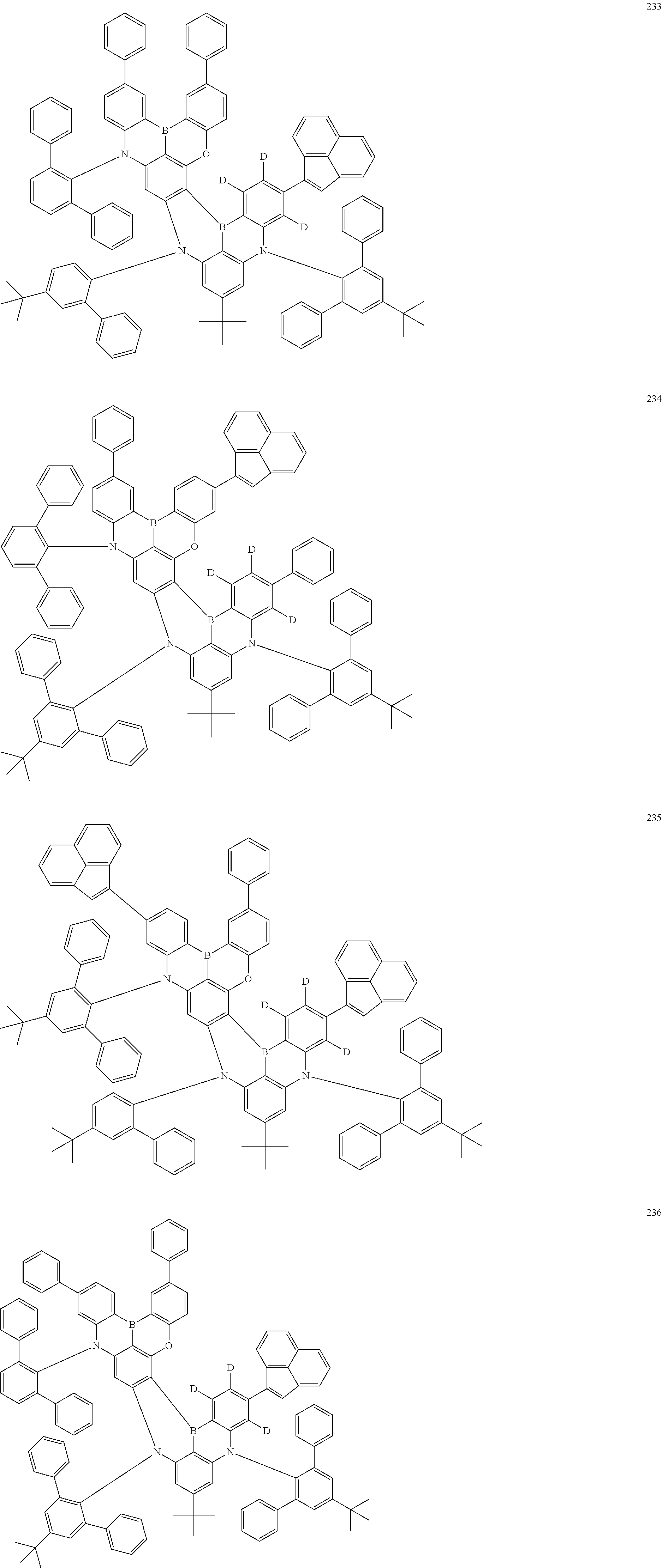 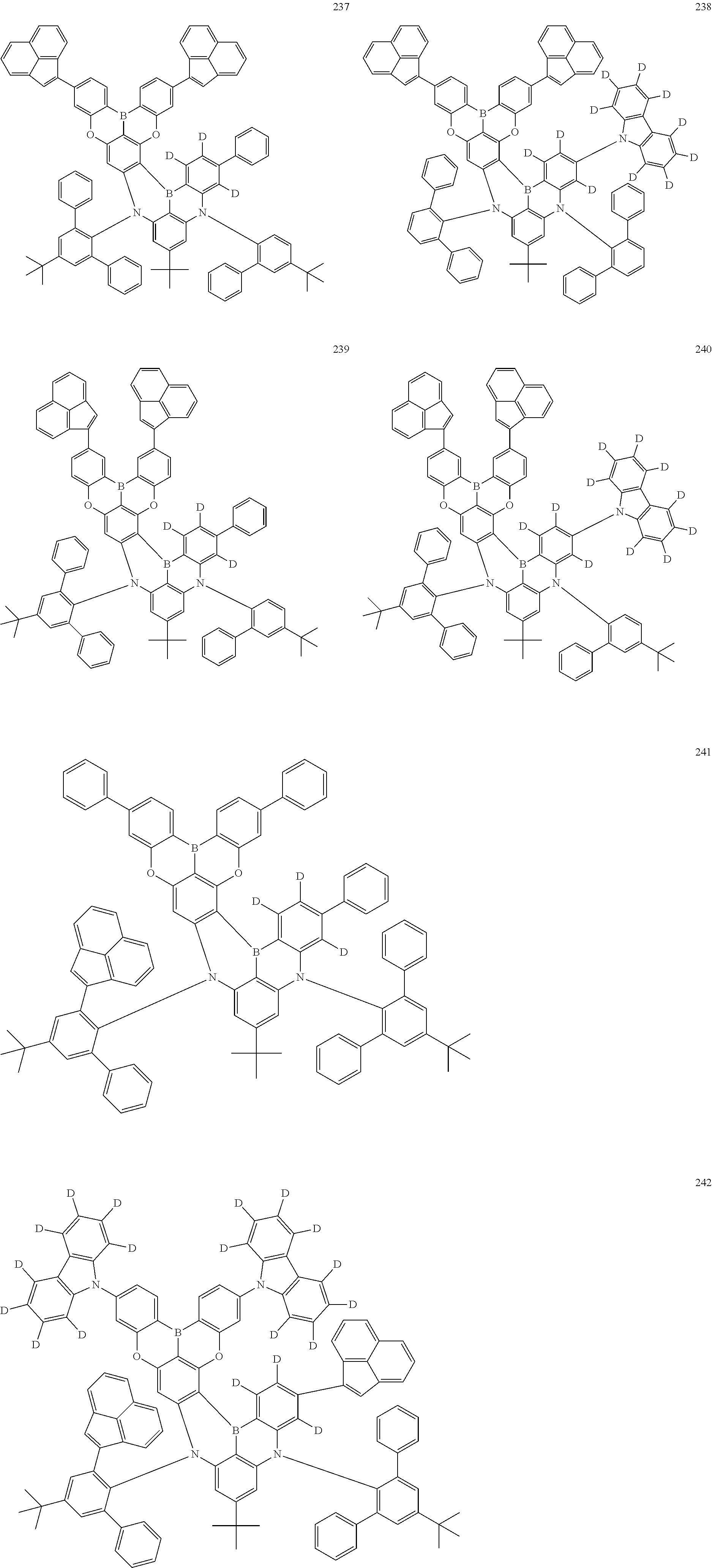 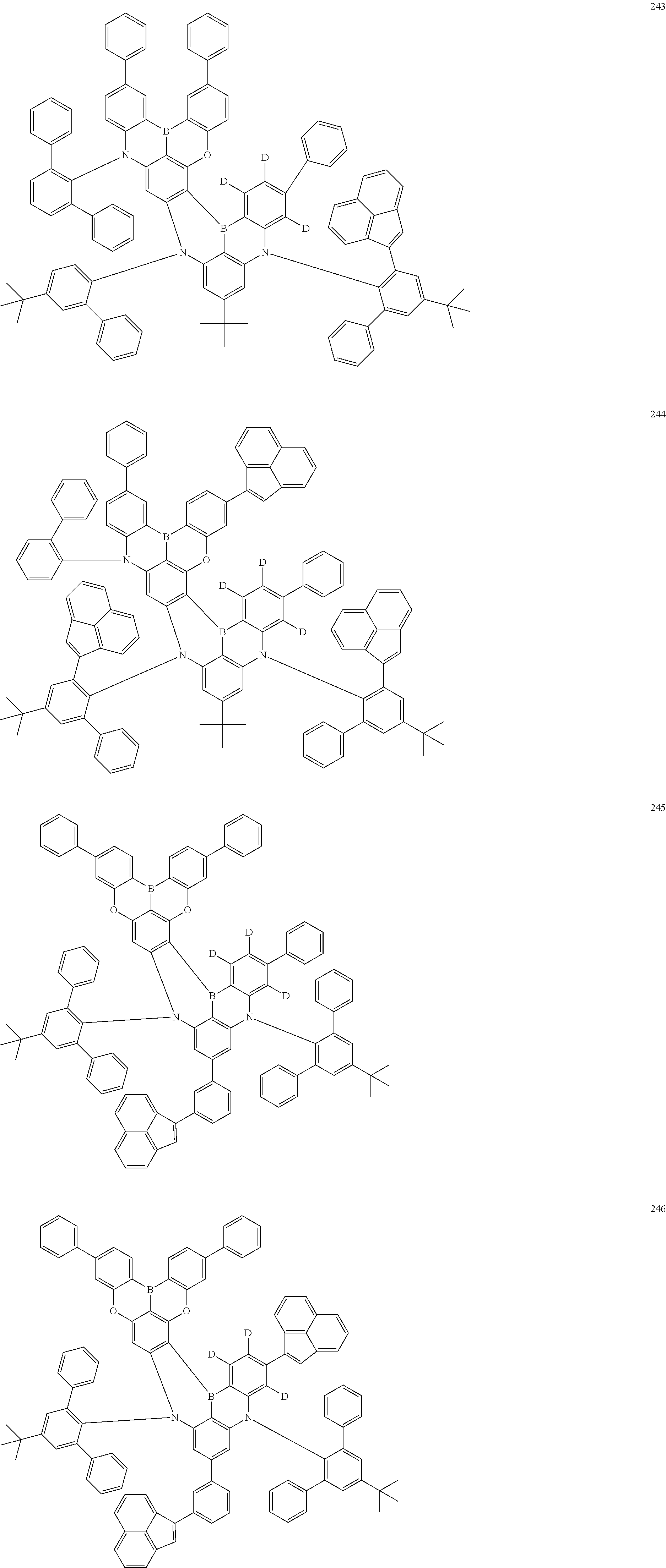 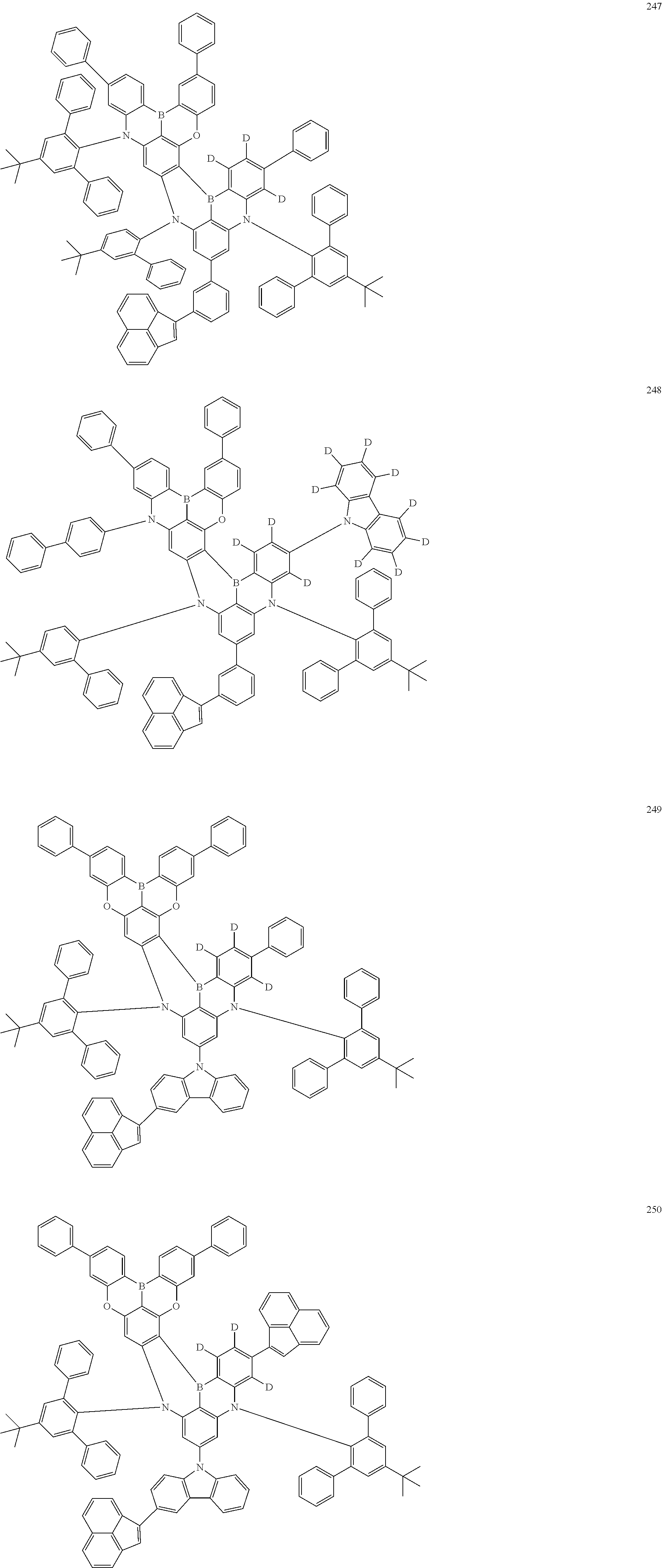 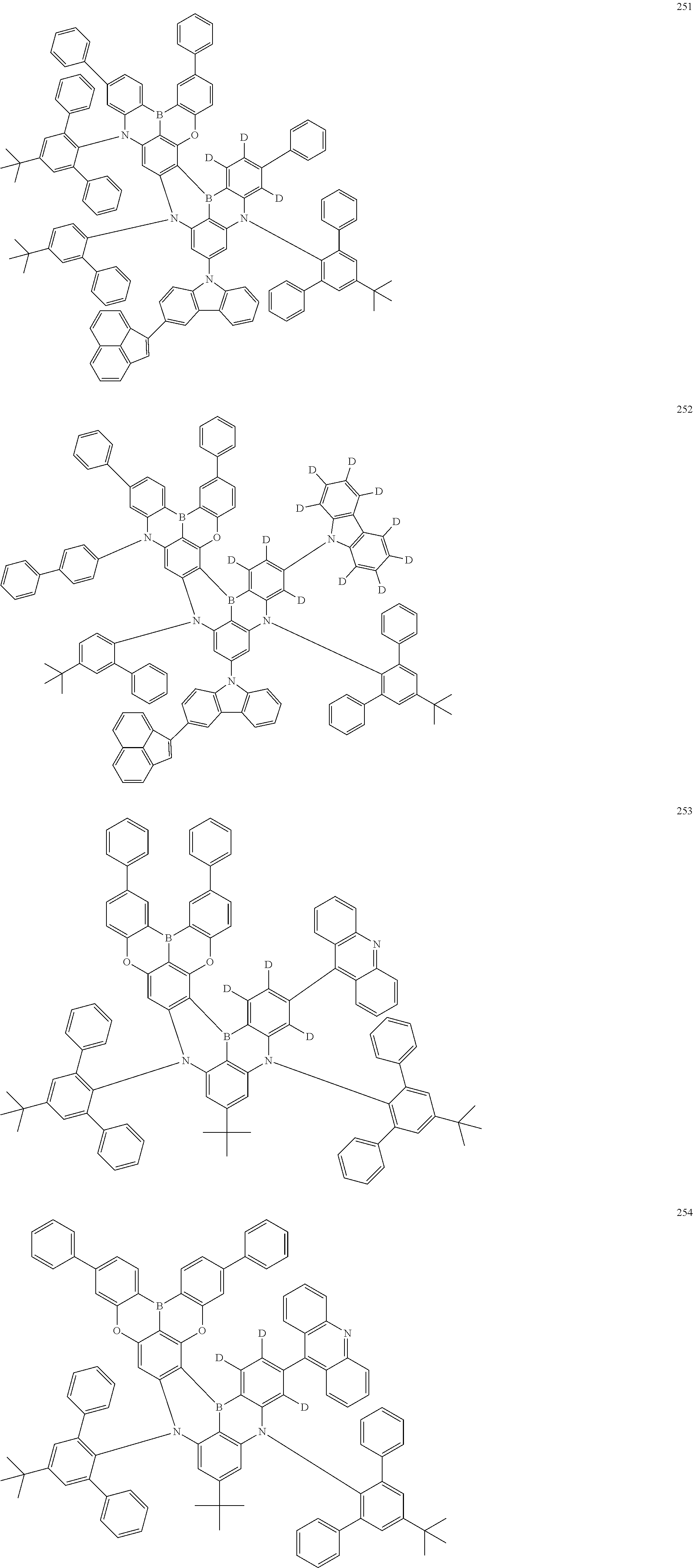 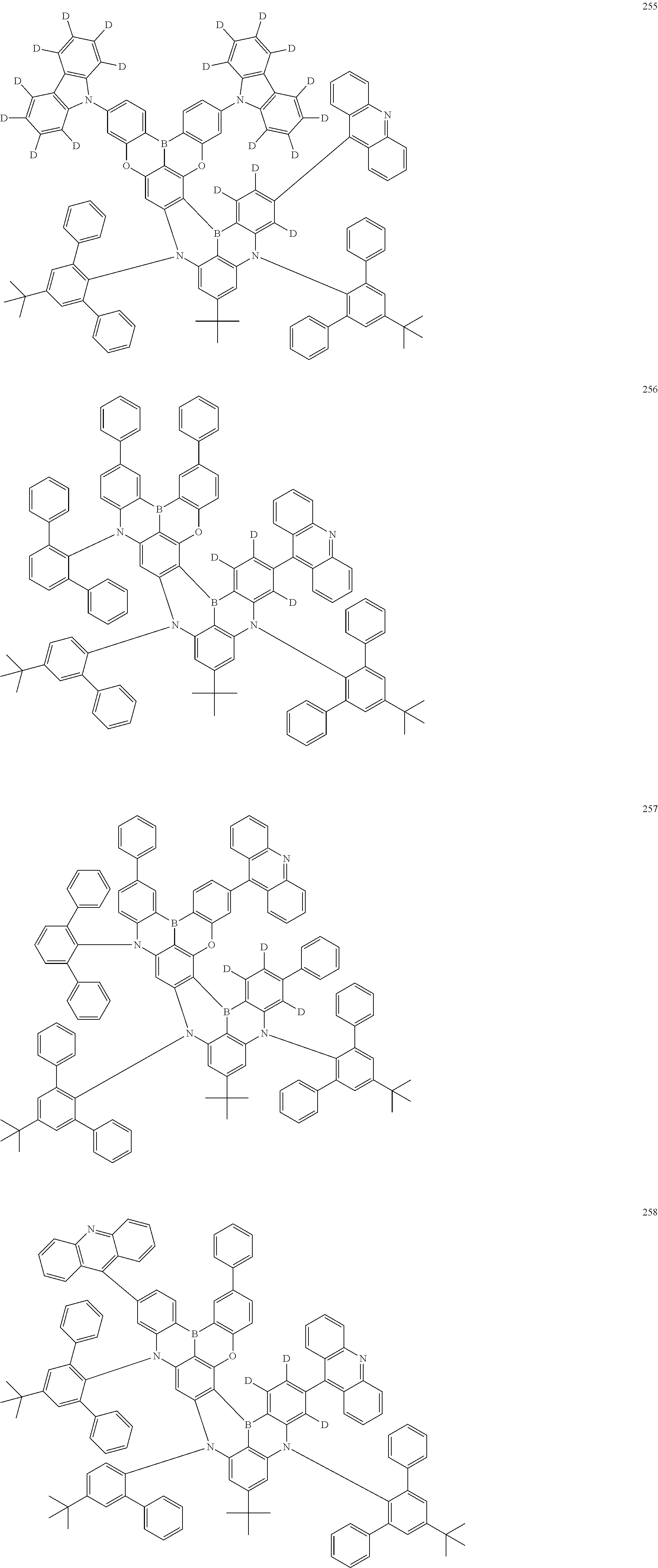 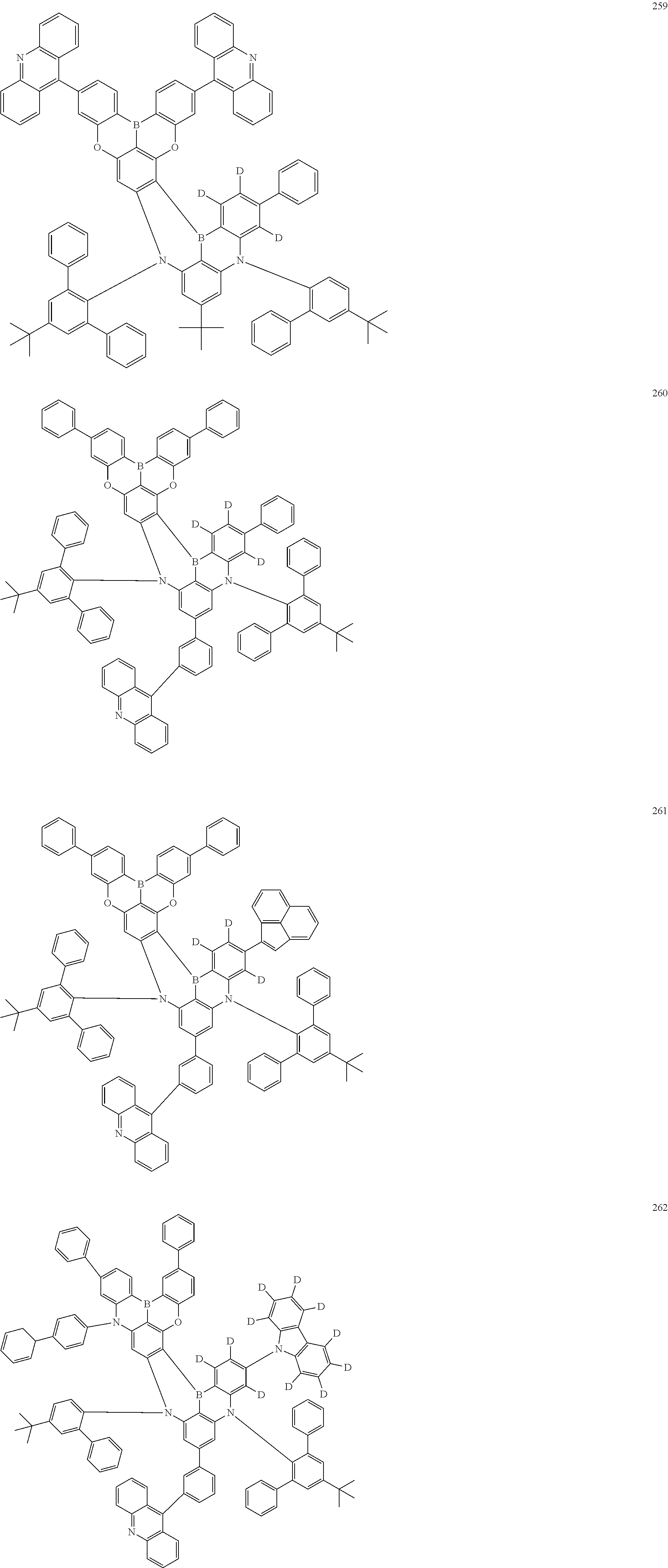 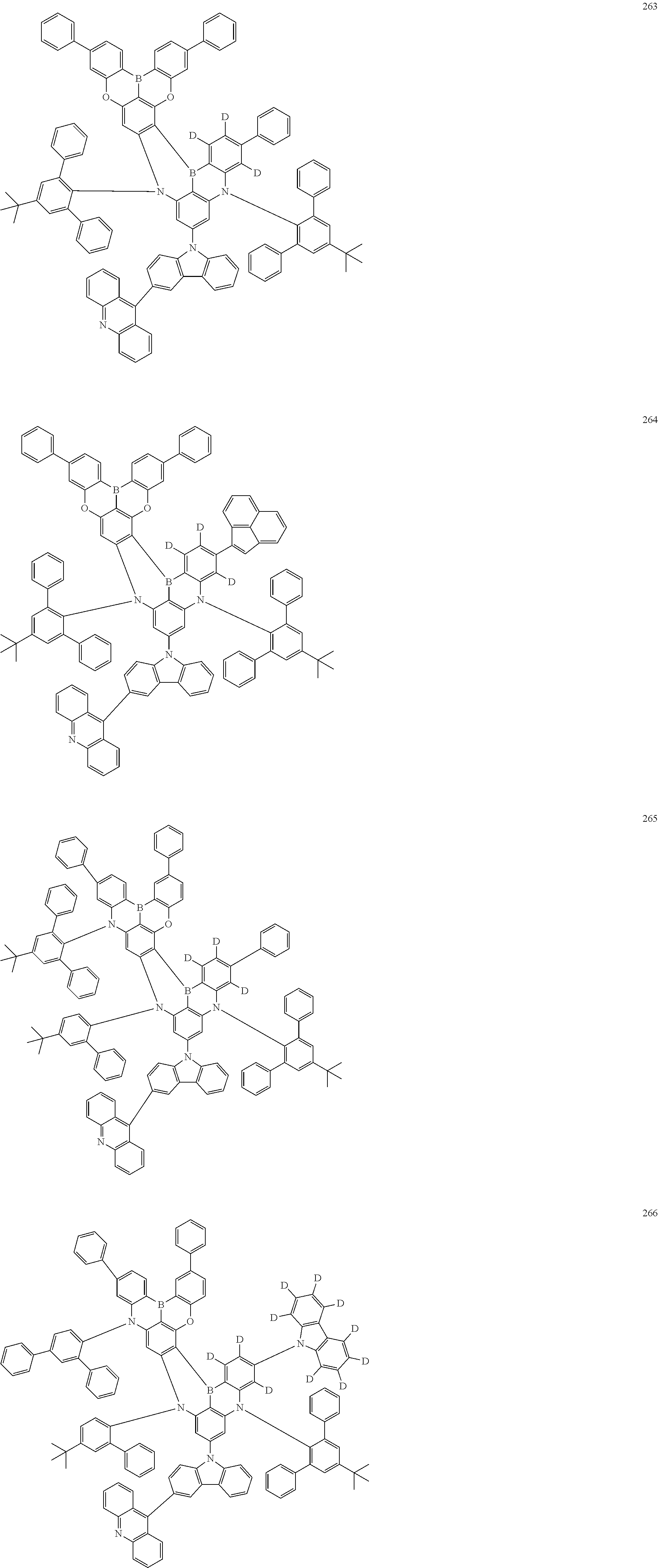 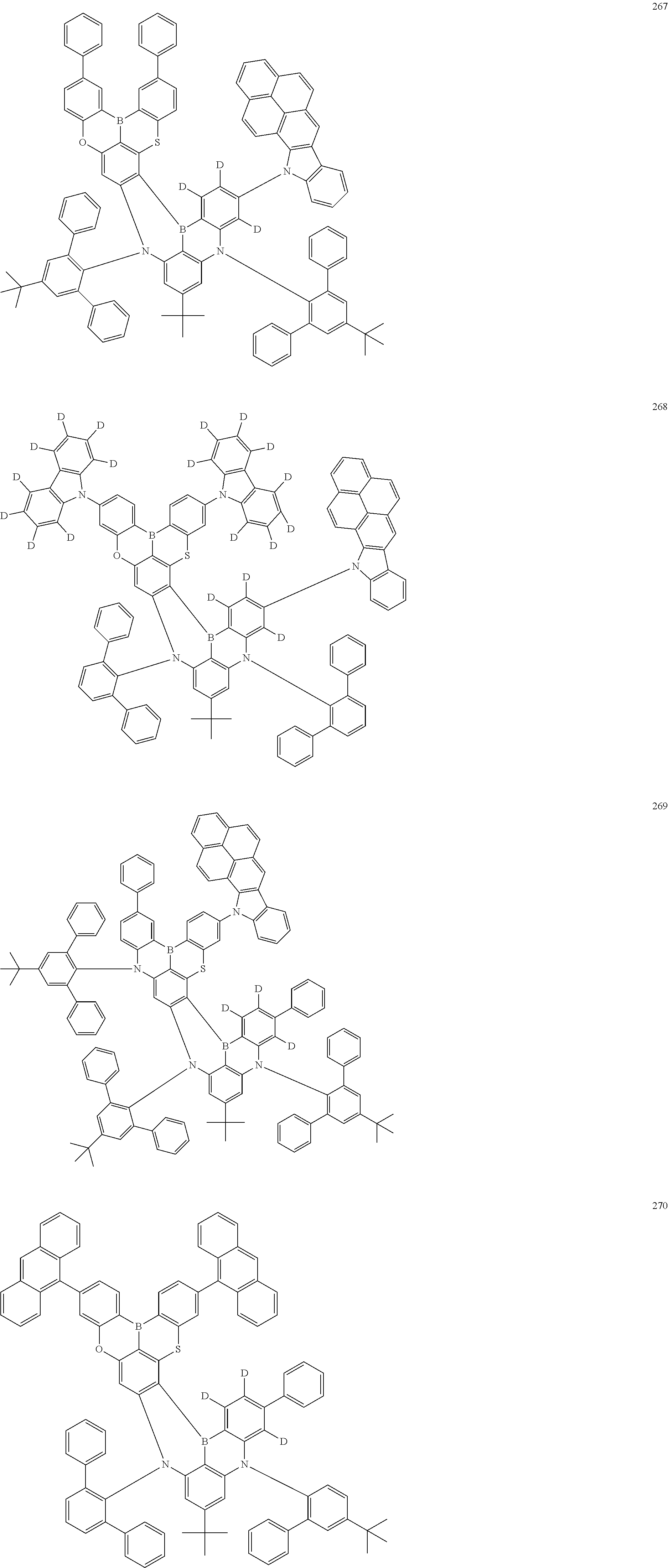 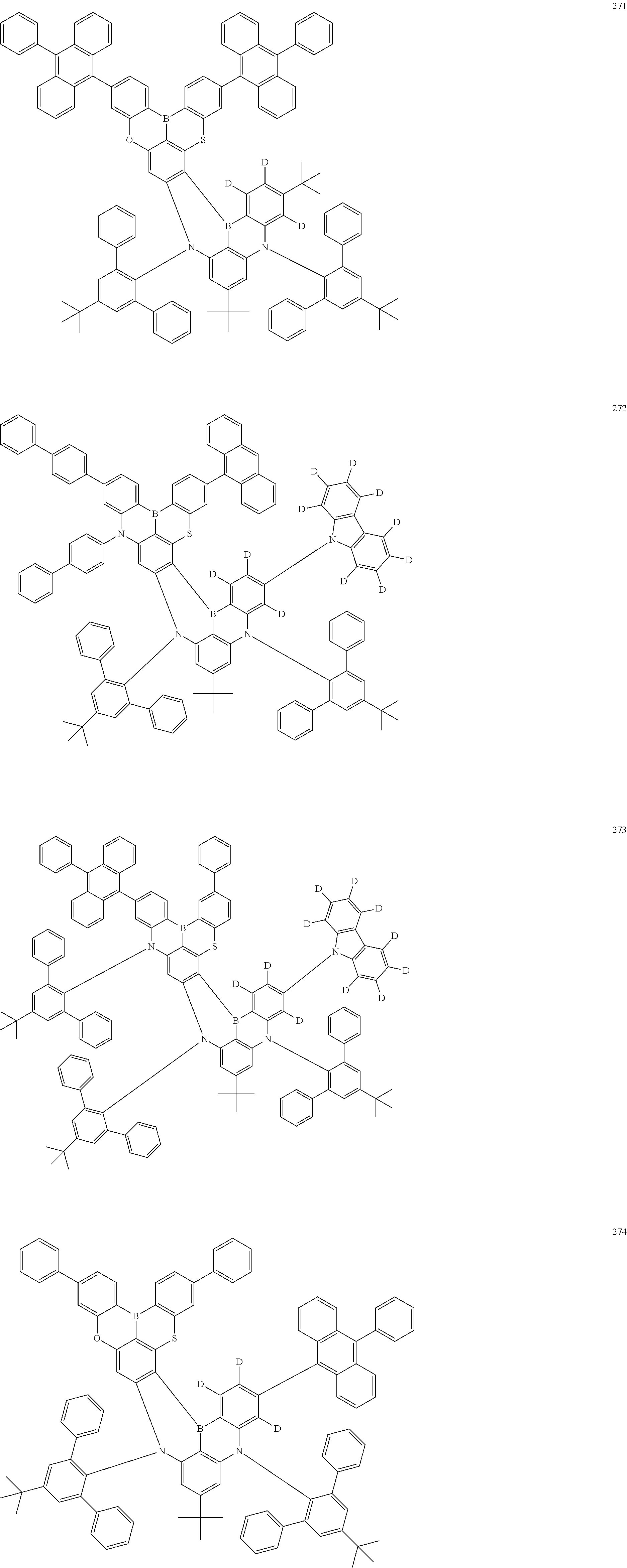 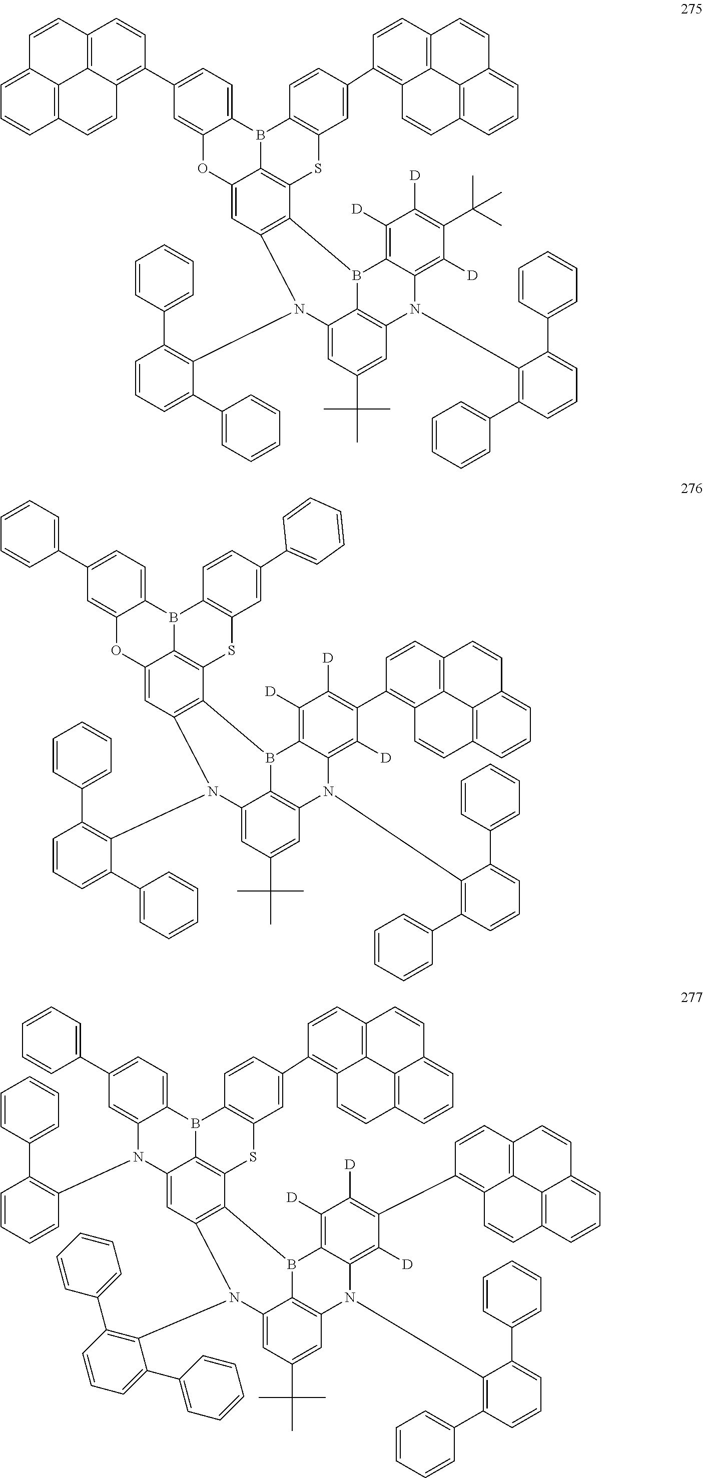 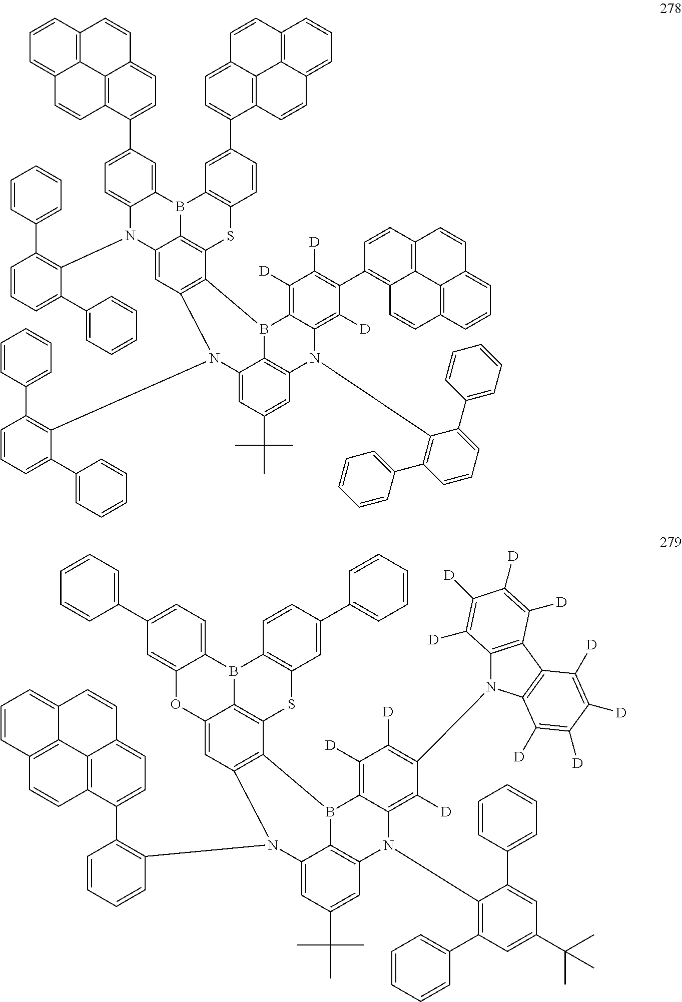 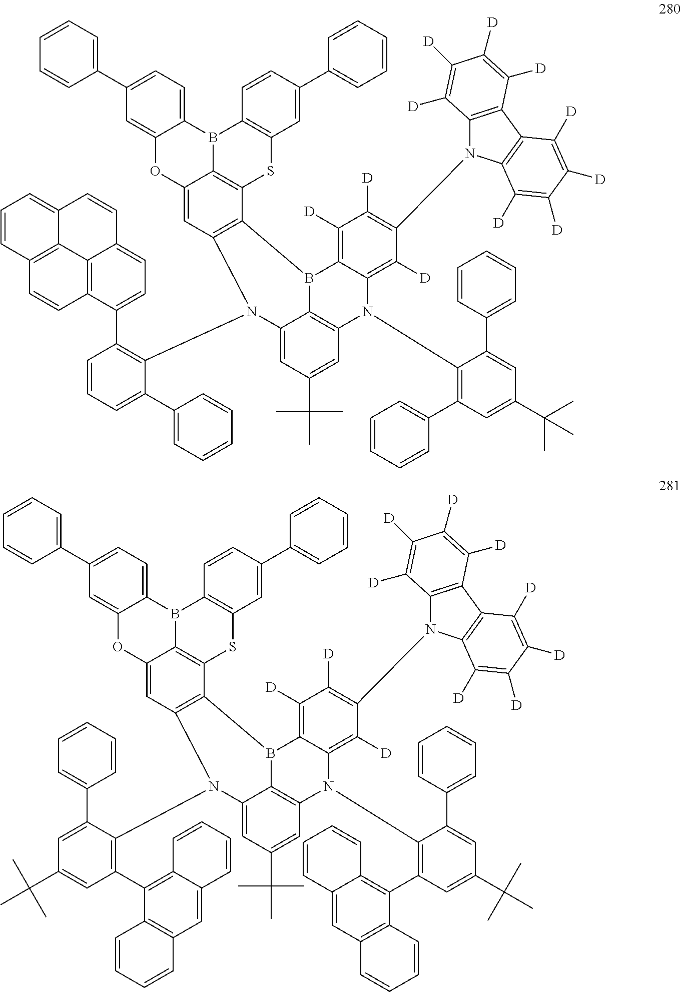 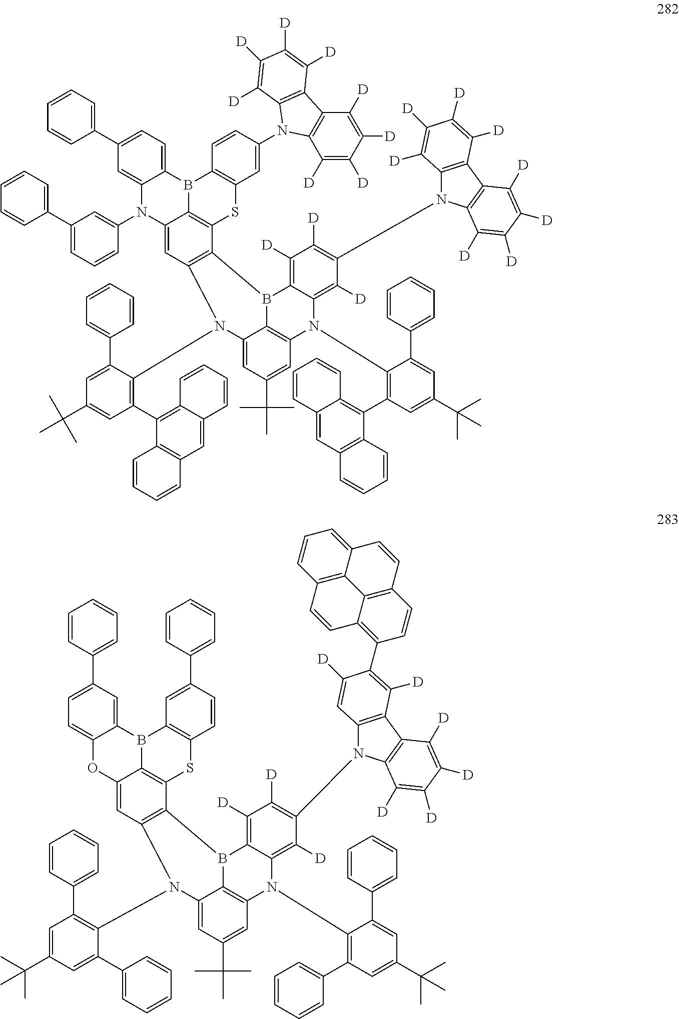 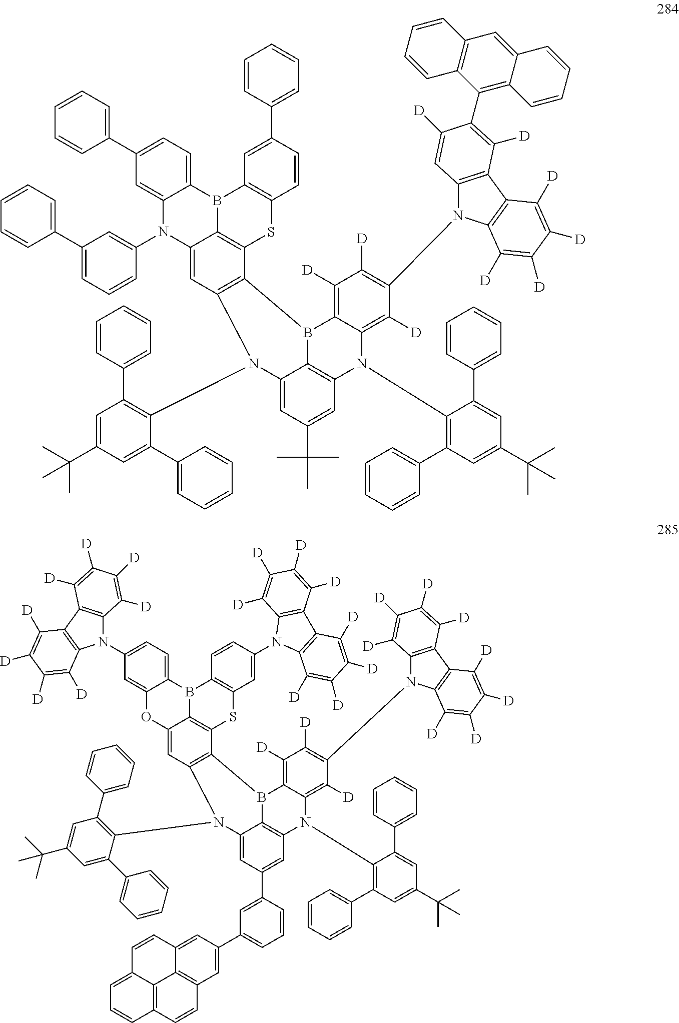 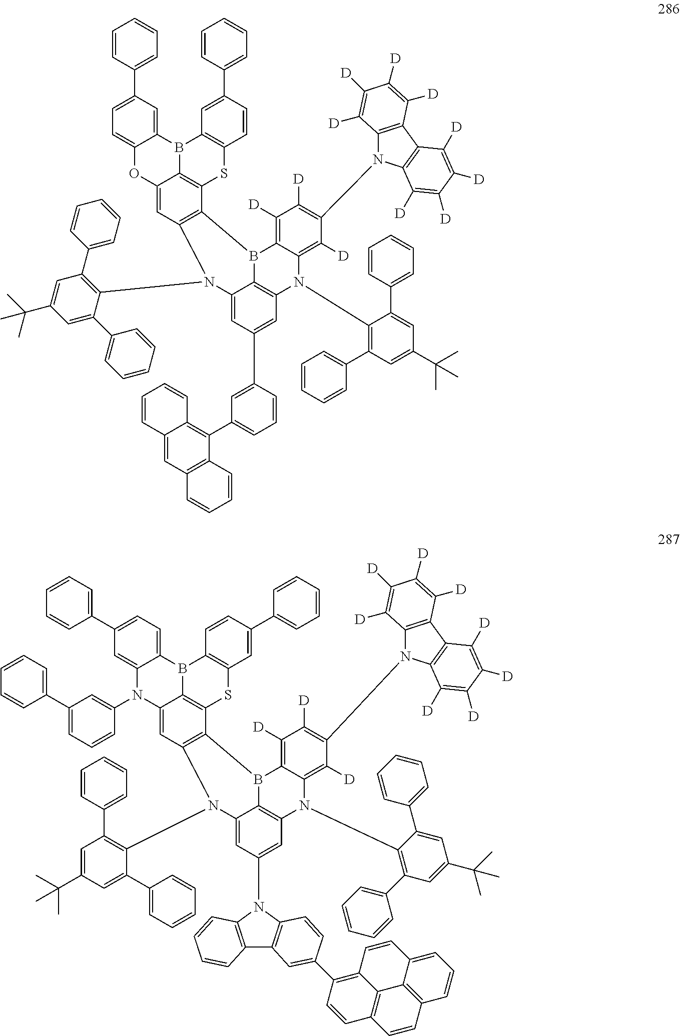 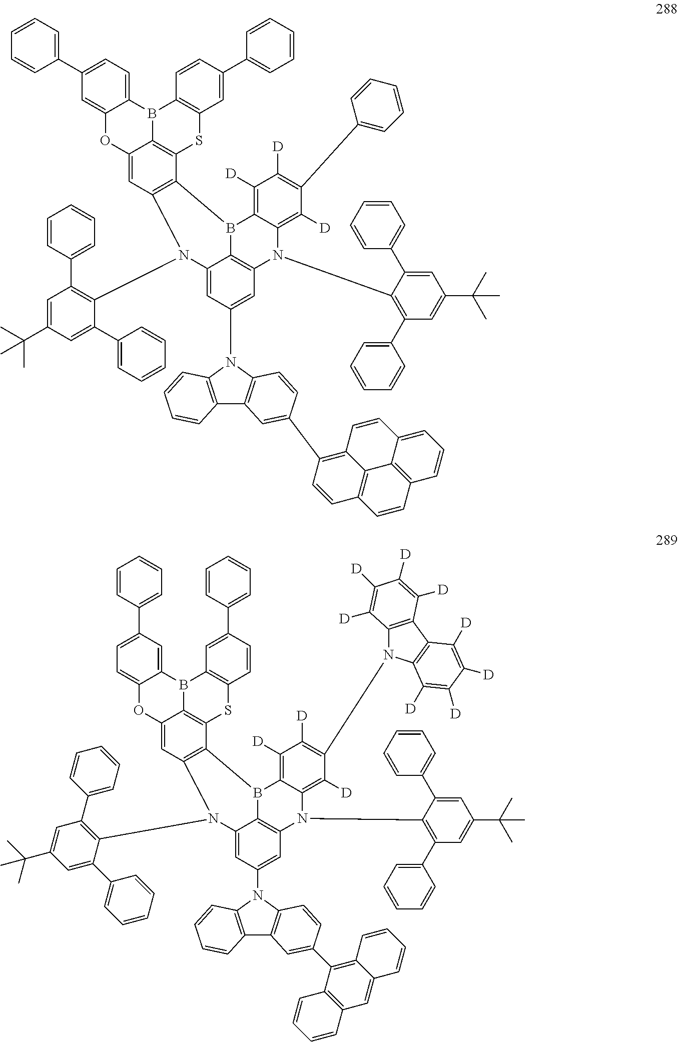 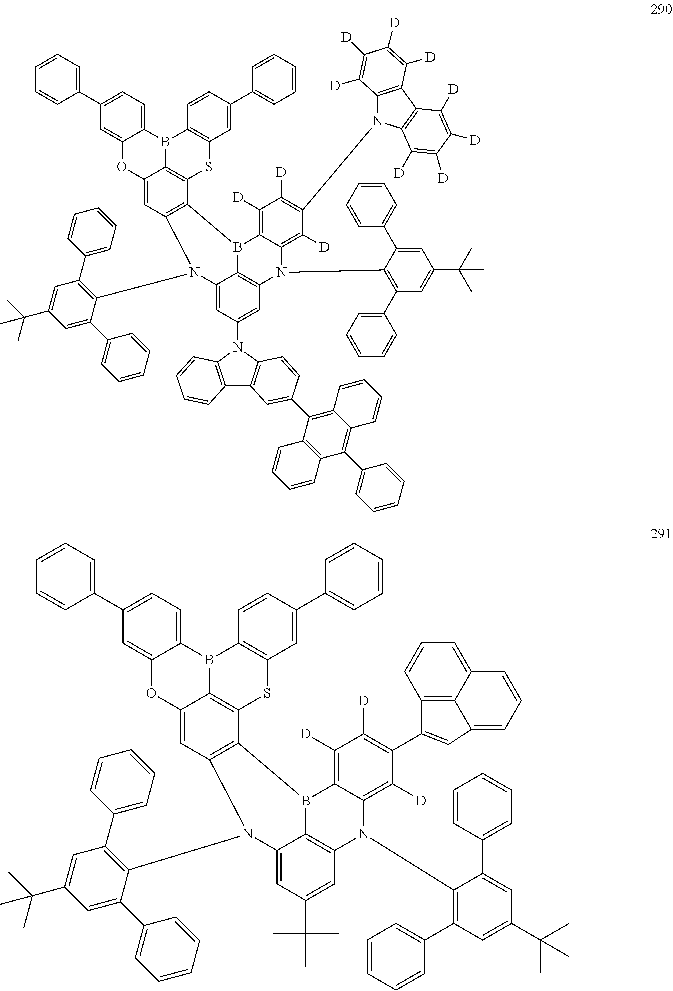 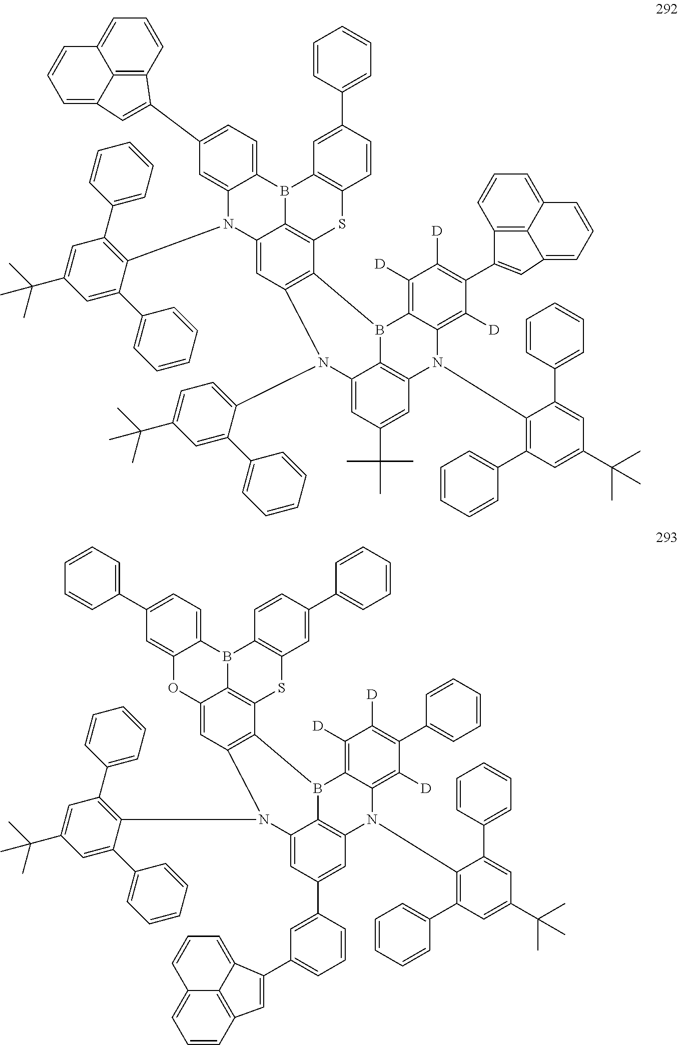 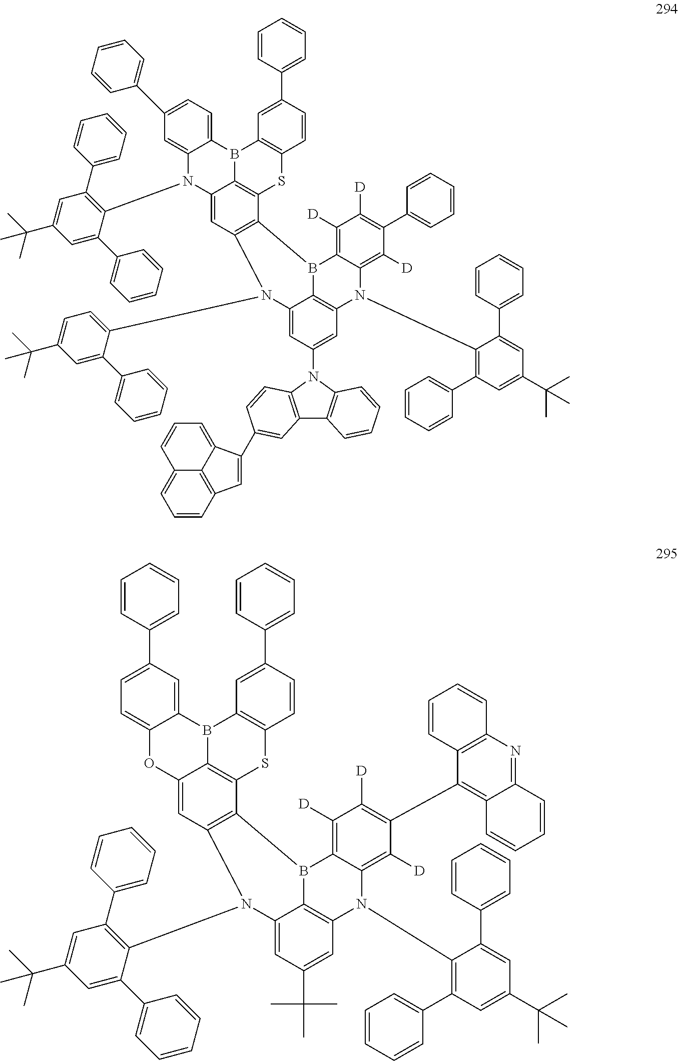 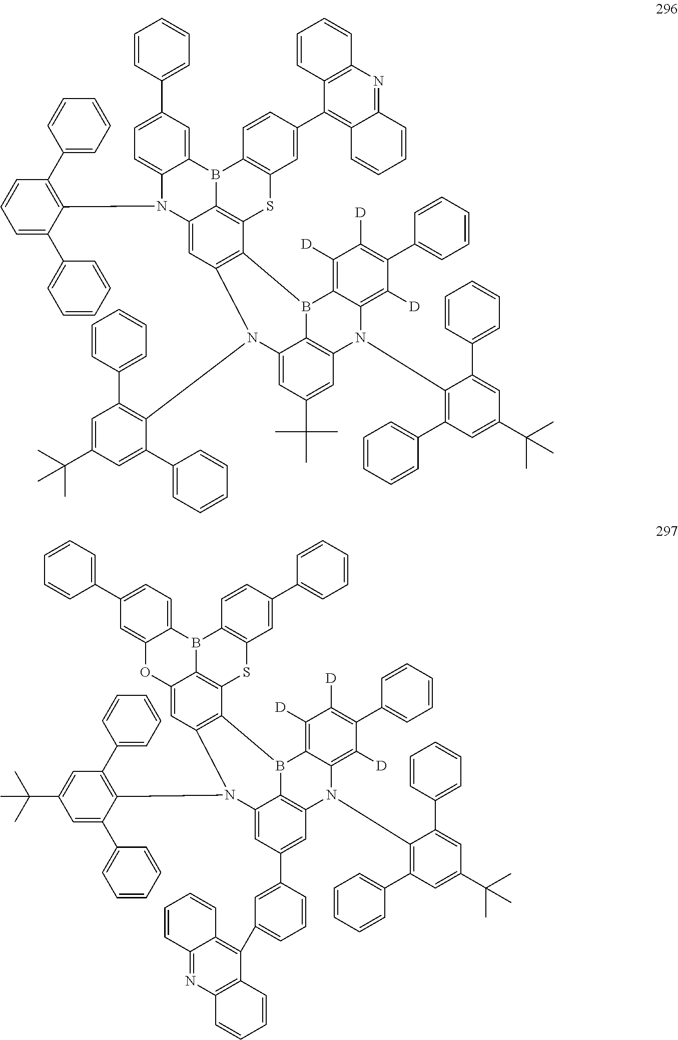 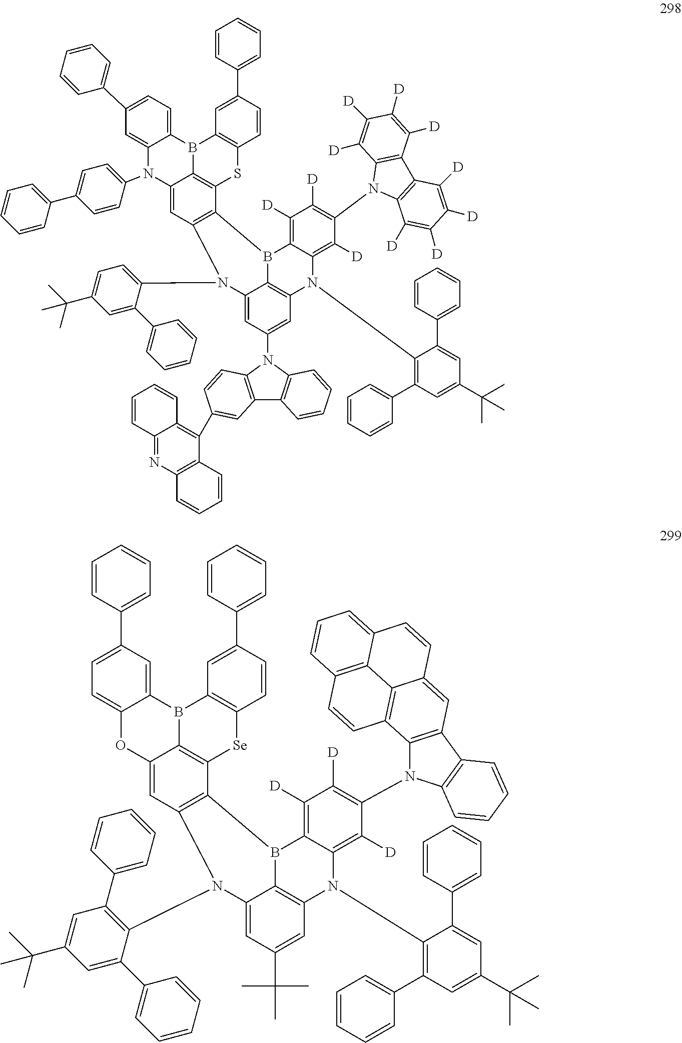 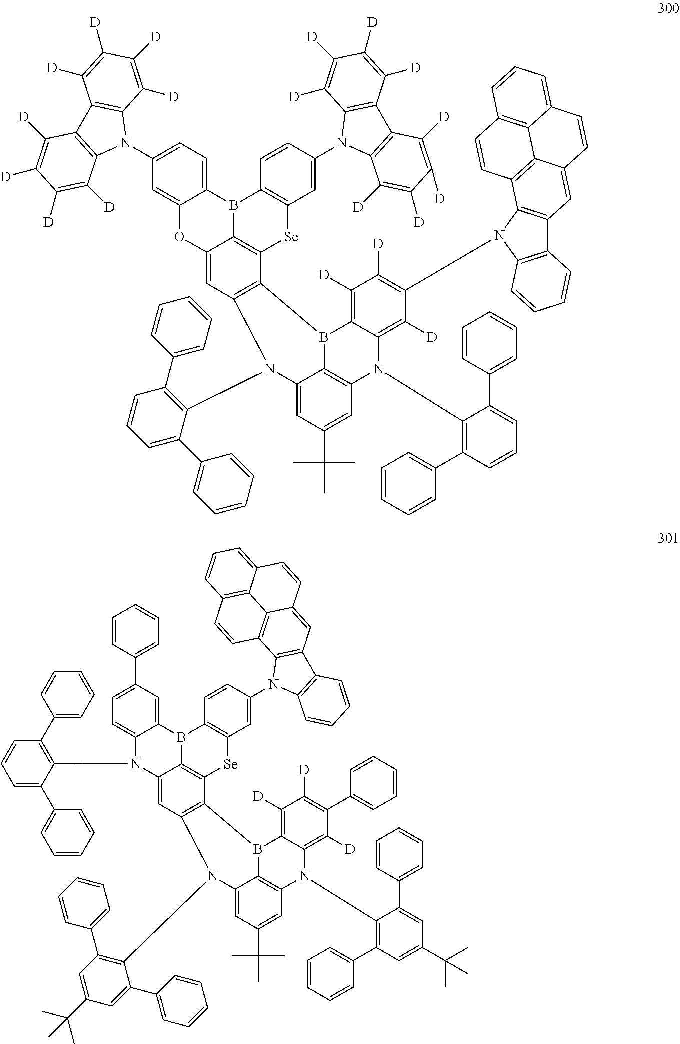 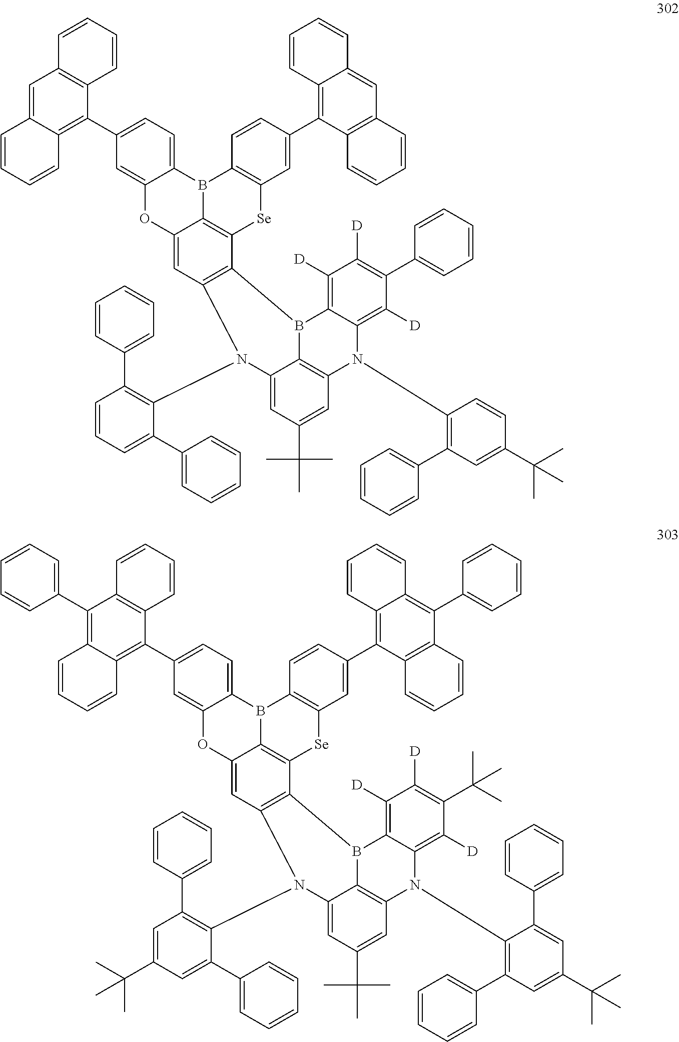 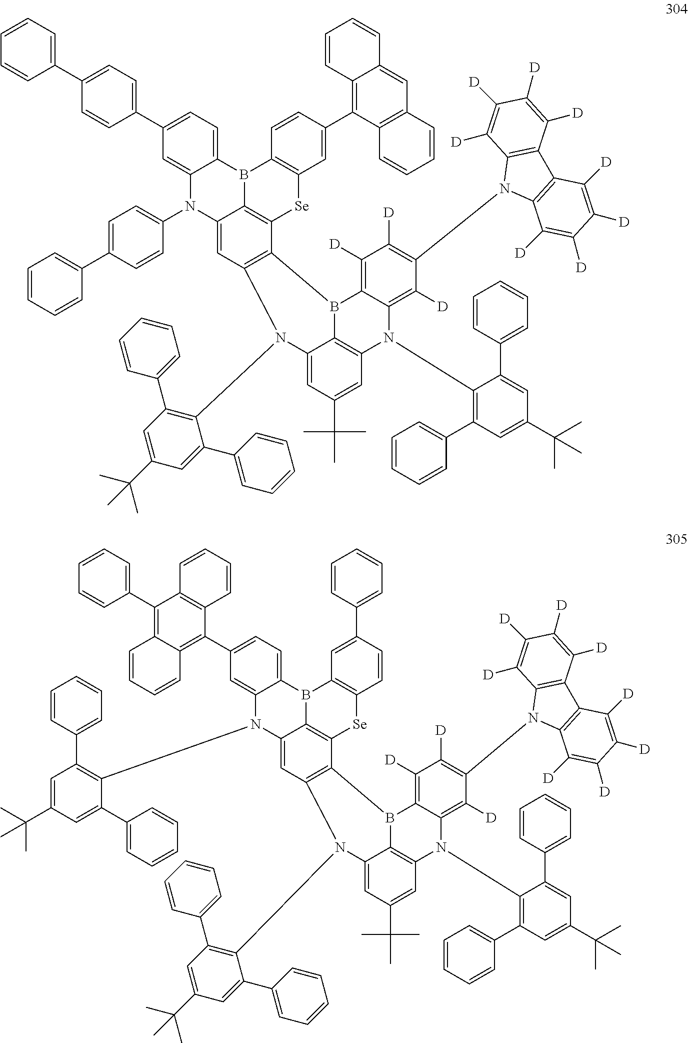 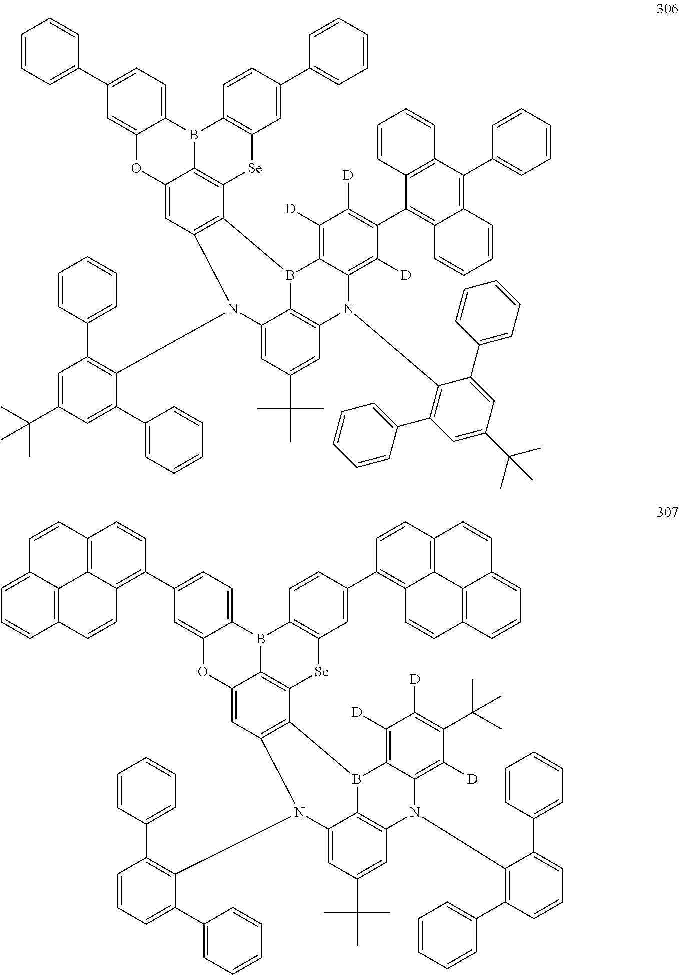 [SMILES: [2H]c1c([2H])c(-c2c3ccccc3c(-c3ccccc3)c3ccccc23)c([2H])c2c1B1c3c(cc(C(C)(C)C)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)[Se]c1cc(-c2ccccc2)ccc1B4c1ccc(-c2ccccc2)cc1O3 ; [2H]c1c([2H])c(C(C)(C)C)c([2H])c2c1B1c3c(cc(C(C)(C)C)cc3N2c2c(-c3ccccc3)cccc2-c2ccccc2)N(c2c(-c3ccccc3)cccc2-c2ccccc2)c2cc3c4c(c21)[Se]c1cc(-c2ccc5ccc6cccc7ccc2c5c67)ccc1B4c1ccc(-c2ccc4ccc5cccc6ccc2c4c56)cc1O3] 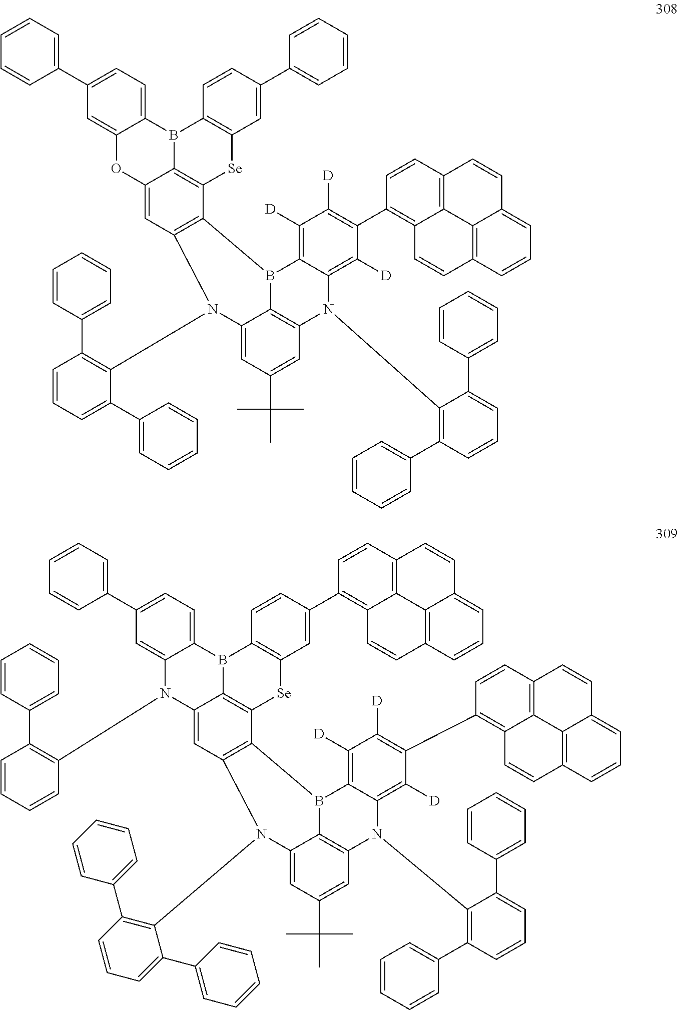 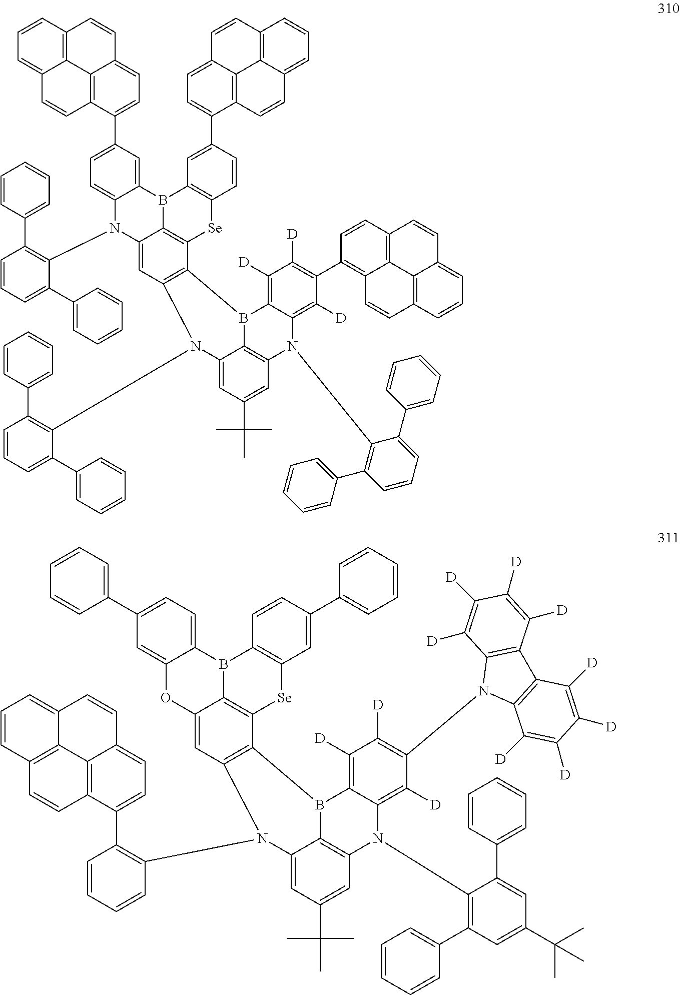 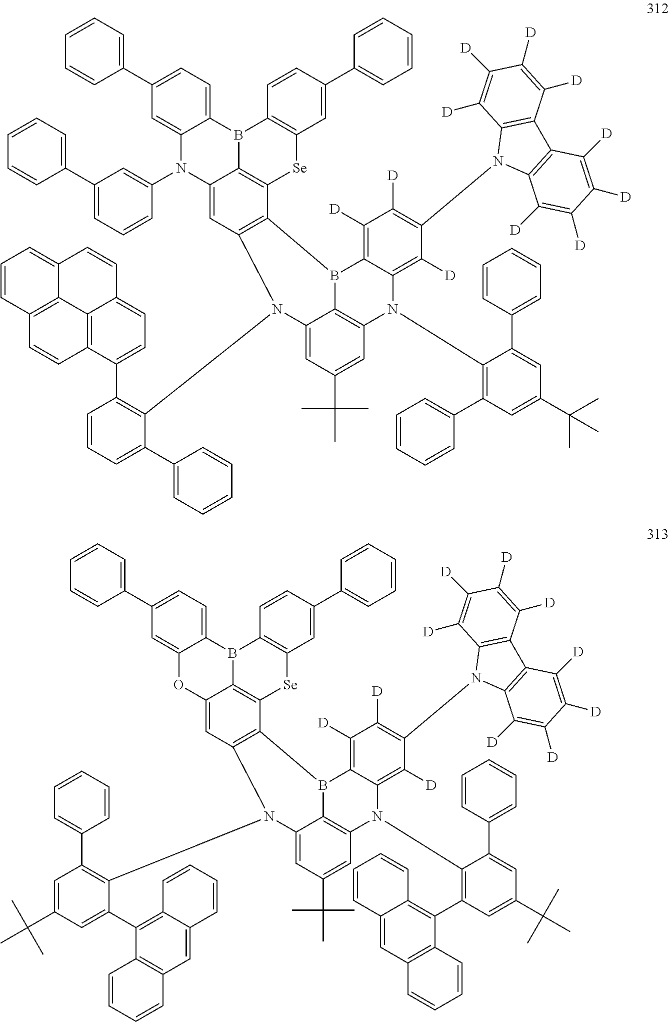 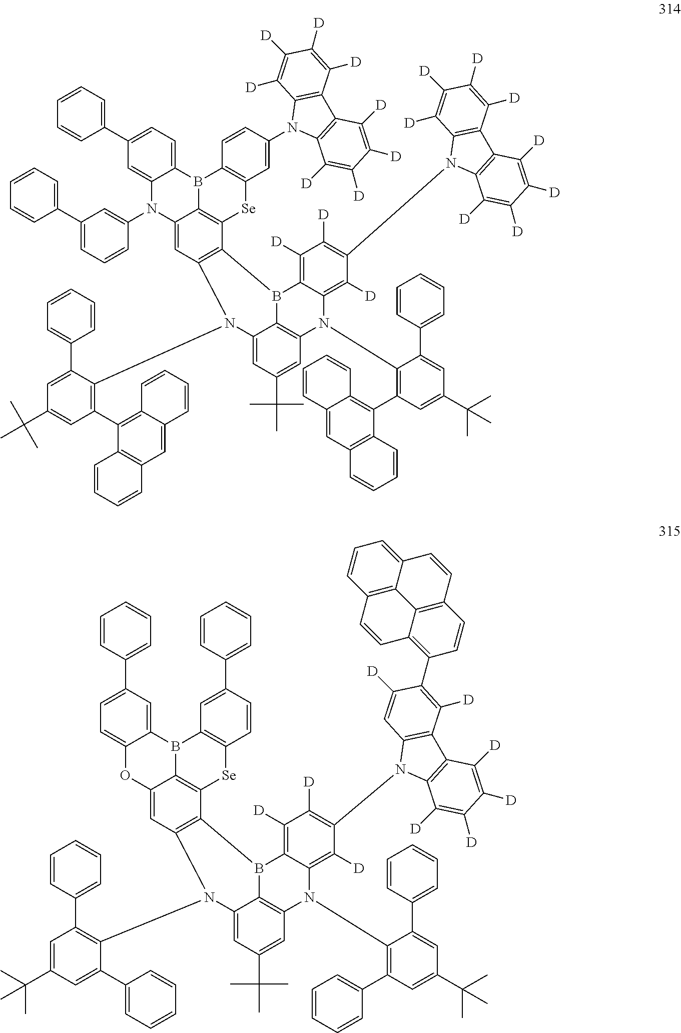 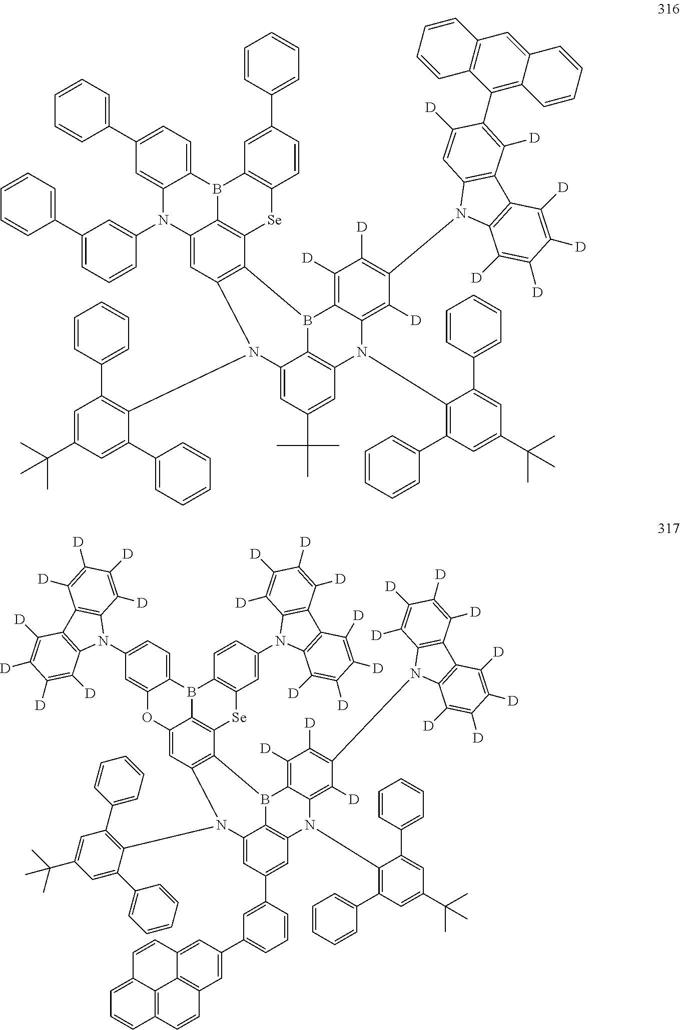 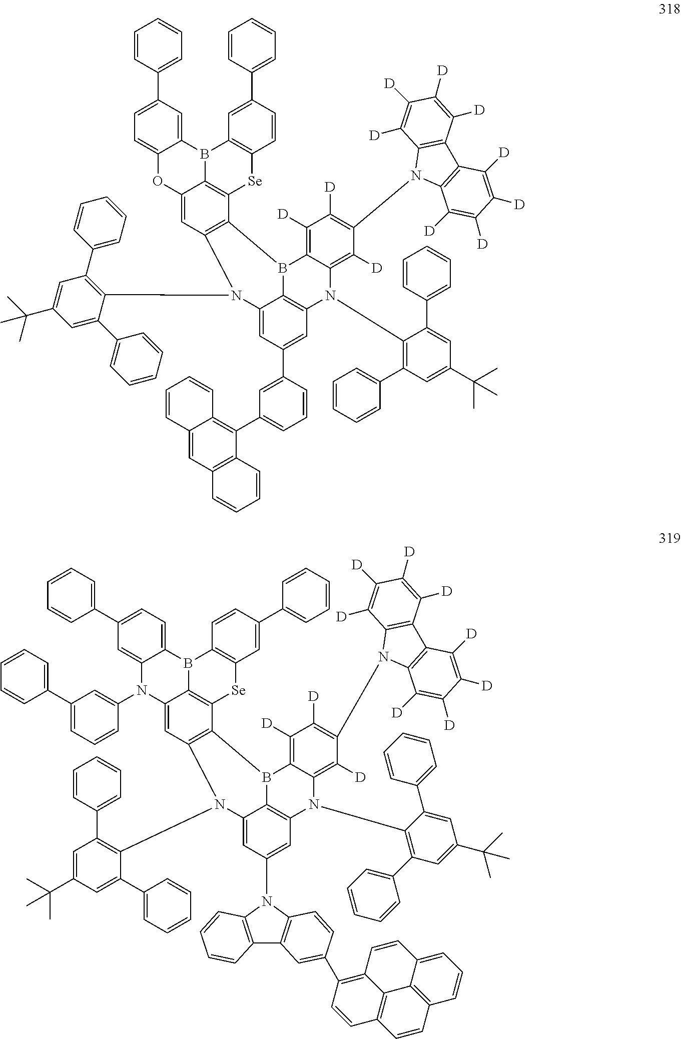 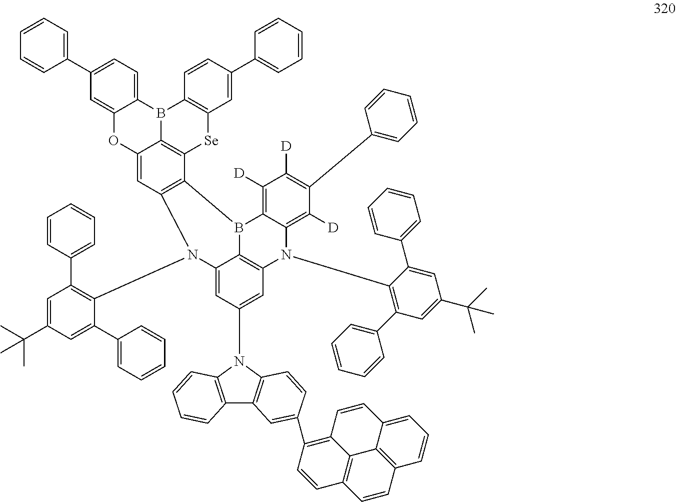 [SMILES: [2H]c1c([2H])c(-c2ccccc2)c([2H])c2c1B1c3c(cc(-n4c5ccccc5c5cc(-c6ccc7ccc8cccc9ccc6c7c89)ccc54)cc3N2c2c(-c3ccccc3)cc(C(C)(C)C)cc2-c2ccccc2)N(c2c(-c3ccccc3)cc(C(C)(C)C)cc2-c2ccccc2)c2cc3c4c(c21)[Se]c1cc(-c2ccccc2)ccc1B4c1ccc(-c2ccccc2)cc1O3] 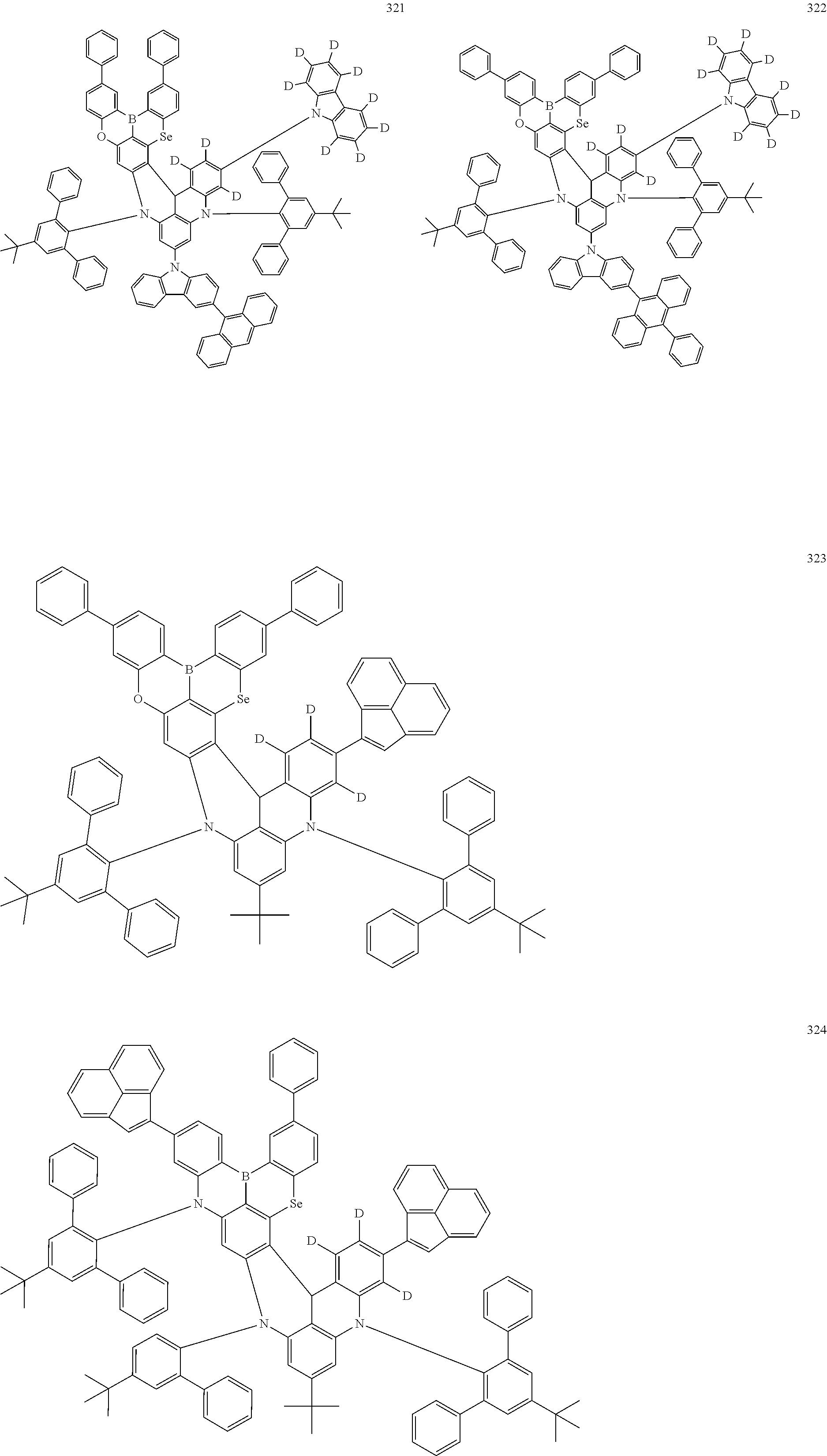 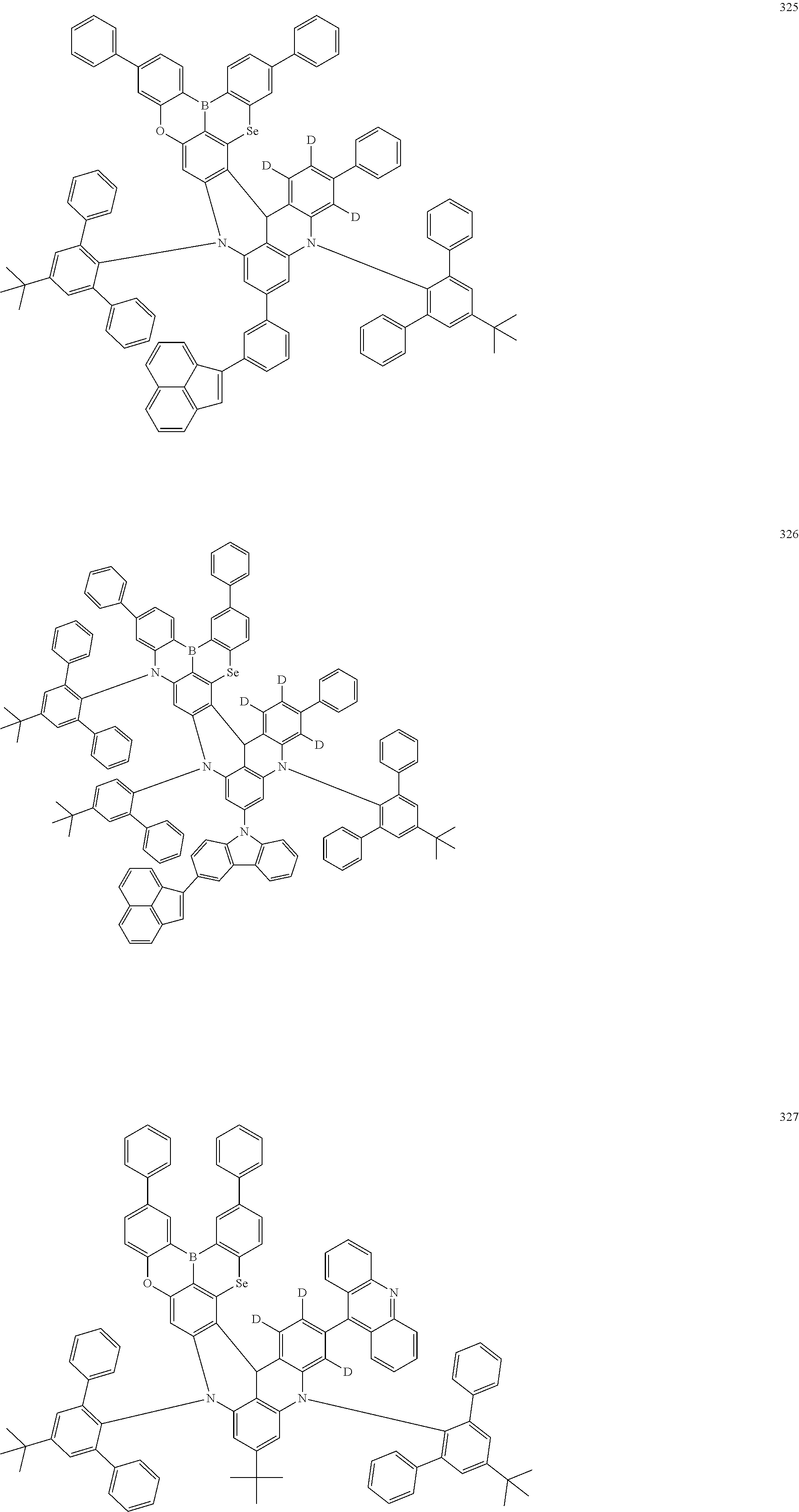 [chemical structure]
